(19) United States
(12) Patent Application Publication
(10) Pub. No.: US 2023/0200209 A1
(43) Pub. Date: Jun. 22, 2023

(54) ORGANOMETALLIC COMPOUND AND ORGANIC LIGHT-EMITTING DIODE INCLUDING THE SAME

(71) Applicants: LG DISPLAY CO., LTD., Seoul (KR); LT MATERIALS CO., LTD., Yongin-si (KR)

(72) Inventors: Jaemin MOON, Seoul (KR); Inbum SONG, Seoul (KR); Dohan KIM, Goyang-si (KR); Sungjin PARK, Incheon (KR); Seokhyeon YU, Osan-si (KR); Hyun Ju LA, Osan-si (KR); Kundo KIM, Osan-si (KR)

(73) Assignees: LG DISPLAY CO., LTD., Seoul (KR); LT MATERIALS CO., LTD., Yongin-si (KR)

(21) Appl. No.: 18/086,400

(22) Filed: Dec. 21, 2022

(30) Foreign Application Priority Data
Dec. 22, 2021 (KR) 10-2021-0184522
Sep. 26, 2022 (KR) 10-20220121842

(51) Int. Cl. H10K 85/30; C07F 15/00; C09K 11/06

(52) U.S. Cl. CPC H10K 85/342; C07F 15/0033; C09K 11/06; C09K 2211/185; C09K 2211/1048; C09K 2211/1051; C09K 2211/1044; C09K 2211/1059; H10K 2101/10

(57) ABSTRACT

A novel organometallic compound represented by a following Chemical Formula I is described:

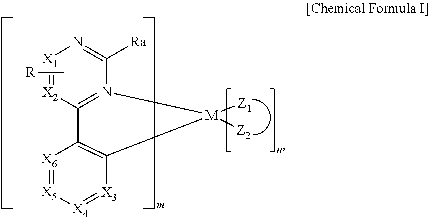

wherein R represents a fused ring connected to X₁ and X₂, with variables as defined herein. The organometallic compound acts as a dopant of a light-emitting layer of an organic light-emitting diode. An organic light emitting device includes the organic light emitting diode and can be a display device or a lighting device. Improved color gamut of the diode, luminous efficiency and a lifespan thereof are achieved, as well as a lower operation voltage of the diode.

### CROSS-REFERENCE TO RELATED APPLICATION

This application claims priority to Korean Patent Application No. 10-2021-0184522 filed on Dec. 22, 2021, and Korean Patent Application No. 10-2022-0121842 filed on Sep. 26, 2022, both in the Korean Intellectual Property Office, the entire contents of all these applications being herein expressly incorporated by reference into the present application.

### BACKGROUND

### Field

The present disclosure relates to an organometallic compound, and more particularly, to an organometallic compound having phosphorescent properties, as well as an organic light-emitting diode and display device including the same.

### Description of Related Art

Display devices are useful in various fields, and providing an improved display device is needed. In particular, an organic light-emitting display device including an organic light-emitting diode (OLED) is rapidly developing.

In an OLED, when electric charges are injected into a light-emitting layer formed between a positive electrode and a negative electrode, an electron and a hole are recombined with each other in the light-emitting layer to form an exciton, and the energy of the exciton is converted into light. In this manner, the OLED emits light.

### SUMMARY OF THE DISCLOSURE

Compared to conventional display devices, an organic light-emitting diode can operate at a low voltage, consume less power, render excellent colors, and can be used in a variety of ways. The OLED can also be formed on a flexible substrate, to provide a flexible or foldable device. Further, the size of the OLED can be adjustable.

An OLED has superior viewing angle and contrast ratio compared to a liquid crystal display (LCD), and is lightweight and ultra-thin because the OLED does not require a backlight.

The OLED can include a plurality of organic layers between a negative electrode (e.g., electron injection electrode, cathode, etc.) and a positive electrode (e.g., hole injection electrode, anode, etc.). The plurality of organic layers can include a hole injection layer, a hole transport layer, a hole transport auxiliary layer, an electron blocking layer, and a light-emitting layer, an electron transport layer, etc.

In the OLED structure described herein, when a voltage is applied across the two electrodes, electrons and holes are injected from the negative and positive electrodes, respectively, into the light-emitting layer and thus excitons are generated in the light-emitting layer and then fall to a ground state to emit light in the process.

Organic materials used in the organic light-emitting diode can be largely classified into light-emitting materials and charge-transporting materials. The light-emitting material is an important factor in determining luminous efficiency of the organic light-emitting diode. The luminescent material must have high quantum efficiency, excellent electron and hole mobility, and must exist uniformly and stably in the light-emitting layer. The light-emitting materials can be classified into light-emitting materials emitting light of blue, red, and green colors based on colors of the light. A color-generating material can include a host and dopants to increase the color purity and luminous efficiency through energy transfer.

When a fluorescent material is used, singlets as about 25% of excitons generated in the light-emitting layer are used to emit light, while most of triplets as 75% of the excitons generated in the light-emitting layer are dissipated as heat. However, when a phosphorescent material is used, singlets and triplets are used to emit light.

Conventionally, an organometallic compound is used as the phosphorescent material in an organic light-emitting diode. Research and development of the phosphorescent material to solve low efficiency and lifetime problems are continuously required.

Accordingly, a purpose of the present invention is to provide an organometallic compound capable of lowering operation voltage, and improving efficiency, and lifespan, and an organic light-emitting diode including an organic light-emitting layer containing the same.

Purposes of the present disclosure are not limited to the above-mentioned purpose. Other purposes and advantages of the present disclosure that are not mentioned can be understood based on following descriptions, and can be more clearly understood based on embodiments of the present disclosure. Further, it will be easily understood that the purposes and advantages of the present disclosure can be realized using means shown in the claims and combinations thereof.

In one aspect, the present disclosure provides an organometallic compound having a novel structure represented by a following Chemical Formula I, and an organic light-emitting diode in which a phosphorescent light-emitting layer contains the same as dopants thereof:

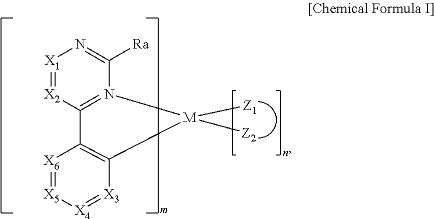

wherein in the Chemical Formula I,
M represents a metal, which is one of Mo, W, Re, Ru, Os, Rh, Ir, Pd, Pt and Au;
Rₐ represents one of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;
each of X₁ and X₂ represents carbon;
each of X₃ to X₆ independently represents one selected from CR_{b} and N;
optionally, two R_{b} on the adjacent two of X₃ to X₆ can be connected to each other to form a ring structure including one selected from a group consisting of a substituted or unsubstituted C3-C20 cycloalkyl group, a substituted or unsubstituted C2-C20 heterocycloalkyl group, a substituted or unsubstituted C7-C20 arylalkyl group, a substituted or unsubstituted C2-C20 heteroarylalkyl group, a substituted or unsubstituted C3-C20 cycloalkenyl group, a substituted or unsubstituted C6-C30 aryl group, and a substituted or unsubstituted C3-C30 heteroaryl group,
R_{b} represents one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;
(Z₁-Z₂) represents a bidentate ligand;
m is an integer selected from 1, 2 or 3, n is an integer selected from 0, 1 or 2, and a sum of m and n is an oxidation number of the metal M;
R represents a fused ring connected to X₁ and X₂, and include one selected from a group consisting of following Chemical Formula II to Chemical Formula IV:

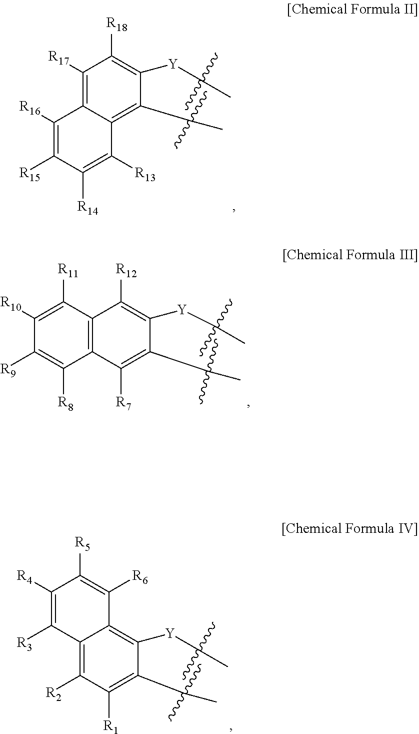

wherein in the Chemical Formula II to Chemical Formula IV,
Y represents one selected from a group consisting of BR₁₉, CR₁₉R₂₀, C═O, CNR₁₉, SiR₁₉R₂₀, NR₁₉, PR₁₉, AsR₁₉, SbR₁₉, P(O)R₁₉, P(S)R₁₉, P(Se)R₁₉, As(O)R₁₉, As(S)R₁₉, As(Se)R₁₉, Sb(O)R₁₉, Sb(S)R₁₉, Sb(Se)R₁₉, O, S, N, Se, Te, SO, SO₂, SeO, SeO₂, TeO, and TeO₂;
each of R₁ to R₁₈ independently represents one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;
each of R₁₉ and R₂₀ independently represents one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group.

The organometallic compound according to the present disclosure can be used as the dopant of the light-emitting layer of the organic light-emitting diode, such that the operation voltage of the organic light-emitting diode can be lowered, and the efficiency and lifespan characteristics of the organic light-emitting diode can be improved.

Effects of the present disclosure are not limited to the above-mentioned effects, and other effects as not mentioned will be clearly understood by those skilled in the art from following descriptions.

### BRIEF DESCRIPTION OF DRAWINGS

FIG. 1 is a cross-sectional view schematically showing an organic light-emitting diode in which a light-emitting layer contains an organometallic compound according to an embodiment of the present disclosure.

FIG. 2 is a cross-sectional view schematically illustrating an organic light-emitting diode having a tandem structure having two light-emitting stacks and containing an organometallic compound represented by the Chemical Formula I according to an embodiment of the present disclosure.

FIG. 3 is a cross-sectional view schematically illustrating an organic light-emitting diode having a tandem structure having three light-emitting stacks and containing an organometallic compound represented by the Chemical Formula I according to an embodiment of the present disclosure.

FIG. 4 is a cross-sectional view schematically illustrating an organic light-emitting display device including an organic light-emitting diode according to an embodiment of the present disclosure.

### DETAILED DESCRIPTIONS OF THE EMBODIMENTS

Advantages and features of the present disclosure, and a method of achieving the advantages and features will become apparent with reference to embodiments described later in detail together with the accompanying drawings. However, the present disclosure is not limited to the embodiments as disclosed below, and can be implemented in various different forms and variations. Thus, these embodiments are set forth only to make the present disclosure complete, and to completely inform the scope of the present disclosure to those of ordinary skill in the technical field to which the present disclosure belongs. All the components of each OLED and each organic light emitting display device according to all embodiments of the present disclosure are operatively coupled and configured.

A shape, a size, a ratio, an angle, a number, etc. disclosed in the drawings for describing the embodiments of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “include”, “comprising”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements can modify the entire list of elements and do not modify the individual elements of the list. In interpretation of numerical values, an error or tolerance therein can occur even when there is no explicit description thereof.

In addition, it will also be understood that when a first element or layer is referred to as being present “on” a second element or layer, the first element can be disposed directly on the second element or can be disposed indirectly on the second element with a third element or layer being disposed between the first and second elements or layers. It will be understood that when an element or layer is referred to as being “connected to”, or “coupled to” another element or layer, it can be directly on, connected to, or coupled to the other element or layer, or one or more intervening elements or layers can be present. In addition, it will also be understood that when an element or layer is referred to as being “between” two elements or layers, it can be the only element or layer between the two elements or layers, or one or more intervening elements or layers can also be present.

Further, as used herein, when a layer, film, region, plate, or the like is disposed “on” or “on a top” of another layer, film, region, plate, or the like, the former can directly contact the latter or still another layer, film, region, plate, or the like can be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former can directly contact the latter or still another layer, film, region, plate, or the like can be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event can occur therebetween unless “directly after”, “directly subsequent” or “directly before” is not indicated.

It will be understood that, although the terms “first”, “second”, “third”, and so on can be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various embodiments of the present disclosure can be partially or entirely combined with each other, and can be technically associated with each other or operate with each other. The embodiments can be implemented independently of each other and can be implemented together in an association relationship.

In interpreting a numerical value, the value is interpreted as including an error range unless there is no separate explicit description thereof.

It will be understood that when an element or layer is referred to as being “connected to”, or “coupled to” another element or layer, it can be directly on, connected to, or coupled to the other element or layer, or one or more intervening elements or layers can be present. In addition, it will also be understood that when an element or layer is referred to as being “between” two elements or layers, it can be the only element or layer between the two elements or layers, or one or more intervening elements or layers can also be present.

The features of the various embodiments of the present disclosure can be partially or entirely combined with each other, and can be technically associated with each other or operate with each other. The embodiments can be implemented independently of each other and can be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, a phrase “adjacent substituents are connected to each other to form a ring (or a ring structure)” means that adjacent substituents can bind to each other to form a substituted or unsubstituted alicyclic or aromatic ring. A phrase “adjacent substituent” to a certain substituent can mean a substituent replacing an atom directly connected to an atom which the certain substituent replaces, a substituent that is sterically closest to the certain substituent, or a substituent replacing an atom replaced with the certain substituent. For example, two substituents replacing an ortho position in a benzene ring structure and two substituents replacing the same carbon in an aliphatic ring can be interpreted as “adjacent substituents.”

Hereinafter, a structure and a preparation example of an organometallic compound according to the present disclosure and an organic light emitting diode including the same will be described.

The organometallic compound according to an embodiment of the present disclosure can be represented by a following Chemical Formula I. While not being bound by theory, the inventors of the present disclosure have found that when a fused ring structure (R) is introduced as in the following Chemical Formula I, a major-axis directional length of an organometallic compound molecule is increased to improves a horizontal orientation and impart stiffness to the organometallic compound molecule. Thus, we have completed the present disclosure. When the organometallic compound represented by the following Chemical Formula I of the present disclosure is used as a dopant of a light emitting layer, a full-width at half-maximum (FWHM) can be reduced such that a color gamut can be improved, and luminous efficiency and lifespan can be improved.

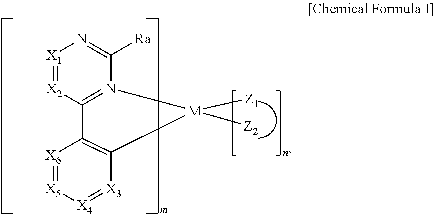

wherein in the Chemical Formula I, M represents one selected from a group consisting of Mo, W, Re, Ru, Os, Rh, Ir, Pd, Pt and Au;
Rₐ represents one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;
each of X₁ and X₂ represents carbon;
each of X₃ to X₆ independently represents one selected from CR_{b} and N;
optionally, two R_{b} on the adjacent two of X₃ to can be connected to each other to form a ring structure including one selected from a group consisting of a substituted or unsubstituted C3-C20 cycloalkyl group, a substituted or unsubstituted C2-C20 heterocycloalkyl group, a substituted or unsubstituted C7-C20 arylalkyl group, a substituted or unsubstituted C2-C20 heteroarylalkyl group, a substituted or unsubstituted C3-C20 cycloalkenyl group, a substituted or unsubstituted C6-C30 aryl group, and a substituted or unsubstituted C3-C30 heteroaryl group,
R_{b} represents one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;
(Z₁-Z₂) represents a bidentate ligand;
m is an integer selected from 1, 2 or 3, n is an integer selected from 0, 1 or 2, and a sum of m and n is an oxidation number of the metal M;
R represents a fused ring connected to X₁ and X₂, and include one selected from a group consisting of following Chemical Formula II to Chemical Formula IV:

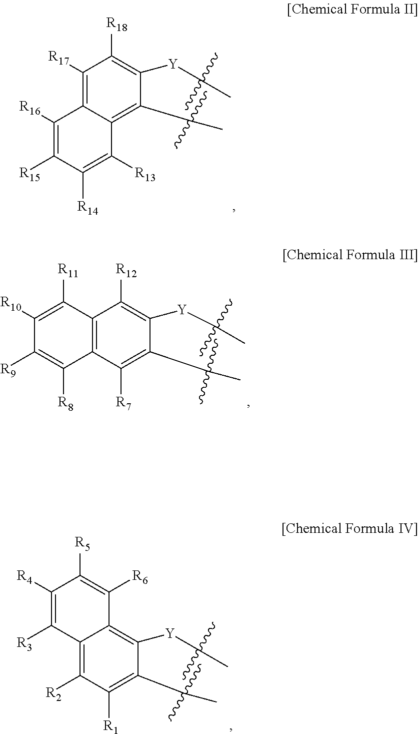

wherein in the Chemical Formula II to Chemical Formula IV,
Y represents one selected from a group consisting of BR₁₉, CR₁₉R₂₀, C═O, CNR₁₉, SiR₁₉R₂₀, NR₁₉, PR₁₉, AsR₁₉, SbR₁₉, P(O)R₁₉, P(S)R₁₉, P(Se)R₁₉, As(O)R₁₉, As(S)R₁₉, As(Se)R₁₉, Sb(O)R₁₉, Sb(S)R₁₉, Sb(Se)R₁₉, O, S, N, Se, Te, SO, SO₂, SeO, SeO₂, TeO, and TeO₂;
each of R₁ to R₁₈ independently represents one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group; and
each of R₁₉ and R₂₀ independently represents one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group.

When a metal complex of iridium (Ir) or platinum (Pt) with a large atomic number is used, phosphorescence can be efficiently obtained even at room temperature. Thus, in the organometallic compound according to an implementation of the present disclosure, a central coordination metal (M) is preferably one of iridium (Ir) or platinum (Pt), for example, more preferably, iridium (Ir). However, the present disclosure is not limited thereto.

The Chemical Formula I representing the organometallic compound according to an implementation of the present disclosure can be one selected from a group consisting of following Chemical Formulas II-1, II-2, III-1, III-2, IV-1, and IV-2, based on a type of R (Chemical Formulas II to IV) and an orientation of Y:

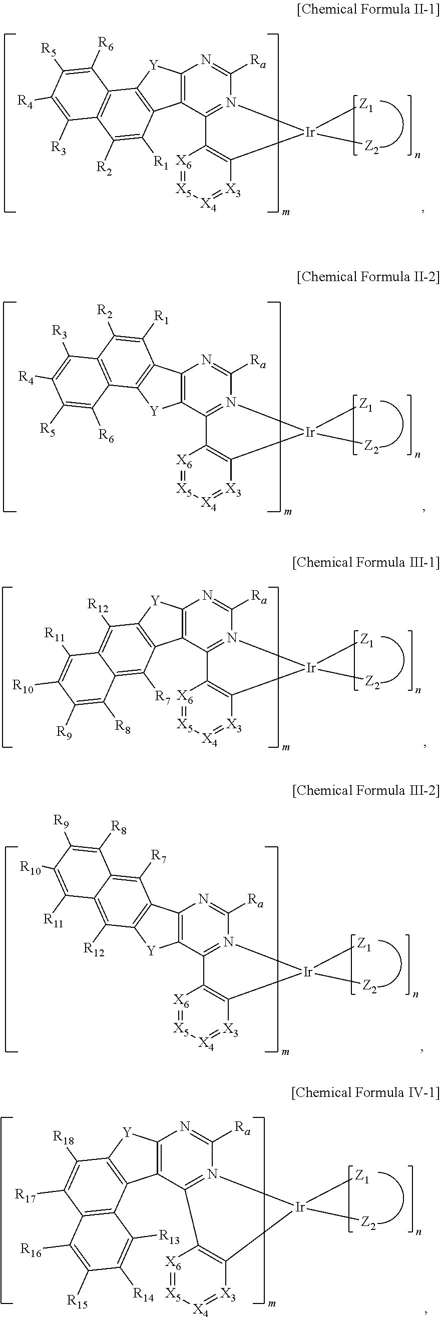

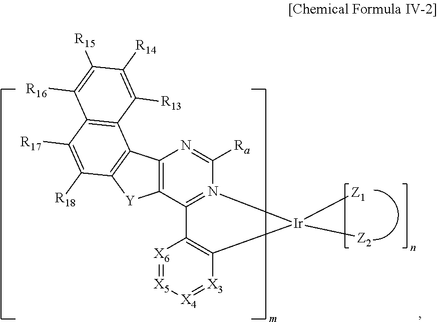

wherein in each of the Chemical Formulas II-1, II-2, III-1, III-2, IV-1 and IV-2, Y, X₃ to X₆, Rₐ, R_{b}, R₁ to R₁₈, (Z₁-Z₂), m and n are the same as defined herein for Chemical Formula I.

In an embodiment, Rₐ is one selected from a group consisting of hydrogen, deuterium, halogen, a hydroxyl group, a cyano group, a nitro group, a substituted or unsubstituted C1-C8 alkyl group, a substituted or unsubstituted C1-C8 alkenyl group, a substituted or unsubstituted C6-C10 aryl group, a substituted or unsubstituted C6-C10 heteroaryl group, an alkoxy group, an amino group, a silyl group, an acyl group, a carbonyl group, a carboxylic acid group, an ester group, a nitrile group, an isonitrile group, and a phosphino group;

each of X₃ to X₆ independently is one selected from CR_{b} and N;

optionally, two R_{b} on the adjacent two of X₃ to X₆ are connected to each other to form a ring structure comprising one selected from a group consisting of a substituted or unsubstituted C3-C10 cycloalkyl group, a substituted or unsubstituted C2-C10 heterocycloalkyl group, a substituted or unsubstituted C7-C10 arylalkyl group, a substituted or unsubstituted C2-C10 heteroarylalkyl group, a substituted or unsubstituted C3-C10 cycloalkenyl group, a substituted or unsubstituted C6-C10 aryl group, and a substituted or unsubstituted C3-C10 heteroaryl group,

R_{b} represents one selected from a group consisting of hydrogen, deuterium, halogen, a hydroxyl group, a cyano group, a nitro group, an amidino group, a hydrazine group, a hydrazone group, a substituted or unsubstituted C1-C8 alkyl group, a substituted or unsubstituted C3-C12 cycloalkyl group, a substituted or unsubstituted C1-C12 heteroalkyl group, a substituted or unsubstituted C7-C12 arylalkyl group, a substituted or unsubstituted C1-C12 alkenyl group, a substituted or unsubstituted C3-C12 cycloalkenyl group, a substituted or unsubstituted C1-C12 heteroalkenyl group, an alkynyl group, a substituted or unsubstituted C6-C12 aryl group, a substituted or unsubstituted C3-C12 heteroaryl group, an alkoxy group, an amino group, a silyl group, an acyl group, a carbonyl group, a carboxylic acid group, an ester group, a nitrile group, an isonitrile group, a sulfonyl group, and a phosphino group;

(Z₁-Z₂) represents a bidentate ligand;

m is an integer selected from 1, 2 or 3, n is an integer selected from 0, 1 or 2, wherein a sum of m and n is an oxidation number of the metal M;
Y is one selected from a group consisting of CR₁₉R₂₀, NR₁₉, O, S, SO, and SO₂;
each of R₁ to R₁₈ is independently one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group; and
each of R₁₉ and R₂₀ is independently one selected from a group consisting of hydrogen, deuterium, a hydroxyl group, a cyano group, a substituted or unsubstituted C1-C12 alkyl group, a substituted or unsubstituted C3-C12 cycloalkyl group, a substituted or unsubstituted C1-C12 heteroalkyl group, a substituted or unsubstituted C1-C12 alkenyl group, a substituted or unsubstituted C3-C12 cycloalkenyl group, a substituted or unsubstituted C1-C12 heteroalkenyl group, a substituted or unsubstituted C6-C12 aryl group, and a substituted or unsubstituted C3-C12 heteroaryl group.

In the organometallic compound according to an implementation of the present disclosure, an ancillary ligand bound to the central coordination metal can be the bidentate ligand. The bidentate ligand can contain an electron donor, thereby increasing an amount of MLCT (metal to ligand charge transfer), thereby allowing the organic light-emitting diode to exhibit improved luminous properties such as high luminous efficiency and high external quantum efficiency.

The organometallic compound according to an implementation of the present disclosure can have a heteroleptic or homoleptic structure. For example, the organometallic compound according to an embodiment of the present disclosure can have a heteroleptic structure in which in the Chemical Formula I, m is 1 and n is 2; or a heteroleptic structure where m is 2 and n is 1; or a homoleptic structure where m is 3 and n is 0.

A specific example of the compound represented by the Chemical Formula I of the present disclosure can include one selected from a group consisting of following compounds 1 to 543. However, the specific example of the compound represented by the Chemical Formula I of the present disclosure is not limited thereto as long as it meets the above definition of the Chemical Formula I:

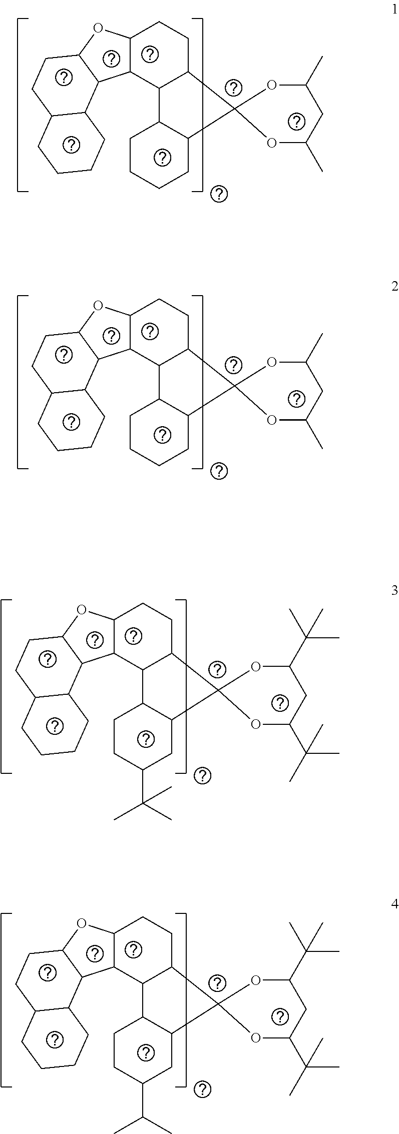

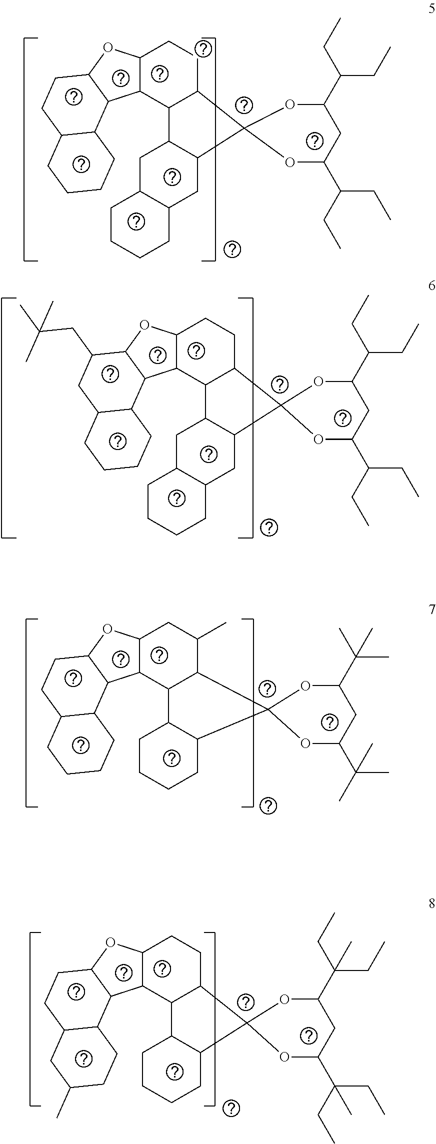

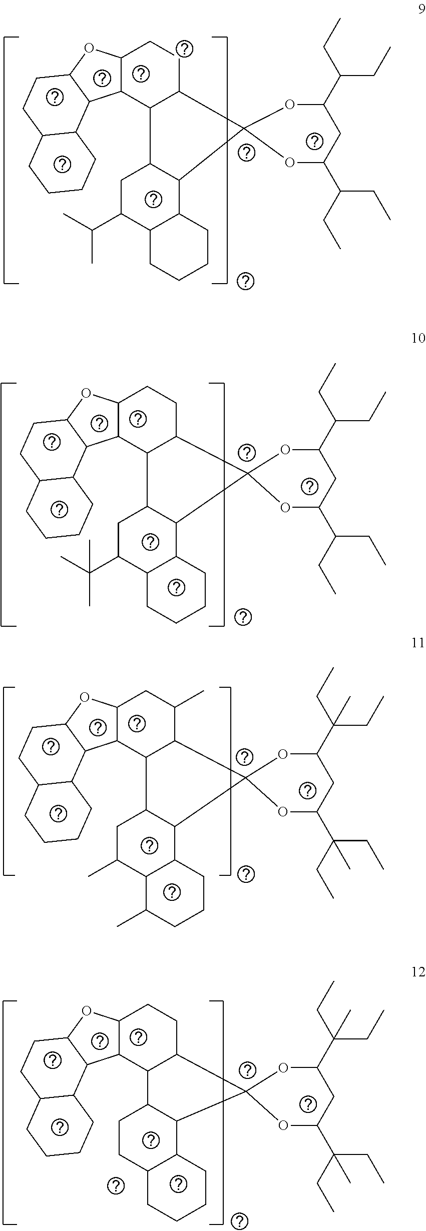

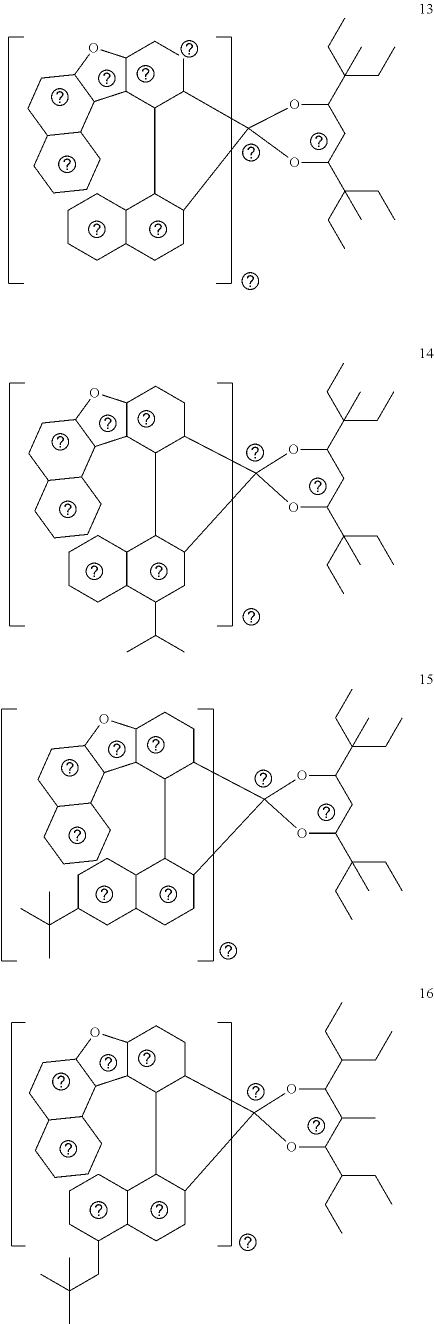

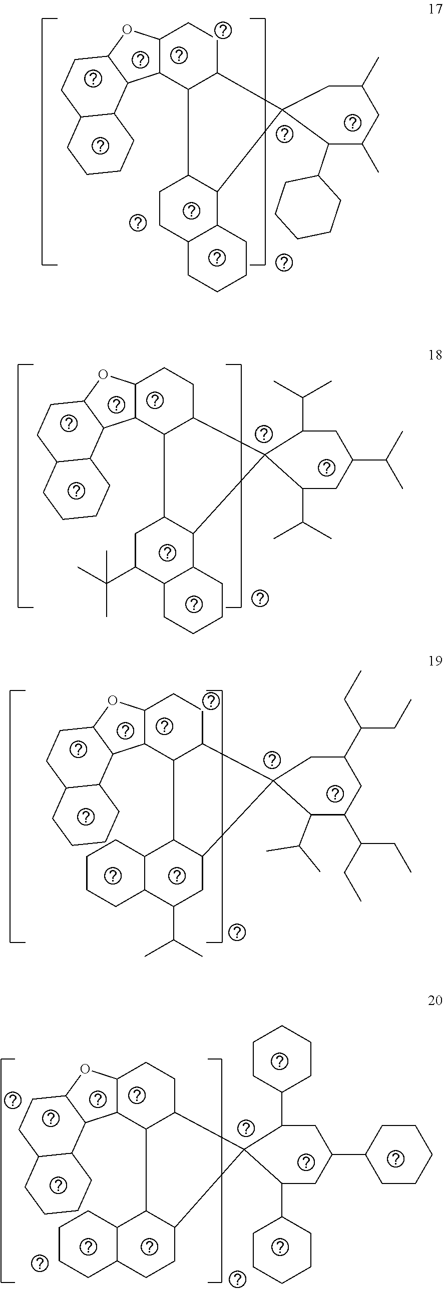

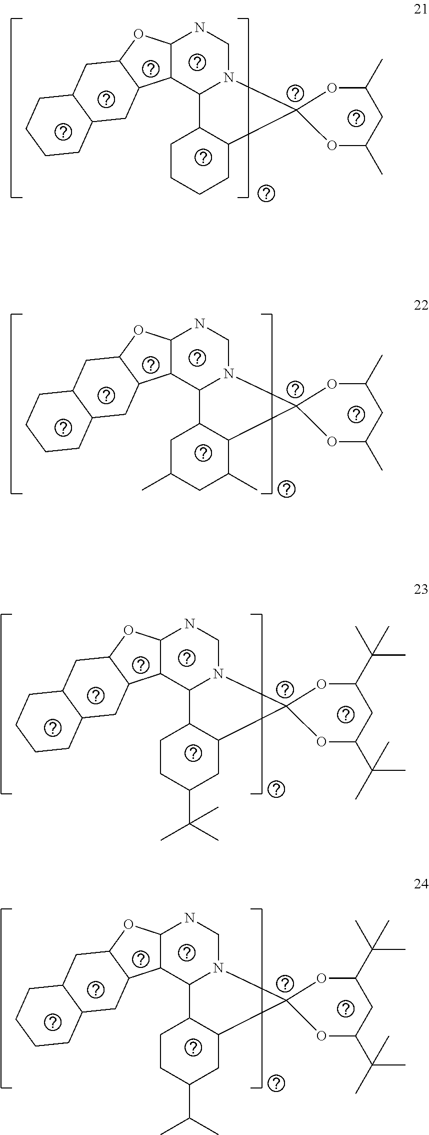

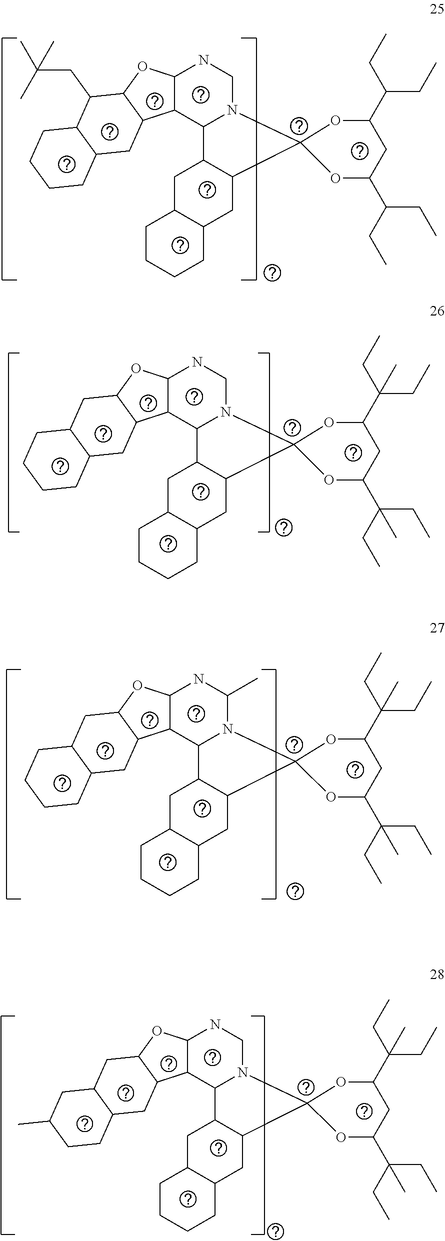

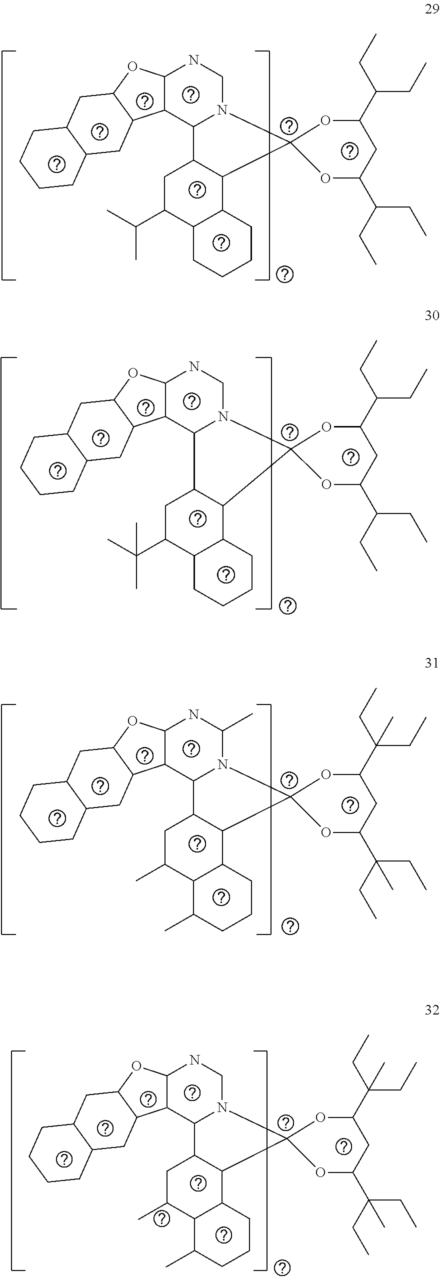

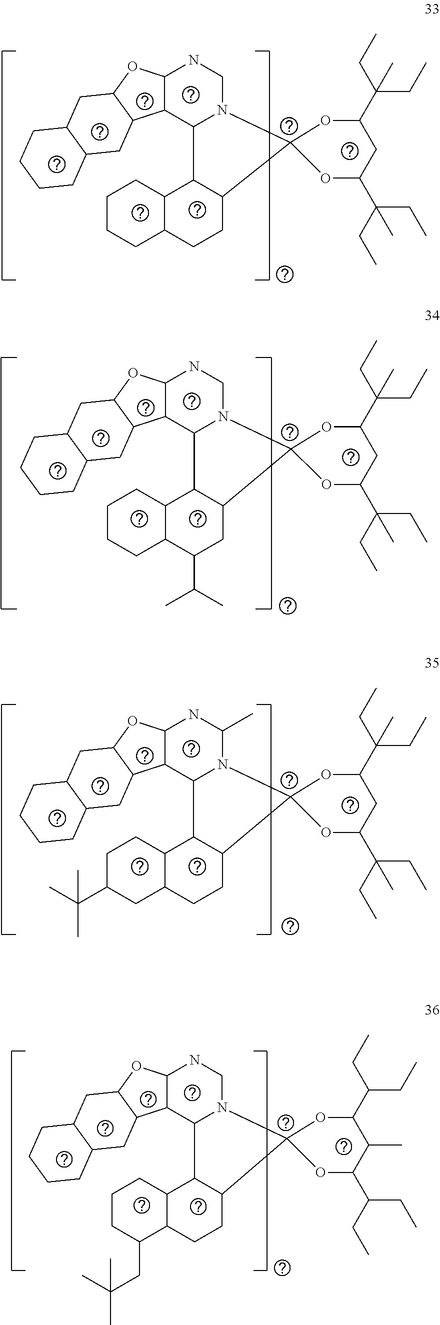

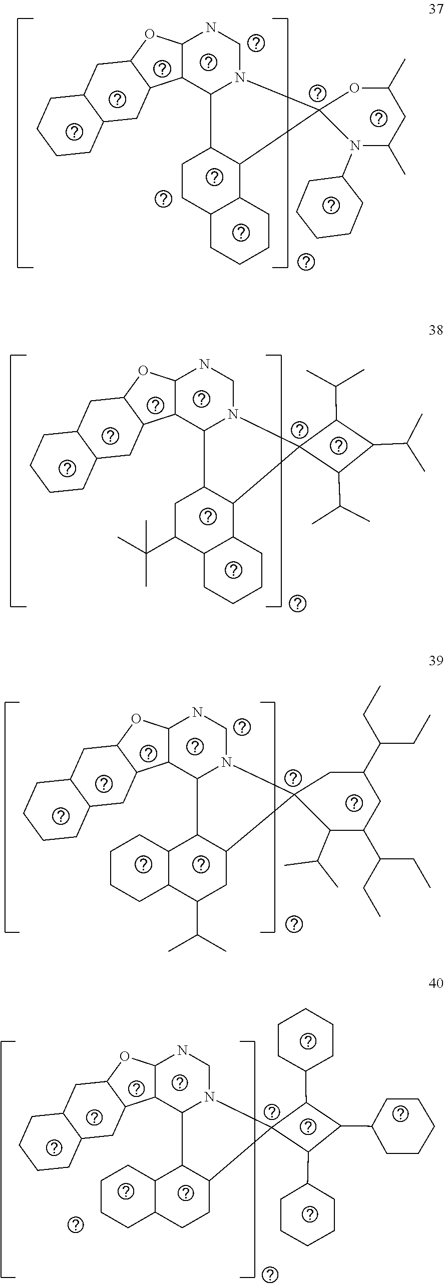

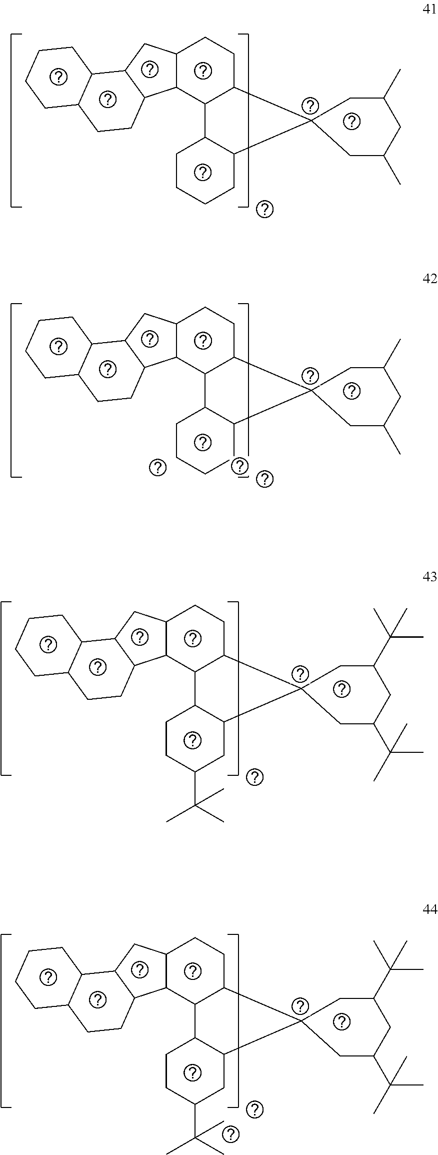

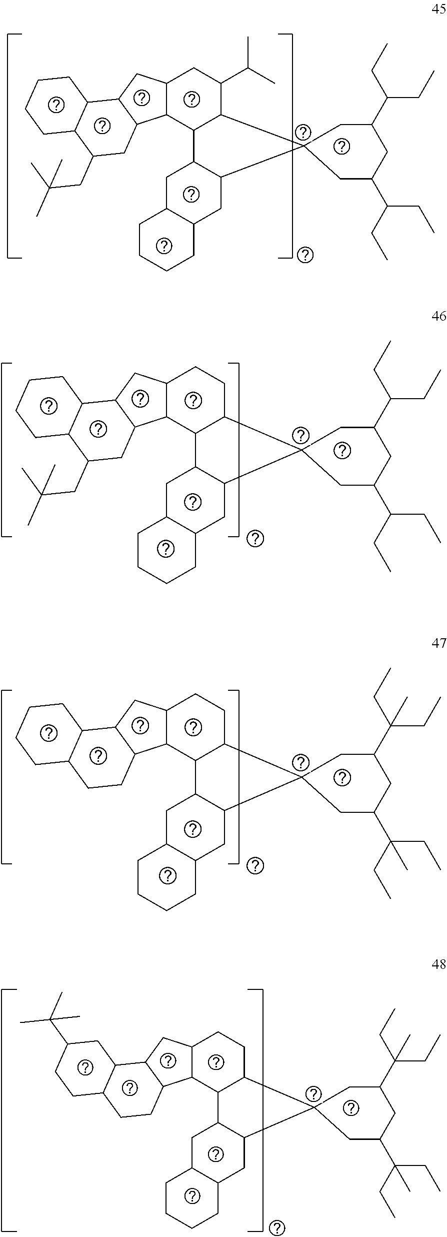

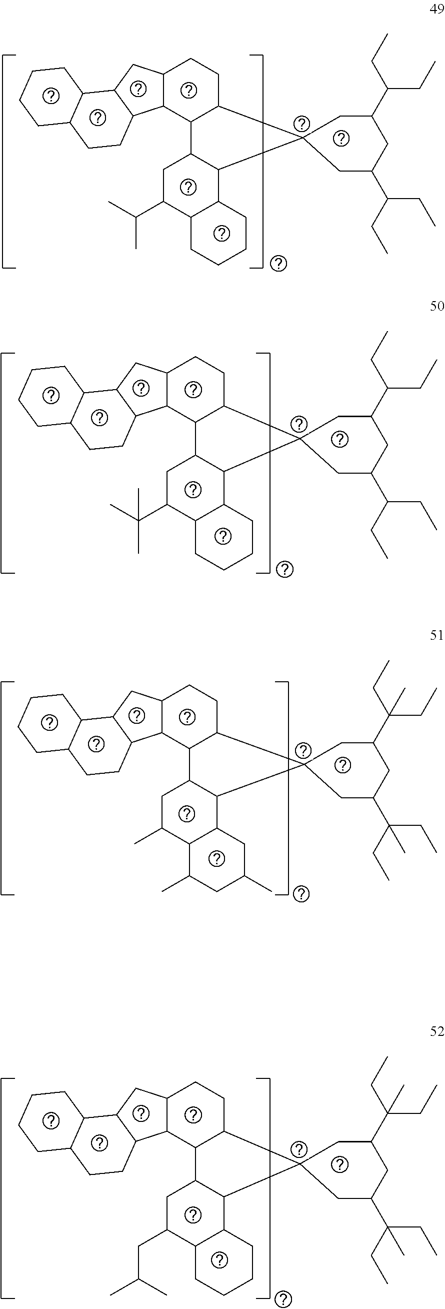

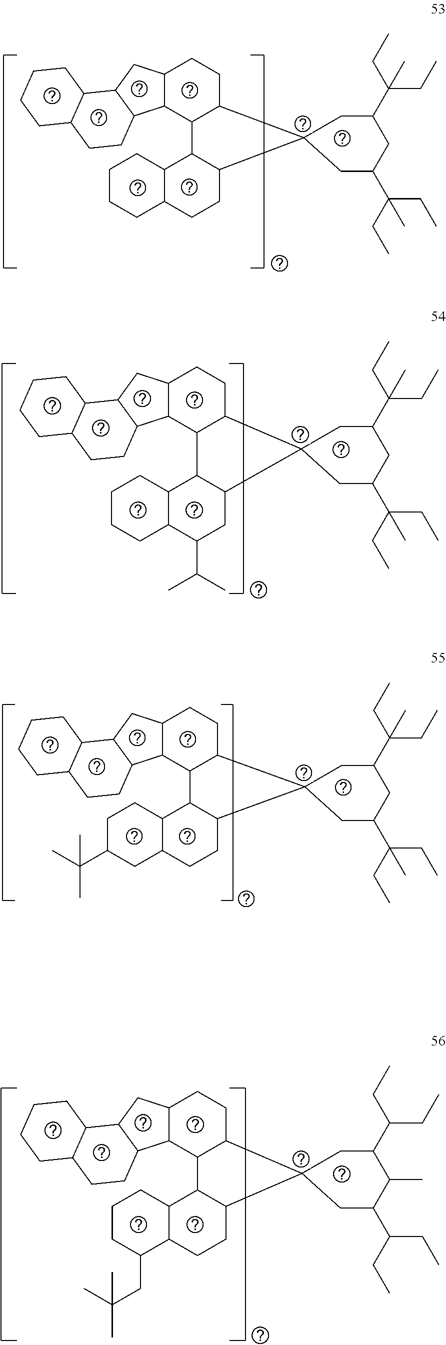

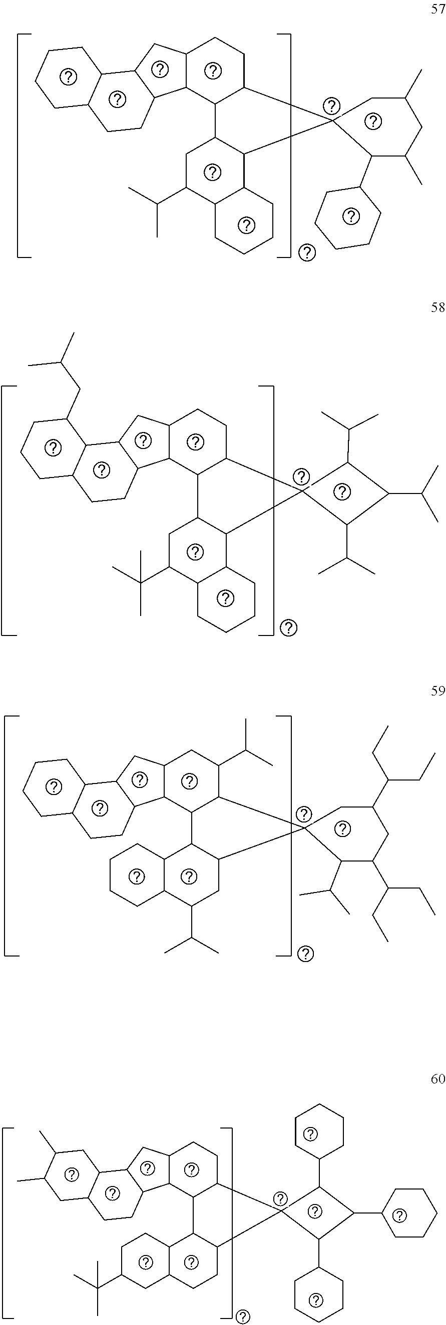

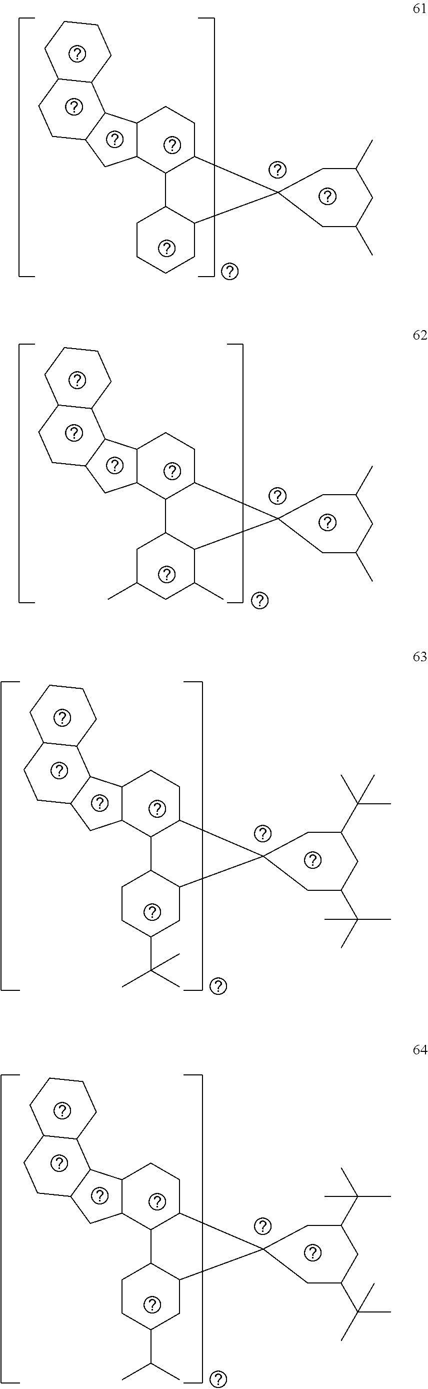

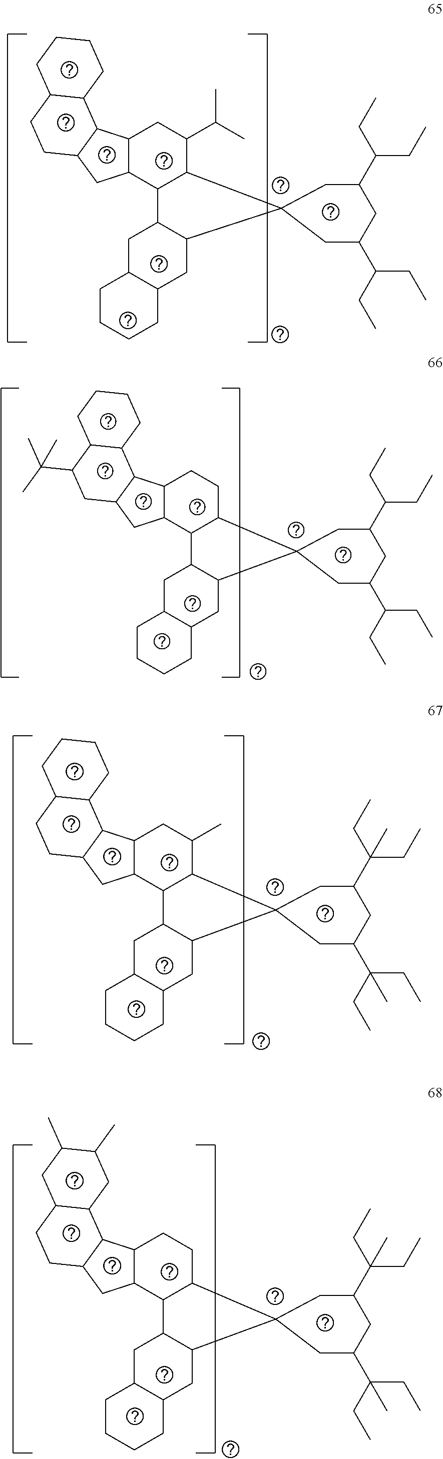

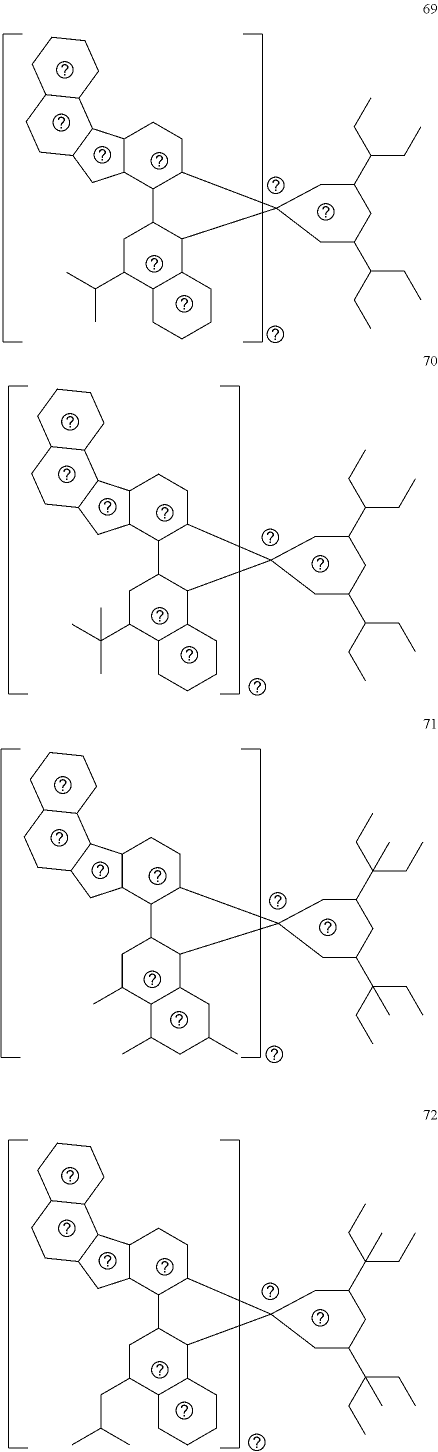

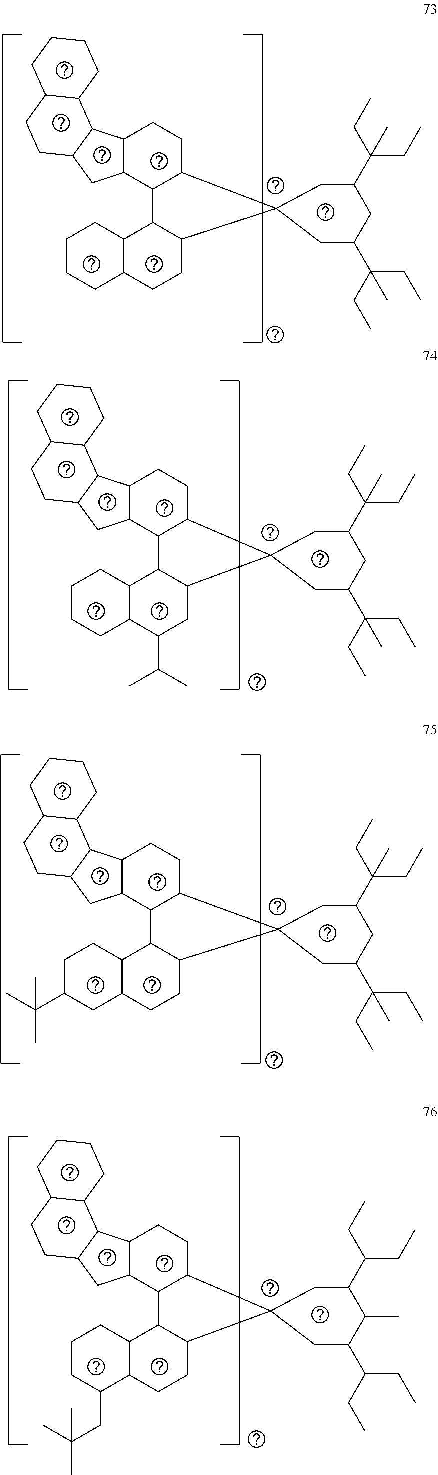

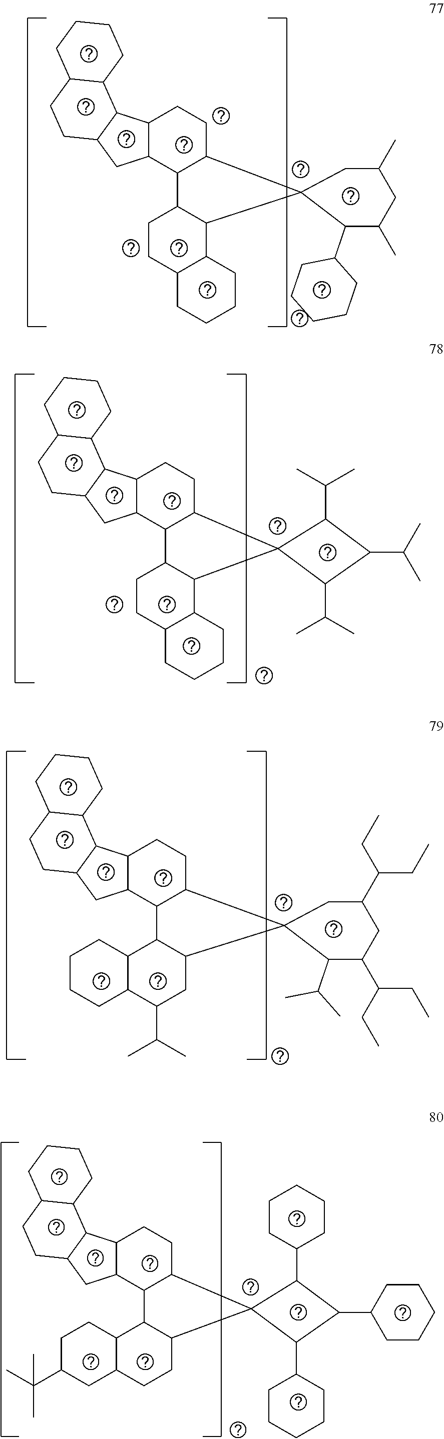

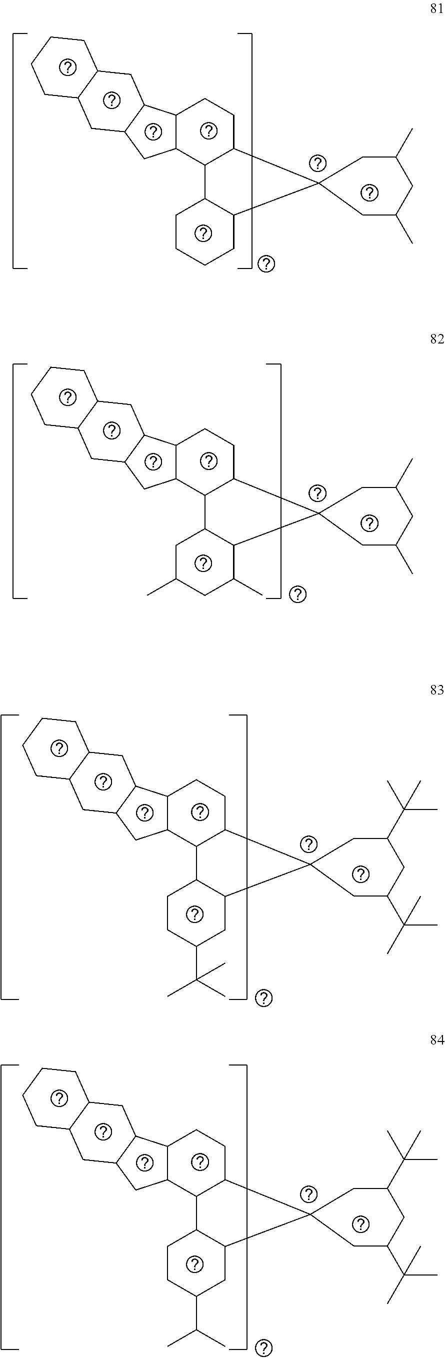

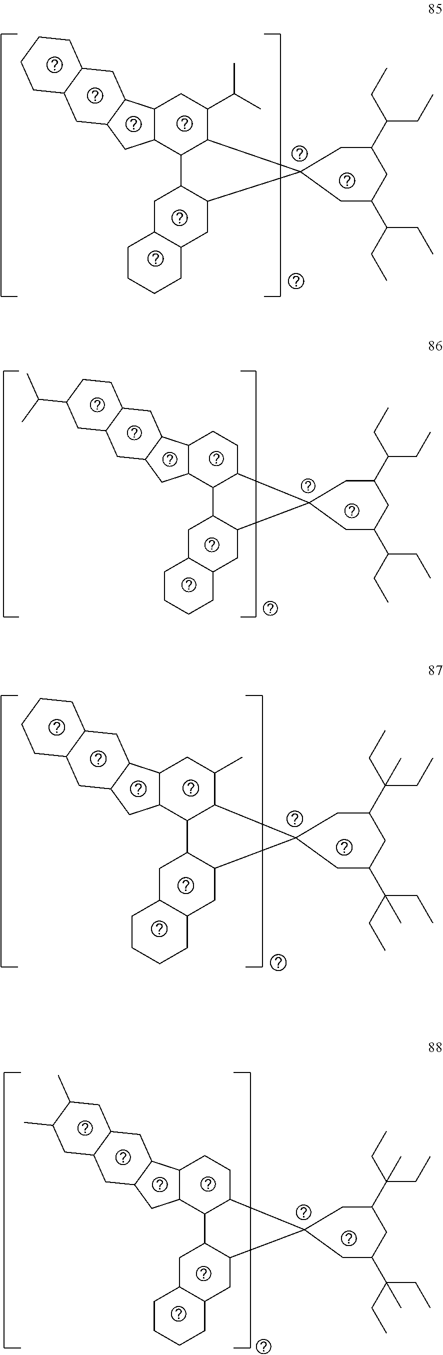

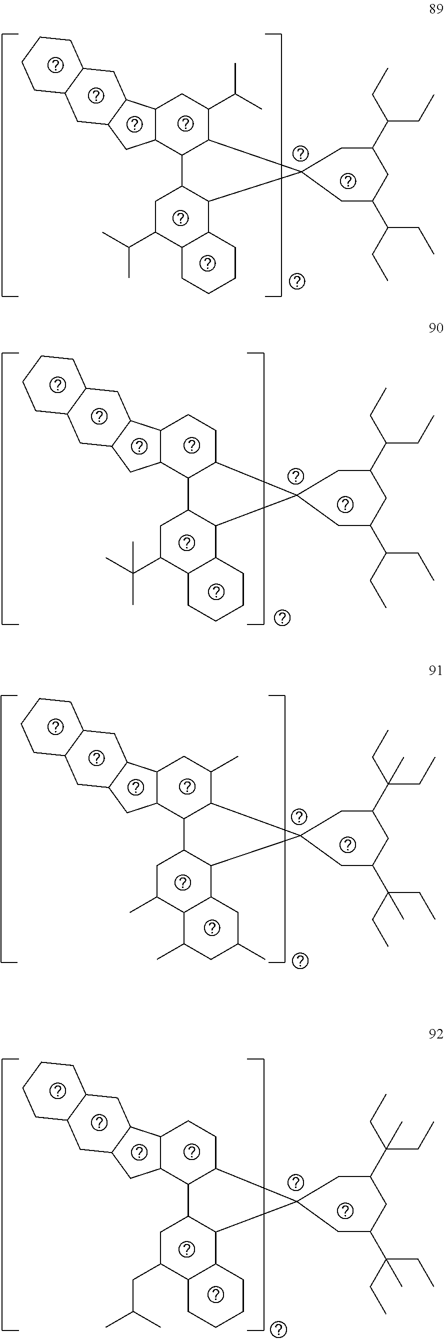

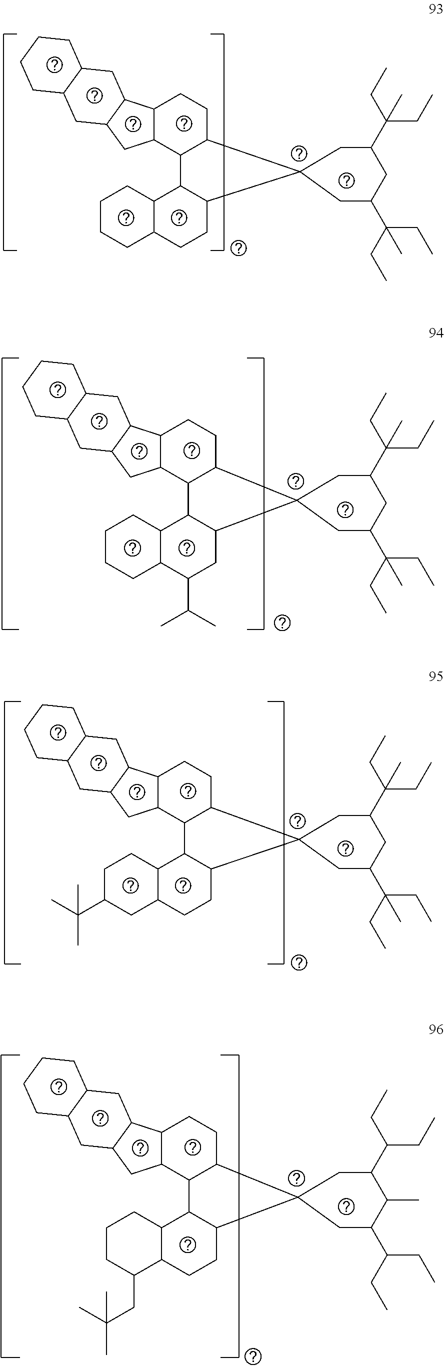

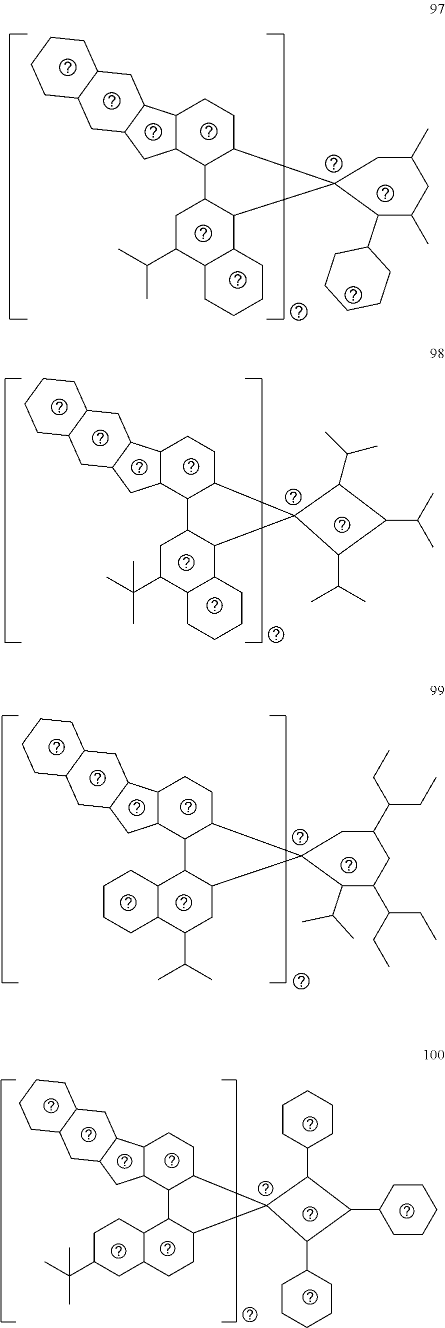

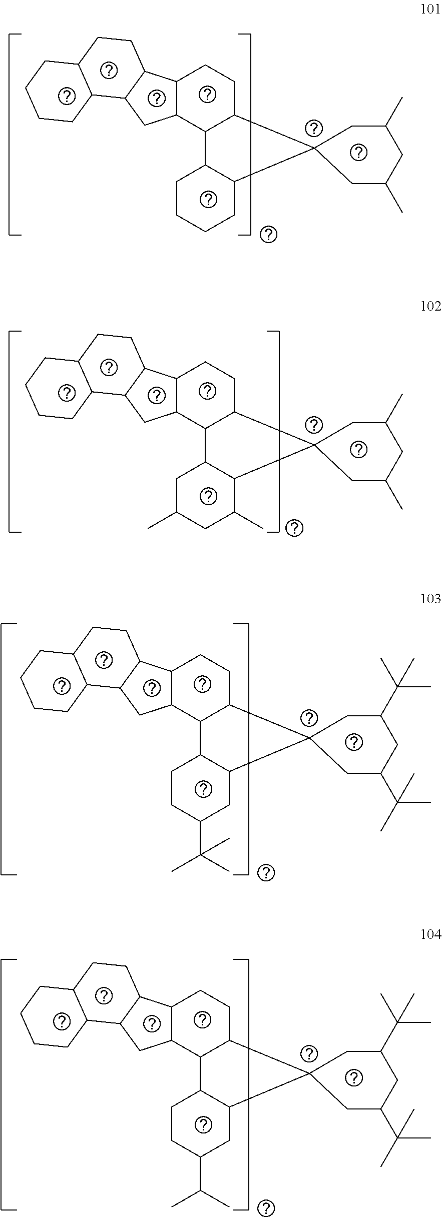

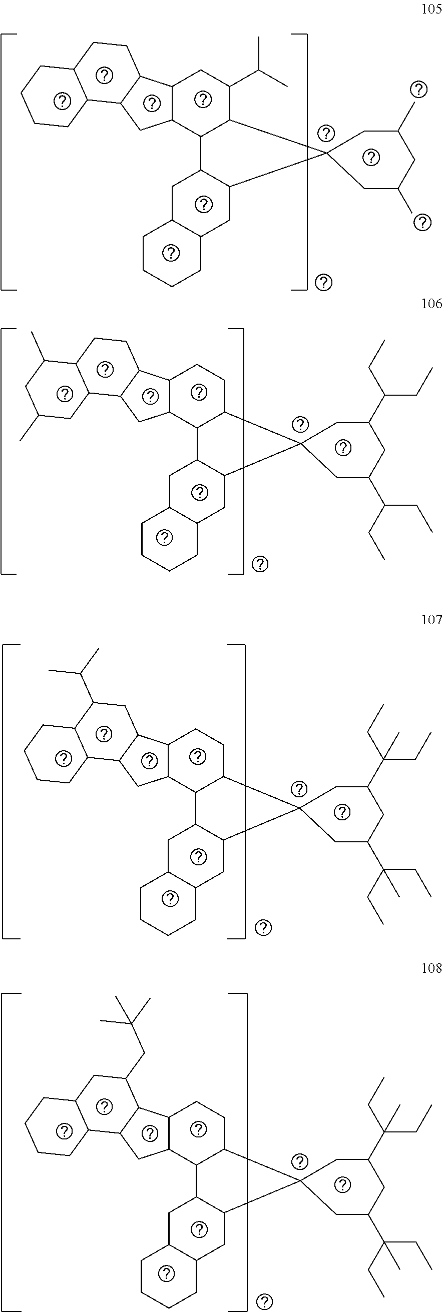

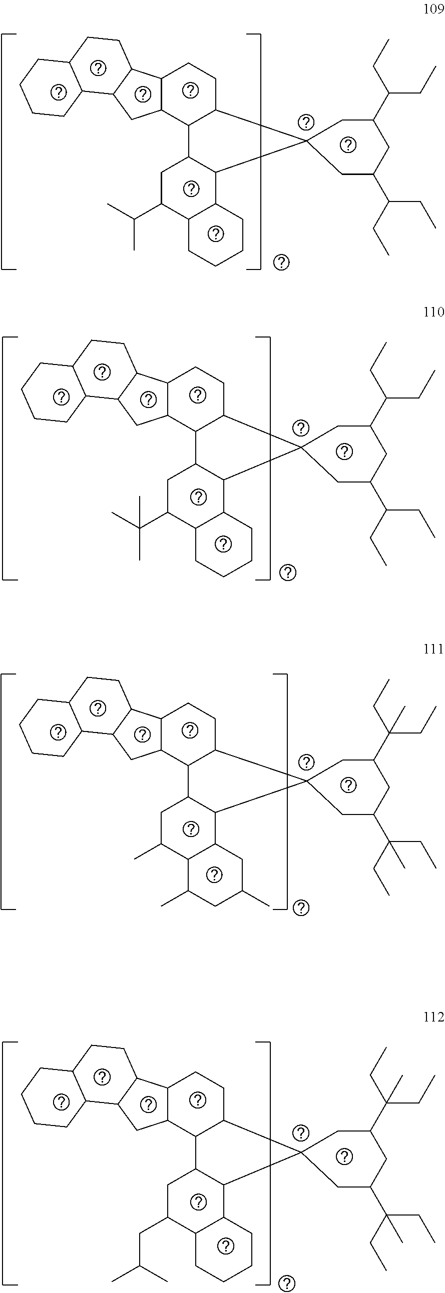

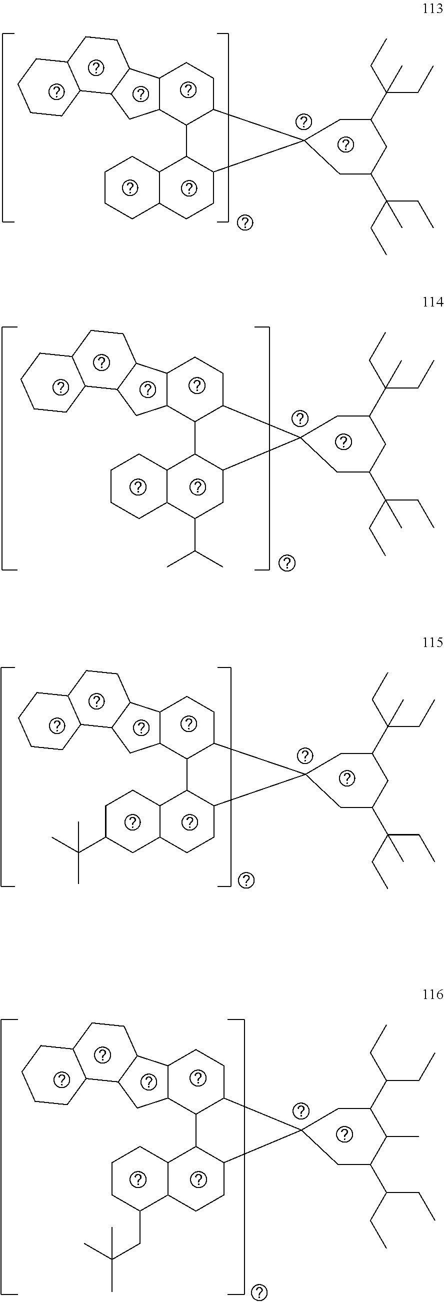

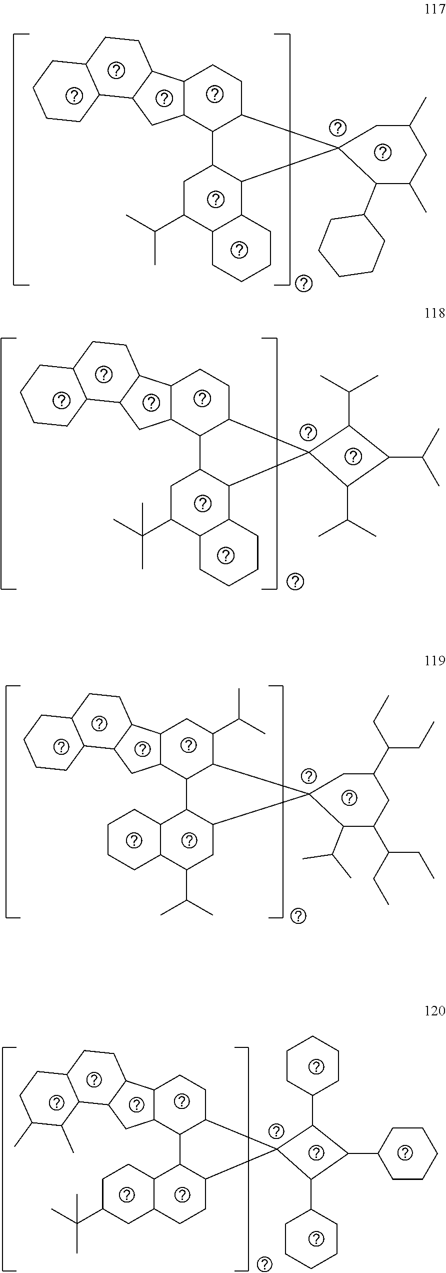

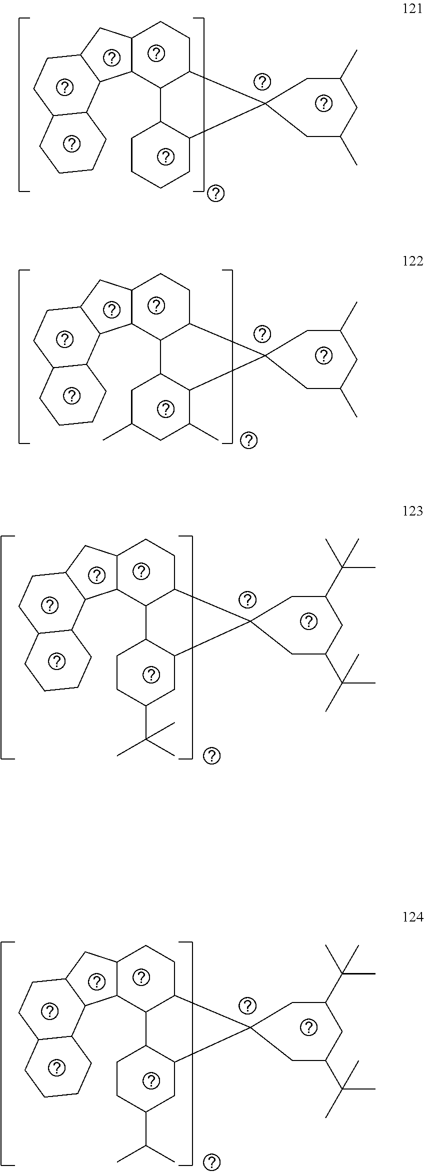

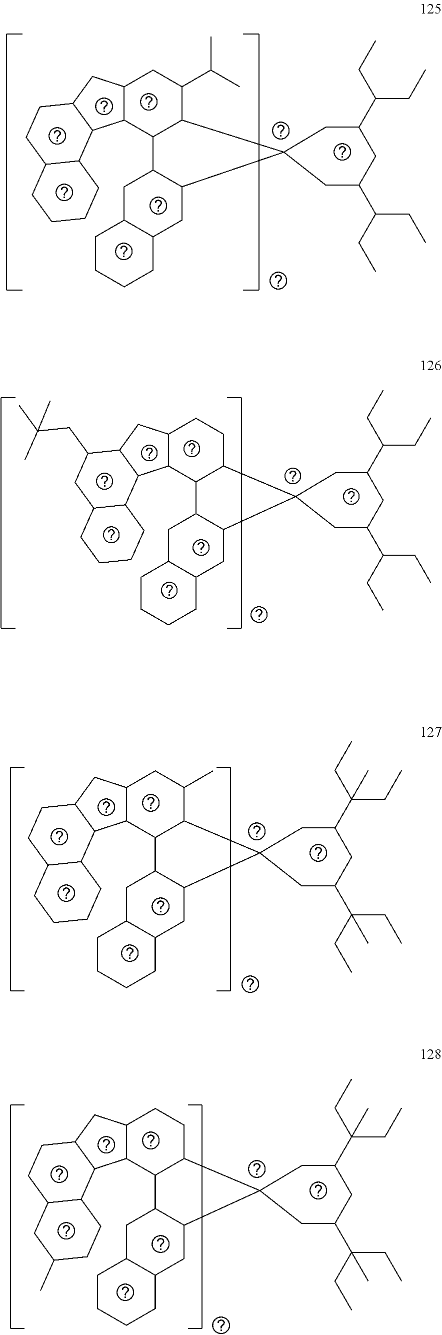

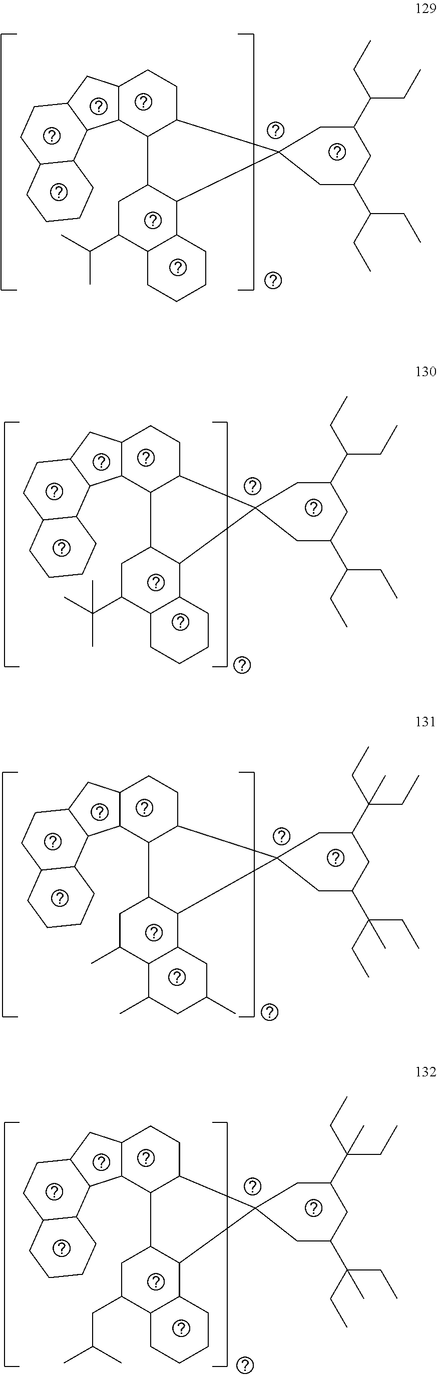

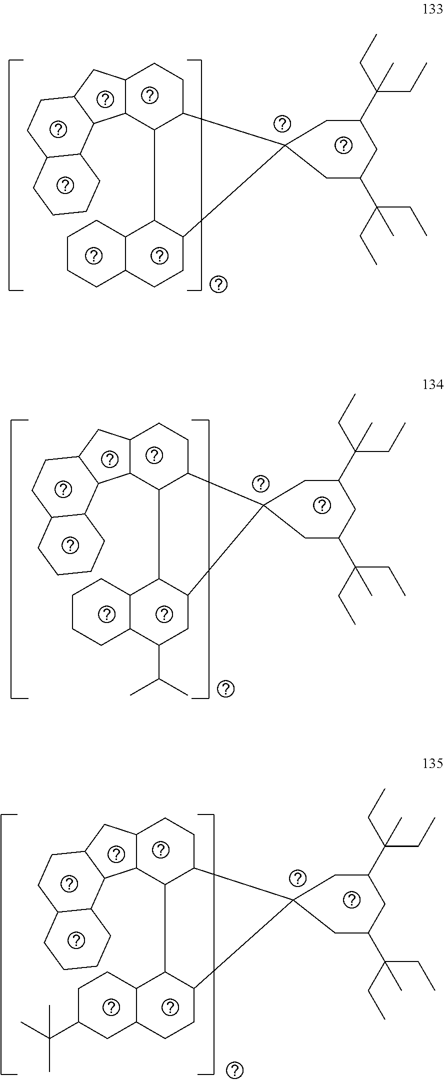

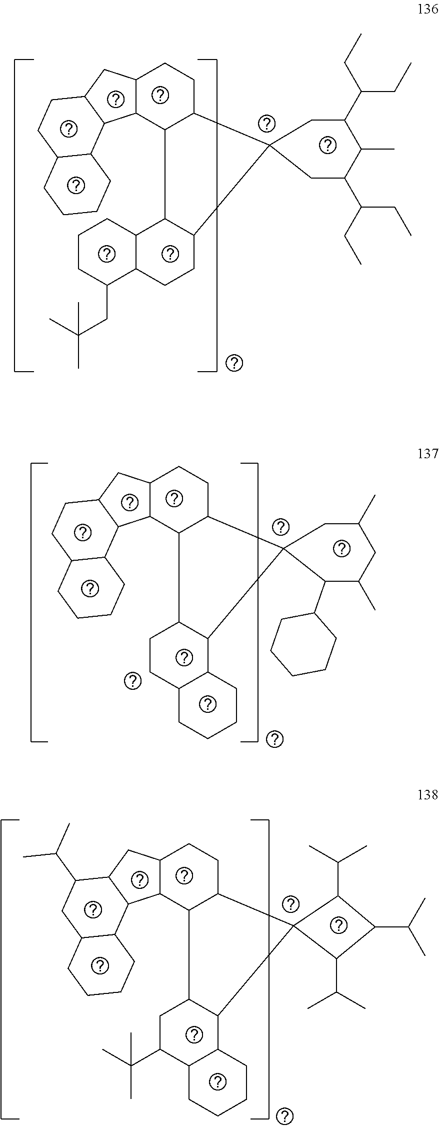

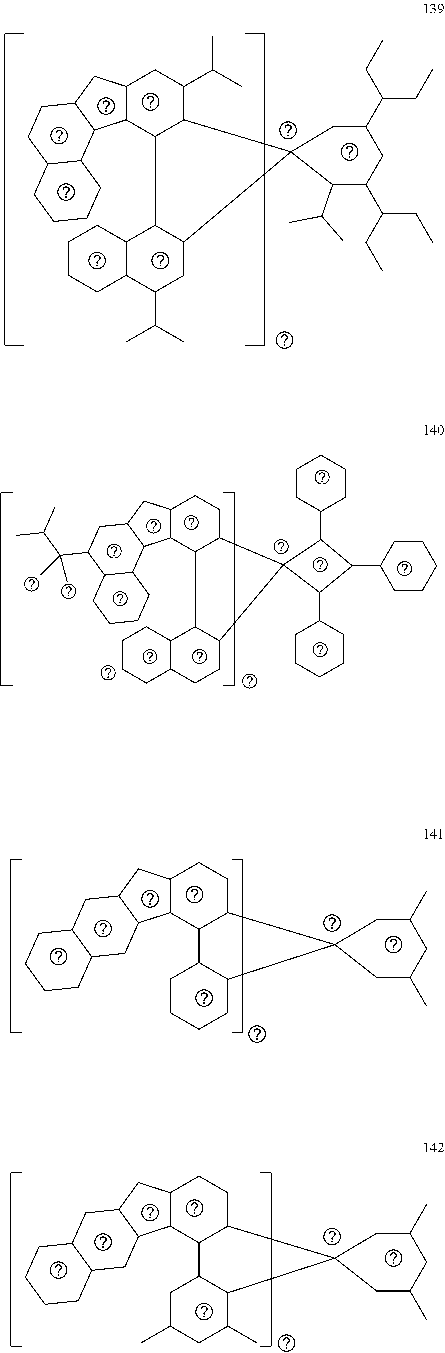

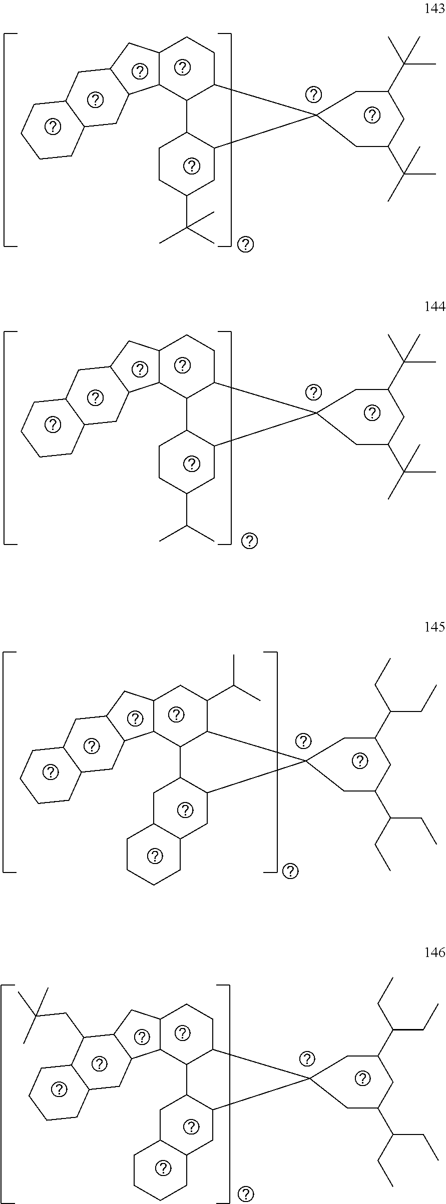

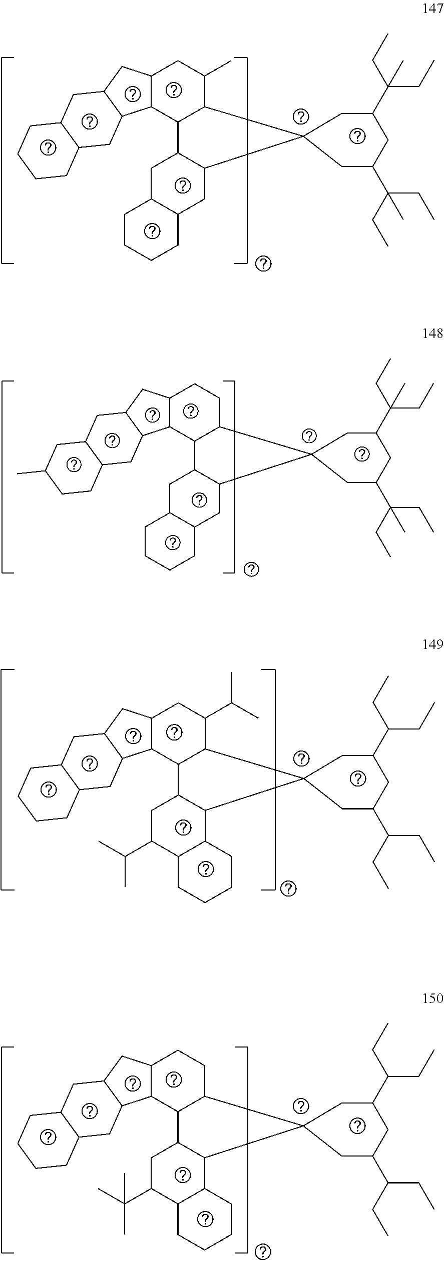

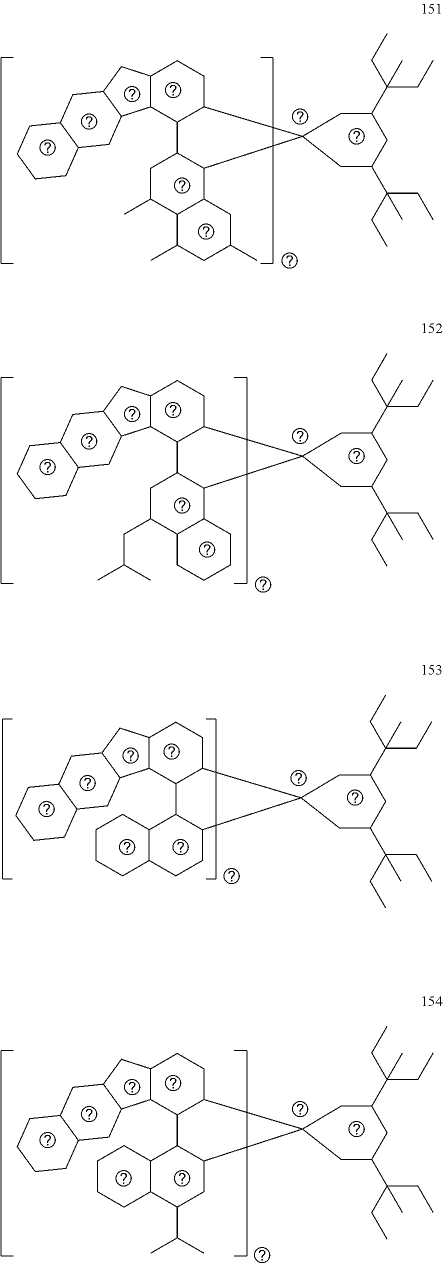

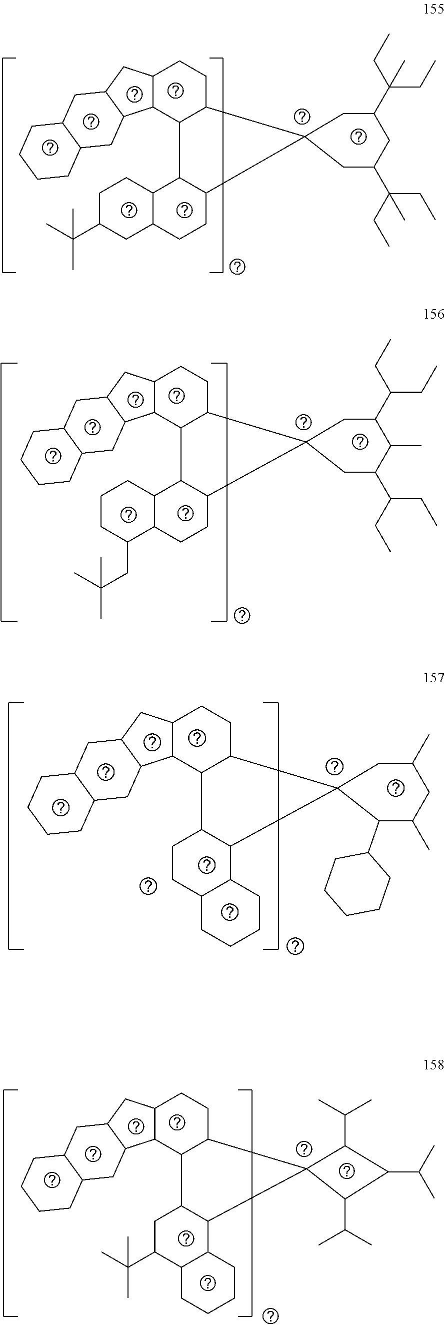

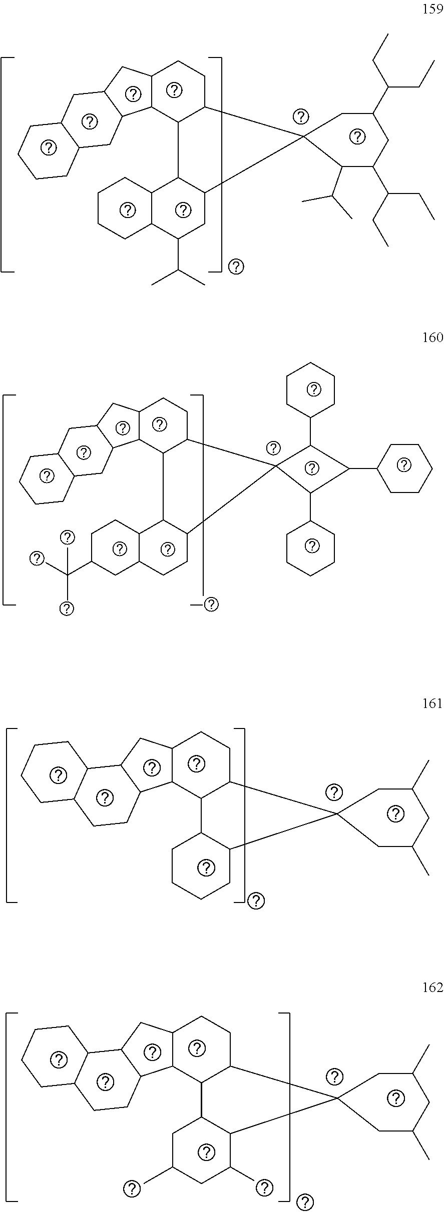

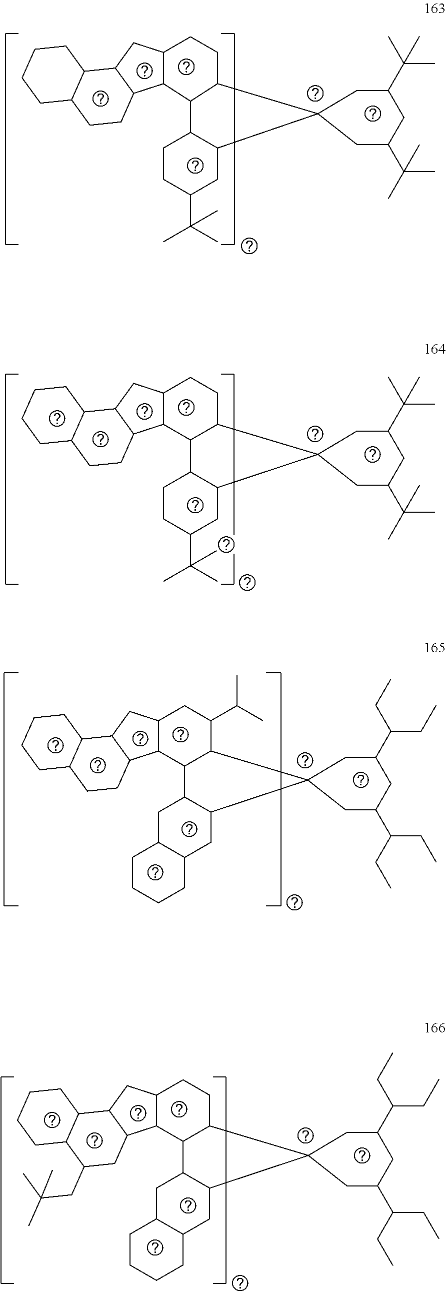

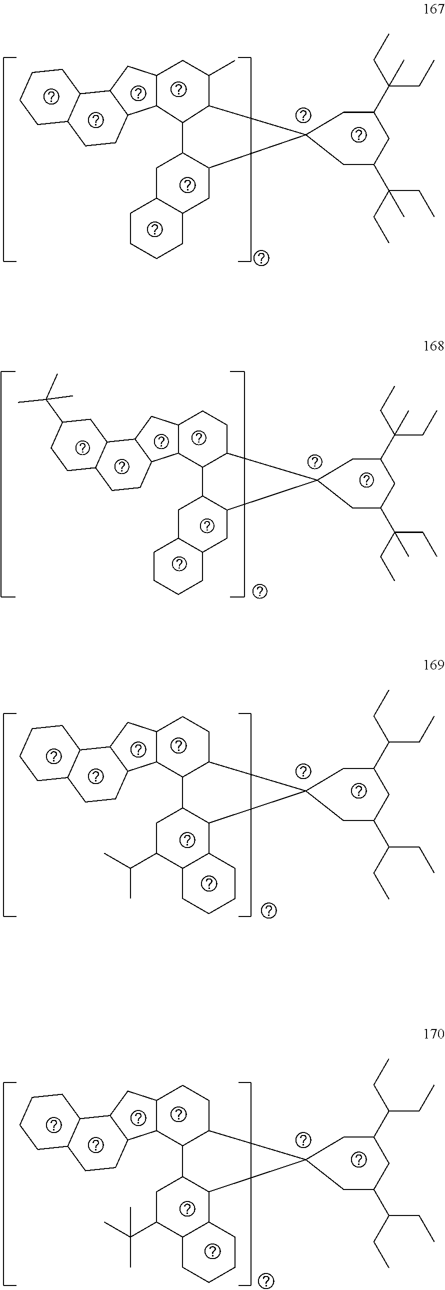

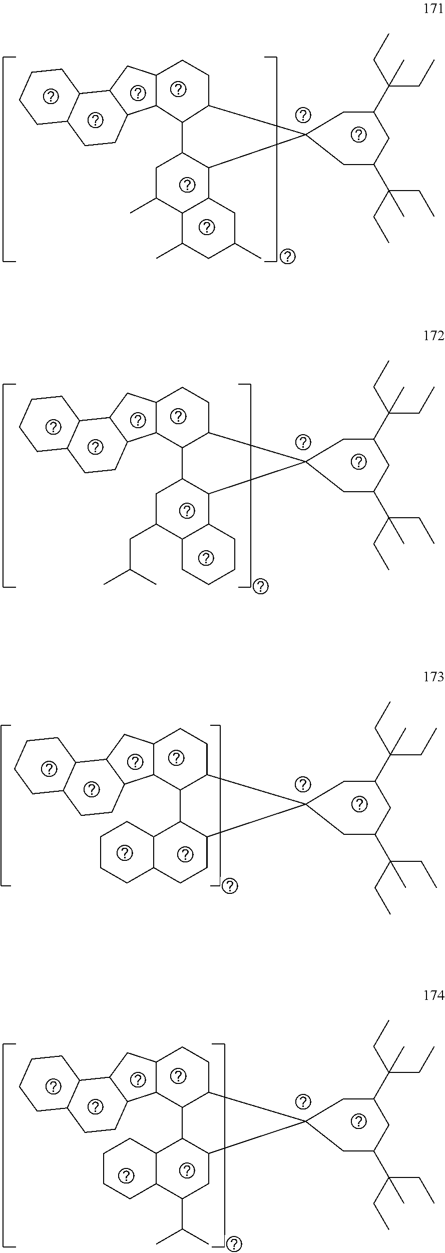

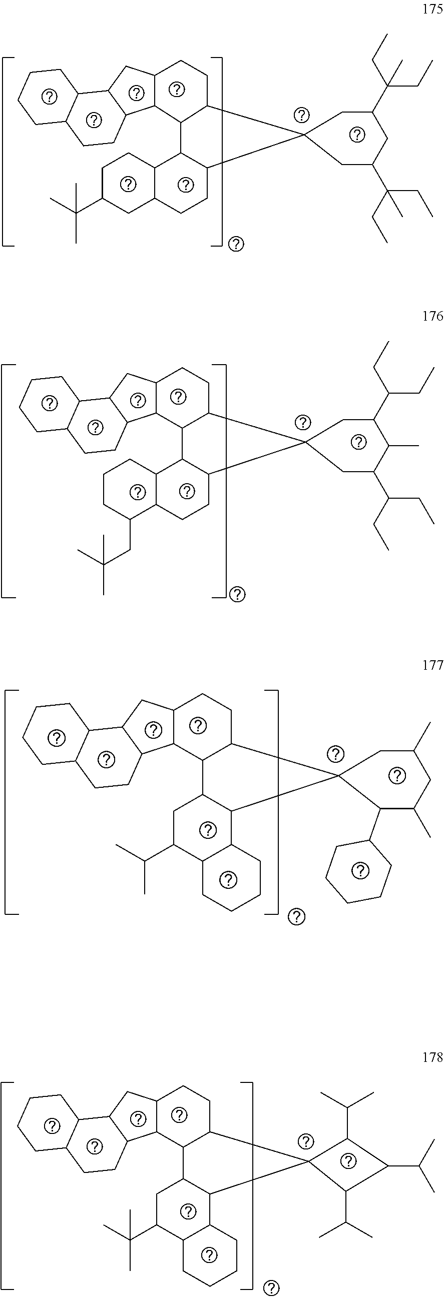

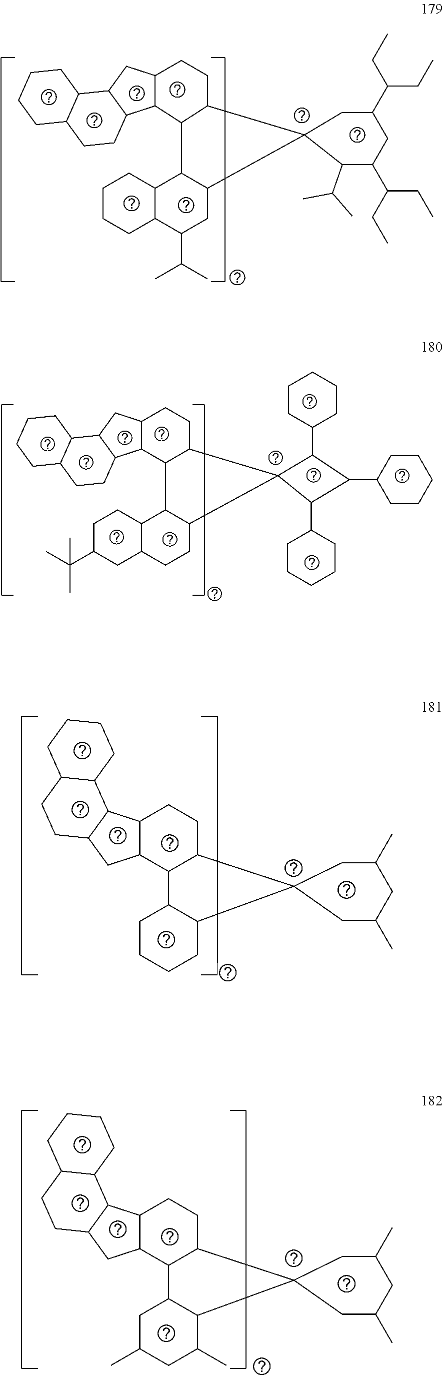

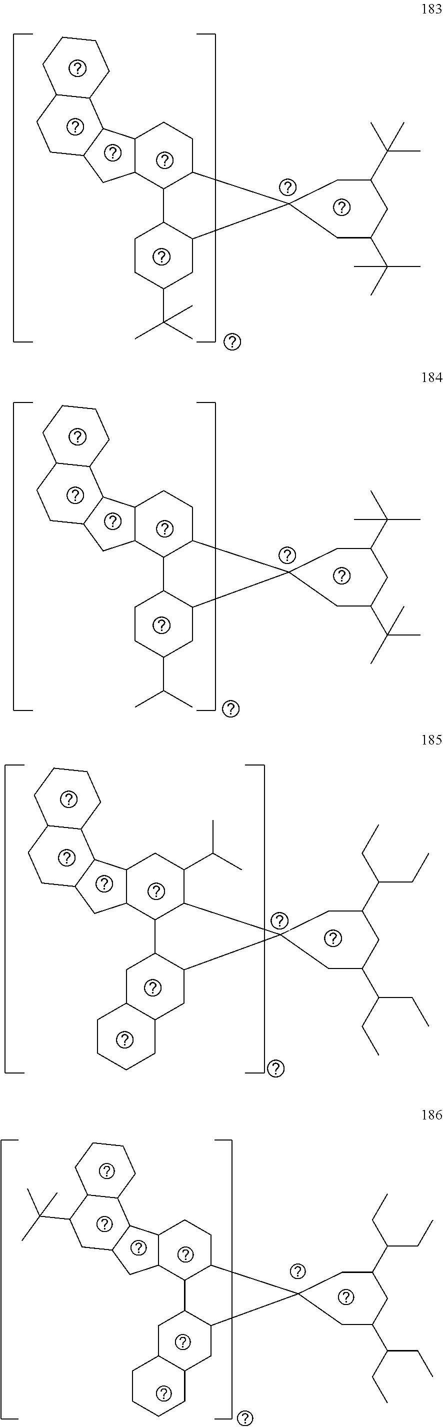

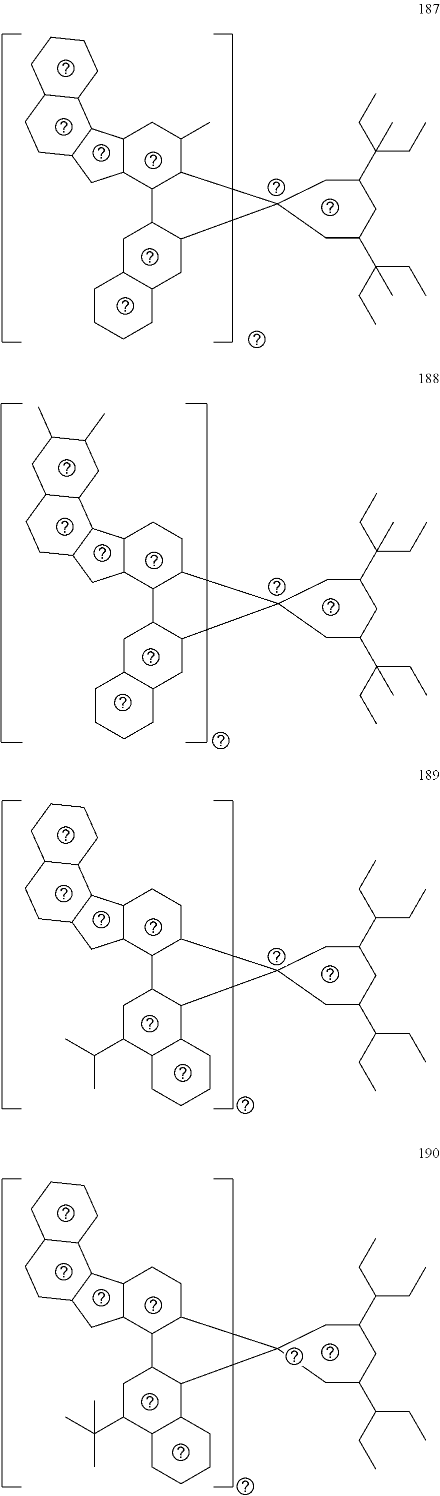

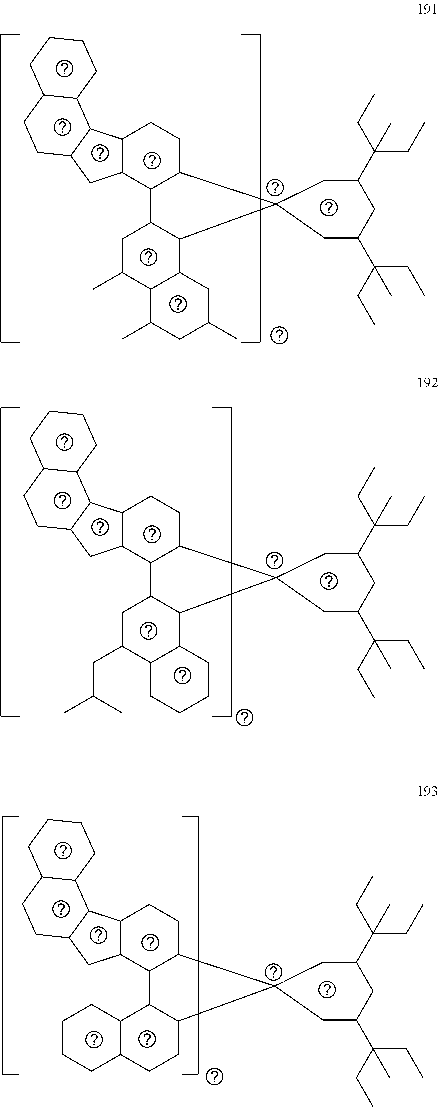

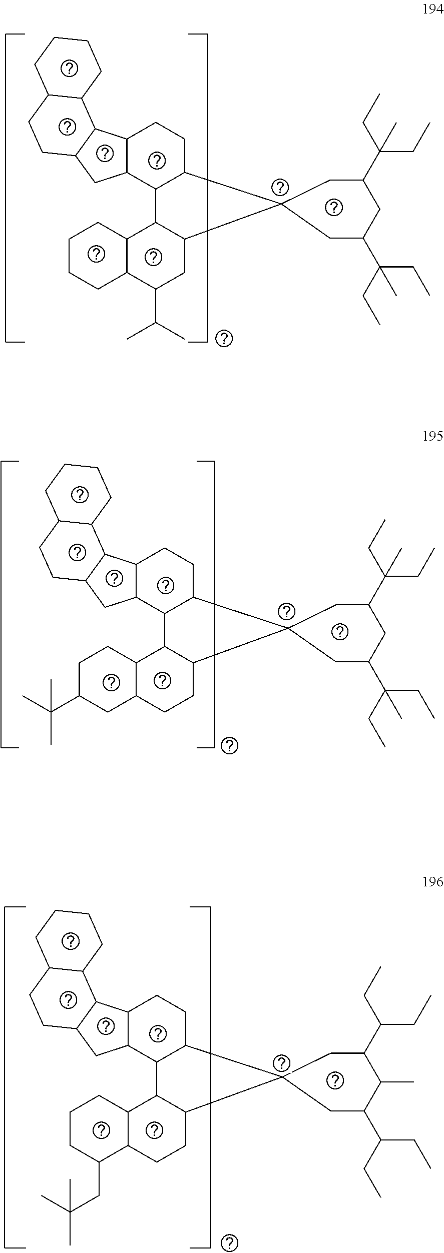

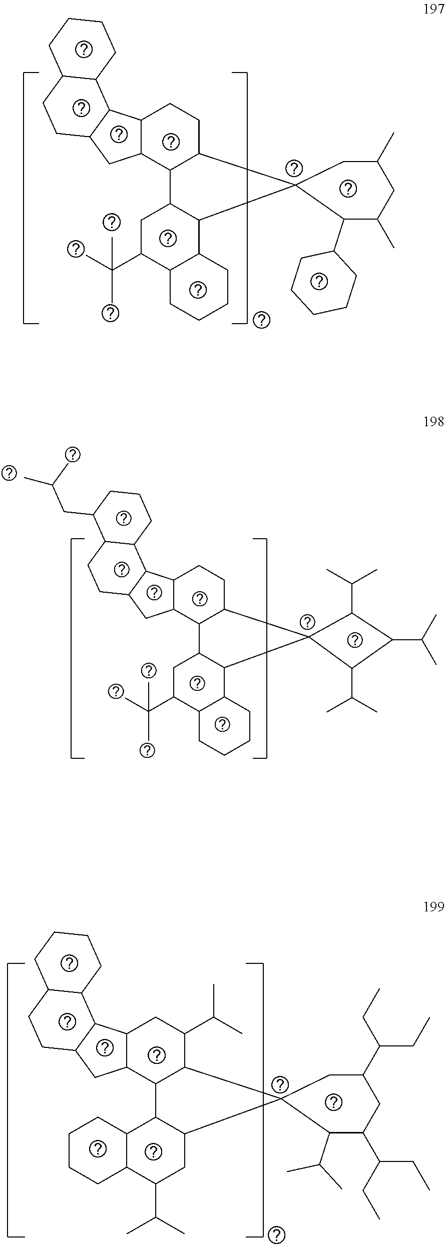

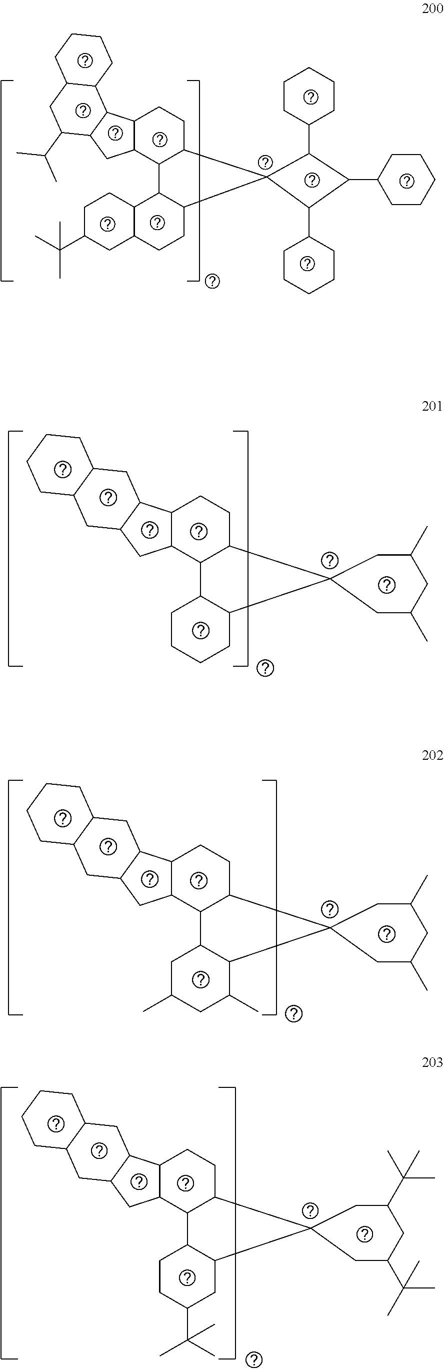

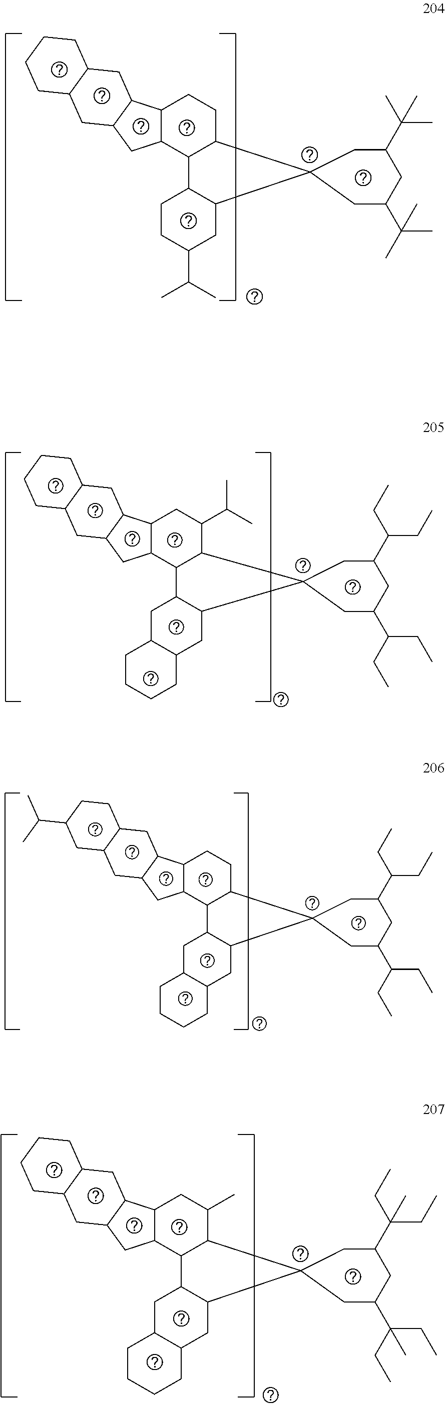

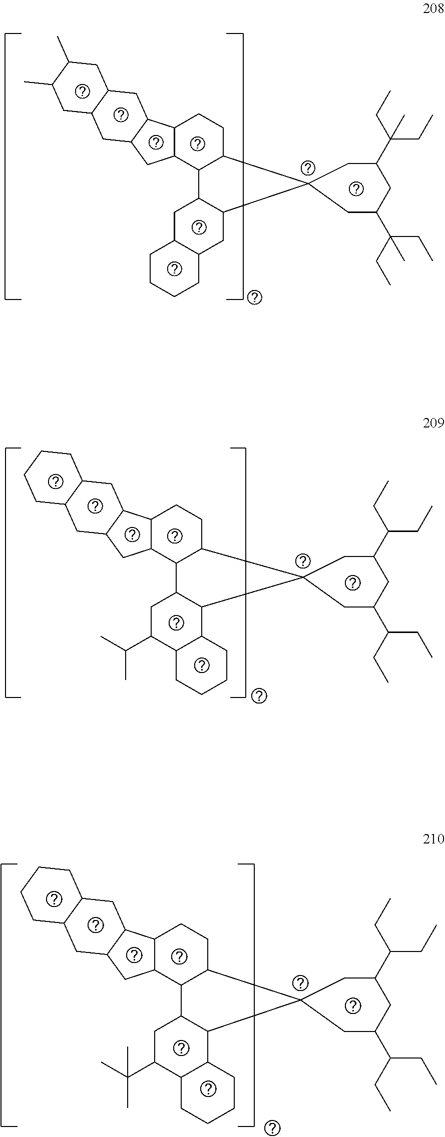

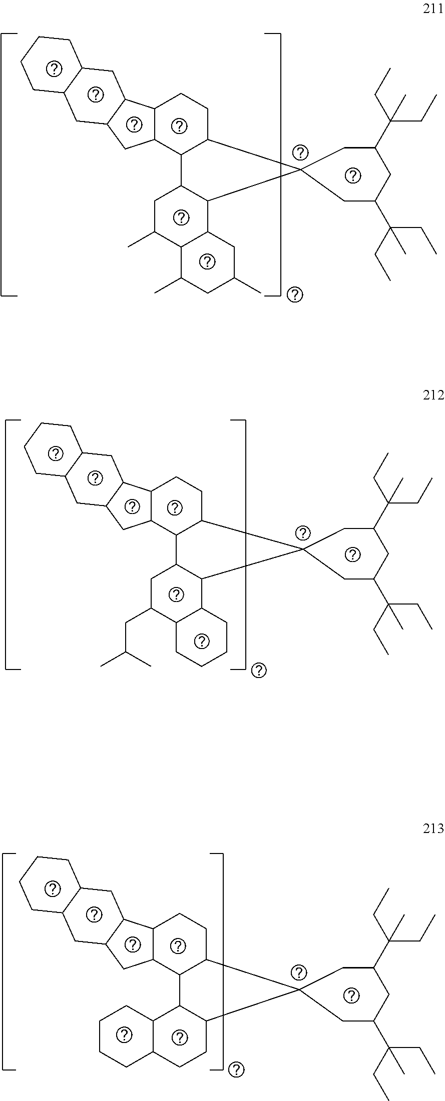

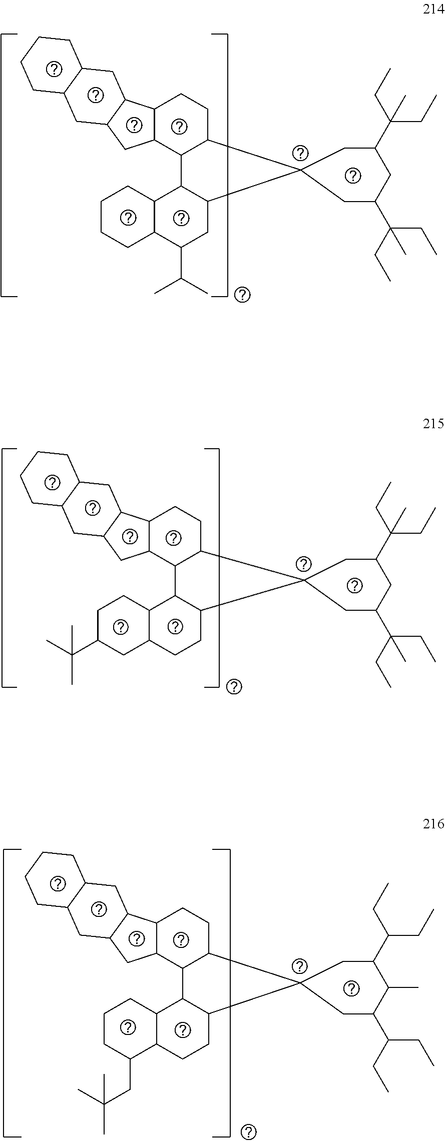

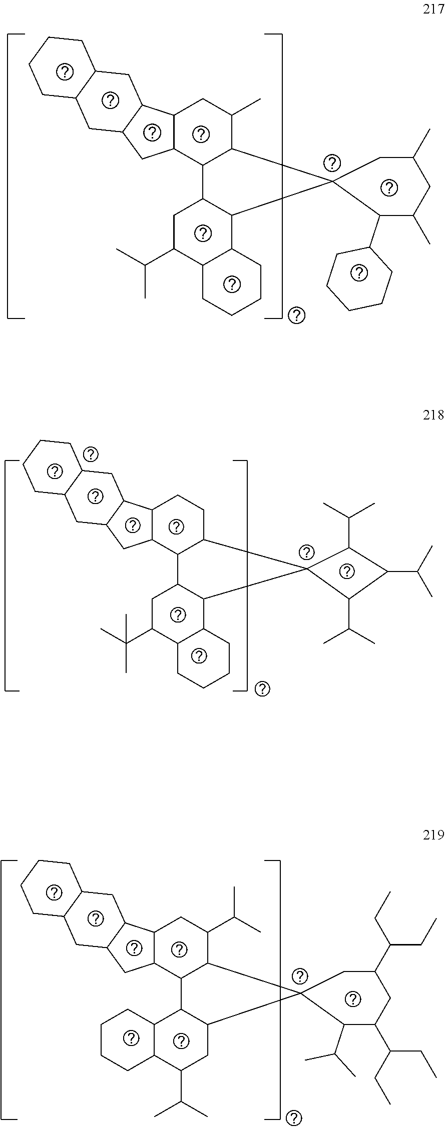

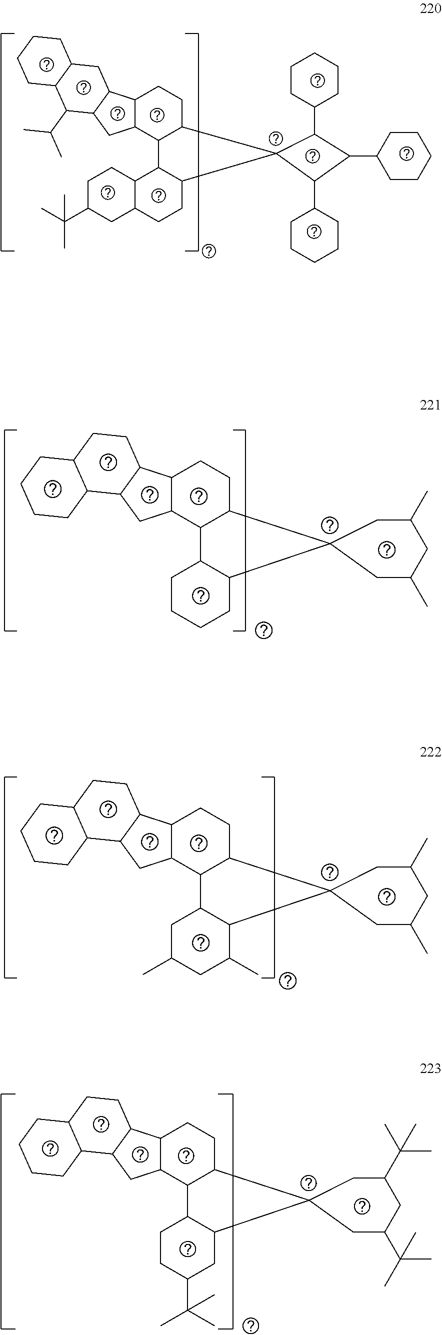

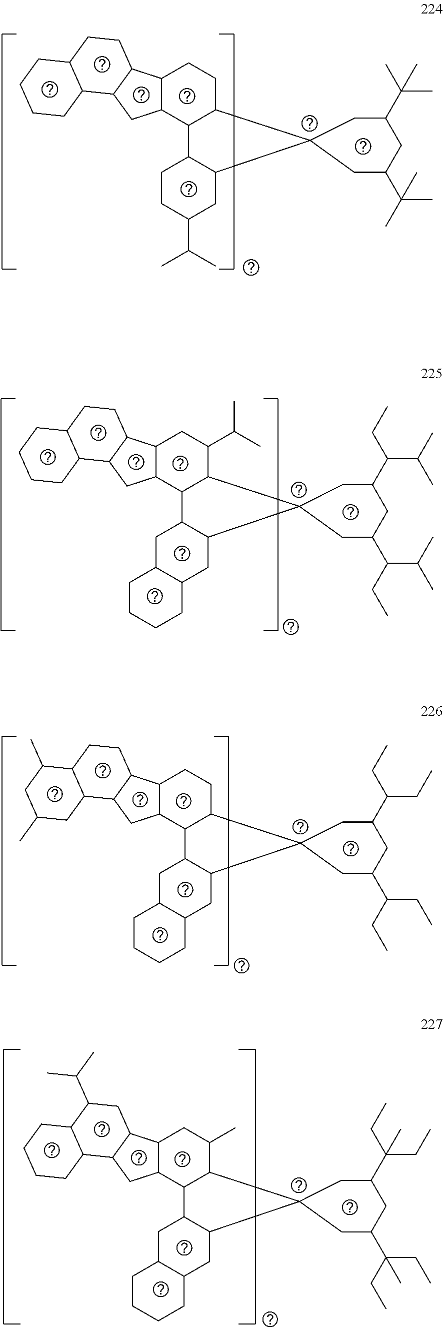

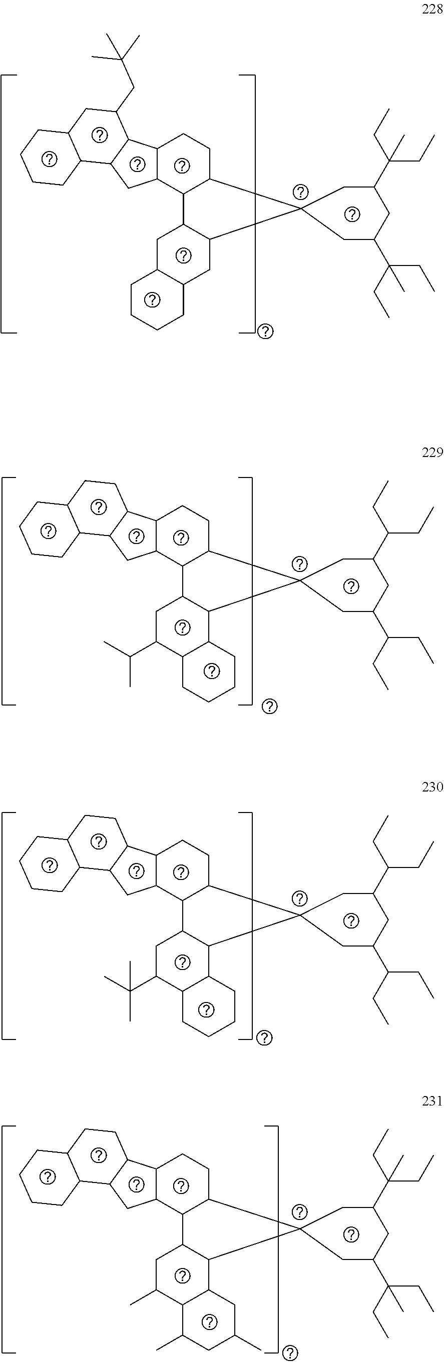

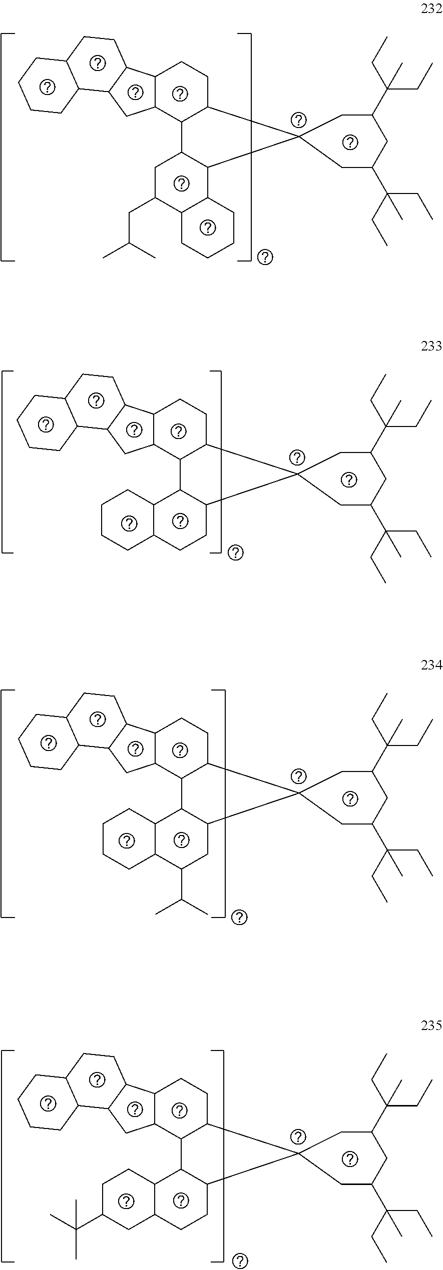

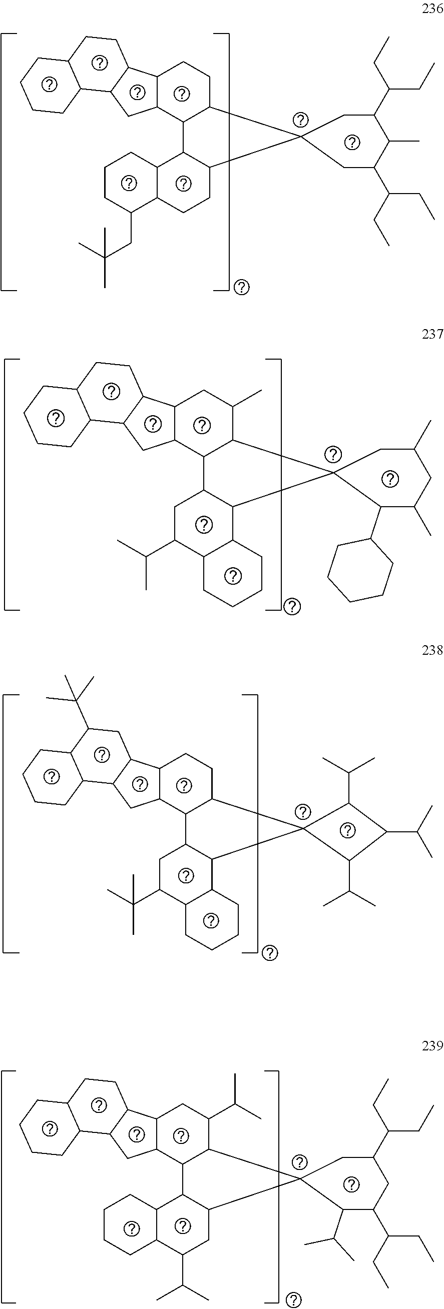

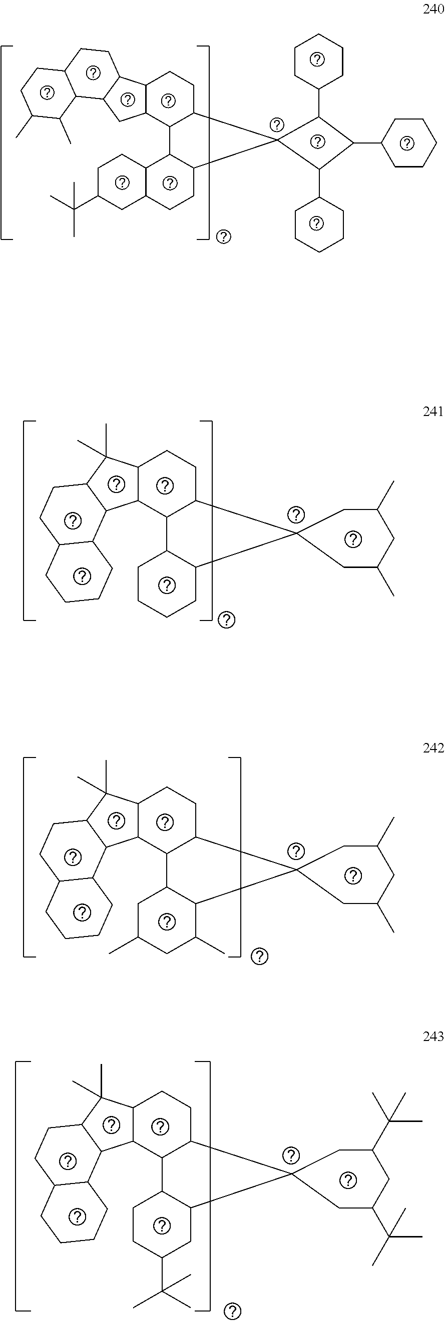

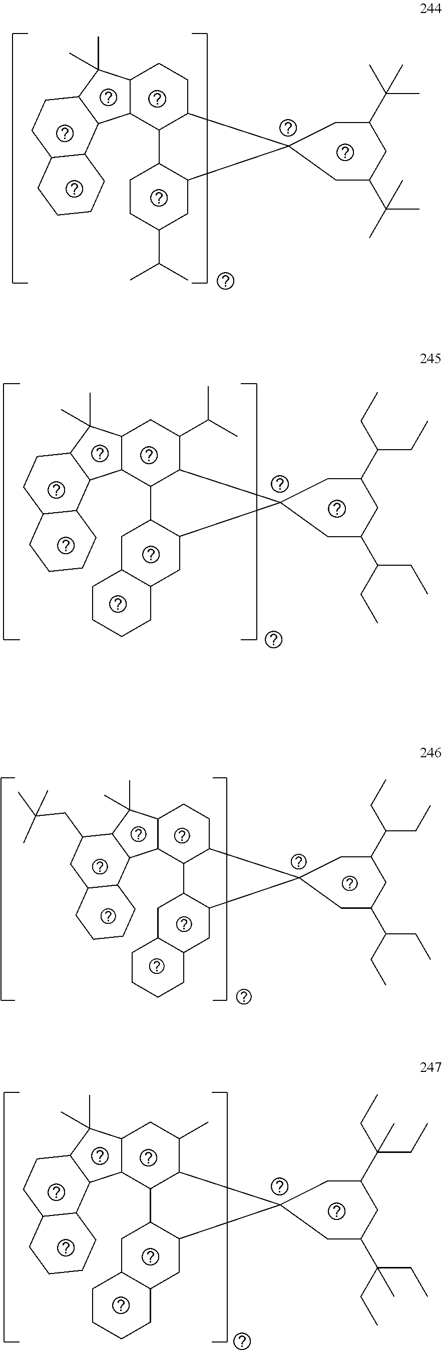

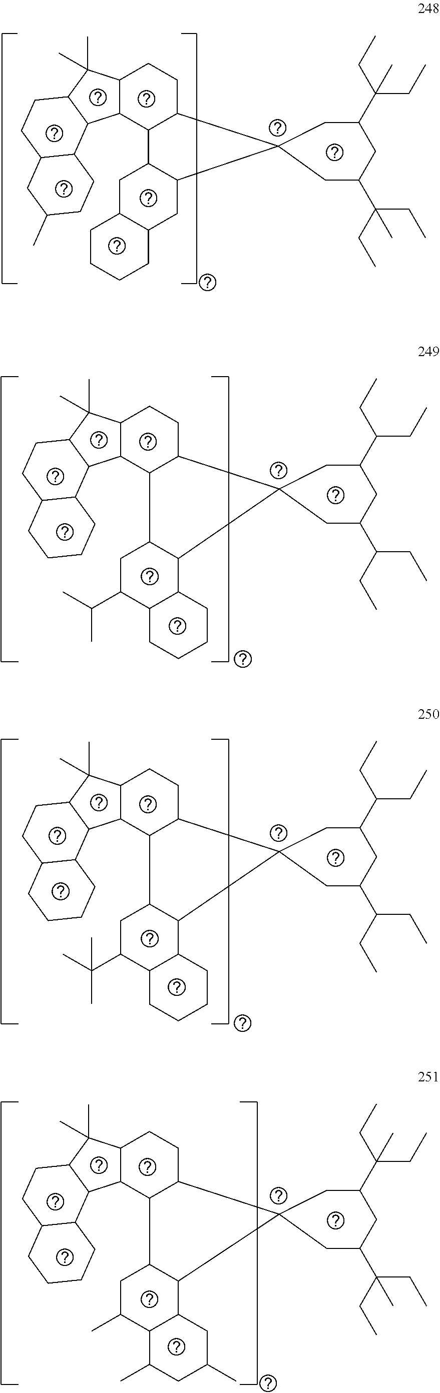

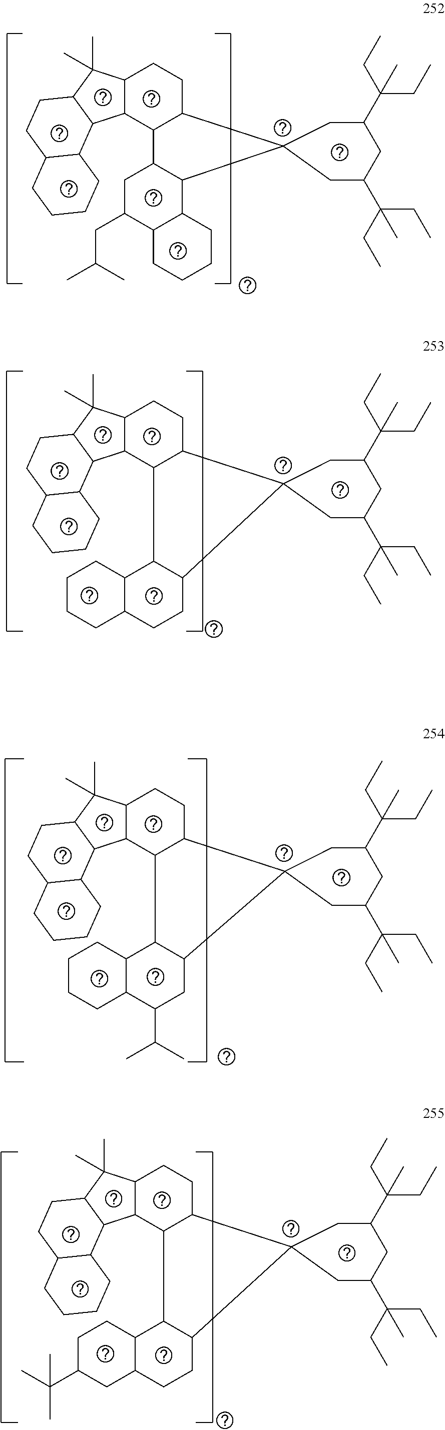

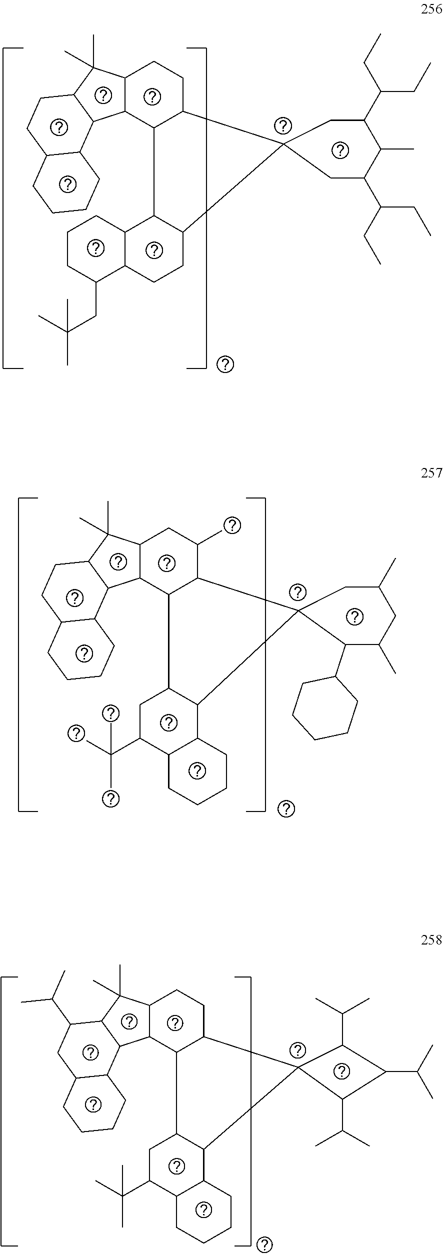

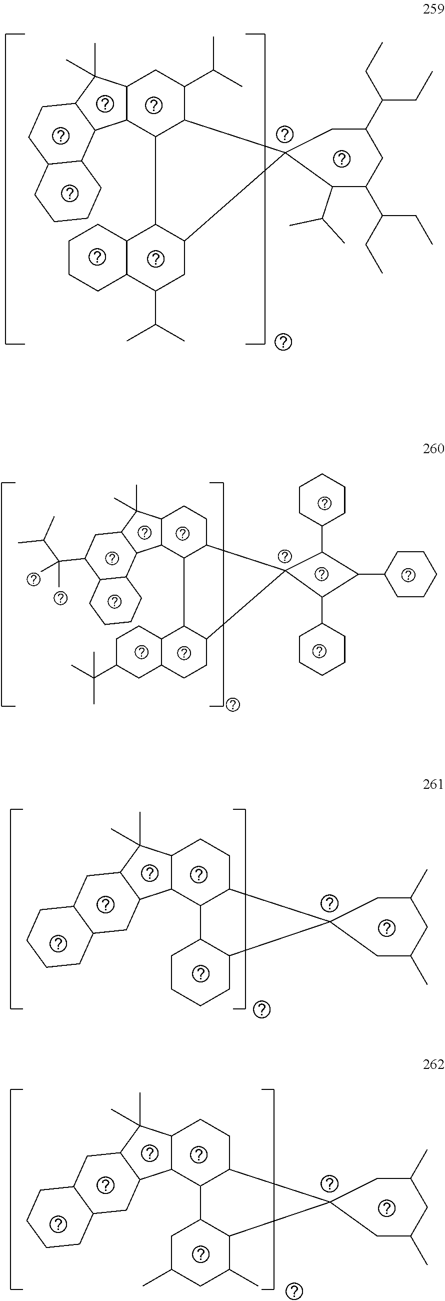

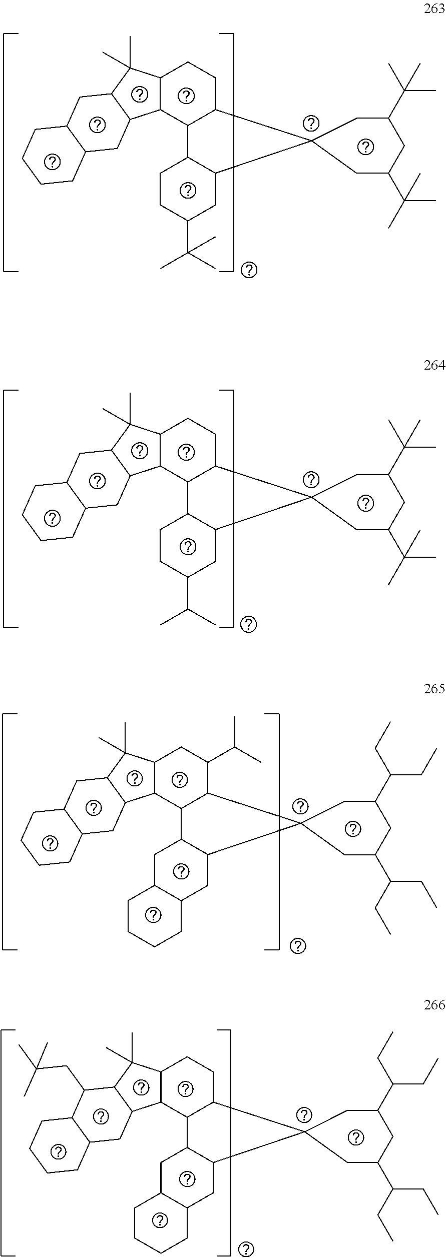

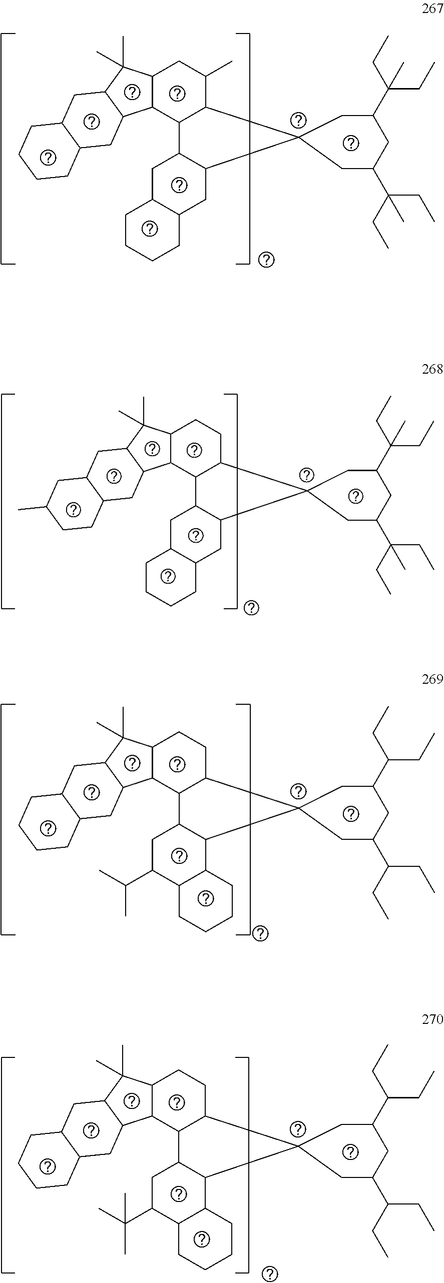

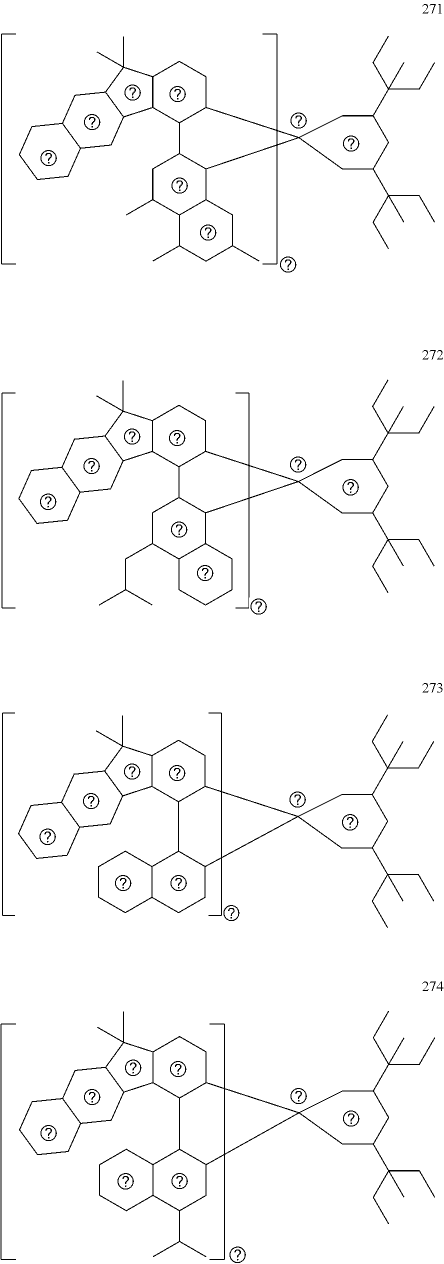

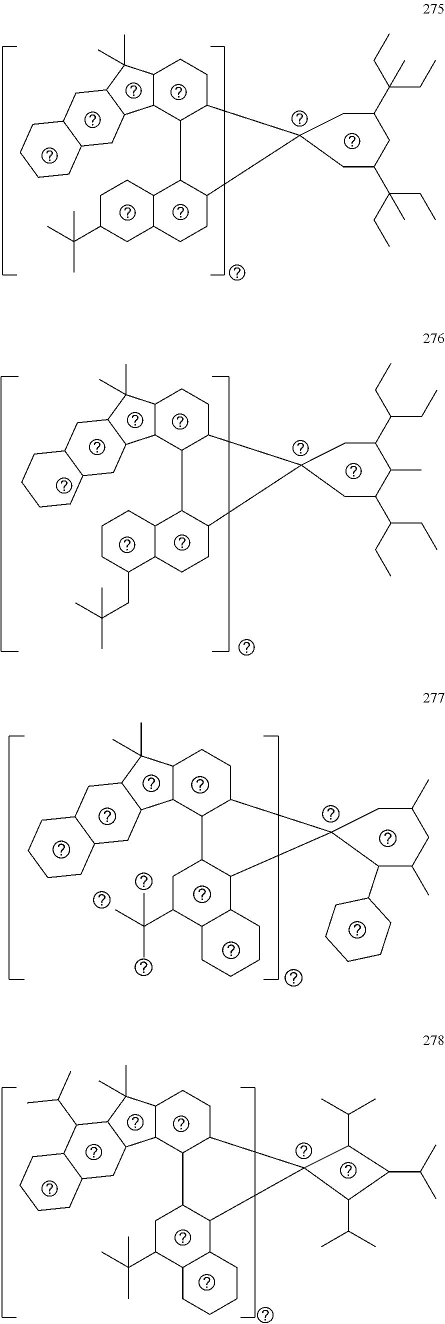

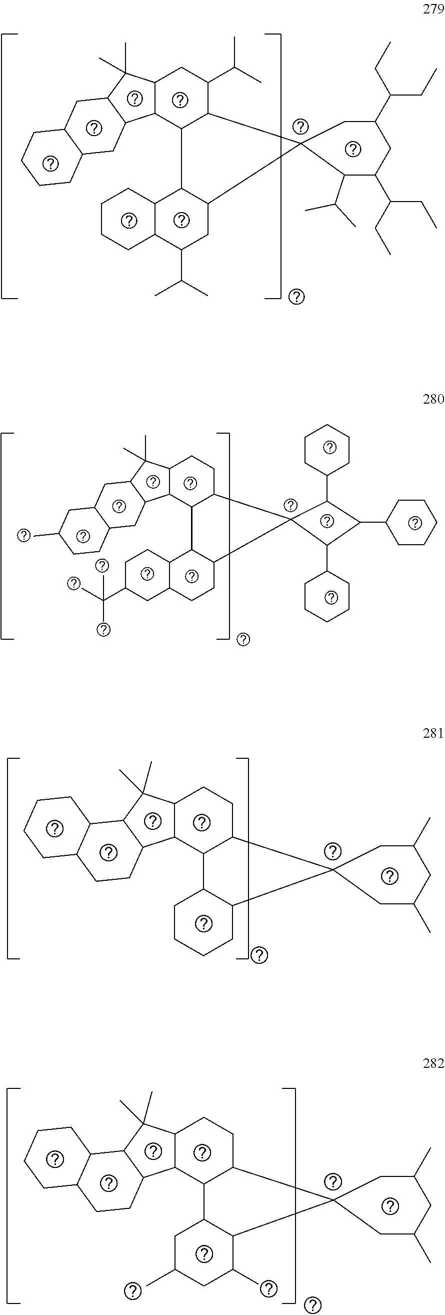

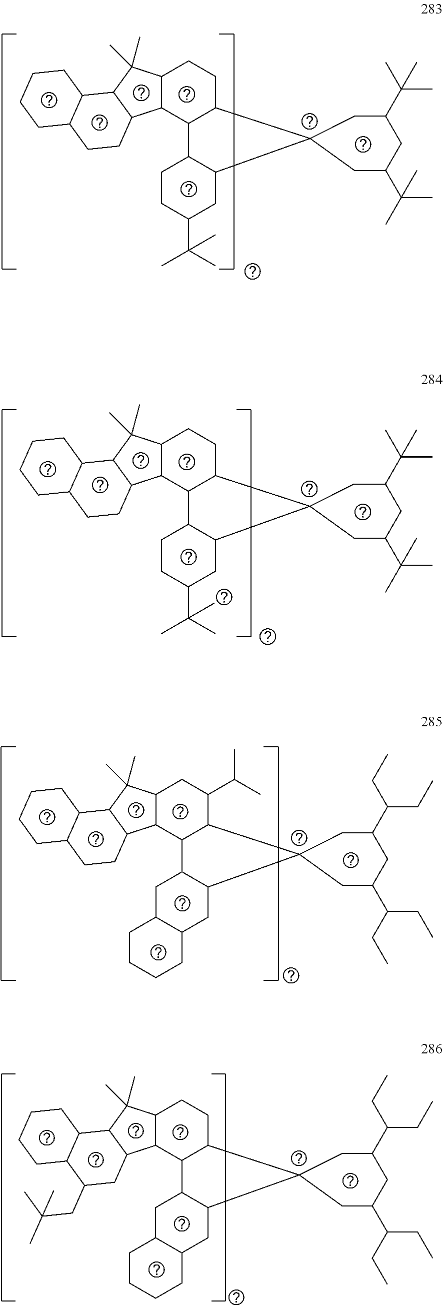

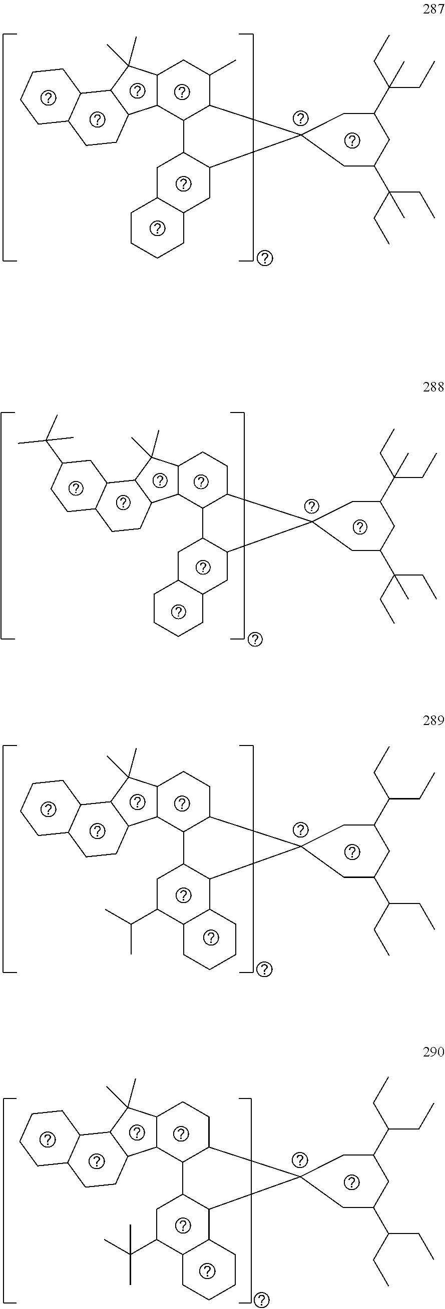

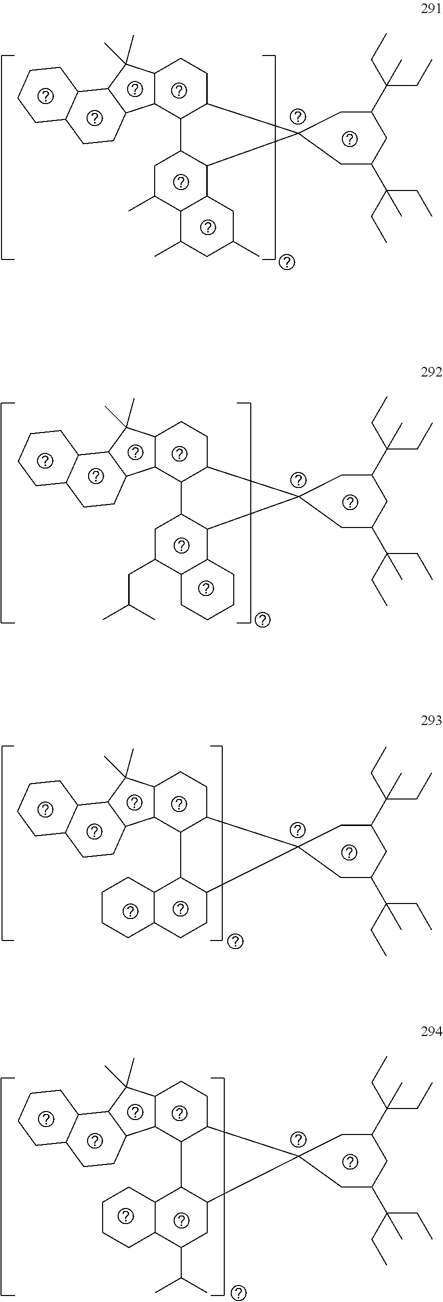

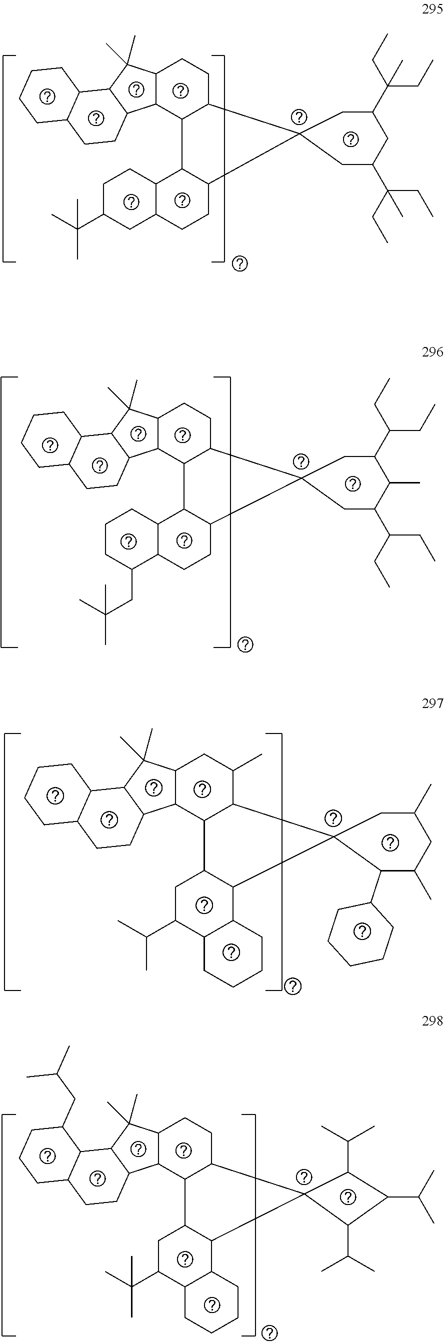

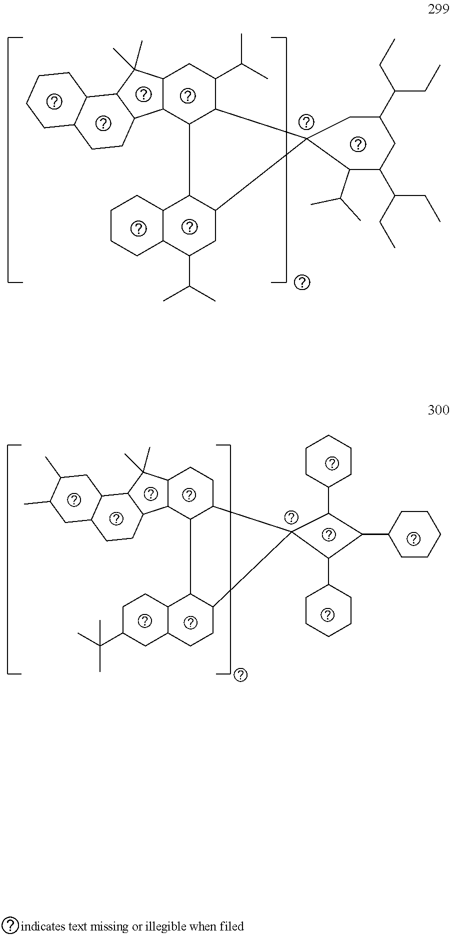

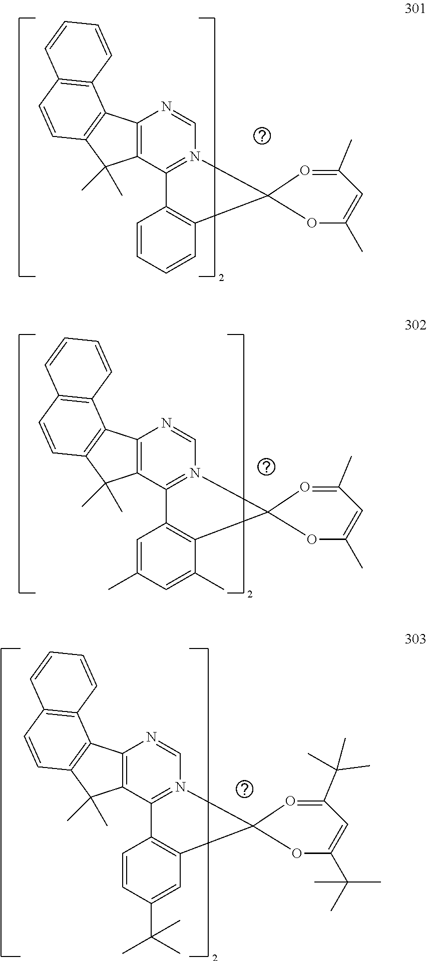

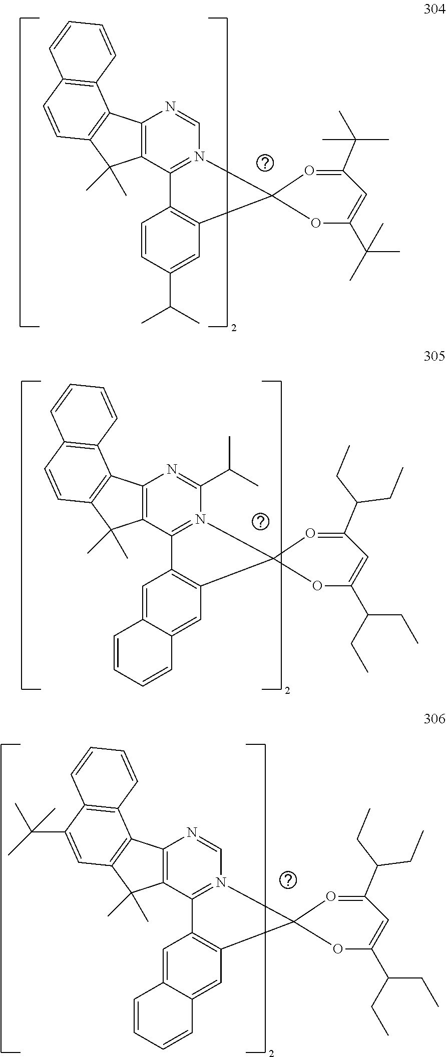

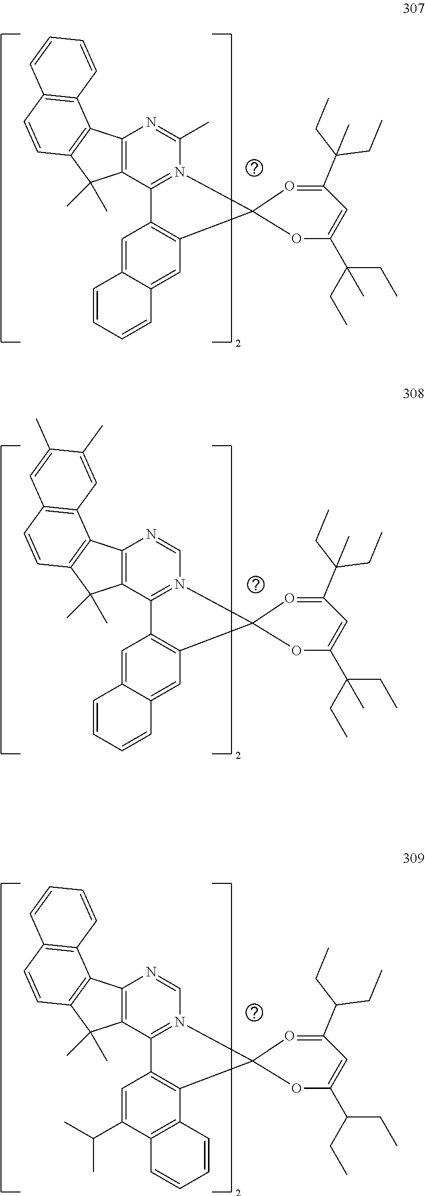

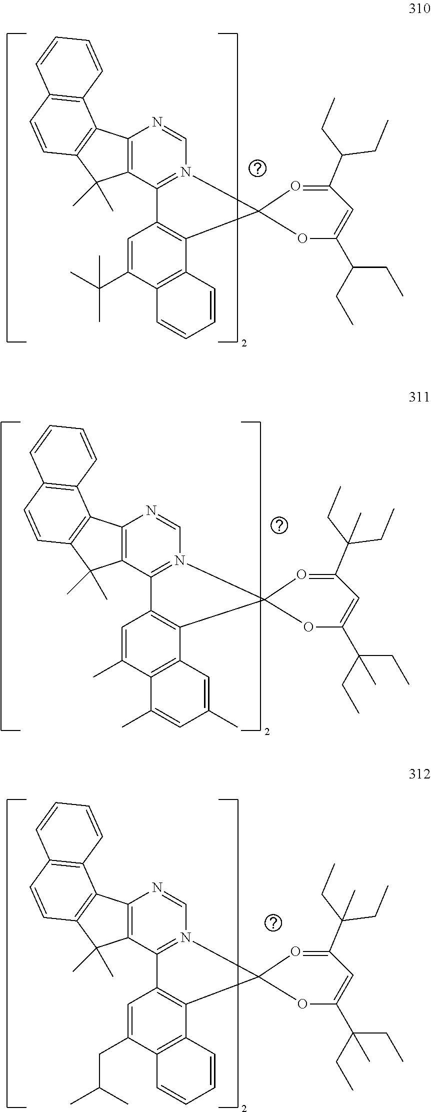

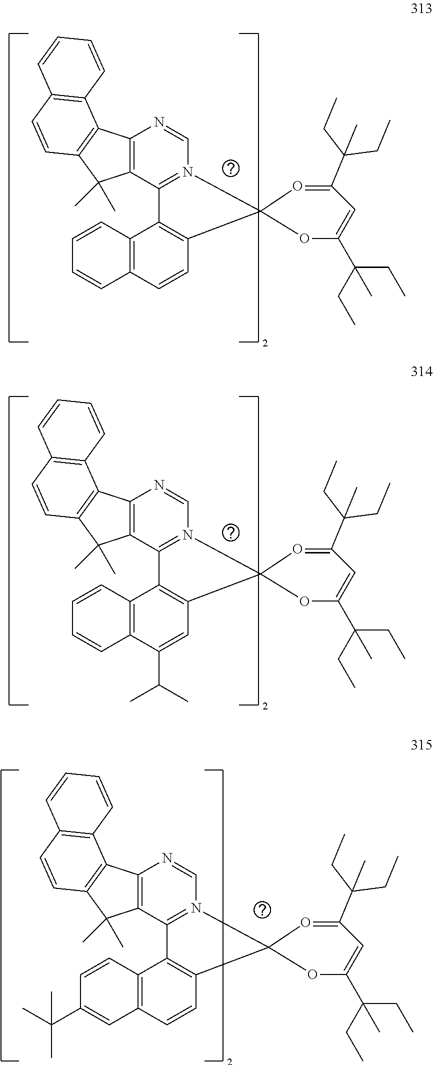

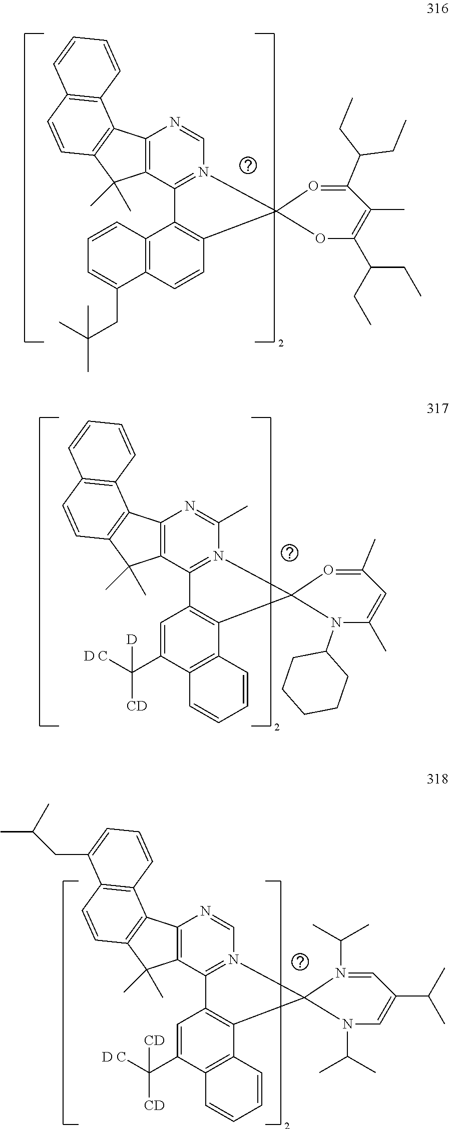

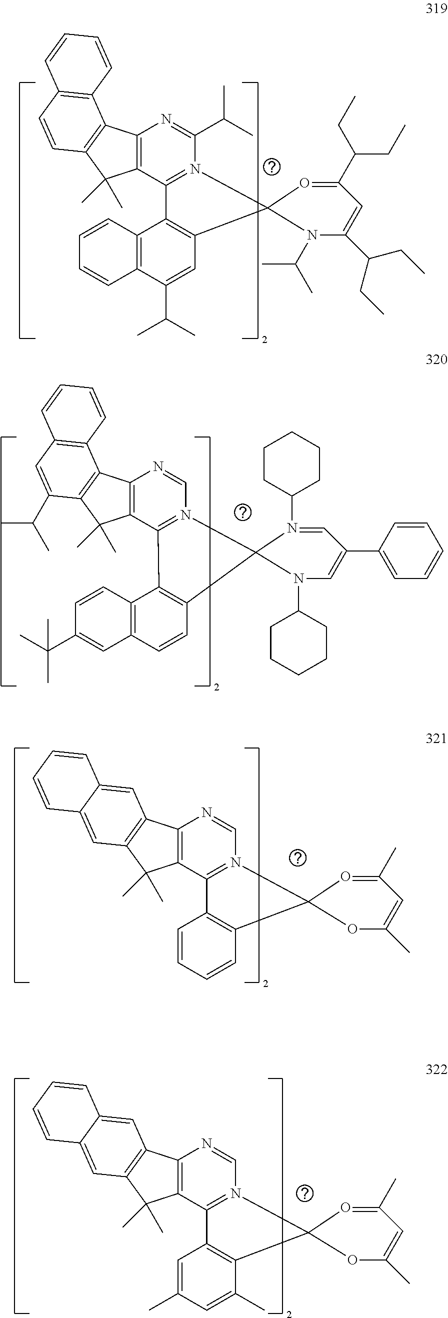

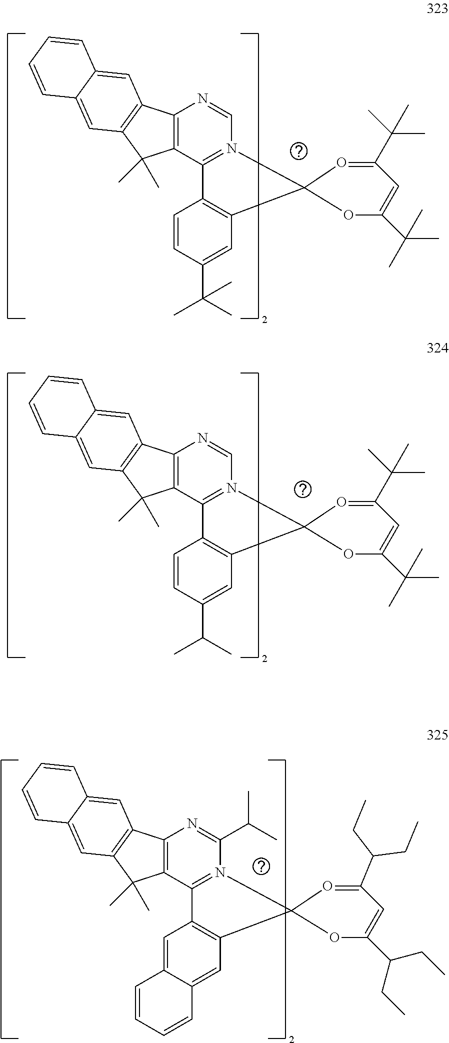

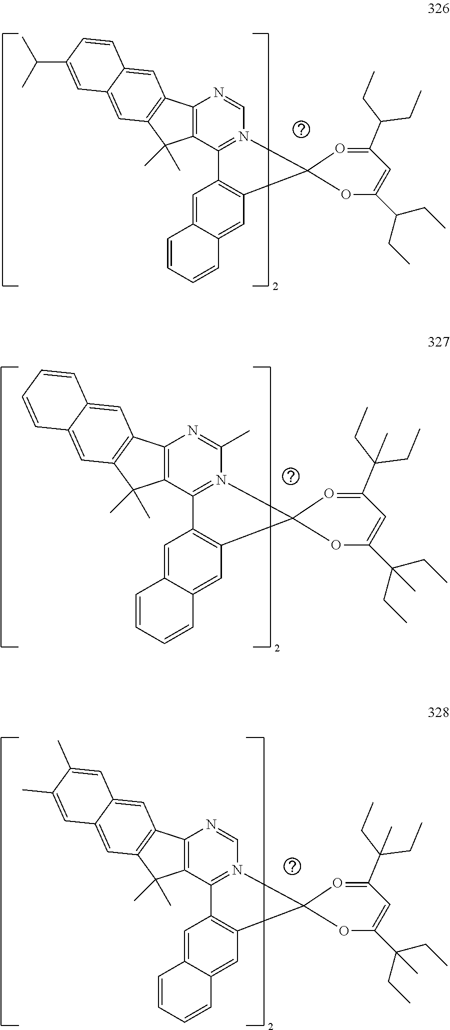

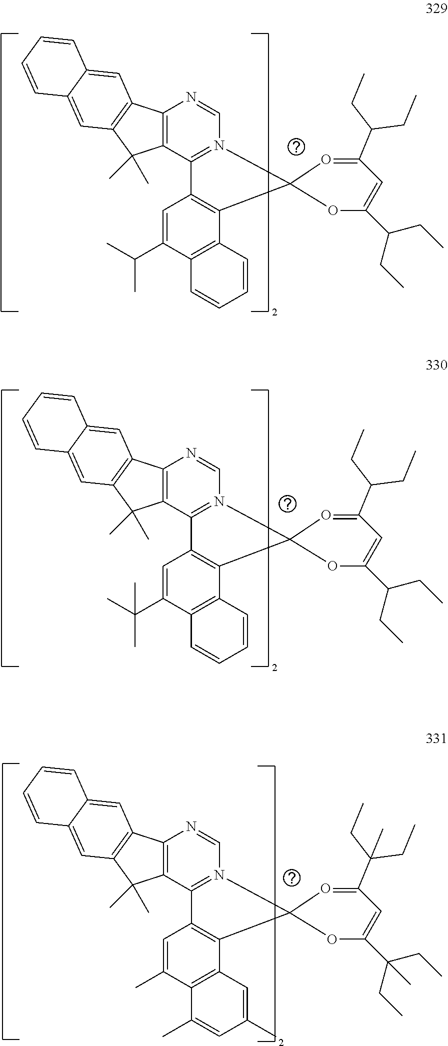

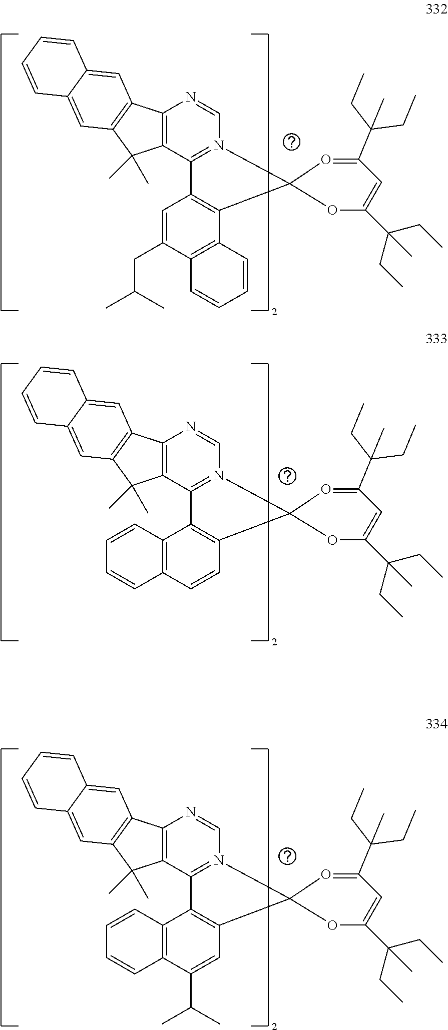

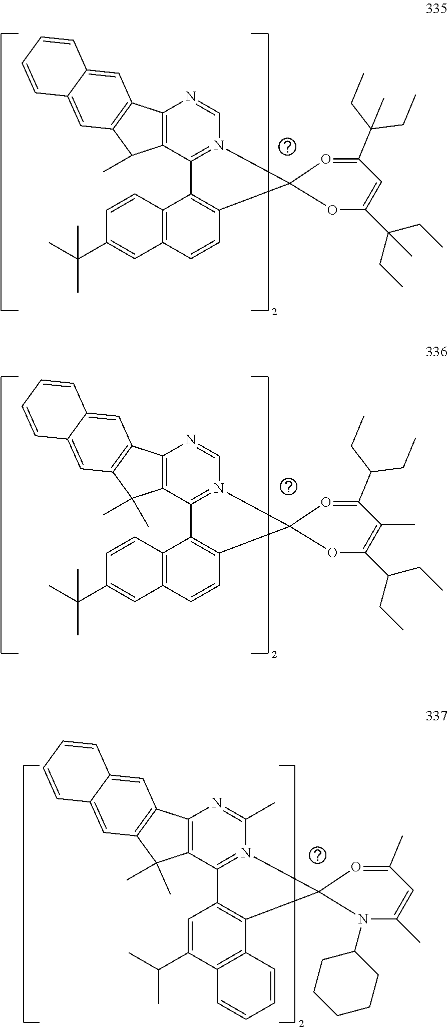

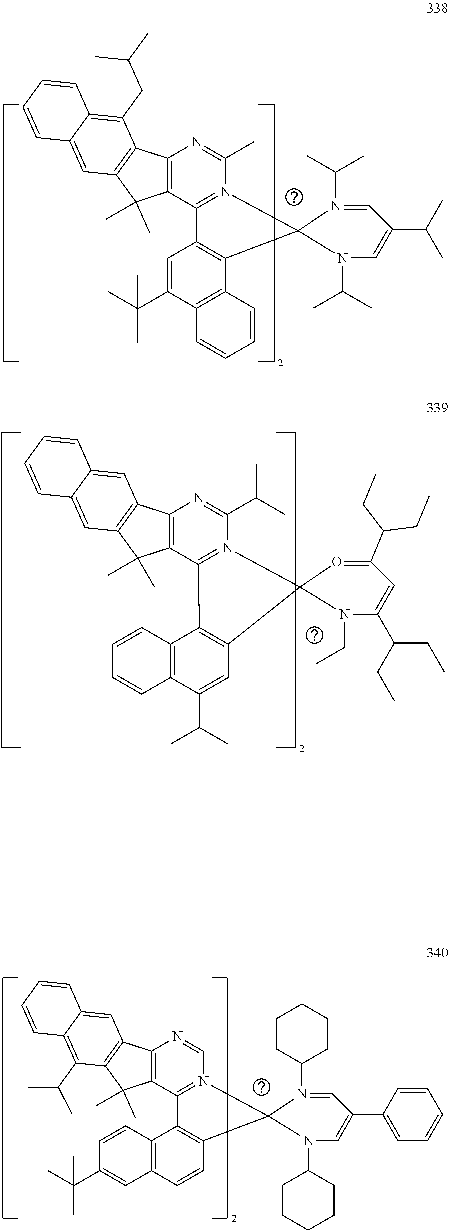

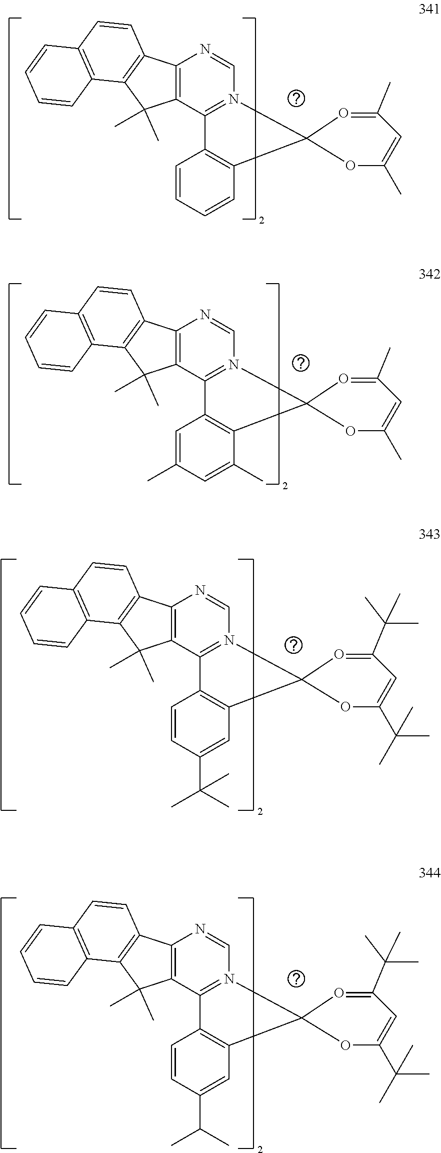

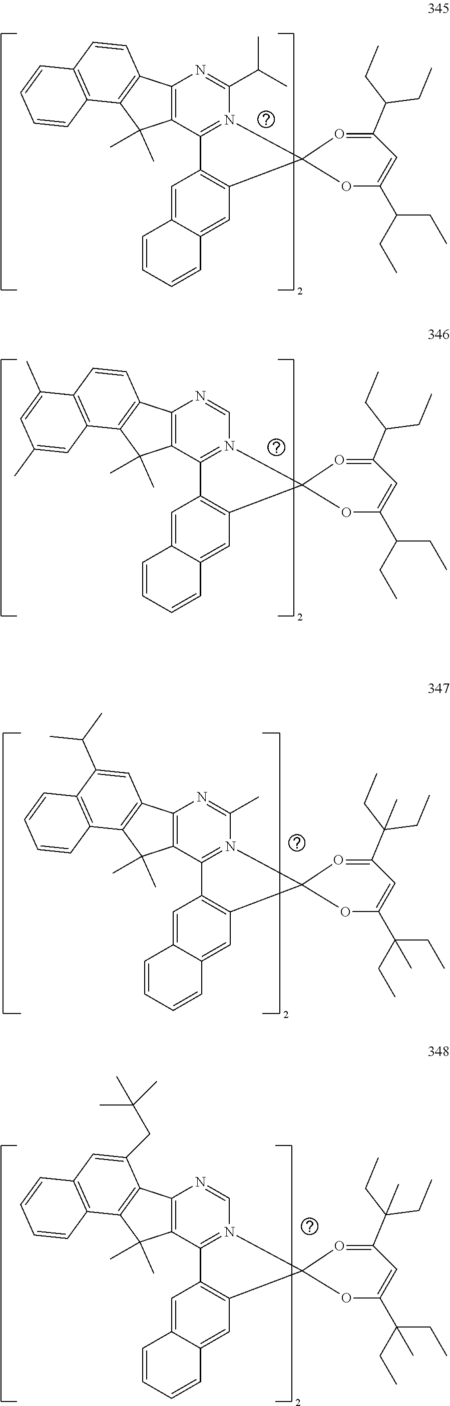

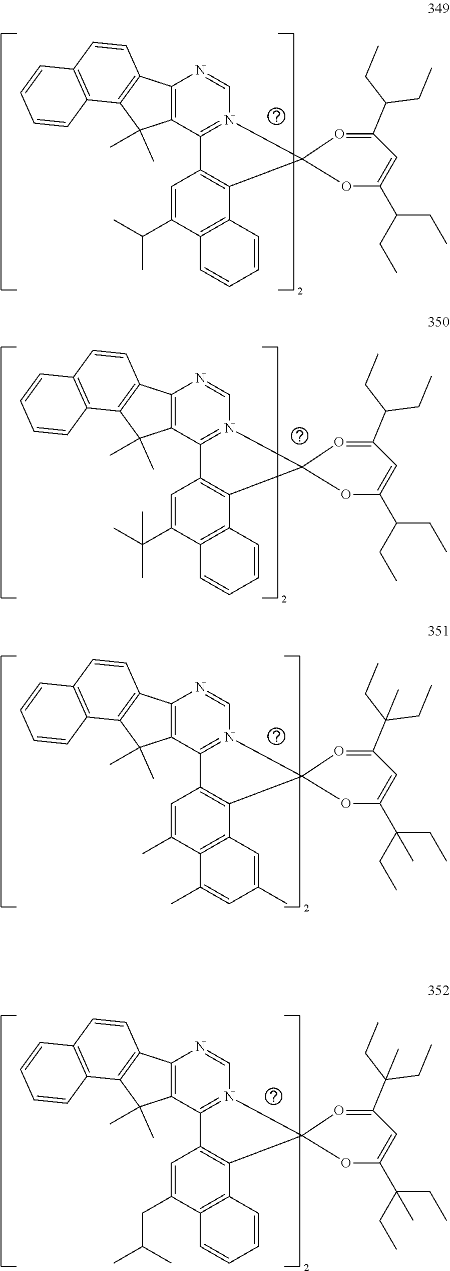

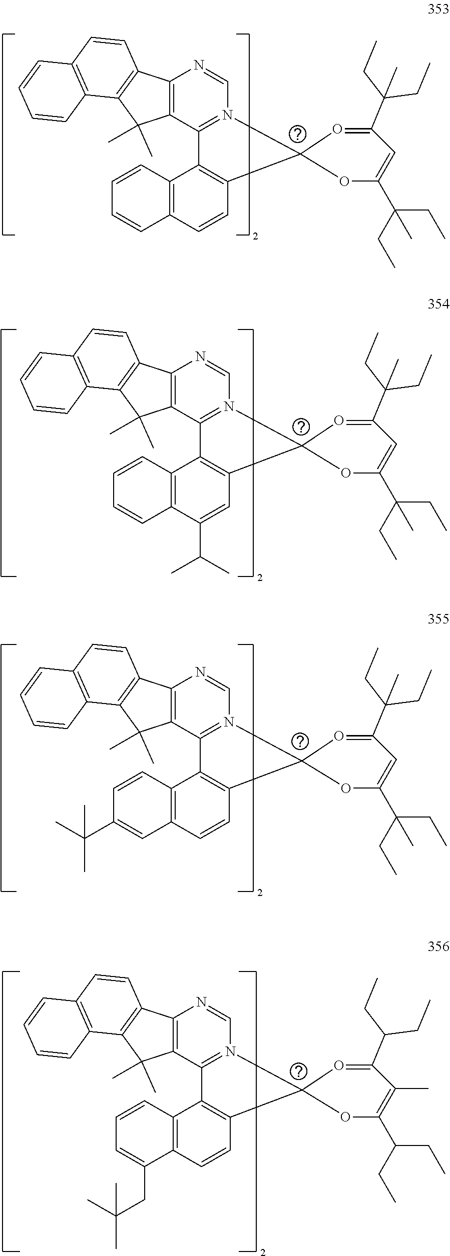

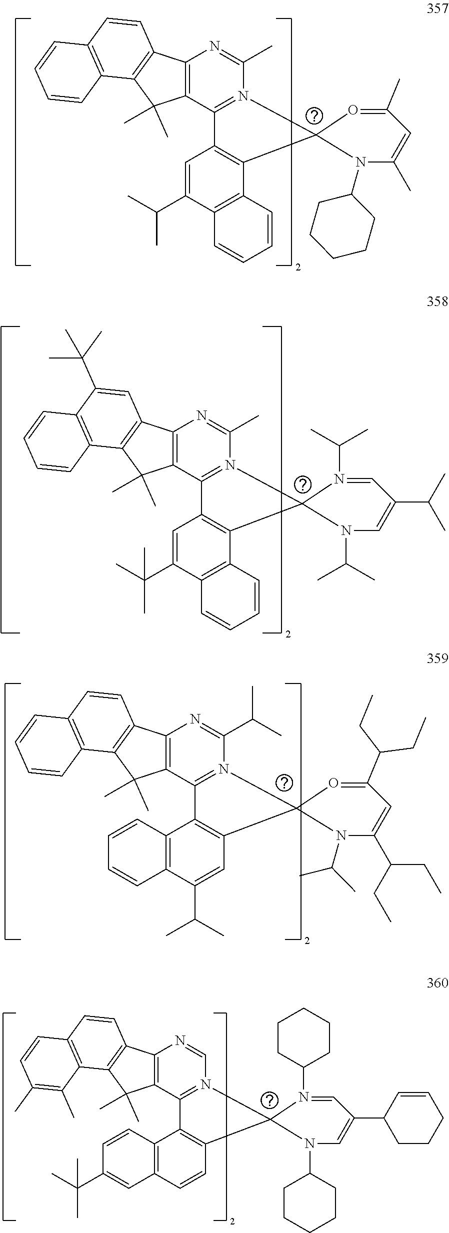

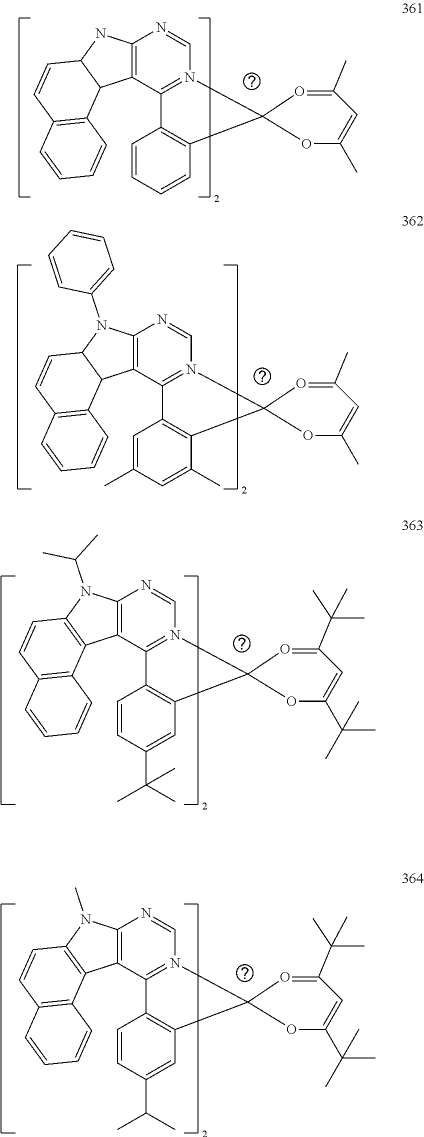

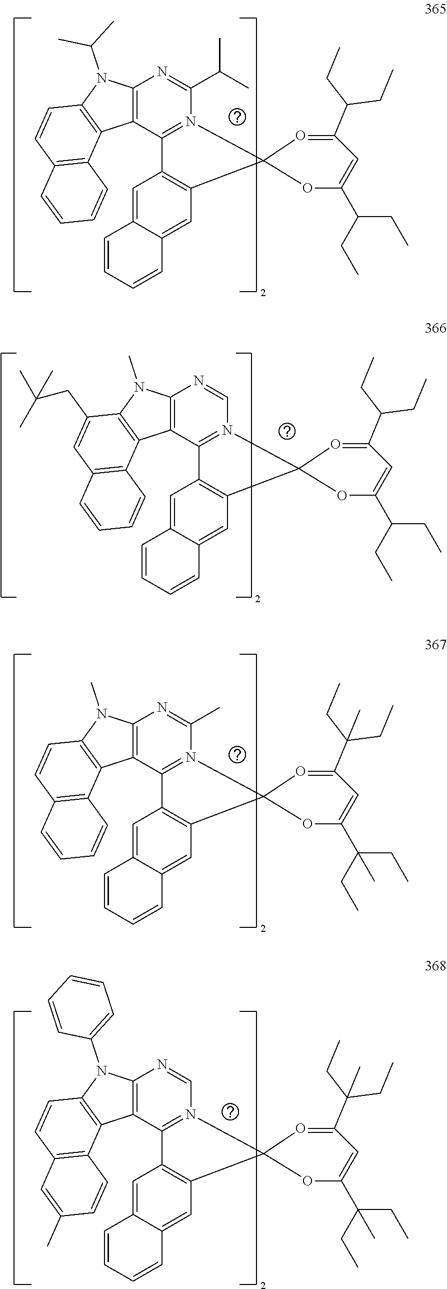

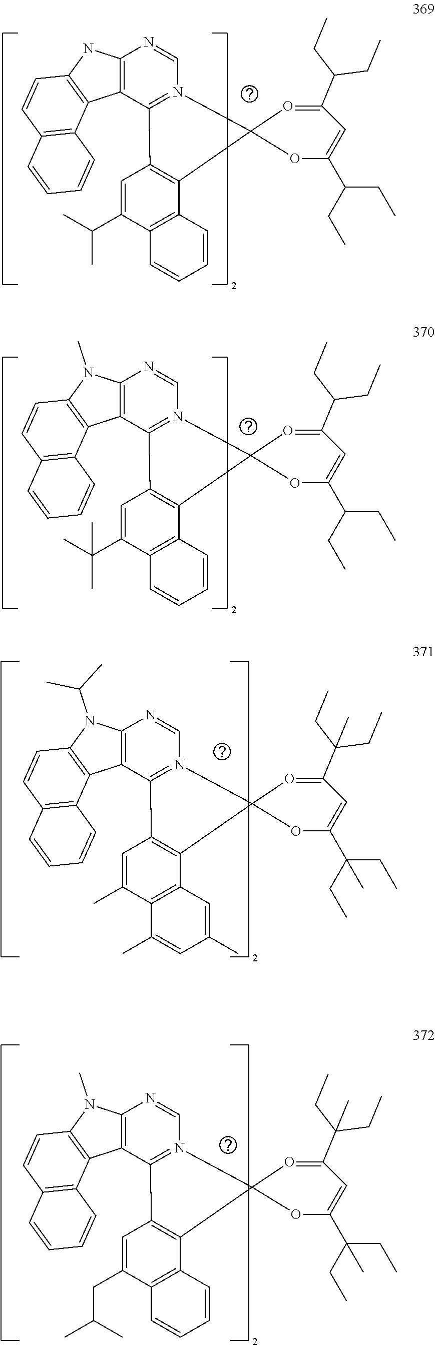

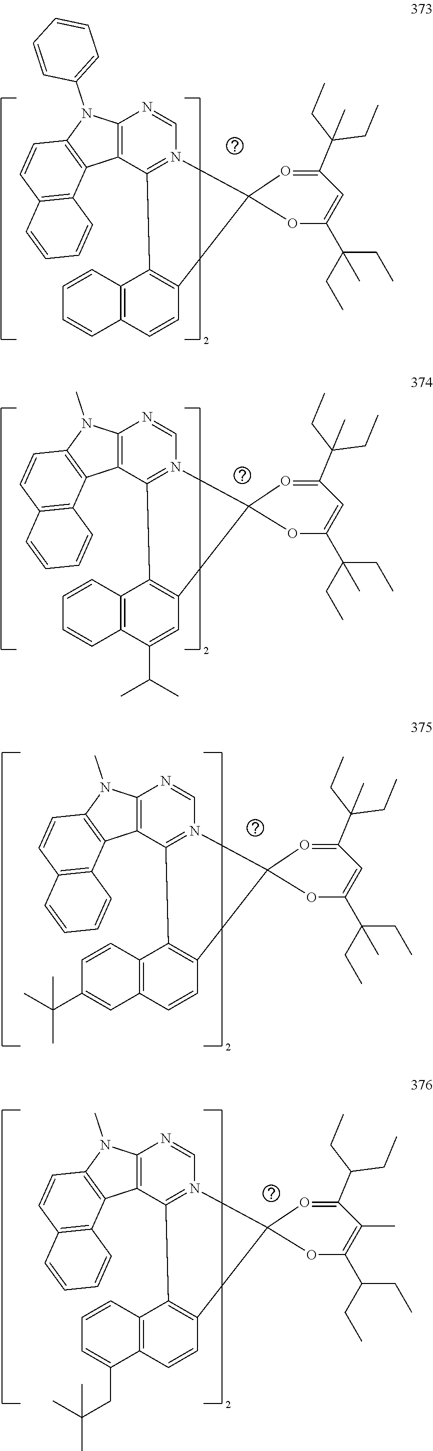

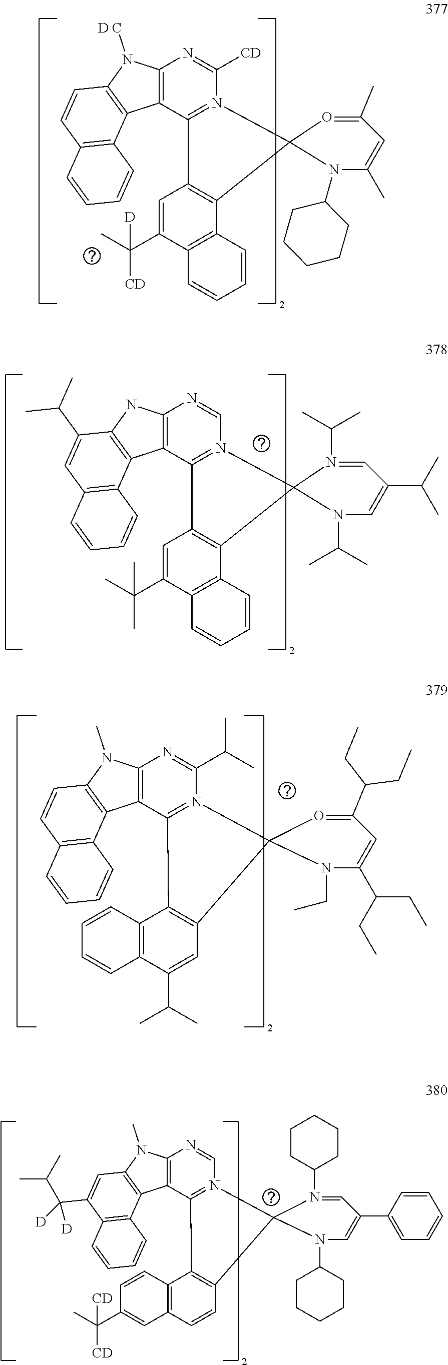

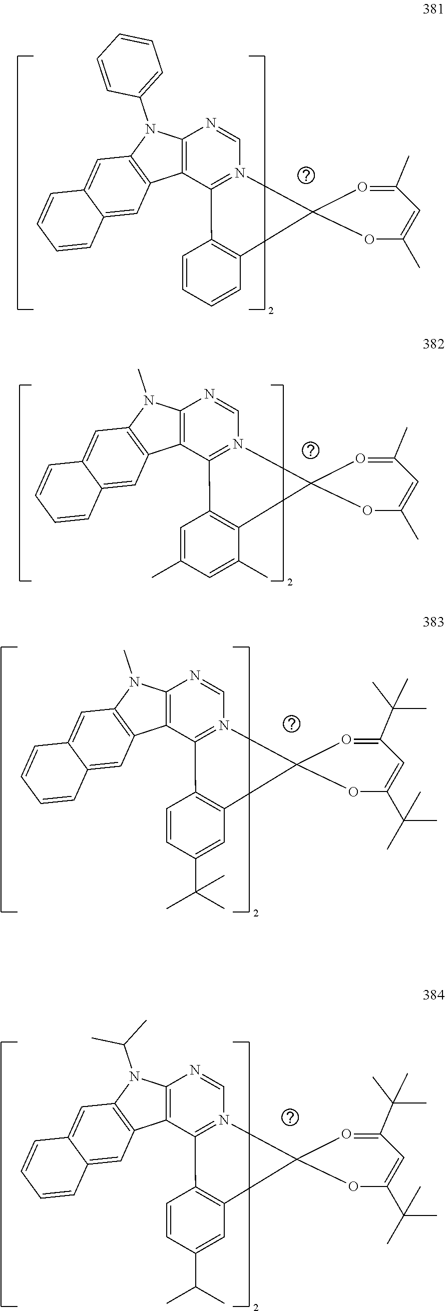

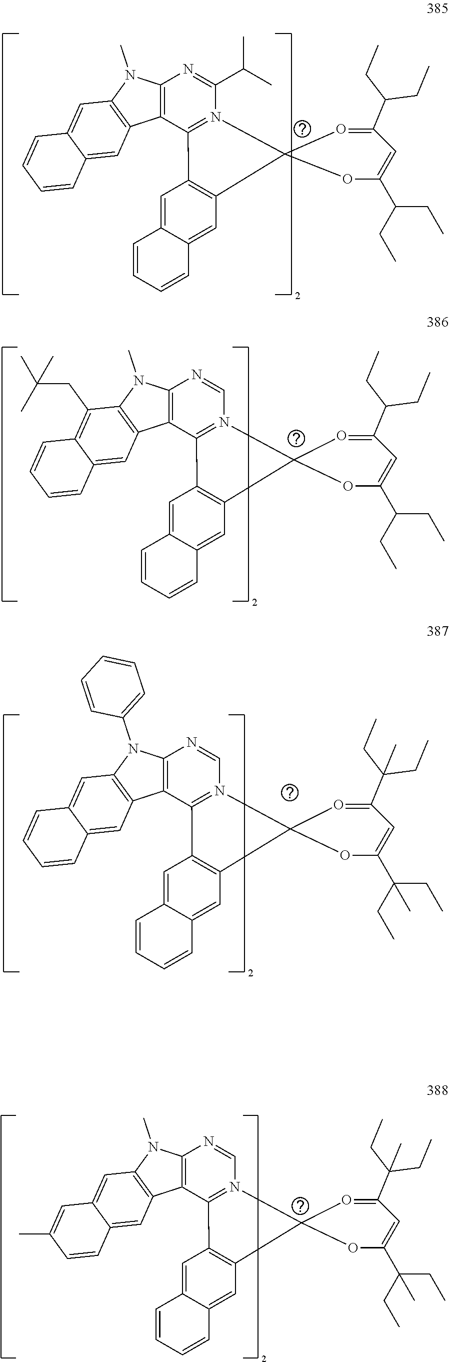

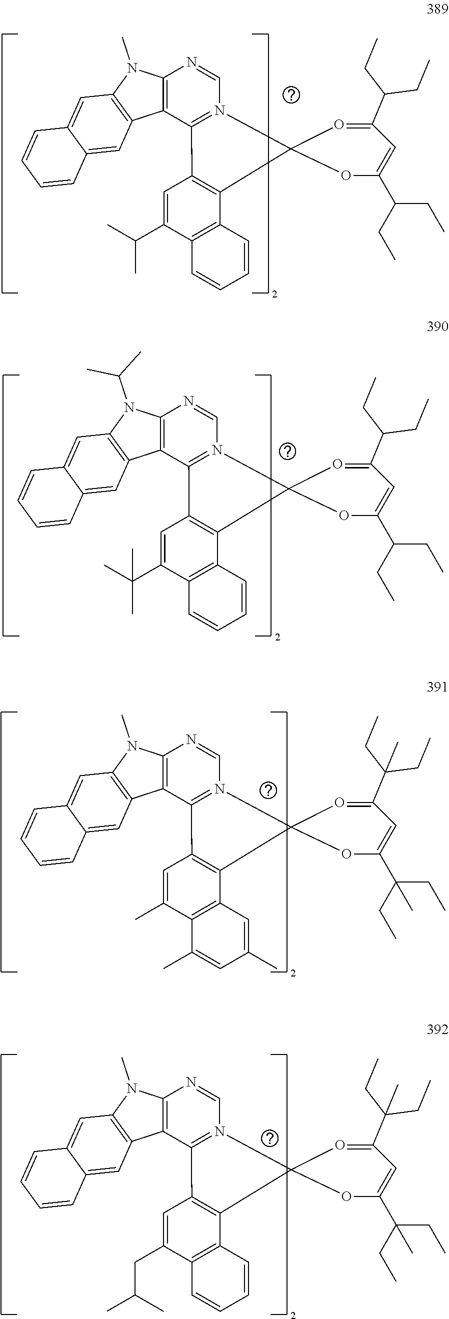

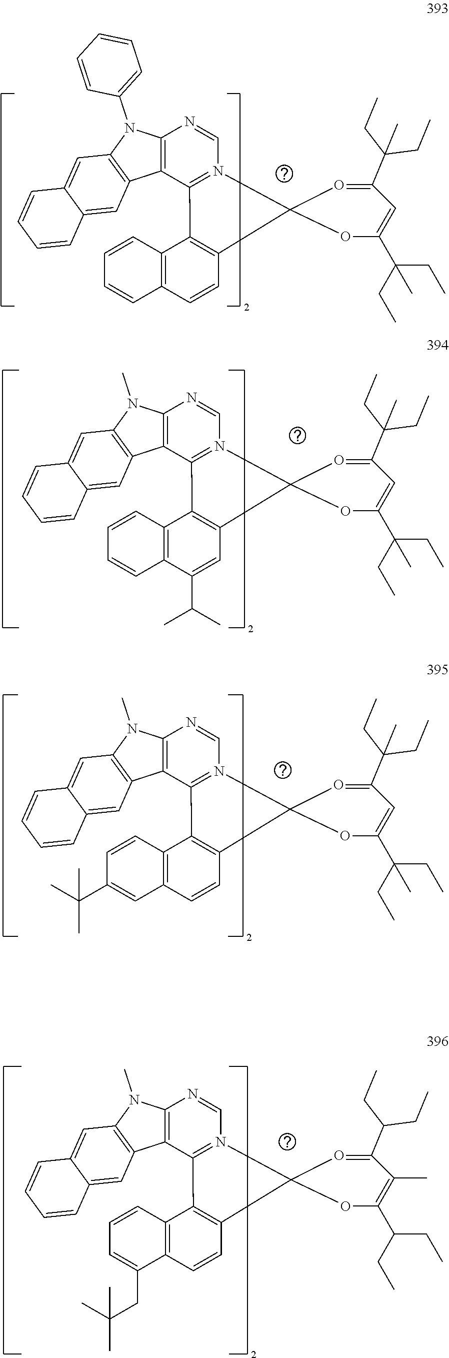

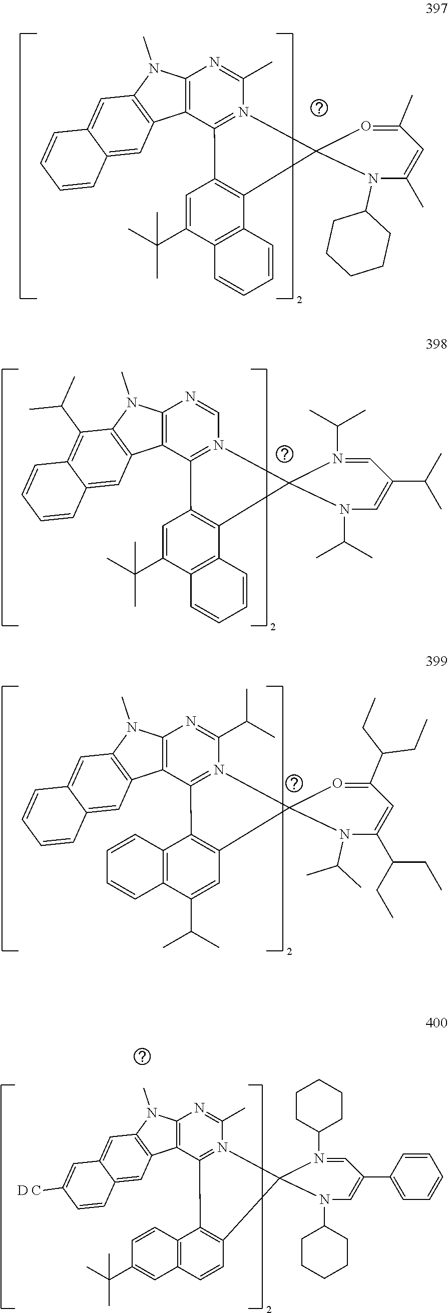

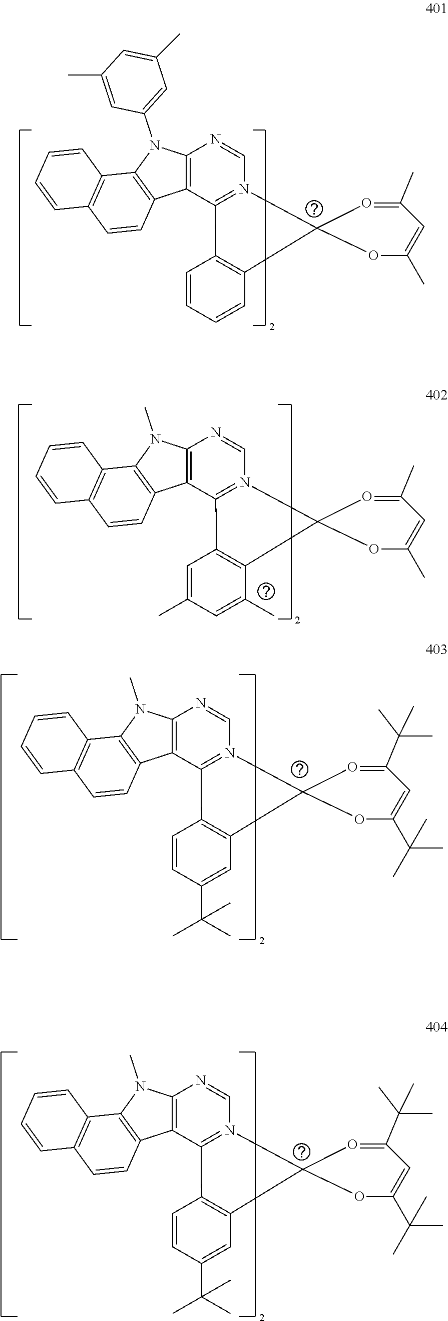

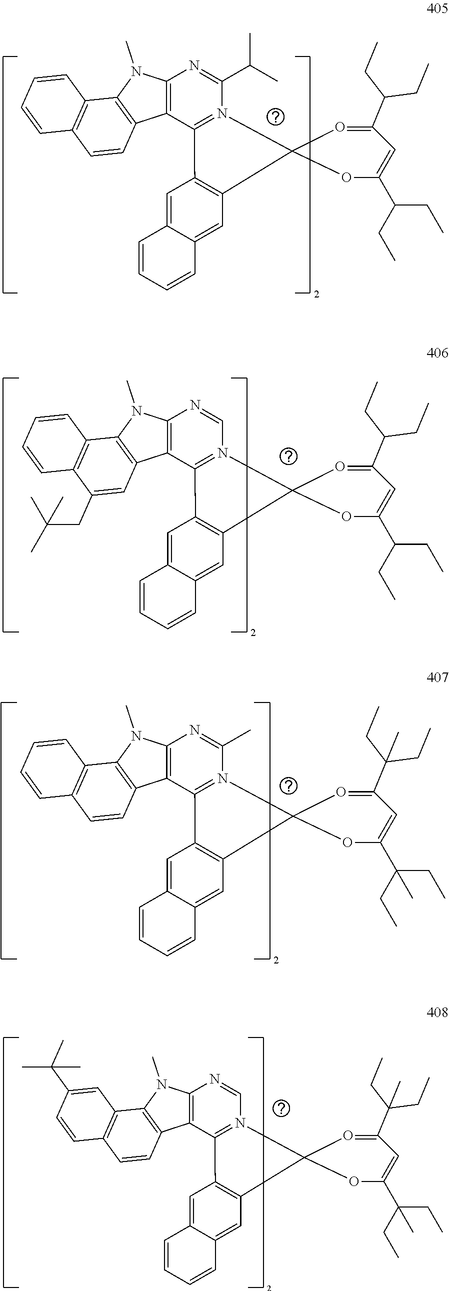

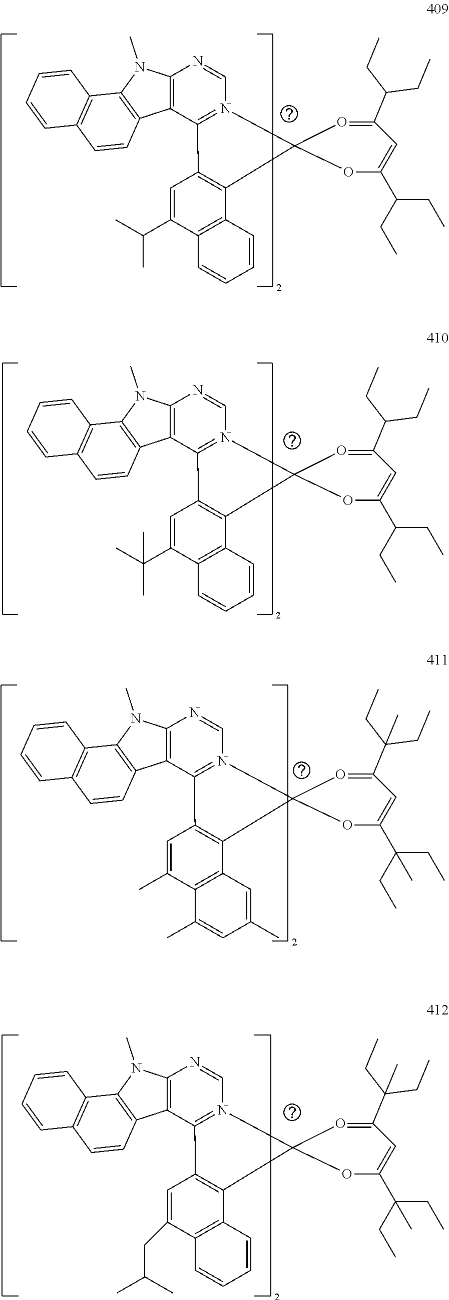

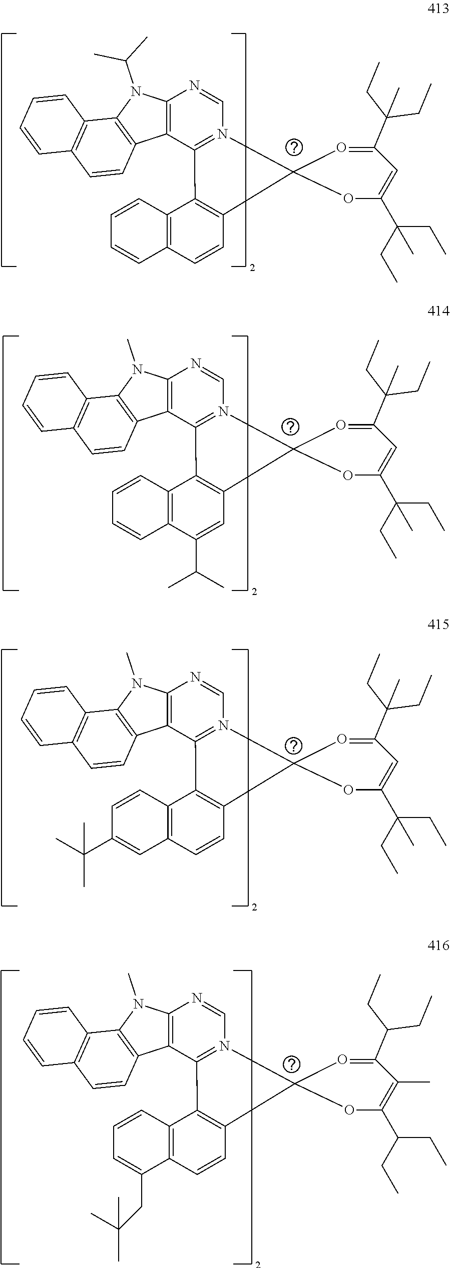

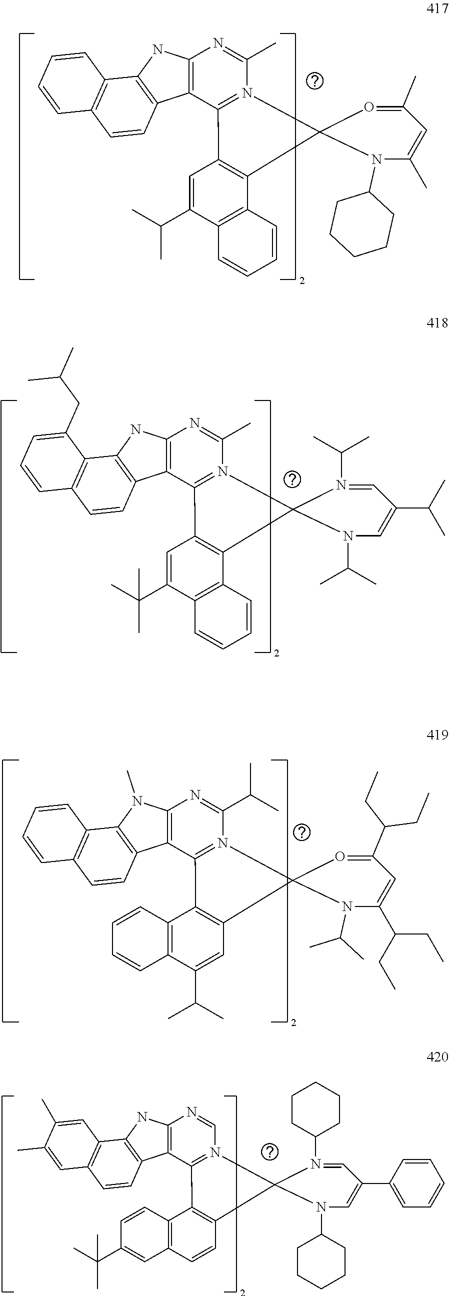

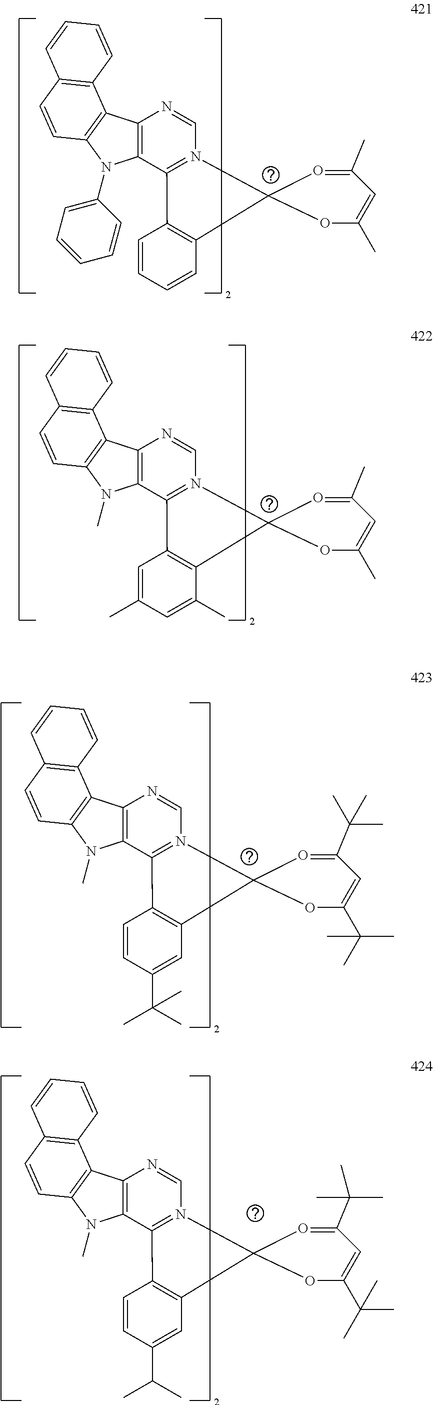

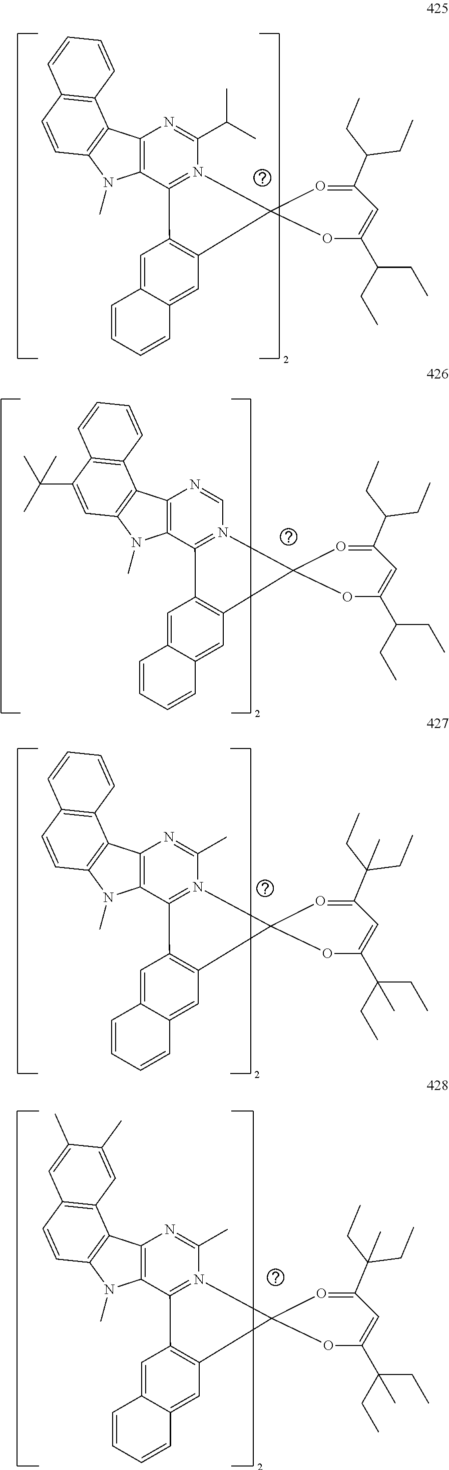

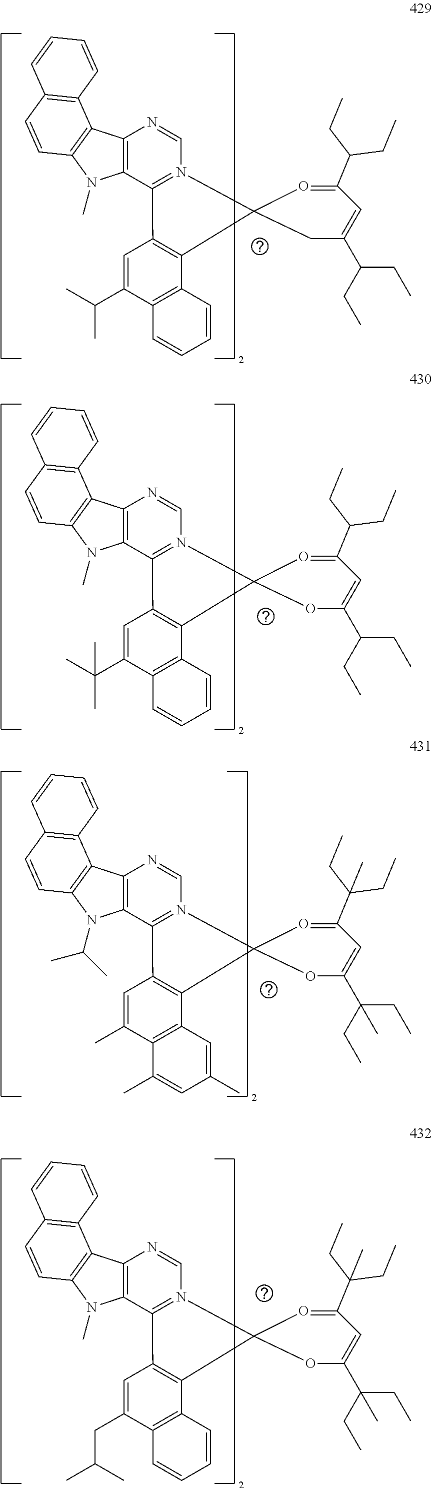

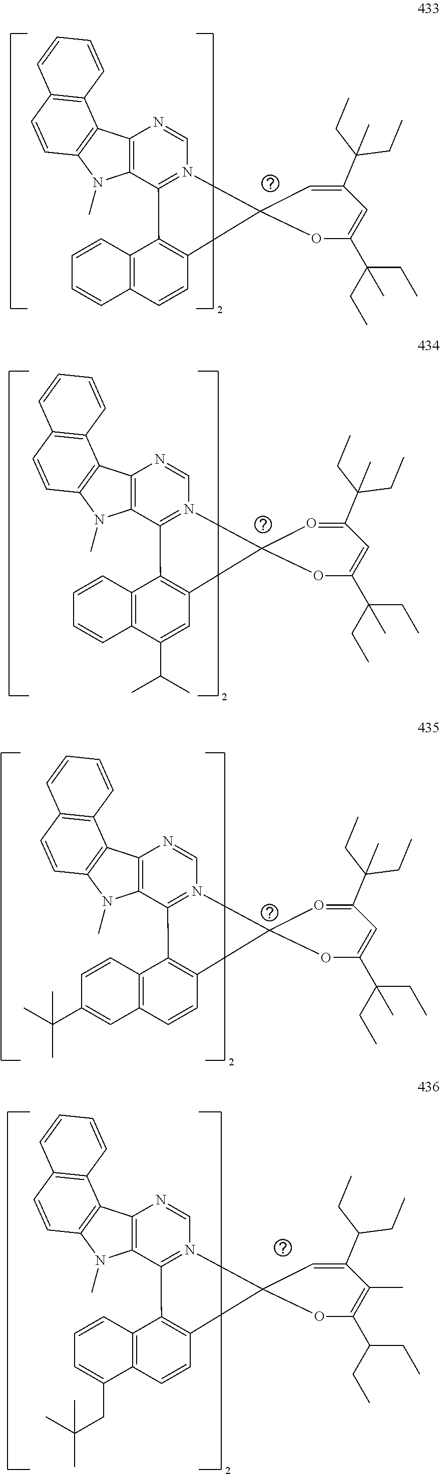

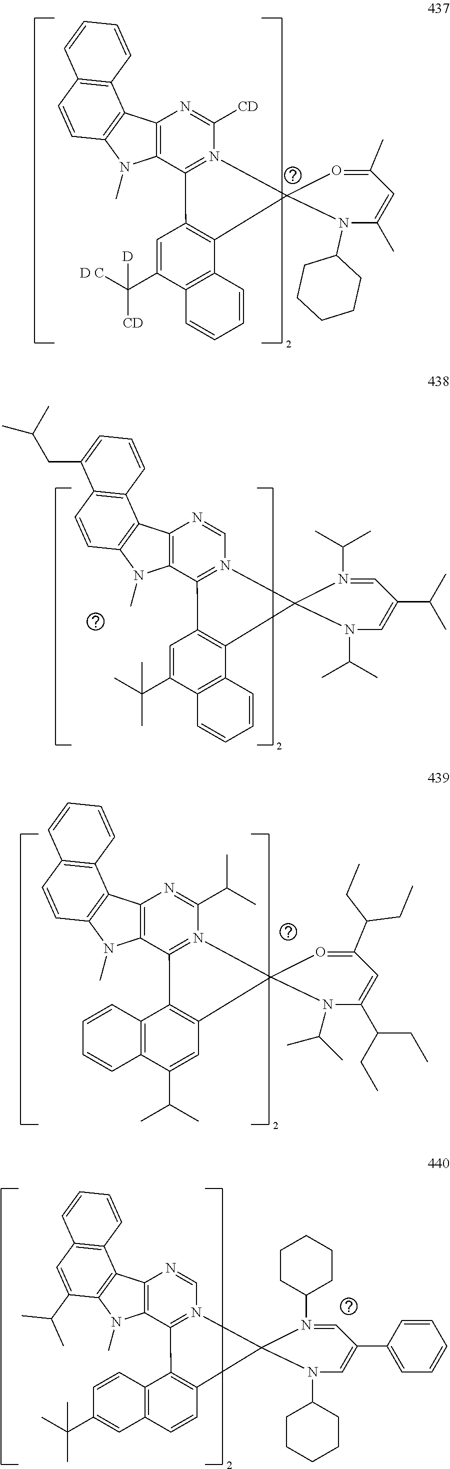

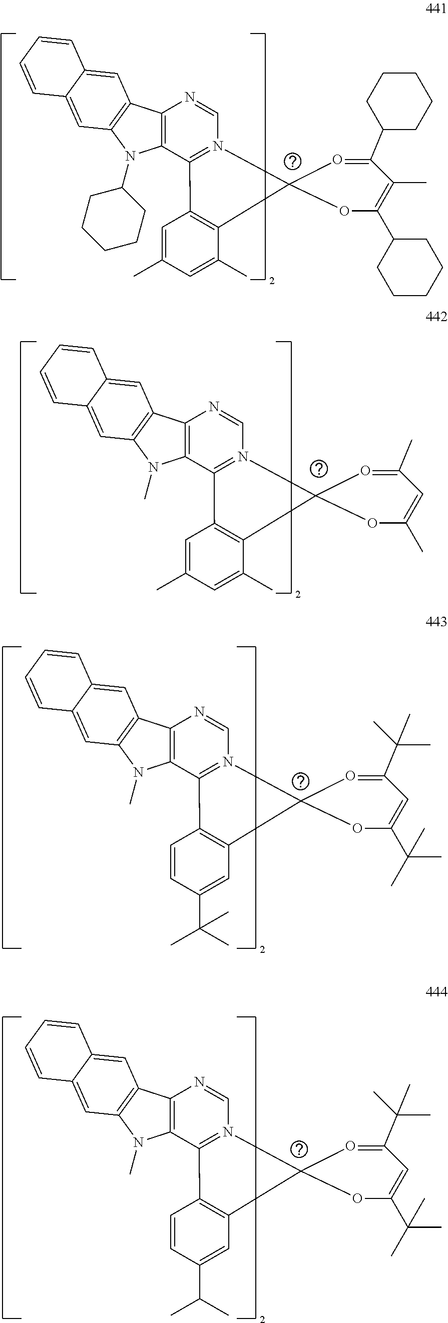

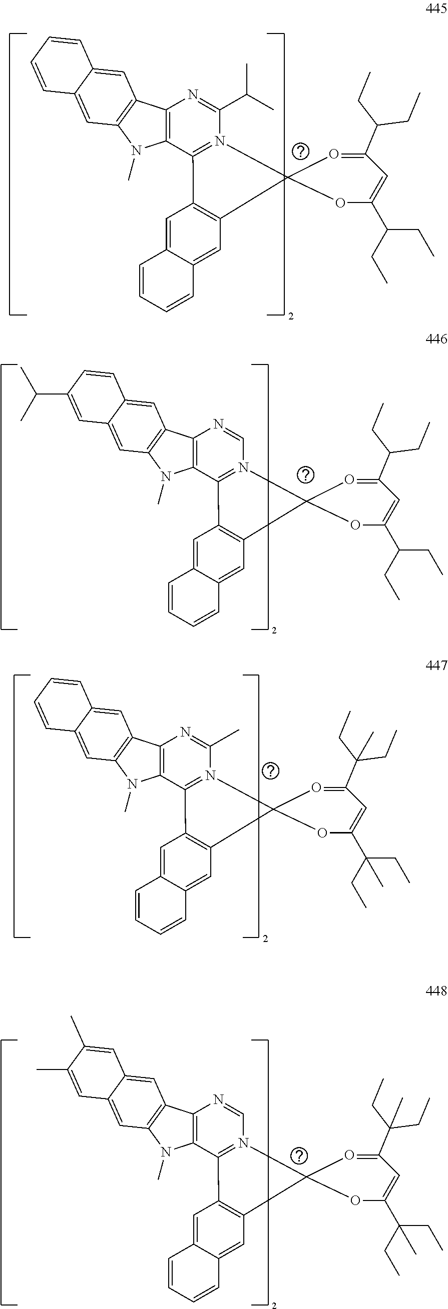

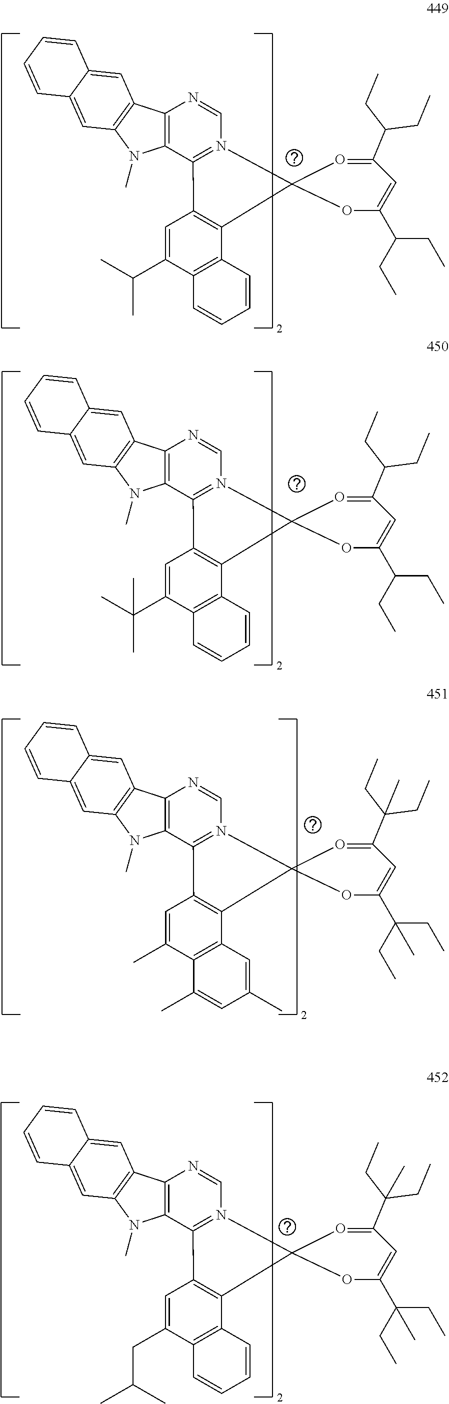

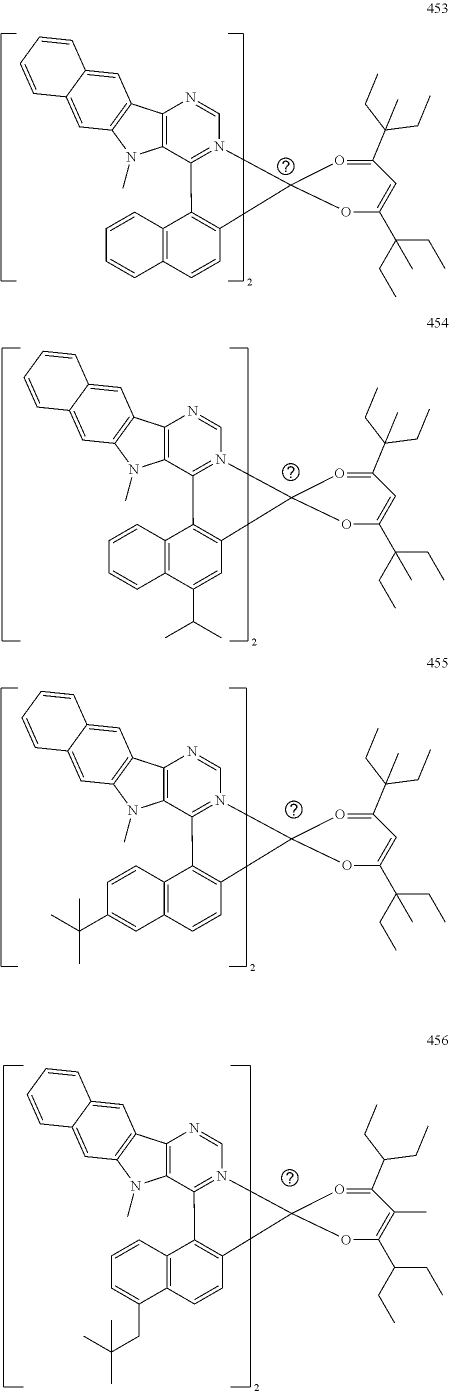

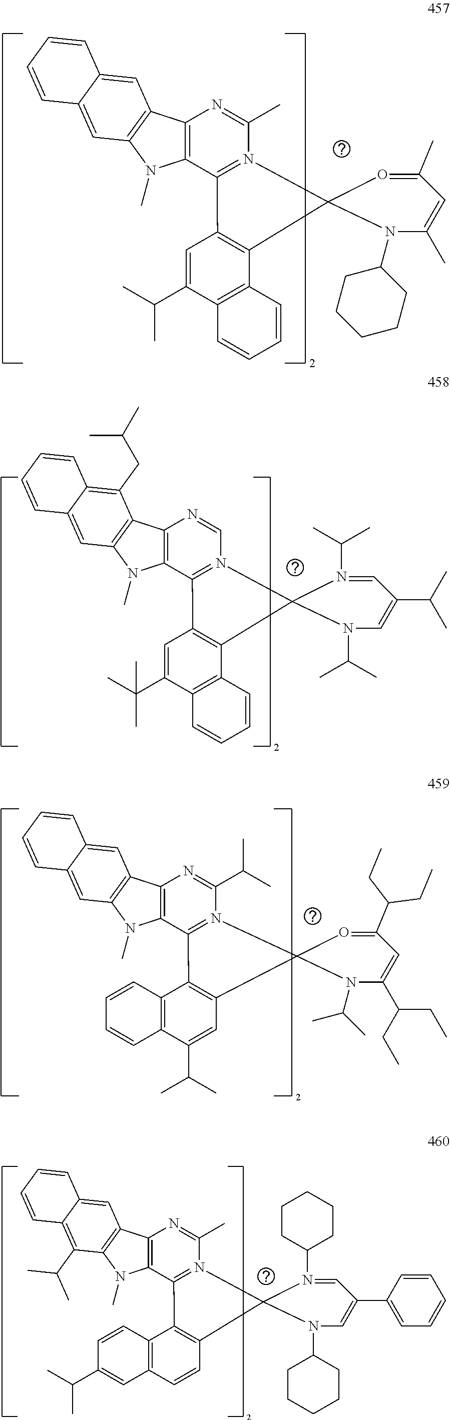

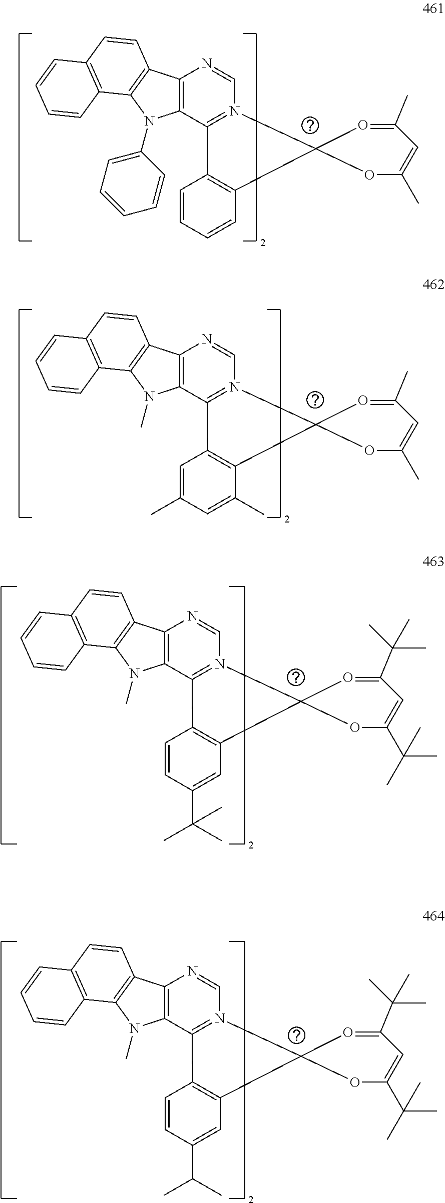

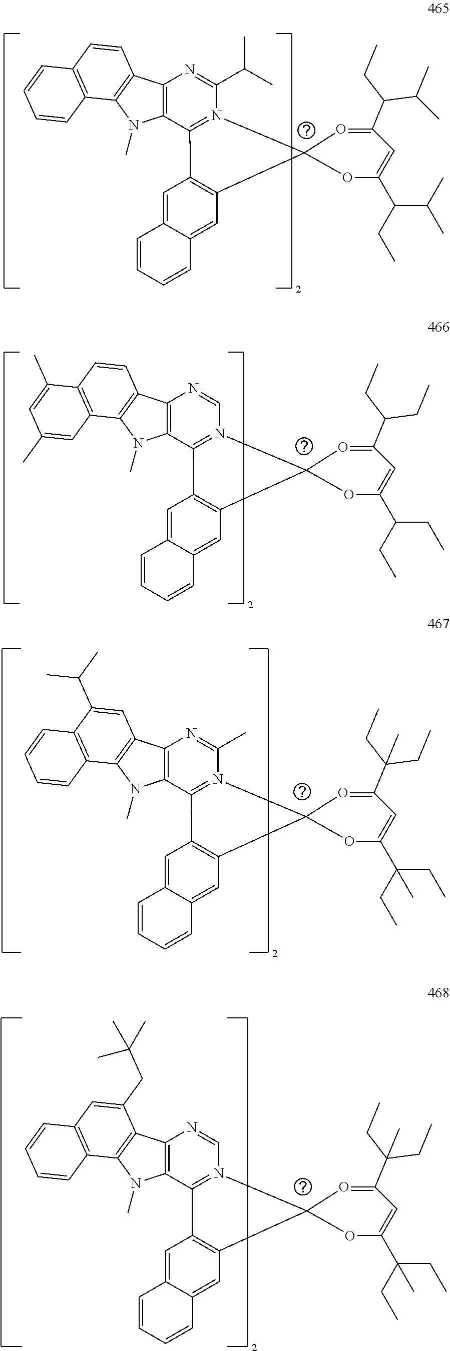

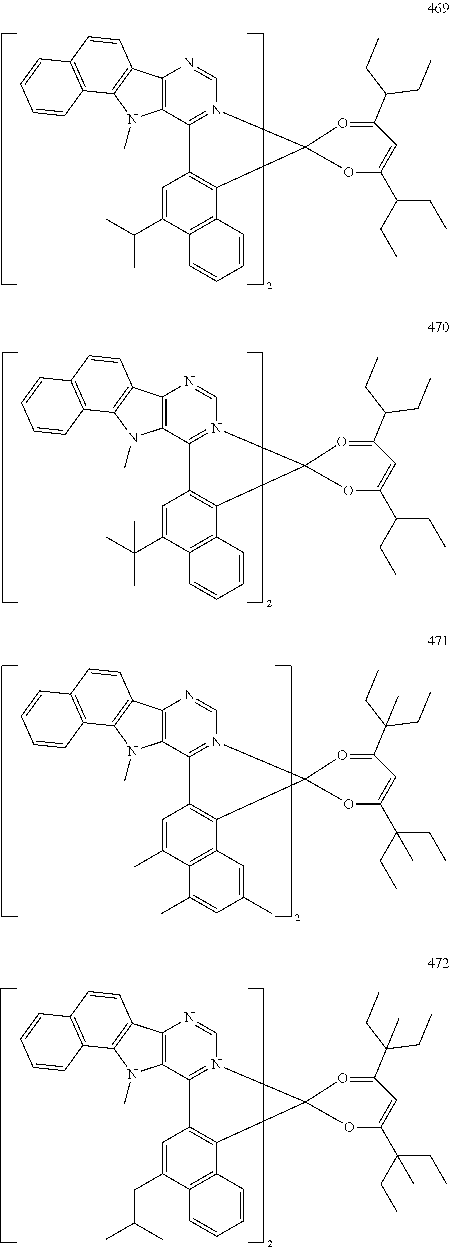

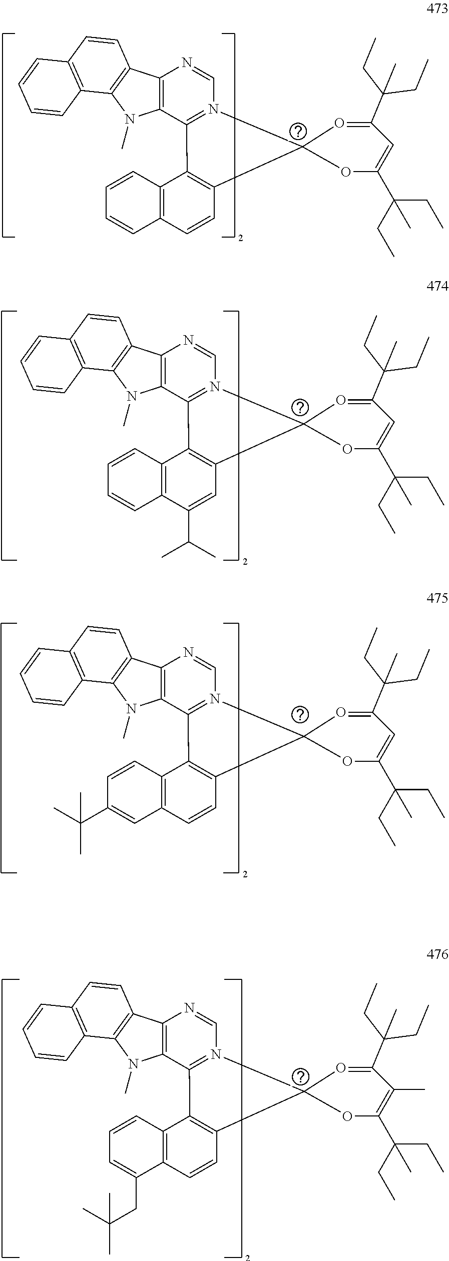

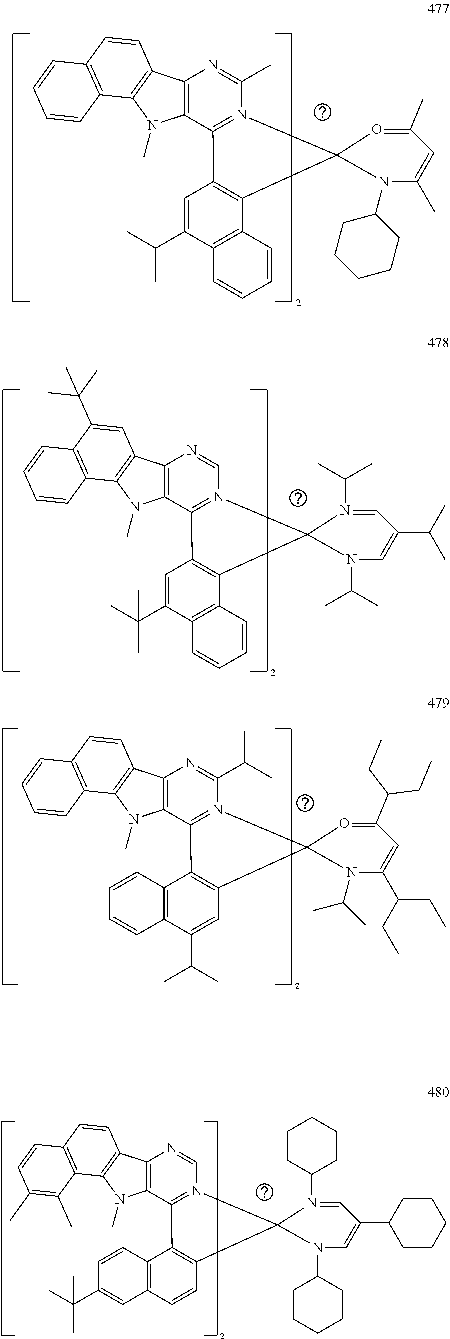

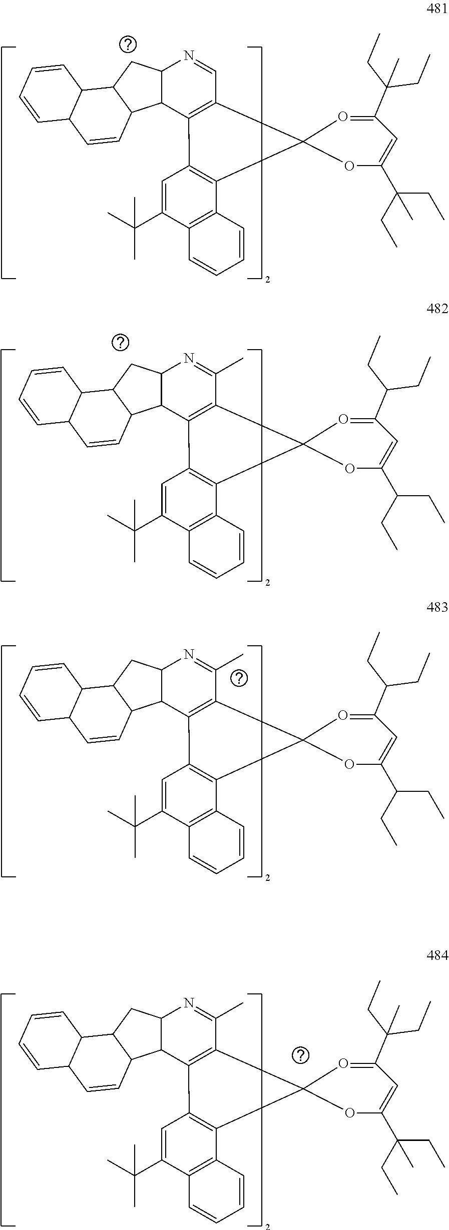

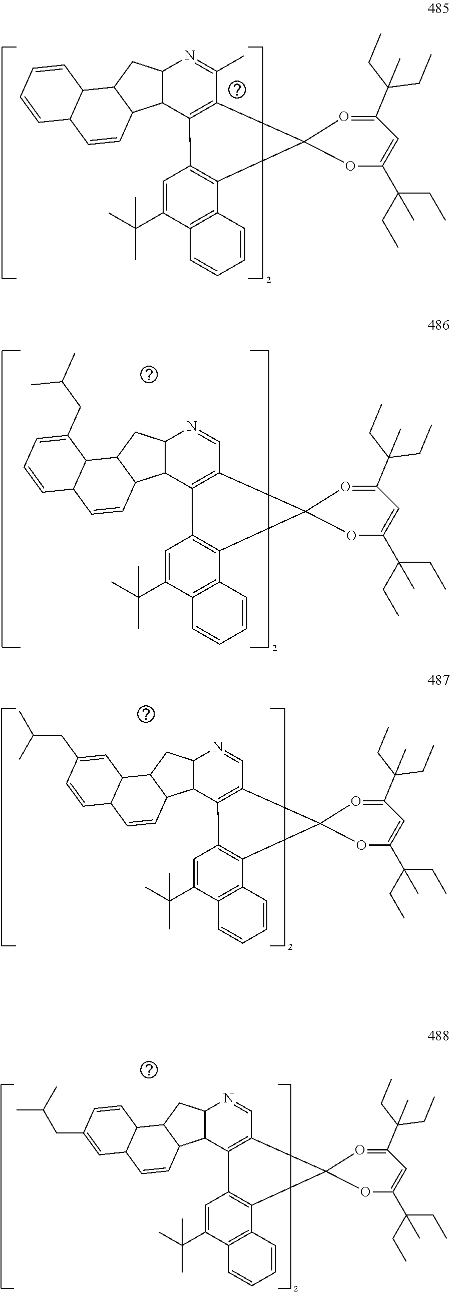

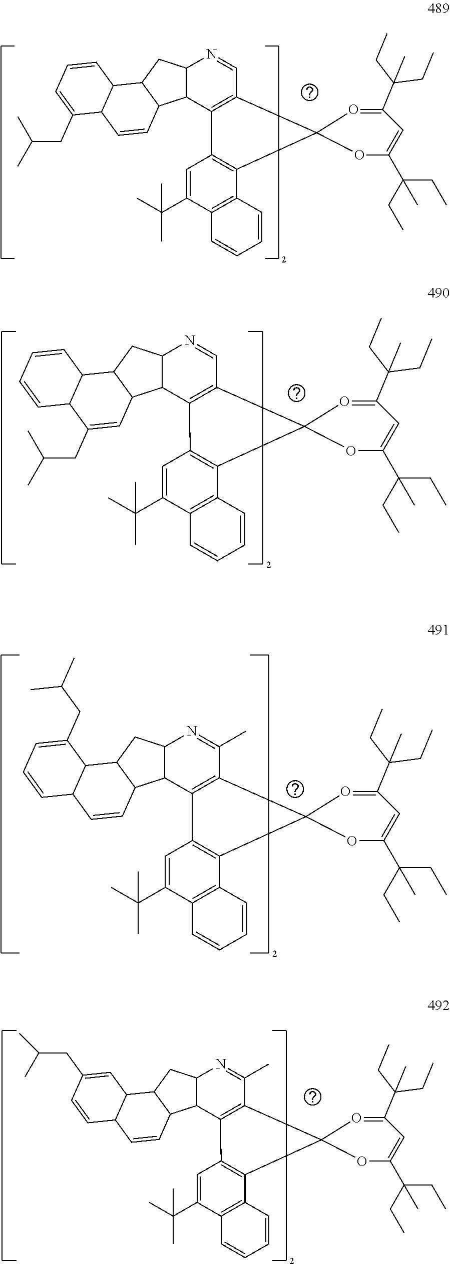

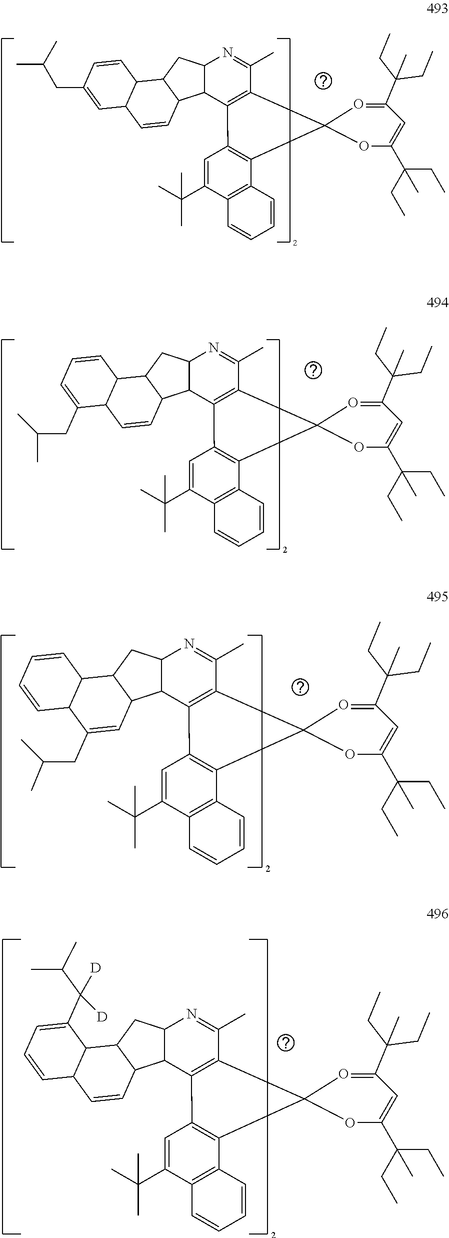

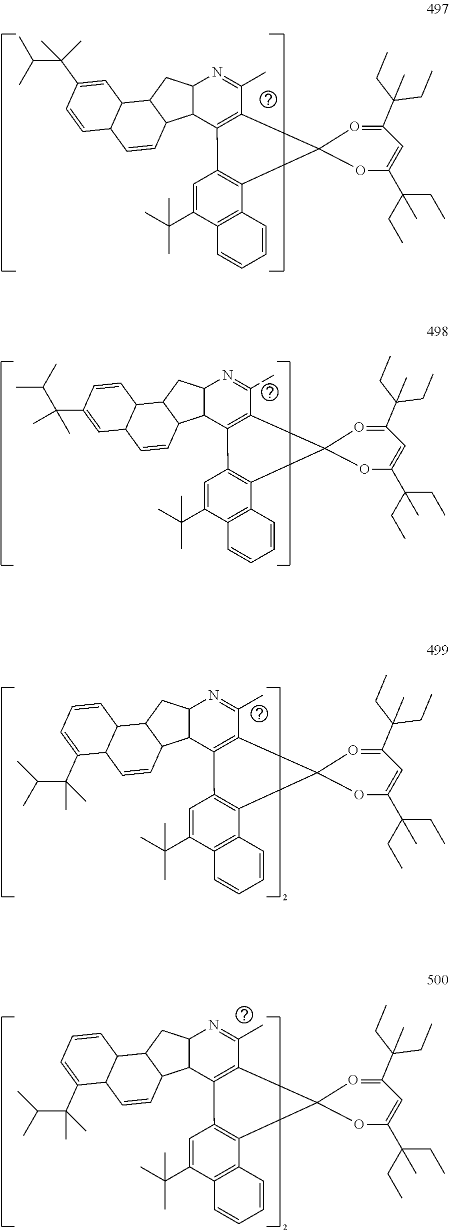

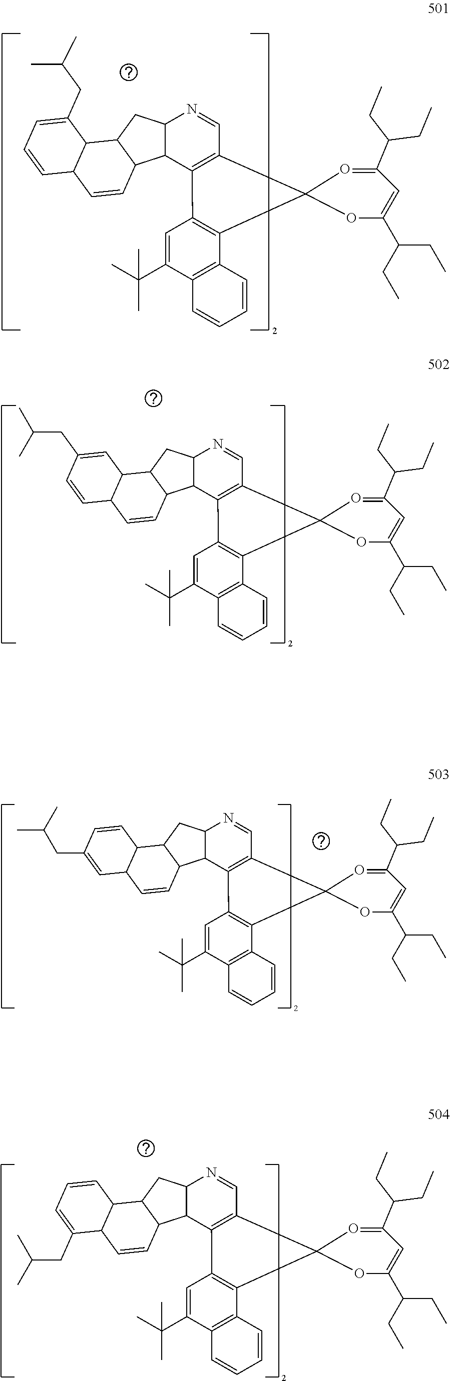

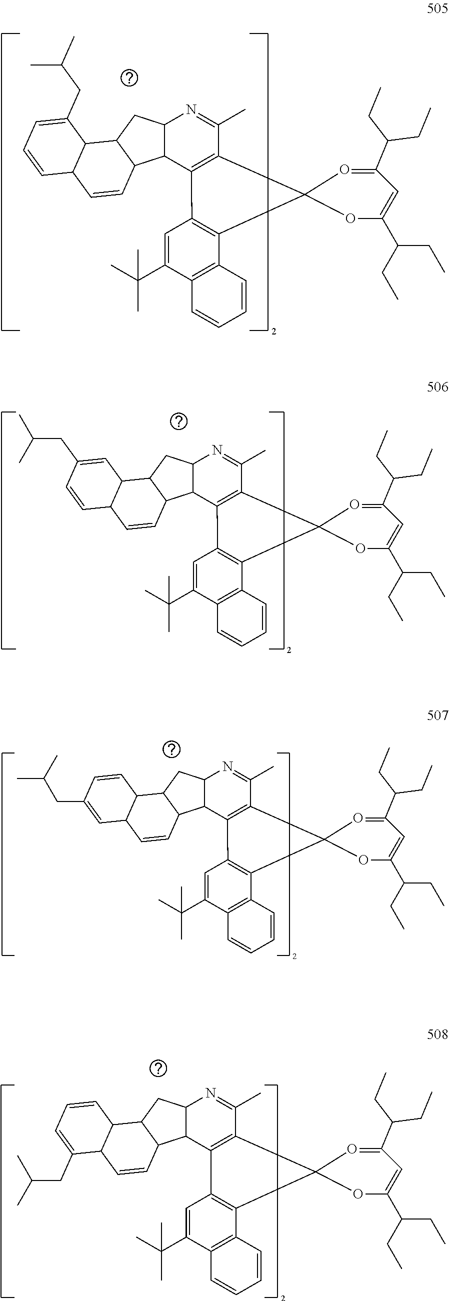

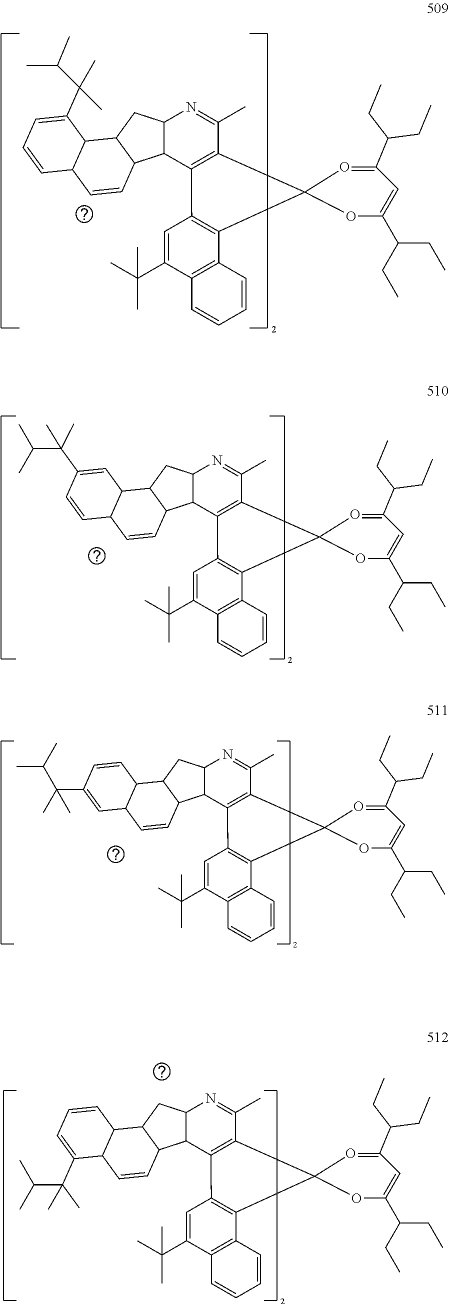

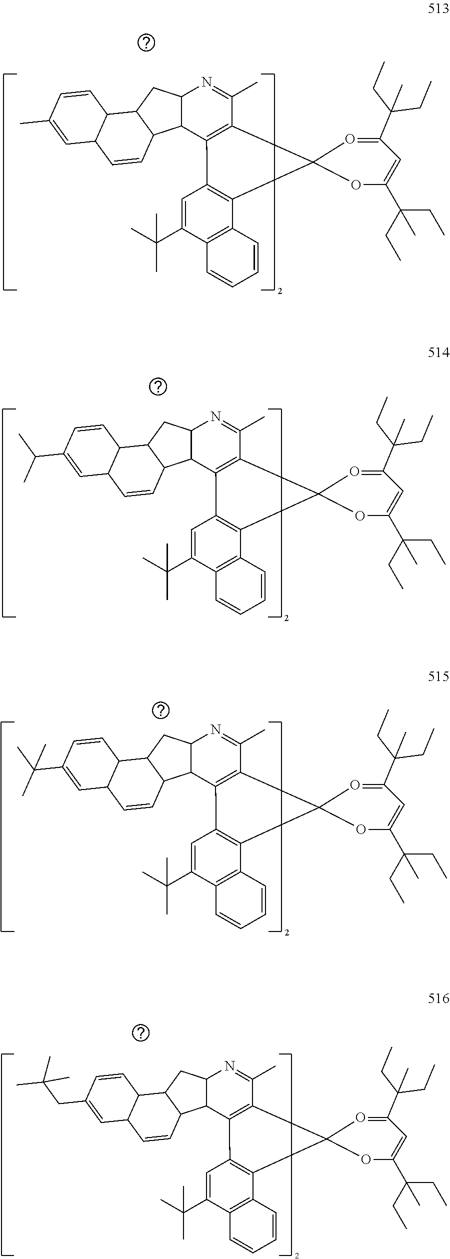

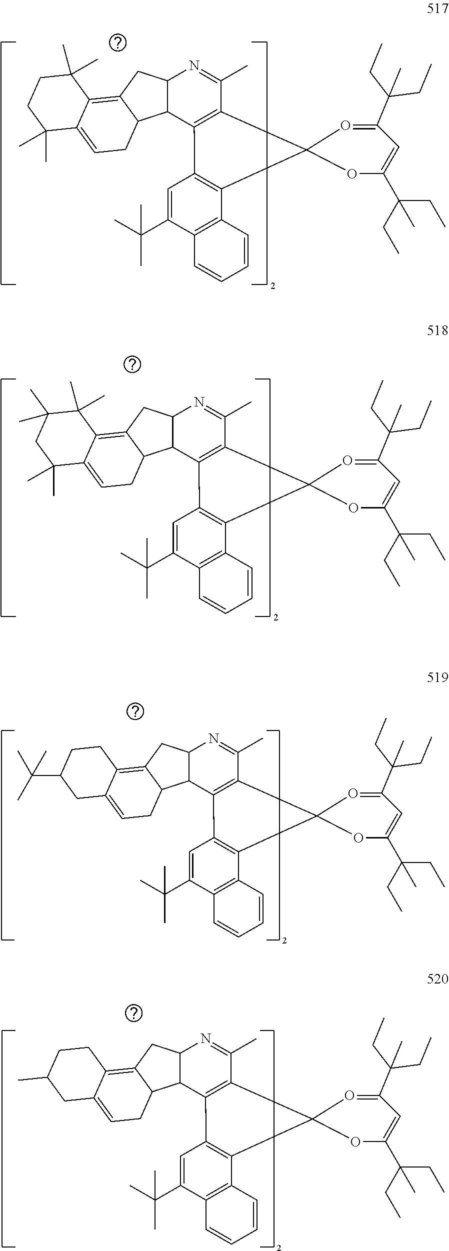

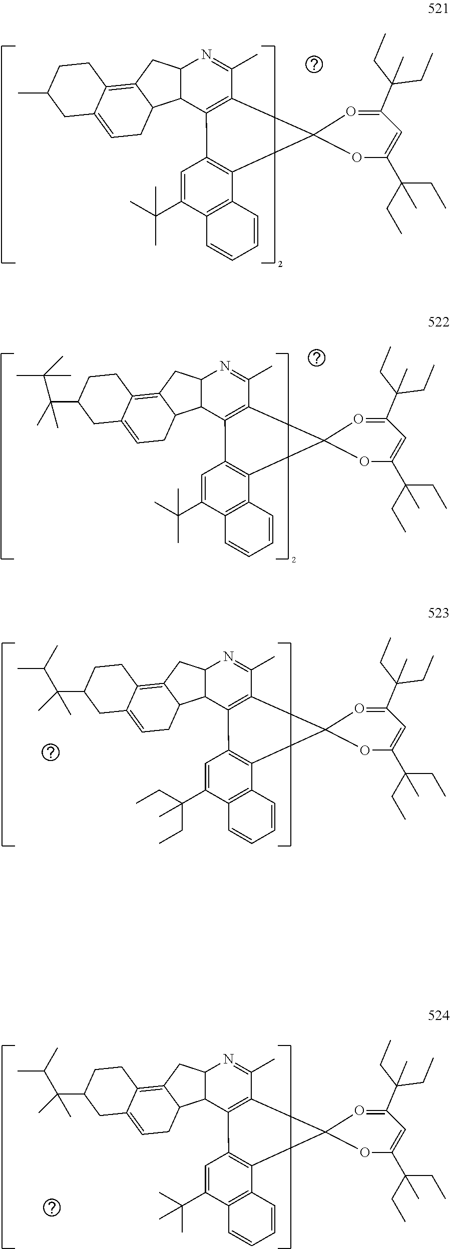

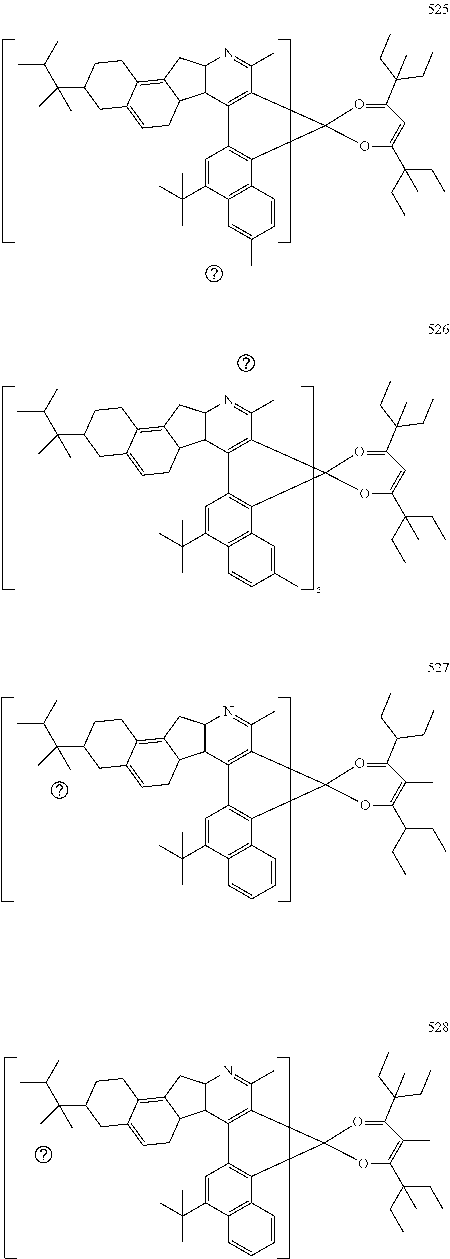

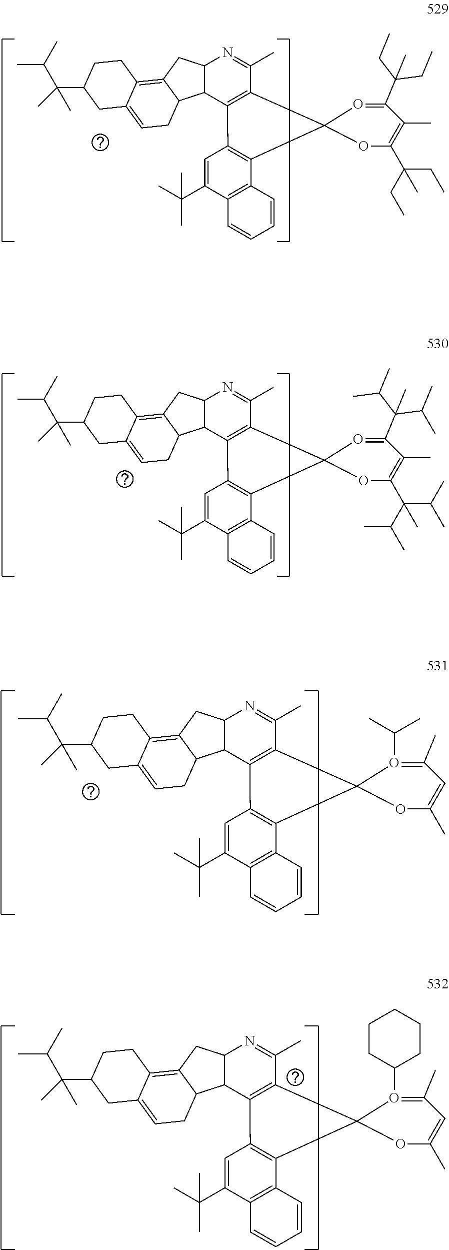

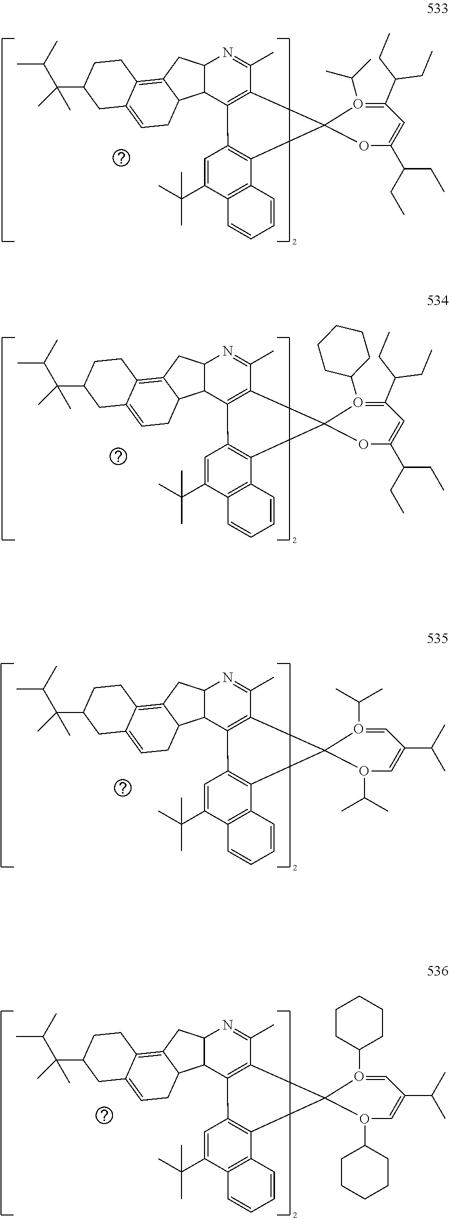

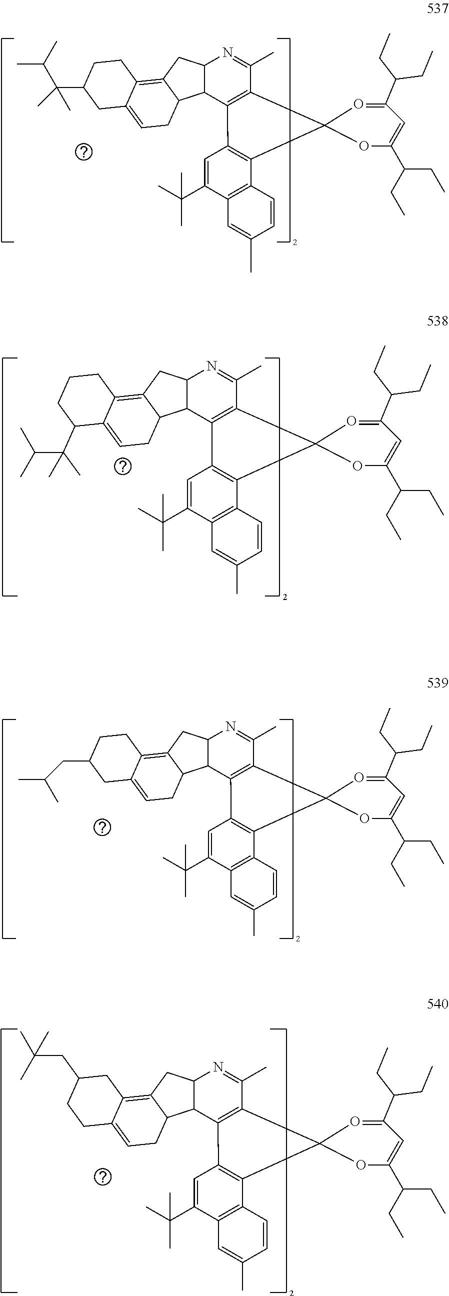

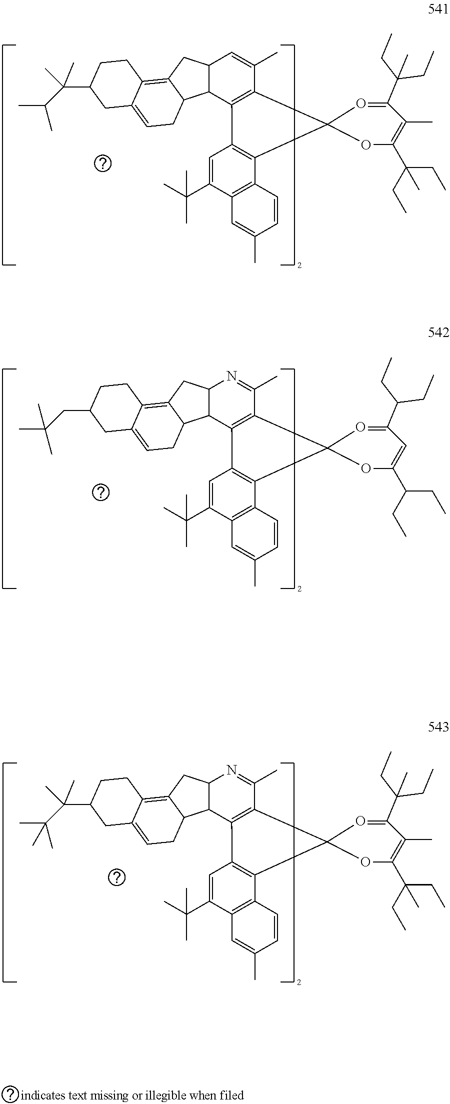

According to one implementation of the present disclosure, the organometallic compound represented by the Chemical Formula I of the present disclosure can be used as a red phosphorescent material or a green phosphorescent material, preferably, as the red phosphorescent material.

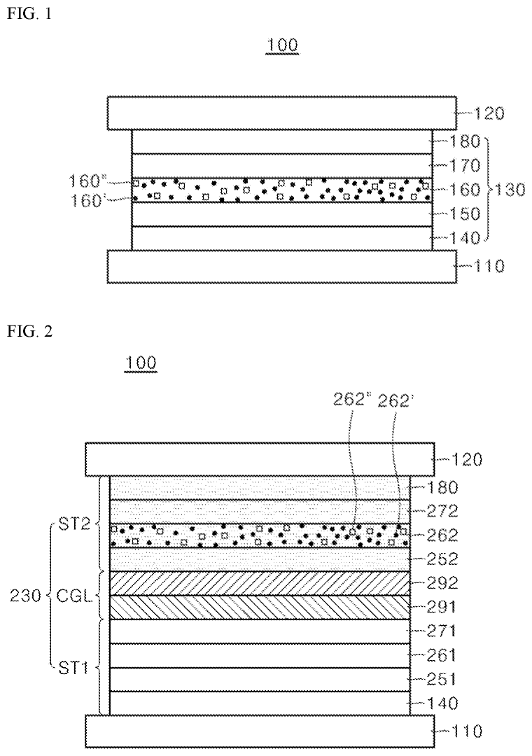

Referring to FIG. 1 according to one implementation of the present disclosure, an organic light-emitting diode 100 can be provided which includes a first electrode 110; a second electrode 120 facing the first electrode 110; and an organic layer 130 disposed between the first electrode 110 and the second electrode 120. The organic layer 130 can include a light-emitting layer 160, and the light-emitting layer 160 can include a host material 160′ and dopants 160″. The dopants 160″ can be made of the organometallic compound represented by the Chemical Formula I. In addition, in the organic light-emitting diode 100, the organic layer 130 disposed between the first electrode 110 and the second electrode 120 can be formed by sequentially stacking a hole injection layer 140 (HIL), a hole transport layer 150, (HTL), a light emission layer 160 (EML), an electron transport layer 170 (ETL) and an electron injection layer 180 (EIL) on the first electrode 110. The second electrode 120 can be formed on the electron injection layer 180, and a protective layer can be formed thereon.

Further, in FIG. 1, a hole transport auxiliary layer can be further added between the hole transport layer 150 and the light-emitting layer 160. The hole transport auxiliary layer can contain a compound having good hole transport properties, and can reduce a difference between HOMO energy levels of the hole transport layer 150 and the light-emitting layer 160 so as to adjust the hole injection properties. Thus, accumulation of holes at an interface between the hole transport auxiliary layer and the light-emitting layer 160 can be reduced, thereby reducing a quenching phenomenon in which excitons disappear at the interface due to polarons. Accordingly, deterioration of the element can be reduced and the element can be stabilized, thereby improving efficiency and lifespan thereof.

The first electrode 110 can act as a positive electrode, and can be made of ITO, IZO, tin-oxide, or zinc-oxide as a conductive material having a relatively large work function value. However, the present disclosure is not limited thereto.

The second electrode 120 can act as a negative electrode, and can include Al, Mg, Ca, or Ag as a conductive material having a relatively small work function value, or an alloy or combination thereof. However, the present disclosure is not limited thereto.

The hole injection layer 140 can be positioned between the first electrode 110 and the hole transport layer 150. The hole injection layer 140 can have a function of improving interface characteristics between the first electrode 110 and the hole transport layer 150, and can be selected from a material having appropriate conductivity. The hole injection layer 140 can include one or more compounds selected from a group consisting of MTDATA, CuPc, TCTA, HATCN, TDAPB, PEDOT/PSS, and N1,N1′-([1,1′-biphenyl]-4,4′-diyObis(N1,N4,N4)-triphenylbenzene-1,4-diamine). Preferably, the hole injection layer 140 can include N1,N1′-([1,1′-biphenyl]-4,4′-diyl)bis(N1,N4,N4-triphenylbenzene-1,4-diamine). However, the present disclosure is not limited thereto.

The hole transport layer 150 can be positioned adjacent to the light-emitting layer and between the first electrode 110 and the light-emitting layer 160. A material of the hole transport layer 150 can include a compound selected from a group consisting of TPD, NPB, CBP, N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)(phenyl)biphenyl)-4-amine, etc. Preferably, the material of the hole transport layer 150 can include NPB. However, the present disclosure is not limited thereto.

According to the present disclosure, the light-emitting layer 160 can be formed by doping a host material 160′ with the organometallic compound represented by the Chemical Formula I as a dopant 160″ in order to improve luminous efficiency of the diode 100. The dopant 160″ can be used as a green or red light emitting material, and preferably as a red phosphorescent material.

A doping concentration of the dopant 160″ according to the present disclosure can be adjusted to be within a range of 1 to 30 wt. % by weight based on a total weight of the host material 160′. However, the disclosure is not limited thereto. For example, the doping concentration can be in a range of 2 to 20 wt. %, for example, 3 to 15 wt. %, for example, 5 to 10 wt. %, for example, 3 to 8 wt. %, for example, 2 to 6 wt. %, for example, 2 to 5 wt. %, or for example, 2 to 3 wt. %.

The light-emitting layer 160 according to the present disclosure contains the host material 160′ which is known in the art and can achieve an effect of the present disclosure while the layer 160 contains the organometallic compound represented by the Chemical Formula I as the dopant 160″. For example, in accordance with the present disclosure, the host material 160′ can include a compound containing a carbazole group, and can preferably include one host material selected from a group consisting of CBP (carbazole biphenyl), mCP (1,3-bis(carbazol-9-yl), and the like. However, the disclosure is not limited thereto.

Further, the electron transport layer 170 and the electron injection layer 180 can be sequentially stacked between the light-emitting layer 160 and the second electrode 120. A material of the electron transport layer 170 requires high electron mobility such that electrons can be stably supplied to the light-emitting layer under smooth electron transport.

For example, the material of the electron transport layer 170 can include a compound selected from a group consisting of Alq3 (tris(8-hydroxyquinolino)aluminum), Liq (8-hydroxyquinolinolatolithium), PBD (2-(4-biphenylyl)-5-(4-tert-butylphenyl)-1,3,4oxadiazole), TAZ (3-(4-biphenyl)4-phenyl-5-tert-butylphenyl-1,2,4-triazole), spiro-PBD, BAlq (bis(2-methyl-8-quinolinolate)-4-(phenylphenolato)aluminum), SAlq, TPBi (2,2′,2-(1,3,5-benzinetriyl)-tris(1-phenyl-1-H-benzimidazole), oxadiazole, triazole, phenanthroline, benzoxazole, benzthiazole, and 2-(4-(9,10-di(naphthalen-2-yl)anthracen-2-yl)phenyl) phenyl-1H-benzo[d]imidazole. Preferably, the material of the electron transport layer 170 can include 2-(4-(9,10-di(naphthalen-2-yl)anthracen-2-yl)phenyl)-1-phenyl-1H-benzo[d]imidazole. However, the present disclosure is not limited thereto.

The electron injection layer 180 serves to facilitate electron injection, and a material of the electron injection layer can include a compound selected from a group consisting of Alq3 (tris(8-hydroxyquinolino)aluminum), PBD, TAZ, Spiro-PBD, BAlq, SAlq, etc. However, the present disclosure is not limited thereto. Alternatively, the electron injection layer 180 can be made of a metal compound. The metal compound can include, for example, one or more selected from a group consisting of Liq, LiF, NaF, KF, RbF, CsF, FrF, BeF₂, MgF₂, CaF₂, SrF₂, BaF₂ and RaF₂. However, the present disclosure is not limited thereto.

The organic light-emitting diode according to the present disclosure can be embodied as a white light-emitting diode having a tandem structure. The tandem organic light-emitting diode according to an illustrative embodiment of the present disclosure can be formed in a structure in which adjacent ones of two or more light-emitting stacks are connected to each other via a charge generation layer (CGL). The organic light-emitting diode can include at least two light-emitting stacks disposed on a substrate, wherein each of the at least two light-emitting stacks includes first and second electrodes facing each other, and the light-emitting layer disposed between the first and second electrodes to emit light in a specific wavelength band. The plurality of light-emitting stacks can emit light of the same color or different colors. In addition, one or more light-emitting layers can be included in one light-emitting stack, and the plurality of light-emitting layers can emit light of the same color or different colors.

In this case, the light-emitting layer included in at least one of the plurality of light-emitting stacks can contain the organometallic compound represented by the Chemical Formula I according to the present disclosure as the dopants. Adjacent ones of the plurality of light-emitting stacks in the tandem structure can be connected to each other via the charge generation layer CGL including an N-type charge generation layer and a P-type charge generation layer.

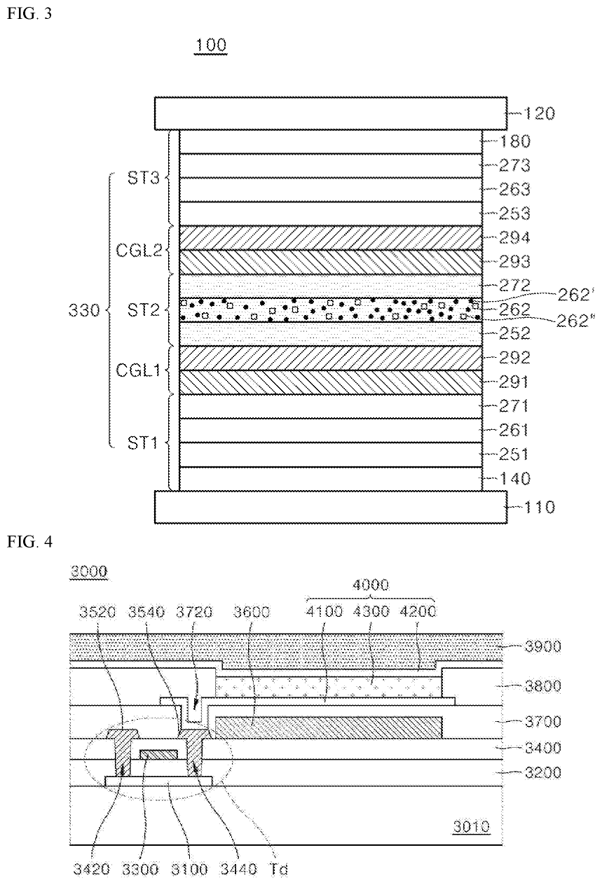

FIG. 2 and FIG. 3 are cross-sectional views schematically showing an organic light-emitting diode in a tandem structure having two light-emitting stacks and an organic light-emitting diode in a tandem structure having three light-emitting stacks, respectively, according to some implementations of the present disclosure.

As shown in FIG. 2, an organic light-emitting diode 100 according to the present disclosure include a first electrode 110 and a second electrode 120 facing each other, and an organic layer 230 positioned between the first electrode 110 and the second electrode 120. The organic layer 230 can be positioned between the first electrode 110 and the second electrode 120 and can include a first light-emitting stack ST1 including a first light-emitting layer 261, a second light-emitting stack ST2 positioned between the first light-emitting stack ST1 and the second electrode 120 and including a second light-emitting layer 262, and the charge generation layer CGL positioned between the first and second light-emitting stacks ST1 and ST2. The charge generation layer CGL can include an N-type charge generation layer 291 and a P-type charge generation layer 292. At least one of the first light-emitting layer 261 and the second light-emitting layer 262 can contain the organometallic compound represented by the Chemical Formula I according to the present disclosure as the dopants. For example, as shown in FIG. 2, the second light-emitting layer 262 of the second light-emitting stack ST2 can contain a host material 262′, and dopants 262″ made of the organometallic compound represented by the Chemical Formula I doped therein. In FIG. 2, each of the first and second light-emitting stacks ST1 and ST2 can further include, in addition to each of the first light-emitting layer 261 and the second light-emitting layer 262, an additional light-emitting layer.

As shown in FIG. 3, the organic light-emitting diode 100 according to the present disclosure include the first electrode 110 and the second electrode 120 facing each other, and an organic layer 330 positioned between the first electrode 110 and the second electrode 120. The organic layer 330 can be positioned between the first electrode 110 and the second electrode 120 and can include the first light-emitting stack ST1 including the first light-emitting layer 261, the second light-emitting stack ST2 including the second light-emitting layer 262, a third light-emitting stack ST3 including a third light-emitting layer 263, a first charge generation layer CGL1 positioned between the first and second light-emitting stacks ST1 and ST2, and a second charge generation layer CGL2 positioned between the second and third light-emitting stacks ST2 and ST3. The first charge generation layer CGL1 can include a N-type charge generation layers 291 and a P-type charge generation layer 292. The second charge generation layer CGL2 can include a N-type charge generation layers 293 and a P-type charge generation layer 294. At least one of the first light-emitting layer 261, the second light-emitting layer 262, and the third light-emitting layer 263 can contain the organometallic compound represented by the Chemical Formula I according to the present disclosure as the dopants. For example, as shown in FIG. 3, the second light-emitting layer 262 of the second light-emitting stack ST2 can contain the host material 262′, and the dopants 262″ made of the organometallic compound represented by the Chemical Formula I doped therein. In FIG. 3, each of the first, second and third light-emitting stacks ST1, ST2 and ST3 can further include an additional light-emitting layer, in addition to each of the first light-emitting layer 261, the second light-emitting layer 262 and the third light-emitting layer 263.

Furthermore, an organic light-emitting diode according to an embodiment of the present disclosure can include a tandem structure in which four or more light-emitting stacks and three or more charge generating layers are disposed between the first electrode and the second electrode.

The organic light-emitting diode according to the present disclosure can be used as a light-emitting element of each of an organic light-emitting display device and a lighting device. In one implementation, FIG. 4 is a cross-sectional view schematically illustrating an organic light-emitting display device including the organic light-emitting diode according to some embodiments of the present disclosure as a light-emitting element thereof.

As shown in FIG. 4, an organic light-emitting display device 3000 includes a substrate 3010, an organic light-emitting diode 4000, and an encapsulation film 3900 covering the organic light-emitting diode 4000. A driving thin-film transistor Td as a driving element, and the organic light-emitting diode 4000 connected to the driving thin-film transistor Td are positioned on the substrate 3010.

In FIG. 4, a gate line and a data line that intersect each other to define a pixel area, a power line extending parallel to and spaced from one of the gate line and the data line, a switching thin film transistor connected to the gate line and the data line, and a storage capacitor connected to one electrode of the thin film transistor and the power line are further formed on the substrate 3010.

The driving thin-film transistor Td is connected to the switching thin film transistor, and includes a semiconductor layer 3100, a gate electrode 3300, a source electrode 3520, and a drain electrode 3540.

The semiconductor layer 3100 can be formed on the substrate 3010 and can be made of an oxide semiconductor material or polycrystalline silicon. When the semiconductor layer 3100 is made of an oxide semiconductor material, a light-shielding pattern can be formed under the semiconductor layer 3100. The light-shielding pattern prevents light from being incident into the semiconductor layer 3100 to prevent the semiconductor layer 3100 from being deteriorated due to the light. Alternatively, the semiconductor layer 3100 can be made of polycrystalline silicon. In this case, both edges of the semiconductor layer 3100 can be doped with impurities.

The gate insulating layer 3200 made of an insulating material is formed over an entirety of a surface of the substrate 3010 and on the semiconductor layer 3100. The gate insulating layer 3200 can be made of an inorganic insulating material such as silicon oxide or silicon nitride.

The gate electrode 3300 made of a conductive material such as a metal is formed on the gate insulating layer 3200 and corresponds to a center of the semiconductor layer 3100. The gate electrode 3300 is connected to the switching thin film transistor.

The interlayer insulating layer 3400 made of an insulating material is formed over the entirety of the surface of the substrate 3010 and on the gate electrode 3300. The interlayer insulating layer 3400 can be made of an inorganic insulating material such as silicon oxide or silicon nitride, or an organic insulating material such as benzocyclobutene or photo-acryl.

The interlayer insulating layer 3400 has first and second semiconductor layer contact holes 3420 and 3440 defined therein respectively exposing both opposing sides of the semiconductor layer 3100. The first and second semiconductor layer contact holes 3420 and 3440 are respectively positioned on both opposing sides of the gate electrode 3300 and are spaced apart from the gate electrode 3300.

The source electrode 3520 and the drain electrode 3540 made of a conductive material such as metal are formed on the interlayer insulating layer 3400. The source electrode 3520 and the drain electrode 3540 are positioned around the gate electrode 3300, and are spaced apart from each other, and respectively contact both opposing sides of the semiconductor layer 3100 via the first and second semiconductor layer contact holes 3420 and 3440, respectively. The source electrode 3520 is connected to a power line.

The semiconductor layer 3100, the gate electrode 3300, the source electrode 3520, and the drain electrode 3540 constitute the driving thin-film transistor Td. The driving thin-film transistor Td has a coplanar structure in which the gate electrode 3300, the source electrode 3520, and the drain electrode 3540 are positioned on top of the semiconductor layer 3100.

Alternatively, the driving thin-film transistor Td can have an inverted staggered structure in which the gate electrode is disposed under the semiconductor layer while the source electrode and the drain electrode are disposed above the semiconductor layer. In this case, the semiconductor layer can be made of amorphous silicon. In one example, the switching thin-film transistor can have substantially the same structure as that of the driving thin-film transistor (Td).

In one example, the organic light-emitting display device 3000 can include a color filter 3600 absorbing the light generated from the electroluminescent element (light-emitting diode) 4000. For example, the color filter 3600 can absorb red (R), green (G), blue (B), and white (W) light. In this case, red, green, and blue color filter patterns that absorb light can be formed separately in different pixel areas. Each of these color filter patterns can be disposed to overlap each organic layer 4300 of the organic light-emitting diode 4000 to emit light of a wavelength band corresponding to each color filter. Adopting the color filter 3600 can allow the organic light-emitting display device 3000 to realize full-color.

For example, when the organic light-emitting display device 3000 is of a bottom emission type, the color filter 3600 absorbing light can be positioned on a portion of the interlayer insulating layer 3400 corresponding to the organic light-emitting diode 4000. In an optional embodiment, when the organic light-emitting display device 3000 is of a top emission type, the color filter can be positioned on top of the organic light-emitting diode 4000, for example, on top of a second electrode 4200. For example, the color filter 3600 can be formed to have a thickness of 2 to 5 μm.

In one example, a planarization layer 3700 having a drain contact hole 3720 defined therein exposing the drain electrode 3540 of the driving thin-film transistor Td is formed to cover the driving thin-film transistor Td.

On the planarization layer 3700, each first electrode 4100 connected to the drain electrode 3540 of the driving thin-film transistor Td via the drain contact hole 3720 is formed individually in each pixel area.

The first electrode 4100 can act as a positive electrode (anode), and can be made of a conductive material having a relatively large work function value. For example, the first electrode 4100 can be made of a transparent conductive material such as ITO, IZO or ZnO.

In one example, when the organic light-emitting display device 3000 is of a top-emission type, a reflective electrode or a reflective layer can be further formed under the first electrode 4100. For example, the reflective electrode or the reflective layer can be made of one of aluminum (Al), silver (Ag), nickel (Ni), and an aluminum-palladium-copper (APC) alloy.

A bank layer 3800 covering an edge of the first electrode 4100 is formed on the planarization layer 3700. The bank layer 3800 exposes a center of the first electrode 4100 corresponding to the pixel area.

An organic layer 4300 is formed on the first electrode 4100. If necessary, the organic light-emitting diode 4000 can have a tandem structure. Regarding the tandem structure, reference can be made to FIG. 2 to FIG. 4 which show some embodiments of the present disclosure, and the above descriptions thereof.

The second electrode 4200 is formed on the substrate 3010 on which the organic layer 4300 has been formed. The second electrode 4200 is disposed over the entirety of the surface of the display area and is made of a conductive material having a relatively small work function value and can be used as a negative electrode (a cathode). For example, the second electrode 4200 can be made of one of aluminum (Al), magnesium (Mg), and an aluminum-magnesium alloy (Al—Mg).

The first electrode 4100, the organic layer 4300, and the second electrode 4200 constitute the organic light-emitting diode 4000.

An encapsulation film 3900 is formed on the second electrode 4200 to prevent external moisture from penetrating into the organic light-emitting diode 4000. In FIG. 4, the encapsulation film 3900 can have a triple-layer structure in which a first inorganic layer, an organic layer, and an inorganic layer are sequentially stacked. However, the present disclosure is not limited thereto.

Hereinafter, Preparation Examples and Present Examples of the present disclosure will be described. However, following Present Examples are only examples of the present disclosure. The present disclosure is not limited thereto.

### PREPARATION EXAMPLE

(1) Preparation of Compound 1

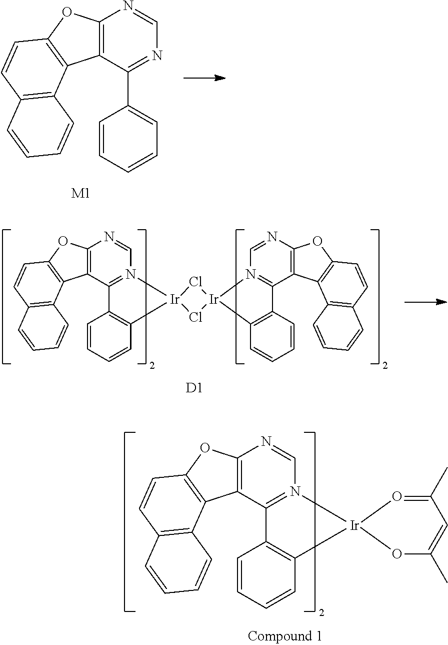

Preparation of Compound D1

M1 (9.78 g, 33 mmol), 2-ethoxyethanol 200 ml, and distilled water 66 ml were charged to a reaction vessel, followed by nitrogen bubbling for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D1 (7.36 g, a yield 60%).

Preparation of Compound 1

D1 (7.36 g, 4.5 mmol), pentane-2,4-dione (4.51 g, 45 mmol), Na₂CO₃ (9.54 g, 90 mmol), and 200 ml of 2-ethoxyethanol were charged into a reaction vessel and a mixture was refluxed for 24 hours under a nitrogen atmosphere. After the reaction was completed, dichloromethane was added to the reaction mixture to dissolve the reaction mixture therein, and then a resulting solution was subjected to extraction with dichloromethane and distilled water. MgSO₄ was used to remove water from an organic layer. After filtering, the solvent was removed therefrom under reduced pressure. Column chromatography was performed with hexane and dichloromethane. Thus, the Compound 1 (4.37 g, a yield 55%) was obtained.

MS (m/z): 882.18

(2) Preparation of Compound 31

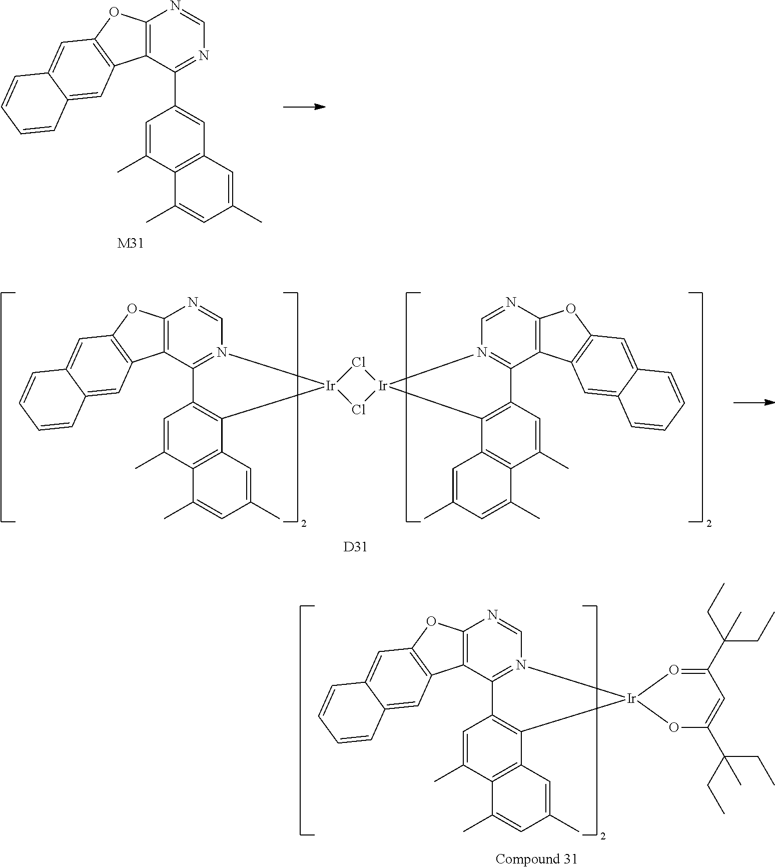

Preparation of Compound D31

M31 (12.82 g, 33 mmol), 2-ethoxyethanol 200 ml, and distilled water 66 ml were charged to a reaction vessel, followed by nitrogen bubbling for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D31 (8.27 g, a yield 55%).

Preparation of Compound 31

D31 (8.27 g, 4.13 mmol), 3,7-diethyl-3,7-dimethylnonane-4,6-dione (9.92 g, 41 mmol), Na₂CO₃ (8.74 g, 82.5 mmol), and 200 ml of 2-ethoxyethanol were charged to a reaction vessel and a mixture was refluxed for 24 hours under a nitrogen atmosphere. After the reaction was completed, dichloromethane was added to the reaction mixture to dissolve the reaction mixture therein, and then a resulting solution was subjected to extraction with dichloromethane and distilled water. MgSO₄ was used to remove water from an organic layer, and after filtering, the solvent was removed therefrom under reduced pressure. Column chromatography was performed with hexane and dichloromethane to obtain the Compound 31 (4.98 g, a yield 50%).

MS (m/z): 1206.46

(3) Preparation of Compound 50

(Step 1) Preparation of Compound A1

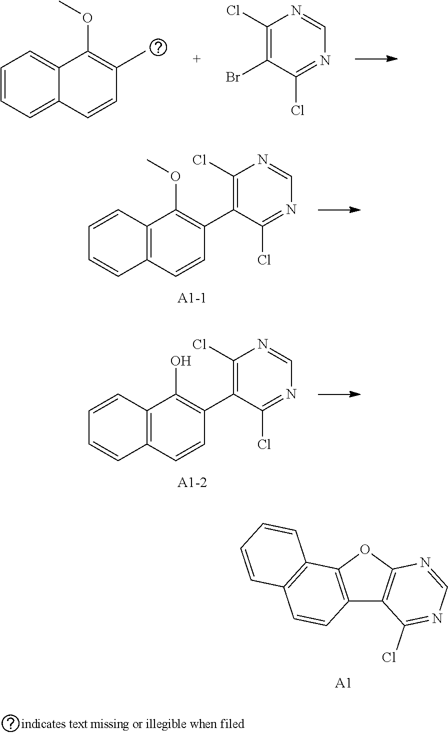 [SMILES: COc1c(C)ccc2ccccc12 ; Clc1ncnc(Cl)c1Br ; COc1c(-c2c(Cl)ncnc2Cl)ccc2ccccc12 ; Oc1c(-c2c(Cl)ncnc2Cl)ccc2ccccc12 ; Clc1ncnc2oc3c4ccccc4ccc3c12 ; "A1"]

Preparation of Compound A1-1

In a reaction vessel, 5-bromo-4,6-dichloropyrimidine (25.6 g, 112.34 mmol), (1-methoxynaphthalen-2-yl)boronic acid (24.97 g, 123.57 mmol), Pd(PPh₃)₄ (6.5 g, 5.62 mmol) and K₂CO₃ (31.05 g, 224.68 mmol) were dissolved in 1,4-dioxane (500 ml) and distilled water (100 ml) and a mixture was refluxed for 15 hours. After completion of the reaction, the mixture was cooled to room temperature and was subjected to extraction using dichloromethane and distilled water. MgSO₄ was added to an organic layer to remove moisture therefrom, and then the solvent was removed therefrom via filtration under reduced pressure. Column chromatography was performed with hexane and dichloromethane. Thus, the Compound A1-1 (30.51 g, a yield 89%) was obtained.

MS (m/z): 305.16

Preparation of Compound A1-2

A1-1 (30.51 g, 99.98 mmol) was dissolved in dichloromethane (450 ml) in a reaction vessel, and then BBr₃ (23.7 ml, 249.95 mmol) was added dropwise thereto and a mixture was stirred at room temperature for 3 hours. After completion of the reaction by adding distilled water thereto, the mixture was stirred at room temperature for 30 minutes, followed by extraction using dichloromethane and distilled water. MgSO₄ was added to an organic layer to remove moisture therefrom, and then the solvent was removed therefrom via filtration under reduced pressure. Column chromatography was performed with hexane and dichloromethane to obtain the Compound A1-2 (28.23 g, a yield 97%).

MS (m/z): 291.13

Preparation of Compound A1

A1-2 (28.23 g, 96.98 mmol) and Cs₂CO₃ (47.40 g, 145.47 mmol) were dissolved in 300 ml of N,N-dimethylacetamide in a reaction vessel and a mixture was refluxed for 16 hours. A reaction solution was cooled to room temperature, and was filtered through celite to remove an inorganic substance therefrom and a filtrate was concentrated. The mixture was dissolved in ethyl acetate, and the mixed solution was filtered through silica gel, and then filtered under reduced pressure to remove the solvent therefrom. An obtained solid was converted into a slurry using hexane to obtain the Compound A1 (22.47 g, a yield 91%) in a form of an ivory solid.

MS (m/z): 254.67

(Step 2) Preparation of Compound M50

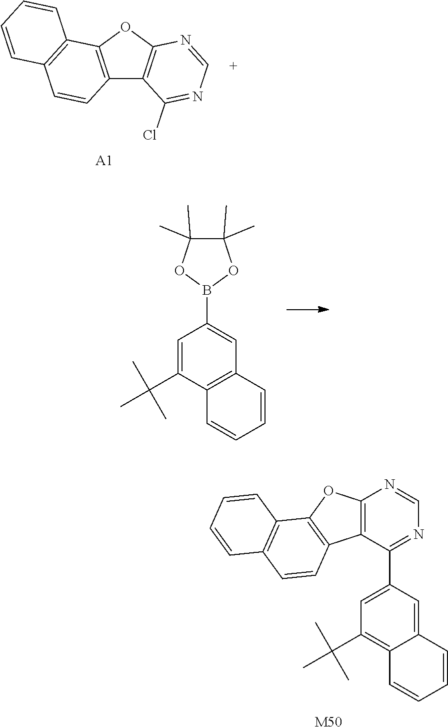 [SMILES: Clc1ncnc2oc3c4ccccc4ccc3c12 ; "A1" ; CC(C)(C)c1cc(B2OC(C)(C)C(C)(C)O2)cc2ccccc12 ; CC(C)(C)c1cc(-c2ncnc3oc4c5ccccc5ccc4c23)cc2ccccc12 ; "M50"]

A1 (22.4 g, 87.96 mmol), 2-(4-(tert-butyl)naphthalen-2-yl)-4,4,5,5-tetramethyl-1,3,2-dioxaborolane (30.02 g, 96.75 mmol), Pd(PPh₃)₄ (10.17 g, 8.80 mmol) and K₂CO₃ (24.31 g, 175.92 mmol) were dissolved in 1,4-dioxane (330 ml) and distilled water (66 ml) and a mixture was refluxed for 16 hours. After completion of the reaction, the mixture was cooled to room temperature and was subjected to extraction using dichloromethane and distilled water. MgSO₄ was added to an organic layer to remove moisture therefrom, and then the solvent was removed therefrom via filtration under reduced pressure. Column chromatography was performed with hexane and dichloromethane. Thus, the Compound M50 (25.84 g, a yield 73%) was obtained.

MS (m/z): 402.49

(Step 3) Preparation of Compound 50

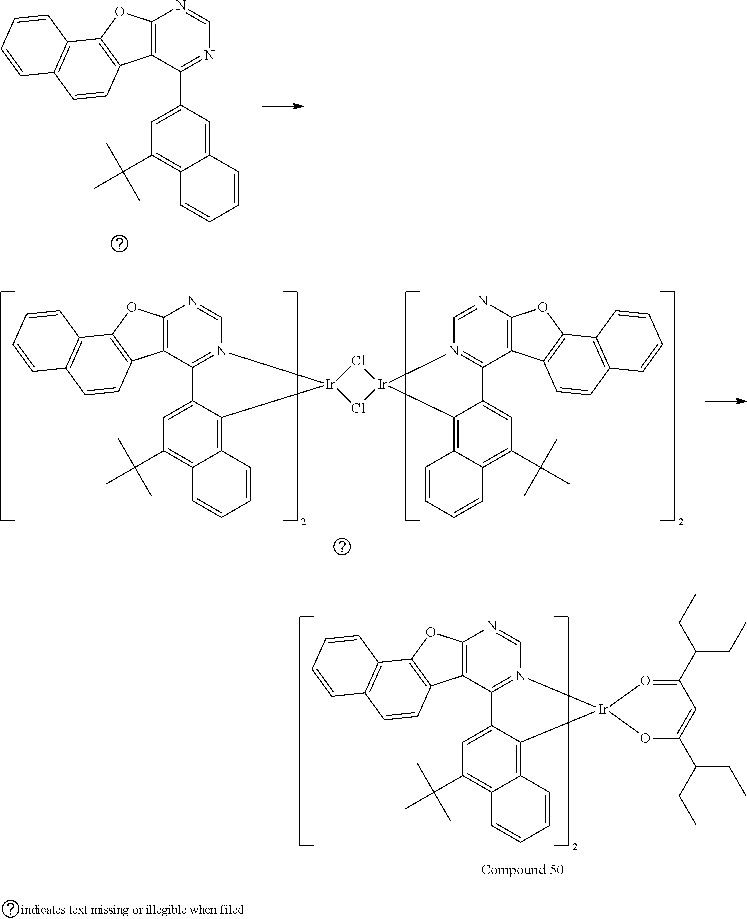

Preparation of Compound D50

M50 (25 g, 62.11 mmol), 2-ethoxyethanol 500 ml, distilled water 167 ml were charged into a reaction vessel, and nitrogen bubbling was performed for 1 hour, and then IrCl₃,H₂O (9.95 g, 28.23 mmol) was added thereto and a mixture was refluxed for 24 hours. After the reaction was completed, a temperature was slowly lowered to room temperature and a resulting solid was filtered. The filtered solid was washed with methanol and dried to obtain the Compound D50 (16.3 g, a yield 56%).

Preparation of Compound 50

D50 (16.3 g, 7.91 mmol), 3,7-diethylnonane-4,6-dione (5.88 g, 27.68 mmol), Na₂CO₃ (16.76 g, 158.16 mmol), and 300 ml of 2-ethoxyethanol were charged into a reaction vessel and were refluxed under nitrogen atmosphere for 24 hours. After the reaction was completed, dichloromethane was added to the reaction mixture to dissolve the reaction mixture therein, followed by extraction with dichloromethane and distilled water. MgSO₄ was used to remove water from an organic layer, and after filtering, the solvent was removed therefrom under reduced pressure. Column chromatography was performed with hexane and dichloromethane. Thus, the Compound 50 (8.2 g, a yield 43%) was obtained.

MS (m/z): 1206.50

(4) Preparation of Compound 57

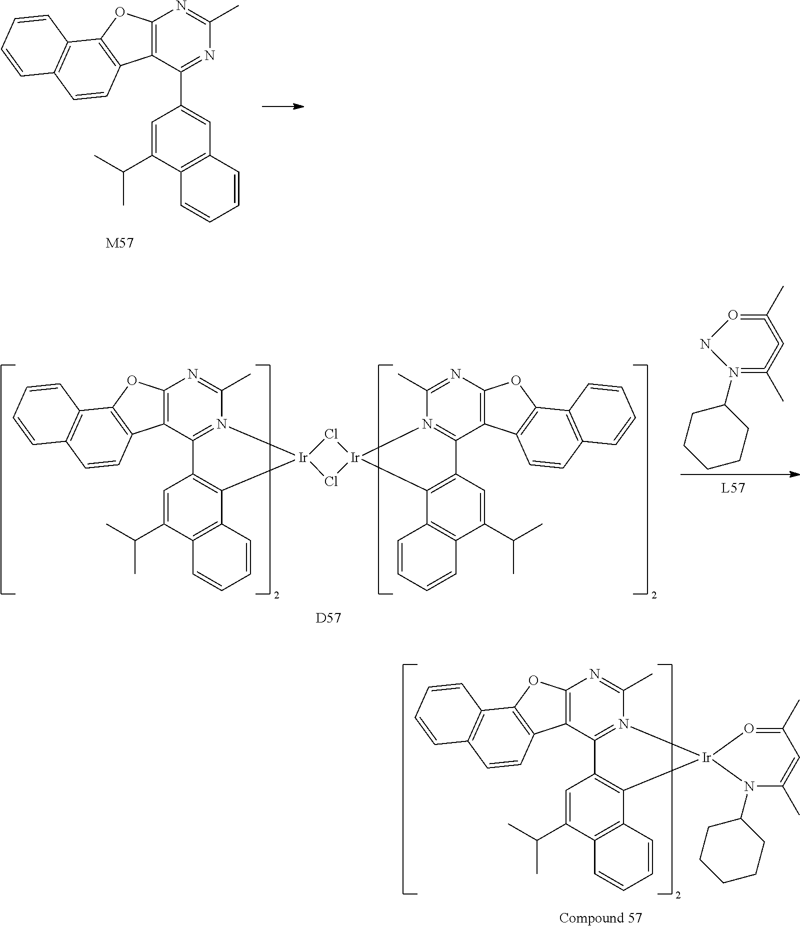

Preparation of Compound D57

M57 (13.28 g, 33 mmol), 2-ethoxyethanol 200 ml, and distilled water 66 ml were charged into a reaction vessel, followed by nitrogen bubbling for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D57 (7.42 g, a yield 48%).

Preparation of Compound 57

M57 (7.42 g, 3.6 mmol) and THF 200 ml were charged into a reaction vessel under a nitrogen stream. Then, L57 (1.75 g, 7.9 mmol) dissolved in THF was slowly added thereto, followed by stirring at room temperature overnight. After completion of the reaction, THF was removed therefrom under reduced pressure in vacuum, the mixture was subjected to extraction with toluene, and was filtered with Celite. Toluene was removed therefrom under reduced pressure, and column chromatography was performed with hexane and dichloromethane to obtain the Compound 57 (4.65 g, a yield 55%).

MS (m/z): 1175.43

(5) Preparation of Compound 58

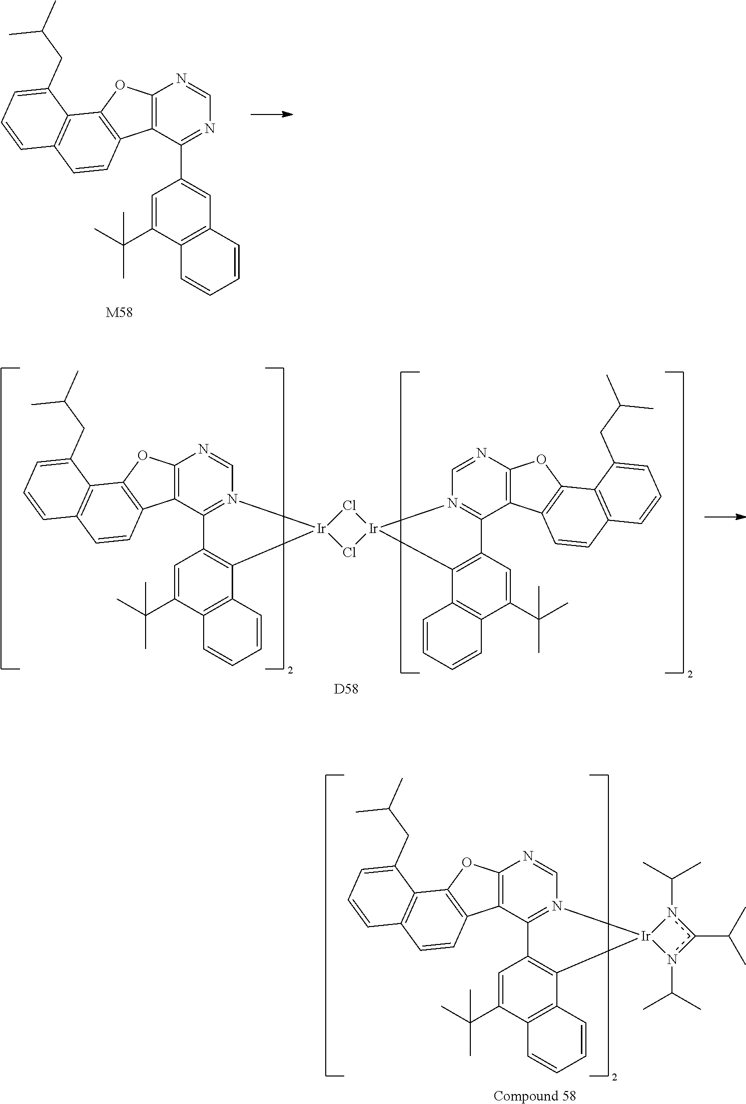

Preparation of Compound D58

M58 (15.13 g, 33 mmol), 2-ethoxyethanol 200 ml, and distilled water 66 ml were charged into a reaction vessel, followed by nitrogen bubbling for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D58 (8.06 g, a yield 47%).

Preparation of Compound 58

2-bromopropane (1.73 g, 14.10 mmol) and 50 ml of THF were charged into a reaction vessel under a nitrogen stream, and a temperature was lowered to −78° C., and n-BuLi (5.8 ml, 2.5M in hexane) was slowly added thereto. After 30 minutes, N,N′-diisopropylcarbodiimide (1.78 g, 14.10 mmol) was slowly added thereto and the mixture was stirred for 30 minutes while the temperature was maintained. The reaction mixture was charged to a reaction vessel in which D58 (8.06 g, 3.53 mmol) was dissolved in 200 ml THF and the reaction mixture was stirred at 80° C. for 8 hours. A temperature of the reaction mixture was lowered to room temperature, volatile substances were removed therefrom, and the reaction mixture was subjected to recrystallization with THF/pentane and dichloromethane/hexane solvent. Thus, the compound 58 (4.41 g, a yield 49%) was obtained.

MS (m/z): 1175.43

(6) Preparation of Compound 74

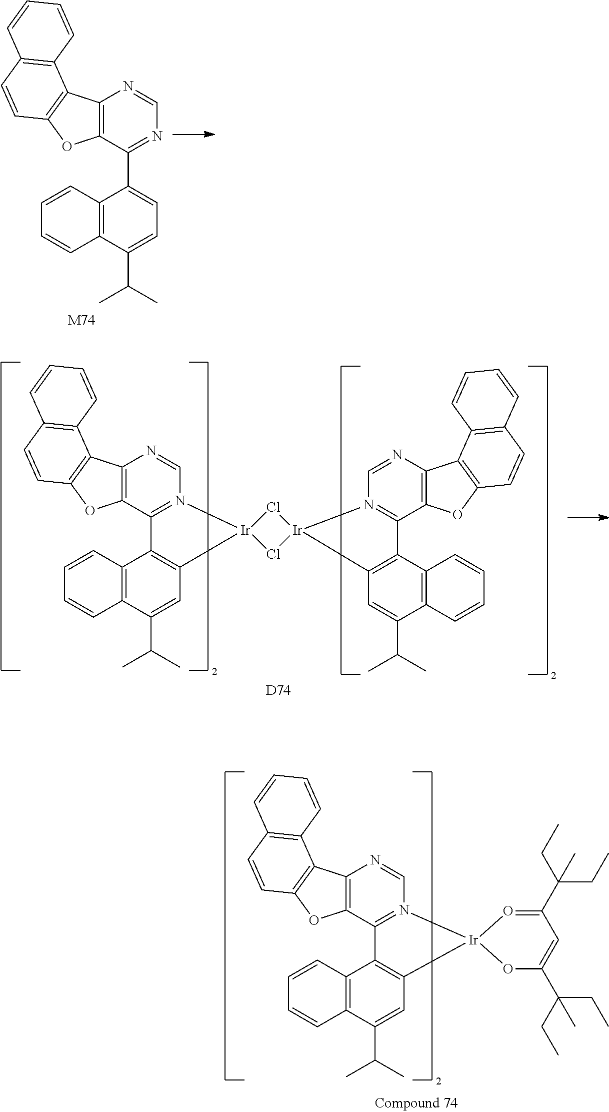

Preparation of Compound D74

M74 (12.82 g, 33 mmol), 2-ethoxyethanol 200 ml, and distilled water 66 ml were charged into a reaction vessel and nitrogen bubbling was performed for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D74 (7.82 g, a yield 52%).

Preparation of Compound 74

D74 (7.82 g, 3.9 mmol), 3,7-diethyl-3,7-dimethylnonane-4,6-dione (9.37 g, 39 mmol), Na₂CO₃ (8.27 g, 78 mmol), and 200 ml of 2-ethoxyethanol were charged into a reaction vessel and a mixture was refluxed for 24 hours under a nitrogen atmosphere. After the reaction was completed, dichloromethane was added to the reaction mixture to dissolve the reaction mixture therein, and then a resulting solution was subjected to extraction with dichloromethane and distilled water. MgSO₄ was used to remove water from an organic layer, and after filtering, the solvent was removed therefrom under reduced pressure. Column chromatography was performed with hexane and dichloromethane to obtain the Compound 74 (4.23 g, a yield 45%).

MS (m/z): 1206.46

(7) Preparation of Compound 86

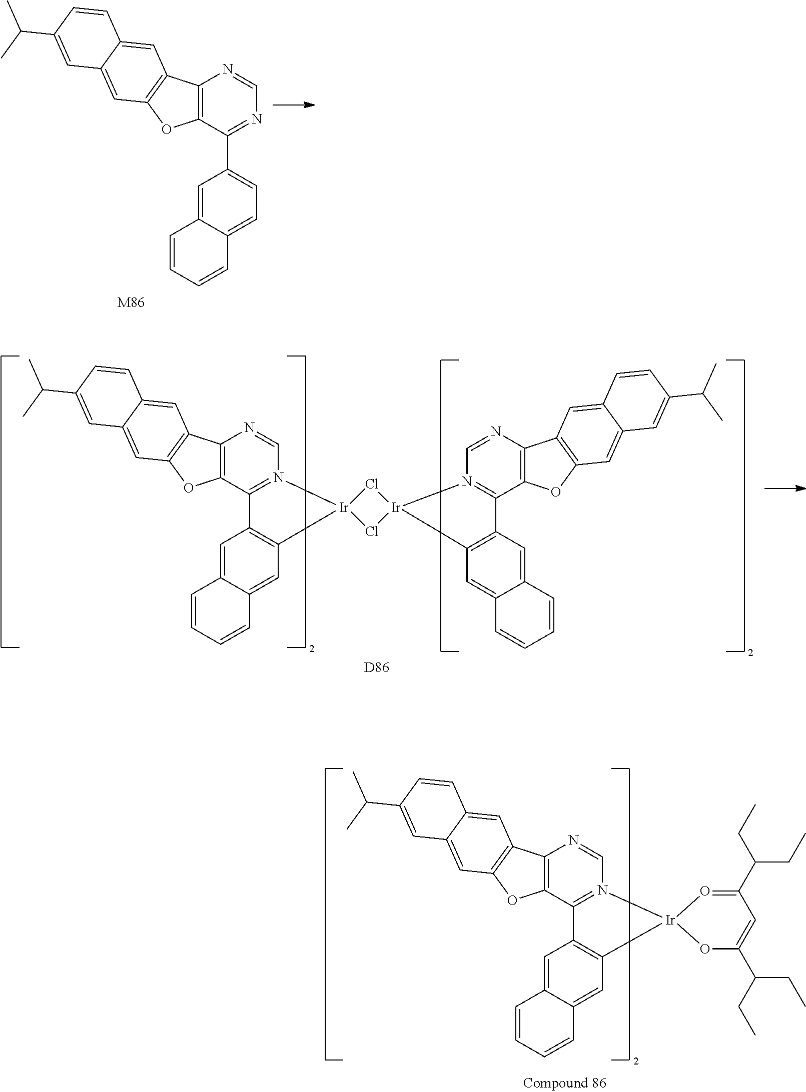

Preparation of Compound D86

M86 (12.82 g, 33 mmol), 2-ethoxyethanol 200 ml, and distilled water 66 ml were charged into a reaction vessel, followed by nitrogen bubbling for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D86 (6.02 g, a yield 40%).

Preparation of Compound 86

D86 (6.02 g, 3.0 mmol), 3,7-diethylnonane-4,6-dione (6.37 g, 30 mmol), Na₂CO₃ (6.36 g, 60 mmol), and 200 ml of 2-ethoxyethanol were charged into a reaction vessel and a mixture was refluxed under nitrogen atmosphere for 24 hours. After the reaction was completed, dichloromethane was added to the reaction mixture to dissolve the reaction mixture therein, and then a resulting solution was subjected to extraction with dichloromethane and distilled water. MgSO₄ was used to remove water from an organic layer, and after filtering, the solvent was removed therefrom under reduced pressure. Column chromatography was performed with hexane and dichloromethane to obtain the Compound 86 (2.97 g, a yield 42%).

MS (m/z) 1178.43

(8) Preparation of Compound 102

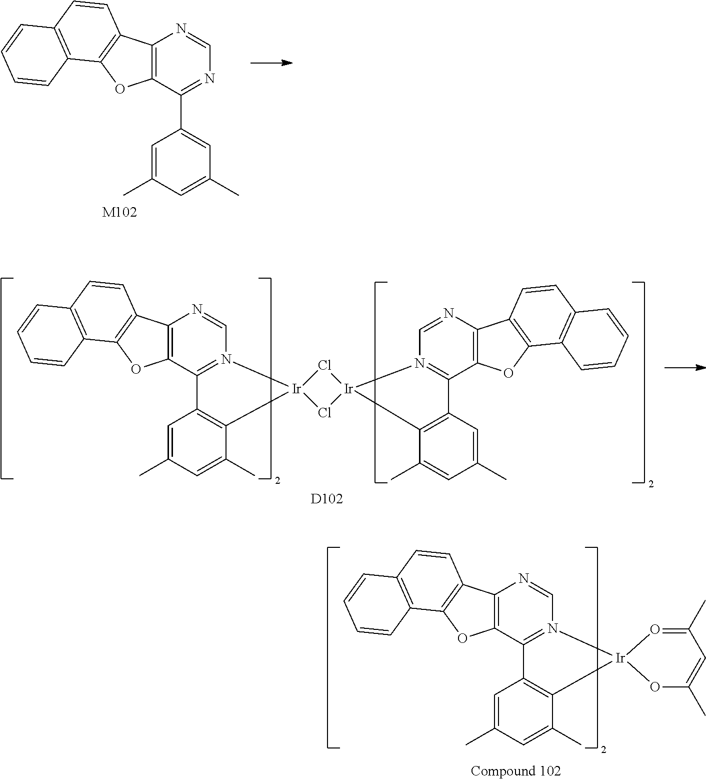

Preparation of Compound D102

M102 (10.70 g, 33 mmol), 2-ethoxyethanol 200 ml, and distilled water 66 ml were charged into a reaction vessel, followed by nitrogen bubbling for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D102 (8.13 g, a yield 62%).

Preparation of Compound 102

D102 (8.13 g, 4.65 mmol), pentane-2,4-dione (4.66 g, 46.5 mmol), Na₂CO₃ (9.86 g, 93 mmol), and 200 ml of 2-ethoxyethanol were charged into a reaction vessel and a mixture was refluxed for 24 hours under a nitrogen atmosphere. After the reaction was completed, dichloromethane was added to the reaction mixture to dissolve the reaction mixture therein, and then a resulting solution was subjected to extraction with dichloromethane and distilled water. MgSO₄ was used to remove water from an organic layer, and after filtering, the solvent was removed therefrom under reduced pressure. Column chromatography was performed with hexane and dichloromethane. Thus, the Compound 102 (4.62 g, a yield 53%) was obtained.

MS (m/z): 938.24

(9) Preparation of Compound 124

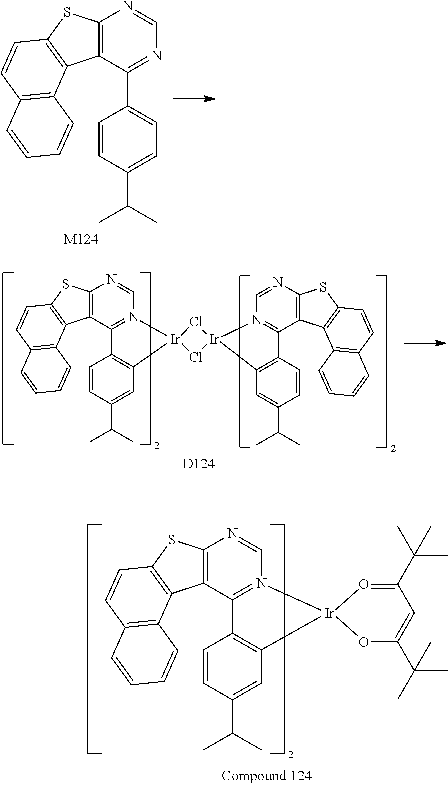

Preparation of Compound D124

M124 (11.70 g, 33 mmol), 2-ethoxyethanol 200 ml, and distilled water 66 ml were charged to a reaction vessel, followed by nitrogen bubbling for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D124 (7.15 g, a yield 51%).

Preparation of Compound 124

D124 (7.15 g, 3.83 mmol), 2,2,6,6-tetramethylheptane-3,5-dione (7.05 g, 38.3 mmol), Na₂CO₃ (8.11 g, 77 mmol), and 200 ml of 2-ethoxyethanol were charged to a reaction vessel and a mixture was refluxed for 24 hours under a nitrogen atmosphere. After the reaction was completed, dichloromethane was added to the reaction mixture to dissolve the reaction mixture therein, and then a resulting solution was subjected to extraction with dichloromethane and distilled water. MgSO₄ was used to remove water from an organic layer, and after filtering, the solvent was removed therefrom under reduced pressure. Column chromatography was performed with hexane and dichloromethane to obtain the Compound 124 (4.06 g, a yield 49%).

MS (m/z): 1082.32

(10) Preparation of Compound 148

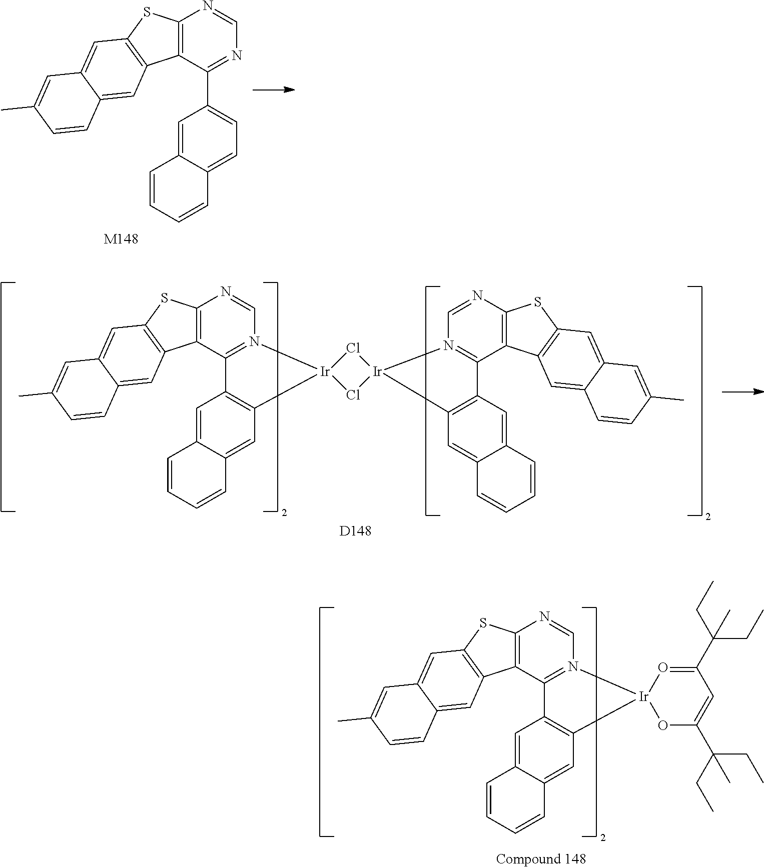

Preparation of Compound D148

M148 (12.42 g, 33 mmol), 2-ethoxyethanol 200 ml, and distilled water 66 ml were charged into a reaction vessel, and nitrogen bubbling was performed for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D148 (5.58 g, a yield 38%).

Preparation of Compound 148

D148 (5.58 g, 2.85 mmol), 3,7-diethyl-3,7-dimethylnonane-4,6-dione (6.85 g, 28.5 mmol), Na₂CO₃ (6.04 g, 57 mmol), and 200 ml 2-ethoxyethanol were charged into a reaction vessel and a mixture was refluxed for 24 hours under a nitrogen atmosphere. After the reaction was completed, dichloromethane was added to the reaction mixture to dissolve the reaction mixture therein, and then a resulting solution was subjected to extraction with dichloromethane and distilled water. MgSO₄ was used to remove water from an organic layer, and after filtering, the solvent was removed therefrom under reduced pressure. Column chromatography was performed with hexane and dichloromethane to obtain the Compound 148 (2.70 g, a yield 40%).

MS (m/z): 1182.36

(11) Preparation of Compound 170

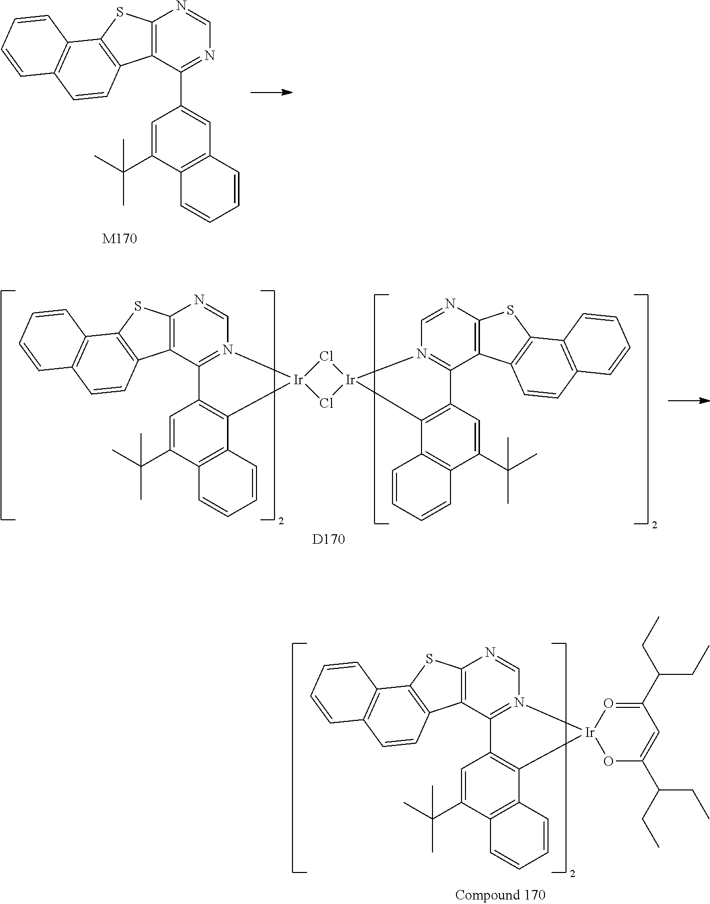

Preparation of Compound D170

M170 (13.81 g, 33 mmol), 2-ethoxyethanol 200 ml, and distilled water 66 ml were charged to a reaction vessel, followed by nitrogen bubbling for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D170 (8.77 g, a yield 55%).

Preparation of Compound 170

D170 (8.77 g, 4.13 mmol), 3,7-diethylnonane-4,6-dione (8.76 g, 41.3 mmol), Na₂CO₃ (8.74 g, 83 mmol), and 200 ml of 2-ethoxyethanol were charged into a reaction vessel, and a mixture was refluxed under a nitrogen atmosphere for 24 hours. After the reaction was completed, dichloromethane was added to the reaction mixture to dissolve the reaction mixture therein, and then a resulting solution was subjected to extraction with dichloromethane and distilled water. MgSO₄ was used to remove water from an organic layer, and after filtering, the solvent was removed therefrom under reduced pressure. Column chromatography was performed with hexane and dichloromethane. Thus, the Compound 170 (4.90 g, a yield 48%) was obtained.

MS (m/z): 1238.42

(12) Preparation of Compound 177

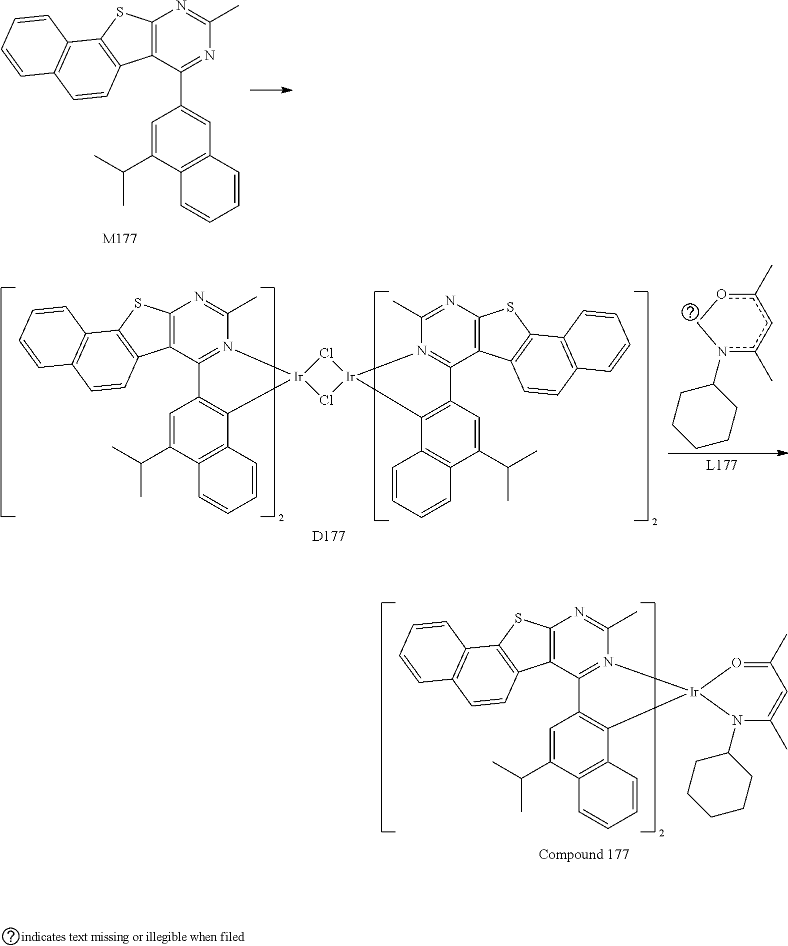

Preparation of Compound D177

M177 (13.81 g, 33 mmol), 2-ethoxyethanol 200 ml, and distilled water 66 ml were charged into a reaction vessel, followed by nitrogen bubbling for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D177 (7.17 g, a yield 45%).

Preparation of Compound 177

M177 (7.17 g, 3.4 mmol), and 200 ml of THF were charged into a reaction vessel under a nitrogen stream, and L177 (1.64 g, 7.4 mmol) dissolved in THF was slowly added thereto, followed by stirring at room temperature overnight. After completion of the reaction, THF was removed therefrom under reduced pressure in vacuum, and the mixture was subjected to extraction with toluene, and filtered with celite. Toluene was removed therefrom under reduced pressure, and column chromatography was performed with hexane and dichloromethane to obtain the Compound 177 (4.08 g, a yield 50%).

MS (m/z): 1207.39

(13) Preparation of Compound 178

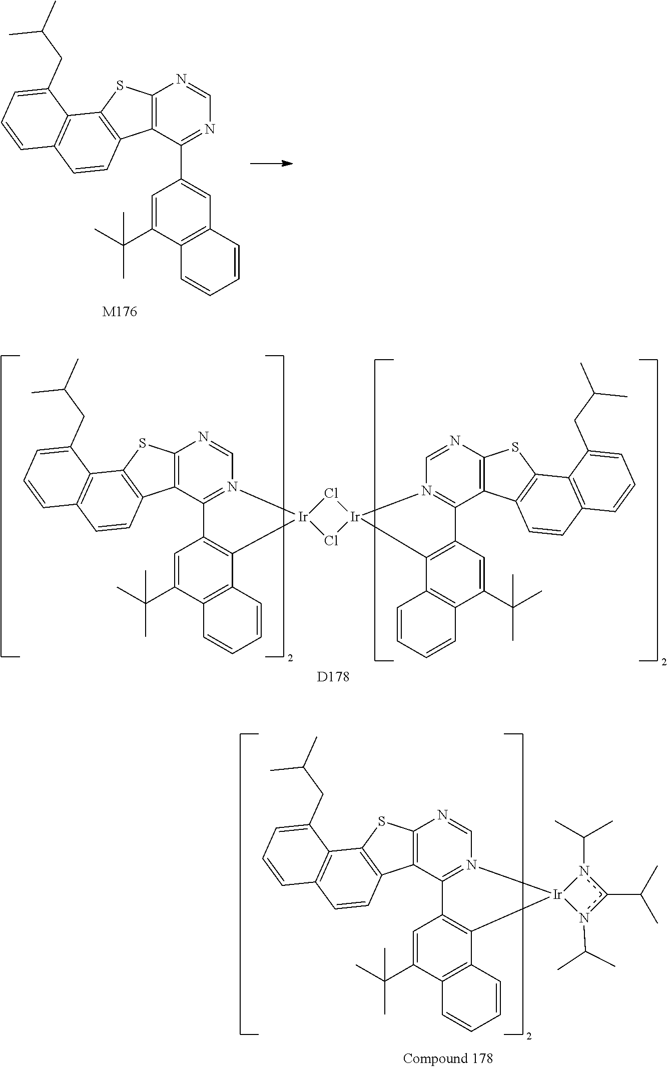

Preparation of Compound D178

M178 (15.66 g, 33 mmol), 2-ethoxyethanol 200 ml, and distilled water 66 ml were charged into a reaction vessel, followed by nitrogen bubbling for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D178 (7.58 g, a yield 43%).

Preparation of Compound 178

2-bromopropane (1.59 g, 12.90 mmol) and 50 ml of THF were charged into a reaction vessel under a nitrogen stream, and a temperature was lowered to −78° C., and n-BuLi (5.3 ml, 2.5M in hexane) was slowly added thereto. After 30 minutes, while the temperature was maintained, N,N′-diisopropylcarbodiimide (1.63 g, 12.90 mmol) was slowly added thereto and the mixture was stirred for 30 minutes. The reaction mixture was charged to a reaction vessel in which D178 (7.58 g, 3.23 mmol) was dissolved in 200 ml THF and then the mixture was stirred at 80° C. for 8 hours. The temperature of the reaction mixture was lowered to room temperature, volatile substances were removed therefrom, and the mixture was subjected to recrystallization with THF/pentane and dichloromethane/hexane solvent. Thus, the compound 178 (3.71 g, a yield 44%) was obtained.

MS (m/z): 1308.54

(14) Preparation of Compound 190

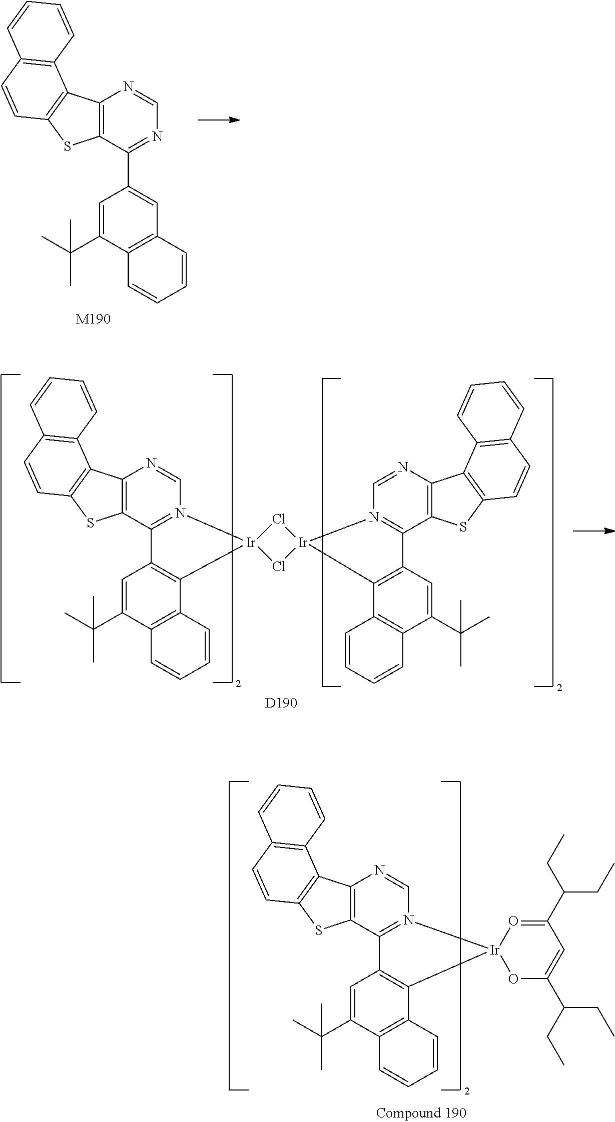

Preparation of Compound D190

M190 (13.81 g, 33 mmol), 2-ethoxyethanol 200 ml, and distilled water 66 ml were charged to a reaction vessel, followed by nitrogen bubbling for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D190 (9.09 g, a yield 57%).

Preparation of Compound 190

D190 (9.09 g, 4.28 mmol), 3,7-diethylnonane-4,6-dione (9.08 g, 42.8 mmol), Na₂CO₃ (9.06 g, 86 mmol), and 200 ml of 2-ethoxyethanol were charged into a reaction vessel and a mixture was refluxed under a nitrogen atmosphere for 24 hours. After the reaction was completed, dichloromethane was added to the reaction mixture to dissolve the reaction mixture therein, and then a resulting solution was subjected to extraction with dichloromethane and distilled water. MgSO₄ was used to remove water from an organic layer, and after filtering, the solvent was removed therefrom under reduced pressure. Column chromatography was performed with hexane and dichloromethane to obtain the Compound 190 (4.87 g, a yield 46%).

MS (m/z): 1238.42

(15) Preparation of Compound 216

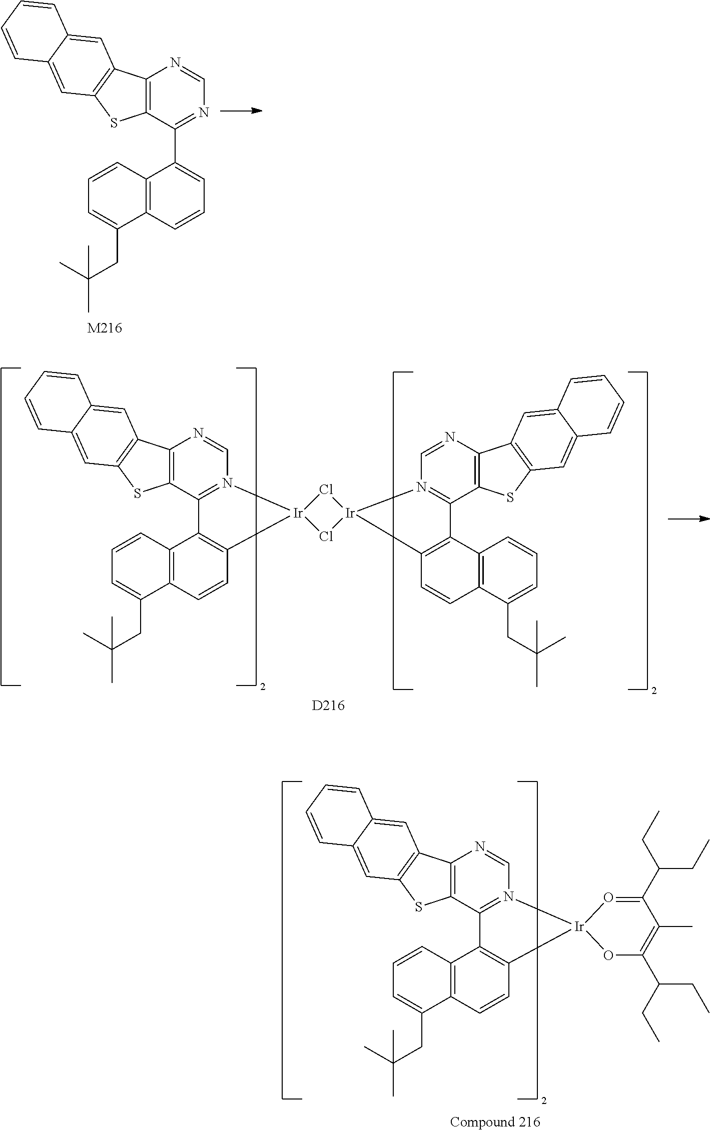

Preparation of Compound D216

M216 (14.28 g, 33 mmol), 2-ethoxyethanol 200 ml, and distilled water 66 ml were charged to a reaction vessel, followed by nitrogen bubbling for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D216 (6.38 g, a yield 39%).

Preparation of Compound 216

D216 (6.38 g, 2.93 mmol), 3,7-diethyl-5-methylnonane-4,6-dione (6.62 g, 29.3 mmol), Na₂CO₃ (6.20 g, 59 mmol), and 200 ml of 2-ethoxyethanol were charged into a reaction vessel and a mixture was refluxed for 24 hours under a nitrogen atmosphere. After the reaction was completed, dichloromethane was added to the reaction mixture to dissolve the reaction mixture therein, and then a resulting solution was subjected to extraction with dichloromethane and distilled water. MgSO₄ was used to remove water from an organic layer, and after filtering, the solvent was removed therefrom under reduced pressure. Column chromatography was performed with hexane and dichloromethane to obtain the Compound 216 (2.85 g, a yield 38%).

MS (m/z): 1280.46

(16) Preparation of Compound 223

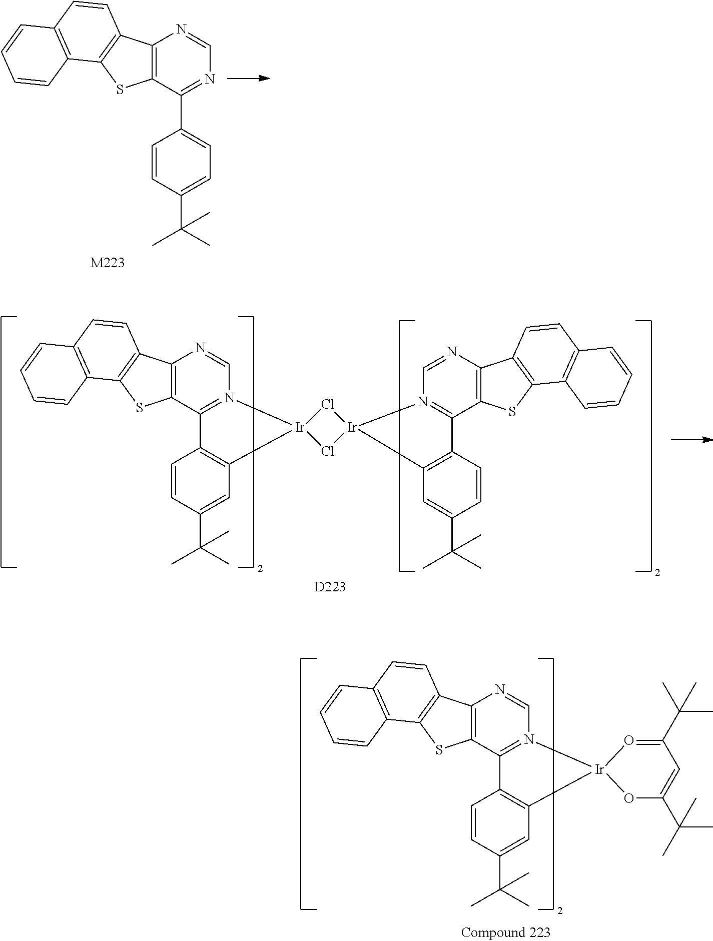

Preparation of Compound D223

M223 (12.16 g, 33 mmol), 2-ethoxyethanol 200 ml, and distilled water 66 ml were charged into a reaction vessel, followed by nitrogen bubbling for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D223 (8.66 g, a yield 60%).

Preparation of Compound 223

D223 (8.66 g, 4.50 mmol), 2,2,6,6-tetramethylheptane-3,5-dione (8.29 g, 45.0 mmol), Na₂CO₃ (9.54 g, 90 mmol), and 200 ml of 2-ethoxyethanol were charged into a reaction vessel and a mixture was refluxed for 24 hours under a nitrogen atmosphere. After the reaction was completed, dichloromethane was added to the reaction mixture to dissolve the reaction mixture therein, and then a resulting solution was subjected to extraction with dichloromethane and distilled water. MgSO₄ was used to remove water from an organic layer, and after filtering, the solvent was removed therefrom under reduced pressure. Column chromatography was performed with hexane and dichloromethane to obtain the Compound 223 (5.10 g, a yield 51%).

MS (m/z): 1110.36

(17) Preparation of Compound 241

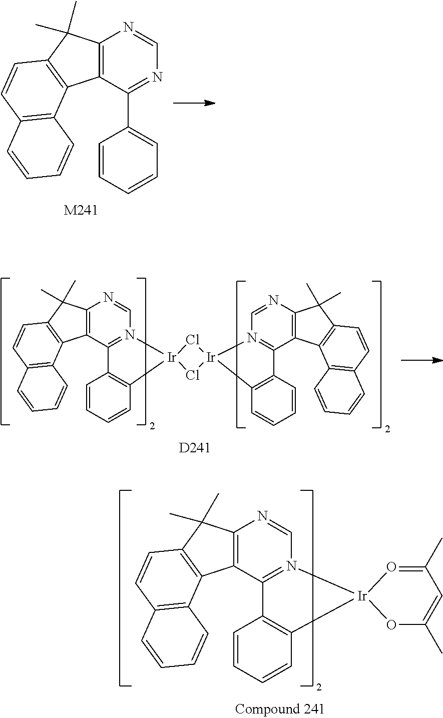

Preparation of Compound D241

M241 (10.64 g, 33 mmol), 2-ethoxyethanol 200 ml, and distilled water 66 ml were charged into a reaction vessel, and nitrogen bubbling was performed for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D241 (6.27 g, a yield 48%).

Preparation of Compound 241

D241 (6.27 g, 3.60 mmol), pentane-2,4-dione (3.60 g, 36.0 mmol), Na₂CO₃ (7.63 g, 72 mmol), and 200 ml of 2-ethoxyethanol were charged into a reaction vessel and a mixture was refluxed for 24 hours under a nitrogen atmosphere. After the reaction was completed, dichloromethane was added to the reaction mixture to dissolve the reaction mixture therein, and then a resulting solution was subjected to extraction with dichloromethane and distilled water. MgSO₄ was used to remove water from an organic layer, and after filtering, the solvent was removed therefrom under reduced pressure. Column chromatography was performed with hexane and dichloromethane to obtain the Compound 241 (3.16 g, a yield 47%).

MS (m/z): 934.29

(18) Preparation of Compound 271

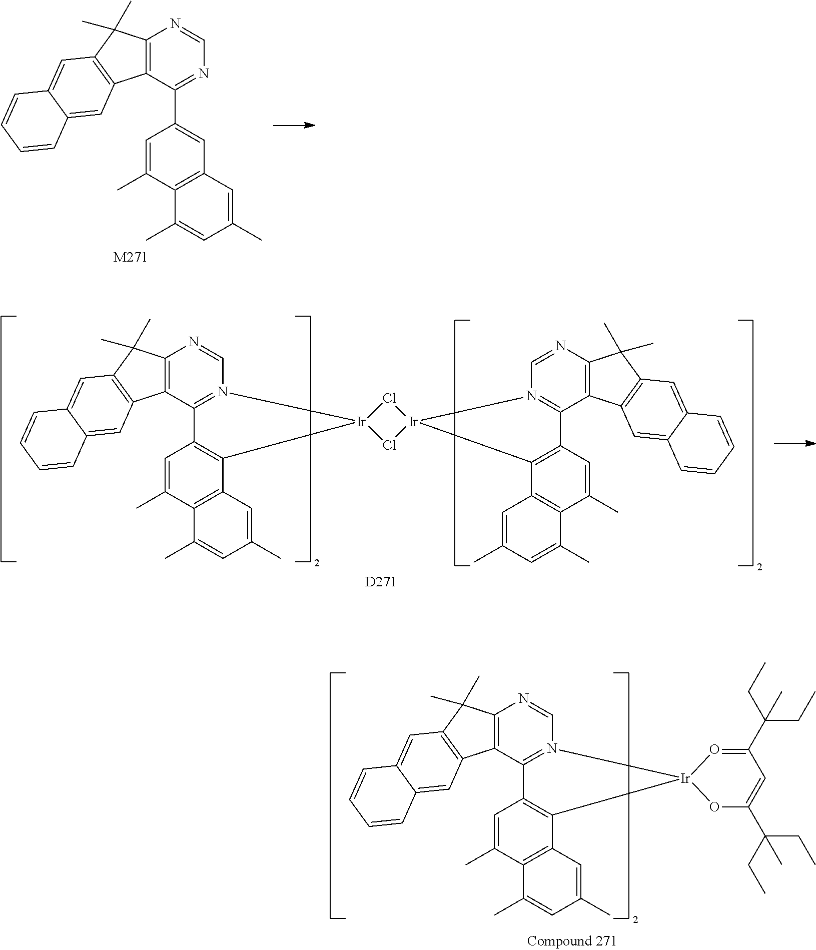

Preparation of Compound D271

M271 (13.68 g, 33 mmol), 2-ethoxyethanol 200 ml, and distilled water 66 ml were charged into a reaction vessel, followed by nitrogen bubbling for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D271 (8.07 g, a yield 51%).

Preparation of Compound 271

D271 (8.07 g, 3.83 mmol), 3,7-diethyl-3,7-dimethylnonane-4,6-dione (9.19 g, 38.3 mmol), Na₂CO₃ (8.11 g, 77 mmol), and 200 ml 2-ethoxyethanol were charged to a reaction vessel and a mixture was refluxed for 24 hours under a nitrogen atmosphere. After the reaction was completed, dichloromethane was added to the reaction mixture to dissolve the reaction mixture therein, and then a resulting solution was subjected to extraction with dichloromethane and distilled water. MgSO₄ was used to remove water from an organic layer, and after filtering, the solvent was removed therefrom under reduced pressure. Column chromatography was performed with hexane and dichloromethane to obtain the Compound 271 (4.14 g, a yield 43%).

MS (m/z): 1258.57

(19) Preparation of Compound 290

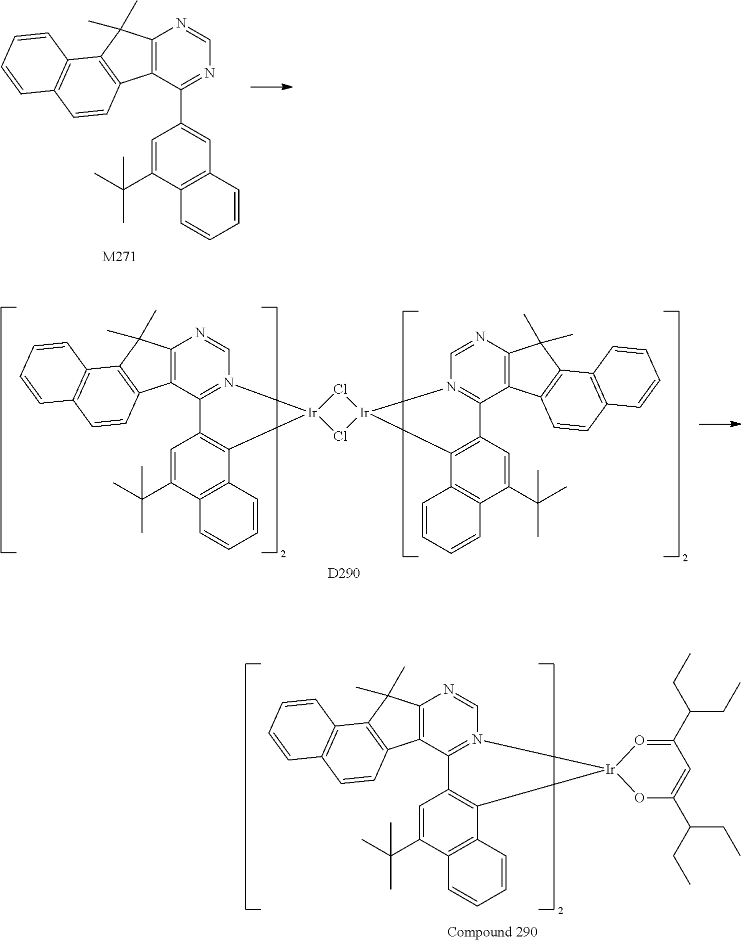

Preparation of Compound D290

M290 (14.14 g, 33 mmol), 2-ethoxyethanol 200 ml, and distilled water 66 ml were charged to a reaction vessel, followed by nitrogen bubbling for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D290 (8.45 g, a yield 52%).

Preparation of Compound 290

D290 (8.45 g, 3.90 mmol), 3,7-diethylnonane-4,6-dione (8.28 g, 39.0 mmol), Na₂CO₃ (8.27 g, 78 mmol), and 200 ml of 2-ethoxyethanol were charged into a reaction vessel and a mixture was refluxed under a nitrogen atmosphere for 24 hours. After the reaction was completed, dichloromethane was added to the reaction mixture to dissolve the reaction mixture therein, and then a resulting solution was subjected to extraction with dichloromethane and distilled water. MgSO₄ was used to remove water from an organic layer, and after filtering, the solvent was removed therefrom under reduced pressure. Column chromatography was performed with hexane and dichloromethane to obtain the Compound 290 (4.42 g, a yield 45%).

MS (m/z): 1258.57

(20) Preparation of Compound 298

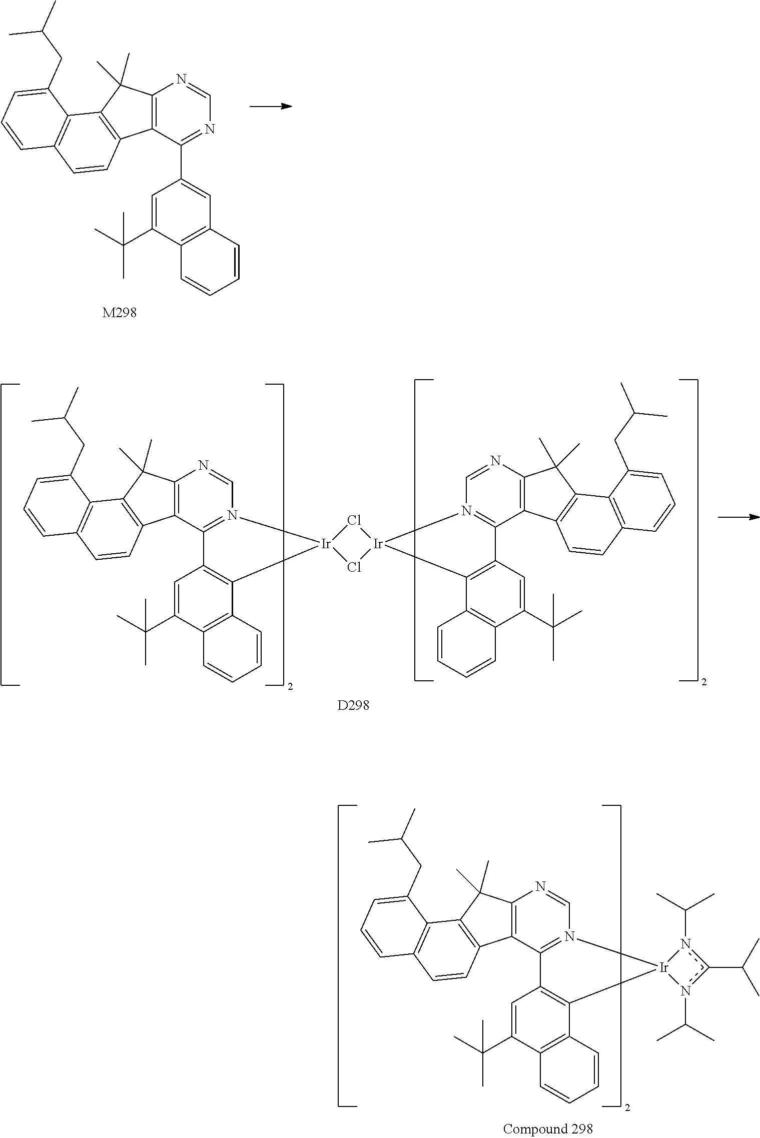

Preparation of Compound D298

M298 (15.99 g, 33 mmol), 2-ethoxyethanol 200 ml, and distilled water 66 ml were charged into a reaction vessel, and nitrogen bubbling was performed for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D298 (7.35 g, a yield 41%).

Preparation of Compound 298

2-bromopropane (1.51 g, 12.30 mmol) and 50 ml of THF were charged into a reaction vessel under a nitrogen stream, and a temperature was lowered to −78° C., and n-BuLi (5.0 ml, 2.5M in hexane) was slowly added thereto. After 30 minutes, while the temperature was maintained, N,N′-diisopropylcarbodiimide (1.55 g, 12.30 mmol) was slowly added thereto and the mixture was stirred for 30 minutes. The reaction mixture was charged to a reaction vessel in which D298 (7.35 g, 3.08 mmol) was dissolved in 200 ml THF and then the mixture was stirred at 80° C. for 8 hours. The temperature of the reaction mixture was lowered to room temperature, volatile substances were removed therefrom, and the mixture was subjected to recrystallization with THF/pentane and dichloromethane/hexane solvent. Thus, the compound 298 (3.27 g, a yield 40%) was obtained.

MS (m/z): 1328.69

(21) Preparation of Compound 300

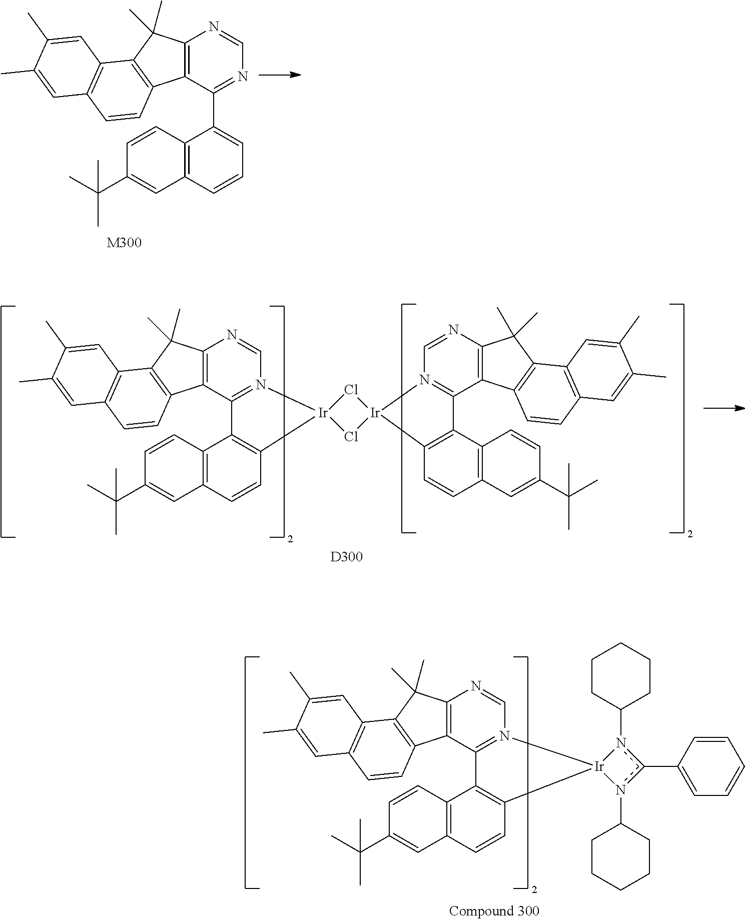

Preparation of Compound D300

M300 (15.07 g, 33 mmol), 2-ethoxyethanol 200 ml, and distilled water 66 ml were charged into a reaction vessel and nitrogen bubbling was performed for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D300 (5.13 g, a yield 30%).

Preparation of Compound 300

Bromobenzene (1.41 g, 9.00 mmol) and 50 ml of THF were charged into a reaction vessel under a nitrogen stream, and a temperature was lowered to −78° C., and then n-BuLi (3.7 ml, 2.5M in hexane) was slowly added thereto. After 30 minutes, while the temperature was maintained, N,N′-methanediylidenedicyclohexanamine (1.86 g, 9.00 mmol) was slowly added thereto and the mixture was stirred for 30 minutes. The reaction mixture was charged to a reaction vessel in which D300 (5.13 g, 2.25 mmol) was dissolved in 100 ml THF and then the mixture was stirred at 80° C. for 8 hours. The temperature of the reaction mixture was lowered to room temperature, volatile substances were removed therefrom, and the mixture was subjected to recrystallization with THF/pentane and dichloromethane/hexane solvent. Thus, the compound 300 (2.18 g, a yield 35%) was obtained.

MS (m/z): 1386.68

(22) Preparation of Compound 310

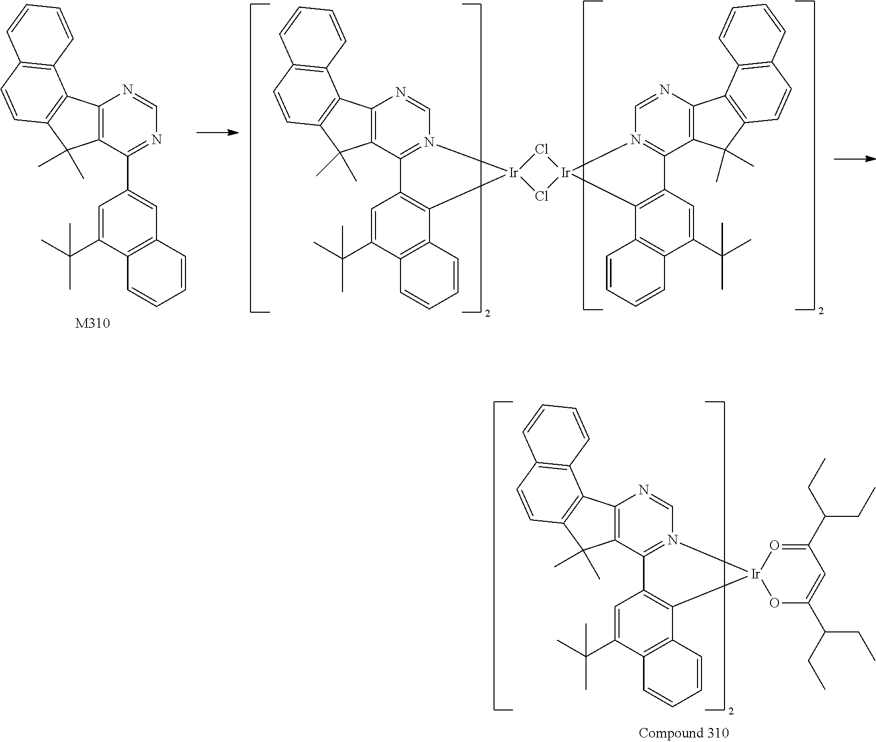

Preparation of Compound D310

M310 (14.14 g, 33 mmol), 2-ethoxyethanol 200 ml, and distilled water 66 ml were charged into a reaction vessel, followed by nitrogen bubbling for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D310 (6.33 g, a yield 39%).

Preparation of Compound 310

D310 (6.33 g, 2.93 mmol), 3,7-diethylnonane-4,6-dione (6.21 g, 29.3 mmol), Na₂CO₃ (6.20 g, 59 mmol), and 200 ml of 2-ethoxyethanol were charged into a reaction vessel and then a mixture was refluxed under a nitrogen atmosphere for 24 hours. After the reaction was completed, dichloromethane was added to the reaction mixture to dissolve the reaction mixture therein, and then a resulting solution was subjected to extraction with dichloromethane and distilled water. MgSO₄ was used to remove water from an organic layer, and after filtering, the solvent was removed therefrom under reduced pressure. Column chromatography was performed with hexane and dichloromethane to obtain the Compound 310 (2.72 g, a yield 37%).

MS (m/z): 1258.57

(23) Preparation of Compound 330

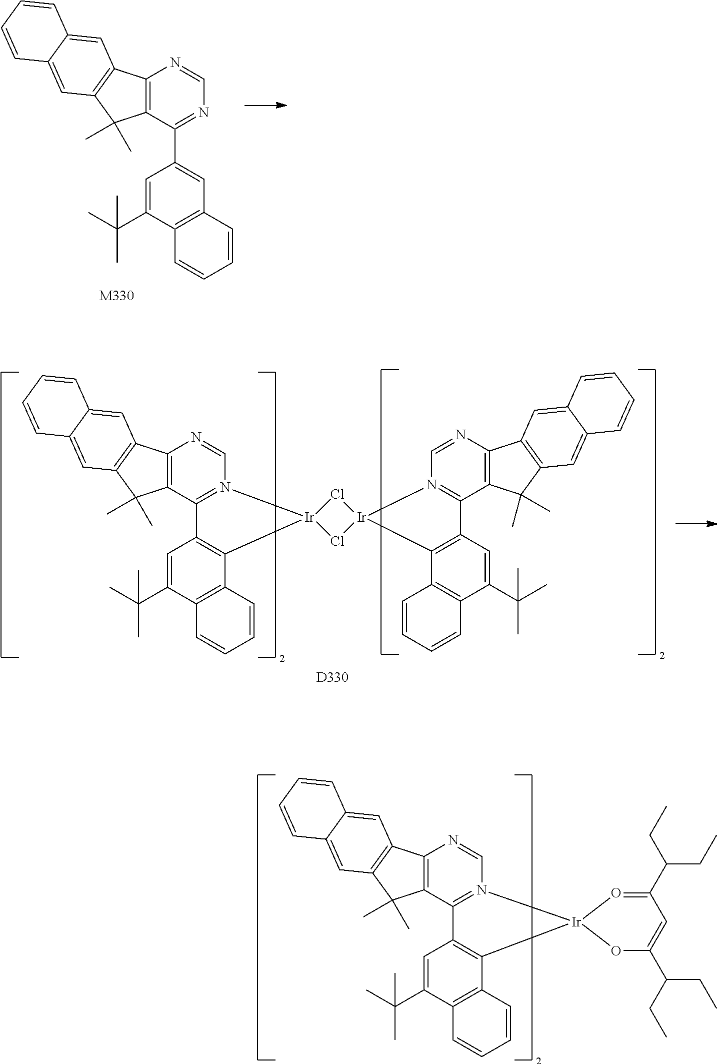

Preparation of Compound D330

M330 (14.14 g, 33 mmol), 2-ethoxyethanol 200 ml, and distilled water 66 ml were charged into a reaction vessel, and nitrogen bubbling was performed for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D330 (6.50 g, a yield 40%).

Preparation of Compound 330

D330 (6.50 g, 3.00 mmol), 3,7-diethylnonane-4,6-dione (6.37 g, 30.0 mmol), Na₂CO₃ (6.36 g, 60 mmol), and 200 ml of 2-ethoxyethanol were charged into a reaction vessel and then a mixture was refluxed under a nitrogen atmosphere for 24 hours. After the reaction was completed, dichloromethane was added to the reaction mixture to dissolve the reaction mixture therein, and then a resulting solution was subjected to extraction with dichloromethane and distilled water. MgSO₄ was used to remove water from an organic layer, and after filtering, the solvent was removed therefrom under reduced pressure. Column chromatography was performed with hexane and dichloromethane to obtain the Compound 330 (2.95 g, a yield 39%).

MS (m/z): 1258.57

(24) Preparation of Compound 352

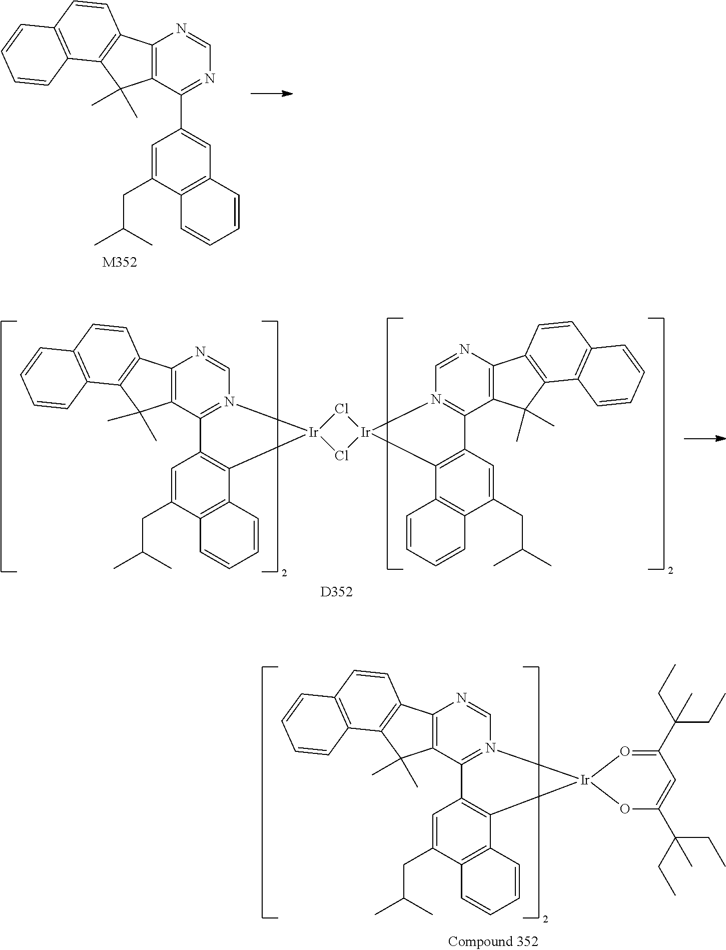

Preparation of Compound D352

M352 (14.14 g, 33 mmol), 2-ethoxyethanol 200 ml, and distilled water 66 ml were charged into a reaction vessel, followed by nitrogen bubbling for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D352 (6.01 g, a yield 37%).

Preparation of Compound 352

D352 (6.01 g, 2.78 mmol), 3,7-diethyl-3,7-dimethylnonane-4,6-dione (6.67 g, 27.8 mmol), Na₂CO₃ (5.88 g, 56 mmol), and 200 ml 2-ethoxyethanol were charged into a reaction vessel and a mixture was refluxed for 24 hours under a nitrogen atmosphere. After the reaction was completed, dichloromethane was added to the reaction mixture to dissolve the reaction mixture therein, and then a resulting solution was subjected to extraction with dichloromethane and distilled water. MgSO₄ was used to remove water from an organic layer, and after filtering, the solvent was removed therefrom under reduced pressure. Column chromatography was performed with hexane and dichloromethane to obtain the Compound 352 (2.50 g, a yield 35%).

MS (m/z): 1286.60

(25) Preparation of Compound 363

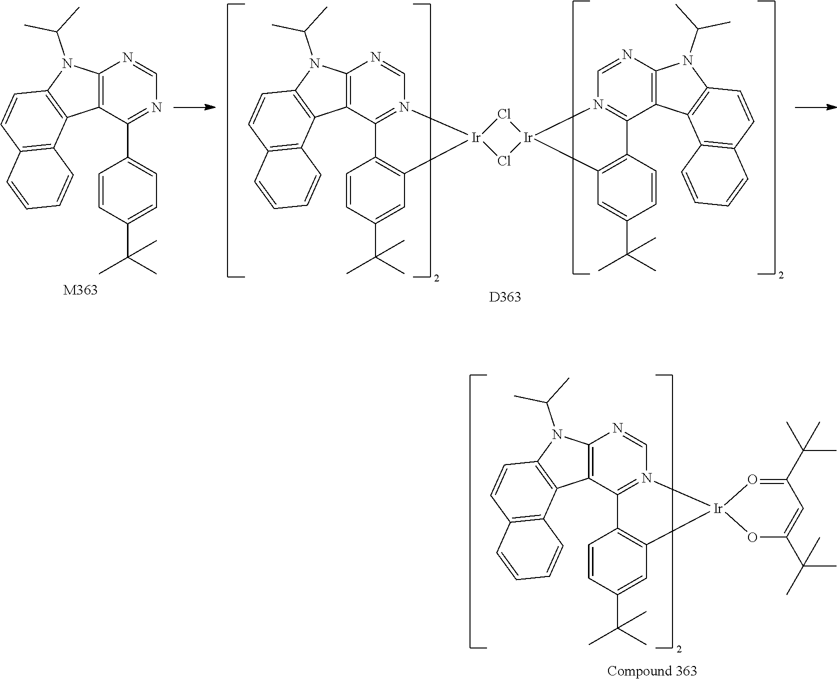

Preparation of Compound D363

M363 (12.99 g, 33 mmol), 2-ethoxyethanol 200 ml, and distilled water 66 ml were charged into a reaction vessel, followed by nitrogen bubbling for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D363 (5.32 g, a yield 35%).

Preparation of Compound 363

D363 (5.32 g, 2.63 mmol), 2,2,6,6-tetramethylheptane-3,5-dione (4.84 g, 26.3 mmol), Na₂CO₃ (5.56 g, 53 mmol), and 200 ml of 2-ethoxyethanol were charged into a reaction vessel and then a mixture was refluxed for 24 hours under a nitrogen atmosphere. After the reaction was completed, dichloromethane was added to the reaction mixture to dissolve the reaction mixture therein, and then a resulting solution was subjected to extraction with dichloromethane and distilled water. MgSO₄ was used to remove water from an organic layer, and after filtering, the solvent was removed therefrom under reduced pressure. Column chromatography was performed with hexane and dichloromethane to obtain the Compound 363 (2.38 g, a yield 39%).

MS (m/z): 1160.53

(26) Preparation of Compound 382

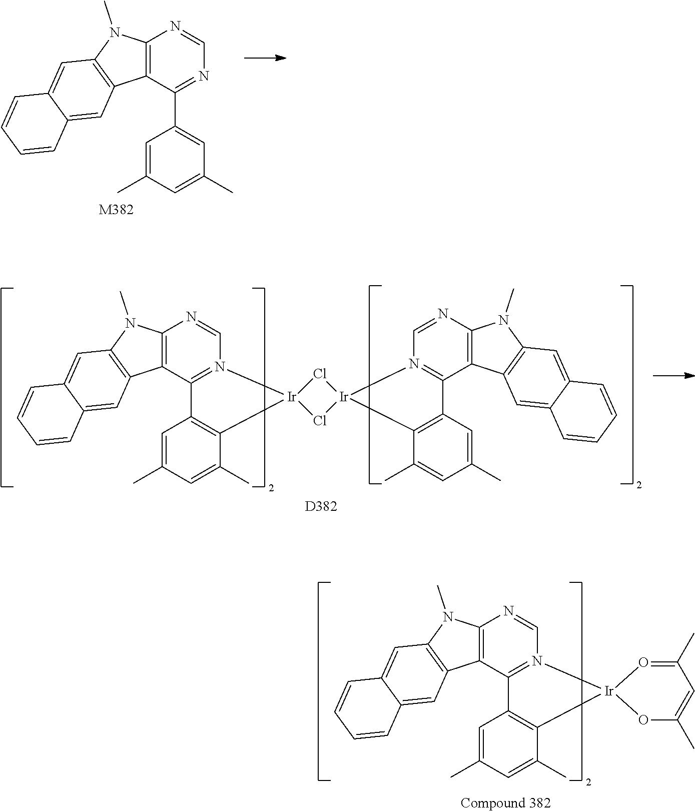

Preparation of Compound D382

M382 (11.13 g, 33 mmol), 2-ethoxyethanol 200 ml, and distilled water 66 ml were charged into a reaction vessel, followed by nitrogen bubbling for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D382 (7.02 g, a yield 52%).

Preparation of Compound 382

D382 (7.02 g, 3.90 mmol), pentane-2,4-dione (3.90 g, 39.0 mmol), Na₂CO₃ (8.27 g, 78 mmol), and 200 ml of 2-ethoxyethanol were charged into a reaction vessel and a mixture was refluxed for 24 hours under a nitrogen atmosphere. After the reaction was completed, dichloromethane was added to the reaction mixture to dissolve the reaction mixture therein, and then a resulting solution was subjected to extraction with dichloromethane and distilled water. MgSO₄ was used to remove water from an organic layer, and after filtering, the solvent was removed therefrom under reduced pressure. Column chromatography was performed with hexane and dichloromethane to obtain the Compound 382 (3.31 g, a yield 44%).

MS (m/z): 964.31

(27) Preparation of Compound 410

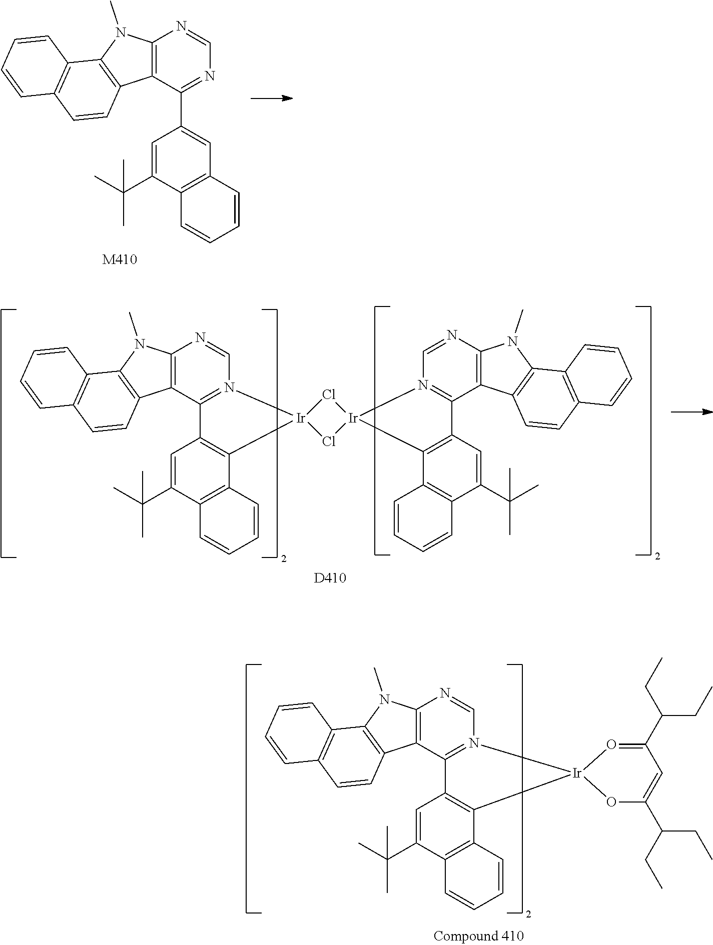

Preparation of Compound D410

M410 (13.71 g, 33 mmol), 2-ethoxyethanol 200 ml, and distilled water 66 ml were charged to a reaction vessel, followed by nitrogen bubbling for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D410 (7.13 g, a yield 45%).

Preparation of Compound 410

D410 (7.13 g, 3.38 mmol), 3,7-diethylnonane-4,6-dione (7.17 g, 33.8 mmol), Na₂CO₃ (7.15 g, 68 mmol), and 200 ml of 2-ethoxyethanol were charged into a reaction vessel and then a mixture was refluxed under a nitrogen atmosphere for 24 hours. After the reaction was completed, dichloromethane was added to the reaction mixture to dissolve the reaction mixture therein, and then a resulting solution was subjected to extraction with dichloromethane and distilled water. MgSO₄ was used to remove water from an organic layer, and after filtering, the solvent was removed therefrom under reduced pressure. Column chromatography was performed with hexane and dichloromethane. Thus, the Compound 410 (3.58 g, a yield 43%) was obtained.

MS (m/z): 1232.53

(28) Preparation of Compound 417

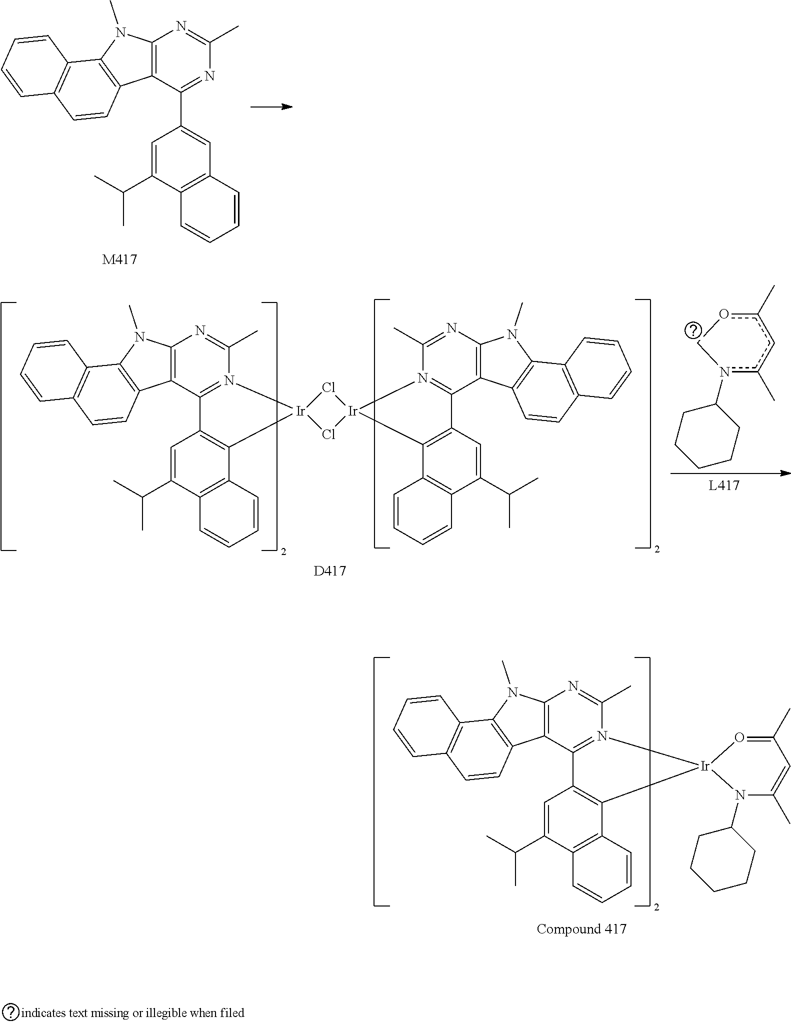

Preparation of Compound D417

M417 (13.71 g, 33 mmol), 2-ethoxyethanol 200 ml, and distilled water 66 ml were charged into a reaction vessel, followed by nitrogen bubbling for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D417 (6.50 g, a yield 41%).

Preparation of Compound 417

M417 (6.50 g, 3.1 mmol), and 200 ml of THF were charged into a reaction vessel under a nitrogen stream, and L417 (1.49 g, 6.8 mmol) dissolved in THF was slowly added thereto, followed by stirring at room temperature overnight. After completion of the reaction, THF was removed therefrom under reduced pressure in vacuum, the mixture was subjected to extraction with toluene, and filtered with celite. Toluene was removed therefrom under reduced pressure, and column chromatography was performed with hexane and dichloromethane to obtain the Compound 417 (2.88 g, a yield 39%).

MS (m/z): 1201.50(29)

Preparation of Compound 418

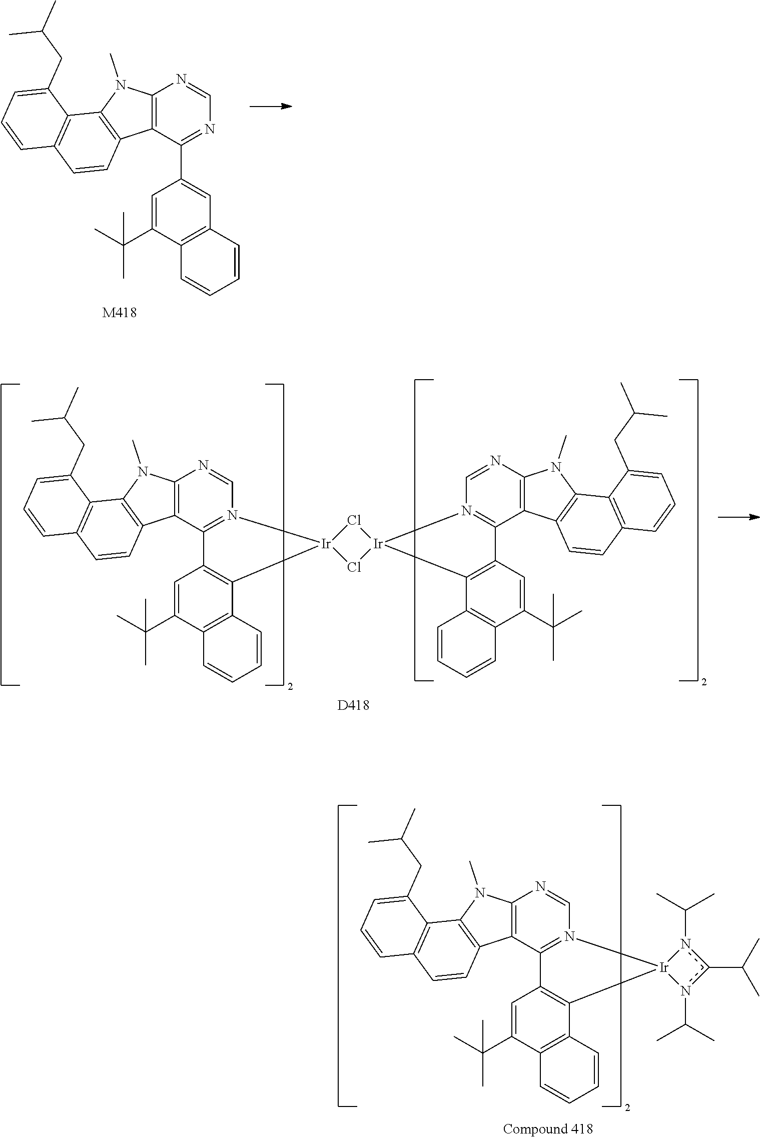

Preparation of Compound D418

M418 (15.56 g, 33 mmol), 2-ethoxyethanol 200 ml, and distilled water 66 ml were charged into a reaction vessel and nitrogen bubbling was performed for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D418 (6.84 g, a yield 39%).

Preparation of Compound 418

2-bromopropane (1.44 g, 11.70 mmol) and 50 ml of THF were charged into a reaction vessel under a nitrogen stream, and a temperature was lowered to −78° C., and n-BuLi (4.80 ml, 2.5M in hexane) was slowly added thereto. After 30 minutes, while the temperature was maintained, N,N′-diisopropylcarbodiimide (1.48 g, 11.70 mmol) was slowly added thereto and the mixture was stirred for 30 minutes. The reaction mixture was charged to a reaction vessel in which D418 (6.84 g, 2.93 mmol) was dissolved in 200 ml THF and then the mixture was stirred at 80° C. for 8 hours. The temperature of the reaction mixture was lowered to room temperature, volatile substances were removed therefrom, and the mixture was subjected to recrystallization with THF/pentane and dichloromethane/hexane solvent. Thus, the compound 418 (2.90 g, a yield 38%) was obtained.

MS (m/z): 1302.65

(30) Preparation of Compound 426

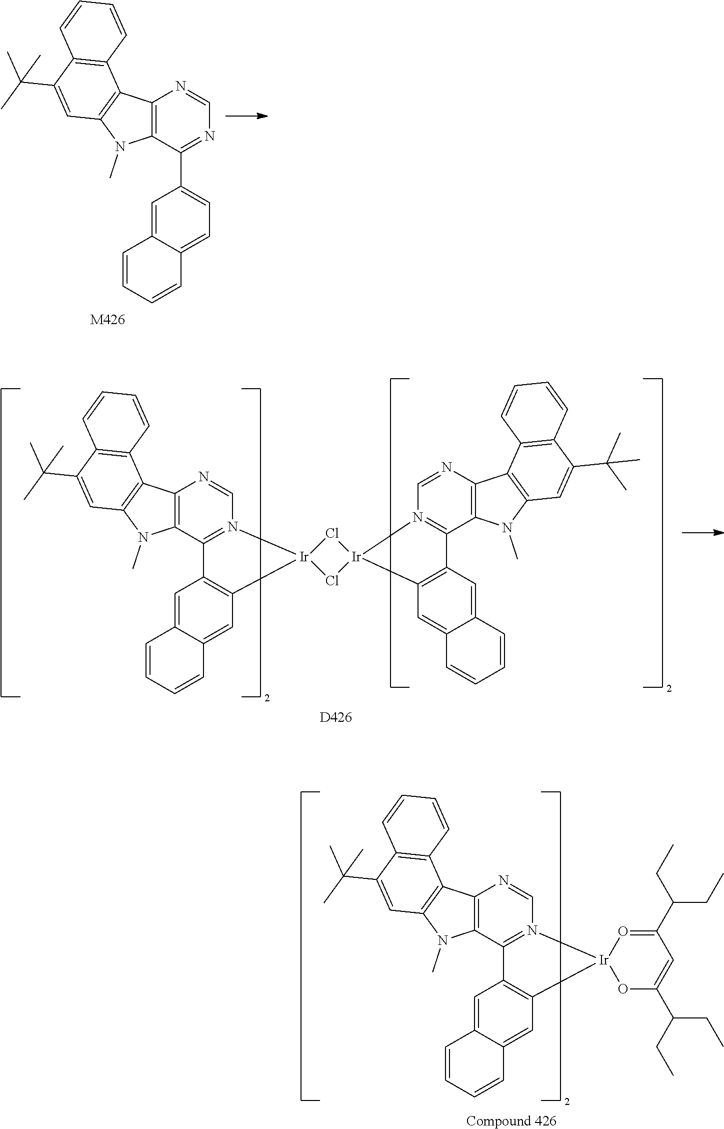

Preparation of Compound D426

M426 (13.71 g, 33 mmol), 2-ethoxyethanol 200 ml, and distilled water 66 ml were charged into a reaction vessel, followed by nitrogen bubbling for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D426 (5.86 g, a yield 37%).

Preparation of Compound 426

D426 (5.86 g, 2.28 mmol), 3,7-diethylnonane-4,6-dione (5.89 g, 27.8 mmol), Na₂CO₃ (5.88 g, 56 mmol), and 200 ml of 2-ethoxyethanol were charged into a reaction vessel and then a mixture was refluxed under a nitrogen atmosphere for 24 hours. After the reaction was completed, dichloromethane was added to the reaction mixture to dissolve the reaction mixture therein, and then a resulting solution was subjected to extraction with dichloromethane and distilled water. MgSO₄ was used to remove water from an organic layer, and after filtering, the solvent was removed therefrom under reduced pressure. Column chromatography was performed with hexane and dichloromethane. Thus, the Compound 426 (2.39 g, a yield 35%) was obtained.

MS (m/z): 1232.53

(31) Preparation of Compound 441

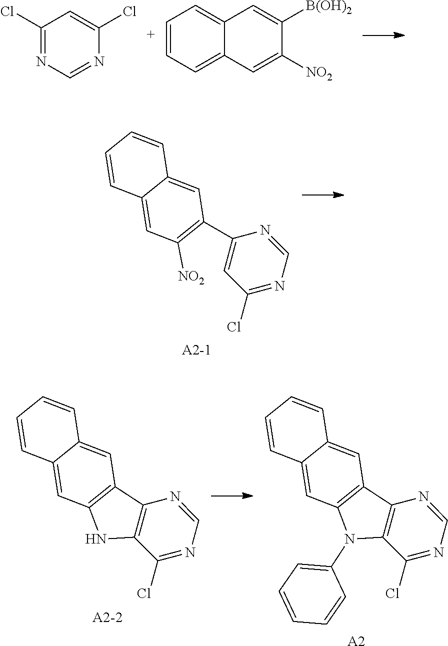

(Step 1) Preparation of Compound A2

Preparation of Compound A2-1

4,6-dichloropyrimidine (25 g, 167.81 mmol), (3-nitronaphthalen-2-yl)boronic acid (40.05 g, 184.59 mmol), Pd(PPh₃)₄ (9.7 g, 8.39 mmol) and K₂CO₃ (46.38 g, 335.62 mmol) were dissolved in 1,4-dioxane (500 ml) and distilled water (100 ml)) in a reaction vessel and a mixture was refluxed for 15 hours. After completion of the reaction, the mixture was cooled to room temperature and was subjected to extraction using dichloromethane and distilled water. MgSO₄ was added to an organic layer to remove moisture therefrom, and then the solvent was removed therefrom via filtration under reduced pressure. Column chromatography was performed with hexane and dichloromethane. Thus, the Compound A2-1 (36.43 g, a yield 76%) was obtained.

MS (m/z): 285.69

Preparation of Compound A2-2

A2-1 (36.43 g, 127.53 mmol) and PPh₃ (83.62 g, 318.82 mmol) were dissolved in 1,2-dichlorobenzene (400 ml) in a reaction vessel and a mixture was refluxed for 15 hours. After completion of the reaction, the mixture was cooled to room temperature and was subjected to extraction using dichloromethane and distilled water. MgSO₄ was added to an organic layer to remove moisture therefrom, and then the solvent was removed therefrom via filtration under reduced pressure. Column chromatography was performed with hexane and dichloromethane. Thus, the Compound A2-2 (22.32 g, a yield 69%) was obtained.

MS (m/z): 253.69

Preparation of Compound A2

A2-2 (22.32 g, 87.98 mmol), iodobenzene (19.74 g, 94.78 mmol), CuI (15 g, 87.98 mmol), trans-1 2-cyclohexanediamine (10.05 g, 87.98 mmol) and NaOH (7.04 g, 175.96 mmol) was dissolved in toluene (250 ml) in a reaction vessel and a mixture was refluxed for 16 hours. After the reaction solution was cooled to room temperature, a resulting solution was subjected to extraction using dichloromethane and distilled water. MgSO₄ was added to an organic layer to remove moisture therefrom, and then the solvent was removed therefrom via filtration under reduced pressure. Column chromatography was performed with hexane and dichloromethane. Thus, the Compound A2 (25.2 g, a yield 87%) in a form of an ivory solid was obtained.

MS (m/z): 329.78

(Step 2) Preparation of Compound M441

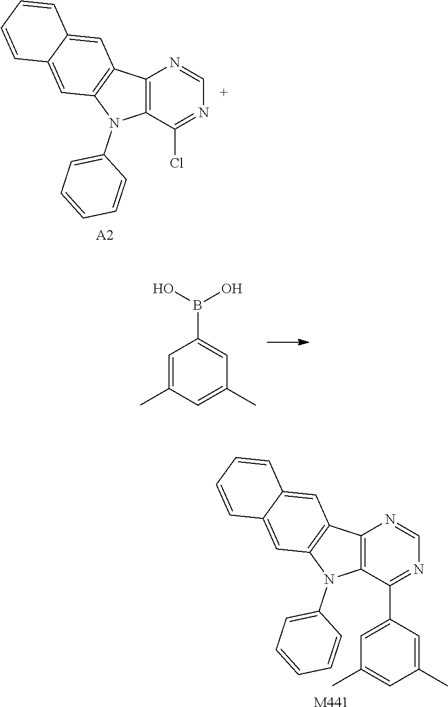

A2 (25.2 g, 76.41 mmol), (3,5-dimethylphenyl)boronic acid (12.61 g, 84.05 mmol), Pd(PPh₃)₄ (8.83 g, 7.64 mmol) and K₂CO₃ (21.12 g, 152.82 mmol) were dissolved in 1,4-dioxane (375 ml) and distilled water (75 ml) in a reaction vessel and a mixture was refluxed for 16 hours. After completion of the reaction, the mixture was cooled to room temperature and was subjected to extraction using dichloromethane and distilled water. MgSO₄ was added to an organic layer to remove moisture therefrom, and then the solvent was removed therefrom via filtration under reduced pressure. Column chromatography was performed with hexane and MC. Thus, the Compound M441 (22.28 g, a yield 73%) was obtained.

MS (m/z): 399.49

(Step 3) Preparation of Compound 441

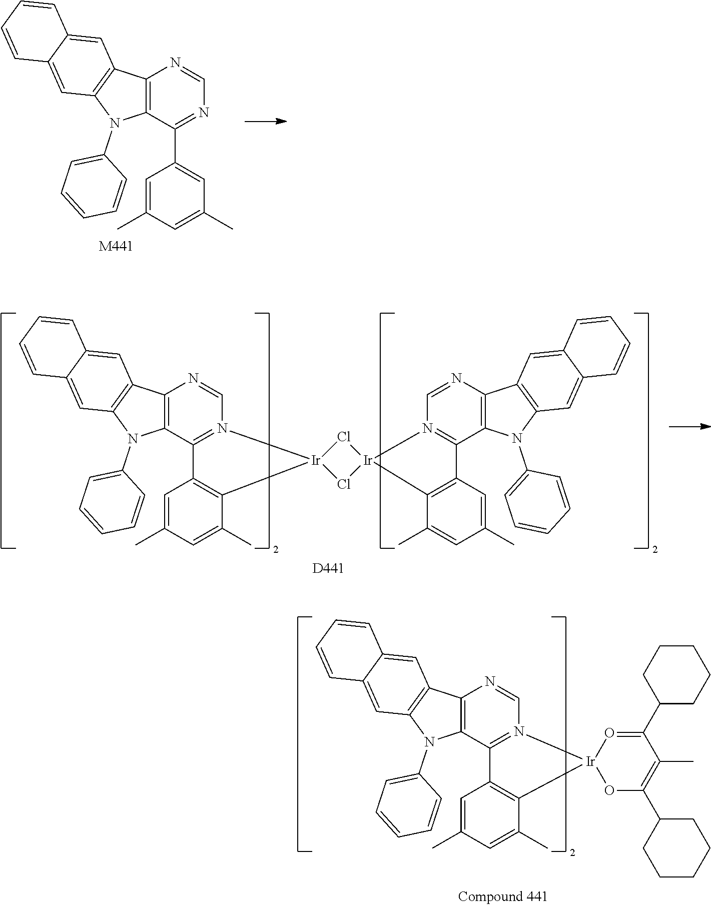

Preparation of Compound D441

M441 (13.18 g, 33 mmol), 2-ethoxyethanol 200 ml, and distilled water 66 ml were charged into a reaction vessel, followed by nitrogen bubbling for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D441 (5.07 g, a yield 33%).

Preparation of Compound 441

D441 (5.07 g, 2.48 mmol), 1,3-dicyclohexyl-2-methylpropane-1,3-dione (6.20 g, 24.8 mmol), Na₂CO₃ (5.25 g, 50 mmol), and 200 ml of 2-ethoxyethanol were charged into a reaction vessel and then a mixture was refluxed for 24 hours under a nitrogen atmosphere. After the reaction was completed, dichloromethane was added to the reaction mixture to dissolve the reaction mixture therein, and then a resulting solution was subjected to extraction with dichloromethane and distilled water. MgSO₄ was used to remove water from an organic layer, and after filtering, the solvent was removed therefrom under reduced pressure. Column chromatography was performed with hexane and dichloromethane to obtain the Compound 441 (1.90 g, a yield 31%).

MS (m/z): 1238.48

(32) Preparation of Compound 470

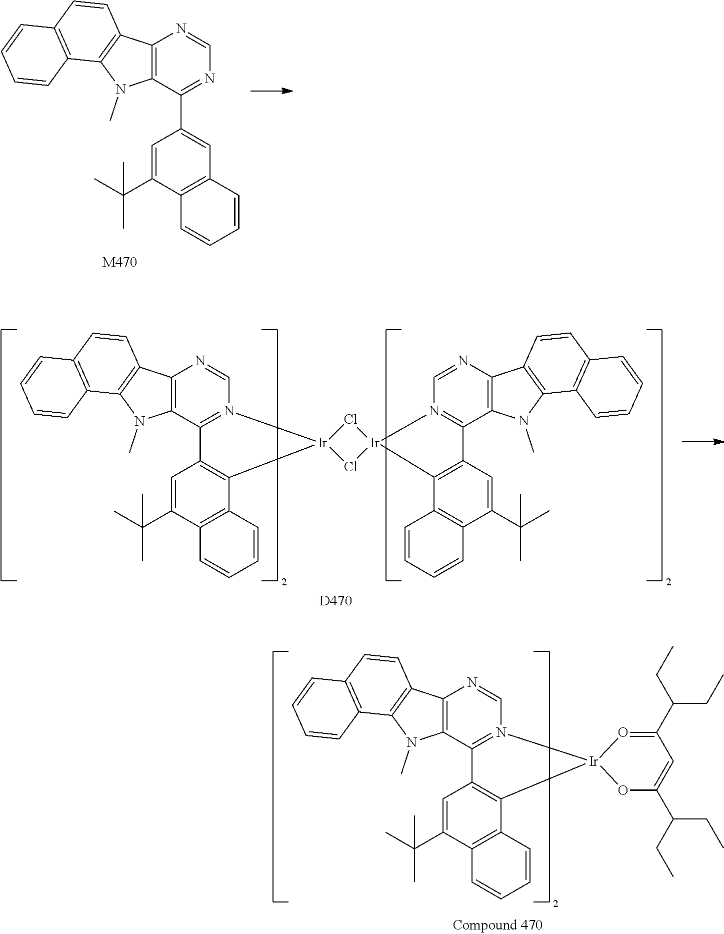

Preparation of Compound D470

M470 (13.71 g, 33 mmol), 2-ethoxyethanol 200 ml, and distilled water 66 ml were charged to a reaction vessel, followed by nitrogen bubbling for 1 hour, and then IrCl₃,H₂O (5.29 g, 15 mmol) was added thereto and a mixture was refluxed for 24 hours. After the reaction was completed, a temperature was slowly lowered to room temperature and a resulting solid was filtered. The filtered solid was washed with methanol and dried to obtain the Compound D470 (6.34 g, a yield 40%).

Preparation of Compound 470

D470 (6.34 g, 3.00 mmol), 3,7-diethylnonane-4,6-dione (6.37 g, 30.0 mmol), Na₂CO₃ (6.36 g, 60 mmol), and 200 ml of 2-ethoxyethanol were charged into a reaction vessel and then a mixture was refluxed under a nitrogen atmosphere for 24 hours. After the reaction was completed, dichloromethane was added to the reaction mixture to dissolve the reaction mixture therein, and then a resulting solution was subjected to extraction with dichloromethane and distilled water. MgSO₄ was used to remove water from an organic layer, and after filtering, the solvent was removed therefrom under reduced pressure. Column chromatography was performed with hexane and dichloromethane to obtain the Compound 470 (2.88 g, a yield 39%).

MS (m/z): 1232.53

### PRESENT EXAMPLE

### Present Example 1

A glass substrate having a thin film of ITO (indium tin oxide) having a thickness of 1,000 Å coated thereon was washed, followed by ultrasonic cleaning with a solvent such as isopropyl alcohol, acetone, and methanol. Then, the glass substrate was dried. Thus, an ITO transparent electrode was formed. HI-1 as a hole injection material was deposited on the ITO transparent electrode in a thermal vacuum deposition manner. Thus, a hole injection layer having a thickness of 60 nm was formed. then, NPB as a hole transport material was deposited on the hole injection layer in a thermal vacuum deposition manner. Thus, a hole transport layer having a thickness of 80 nm was formed. Then, CBP as a host material of a light-emitting layer was deposited on the hole transport layer in a thermal vacuum deposition manner. The Compound 1 as a dopant was doped into the host material at a doping concentration of 5%. Thus, the light-emitting layer of a thickness of 30 nm was formed. ET-1:Liq (1:1) (30 nm) as a material for an electron transport layer and an electron injection layer was deposited on the light-emitting layer. Then, 100 nm thick aluminum was deposited thereon to form a negative electrode. In this way, an organic light-emitting diode was manufactured.

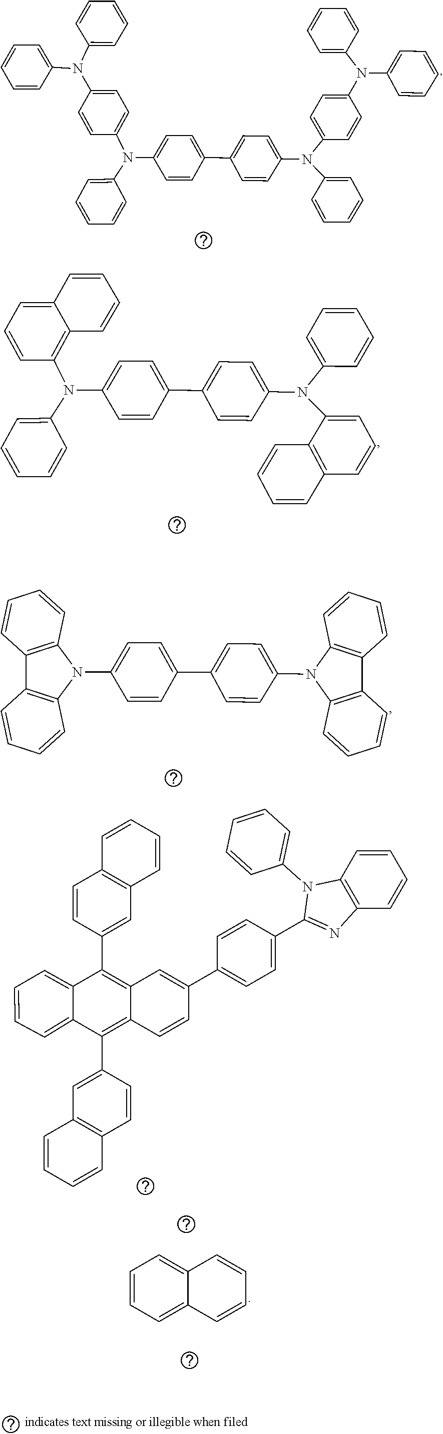 [SMILES: c1ccc(N(c2ccccc2)c2ccc(N(c3ccccc3)c3ccc(-c4ccc(N(c5ccccc5)c5ccc(N(c6ccccc6)c6ccccc6)cc5)cc4)cc3)cc2)cc1 ; c1ccc(N(c2ccc(-c3ccc(N(c4ccccc4)c4cccc5ccccc45)cc3)cc2)c2cccc3ccccc23)cc1 ; c1ccc2c(c1)c1ccccc1n2-c1ccc(-c2ccc(-n3c4ccccc4c4ccccc43)cc2)cc1 ; c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc2ccccc2c1]

The HI-1 means N1,N1′-([1,1′-biphenyl]-4,4′-diyl)bis(N1,N4,N4-triphenylbenzene-1,4-diamine).

The ET-1 means 2-(4-(9,10-di(naphthalen-2-yl) anthracen-2-yl)phenyl)-1-phenyl-1H-benzo[d]imidazole.

### Present Examples 2 to 32 and Comparative Example 1

Organic light-emitting diodes of Present Examples 2 to 32 and Comparative Example 1 were manufactured in the same manner as in Present Example 1, except that Compounds indicated in following Tables 1 to 3 were used instead of the Compound 1 as the dopant in the Present Example 1.

<Performance Evaluation of Organic Light-Emitting Diodes>

Regarding the organic light emitting diodes prepared according to Present Examples 1 to 95 and Comparative Example 1, operation voltages and efficiency characteristics at 10 mA/cm² current, and lifetime characteristics when being accelerated at 20 mA/cm² were measured. Thus, operation voltage (V), EQE (%), and LT95(%) were measured and were converted to values relative to values of Comparative Example 1, and results are shown in Tables 1 to 8 below. LT95 refers to a lifetime evaluation scheme and means a time it takes for an organic light-emitting diode to lose 5% of initial brightness thereof.

TABLE 1

| | | Operation | | |
|---|---|---|---|---|
| | | voltage | EQE | LT95 |
| | | (%, relative | (%, relative | (%, relative |
| Examples | Dopant | value) | value) | value) |
| Comparative | RD | 100 | 100 | 100 |
| Example 1 | | | | |
| Present Example 1 | 1 | 91.5 | 121 | 134 |
| Present Example 2 | 31 | 89.0 | 131 | 152 |
| Present Example 3 | 50 | 88.1 | 138 | 158 |
| Present Example 4 | 57 | 86.5 | 141 | 122 |
| Present Example 5 | 58 | 87.3 | 145 | 116 |
| Present Example 6 | 74 | 90.6 | 127 | 140 |
| Present Example 7 | 86 | 89.8 | 134 | 146 |
| Present Example 8 | 102 | 92.3 | 124 | 128 |
| Present Example 9 | 124 | 90.6 | 118 | 127 |
| Present Example 10 | 148 | 88.1 | 131 | 145 |

A structure of RD as a dopant material of Comparative Example 1 of the Table 1 is as follows.

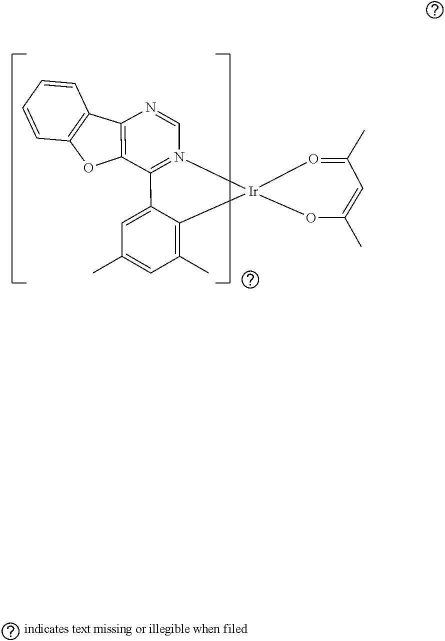

TABLE 2

| | | Operation | | |
|---|---|---|---|---|
| | | voltage | EQE | LT95 |
| | | (%, relative | (%, relative | (%, relative |
| Examples | Dopant | value) | value) | value) |
| Comparative | RD | 100 | 100 | 100 |
| Example 1 | | | | |
| Present Example 11 | 170 | 87.3 | 135 | 149 |
| Present Example 12 | 177 | 85.6 | 138 | 122 |
| Present Example 13 | 178 | 86.5 | 142 | 118 |
| Present Example 14 | 190 | 89.8 | 125 | 140 |
| Present Example 15 | 216 | 89.0 | 128 | 136 |
| Present Example 16 | 223 | 91.5 | 121 | 131 |
| Present Example 17 | 241 | 90.4 | 109 | 130 |
| Present Example 18 | 271 | 87.1 | 117 | 138 |
| Present Example 19 | 290 | 86.3 | 125 | 162 |
| Present Example 20 | 298 | 84.6 | 137 | 114 |

TABLE 3

| | | Operation | | |
|---|---|---|---|---|
| | | voltage | EQE | LT95 |
| | | (V, relative | (%, relative | (%, relative |
| Examples | Dopant | value) | value) | value) |
| Comparative | RD | 100 | 100 | 100 |
| Example 1 | | | | |
| Present Example 21 | 300 | 85.4 | 133 | 122 |
| Present Example 22 | 310 | 89.6 | 113 | 170 |
| Present Example 23 | 330 | 88.8 | 121 | 154 |
| Present Example 24 | 352 | 87.9 | 129 | 146 |
| Present Example 25 | 363 | 89.2 | 103 | 113 |
| Present Example 26 | 382 | 88.3 | 107 | 118 |
| Present Example 27 | 410 | 85.0 | 123 | 139 |
| Present Example 28 | 417 | 84.2 | 127 | 107 |
| Present Example 29 | 418 | 83.3 | 131 | 102 |
| Present Example 30 | 426 | 86.7 | 115 | 128 |
| Present Example 31 | 441 | 87.5 | 111 | 123 |
| Present Example 32 | 470 | 85.8 | 119 | 134 |

TABLE 4

| | | Operation | | |
|---|---|---|---|---|
| | | voltage | EQE | LT95 |
| | | (V, relative | (%, relative | (%, relative |
| Examples | Dopant | value) | value) | value) |
| Comparative | RD | 100 | 100 | 100 |
| Example 1 | | | | |
| Present Example 33 | 481 | 88.2 | 139 | 155 |
| Present Example 34 | 482 | 88.5 | 140 | 163 |
| Present Example 35 | 483 | 88.3 | 140 | 190 |
| Present Example 36 | 484 | 88.7 | 141 | 160 |
| Present Example 37 | 485 | 88.6 | 141 | 185 |
| Present Example 38 | 486 | 88.3 | 143 | 161 |
| Present Example 39 | 487 | 88.4 | 151 | 153 |
| Present Example 40 | 488 | 88.5 | 155 | 150 |
| Present Example 41 | 489 | 88.3 | 150 | 152 |
| Present Example 42 | 490 | 88.3 | 142 | 157 |
| Present Example 43 | 491 | 88.4 | 144 | 163 |
| Present Example 44 | 492 | 88.5 | 152 | 158 |

TABLE 5

| | | Operation | | |
|---|---|---|---|---|
| | | voltage | EQE | LT95 |
| | | (V, relative | (%, relative | (%, relative |
| Examples | Dopant | value) | value) | value) |
| Comparative | RD | 100 | 100 | 100 |
| Example 1 | | | | |
| Present Example 45 | 493 | 88.5 | 157 | 155 |
| Present Example 46 | 494 | 88.4 | 153 | 156 |
| Present Example 47 | 495 | 88.3 | 143 | 162 |
| Present Example 48 | 496 | 88.3 | 145 | 189 |
| Present Example 49 | 497 | 88.4 | 153 | 188 |
| Present Example 50 | 498 | 88.5 | 157 | 186 |
| Present Example 51 | 499 | 88.3 | 153 | 183 |
| Present Example 52 | 500 | 88.3 | 144 | 190 |
| Present Example 53 | 501 | 88.2 | 142 | 163 |
| Present Example 54 | 502 | 88.3 | 150 | 155 |
| Present Example 55 | 503 | 88.3 | 153 | 154 |
| Present Example 56 | 504 | 88.2 | 148 | 152 |

TABLE 6

| | | Operation | | |
|---|---|---|---|---|
| | | voltage | EQE | LT95 |
| | | (V, relative | (%, relative | (%, relative |
| Examples | Dopant | value) | value) | value) |
| Comparative | RD | 100 | 100 | 100 |
| Example 1 | | | | |
| Present Example 57 | 505 | 88.3 | 144 | 164 |
| Present Example 58 | 506 | 88.4 | 151 | 158 |
| Present Example 59 | 507 | 88.5 | 155 | 156 |
| Present Example 60 | 508 | 88.2 | 152 | 155 |
| Present Example 61 | 509 | 88.3 | 144 | 192 |
| Present Example 62 | 510 | 88.3 | 153 | 190 |
| Present Example 63 | 511 | 88.5 | 155 | 187 |
| Present Example 64 | 512 | 88.2 | 152 | 184 |
| Present Example 65 | 513 | 88.3 | 145 | 157 |
| Present Example 66 | 514 | 88.4 | 152 | 154 |
| Present Example 67 | 515 | 88.5 | 150 | 152 |
| Present Example 68 | 516 | 88.5 | 159 | 158 |

TABLE 7

| | | Operation | | |
|---|---|---|---|---|
| | | voltage | EQE | LT95 |
| | | (V, relative | (%, relative | (%, relative |
| Examples | Dopant | value) | value) | value) |
| Comparative | RD | 100 | 100 | 100 |
| Example 1 | | | | |
| Present Example 69 | 517 | 88.7 | 156 | 160 |
| Present Example 70 | 518 | 88.7 | 155 | 159 |
| Present Example 71 | 519 | 88.3 | 152 | 149 |
| Present Example 72 | 520 | 88.2 | 143 | 150 |
| Present Example 73 | 521 | 88.1 | 141 | 145 |
| Present Example 74 | 522 | 88.5 | 160 | 188 |
| Present Example 75 | 523 | 88.7 | 156 | 189 |
| Present Example 76 | 524 | 88.2 | 159 | 177 |
| Present Example 77 | 525 | 88.7 | 160 | 182 |
| Present Example 78 | 526 | 88.8 | 158 | 184 |
| Present Example 79 | 527 | 88.5 | 155 | 195 |
| Present Example 80 | 528 | 88.5 | 155 | 201 |
| Present Example 81 | 529 | 88.5 | 157 | 194 |
| Present Example 82 | 530 | 88.7 | 156 | 190 |

TABLE 8

| | | Operation | | |
|---|---|---|---|---|
| | | voltage | EQE | LT95 |
| | | (V, relative | (%, relative | (%, relative |
| Examples | Dopant | value) | value) | value) |
| Comparative | RD | 100 | 100 | 100 |
| Example 1 | | | | |
| Present Example 83 | 531 | 87.9 | 157 | 152 |
| Present Example 84 | 532 | 88.1 | 158 | 155 |
| Present Example 85 | 533 | 88.2 | 159 | 156 |
| Present Example 86 | 534 | 88.2 | 160 | 158 |
| Present Example 87 | 535 | 87.8 | 162 | 140 |
| Present Example 88 | 536 | 87.9 | 163 | 145 |
| Present Example 89 | 537 | 87.9 | 155 | 178 |
| Present Example 90 | 538 | 87.7 | 143 | 170 |
| Present Example 91 | 539 | 89.8 | 149 | 140 |
| Present Example 92 | 540 | 89.9 | 147 | 142 |
| Present Example 93 | 541 | 89.9 | 151 | 168 |
| Present Example 94 | 542 | 89.5 | 153 | 138 |
| Present Example 95 | 543 | 89.4 | 155 | 150 |

It can be identified from the results of the above Table 1 to Table 8 that in the organic light-emitting diode in which the organometallic compound of each of Present Examples 1 to 95 according to the present disclosure is used as the dopant of the light-emitting layer of the diode, the operation voltage of the diode is lowered, and external quantum efficiency (EQE) and lifetime (LT95) of the diode are improved, compared to those in Comparative Example 1.

A scope of protection of the present disclosure should be construed by the scope of the claims, and all technical ideas within the scope equivalent thereto should be construed as being included in the scope of the present disclosure. Although the embodiments of the present disclosure have been described in more detail with reference to the accompanying drawings, the present disclosure is not necessarily limited to these embodiments. The present disclosure can be implemented in various modified manners within the scope not departing from the technical idea of the present disclosure. Accordingly, the embodiments disclosed in the present disclosure are not intended to limit the technical idea of the present disclosure, but to describe the present disclosure. the scope of the technical idea of the present disclosure is not limited by the embodiments. Therefore, it should be understood that the embodiments as described above are illustrative and non-limiting in all respects. The scope of protection of the present disclosure should be interpreted by the claims, and all technical ideas within the scope of the present disclosure should be interpreted as being included in the scope of the present disclosure.

What is claimed is:

1. An organometallic compound represented by a following Chemical Formula I: 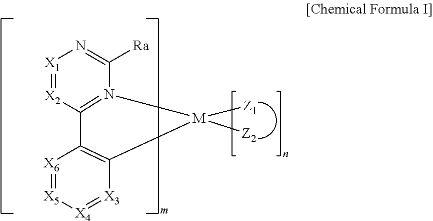
wherein in the Chemical Formula I:
M is one selected from a group consisting of Mo, W, Re, Ru, Os, Rh, Ir, Pd, Pt and Au;
Rₐ is one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;
each of X₁ and X₂ is carbon;
each of X₃ to X₆ independently is one selected from CR_{b} and N;
optionally, two R_{b} on the adjacent two of X₃ to X₆ may be connected to each other to form a ring structure comprising one selected from a group consisting of a substituted or unsubstituted C3-C20 cycloalkyl group, a substituted or unsubstituted C2-C20 heterocycloalkyl group, a substituted or unsubstituted C7-C20 arylalkyl group, a substituted or unsubstituted C2-C20 heteroarylalkyl group, a substituted or unsubstituted C3-C20 cycloalkenyl group, a substituted or unsubstituted C6-C30 aryl group, and a substituted or unsubstituted C3-C30 heteroaryl group,
R_{b} is one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;
(Z₁-Z₂) represents a bidentate ligand;
m is an integer selected from 1, 2 or 3, n is an integer selected from 0, 1 or 2, wherein a sum of m and n is an oxidation number of the metal M;
R is a fused ring connected to X₁ and X₂, and comprises one of following Chemical Formula II to Chemical Formula IV: 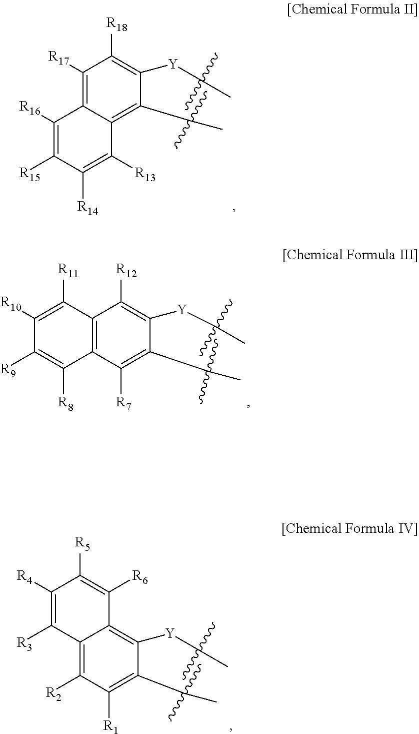
wherein in the Chemical Formula II to Chemical Formula IV,
Y is one selected from a group consisting of BR₁₉, CR₁₉R₂₀, C═O, CNR₁₉, SiR₁₉R₂₀, NR₁₉, PR₁₉, AsR₁₉, SbR₁₉, P(O)R₁₉, P(S)R₁₉, P(Se)R₁₉, As(O)R₁₉, As(S)R₁₉, As(Se)R₁₉, Sb(O)R₁₉, Sb(S)R₁₉, Sb(Se)R₁₉, O, S, N, Se, Te, SO, SO₂, SeO, SeO₂, TeO, and TeO₂;
each of R₁ to R₁₈ is independently one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group; and
each of R₁₉ and R₂₀ is independently one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group.

2. The organometallic compound of claim 1, wherein the Chemical Formula I is one selected from a group consisting of following Chemical Formulas II-1, II-2, III-1, III-2, IV-1, and IV-2: 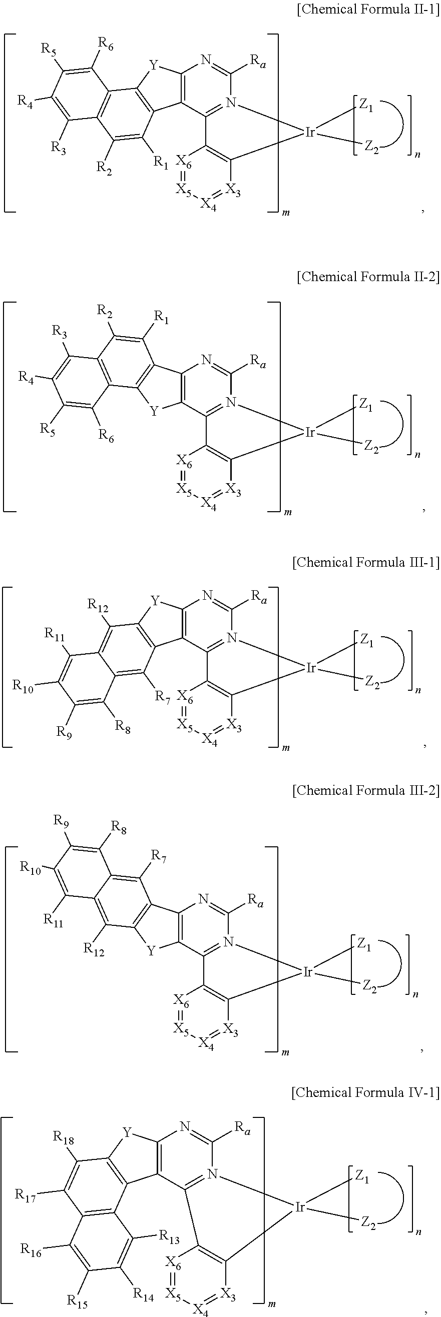 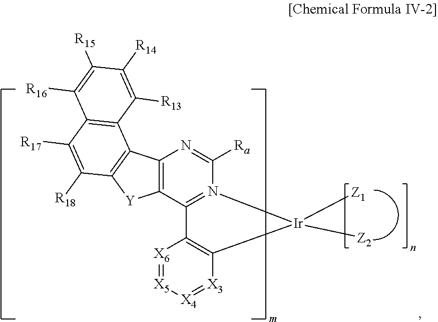
wherein in each of the Chemical Formulas II-1, II-2, III-1, III-2, IV-1 and IV-2,
Rₐ is one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;
each of X₃ to X₆ independently is one selected from CR_{b} and N;
optionally, two R_{b} on the adjacent two of X₃ to X₆ may be connected to each other to form a ring structure comprising one selected from a group consisting of a substituted or unsubstituted C3-C20 cycloalkyl group, a substituted or unsubstituted C2-C20 heterocycloalkyl group, a substituted or unsubstituted C7-C20 arylalkyl group, a substituted or unsubstituted C2-C20 heteroarylalkyl group, a substituted or unsubstituted C3-C20 cycloalkenyl group, a substituted or unsubstituted C6-C30 aryl group, and a substituted or unsubstituted C3-C30 heteroaryl group,
R_{b} represents one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;
(Z₁-Z₂) represents a bidentate ligand;
m is an integer selected from 1, 2 or 3, n is an integer selected from 0, 1 or 2, wherein a sum of m and n is an oxidation number of the metal M;
Y is one selected from a group consisting of BR₁₉, CR₁₉R₂₀, C═O, CNR₁₉, SiR₁₉R₂₀, NR₁₉, PR₁₉, AsR₁₉, SbR₁₉, P(O)R₁₉, P(S)R₁₉, P(Se)R₁₉, As(O)R₁₉, As(S)R₁₉, As(Se)R₁₉, Sb(O)R₁₉, Sb(S)R₁₉, Sb(Se)R₁₉, O, N, S, Se, Te, SO, SO₂, SeO, SeO₂, TeO, and TeO₂;
each of R₁ to R₁₈ is independently one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group; and
each of R₁₉ and R₂₀ is independently one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group.

3. The organometallic compound of claim 1, wherein M is iridium (Ir) or platinum (Pt).

4. The organometallic compound of claim 2, wherein the Chemical Formula I is selected from Chemical Formulas II-1 and II-2, wherein in each of the Chemical Formulas II-1 and II-2:
Rₐ is one selected from a group consisting of hydrogen, deuterium, halogen, a hydroxyl group, a cyano group, a nitro group, a substituted or unsubstituted C1-C8 alkyl group, a substituted or unsubstituted C1-C8 alkenyl group, a substituted or unsubstituted C6-C10 aryl group, a substituted or unsubstituted C6-C10 heteroaryl group, an alkoxy group, an amino group, a silyl group, an acyl group, a carbonyl group, a carboxylic acid group, an ester group, a nitrile group, an isonitrile group, and a phosphino group;
each of X₃ to X₆ independently is one selected from CR_{b} and N;
optionally, two R_{b} on the adjacent two of X₃ to X₆ are connected to each other to form a ring structure comprising one selected from a group consisting of a substituted or unsubstituted C3-C10 cycloalkyl group, a substituted or unsubstituted C2-C10 heterocycloalkyl group, a substituted or unsubstituted C7-C10 arylalkyl group, a substituted or unsubstituted C2-C10 heteroarylalkyl group, a substituted or unsubstituted C3-C10 cycloalkenyl group, a substituted or unsubstituted C6-C10 aryl group, and a substituted or unsubstituted C3-C10 heteroaryl group,
R_{b} represents one selected from a group consisting of hydrogen, deuterium, halogen, a hydroxyl group, a cyano group, a nitro group, an amidino group, a hydrazine group, a hydrazone group, a substituted or unsubstituted C1-C8 alkyl group, a substituted or unsubstituted C3-C12 cycloalkyl group, a substituted or unsubstituted C1-C12 heteroalkyl group, a substituted or unsubstituted C7-C12 arylalkyl group, a substituted or unsubstituted C1-C12 alkenyl group, a substituted or unsubstituted C3-C12 cycloalkenyl group, a substituted or unsubstituted C1-C12 heteroalkenyl group, an alkynyl group, a substituted or unsubstituted C6-C12 aryl group, a substituted or unsubstituted C3-C12 heteroaryl group, an alkoxy group, an amino group, a silyl group, an acyl group, a carbonyl group, a carboxylic acid group, an ester group, a nitrile group, an isonitrile group, a sulfonyl group, and a phosphino group;
(Z₁-Z₂) represents a bidentate ligand;
m is an integer selected from 1, 2 or 3, n is an integer selected from 0, 1 or 2, wherein a sum of m and n is an oxidation number of the metal M;
Y is one selected from a group consisting of CR₁₉R₂₀, NR₁₉, O, S, SO, and SO₂;
each of R₁ to R₁₈ is independently one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group; and
each of R₁₉ and R₂₀ is independently one selected from a group consisting of hydrogen, deuterium, a hydroxyl group, a cyano group, a substituted or unsubstituted C1-C12 alkyl group, a substituted or unsubstituted C3-C12 cycloalkyl group, a substituted or unsubstituted C1-C12 heteroalkyl group, a substituted or unsubstituted C1-C12 alkenyl group, a substituted or unsubstituted C3-C12 cycloalkenyl group, a substituted or unsubstituted C1-C12 heteroalkenyl group, a substituted or unsubstituted C6-C12 aryl group, and a substituted or unsubstituted C3-C12 heteroaryl group.

5. The organometallic compound of claim 2, wherein the Chemical Formula I is selected from Chemical Formulas III-1 and III-2, wherein in each of the Chemical Formulas III-1 and III-2:
Rₐ is one selected from a group consisting of hydrogen, deuterium, halogen, a hydroxyl group, a cyano group, a nitro group, a substituted or unsubstituted C1-C8 alkyl group, a substituted or unsubstituted C1-C8 alkenyl group, a substituted or unsubstituted C6-C10 aryl group, a substituted or unsubstituted C6-C10 heteroaryl group, an alkoxy group, an amino group, a silyl group, an acyl group, a carbonyl group, a carboxylic acid group, an ester group, a nitrile group, an isonitrile group, and a phosphino group;
each of X₃ to X₆ independently is one selected from CR_{b} and N;
optionally, two R_{b} on the adjacent two of X₃ to X₆ are connected to each other to form a ring structure comprising one selected from a group consisting of a substituted or unsubstituted C3-C10 cycloalkyl group, a substituted or unsubstituted C2-C10 heterocycloalkyl group, a substituted or unsubstituted C7-C10 arylalkyl group, a substituted or unsubstituted C2-C10 heteroarylalkyl group, a substituted or unsubstituted C3-C10 cycloalkenyl group, a substituted or unsubstituted C6-C10 aryl group, and a substituted or unsubstituted C3-C10 heteroaryl group,
R_{b} represents one selected from a group consisting of hydrogen, deuterium, halogen, a hydroxyl group, a cyano group, a nitro group, an amidino group, a hydrazine group, a hydrazone group, a substituted or unsubstituted C1-C8 alkyl group, a substituted or unsubstituted C3-C12 cycloalkyl group, a substituted or unsubstituted C1-C12 heteroalkyl group, a substituted or unsubstituted C7-C12 arylalkyl group, a substituted or unsubstituted C1-C12 alkenyl group, a substituted or unsubstituted C3-C12 cycloalkenyl group, a substituted or unsubstituted C1-C12 heteroalkenyl group, an alkynyl group, a substituted or unsubstituted C6-C12 aryl group, a substituted or unsubstituted C3-C12 heteroaryl group, an alkoxy group, an amino group, a silyl group, an acyl group, a carbonyl group, a carboxylic acid group, an ester group, a nitrile group, an isonitrile group, a sulfonyl group, and a phosphino group;
(Z₁-Z₂) represents a bidentate ligand;
m is an integer selected from 1, 2 or 3, n is an integer selected from 0, 1 or 2, wherein a sum of m and n is an oxidation number of the metal M;
Y is one selected from a group consisting of CR₁₉R₂₀, NR₁₉, O, S, SO, and SO₂;
each of R₁ to R₁₈ is independently one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group; and
each of R₁₉ and R₂₀ is independently one selected from a group consisting of hydrogen, deuterium, a hydroxyl group, a cyano group, a substituted or unsubstituted C1-C12 alkyl group, a substituted or unsubstituted C3-C12 cycloalkyl group, a substituted or unsubstituted C1-C12 heteroalkyl group, a substituted or unsubstituted C1-C12 alkenyl group, a substituted or unsubstituted C3-C12 cycloalkenyl group, a substituted or unsubstituted C1-C12 heteroalkenyl group, a substituted or unsubstituted C6-C12 aryl group, and a substituted or unsubstituted C3-C12 heteroaryl group.

6. The organometallic compound of claim 2, wherein the Chemical Formula I is selected from Chemical Formulas IV-1 and IV-2, wherein in each of the Chemical Formulas IV-1 and IV-2:
Rₐ is one selected from a group consisting of hydrogen, deuterium, halogen, a hydroxyl group, a cyano group, a nitro group, a substituted or unsubstituted C1-C8 alkyl group, a substituted or unsubstituted C1-C8 alkenyl group, a substituted or unsubstituted C6-C10 aryl group, a substituted or unsubstituted C6-C10 heteroaryl group, an alkoxy group, an amino group, a silyl group, an acyl group, a carbonyl group, a carboxylic acid group, an ester group, a nitrile group, an isonitrile group, and a phosphino group;
each of X₃ to X₆ independently is one selected from CR_{b} and N;
optionally, two R_{b} on the adjacent two of X₃ to X₆ are connected to each other to form a ring structure comprising one selected from a group consisting of a substituted or unsubstituted C3-C10 cycloalkyl group, a substituted or unsubstituted C2-C10 heterocycloalkyl group, a substituted or unsubstituted C7-C10 arylalkyl group, a substituted or unsubstituted C2-C10 heteroarylalkyl group, a substituted or unsubstituted C3-C10 cycloalkenyl group, a substituted or unsubstituted C6-C10 aryl group, and a substituted or unsubstituted C3-C10 heteroaryl group,
R_{b} represents one selected from a group consisting of hydrogen, deuterium, halogen, a hydroxyl group, a cyano group, a nitro group, an amidino group, a hydrazine group, a hydrazone group, a substituted or unsubstituted C1-C8 alkyl group, a substituted or unsubstituted C3-C12 cycloalkyl group, a substituted or unsubstituted C1-C12 heteroalkyl group, a substituted or unsubstituted C7-C12 arylalkyl group, a substituted or unsubstituted C1-C12 alkenyl group, a substituted or unsubstituted C3-C12 cycloalkenyl group, a substituted or unsubstituted C1-C12 heteroalkenyl group, an alkynyl group, a substituted or unsubstituted C6-C12 aryl group, a substituted or unsubstituted C3-C12 heteroaryl group, an alkoxy group, an amino group, a silyl group, an acyl group, a carbonyl group, a carboxylic acid group, an ester group, a nitrile group, an isonitrile group, a sulfonyl group, and a phosphino group;
(Z₁-Z₂) represents a bidentate ligand;
m is an integer selected from 1, 2 or 3, n is an integer selected from 0, 1 or 2, wherein a sum of m and n is an oxidation number of the metal M;
Y is one selected from a group consisting of CR₁₉R₂₀, NR₁₉, O, S, SO, and SO₂;
each of R₁ to R₁₈ is independently one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group; and
each of R₁₉ and R₂₀ is independently one selected from a group consisting of hydrogen, deuterium, a hydroxyl group, a cyano group, a substituted or unsubstituted C1-C12 alkyl group, a substituted or unsubstituted C3-C12 cycloalkyl group, a substituted or unsubstituted C1-C12 heteroalkyl group, a substituted or unsubstituted C1-C12 alkenyl group, a substituted or unsubstituted C3-C12 cycloalkenyl group, a substituted or unsubstituted C1-C12 heteroalkenyl group, a substituted or unsubstituted C6-C12 aryl group, and a substituted or unsubstituted C3-C12 heteroaryl group.

7. The organometallic compound of claim 1, wherein the compound represented by the Chemical Formula I is selected from the following compounds 1 to 543

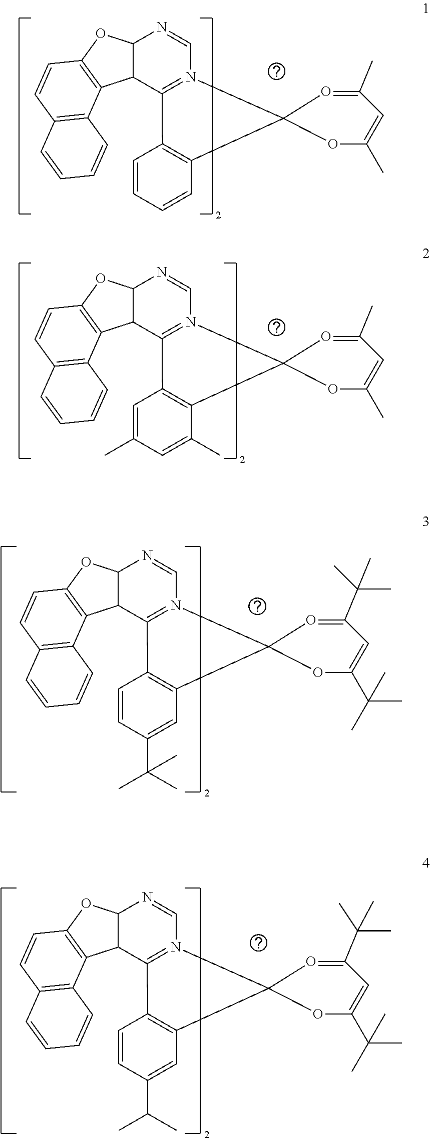

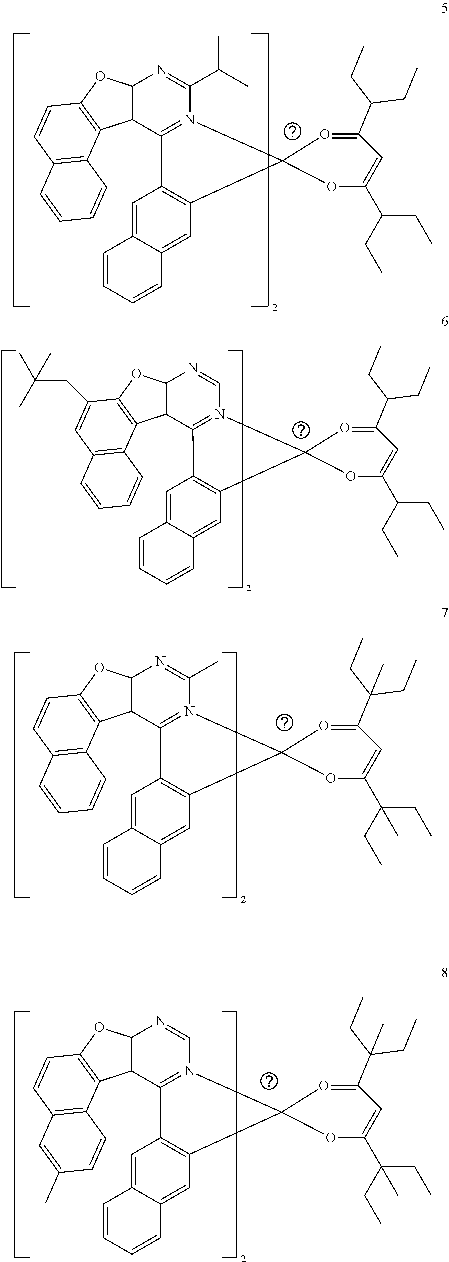

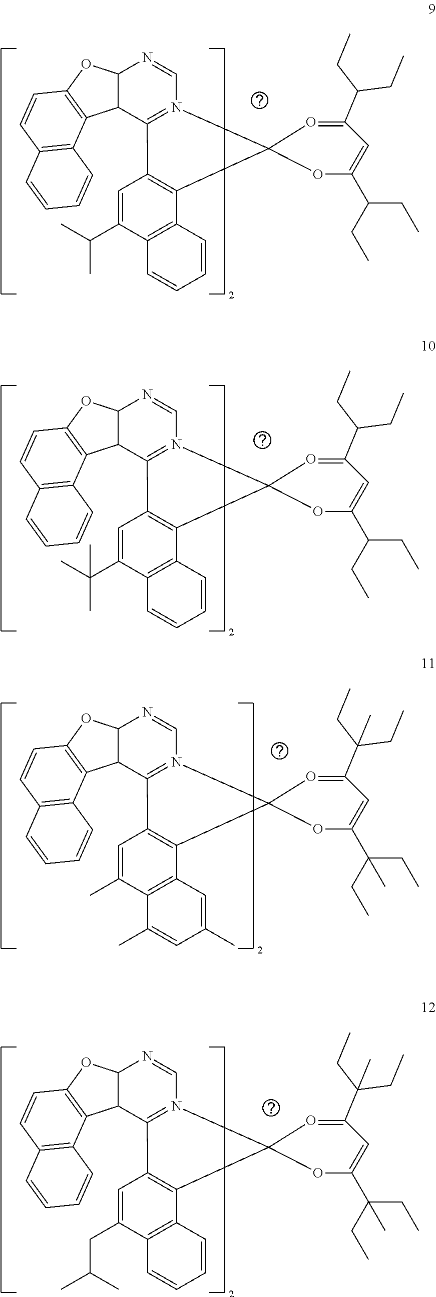

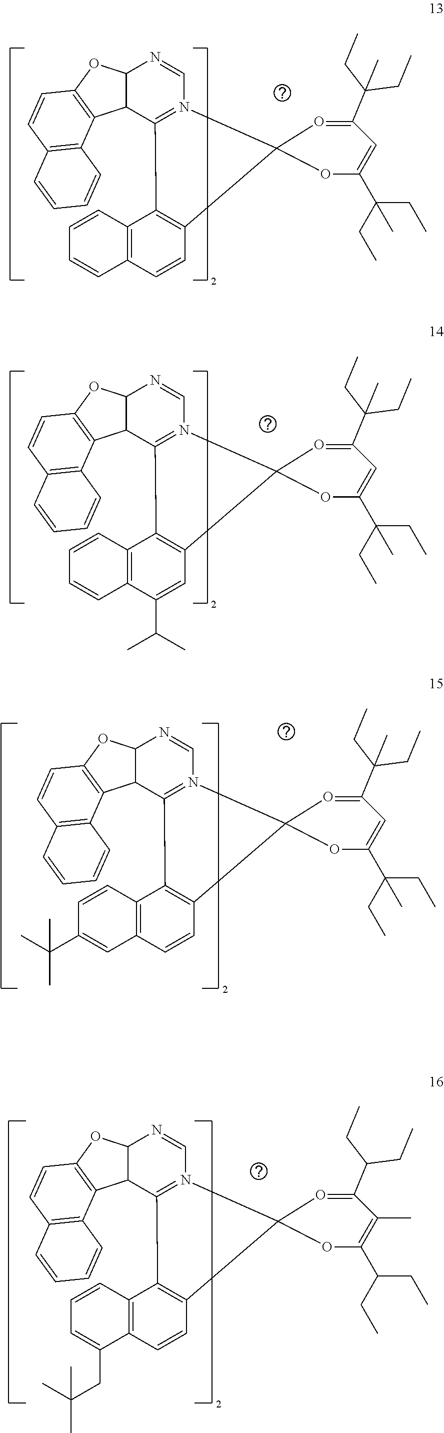

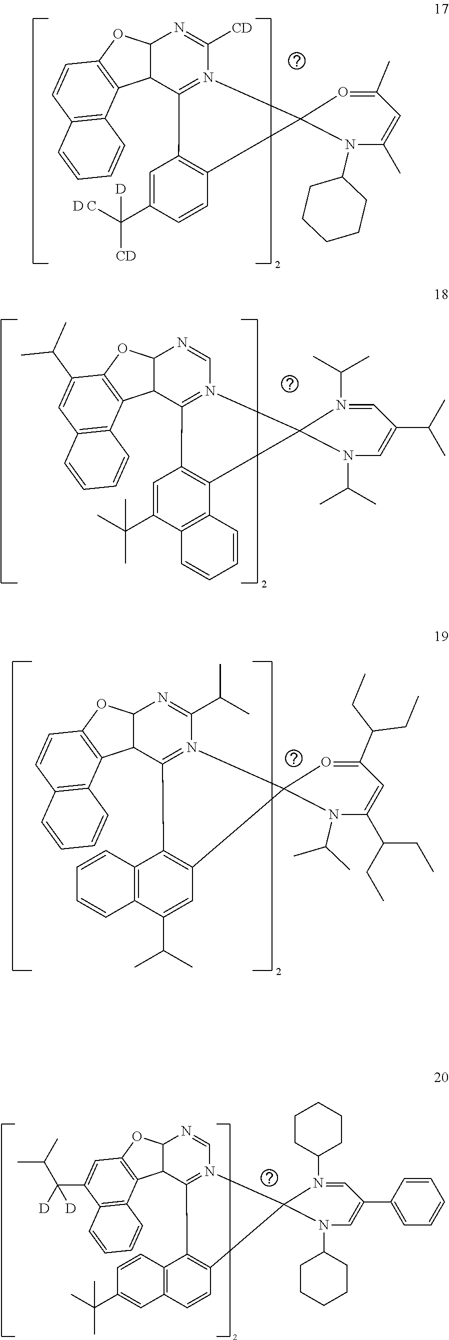

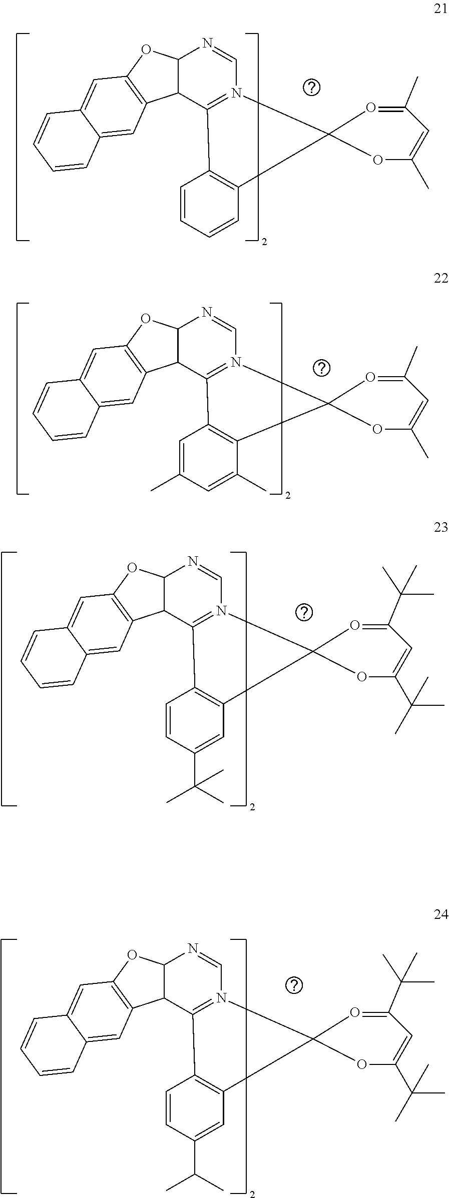

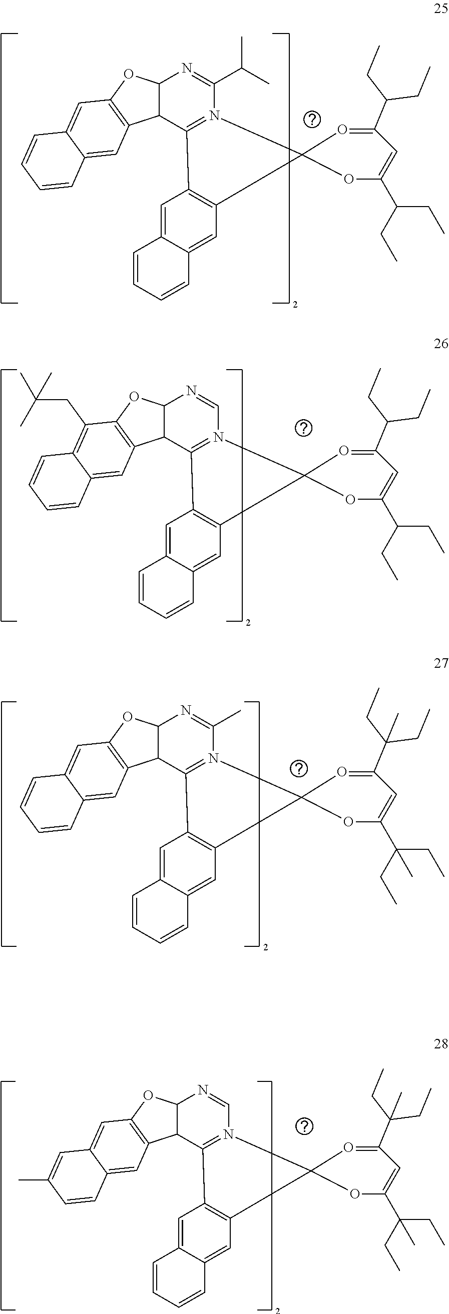

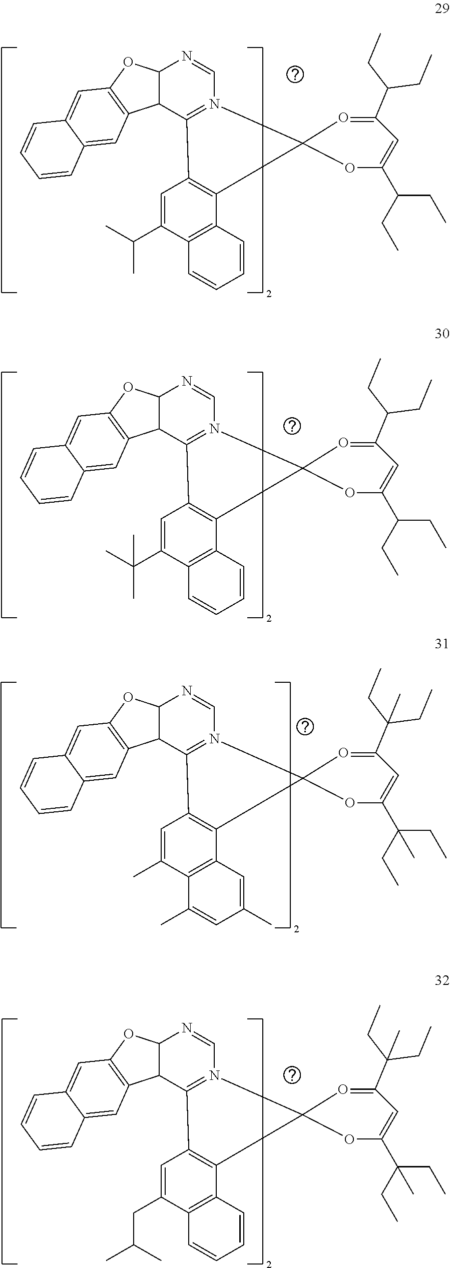

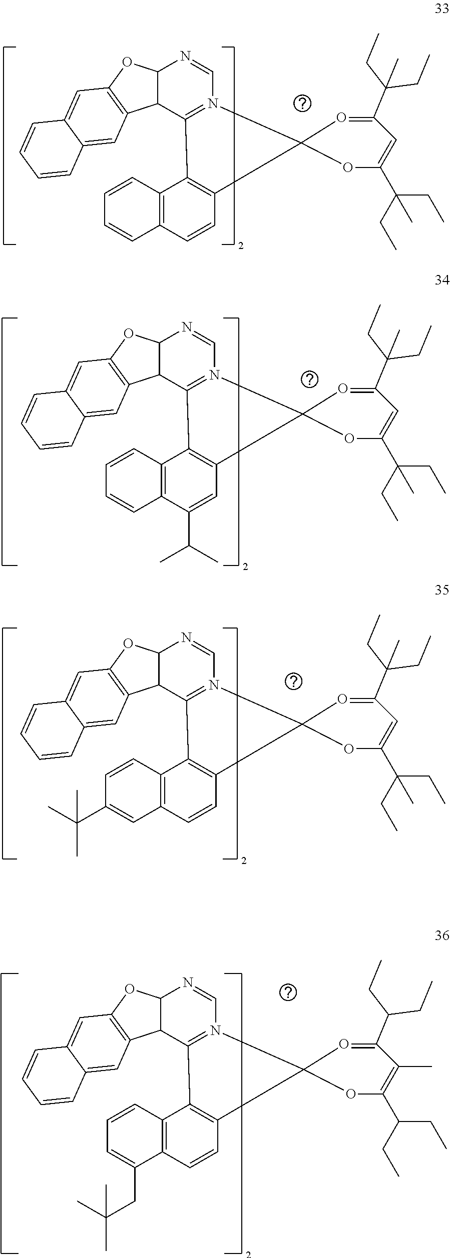

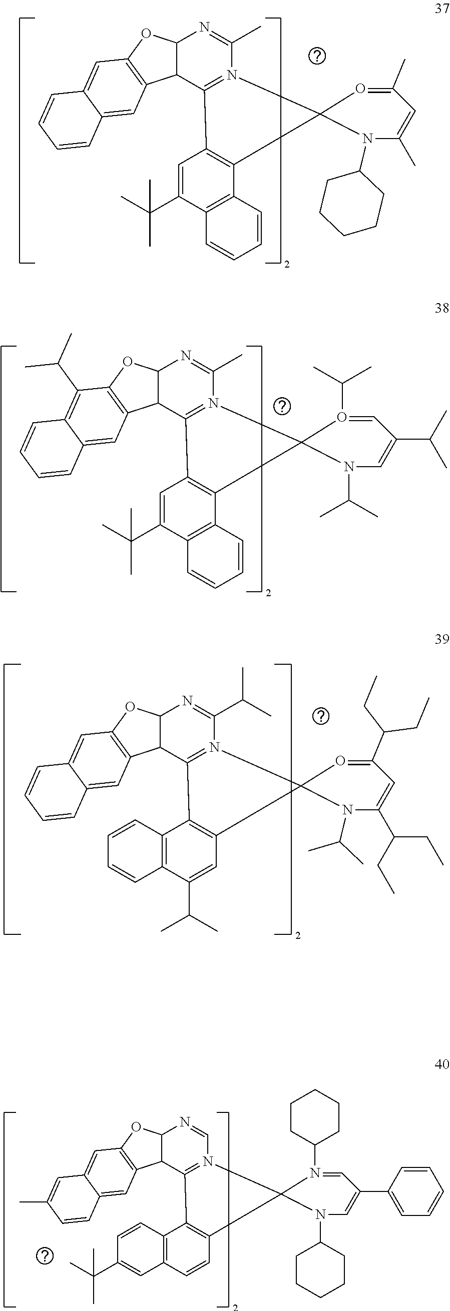

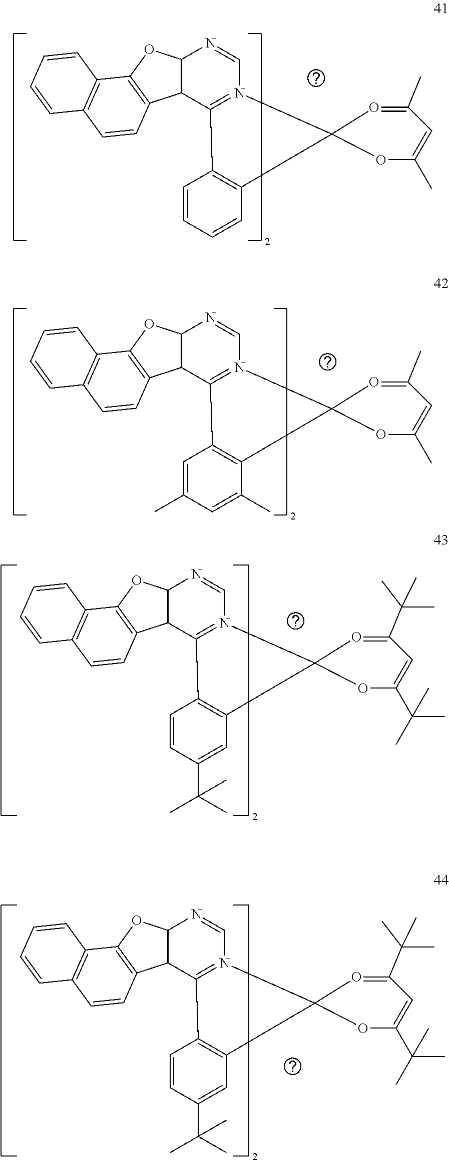

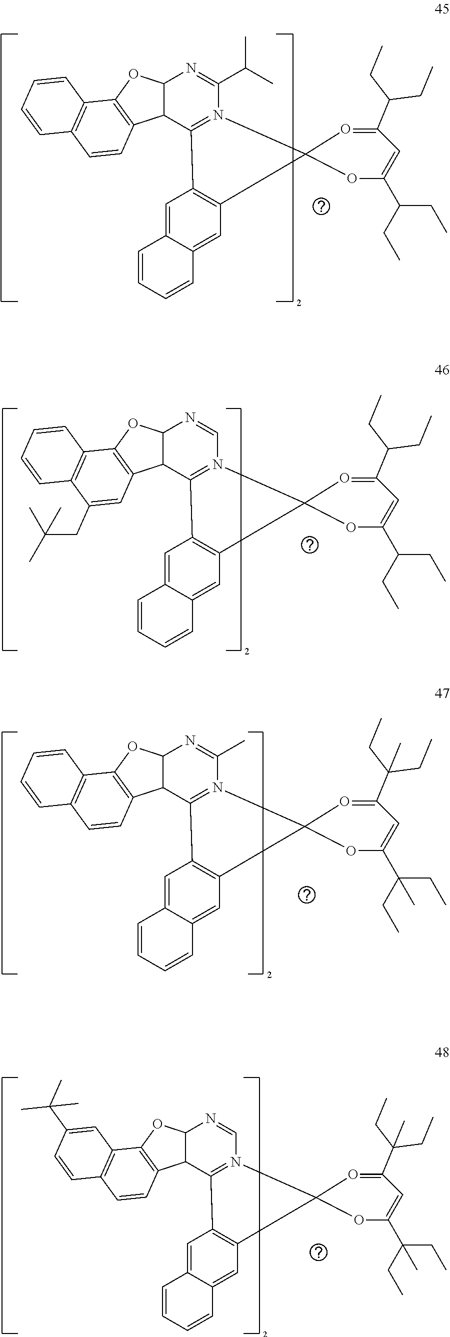

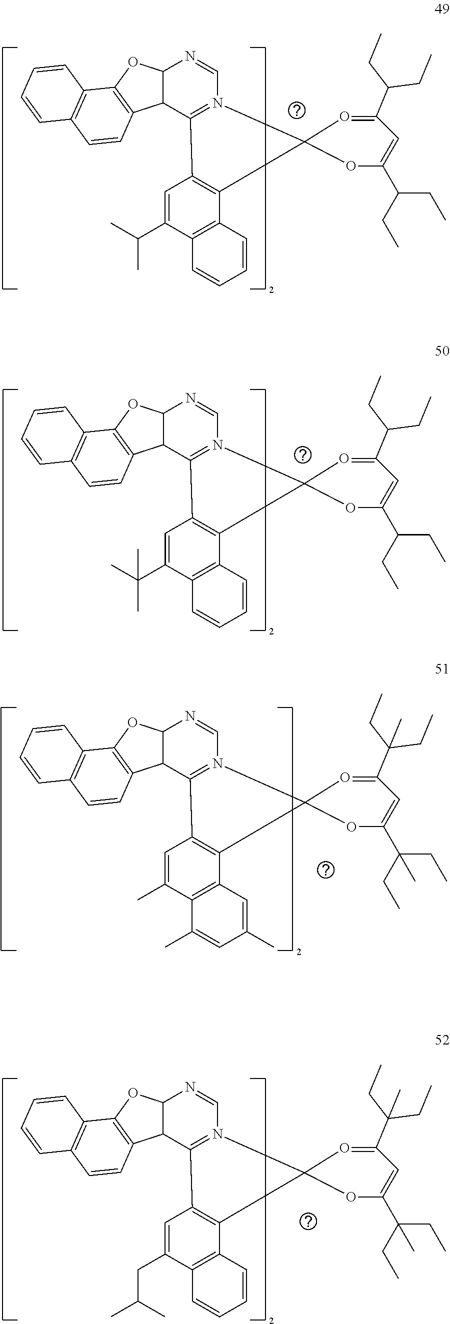

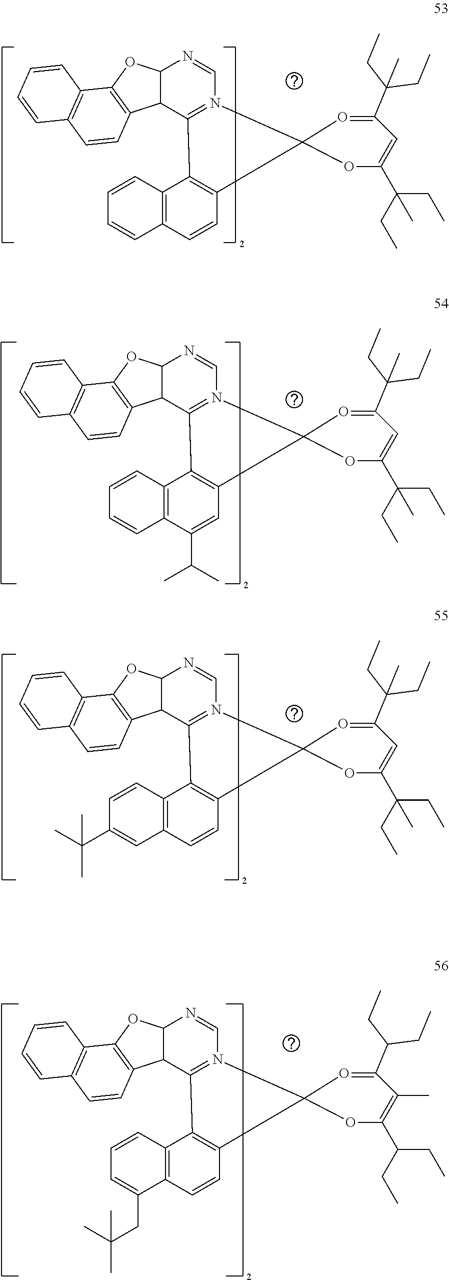

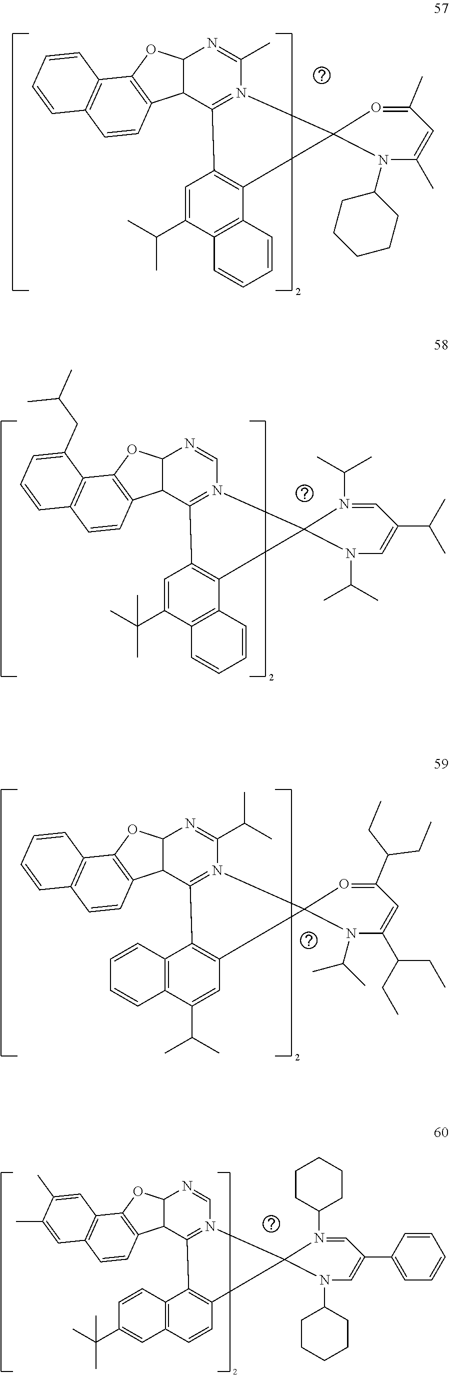

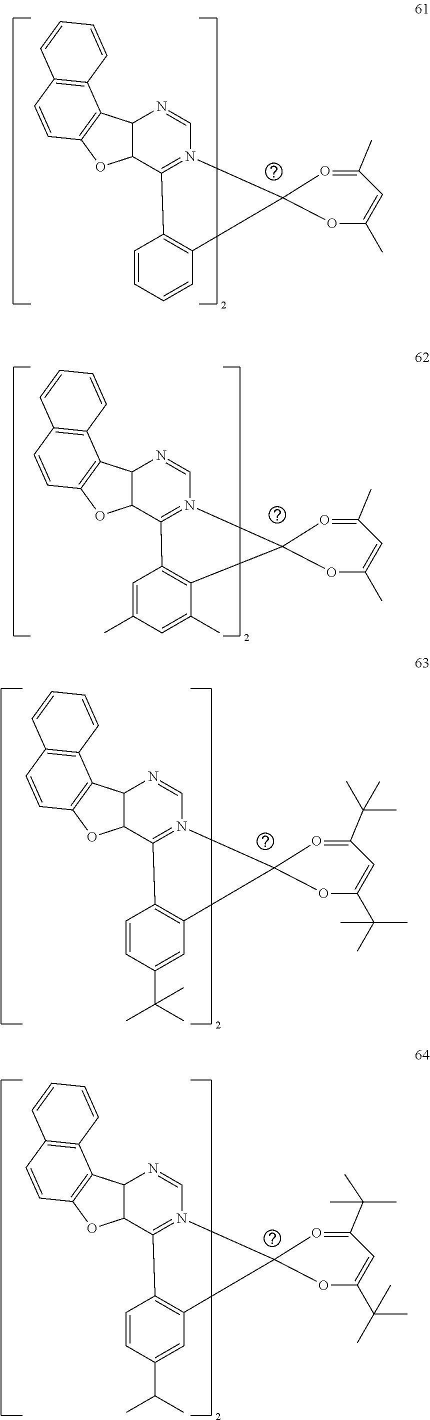

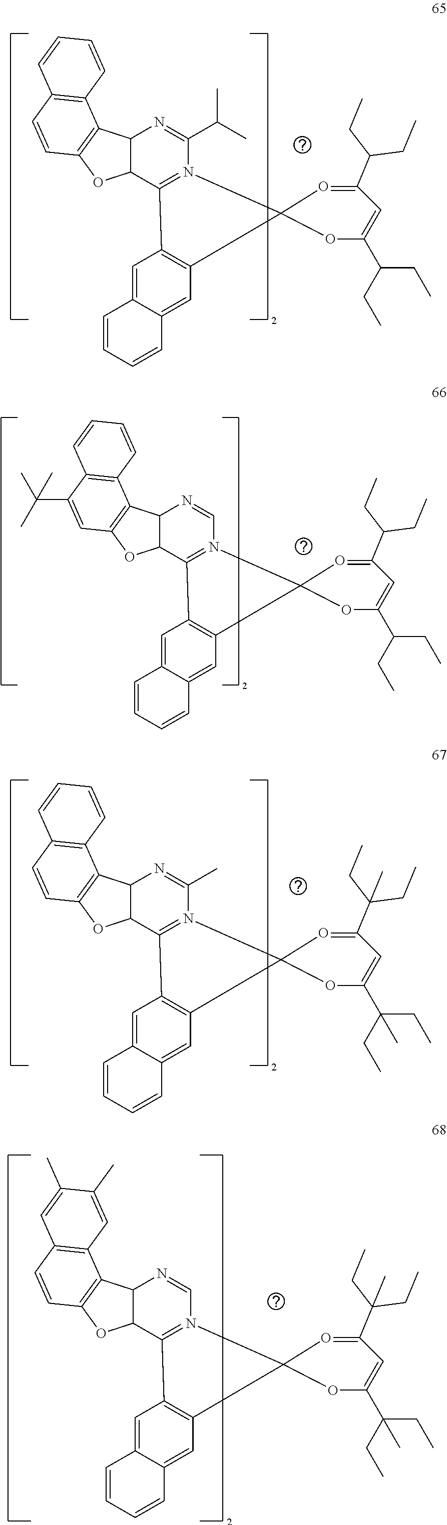

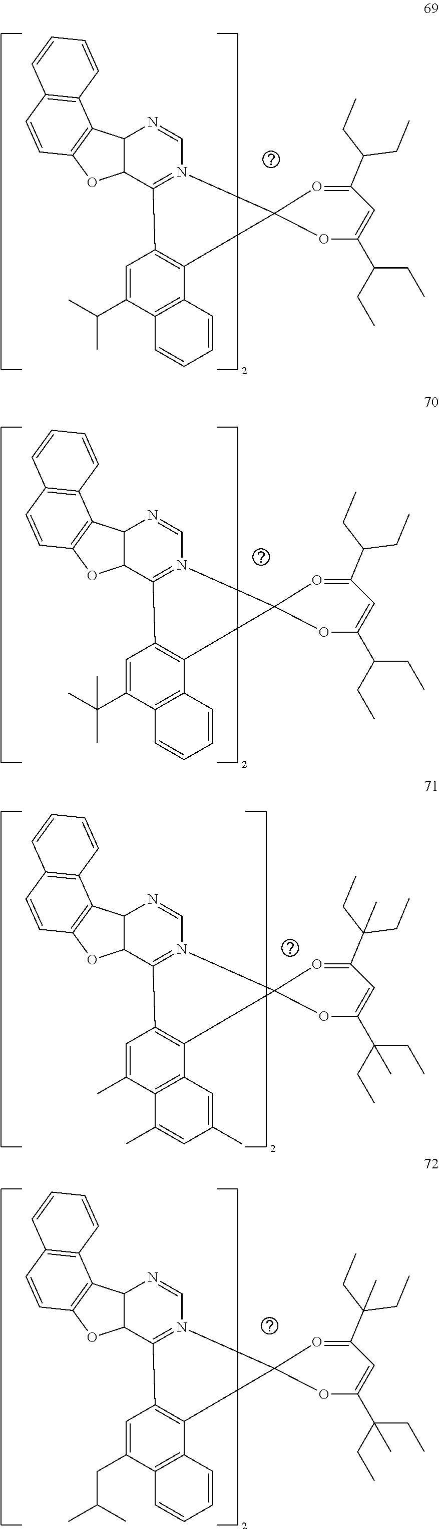

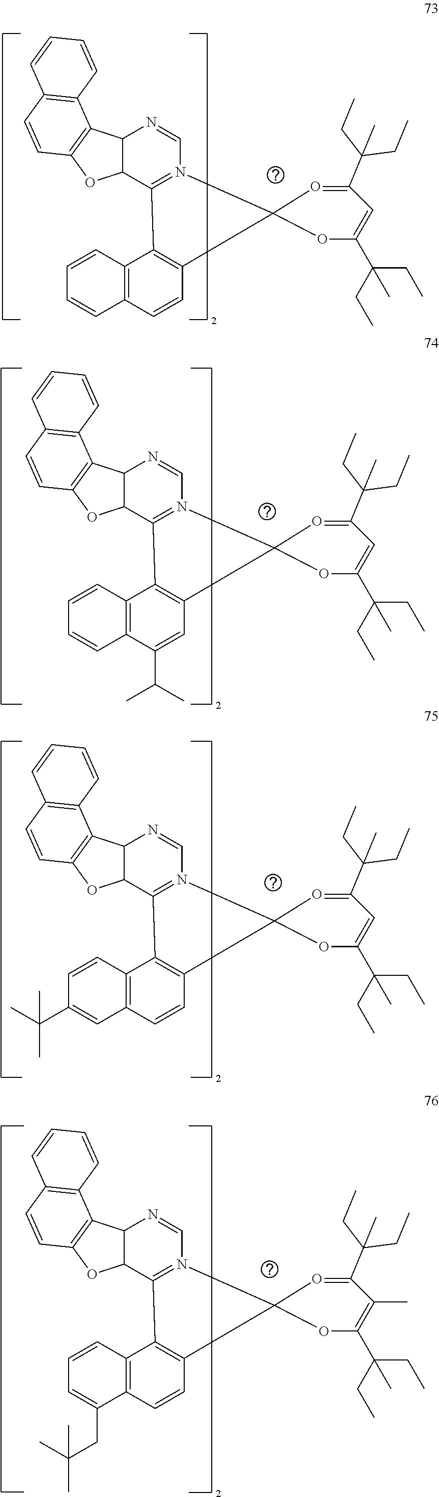

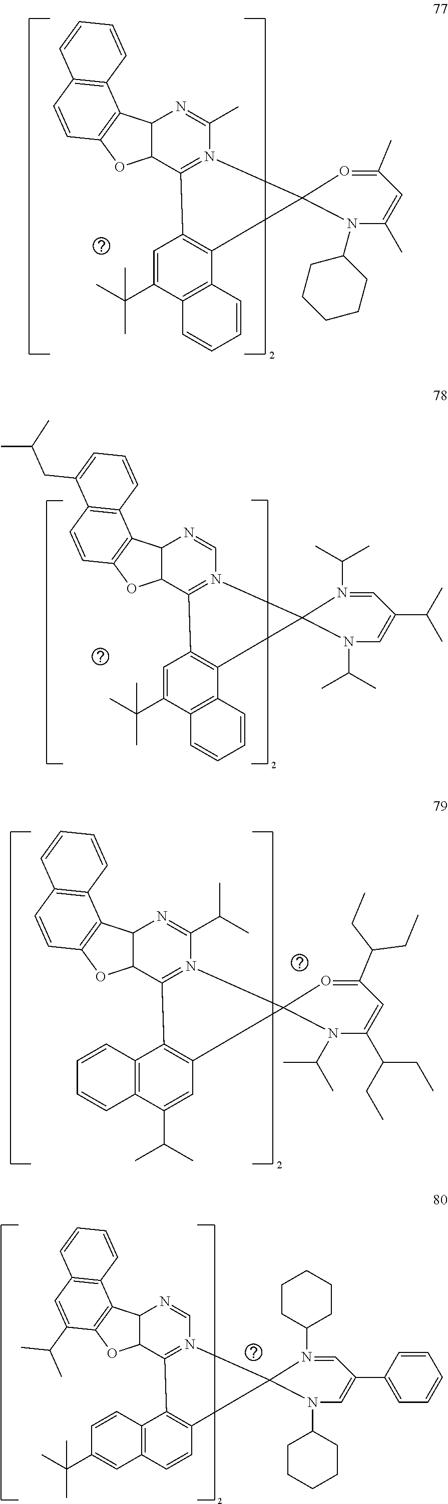

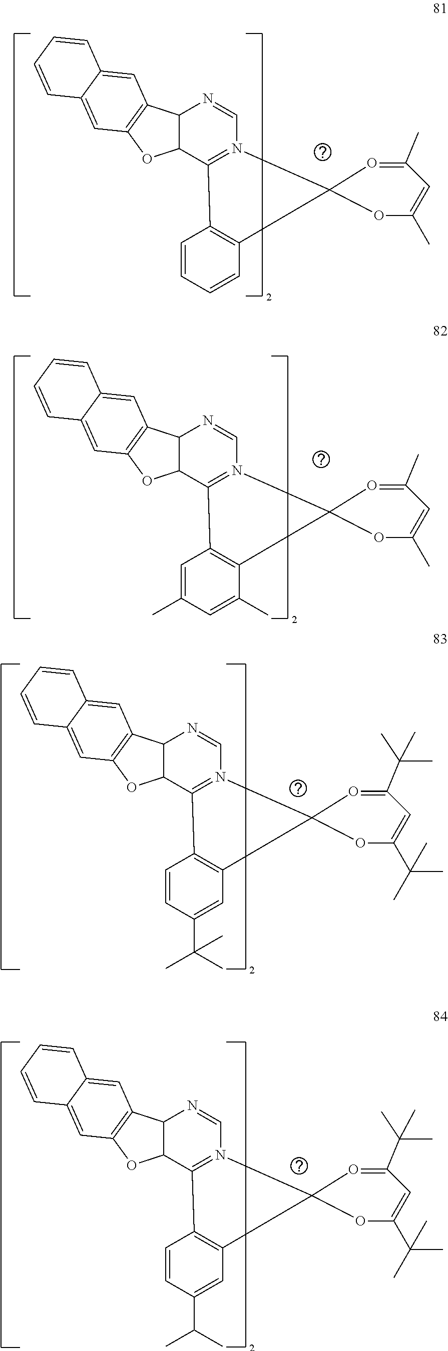

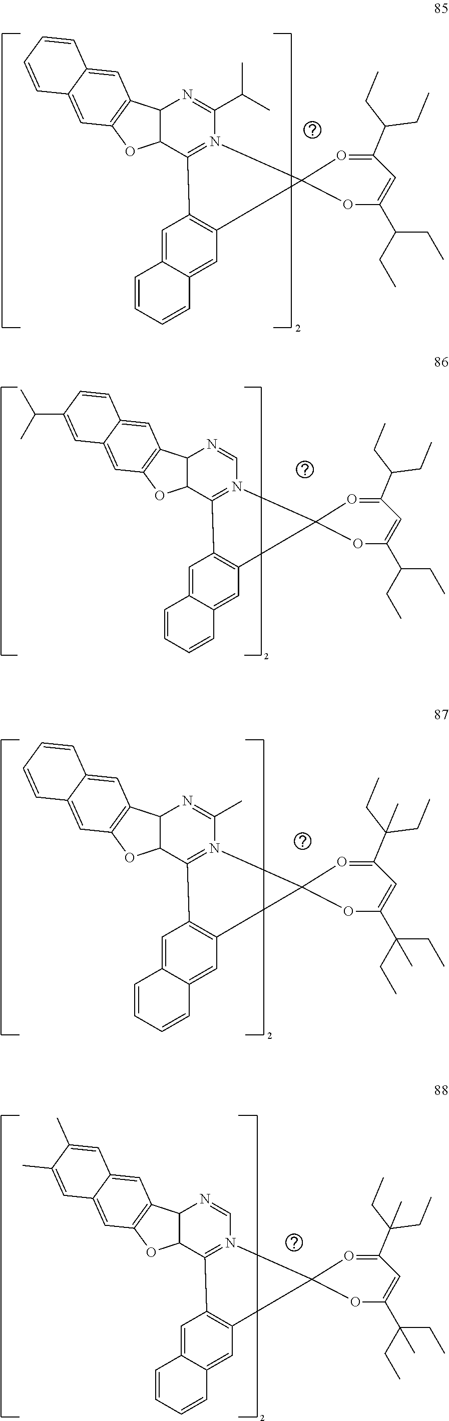

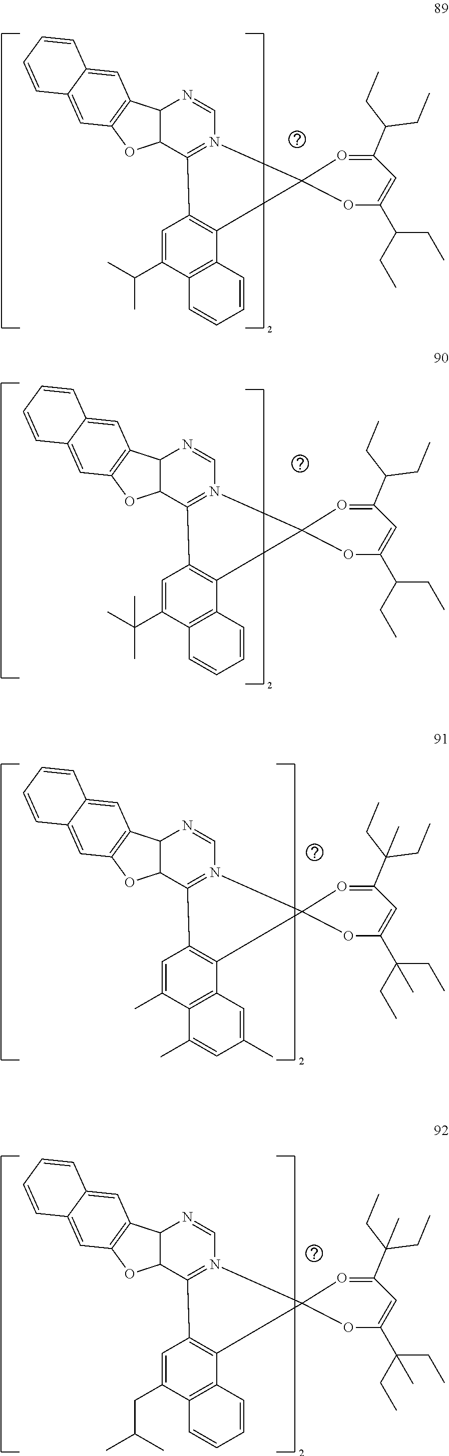

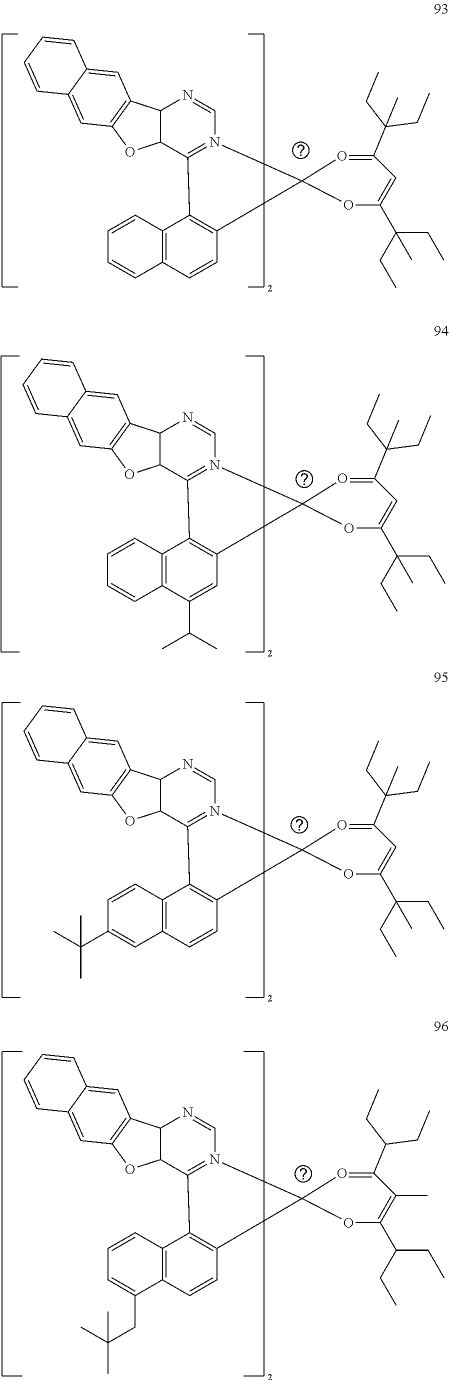

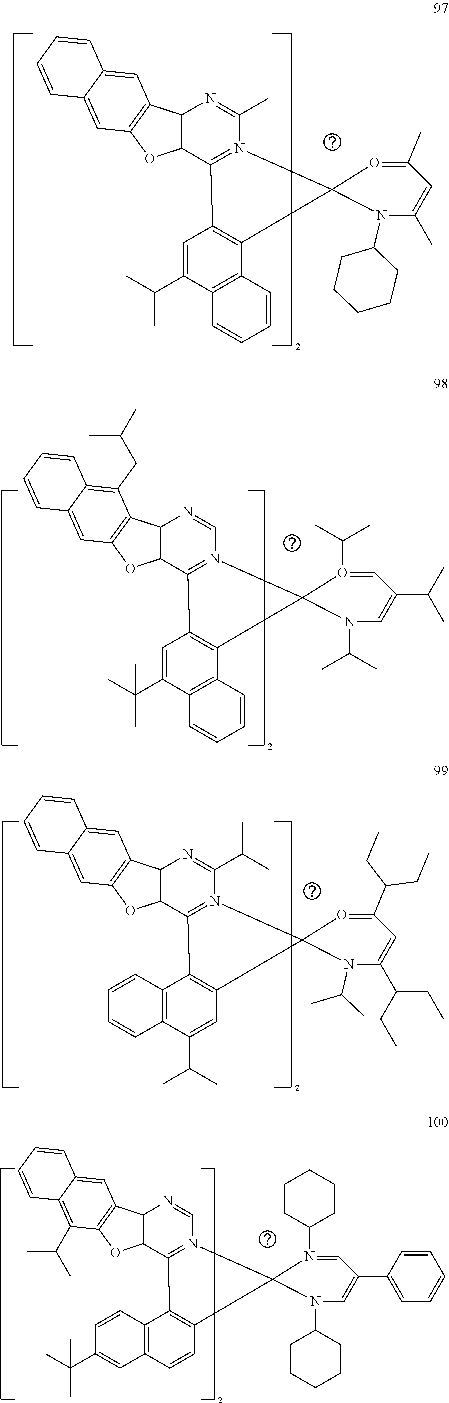

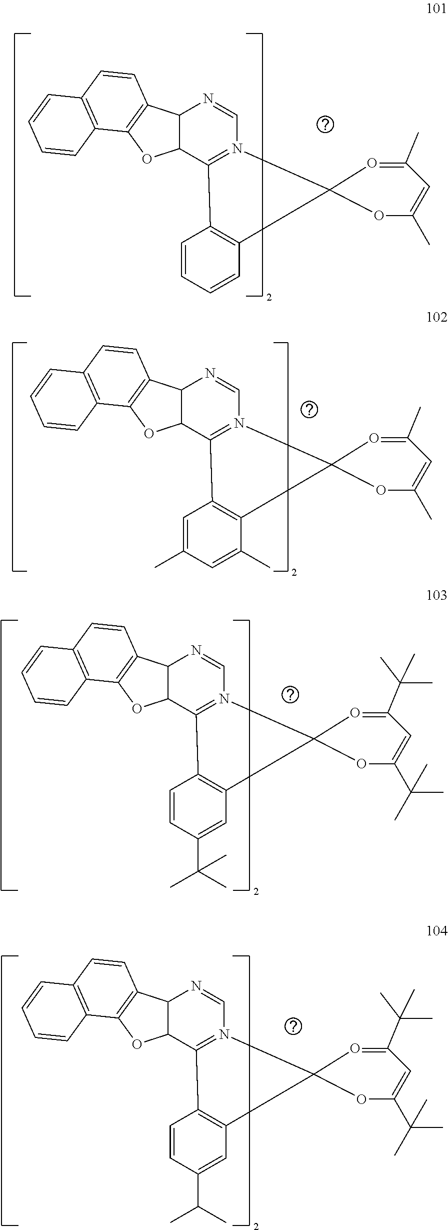

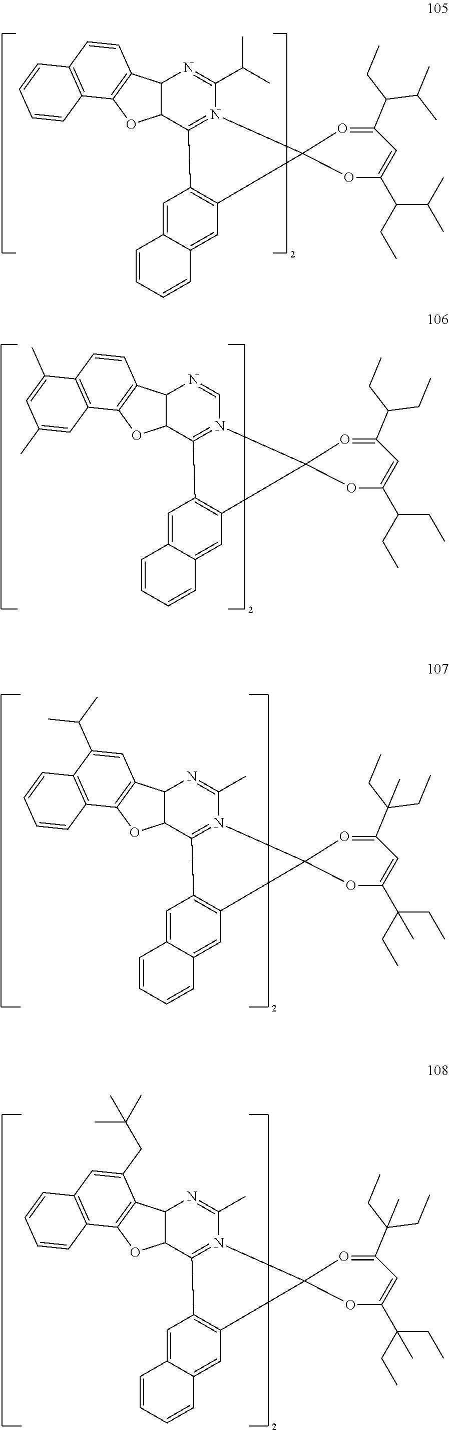

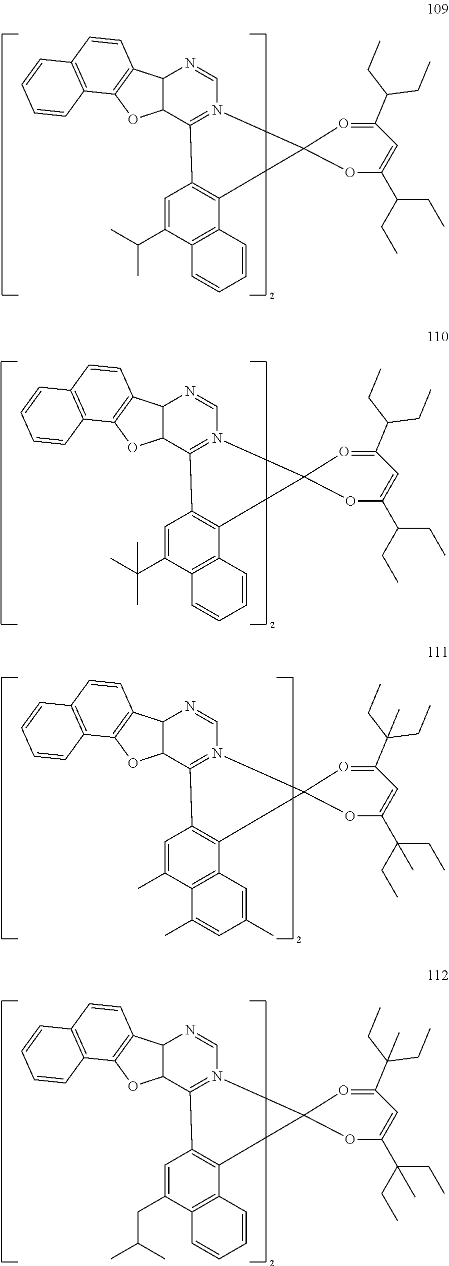

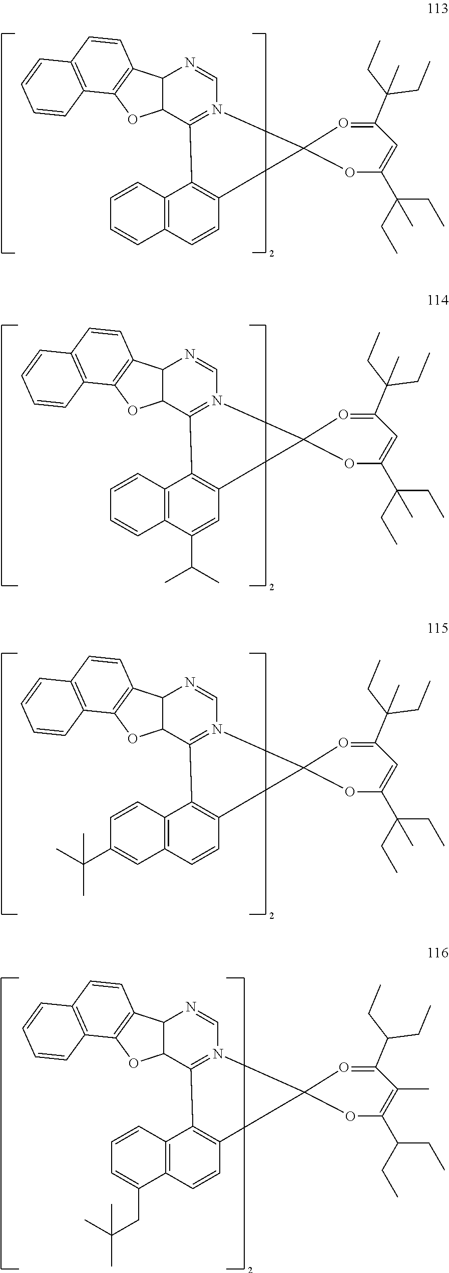

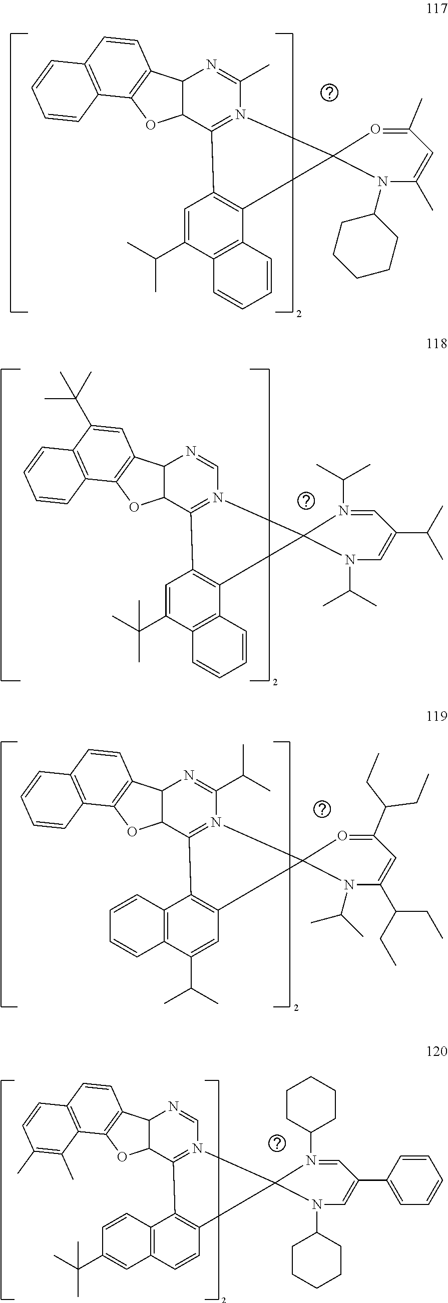

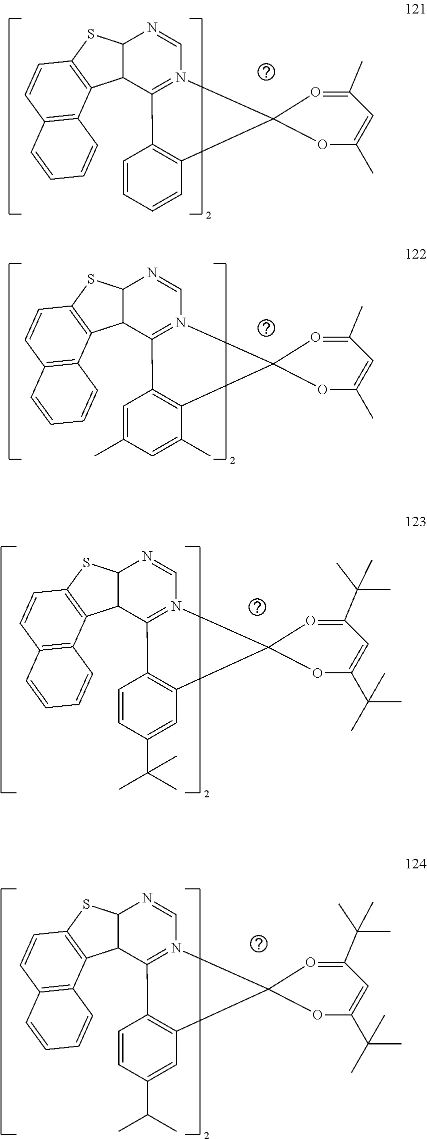

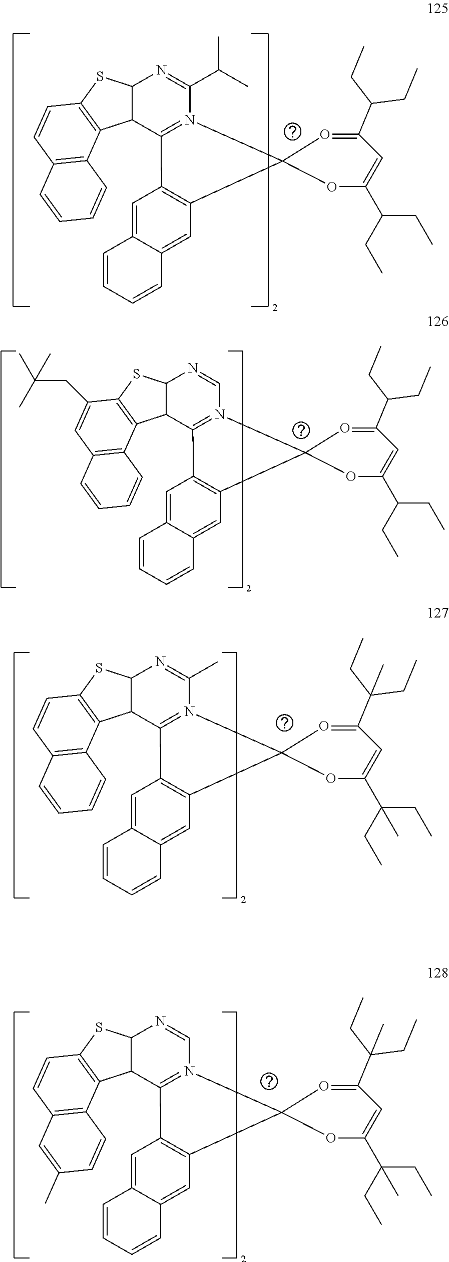

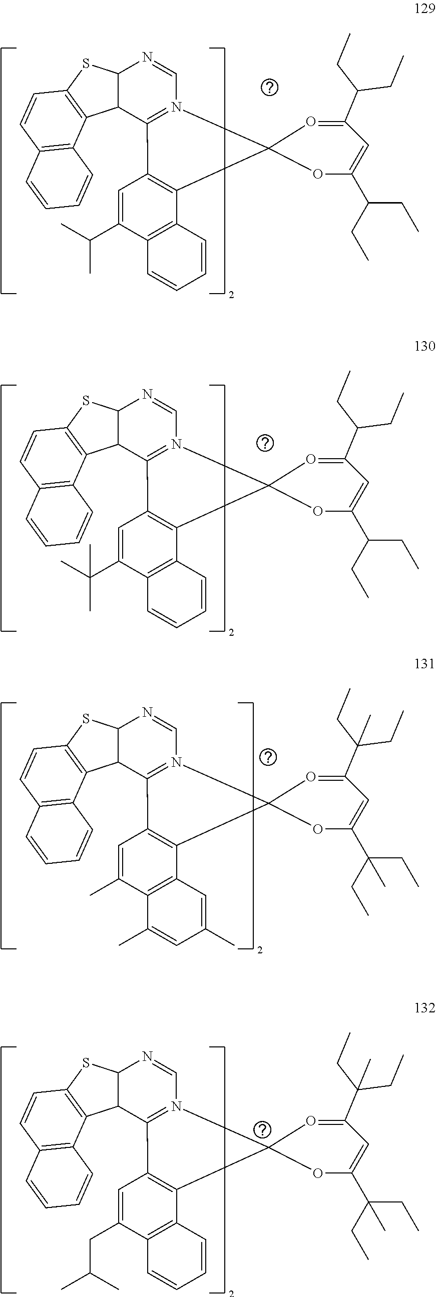

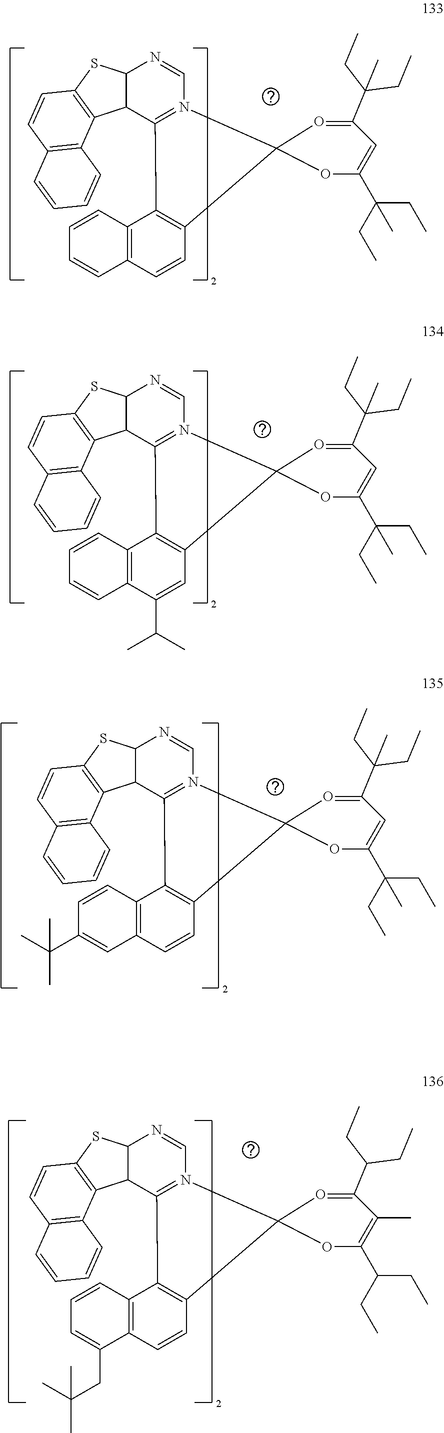

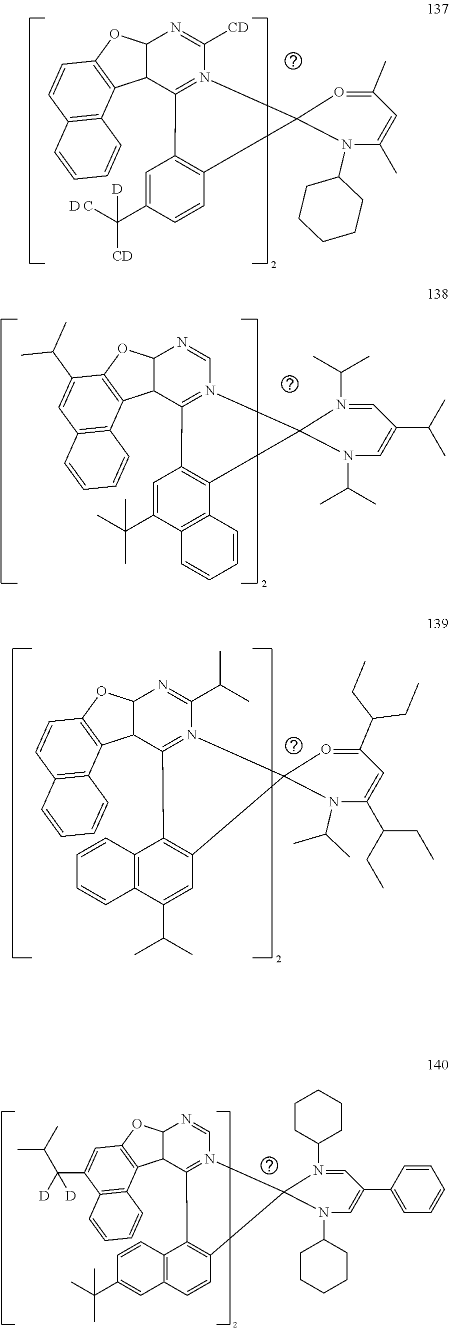

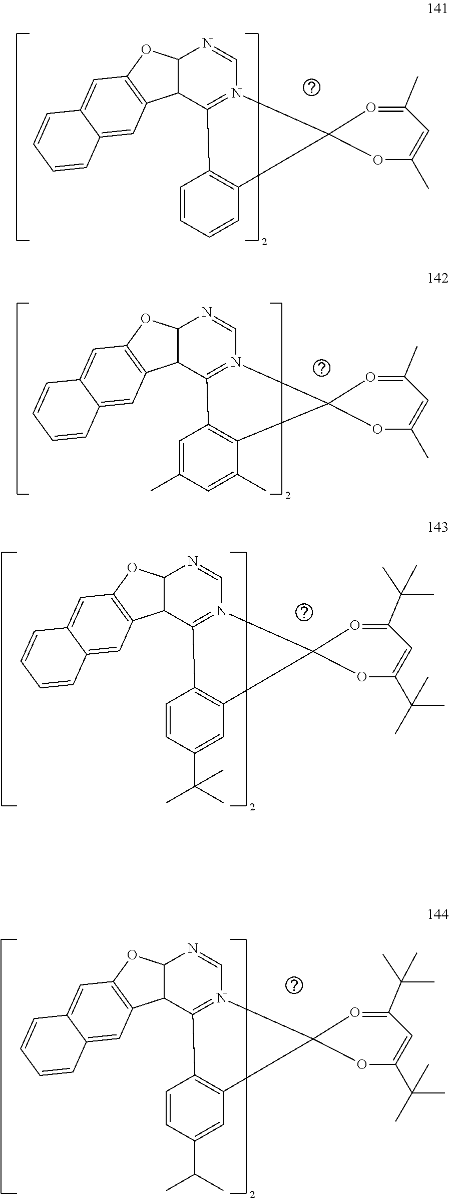

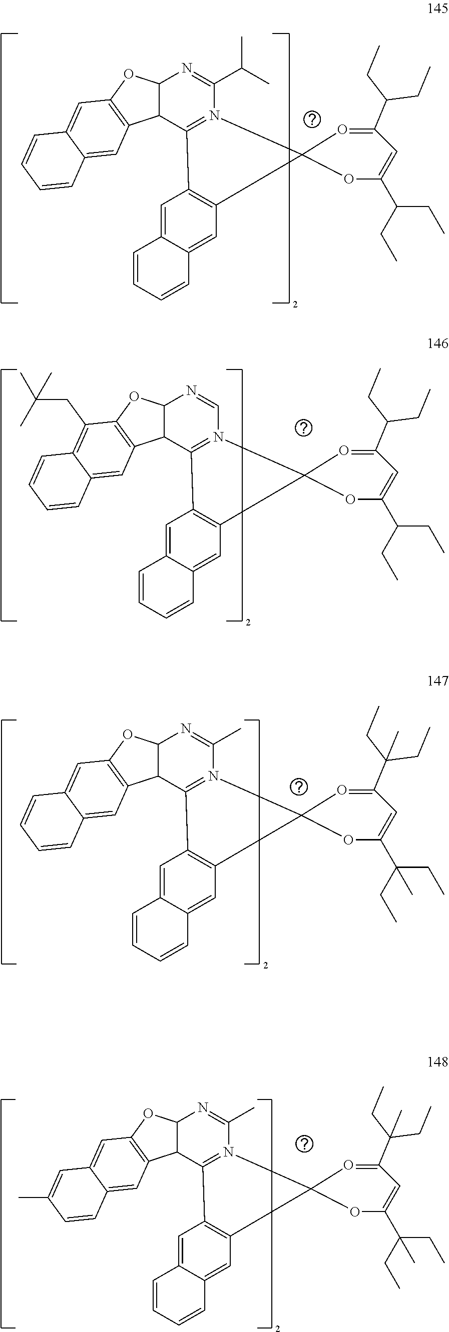

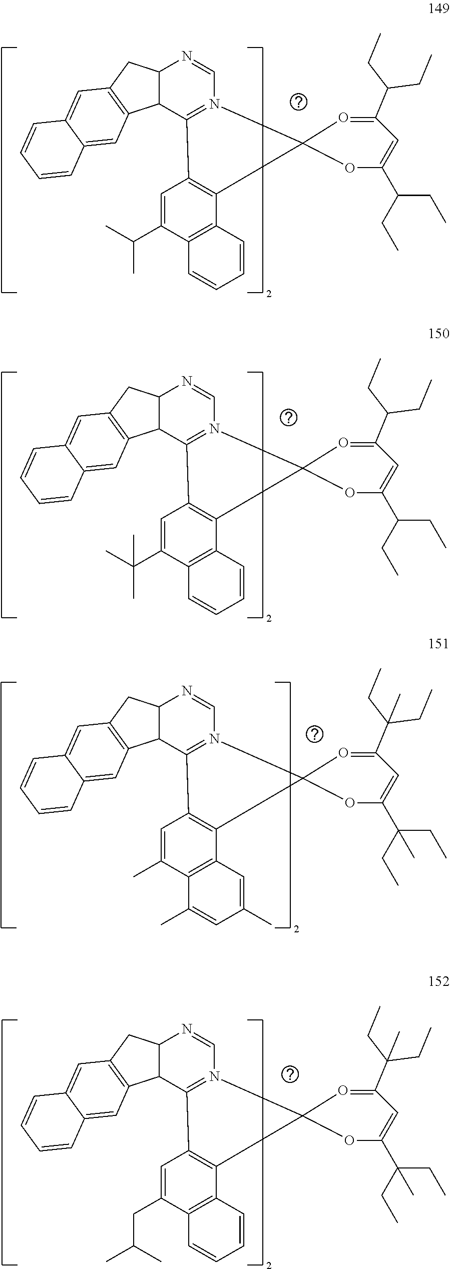

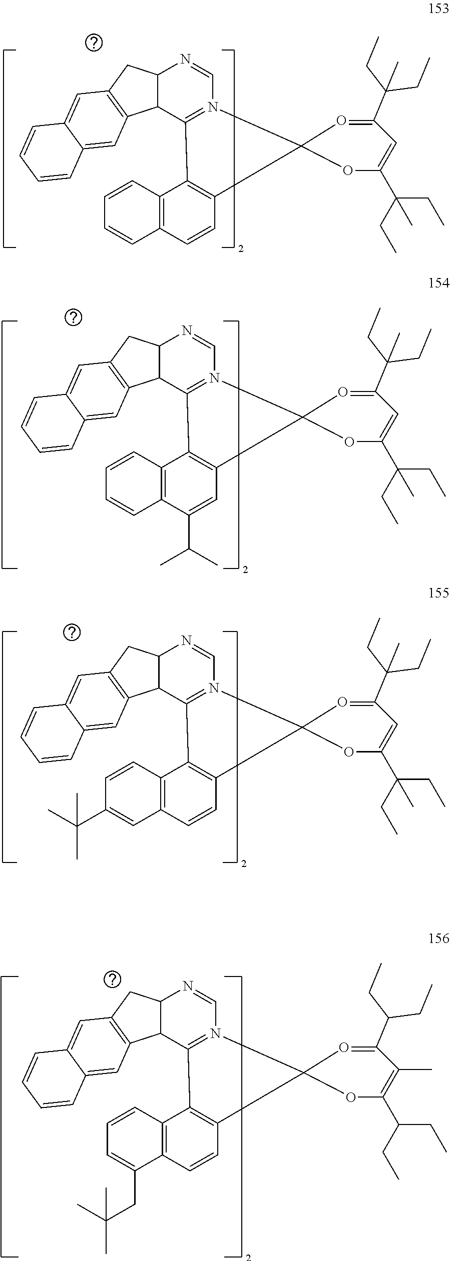

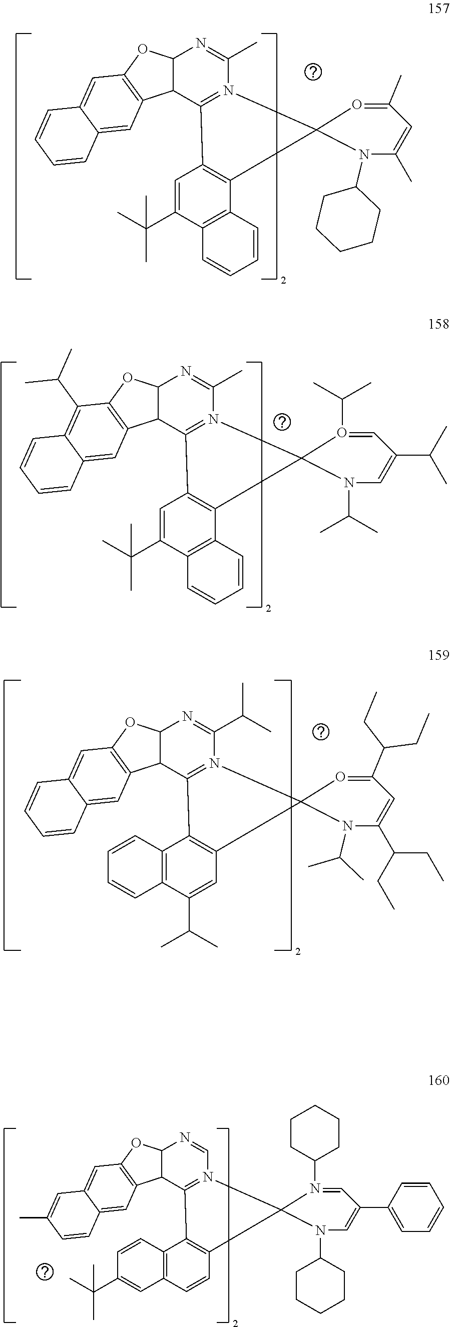

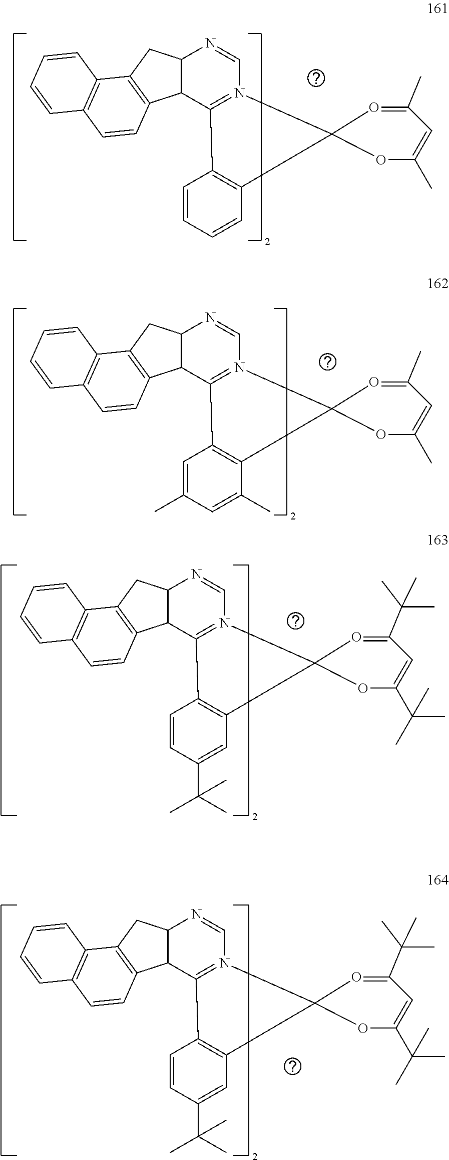

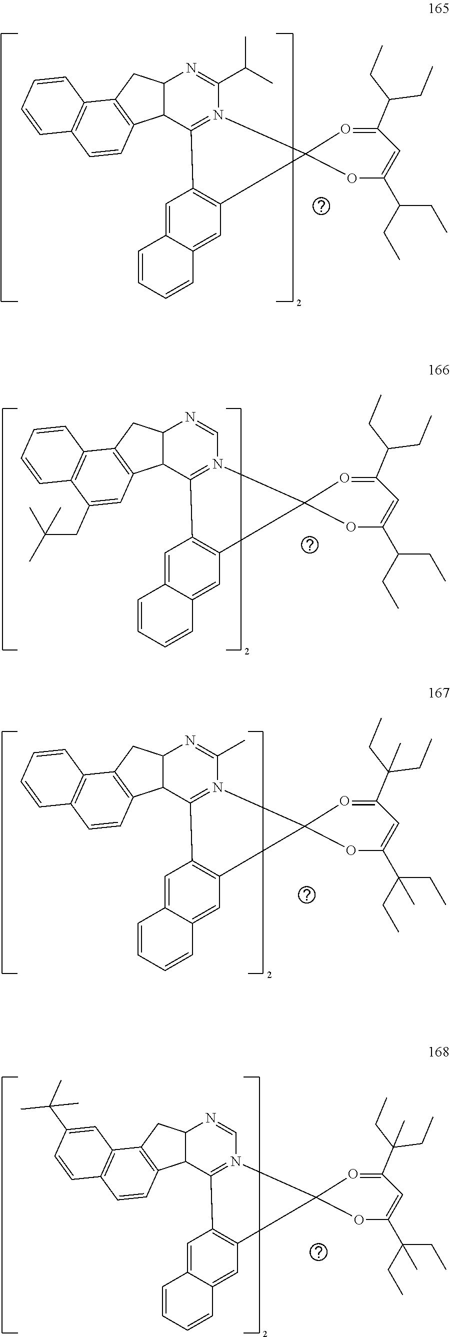

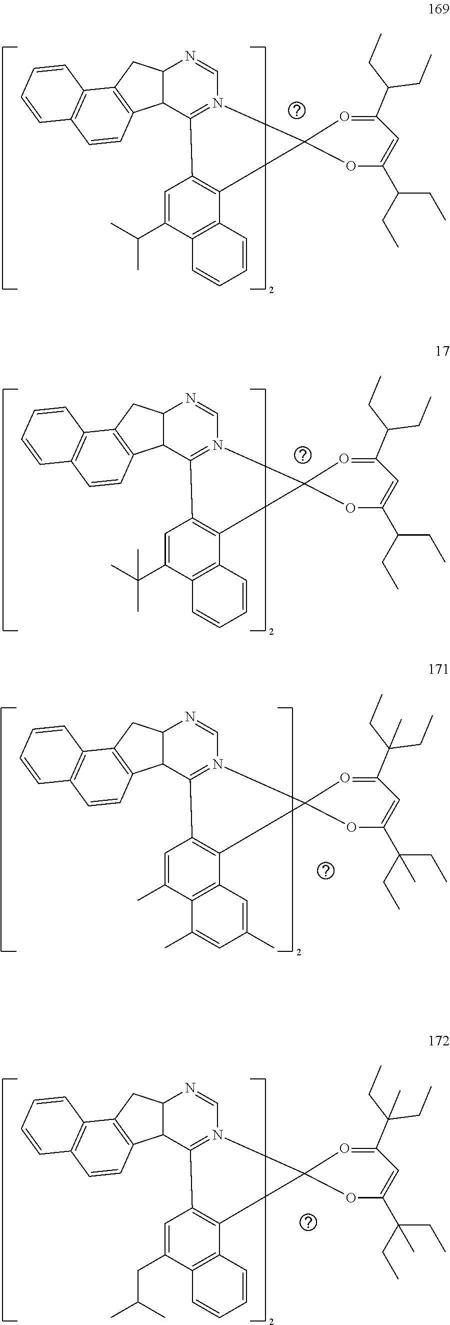

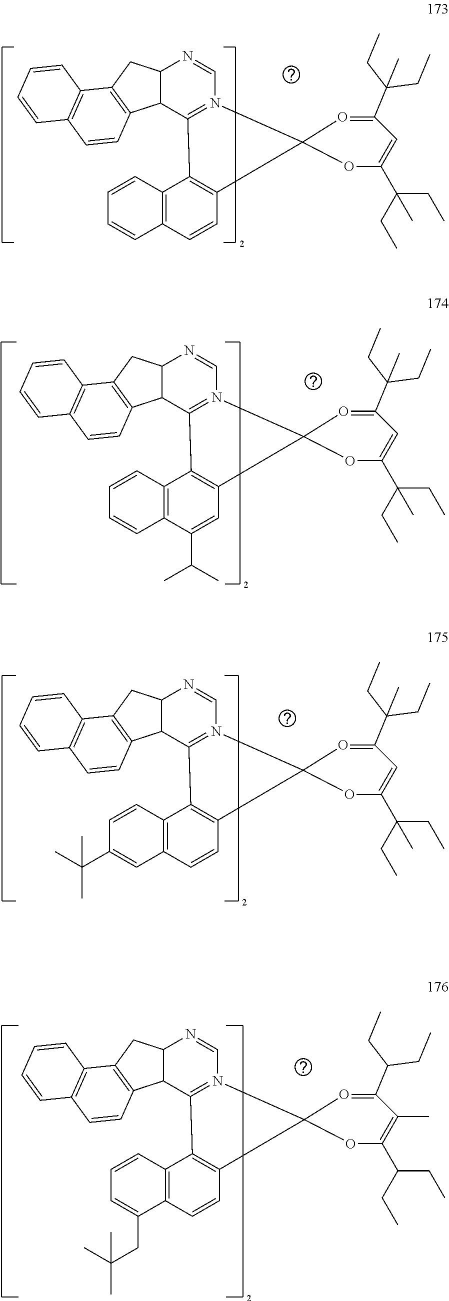

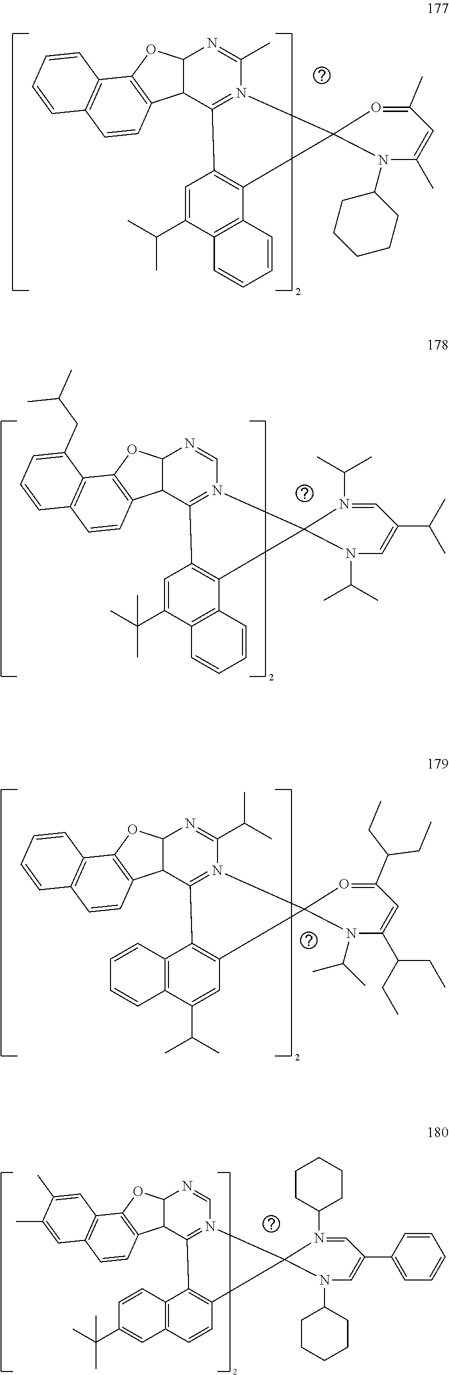

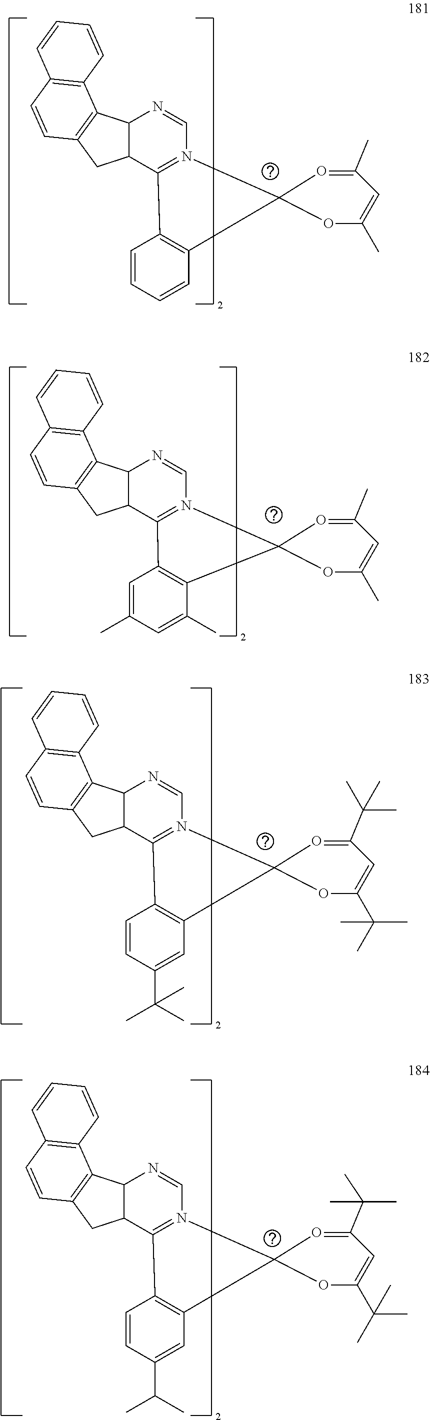

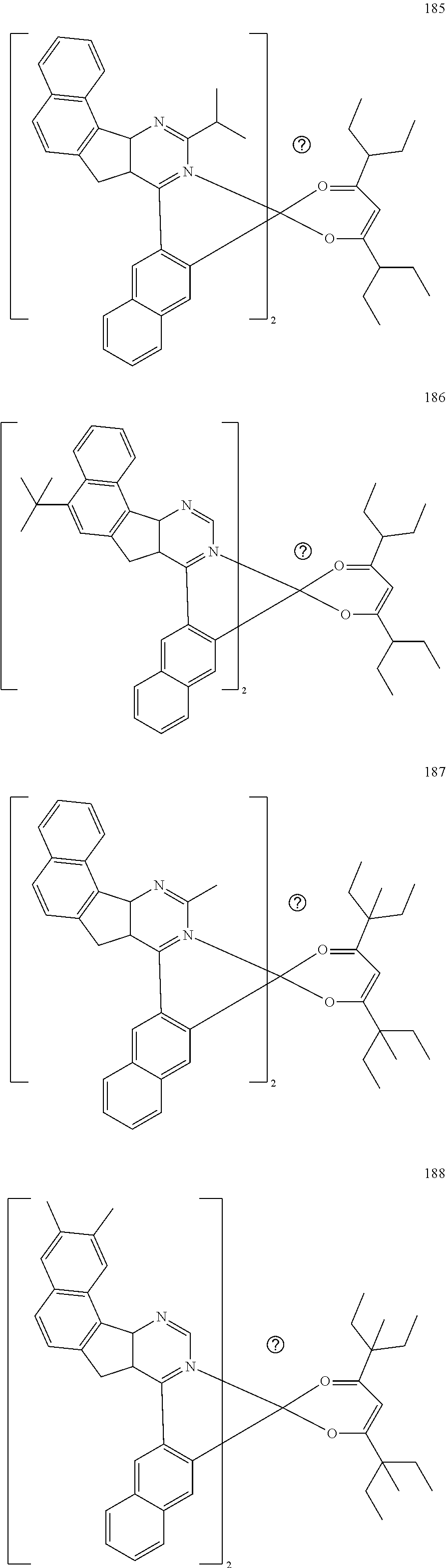

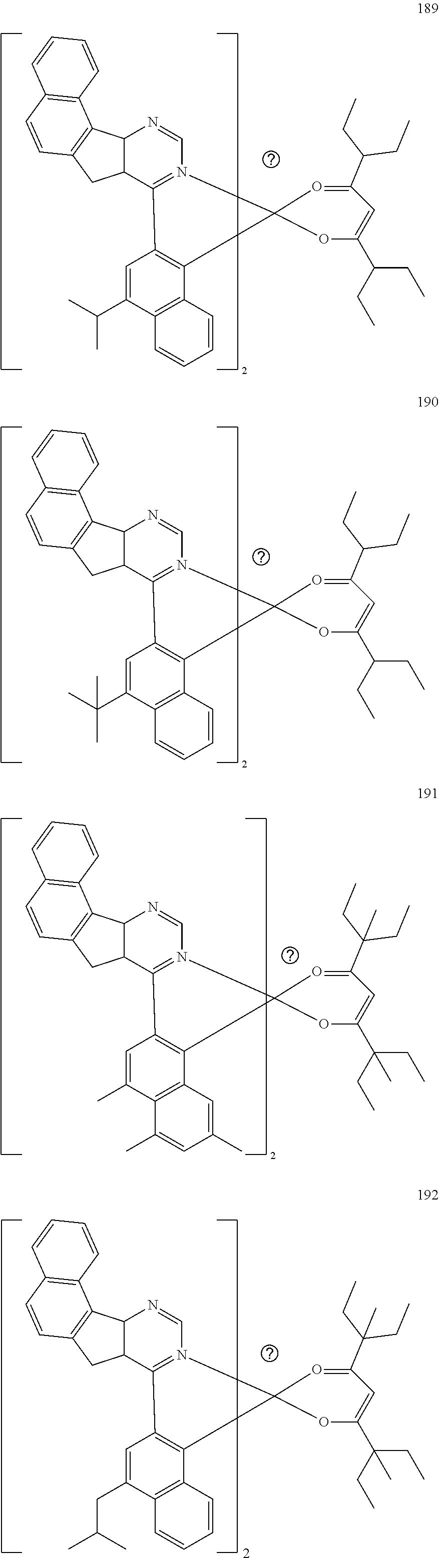

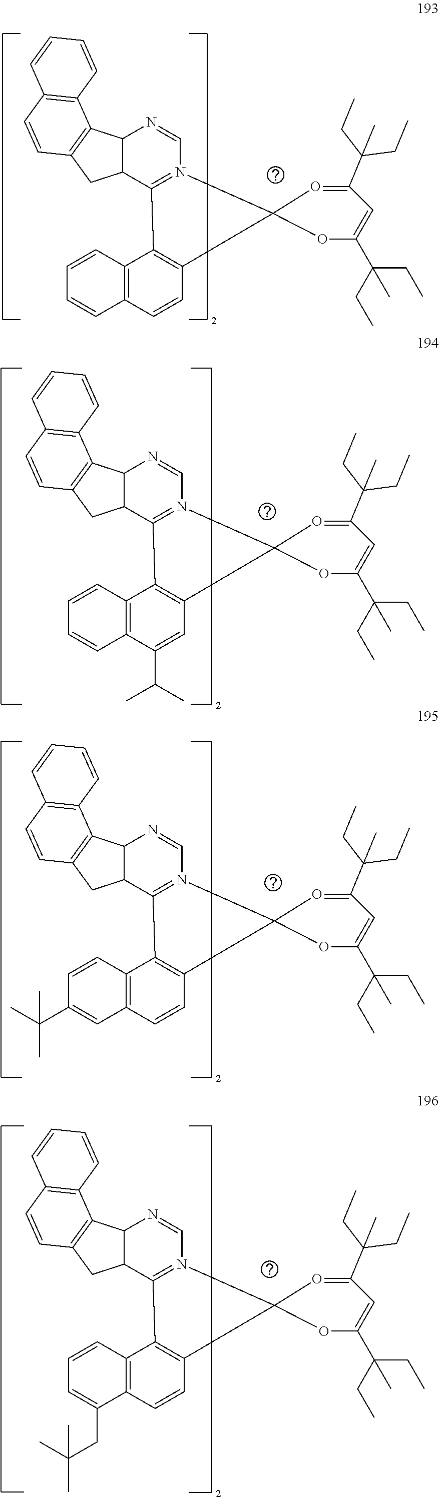

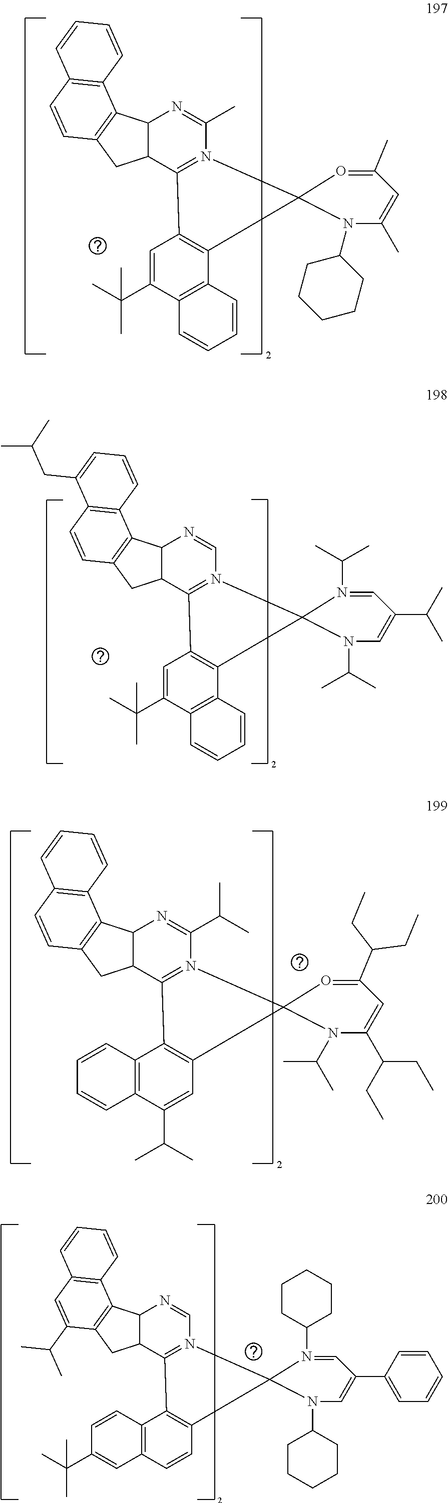

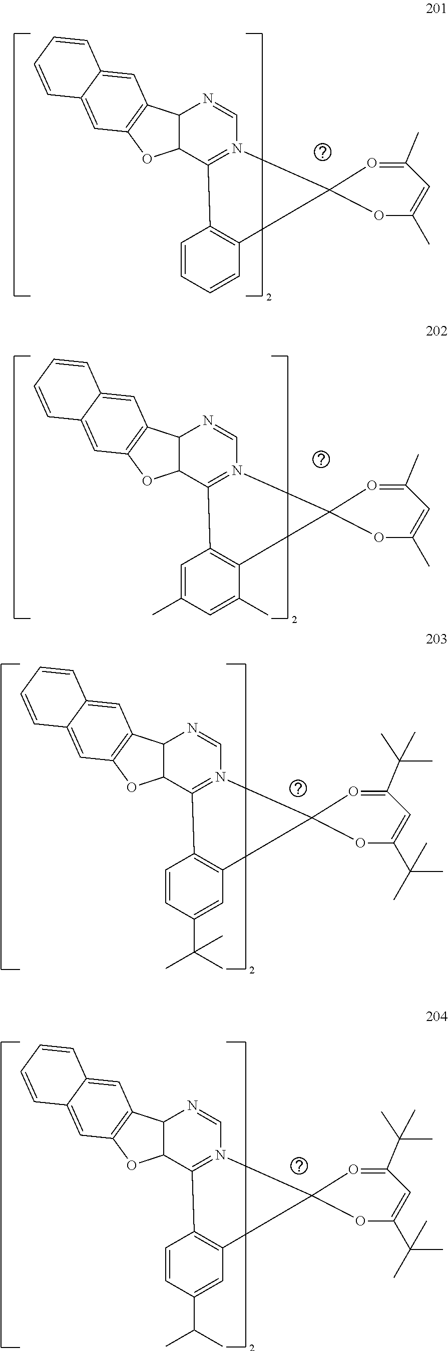

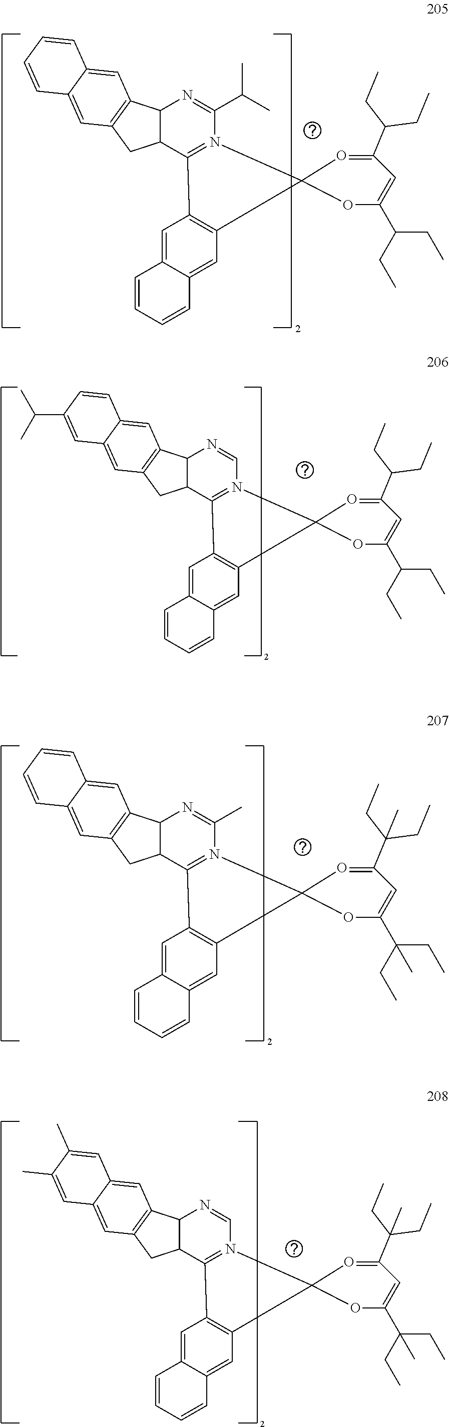

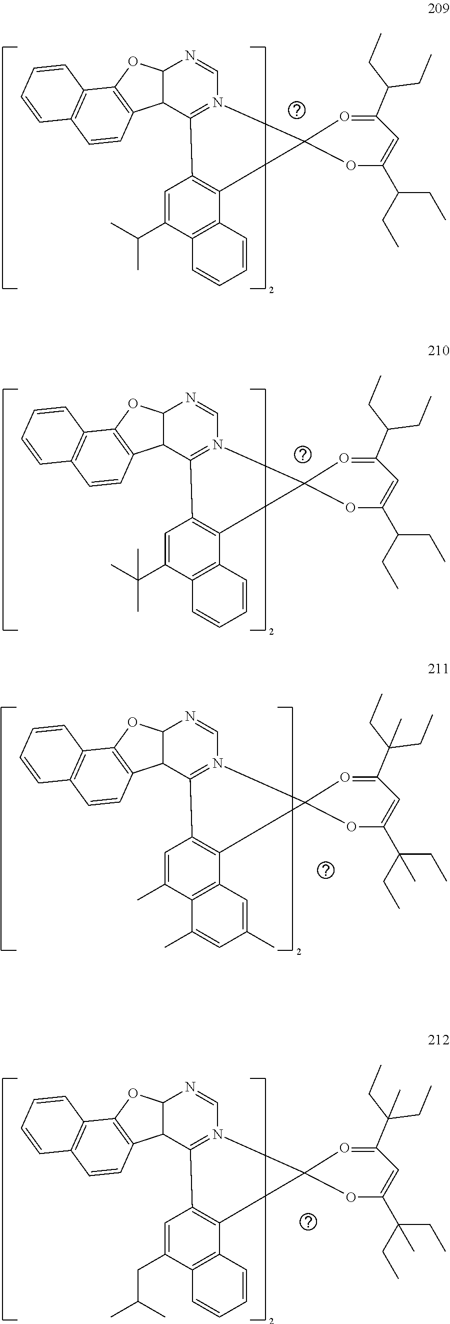

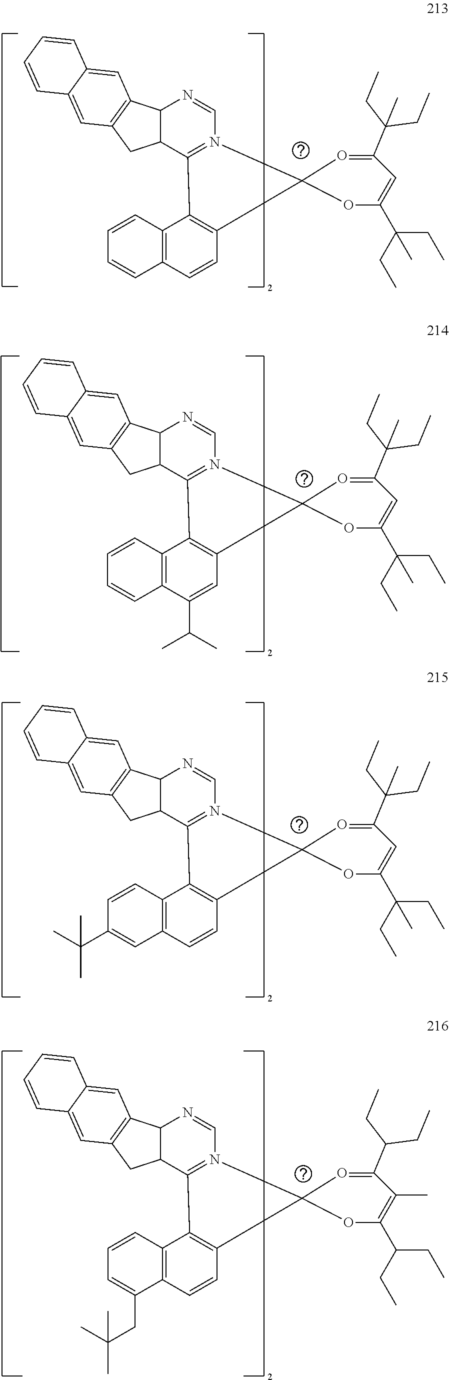

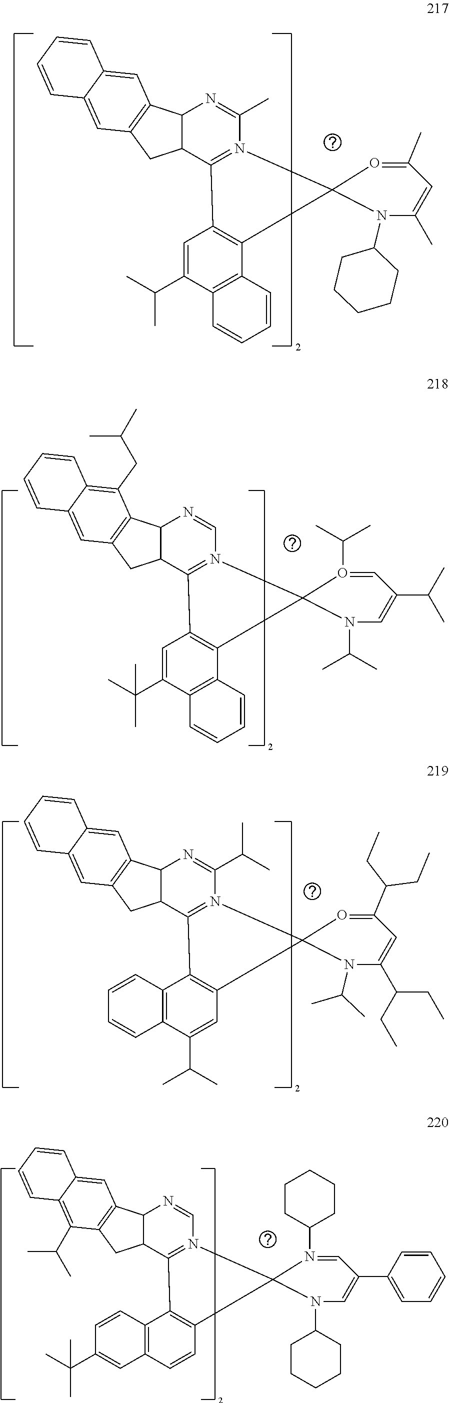

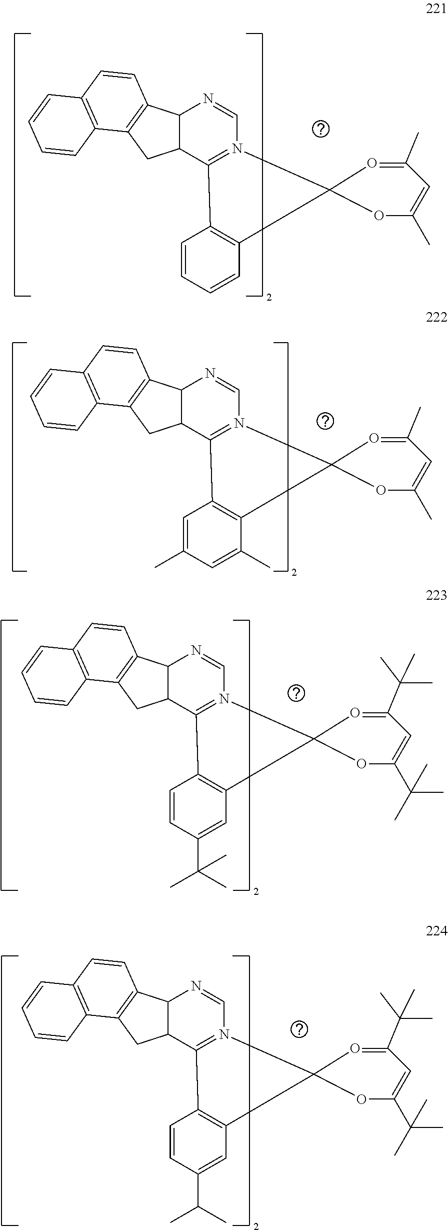

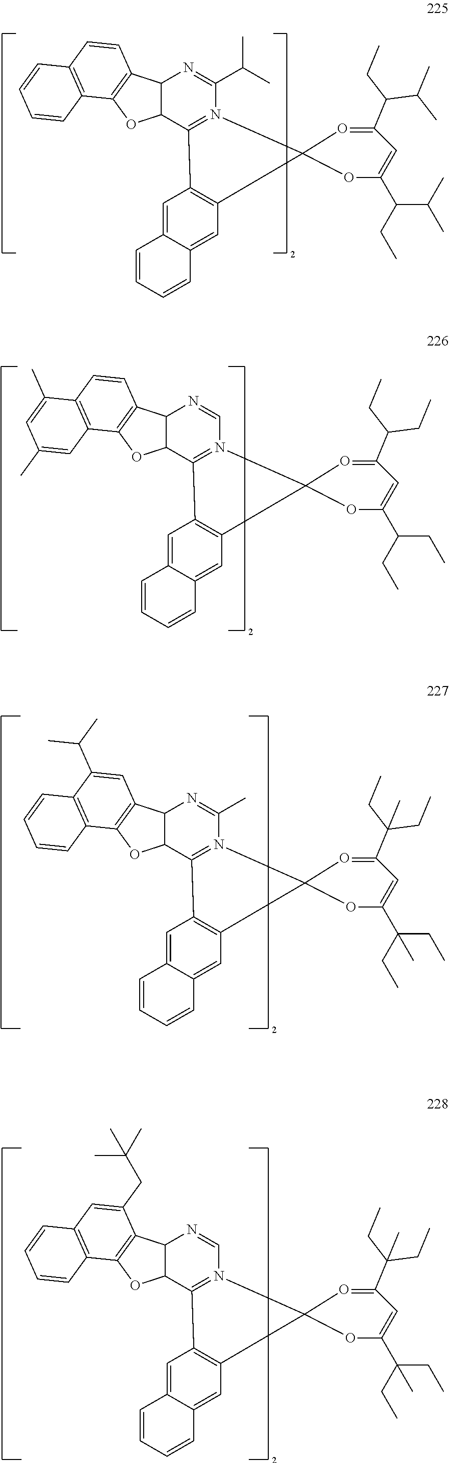

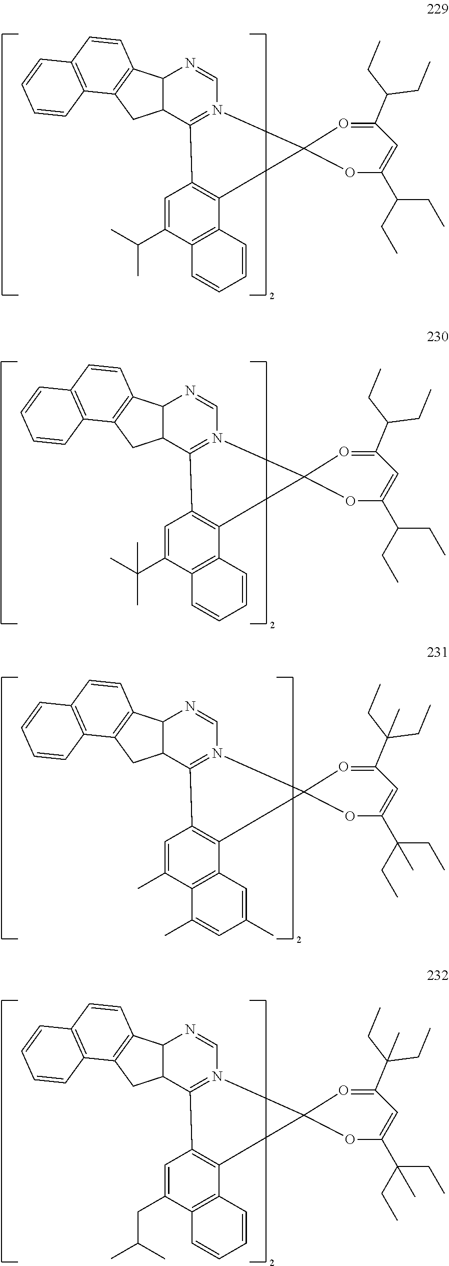

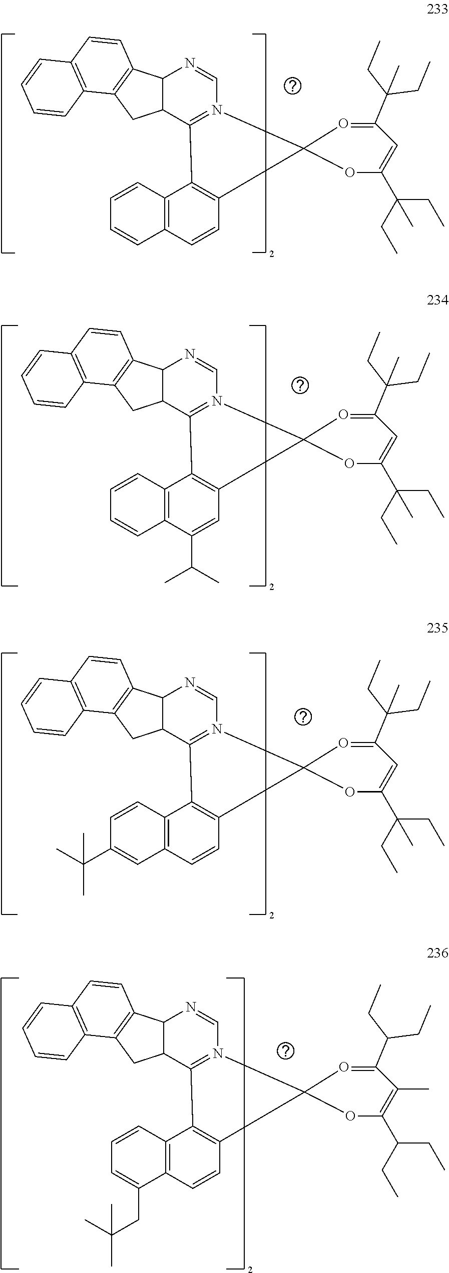

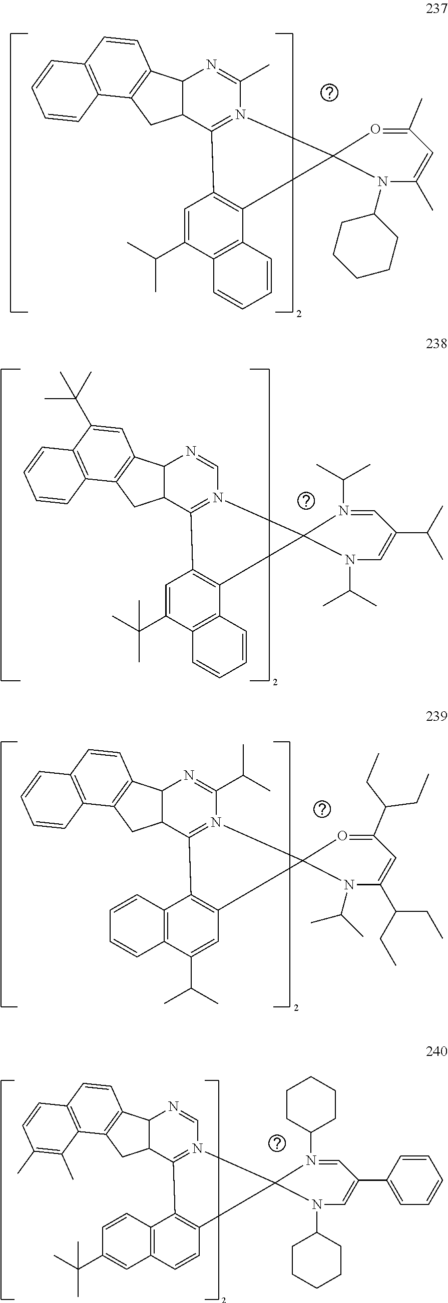

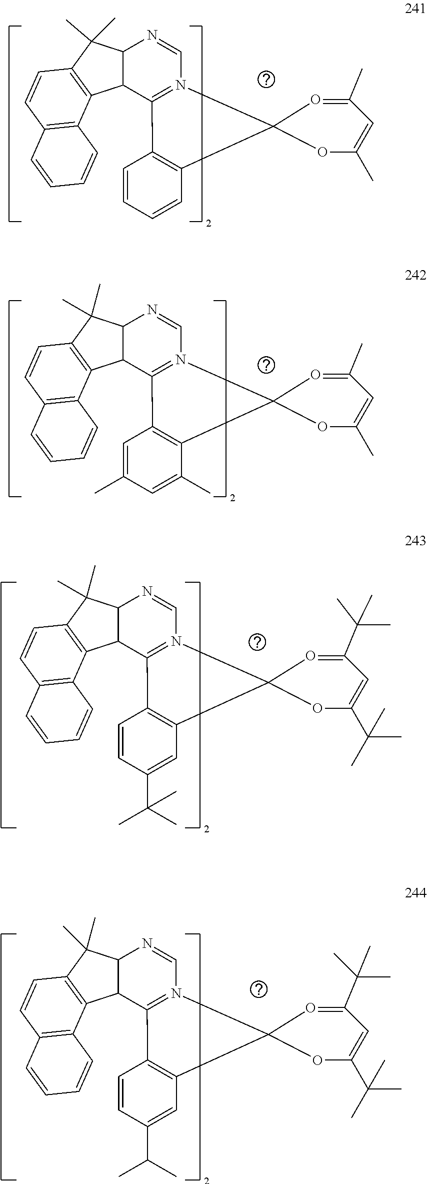

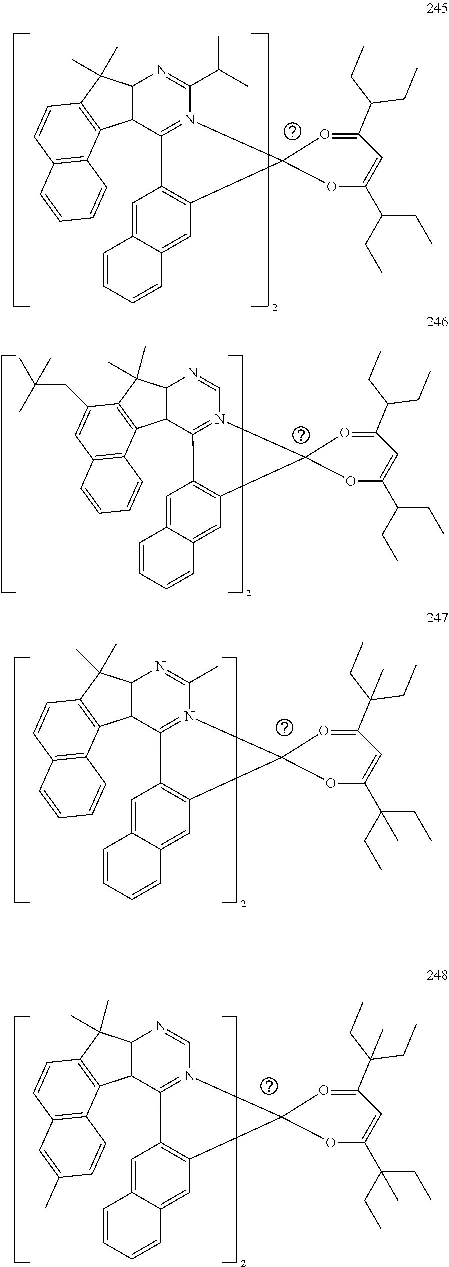

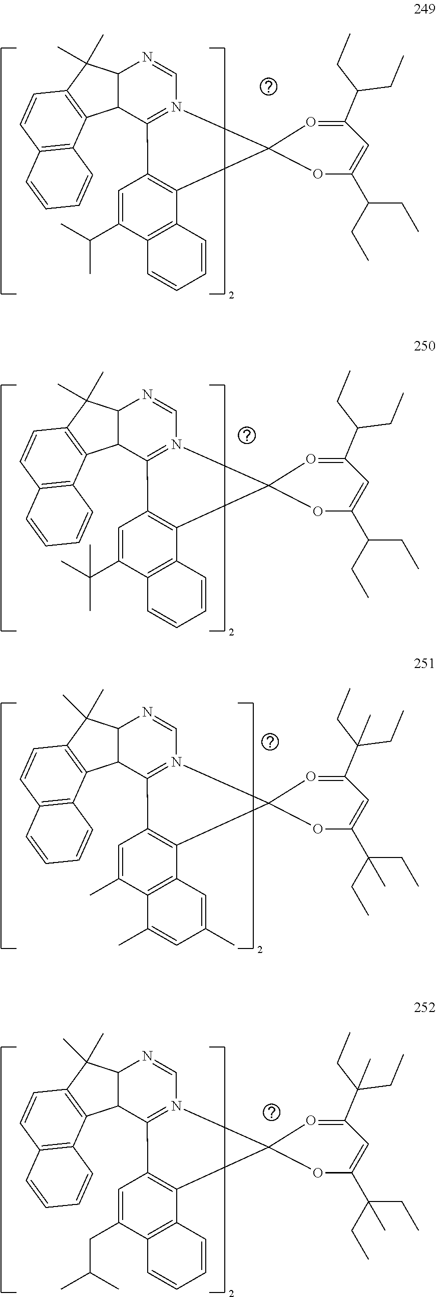

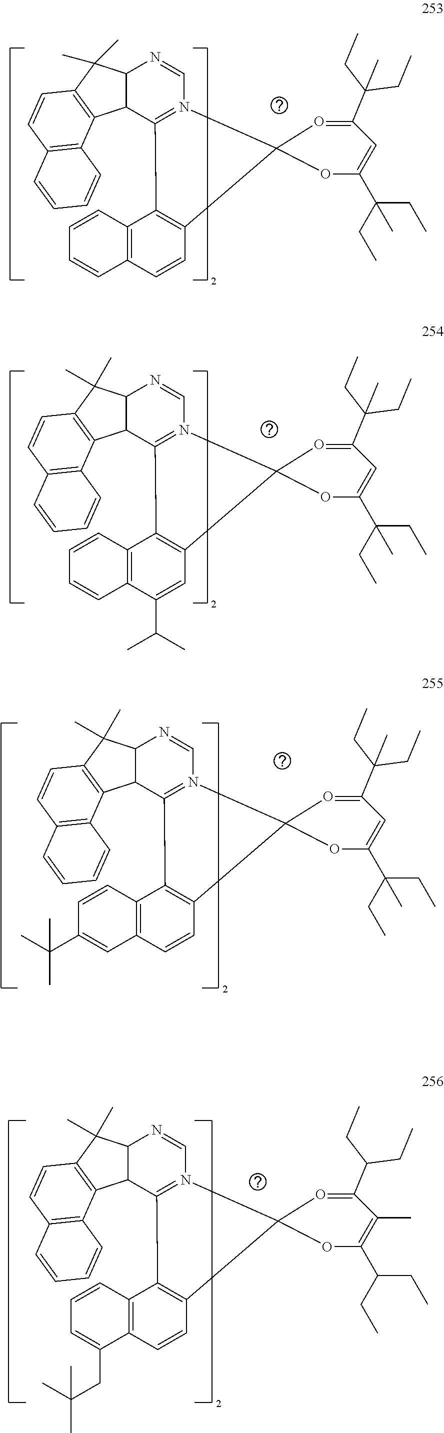

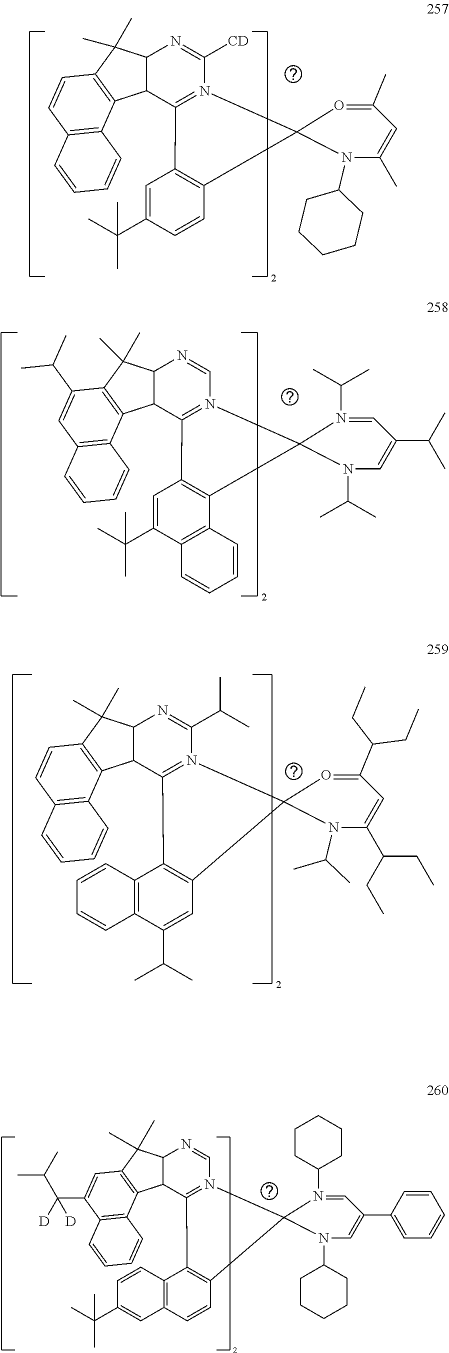

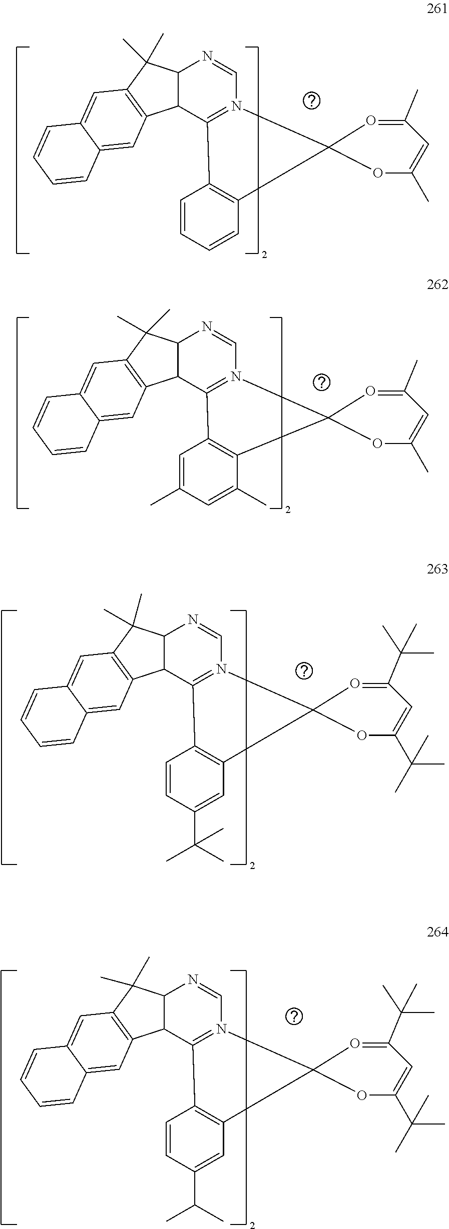

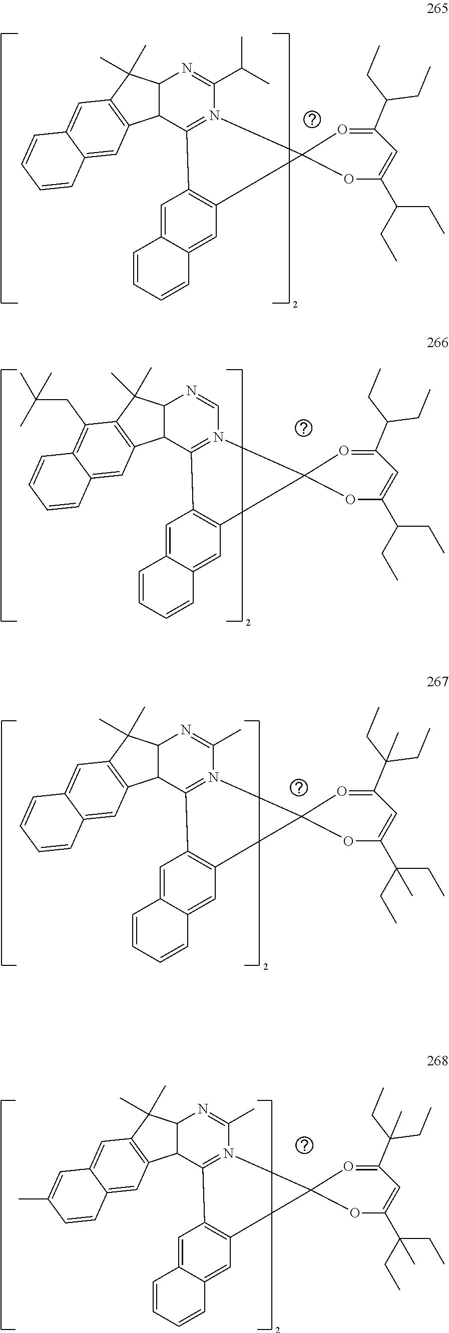

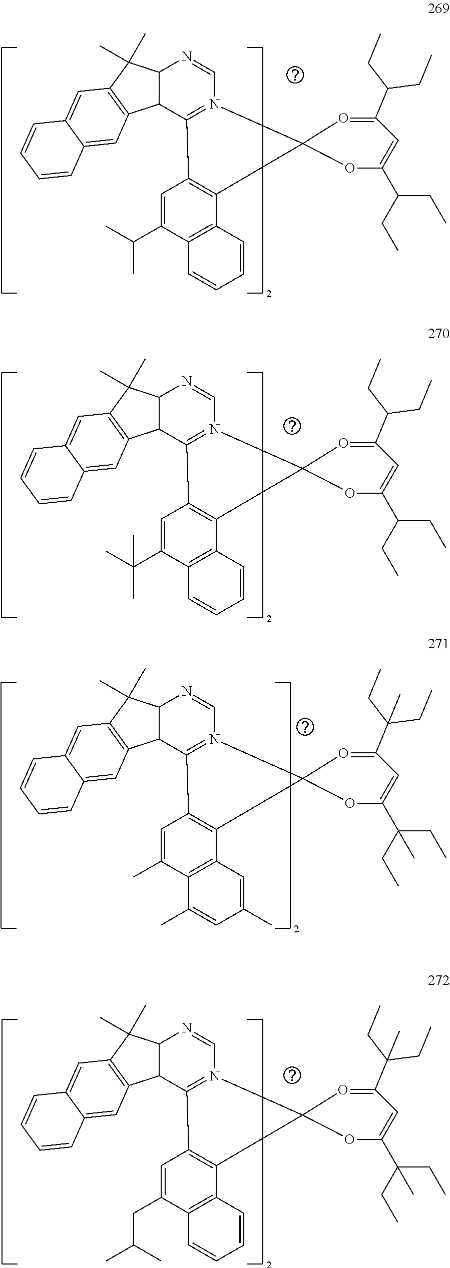

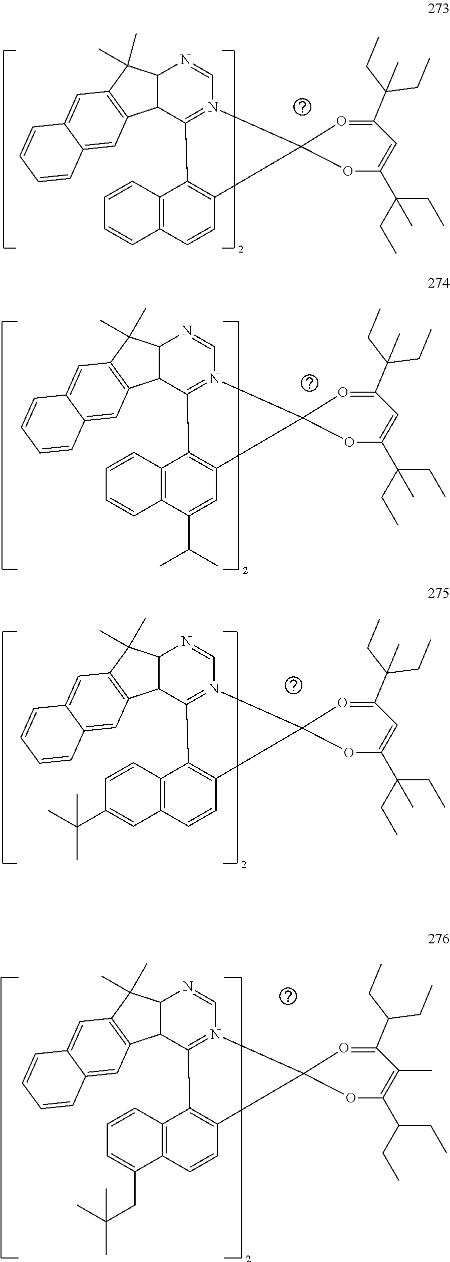

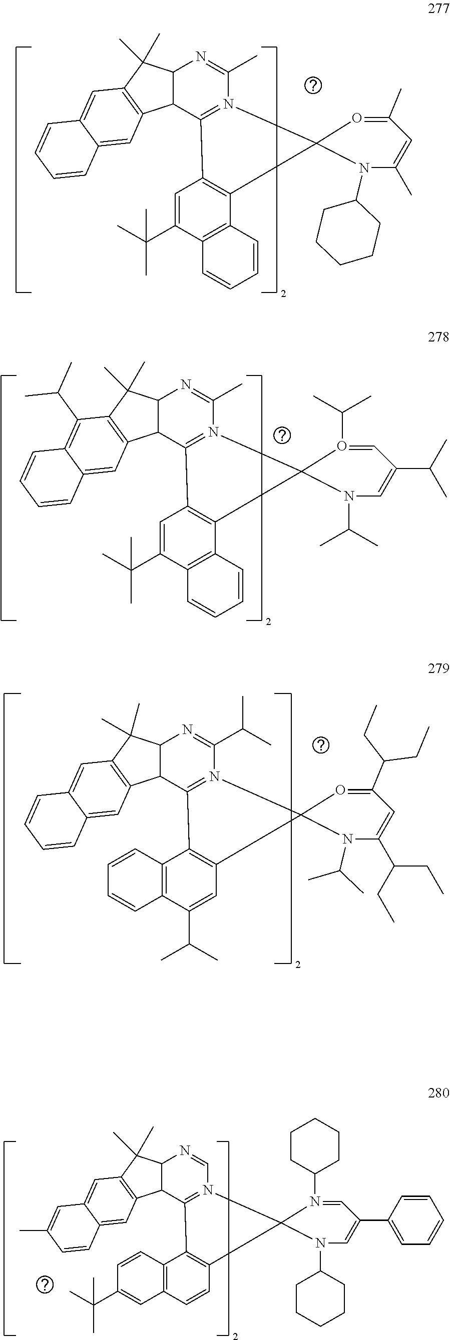

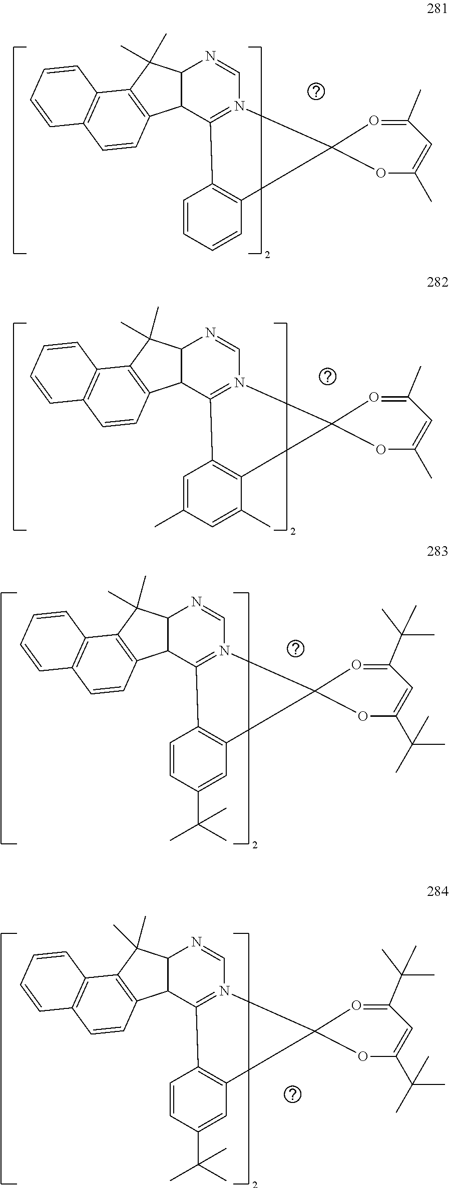

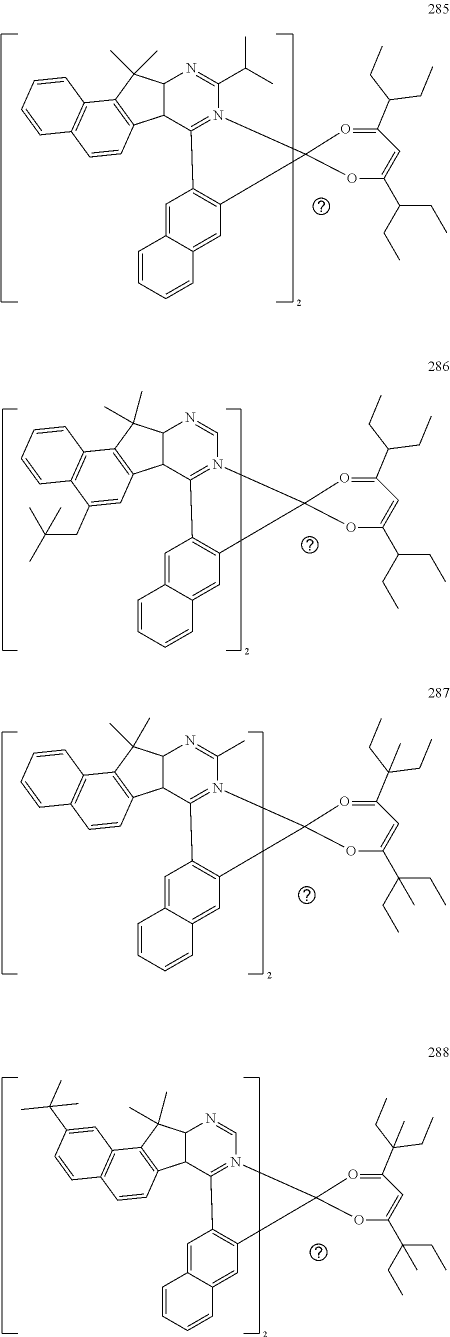

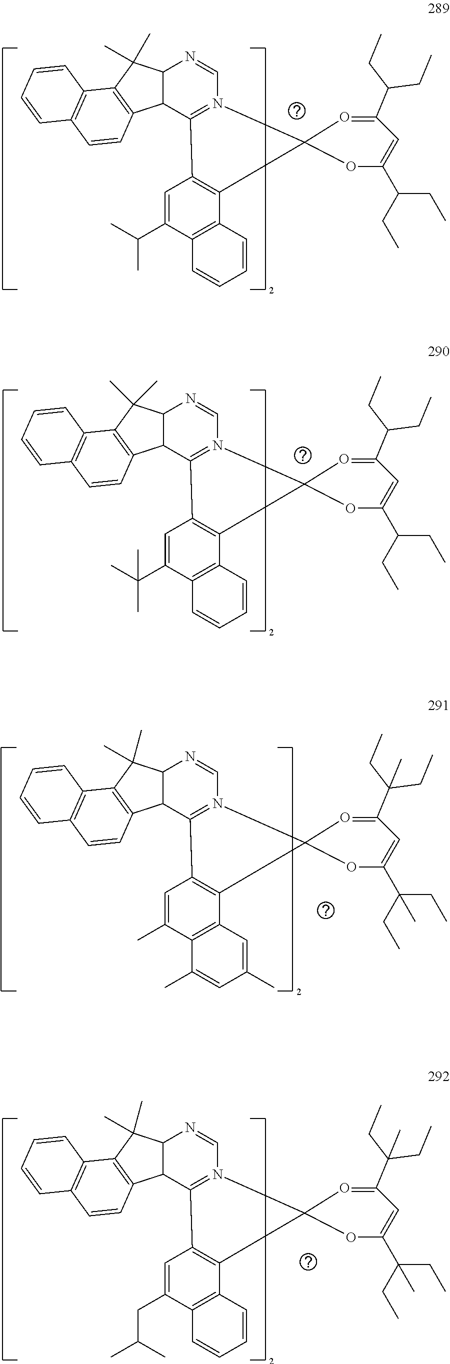

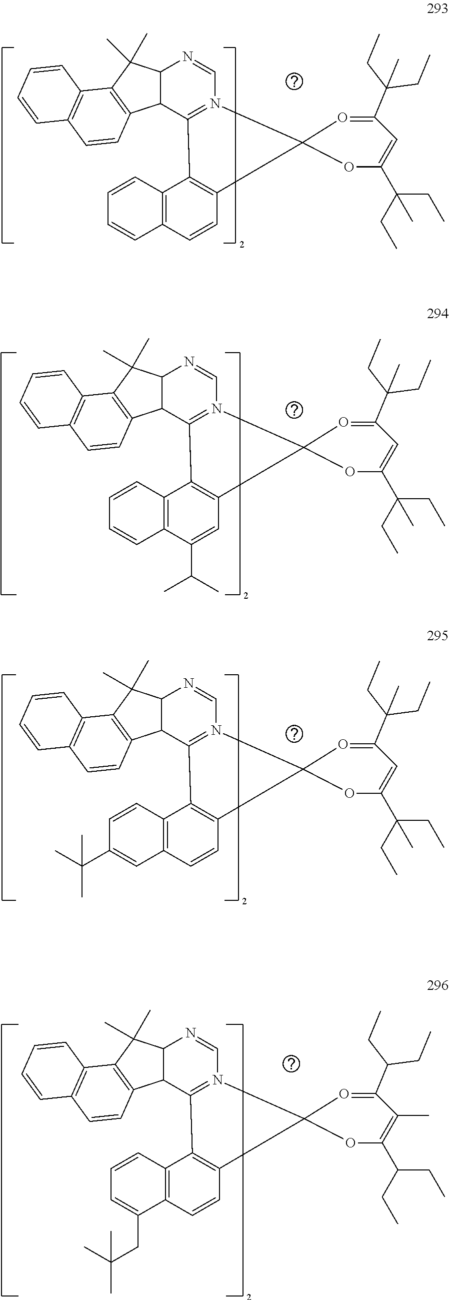

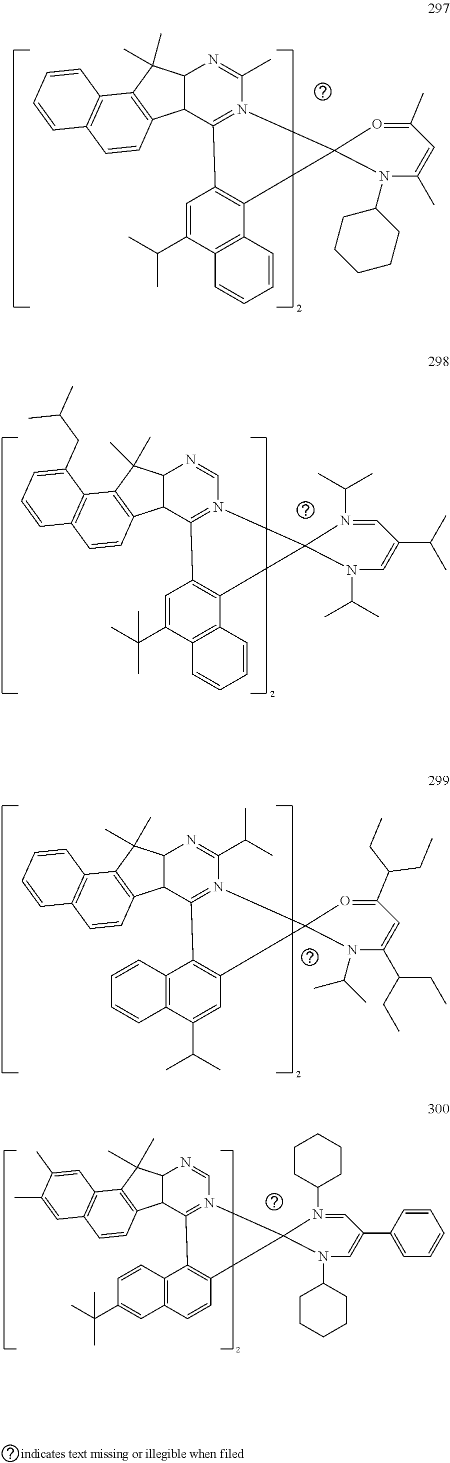

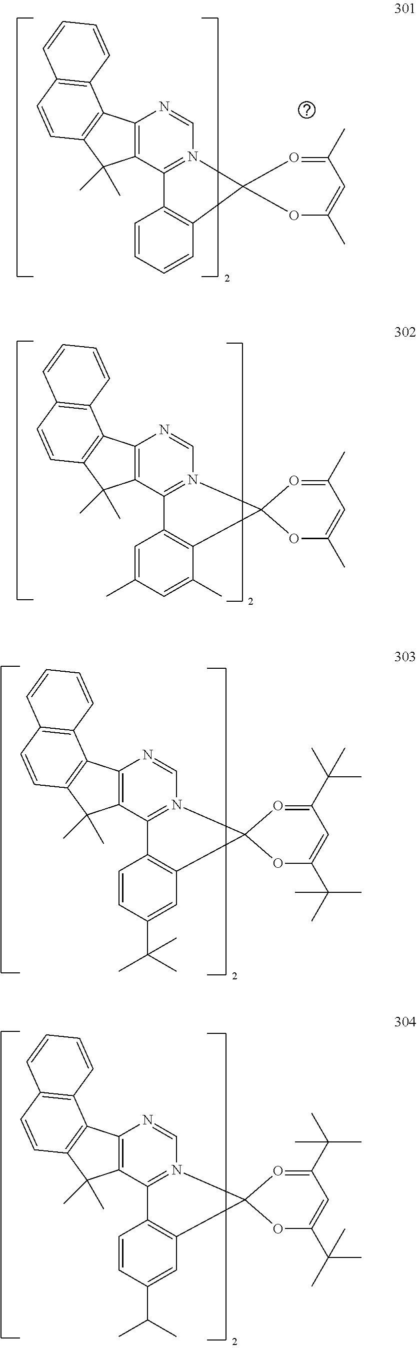

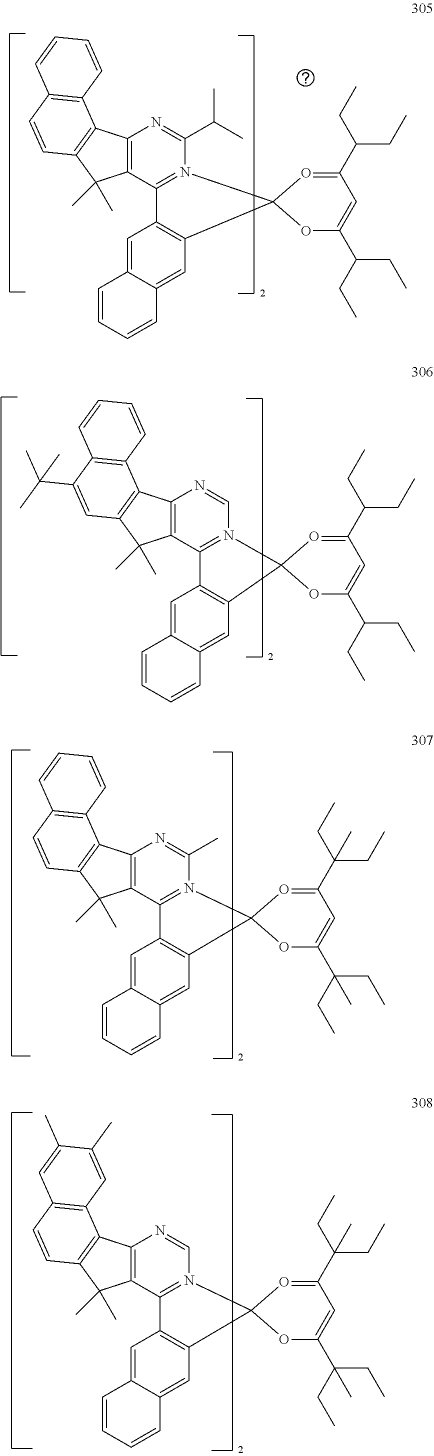

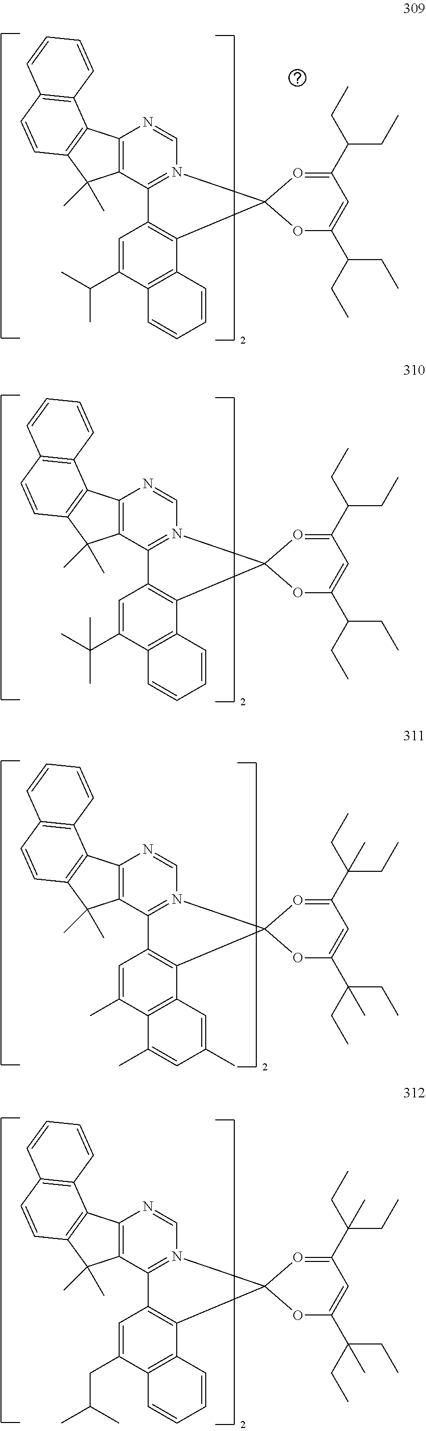

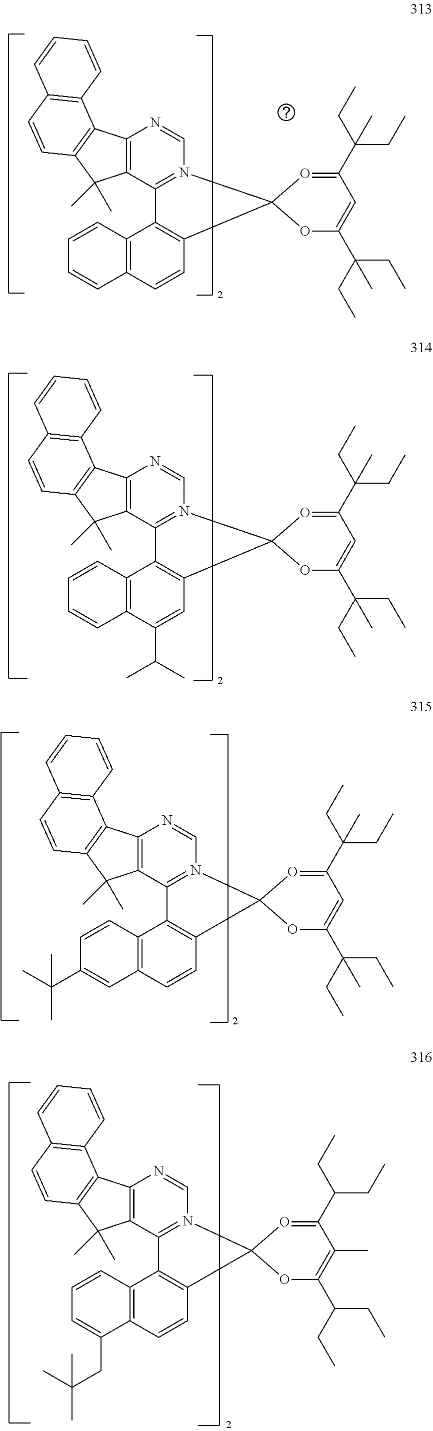

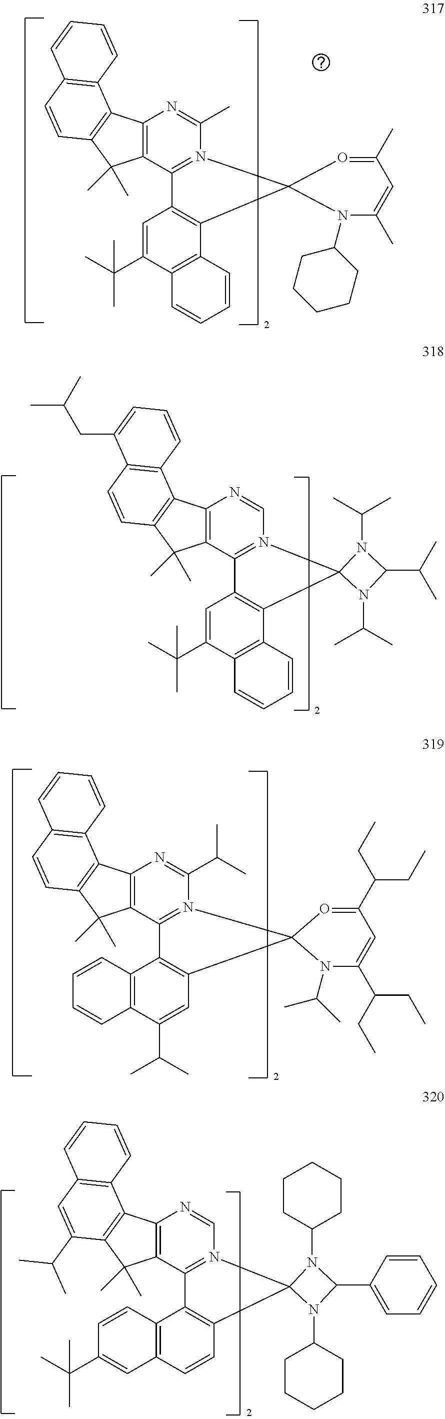

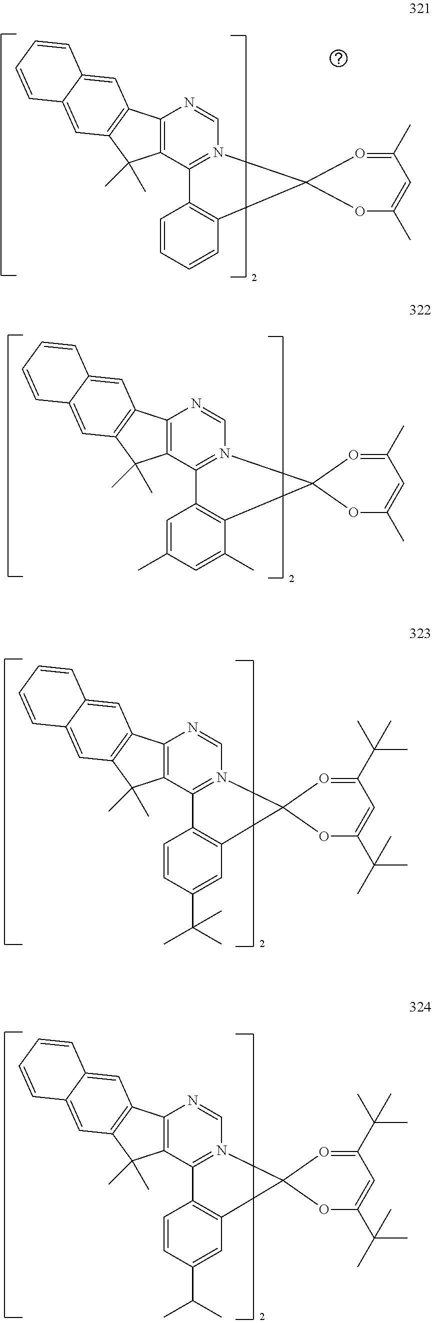

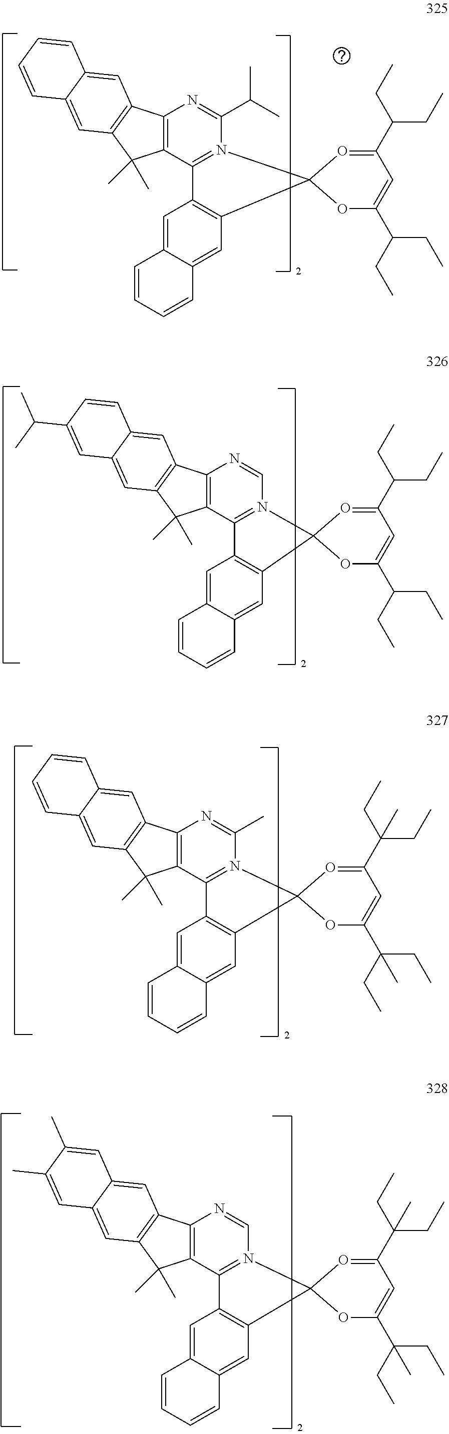

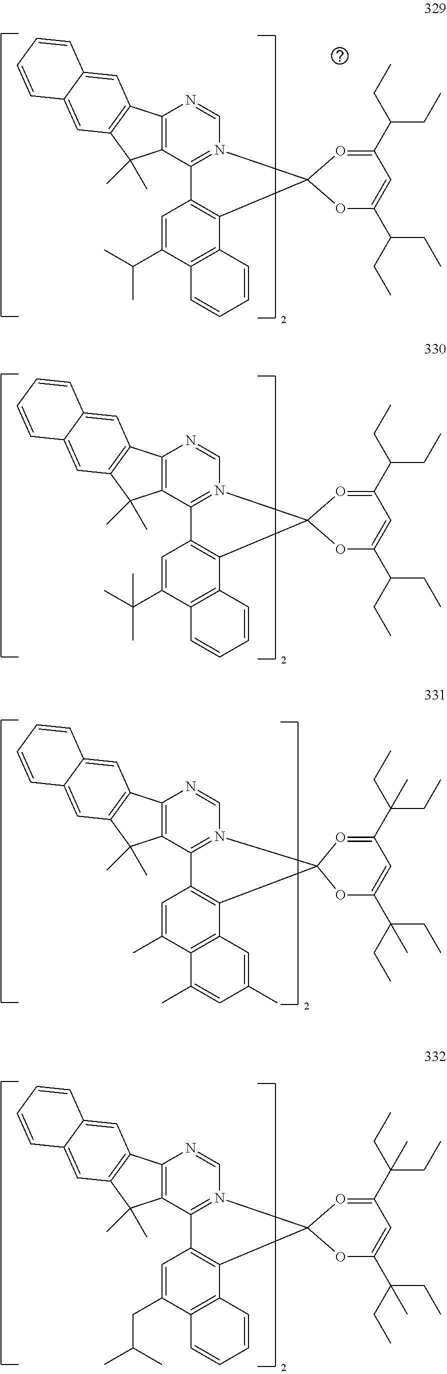

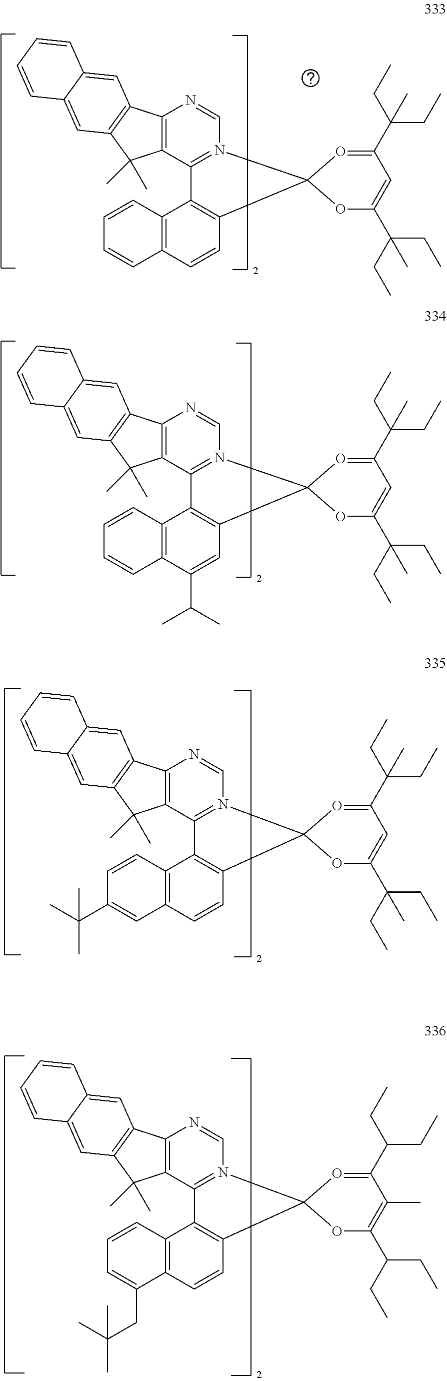

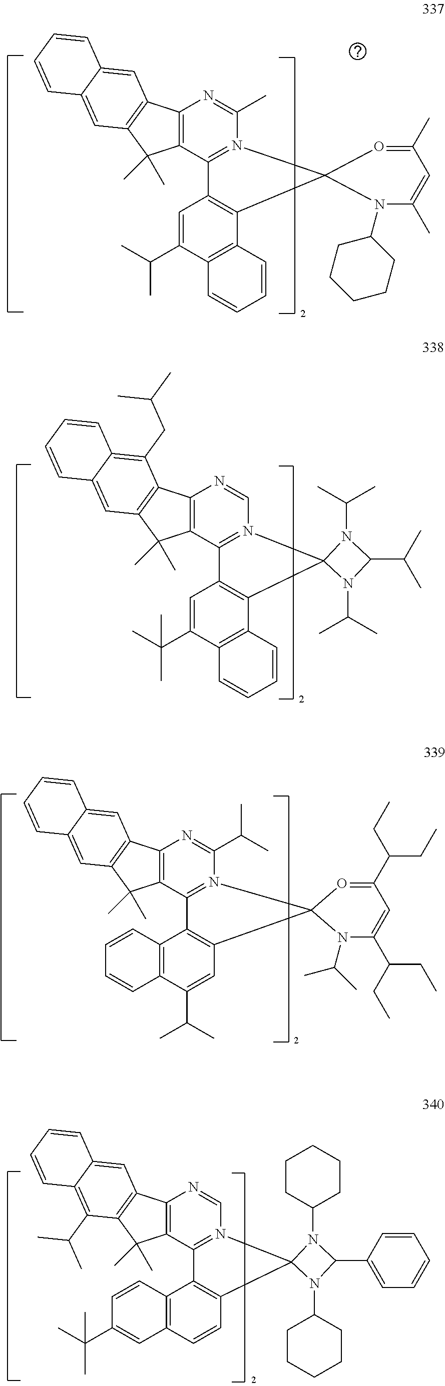

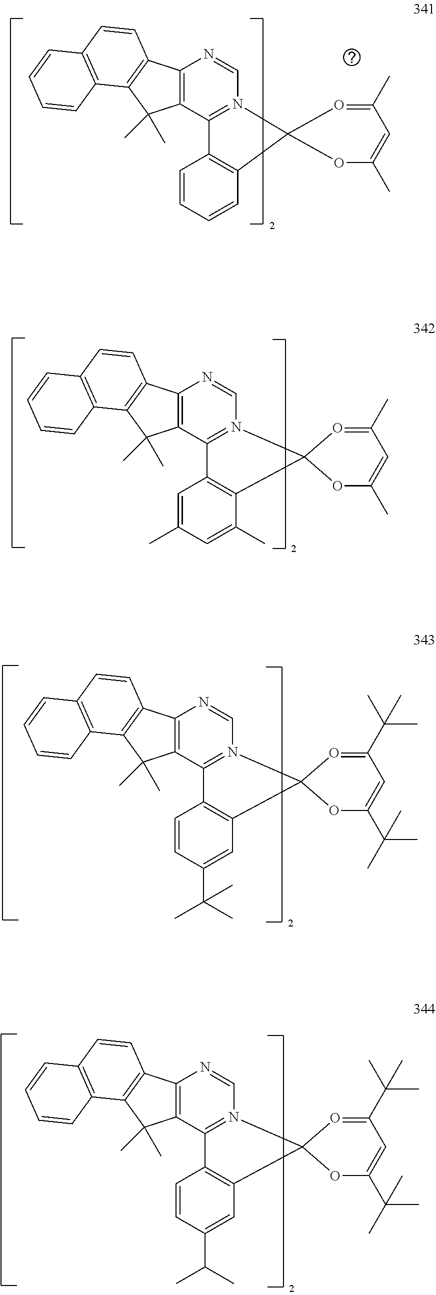

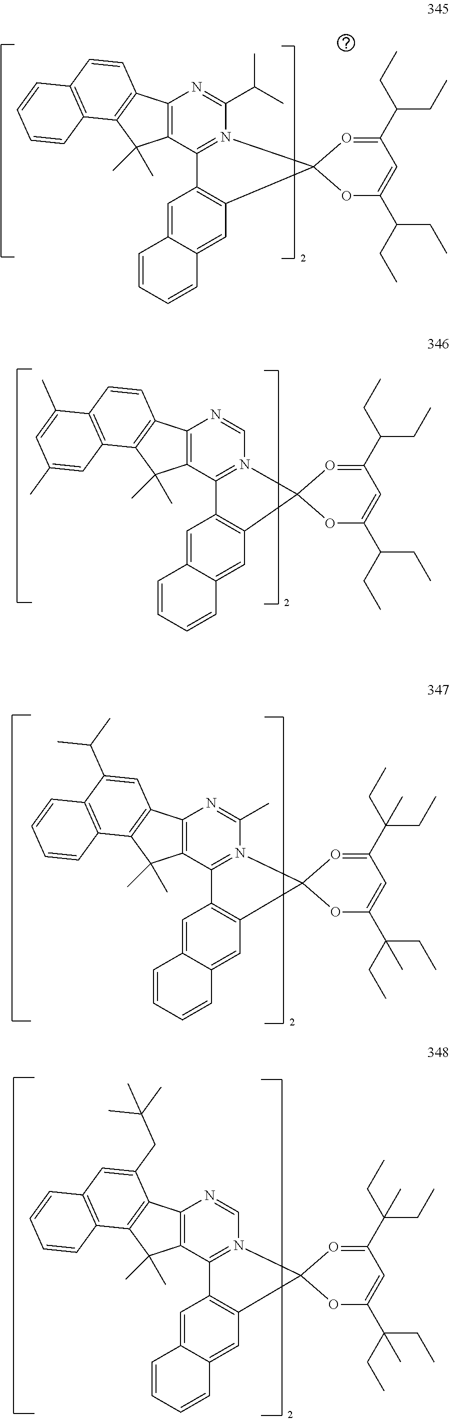

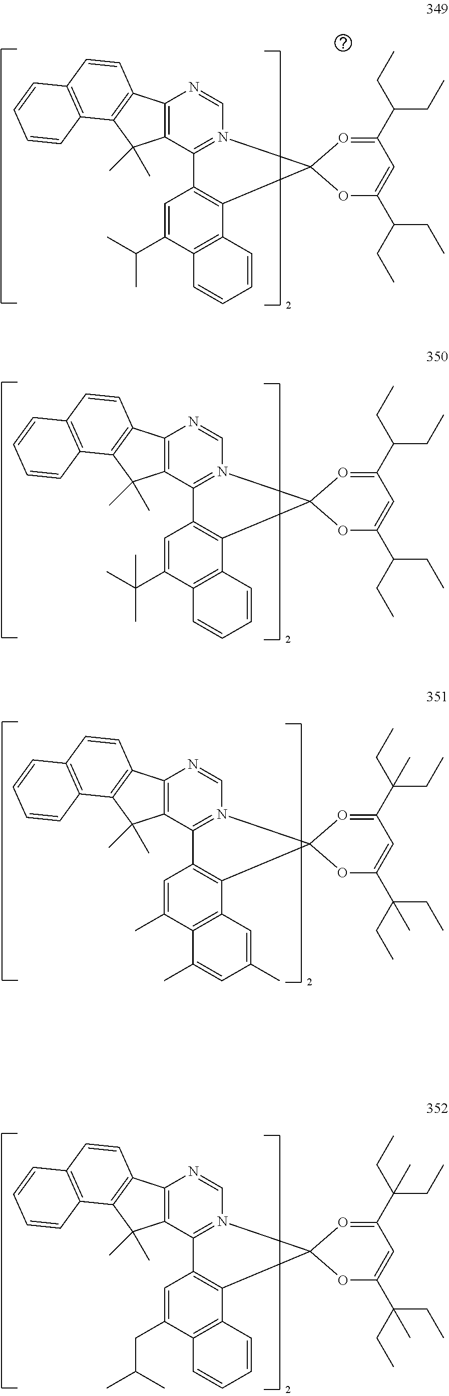

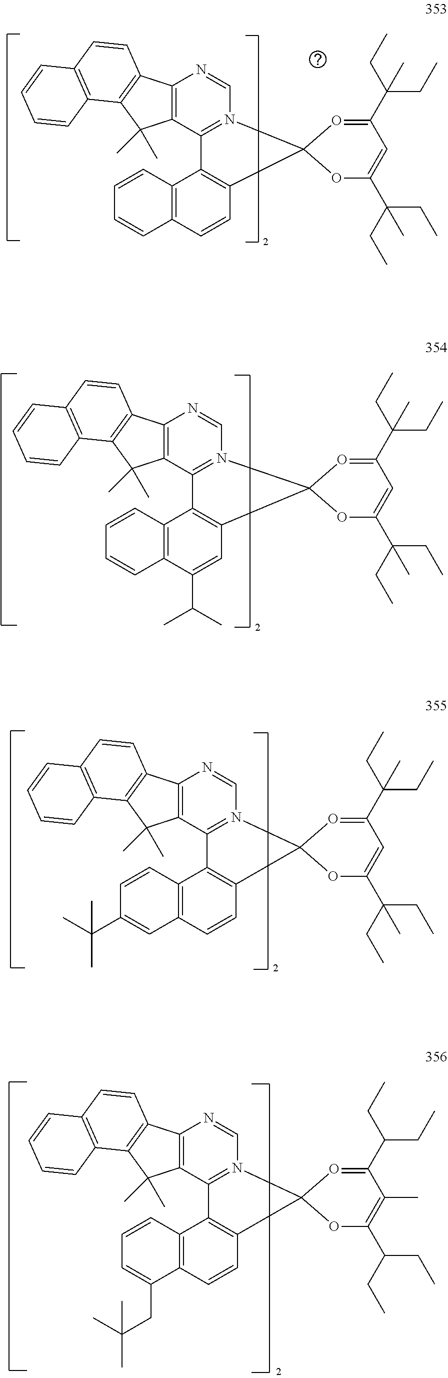

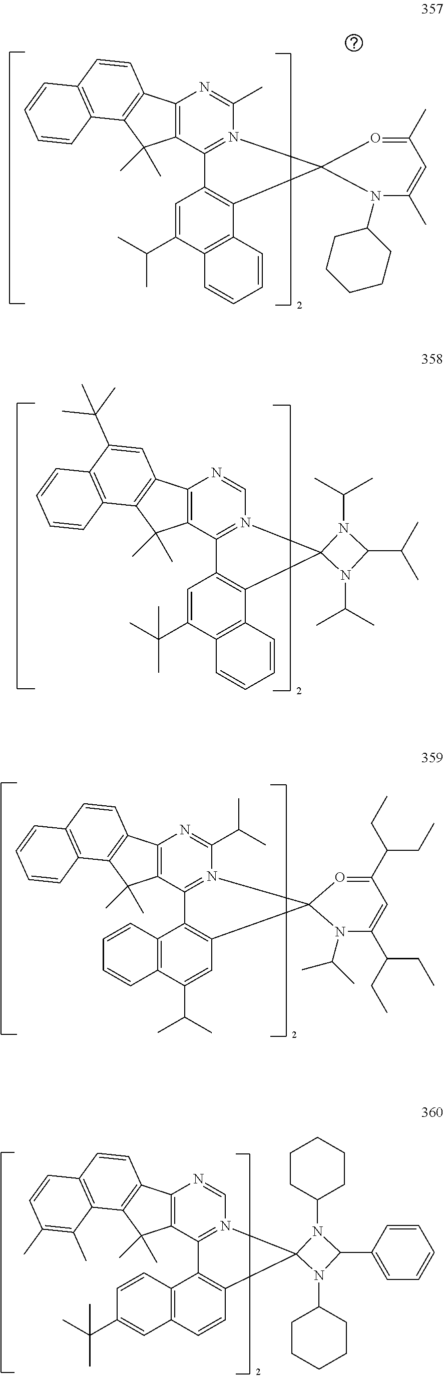

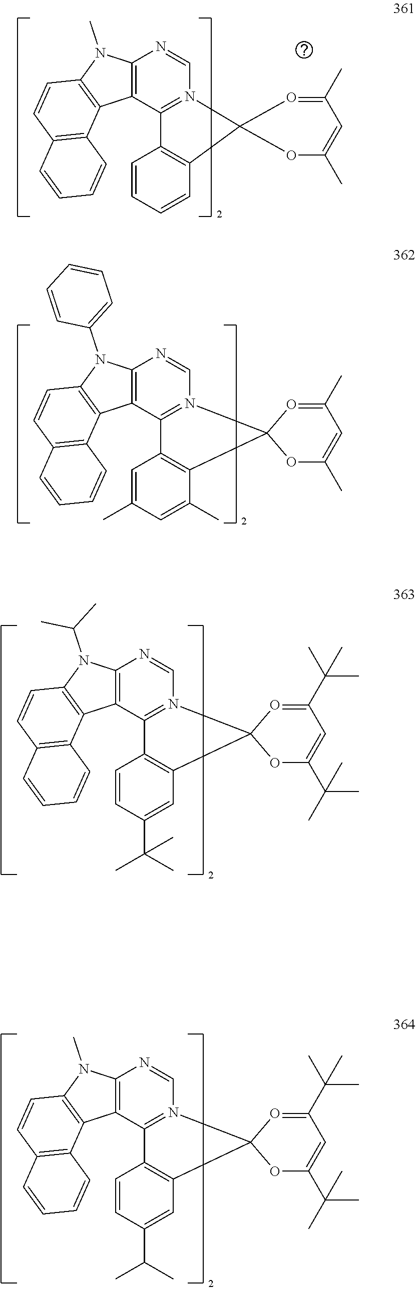

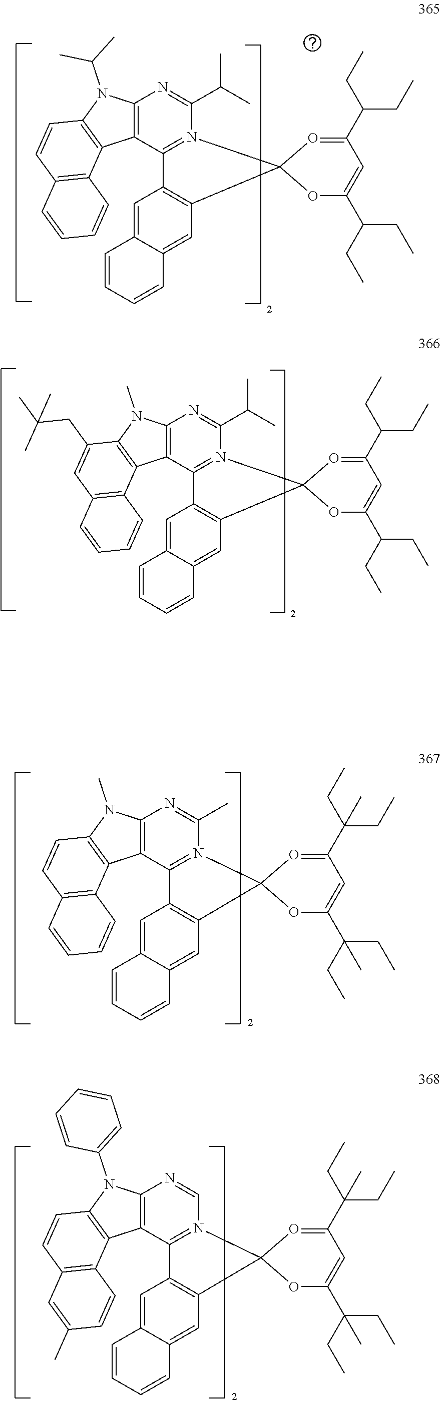

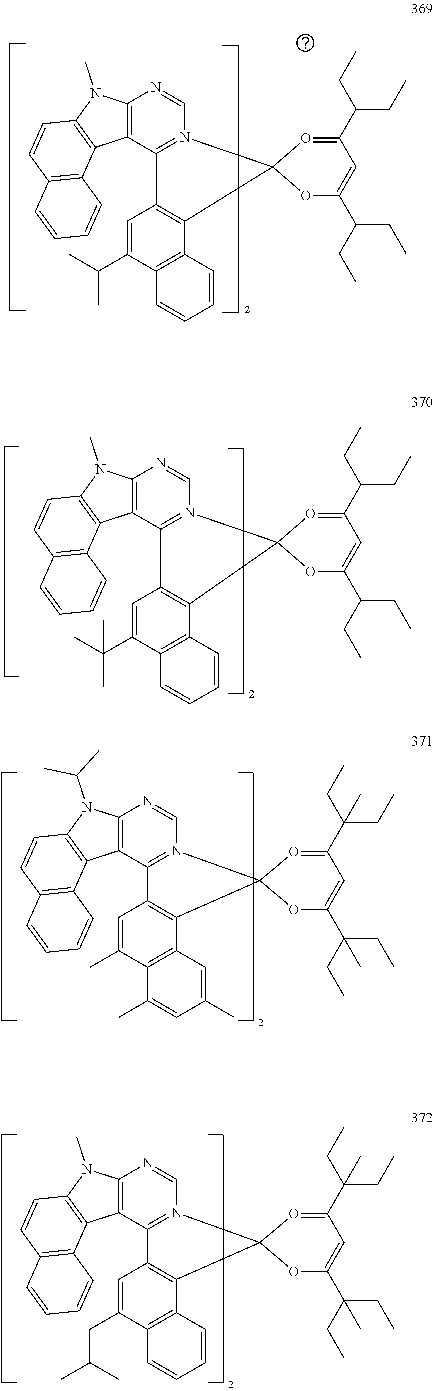

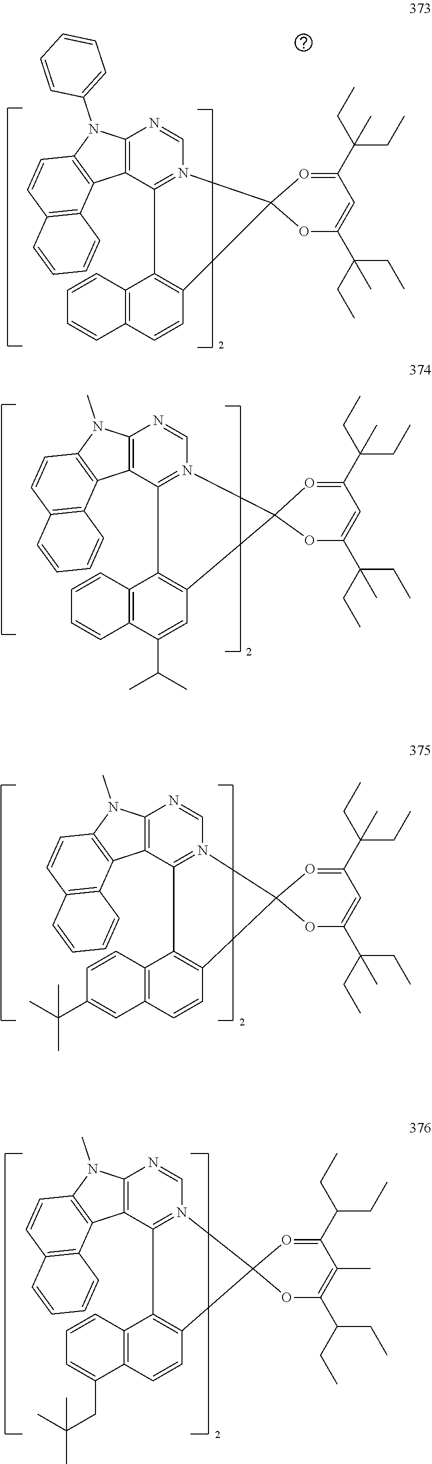

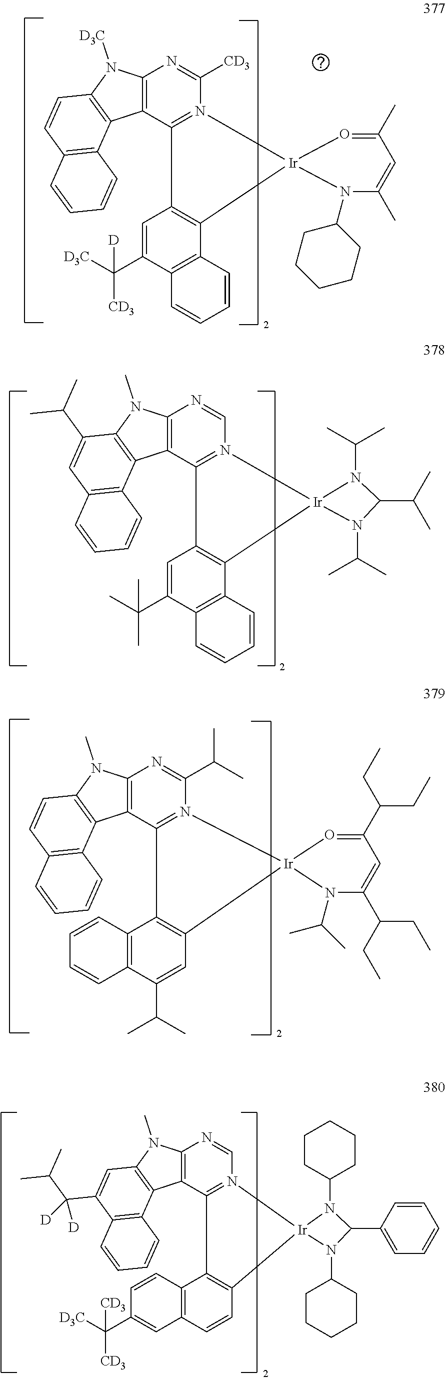

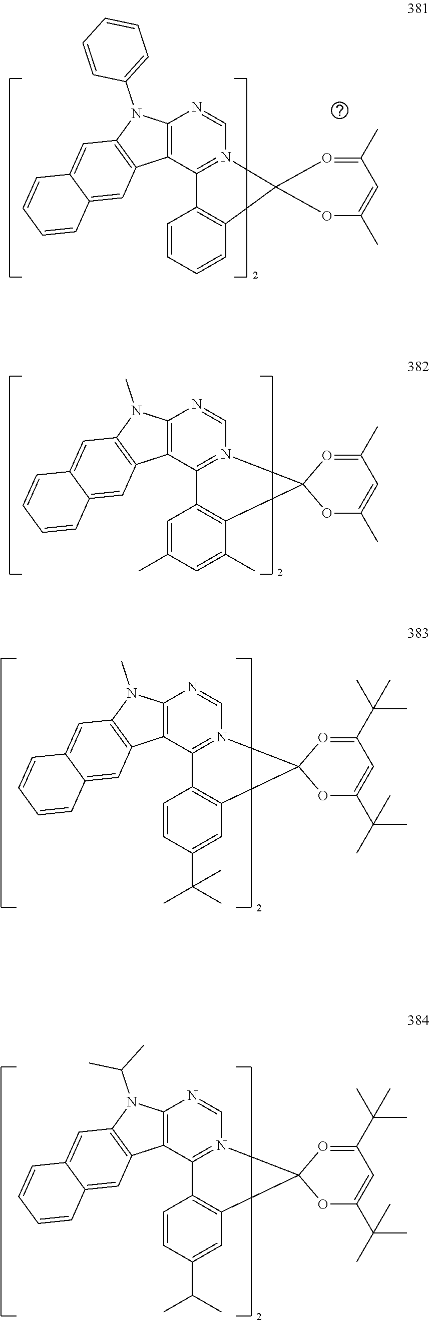

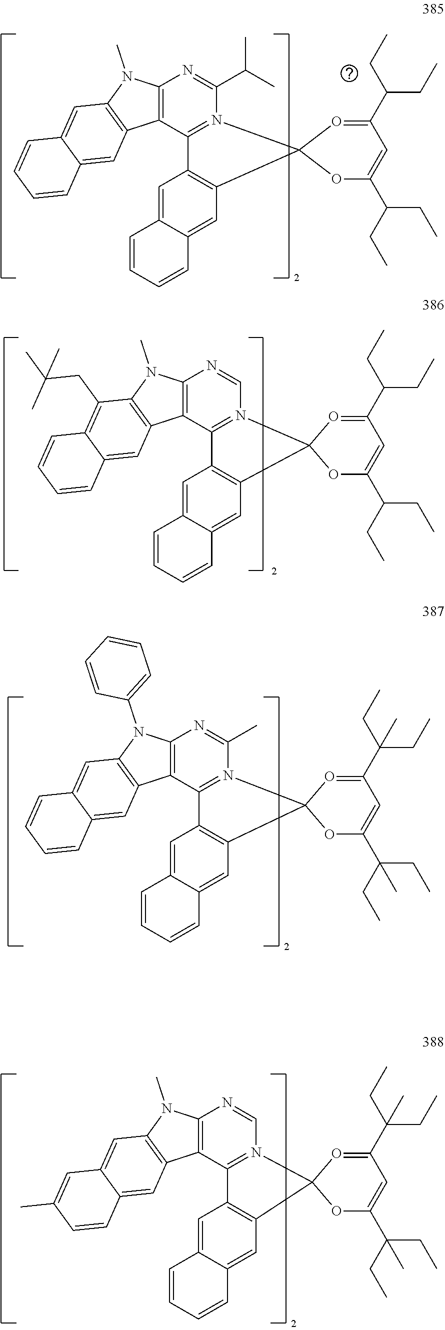

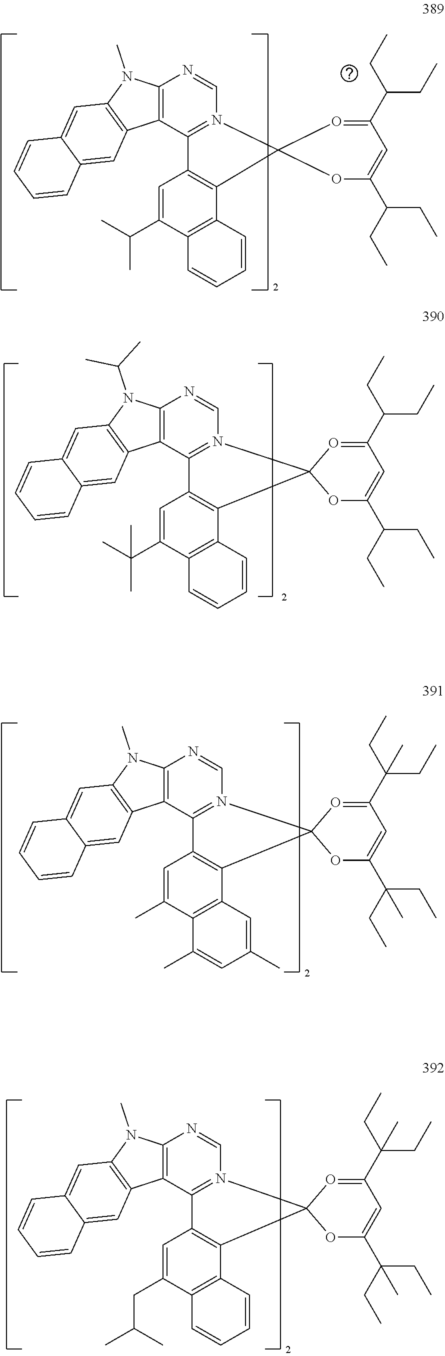

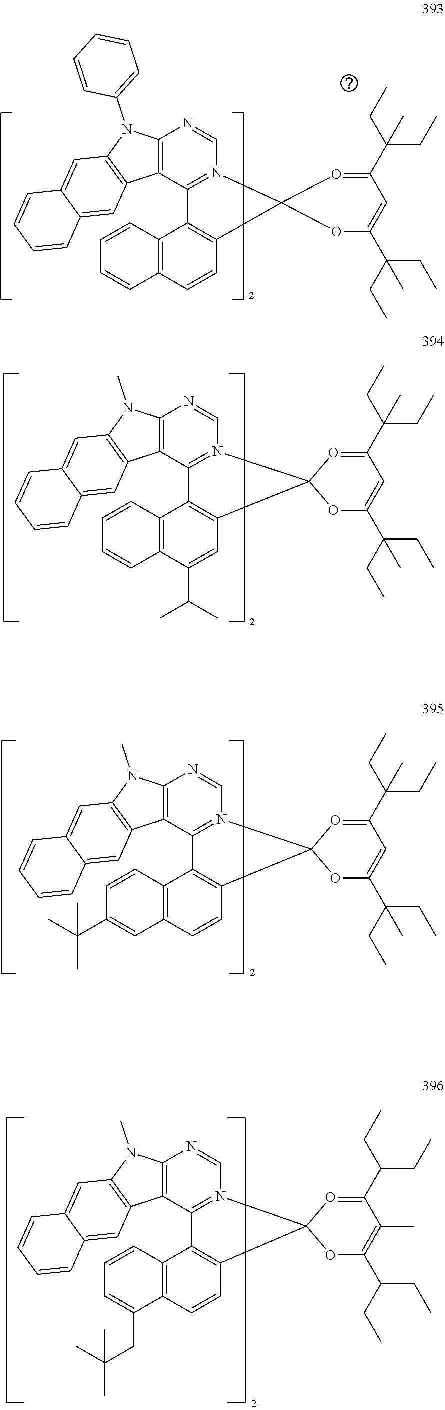

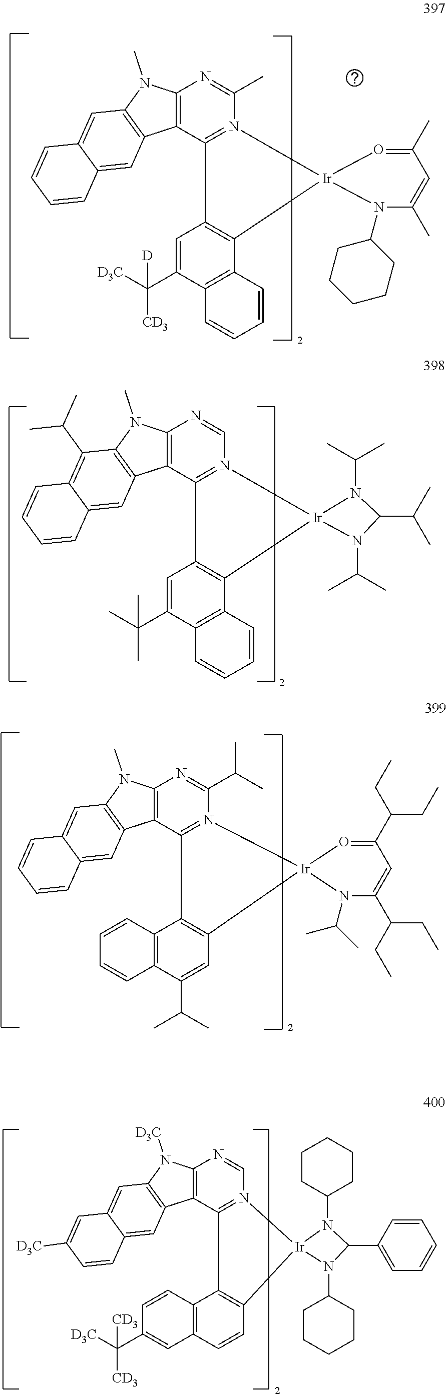

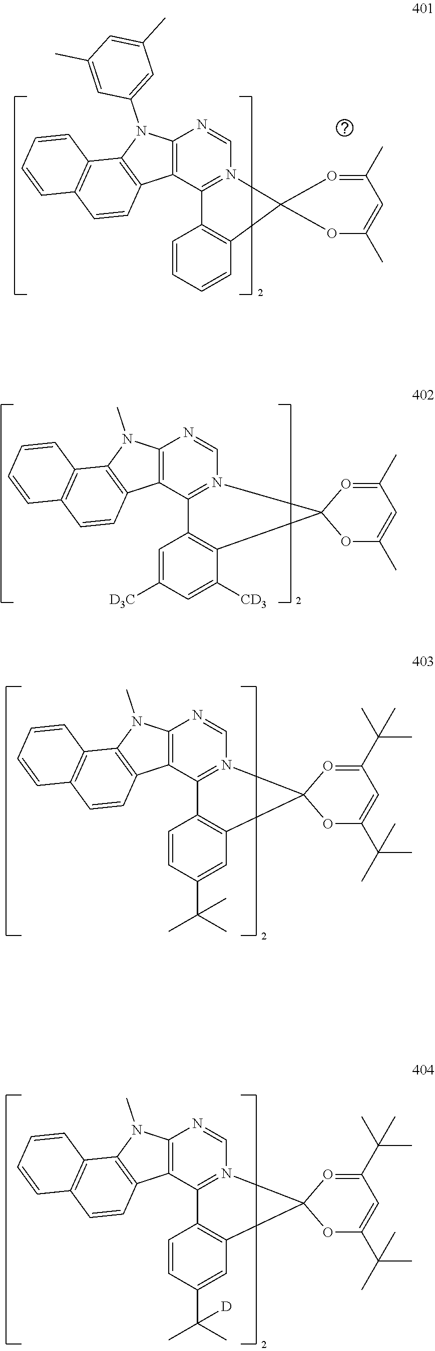

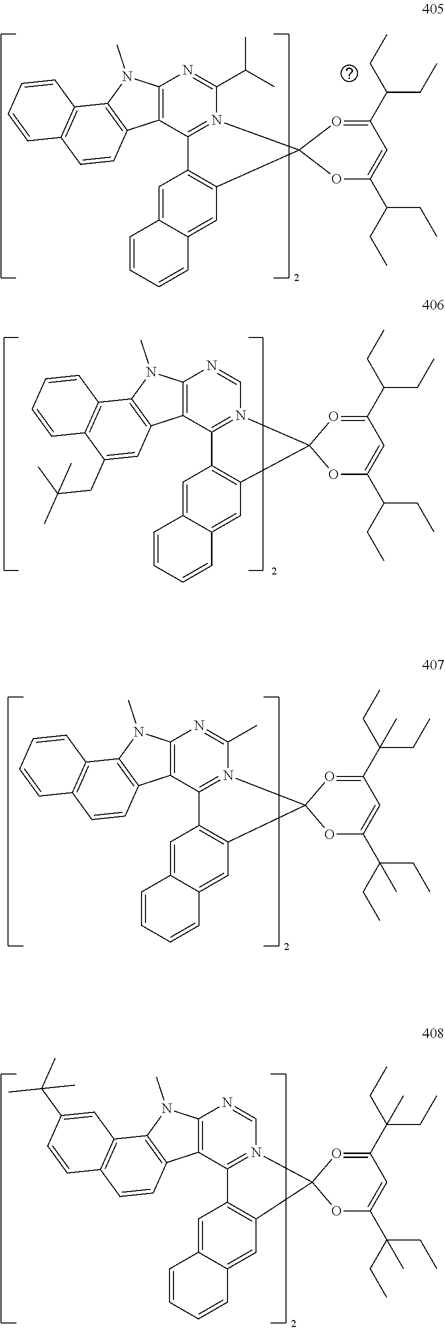

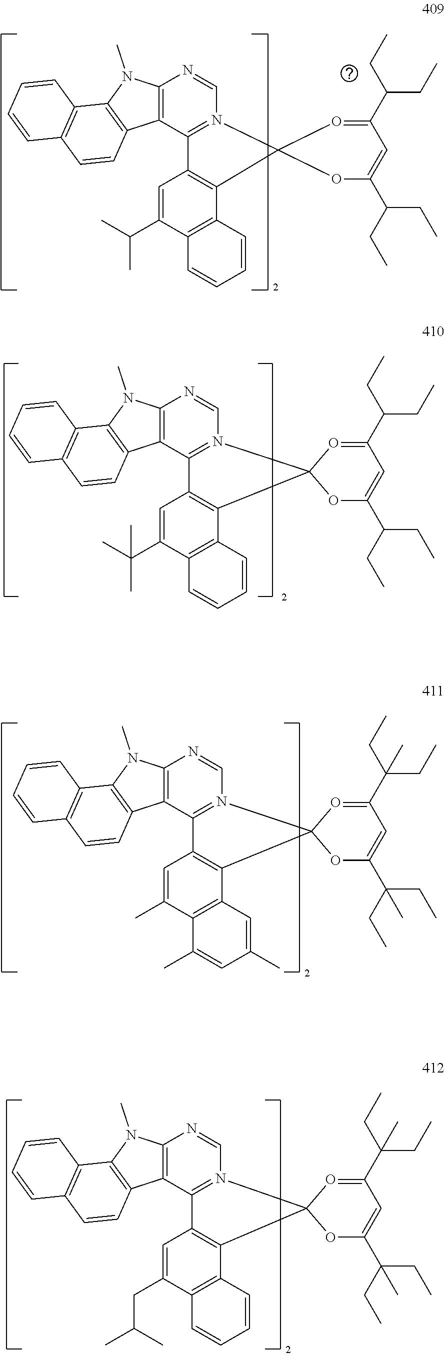

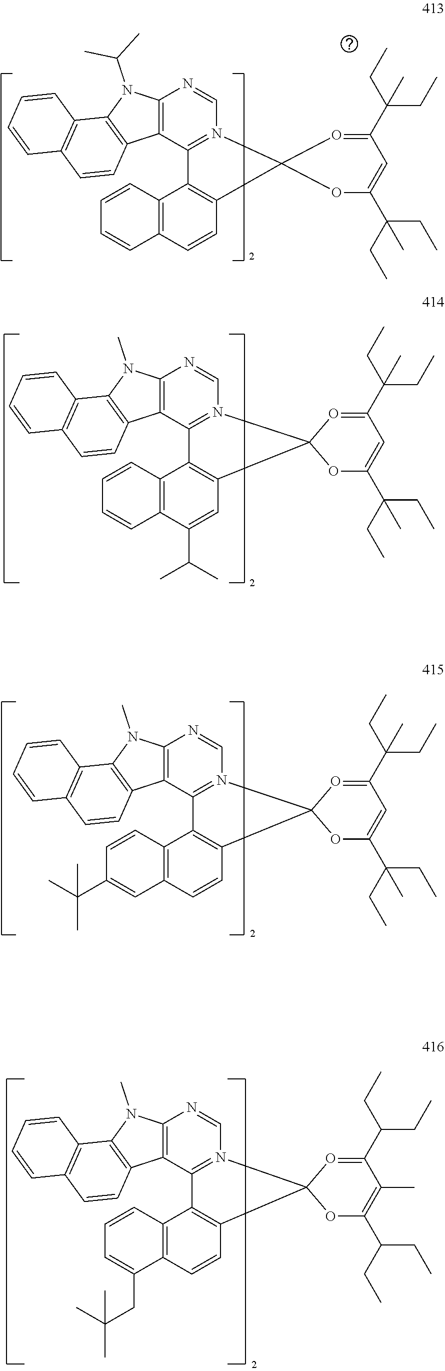

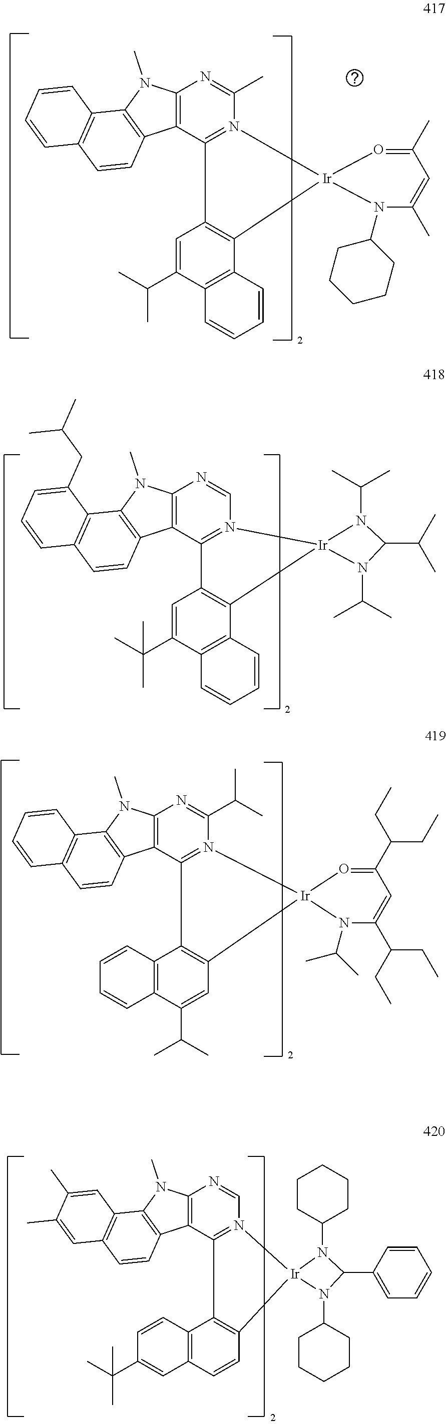

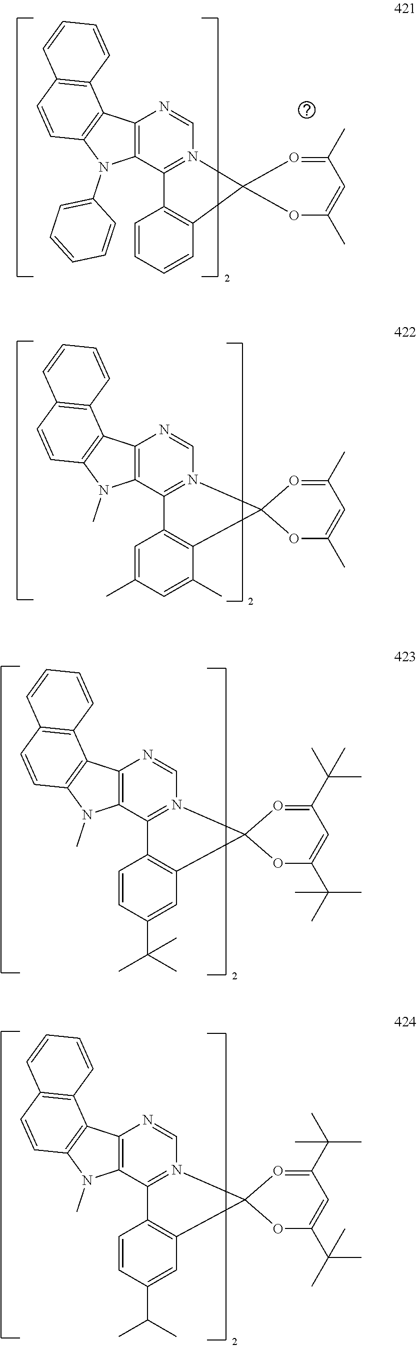

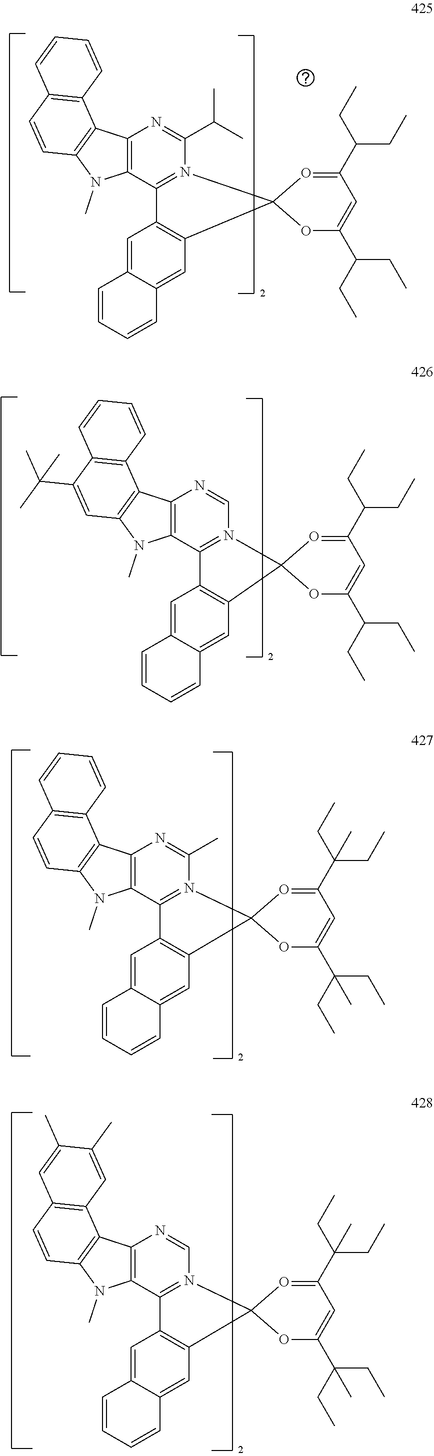

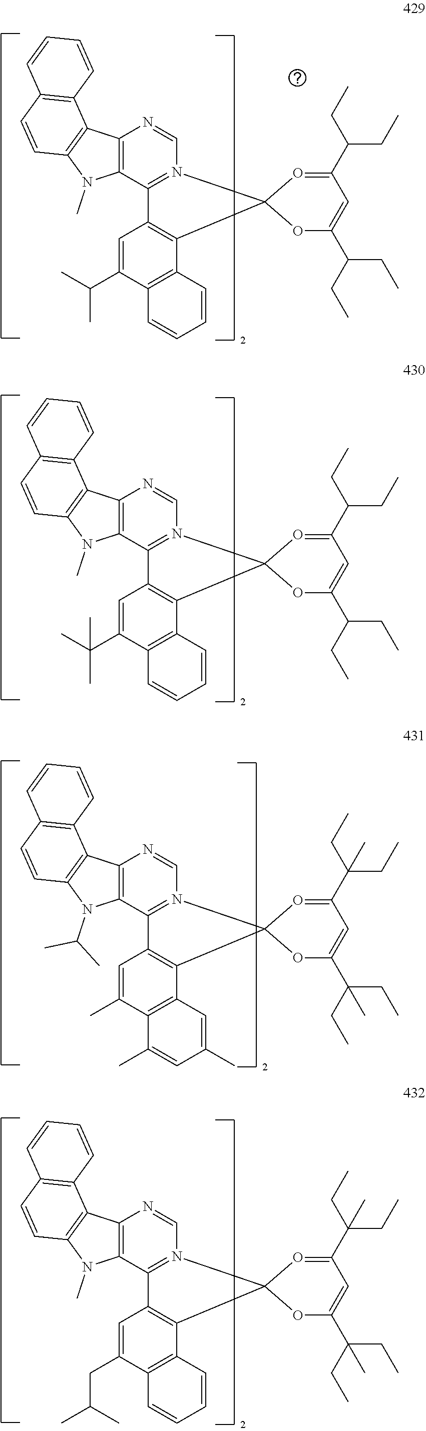

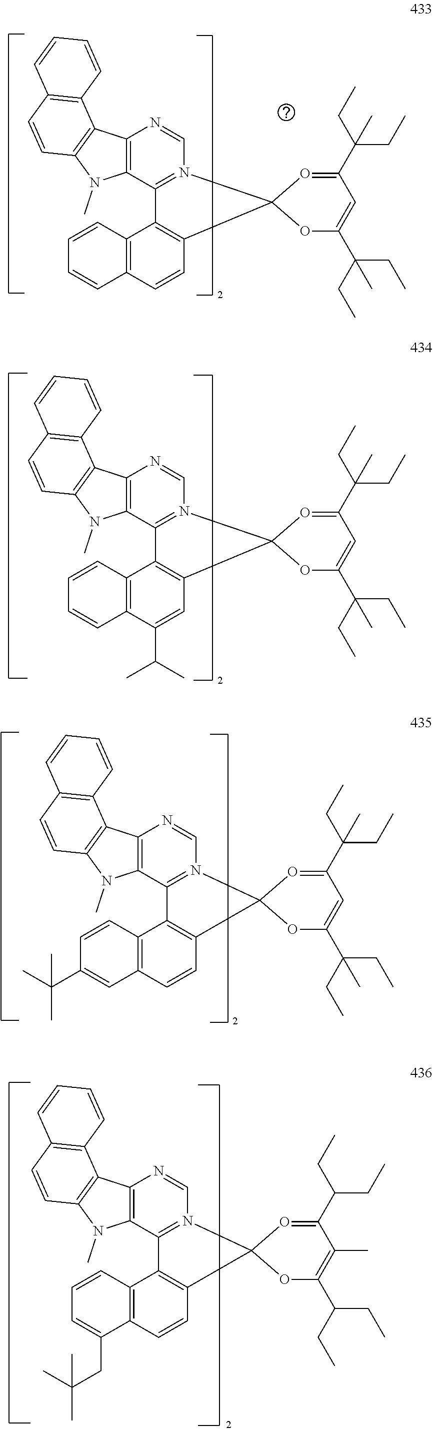

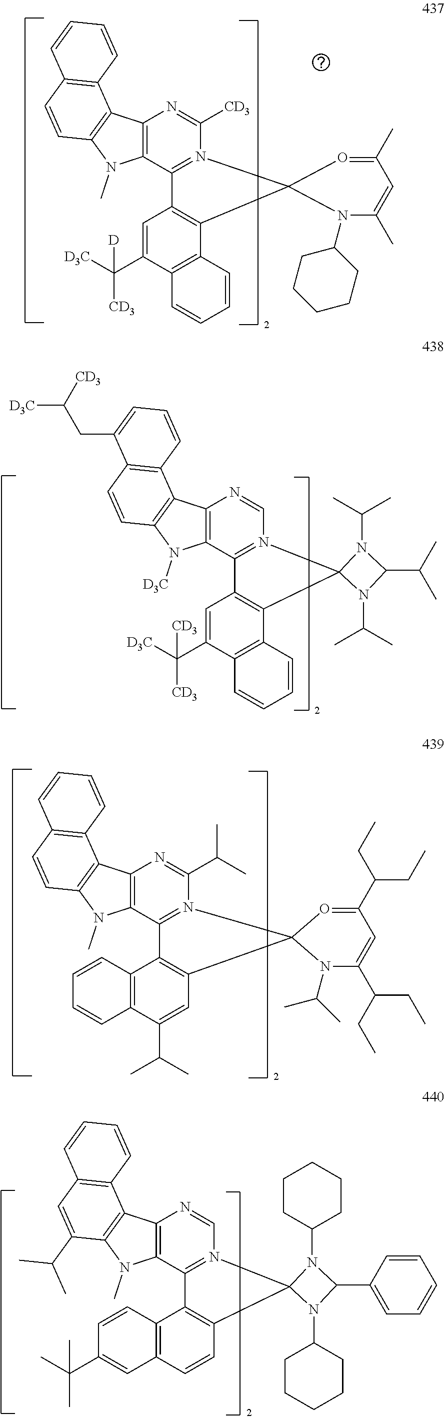

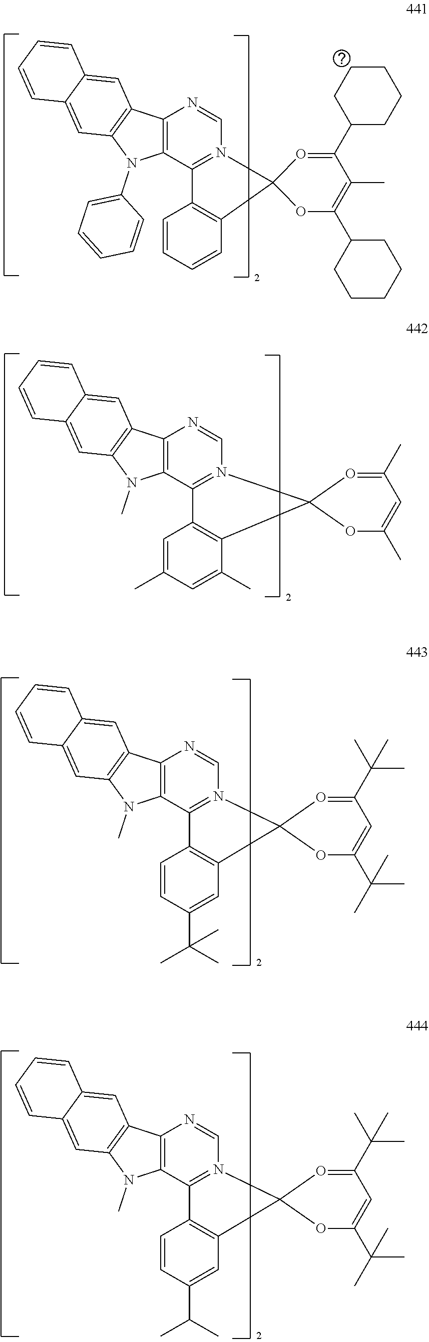

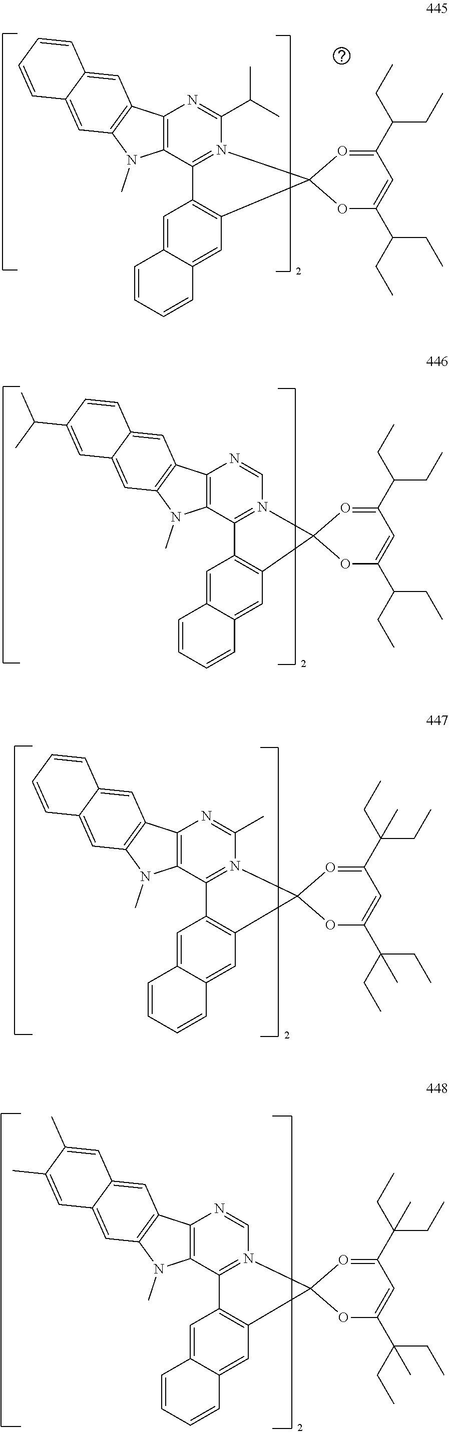

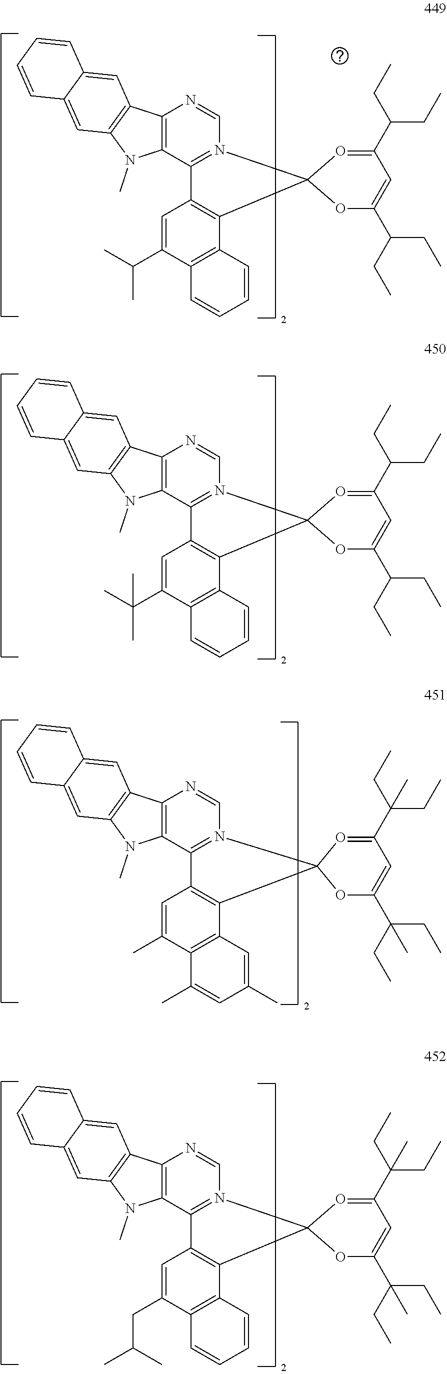

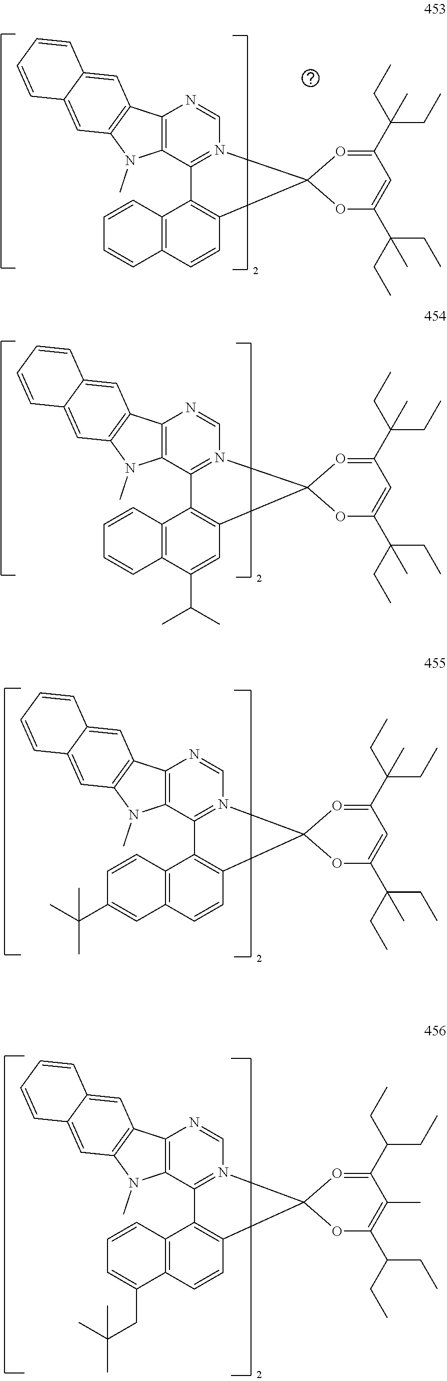

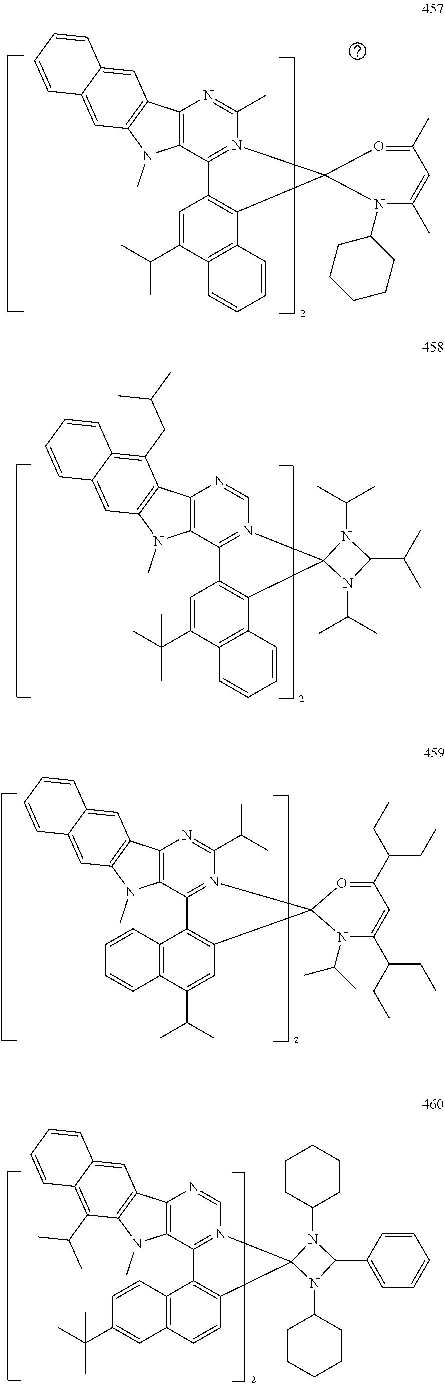

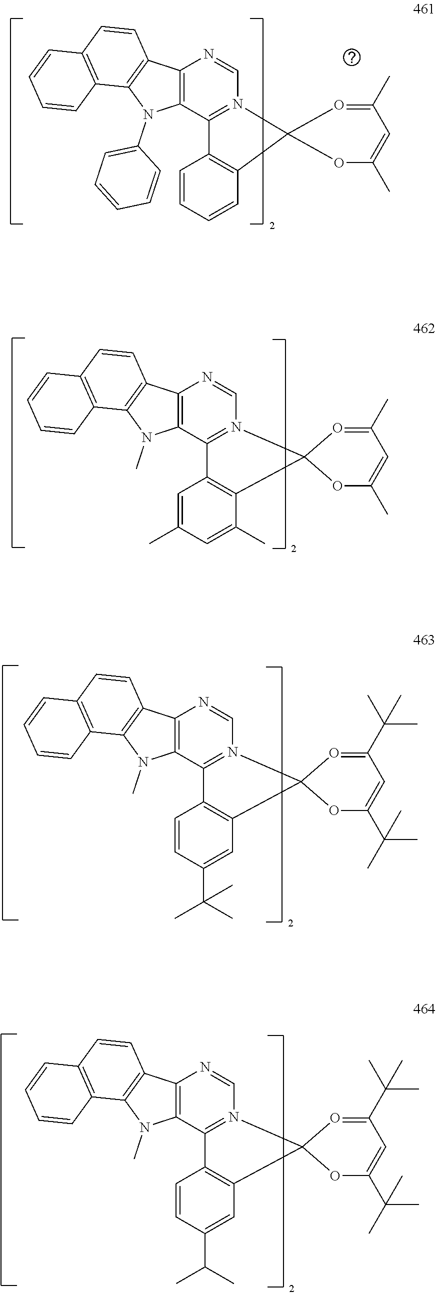

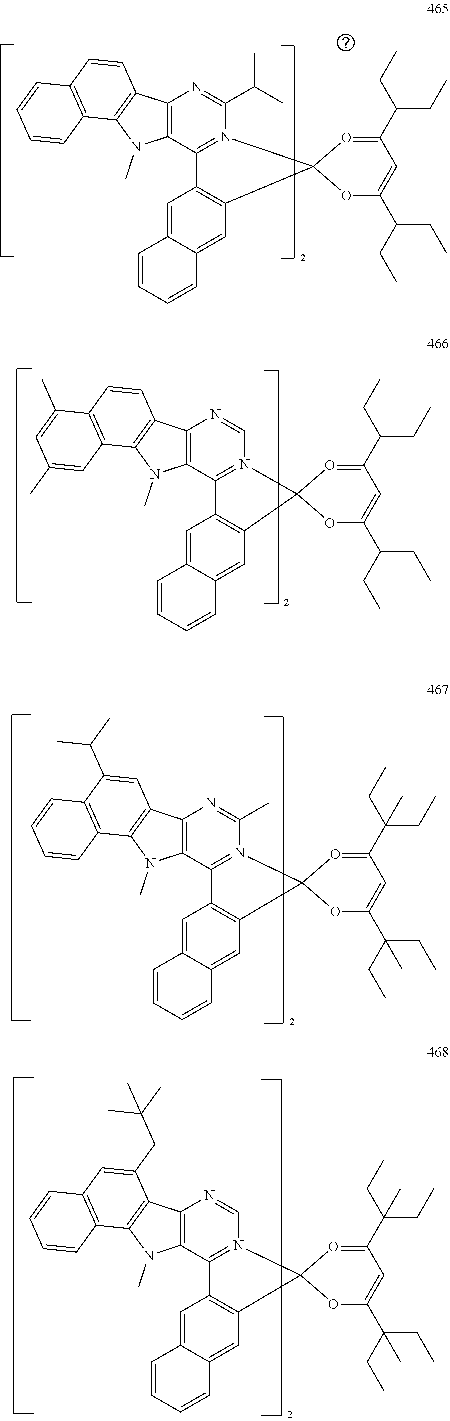

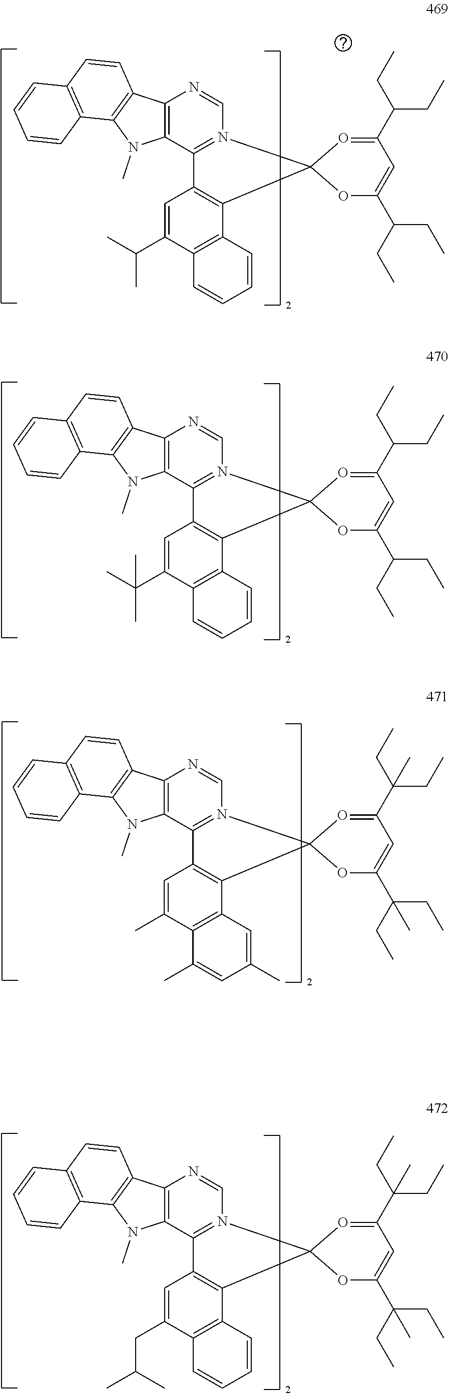

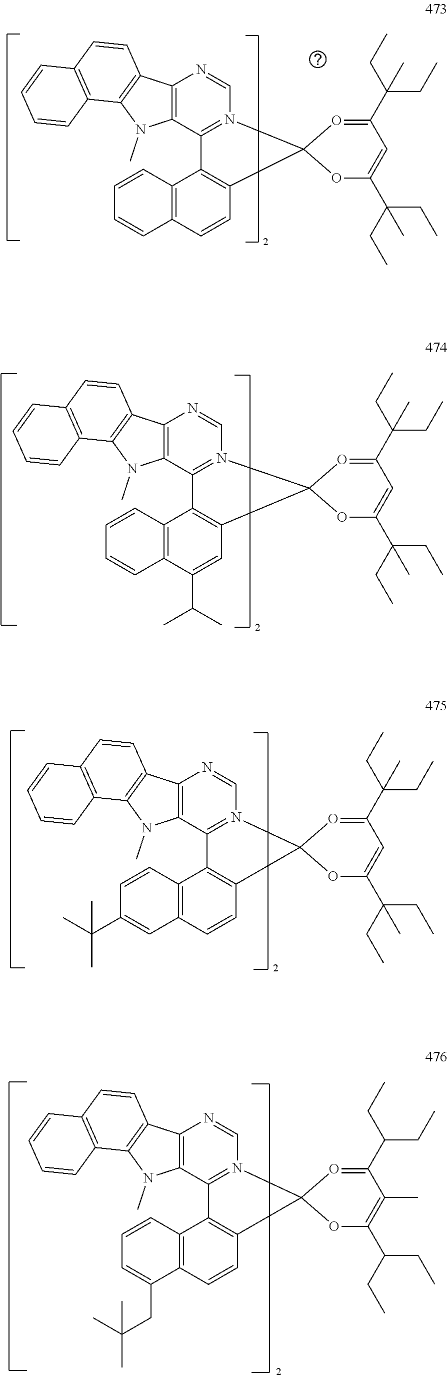

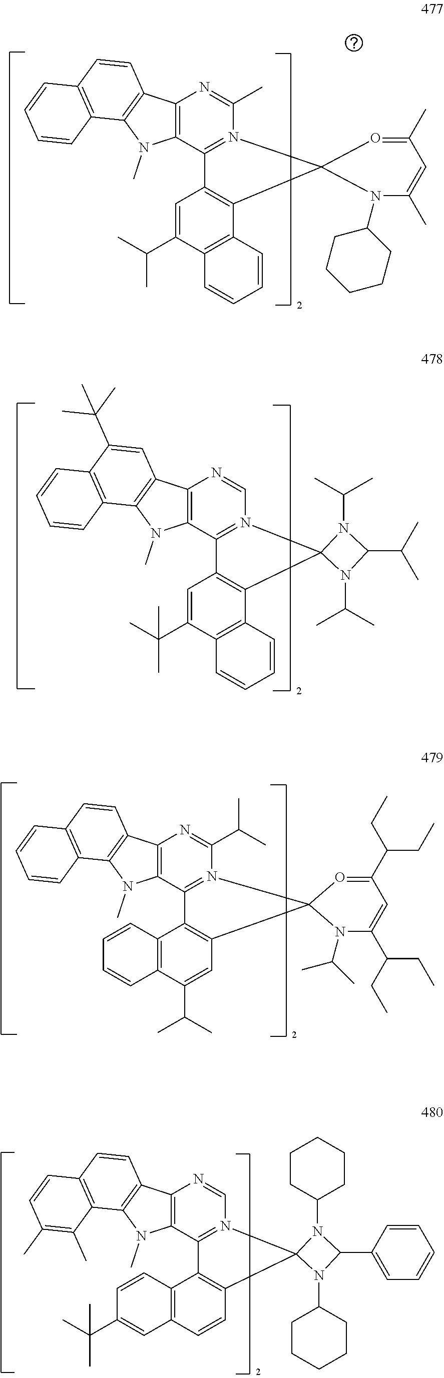

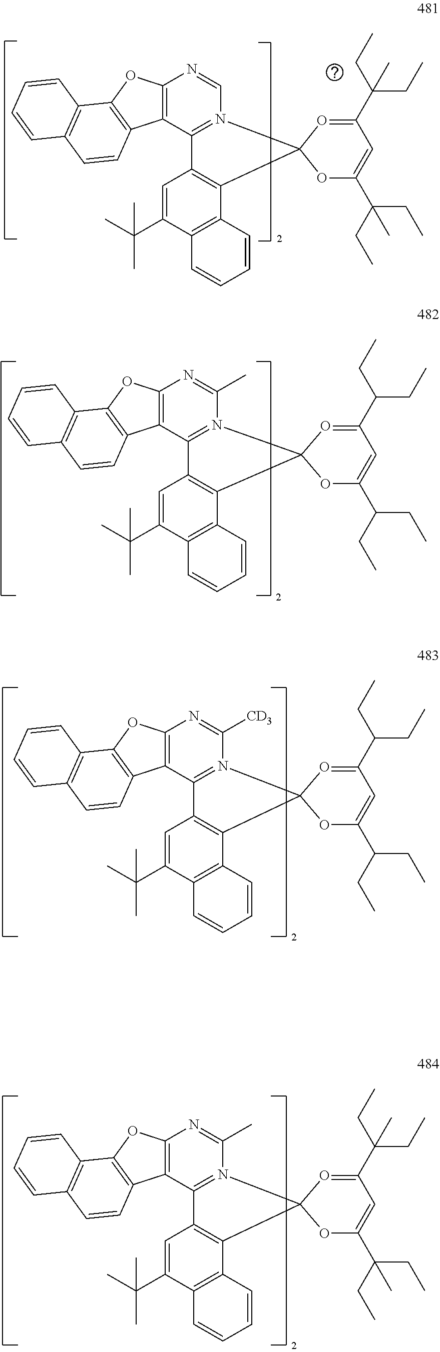

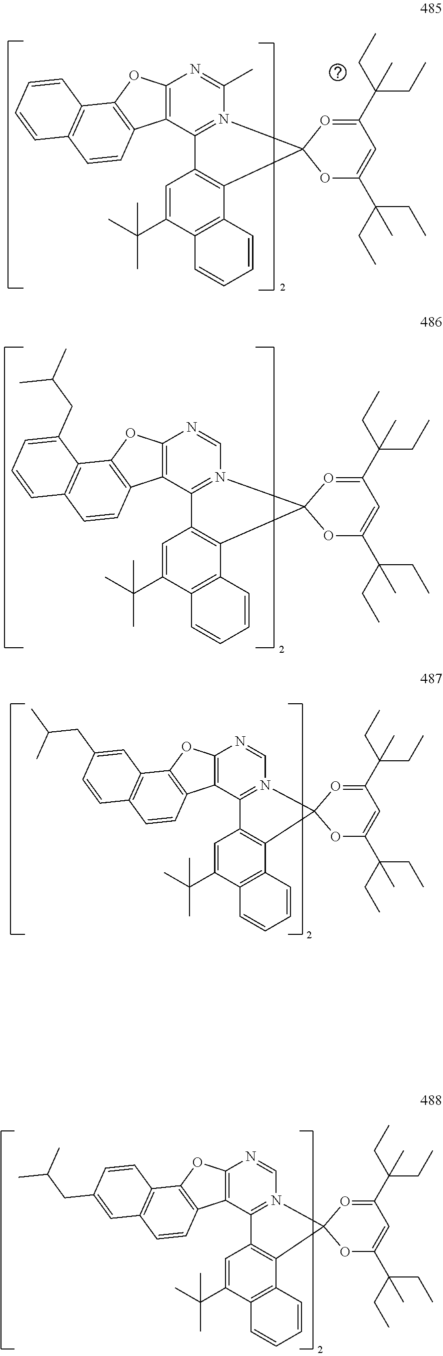

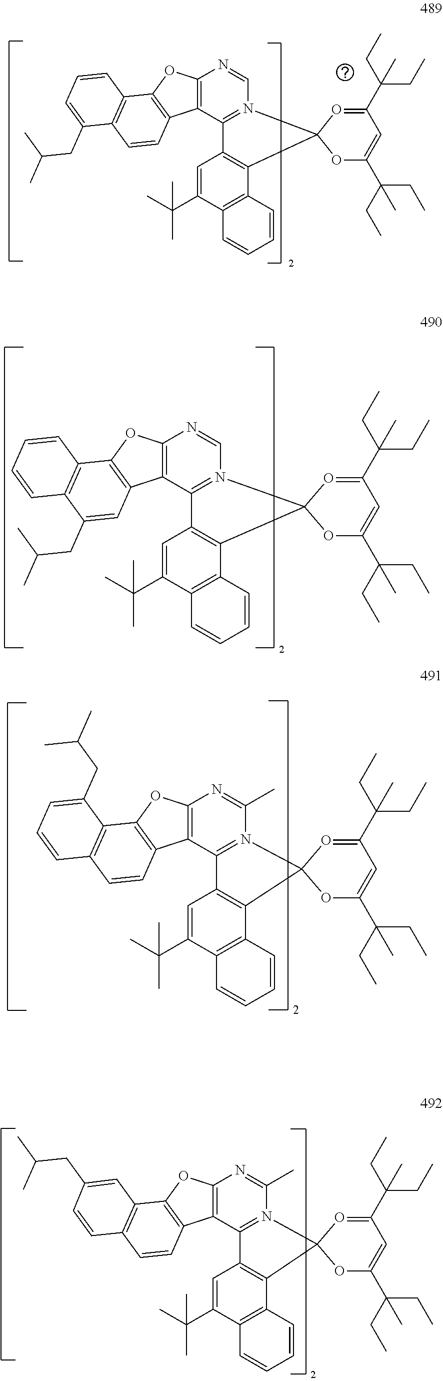

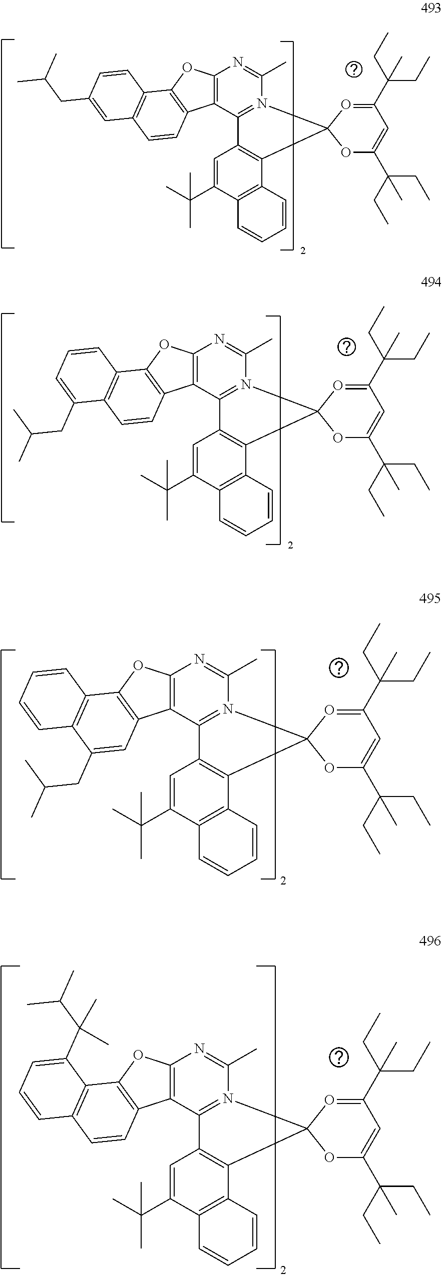

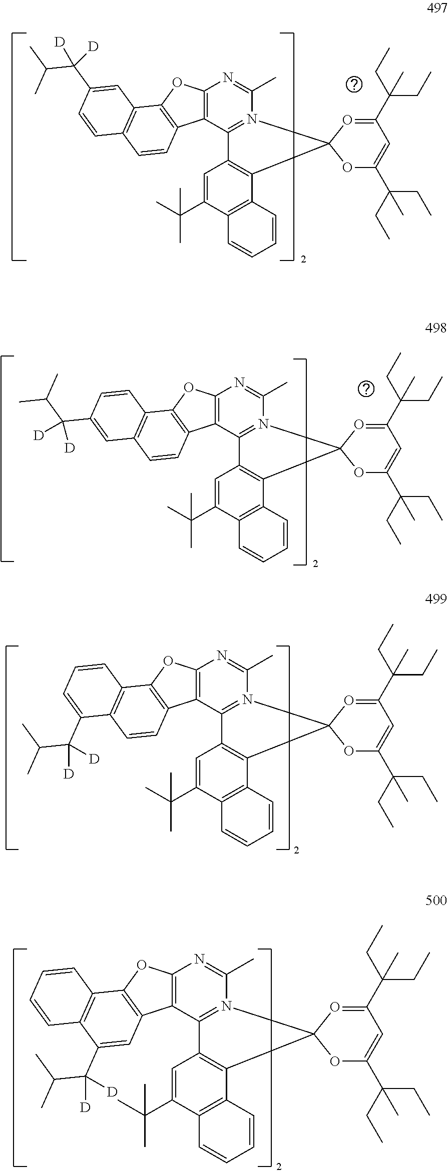

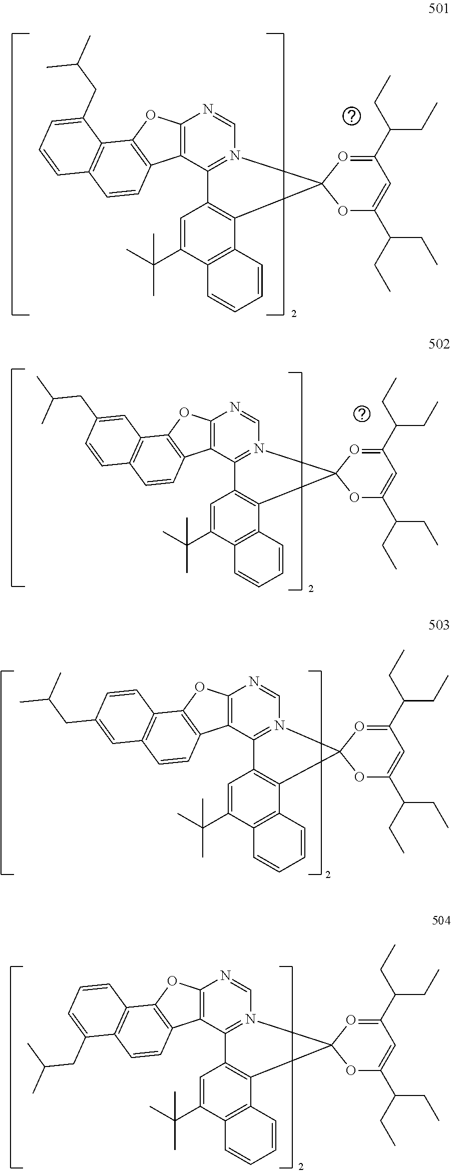

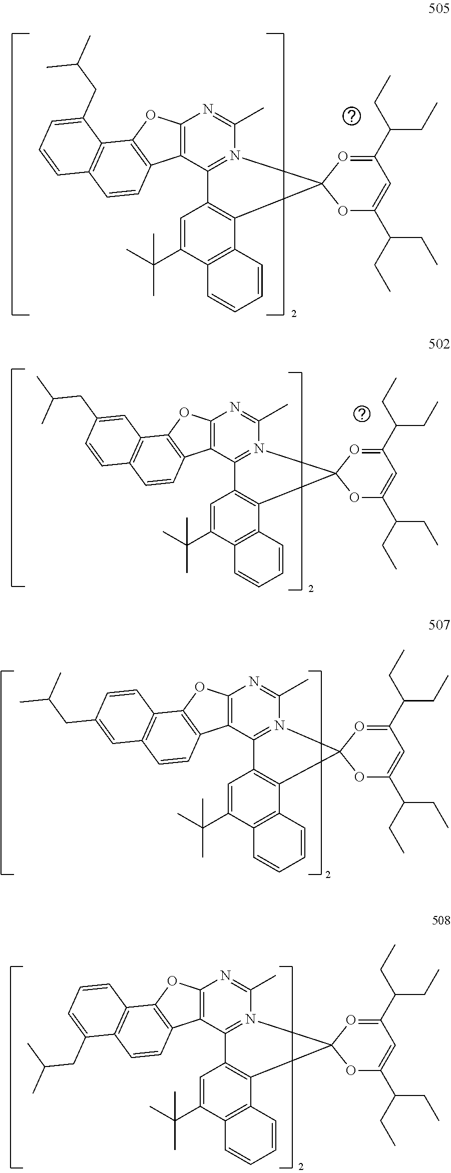

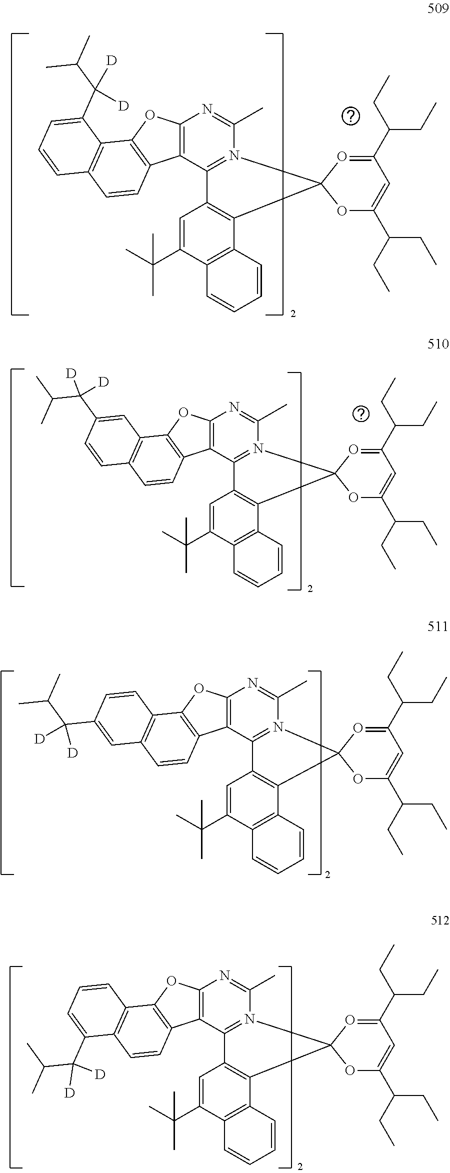

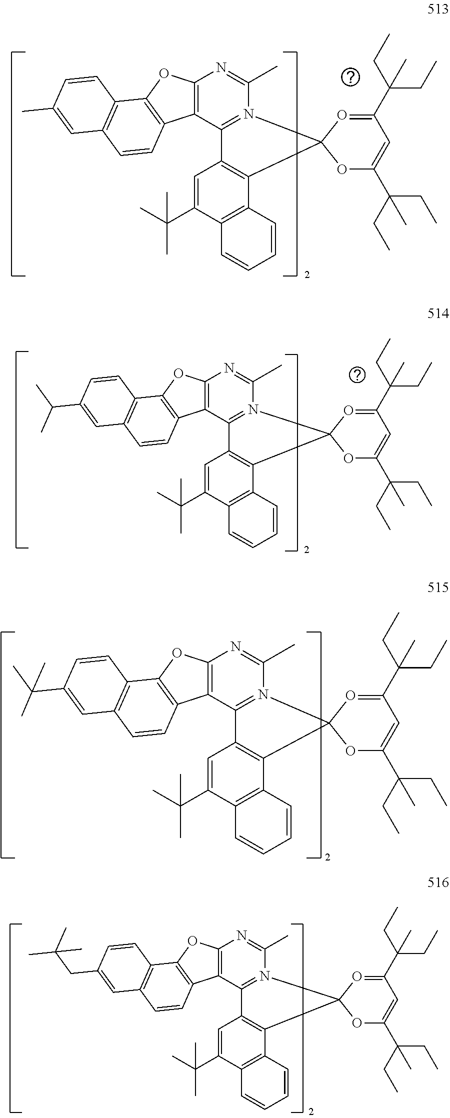

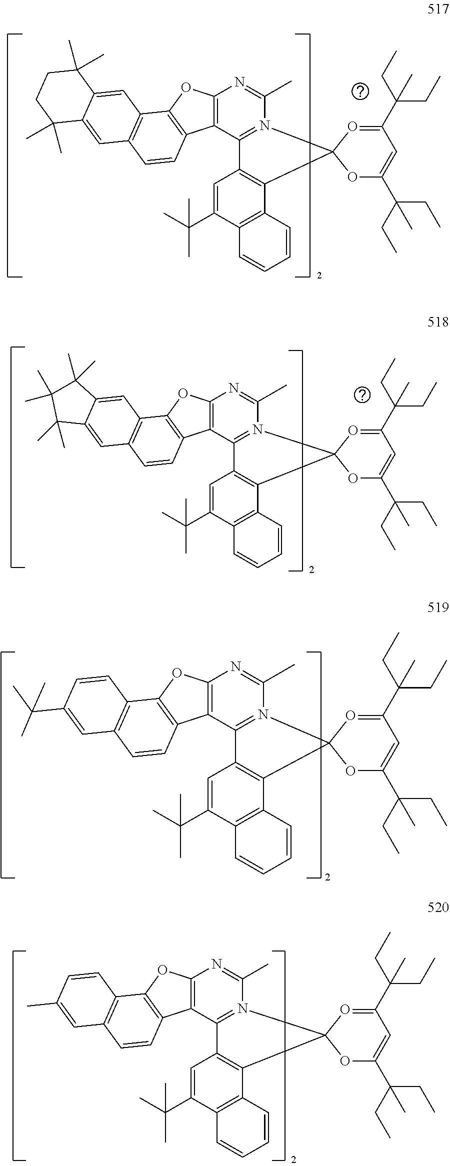

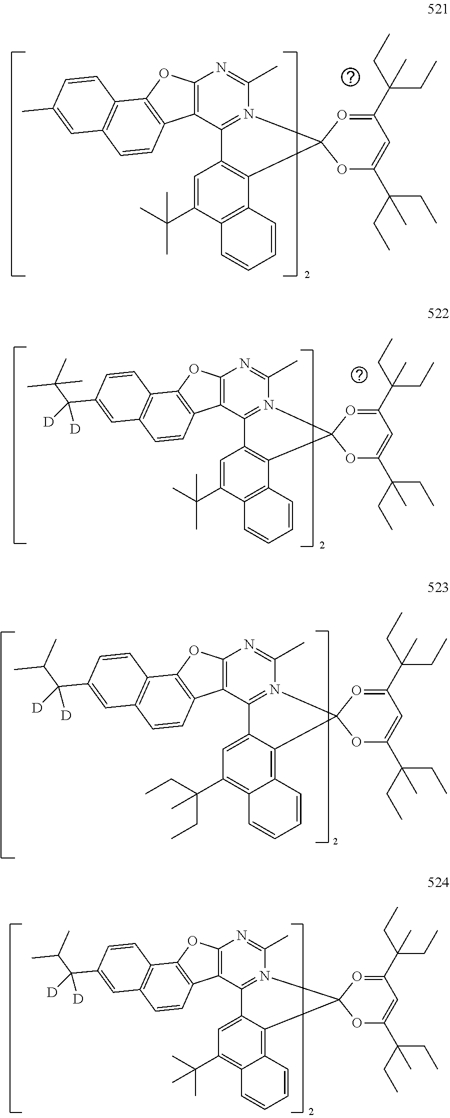

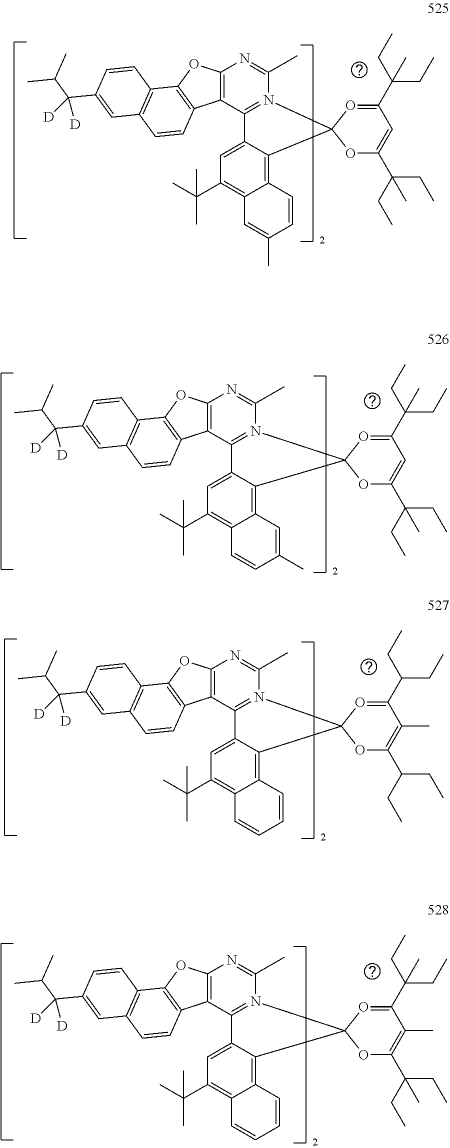

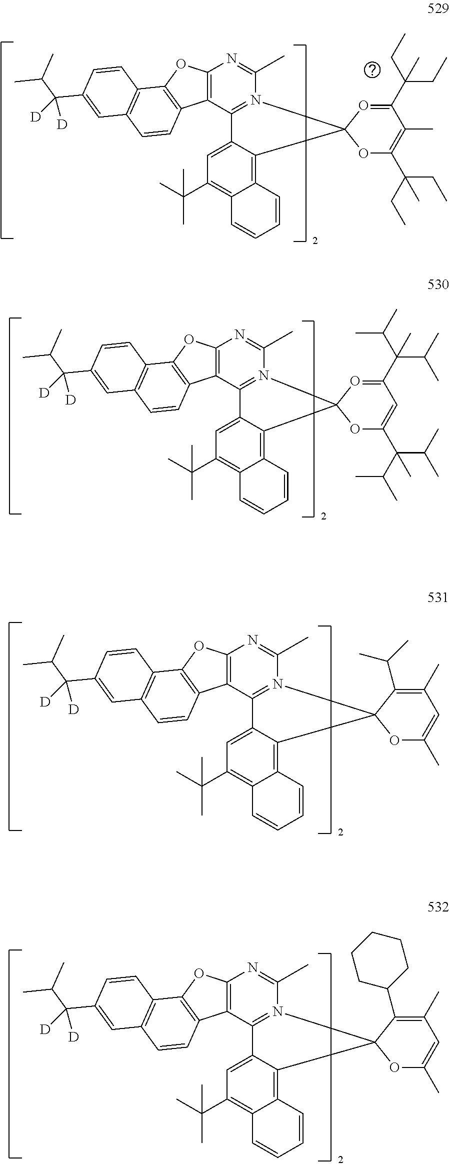

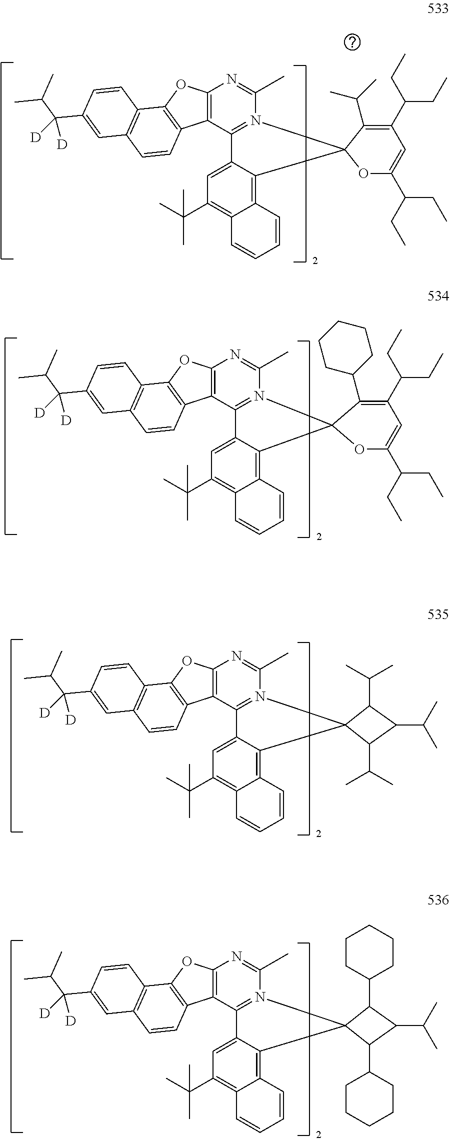

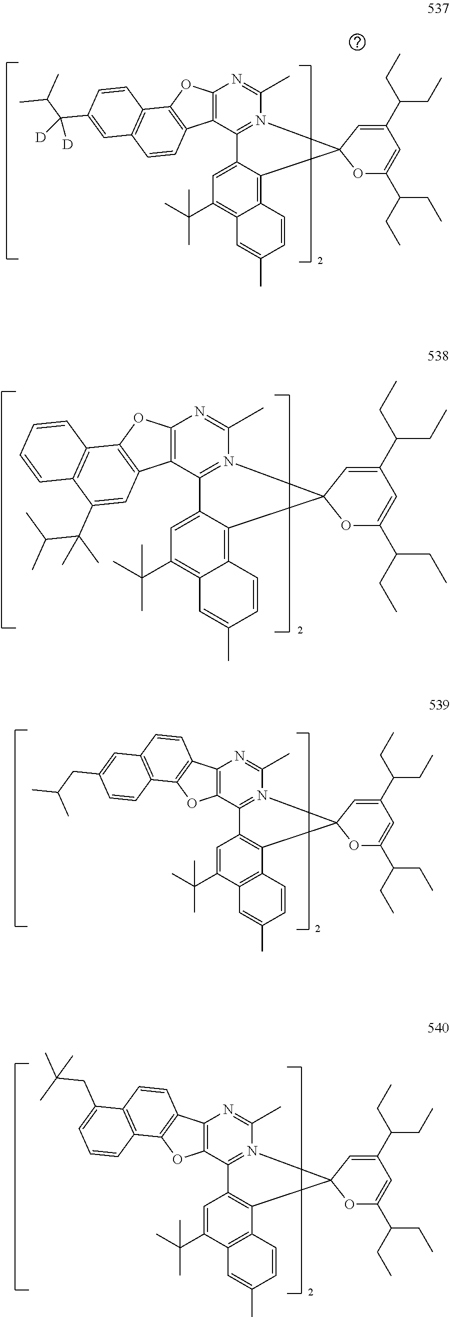

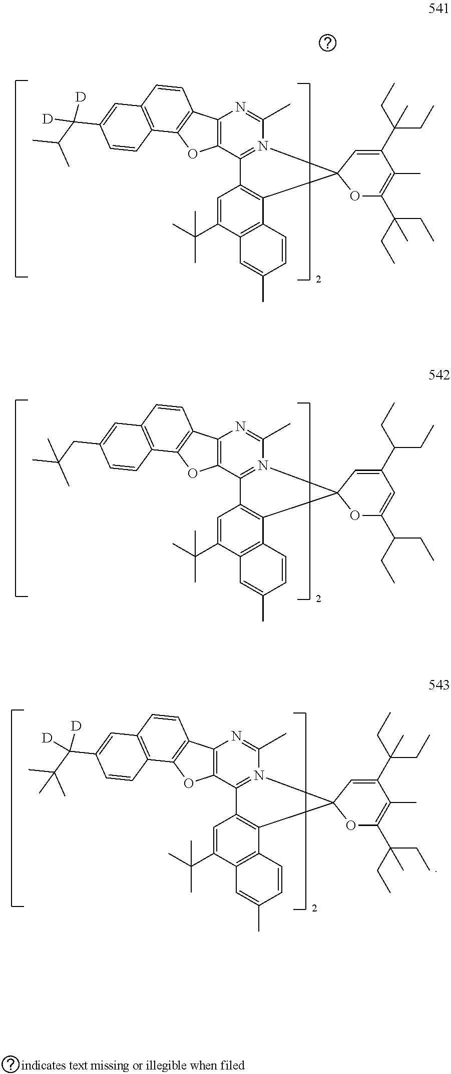

8. An organic light-emitting device comprising:
a first electrode;
a second electrode facing the first electrode; and
an organic layer disposed between the first electrode and the second electrode,
wherein the organic layer comprises a light-emitting layer,
wherein the light emitting layer comprises a dopant material,
wherein the dopant material comprises the organometallic compound according to claim 1.

9. The organic light-emitting device of claim 8, wherein the organometallic compound is one selected from a group consisting of following Chemical Formulas II-1, II-2, III-1, III-2, IV-1, and IV-2: 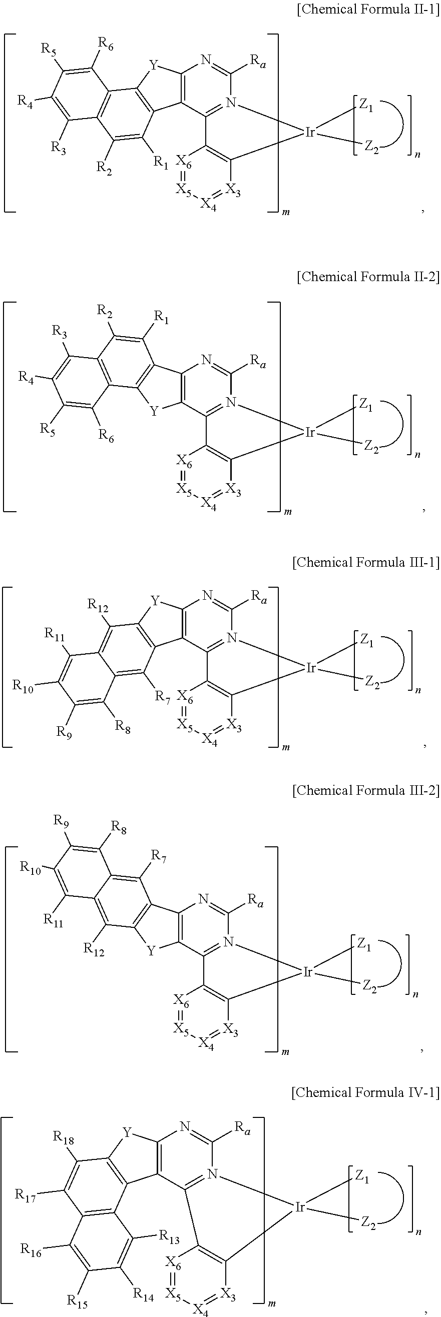 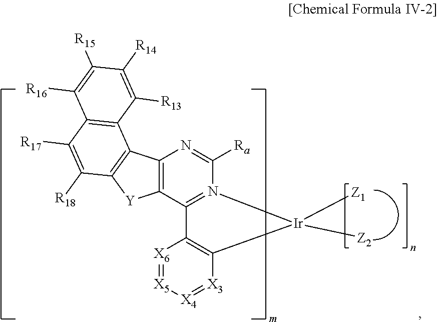
wherein in each of the Chemical Formulas II-1, II-2, III-1, III-2, IV-1 and IV-2,
Rₐ is one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;
each of X₃ to X₆ independently is one selected from CR_{b} and N;
optionally, two R_{b} on the adjacent two of X₃ to X₆ may be connected to each other to form a ring structure comprising one selected from a group consisting of a substituted or unsubstituted C3-C20 cycloalkyl group, a substituted or unsubstituted C2-C20 heterocycloalkyl group, a substituted or unsubstituted C7-C20 arylalkyl group, a substituted or unsubstituted C2-C20 heteroarylalkyl group, a substituted or unsubstituted C3-C20 cycloalkenyl group, a substituted or unsubstituted C6-C30 aryl group, and a substituted or unsubstituted C3-C30 heteroaryl group,
R_{b} represents one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;
(Z₁-Z₂) represents a bidentate ligand;
m is an integer selected from 1, 2 or 3, n is an integer selected from 0, 1 or 2, wherein a sum of m and n is an oxidation number of the metal M;
Y is one selected from a group consisting of BR₁₉, CR₁₉R₂₀, C═O, CNR₁₉, SiR₁₉R₂₀, NR₁₉, PR₁₉, AsR₁₉, SbR₁₉, P(O)R₁₉, P(S)R₁₉, P(Se)R₁₉, As(O)R₁₉, As(S)R₁₉, As(Se)R₁₉, Sb(O)R₁₉, Sb(S)R₁₉, Sb(Se)R₁₉, O, N, S, Se, Te, SO, SO₂, SeO, SeO₂, TeO, and TeO₂;
each of R₁ to R₁₈ is independently one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group; and
each of R₁₉ and R₂₀ is independently one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group.

10. The organic light-emitting device of claim 8, wherein the organometallic compound is selected from the following compounds 1 to 543:

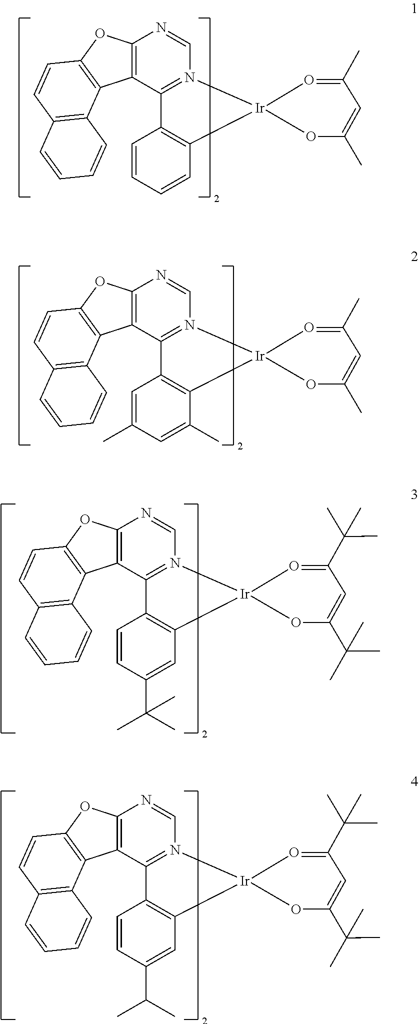

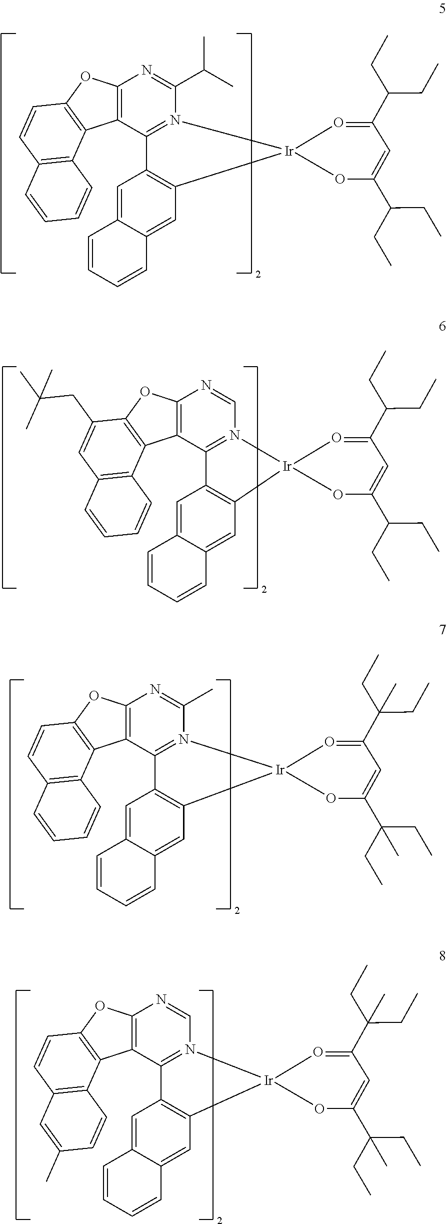

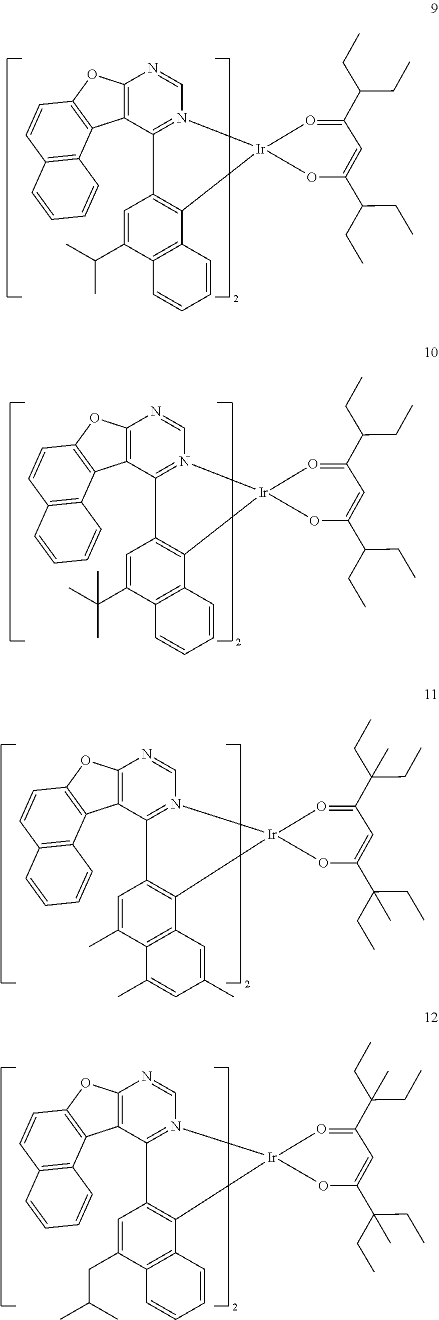

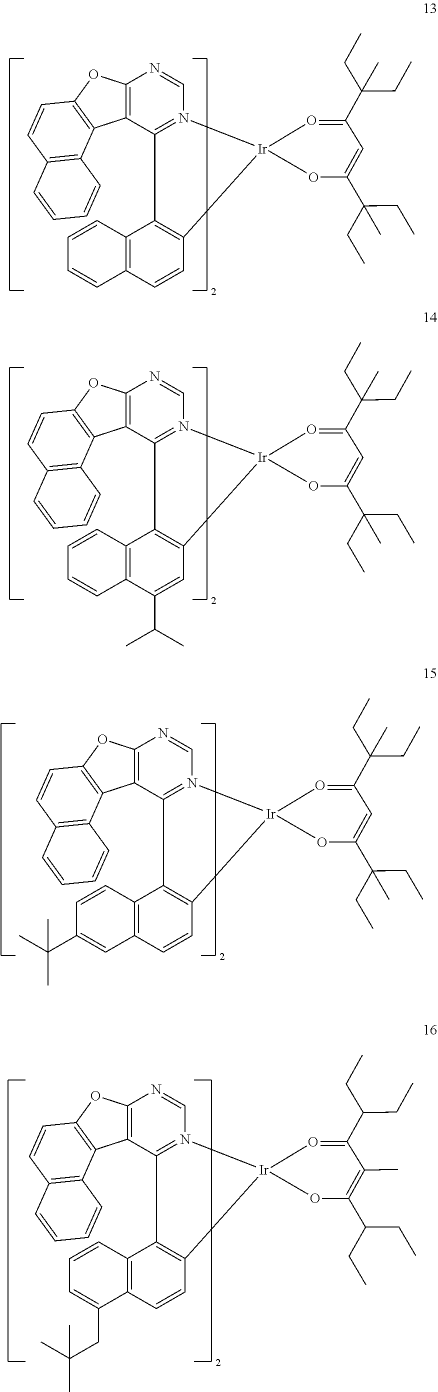

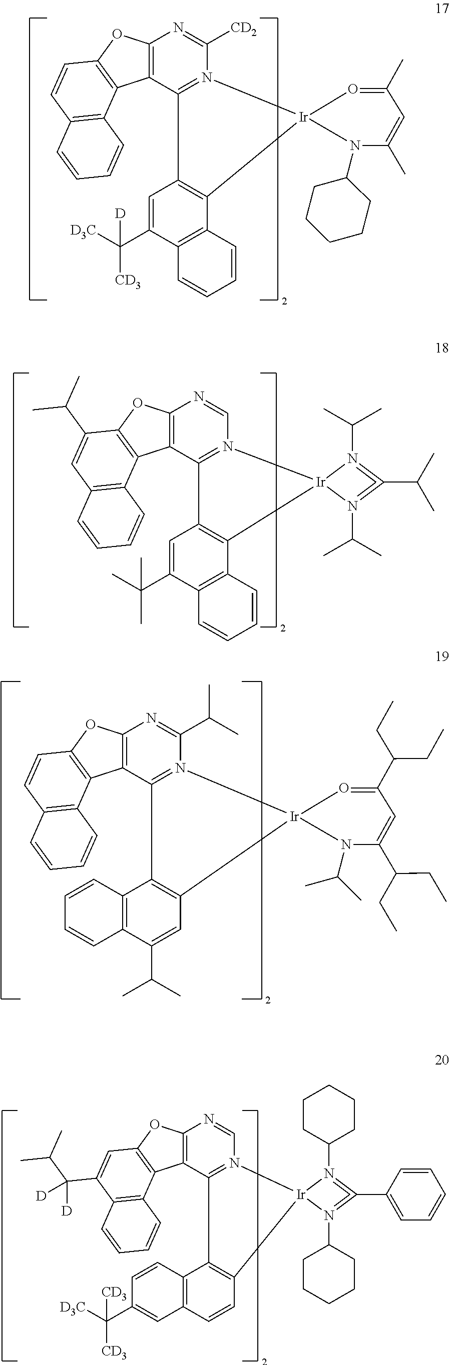

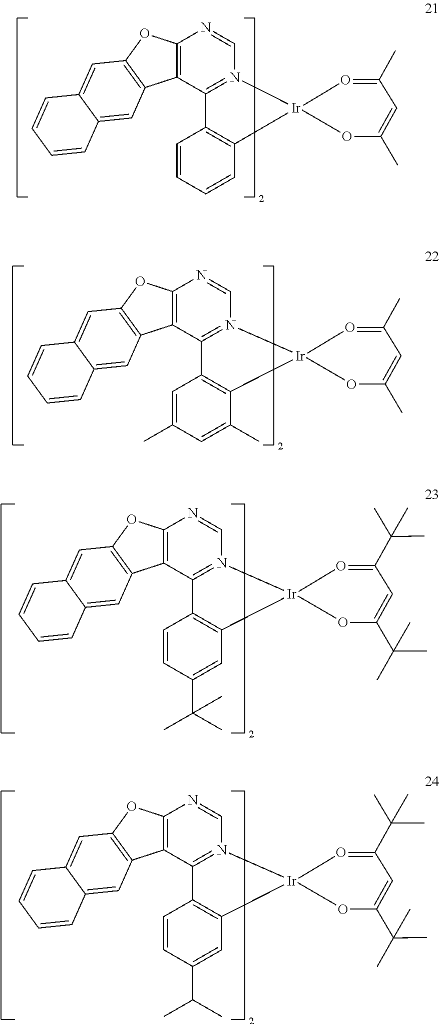

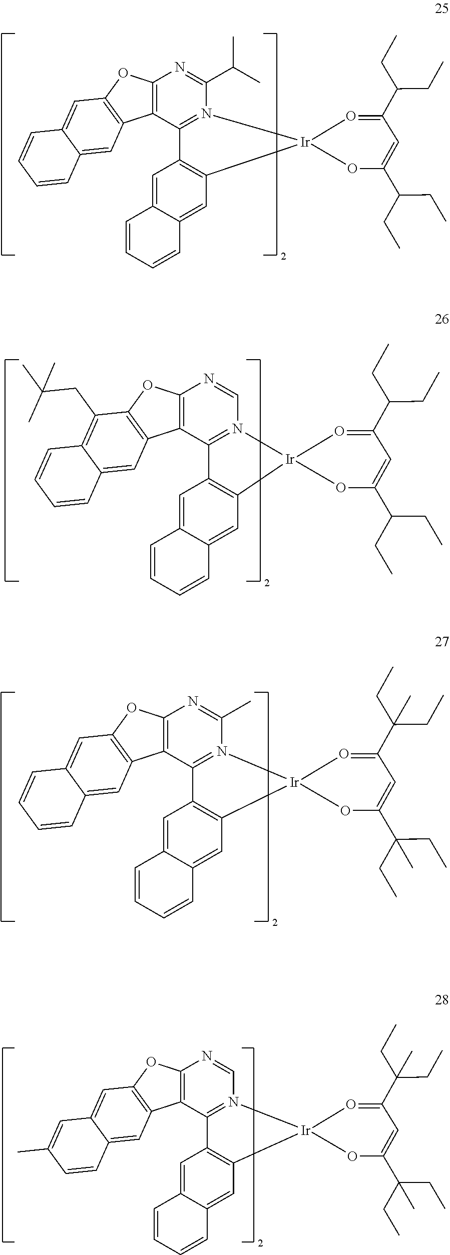

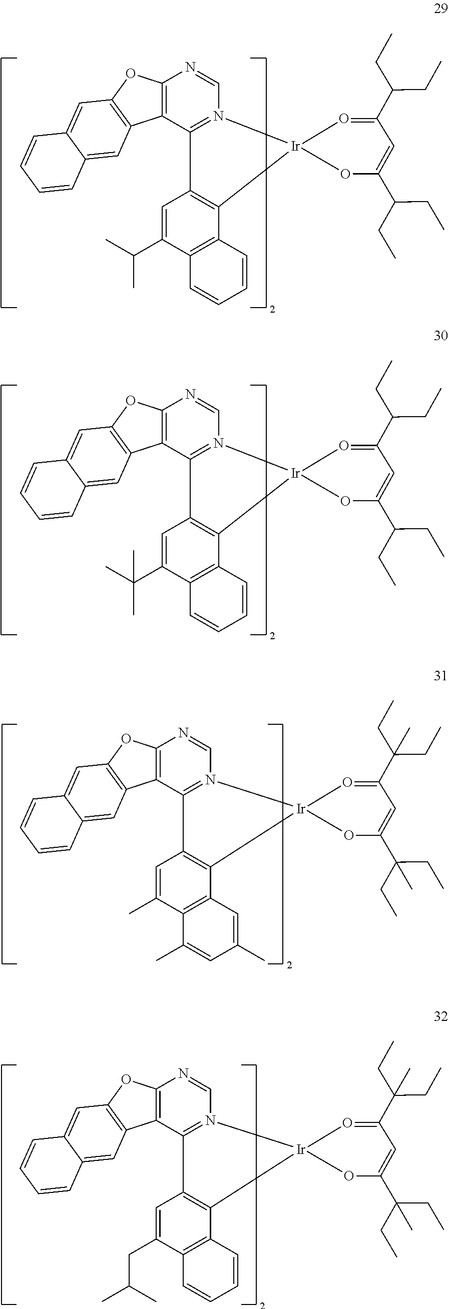

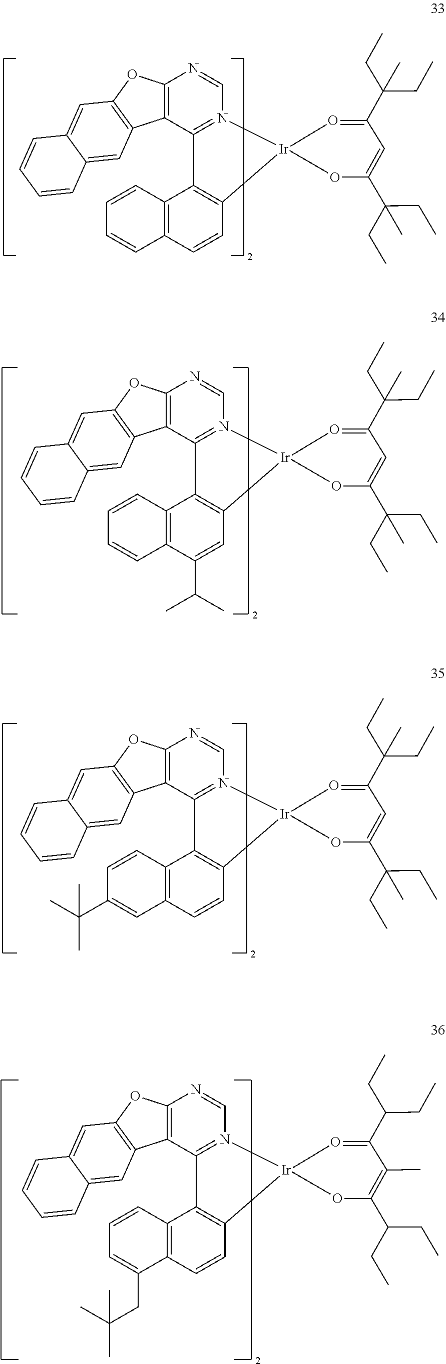

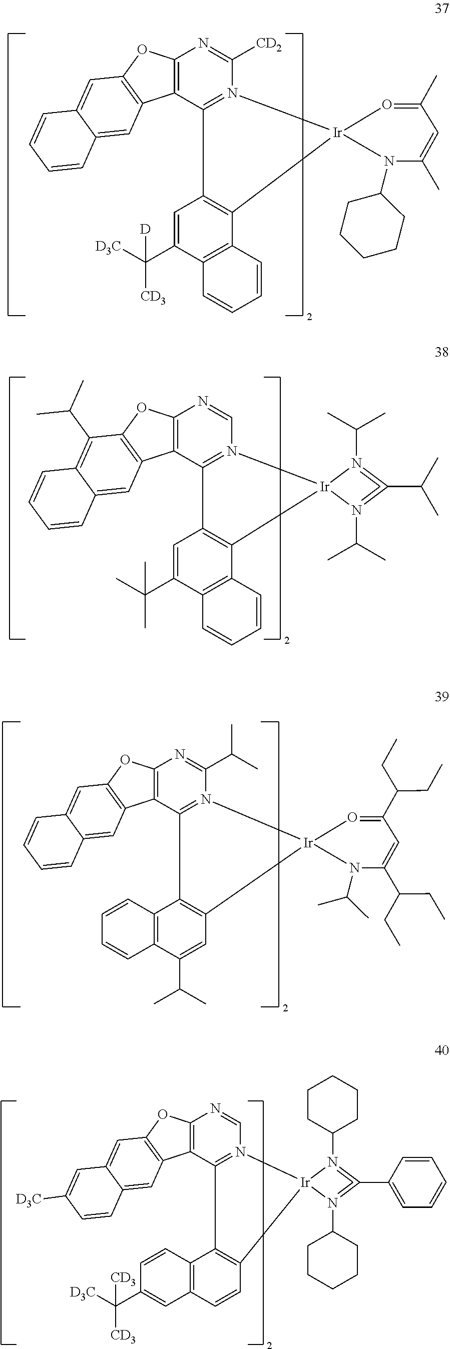

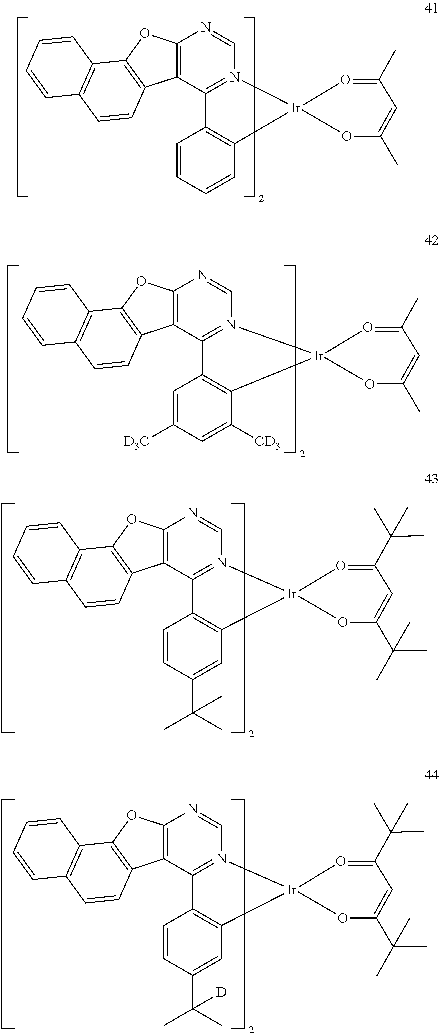

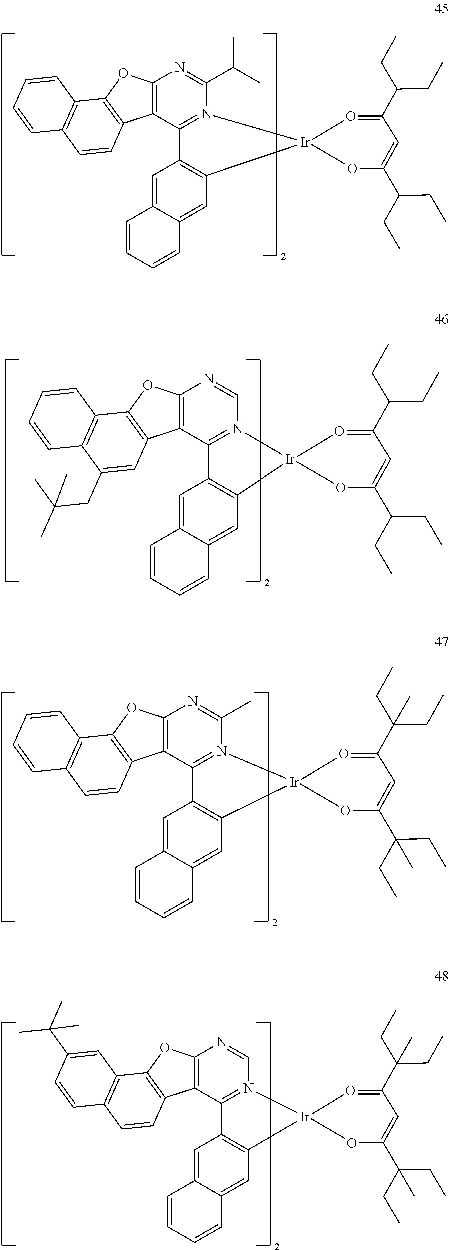

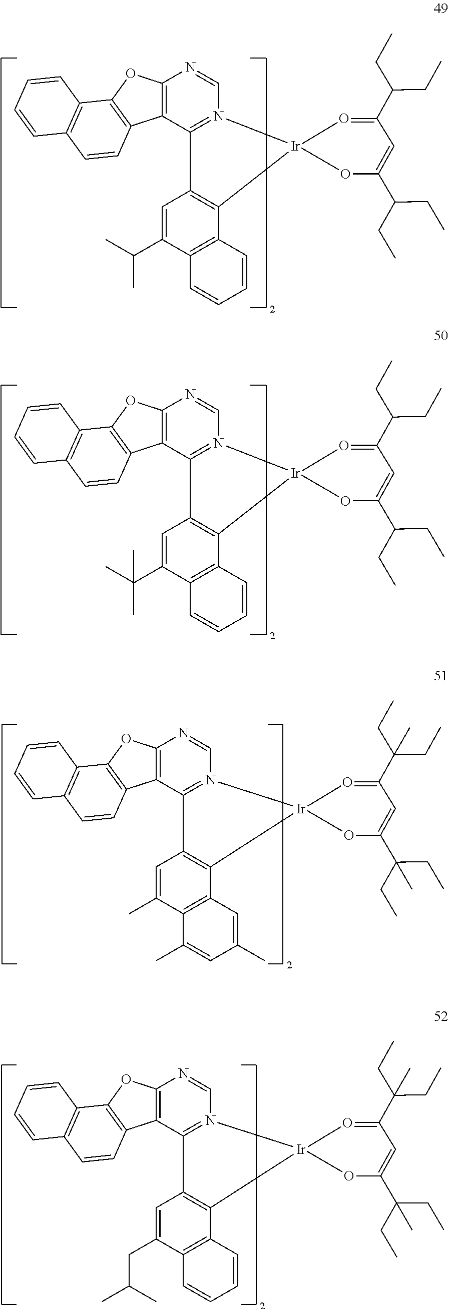

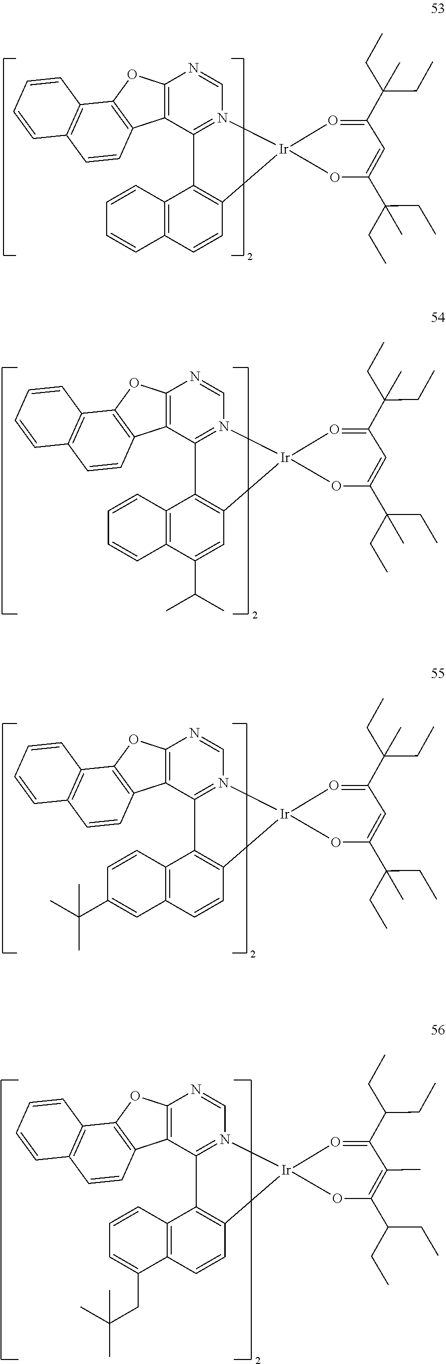

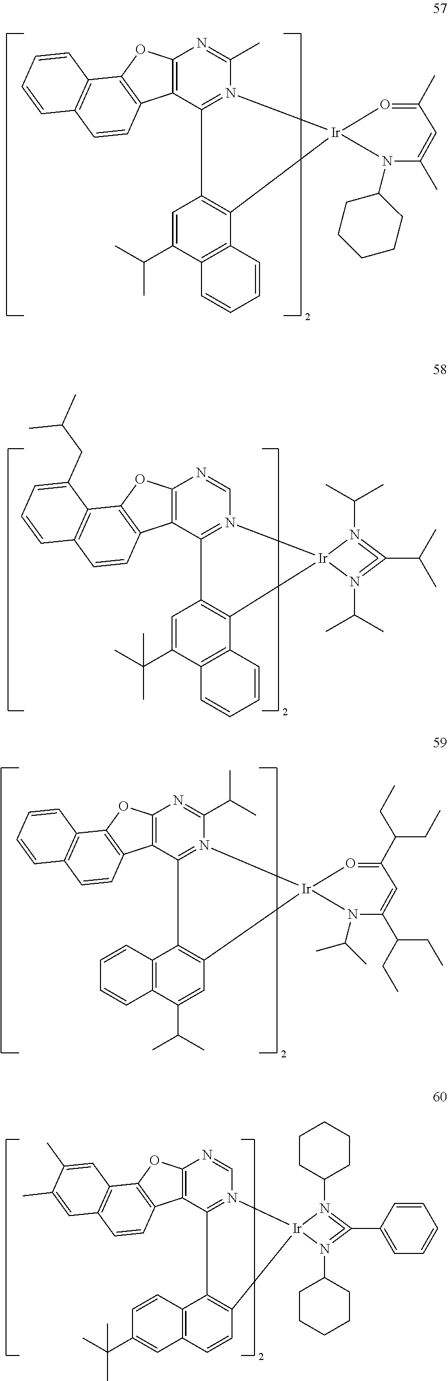

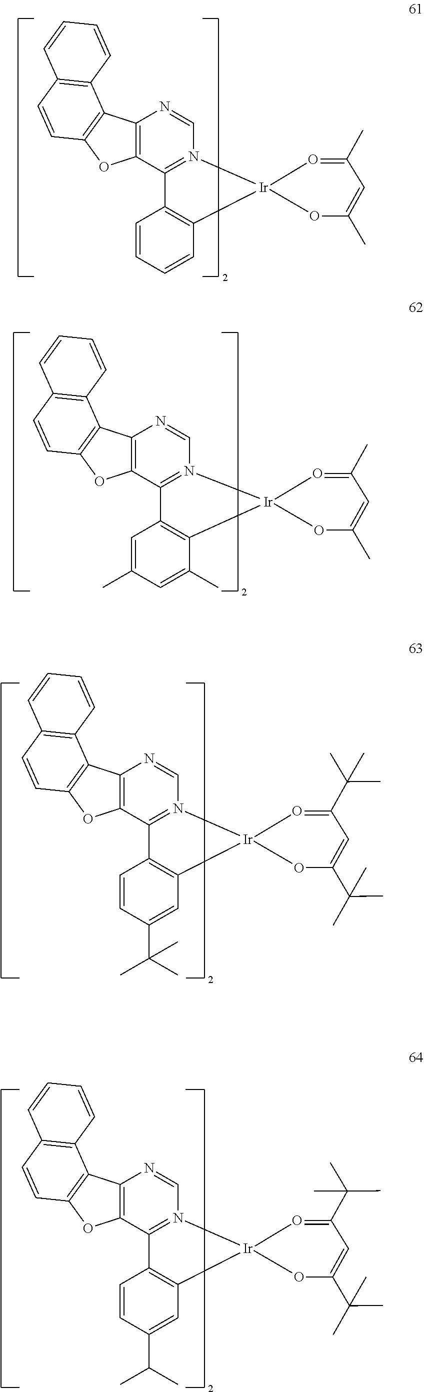

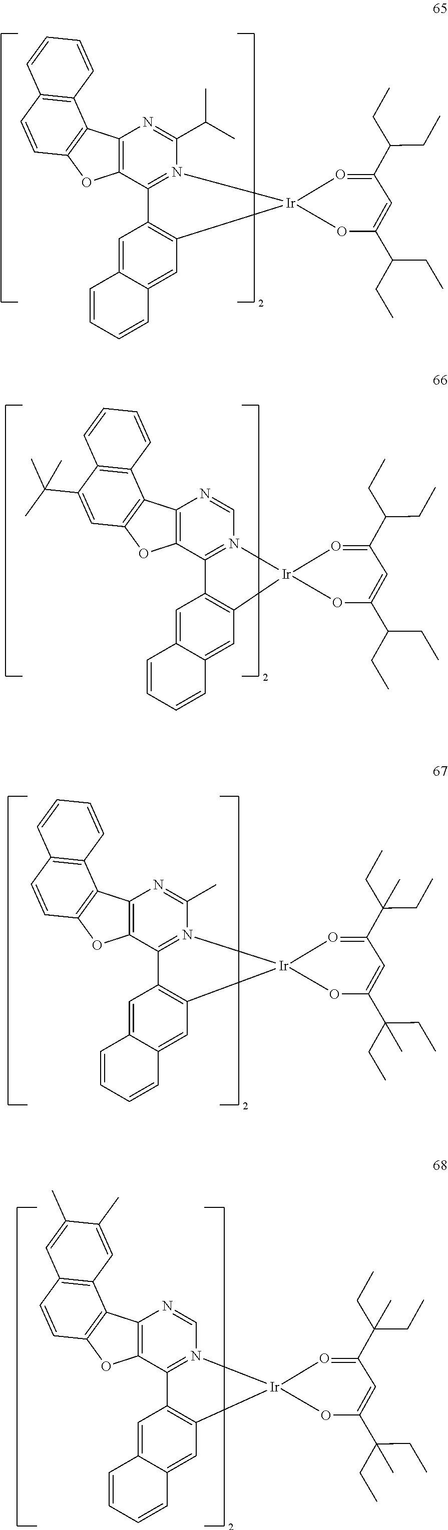

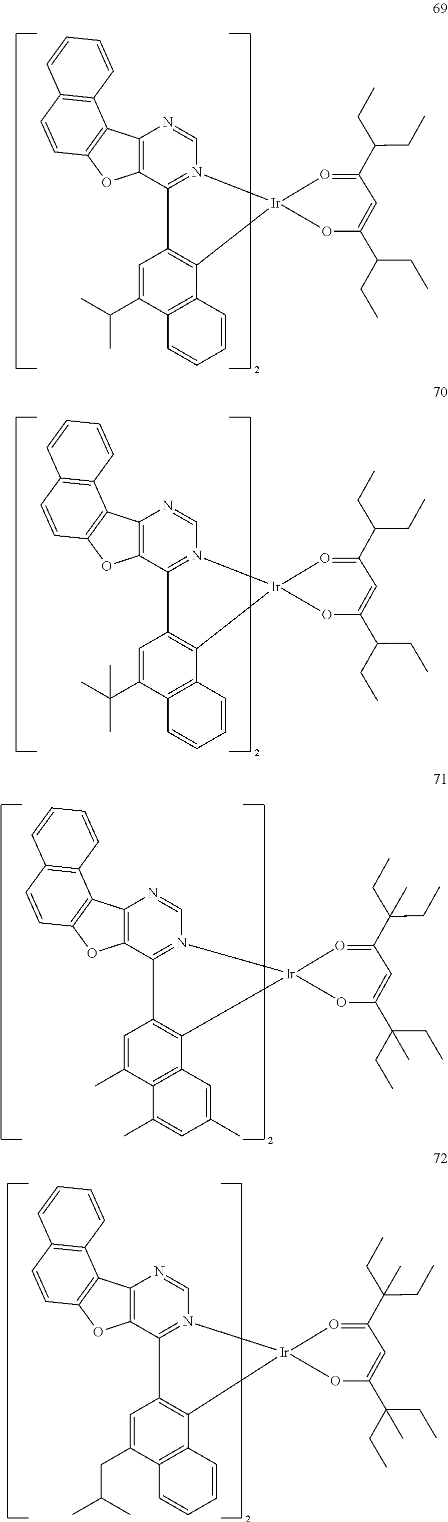

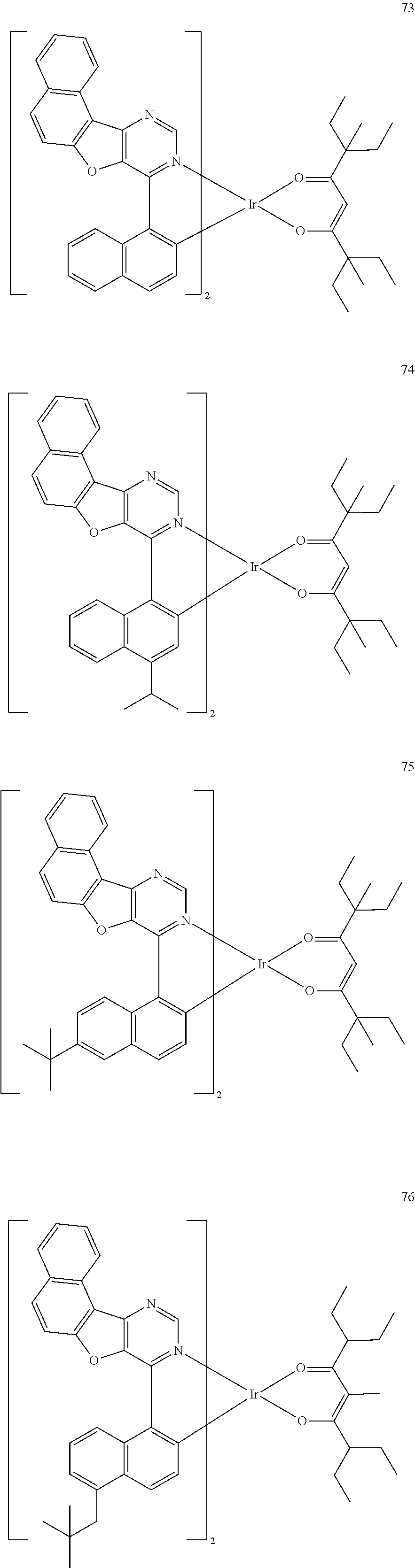

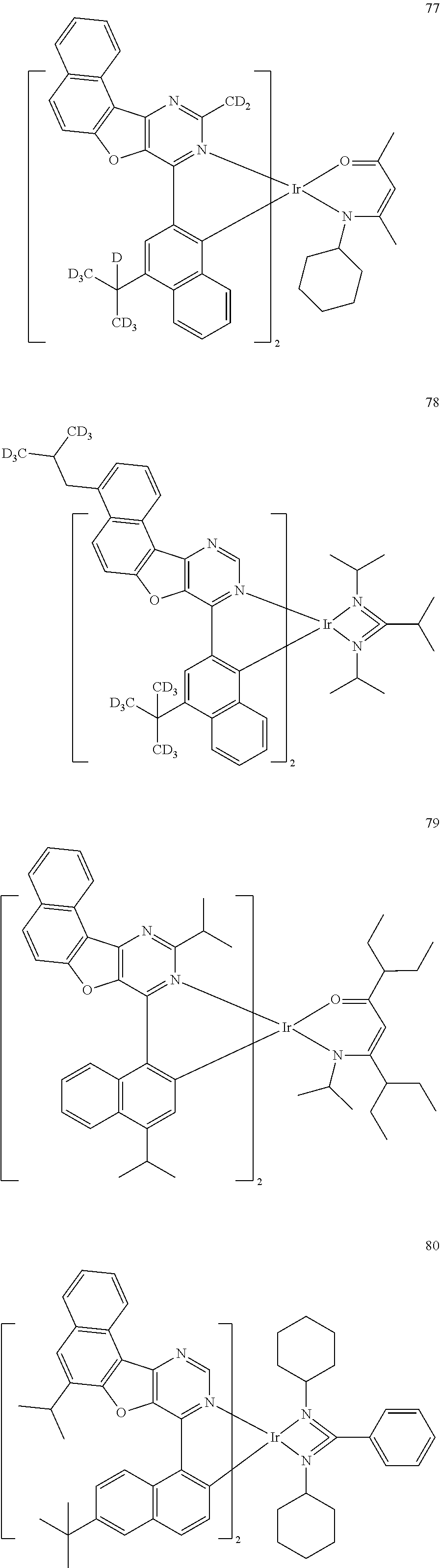

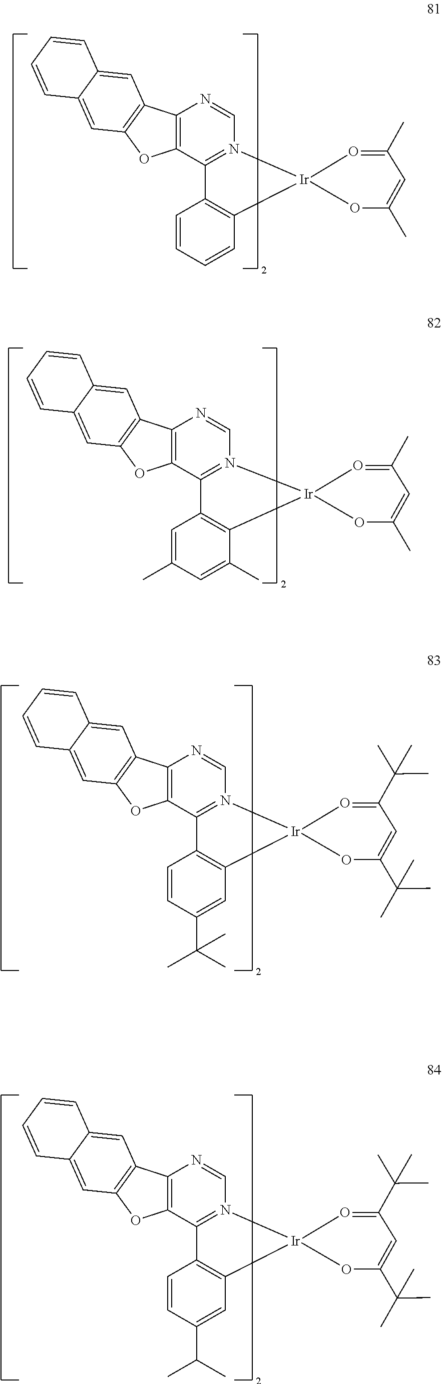

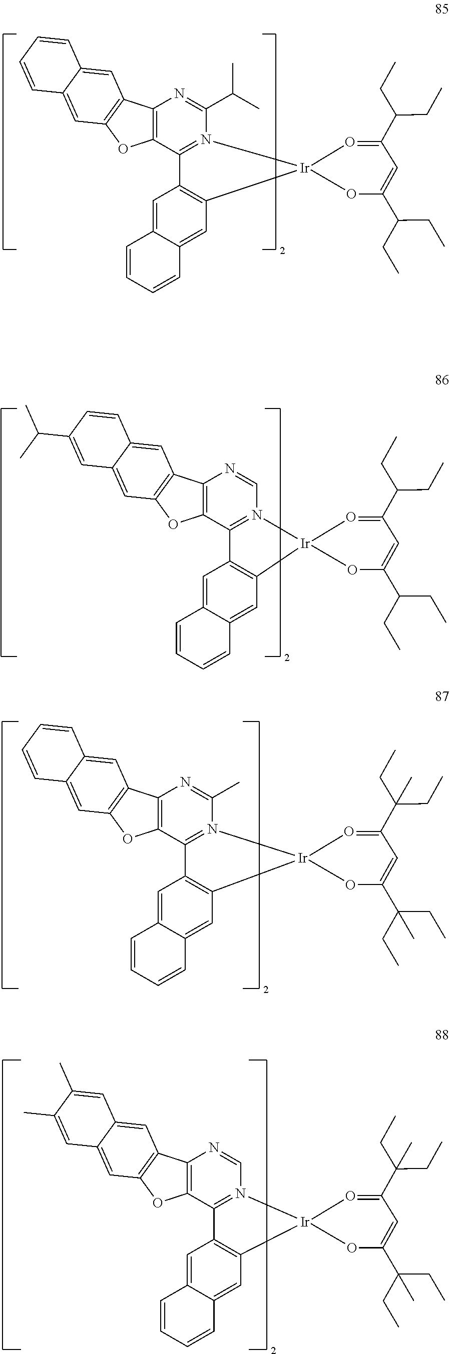

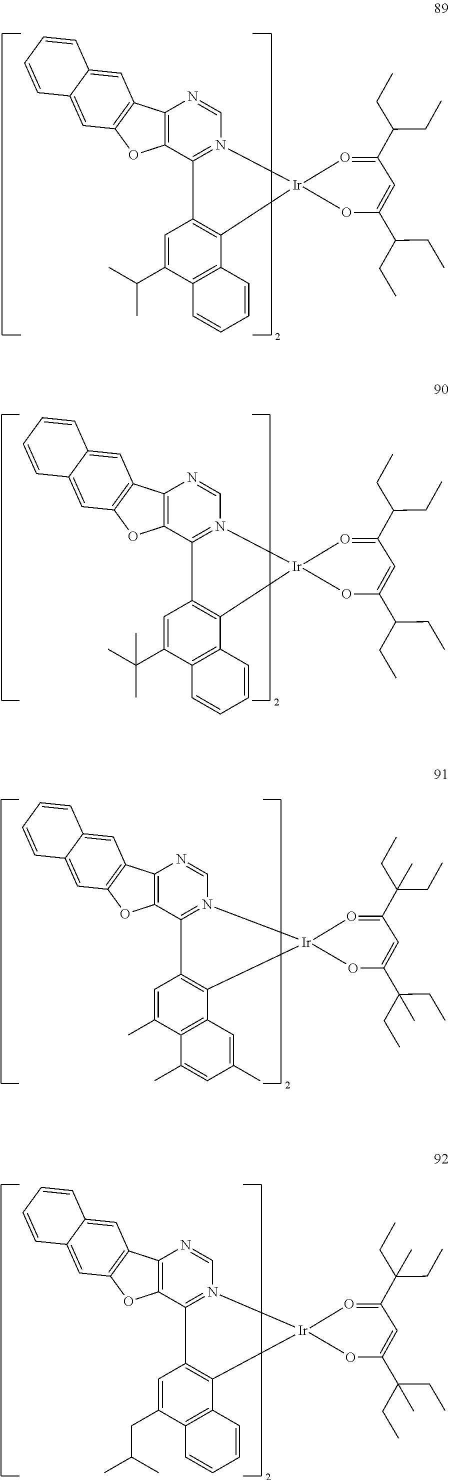

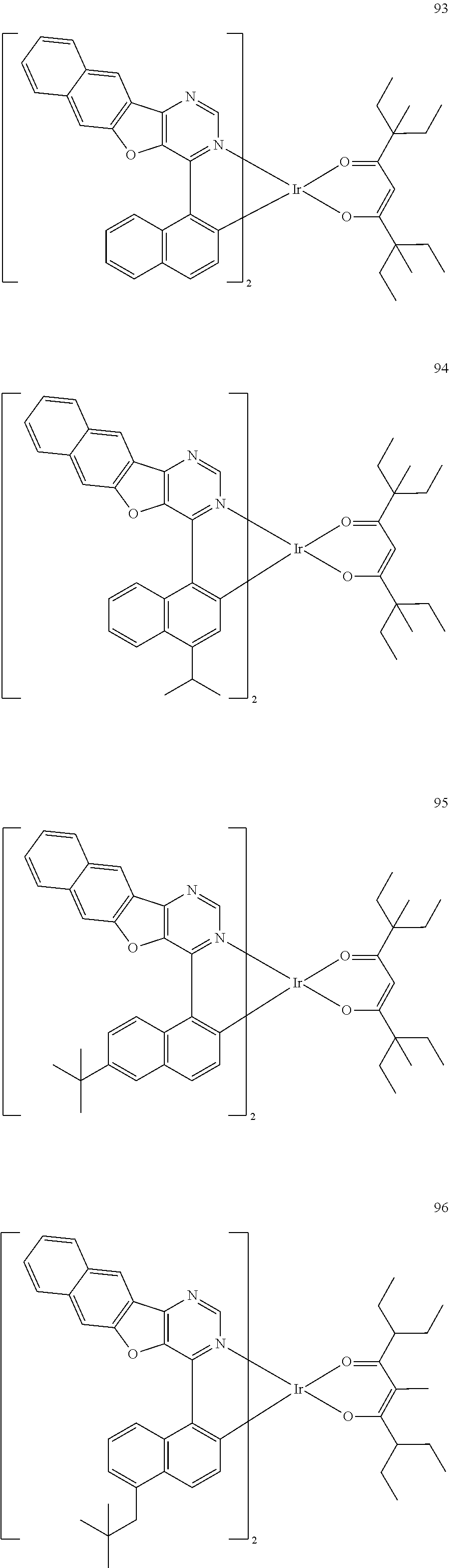

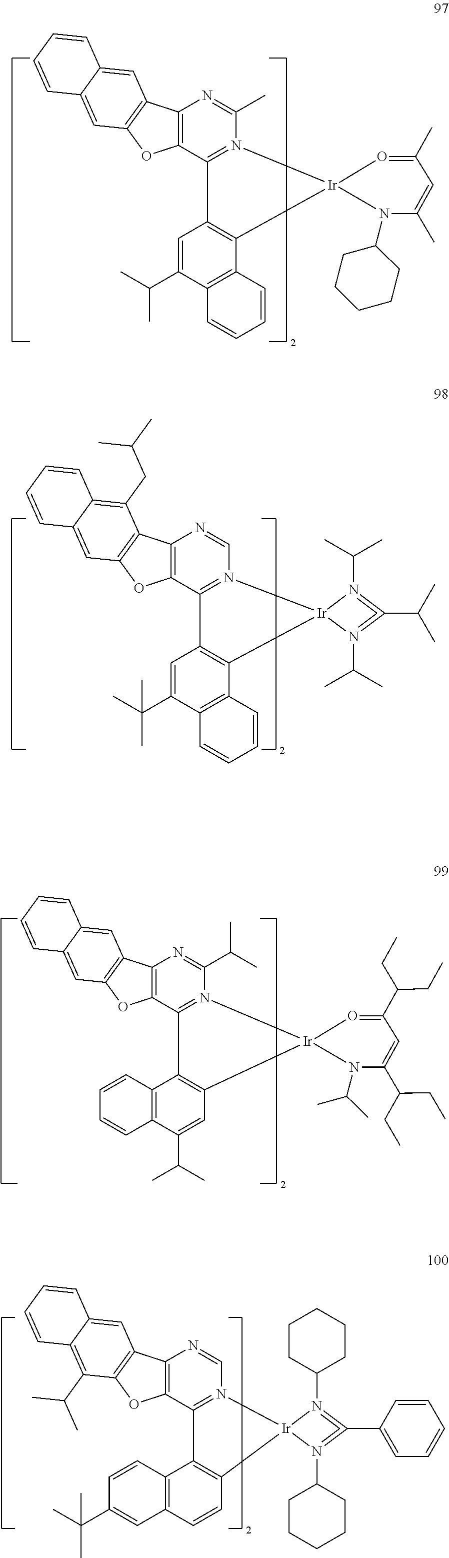

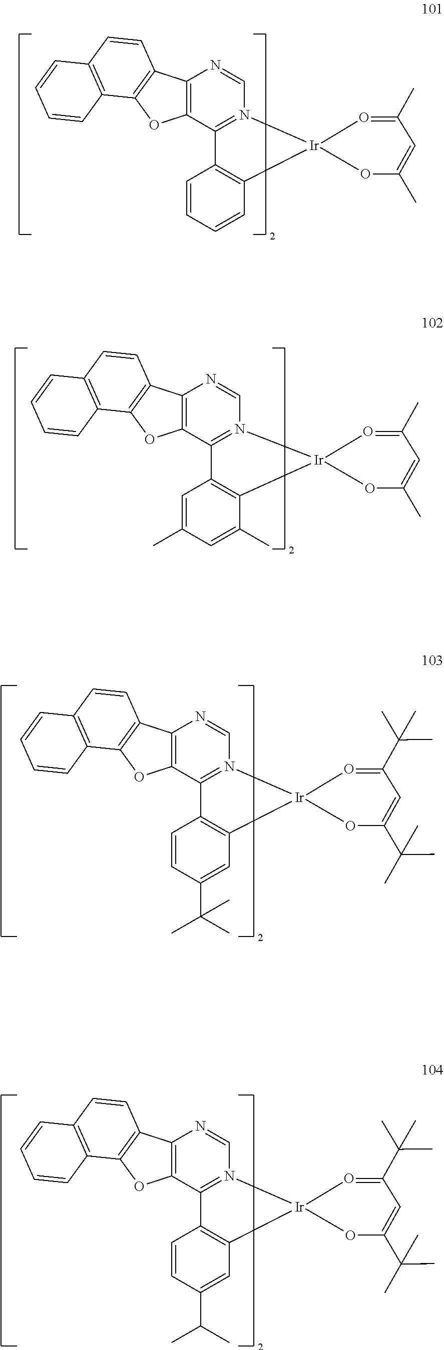

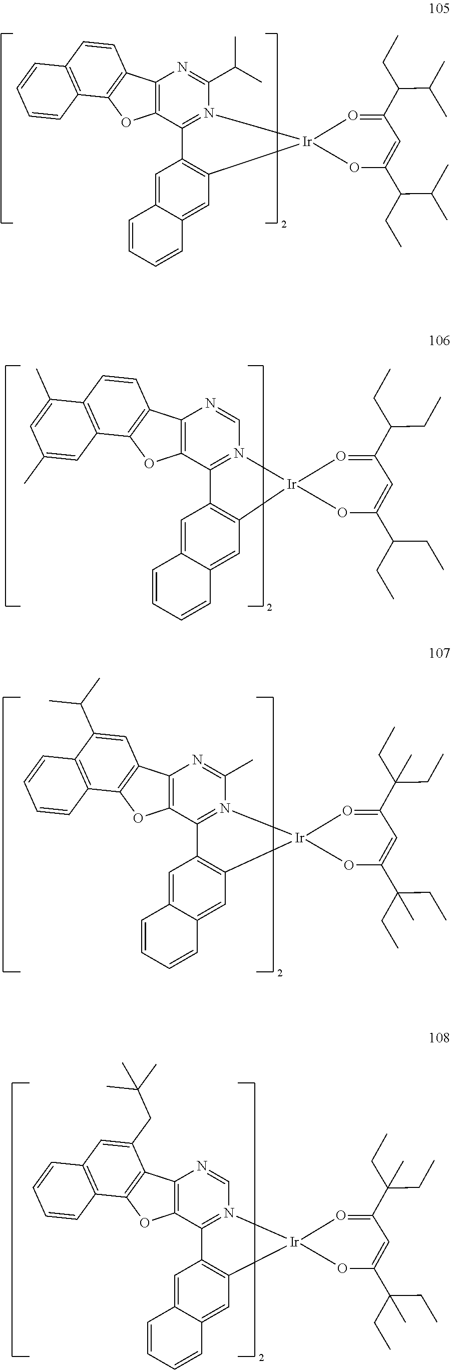

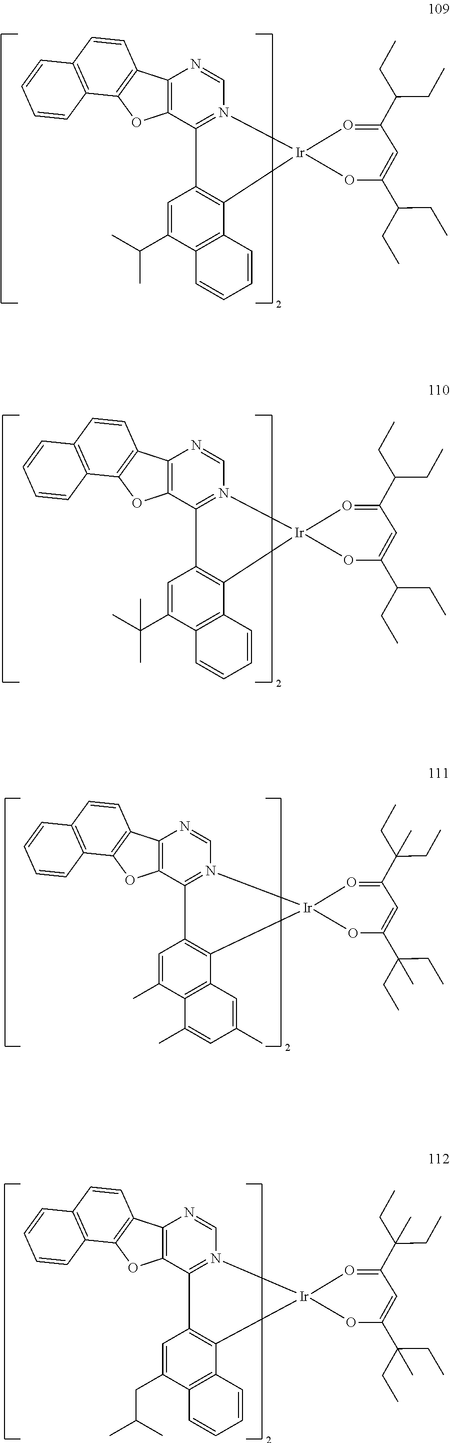

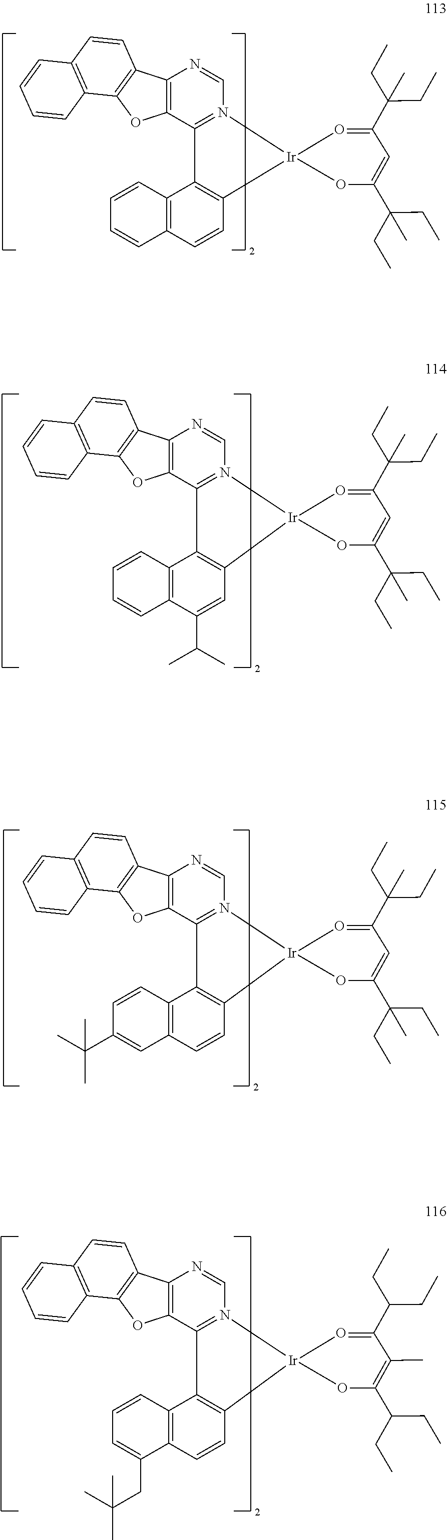

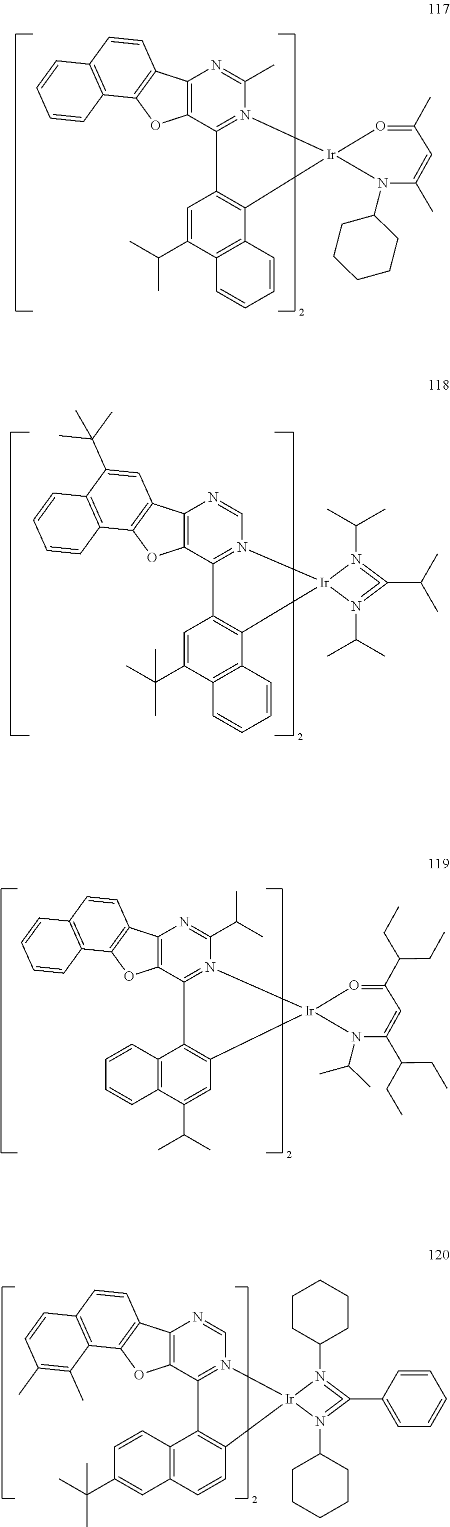

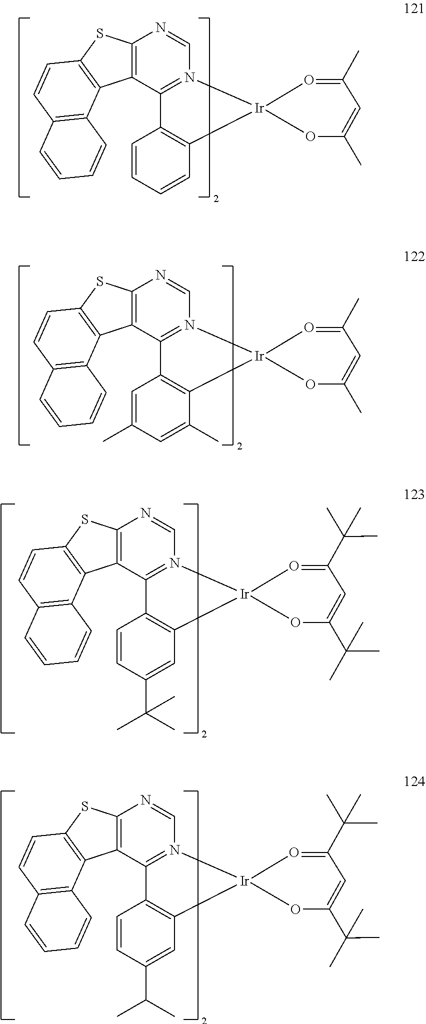

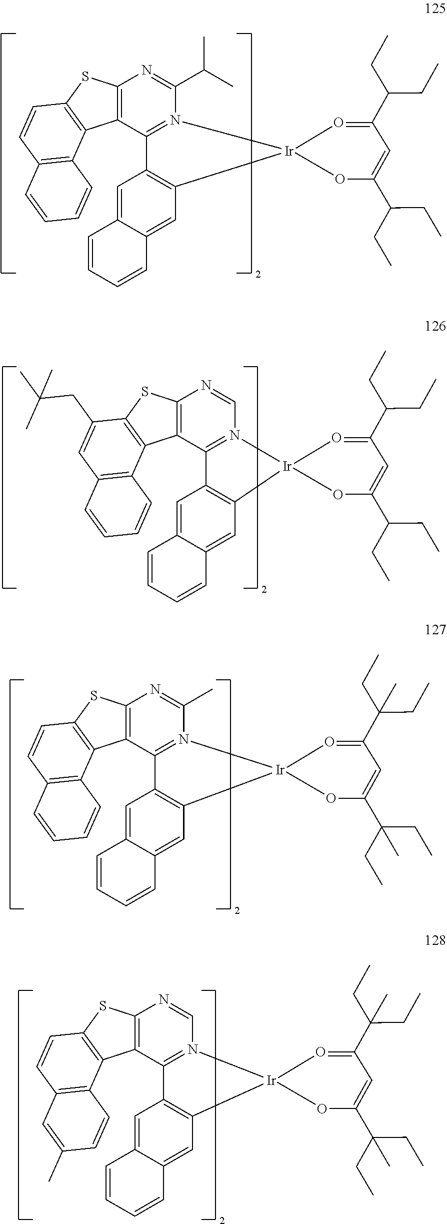

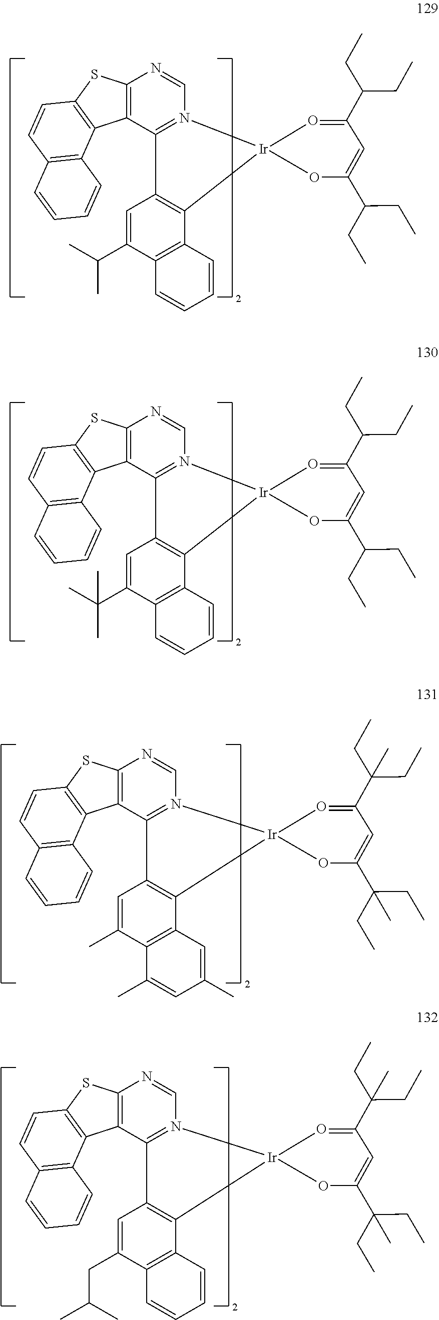

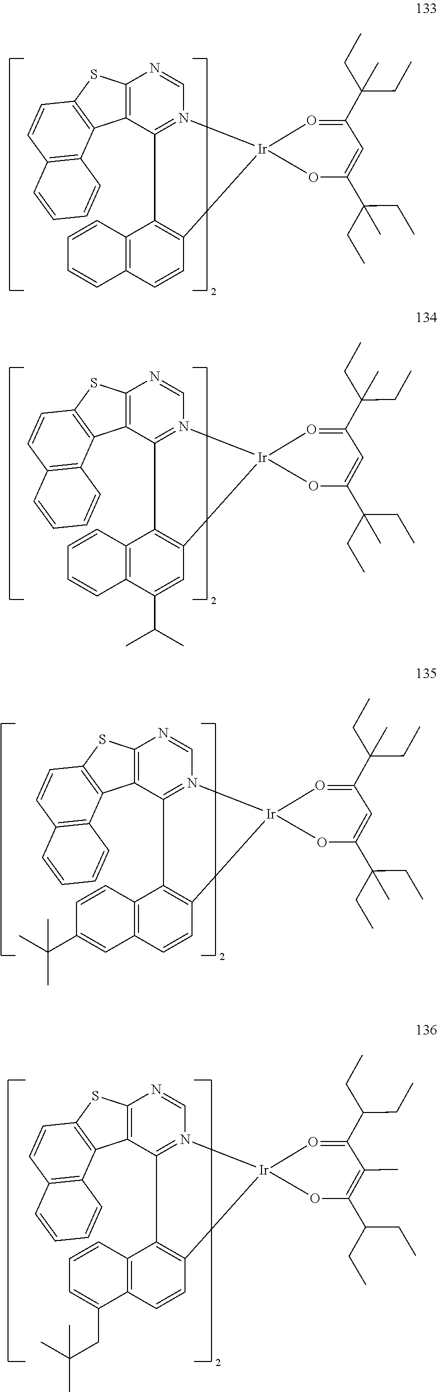

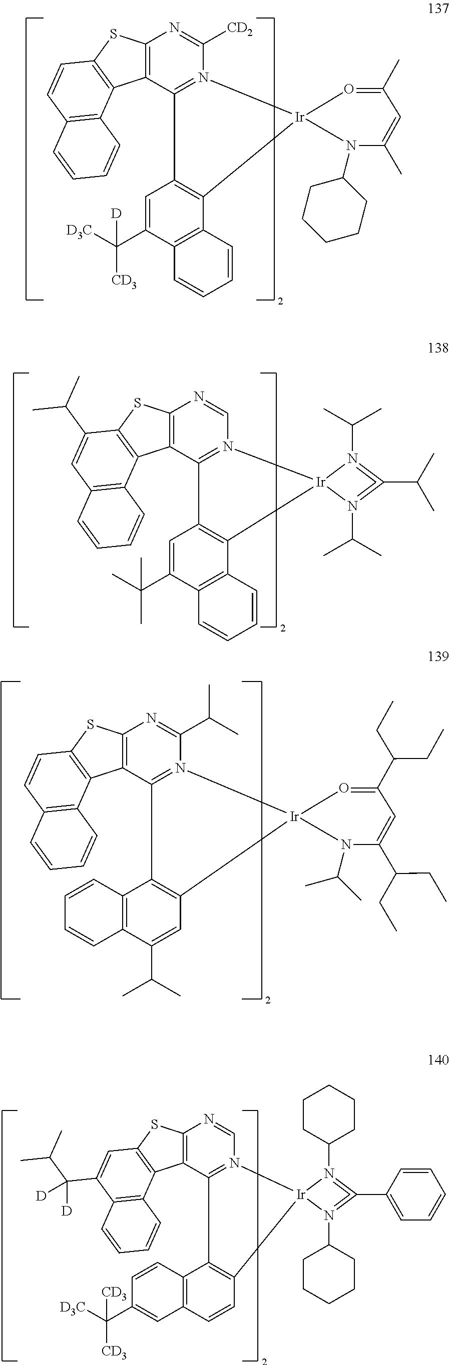

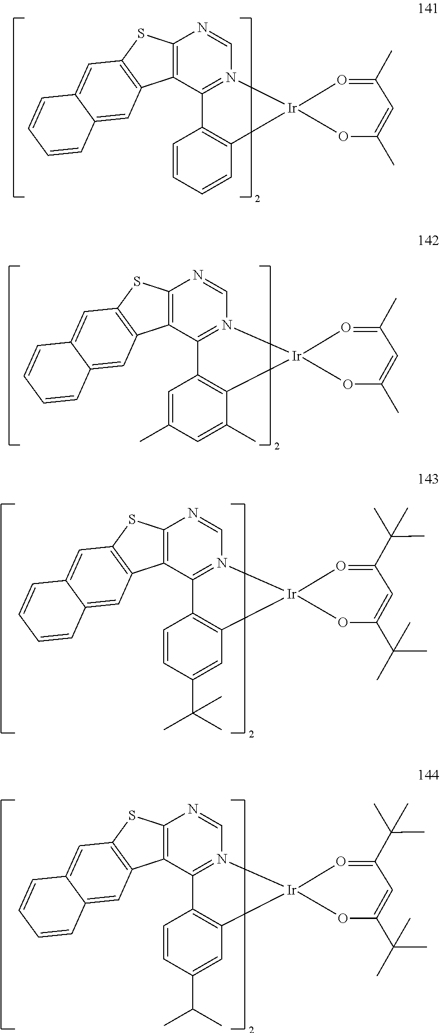

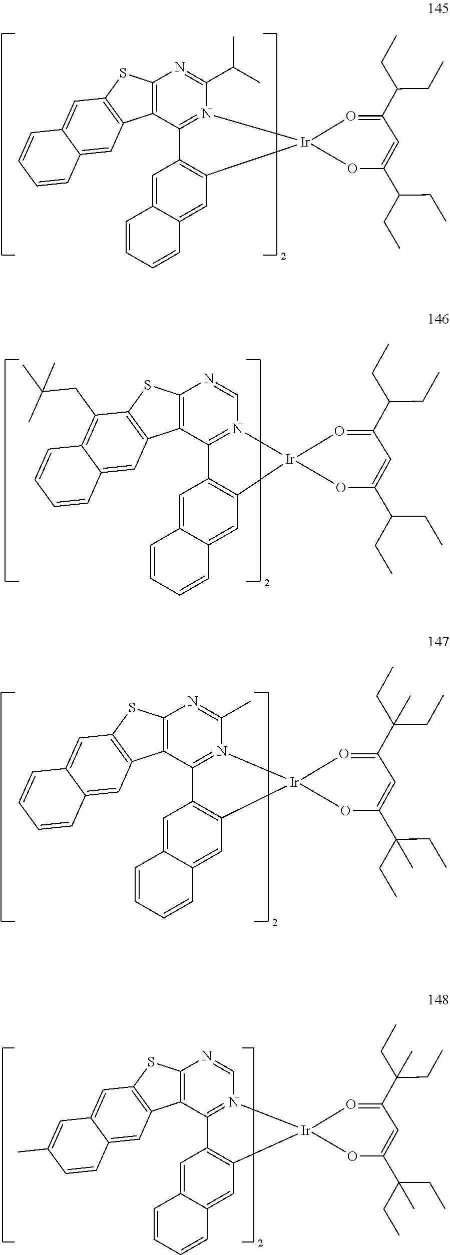

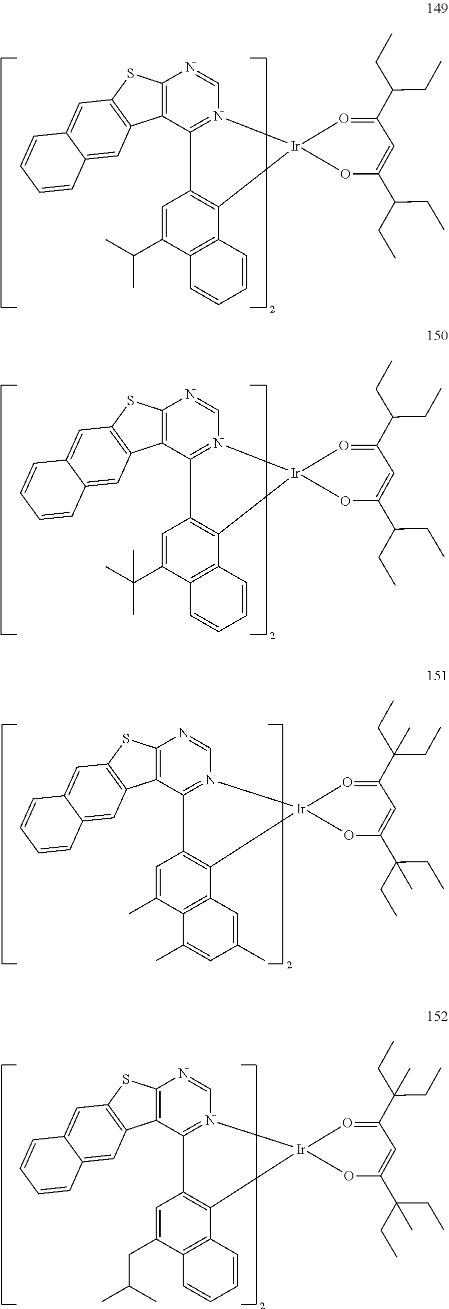

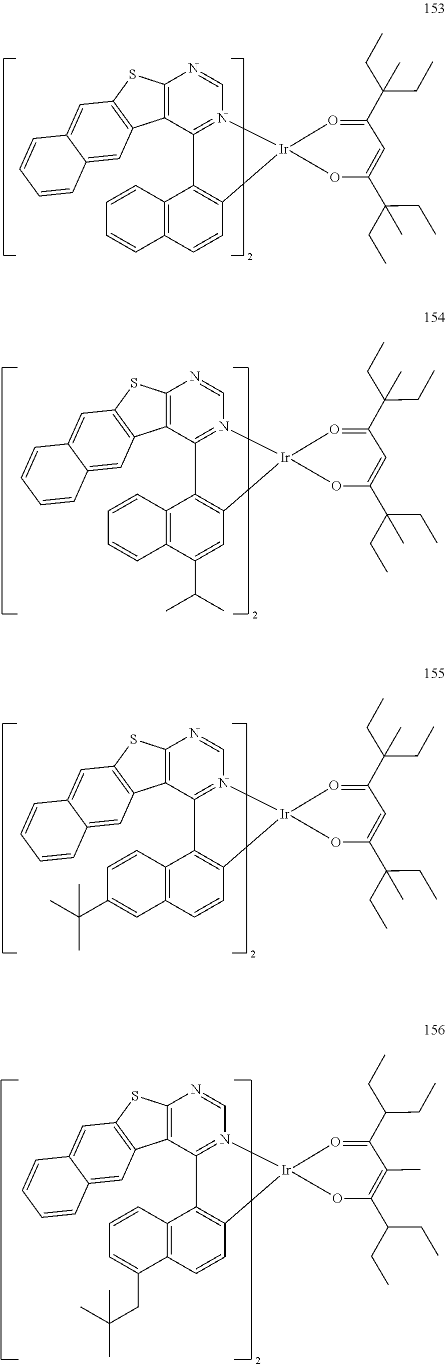

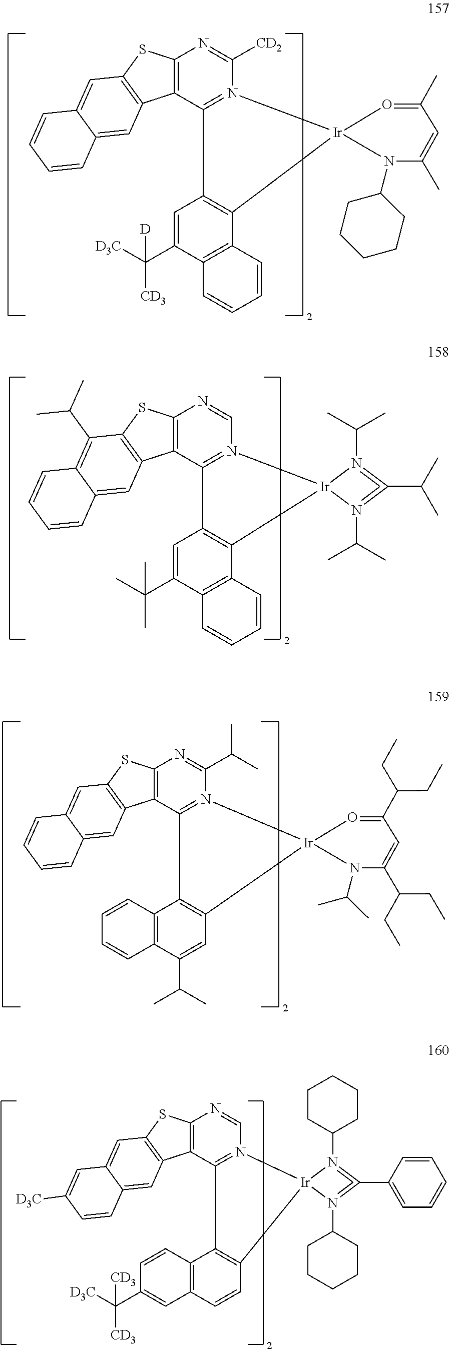

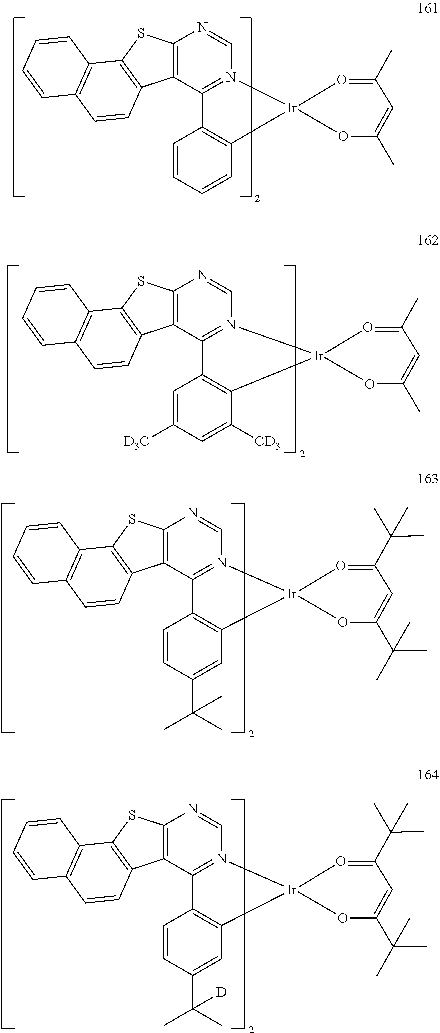

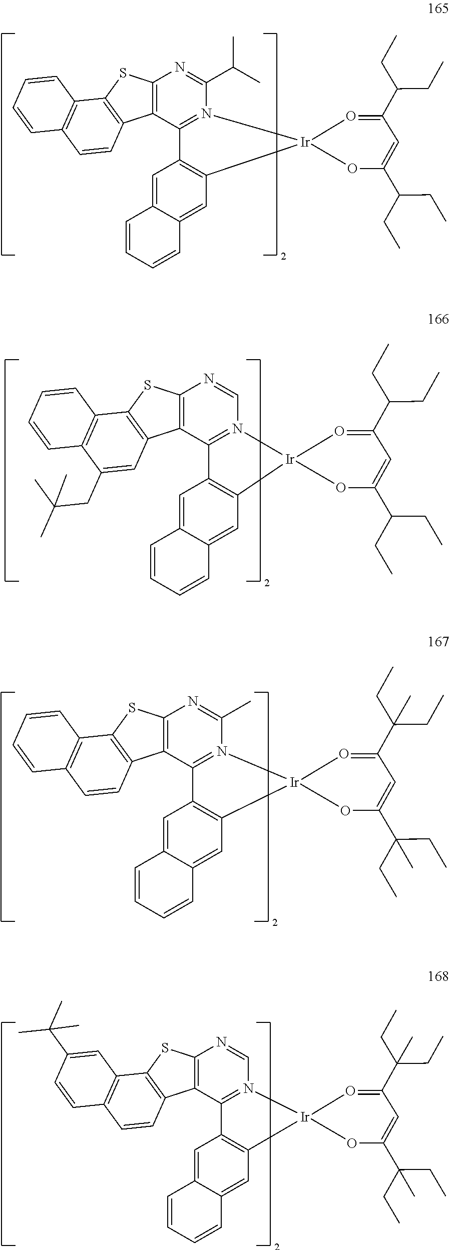

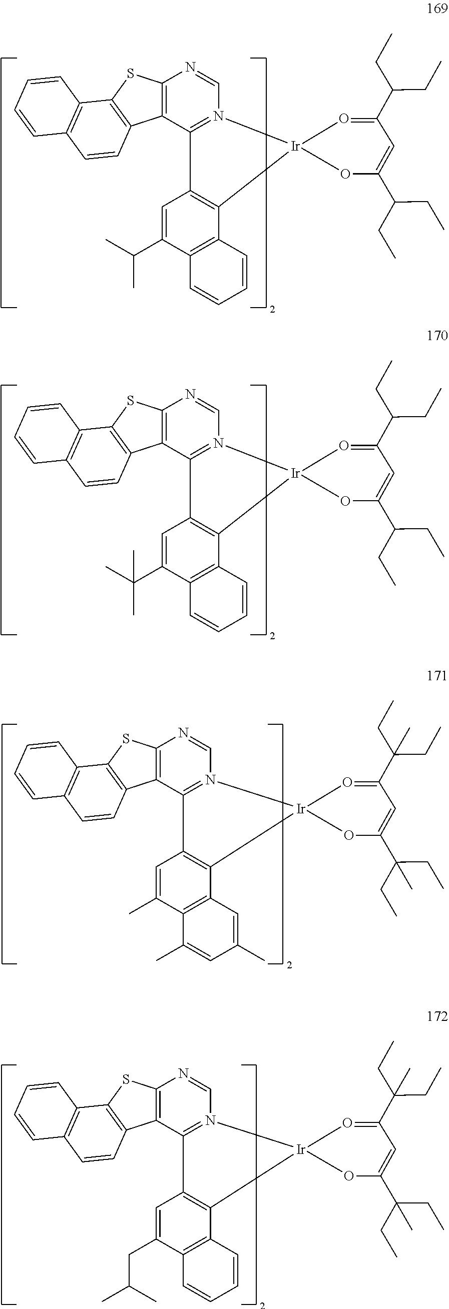

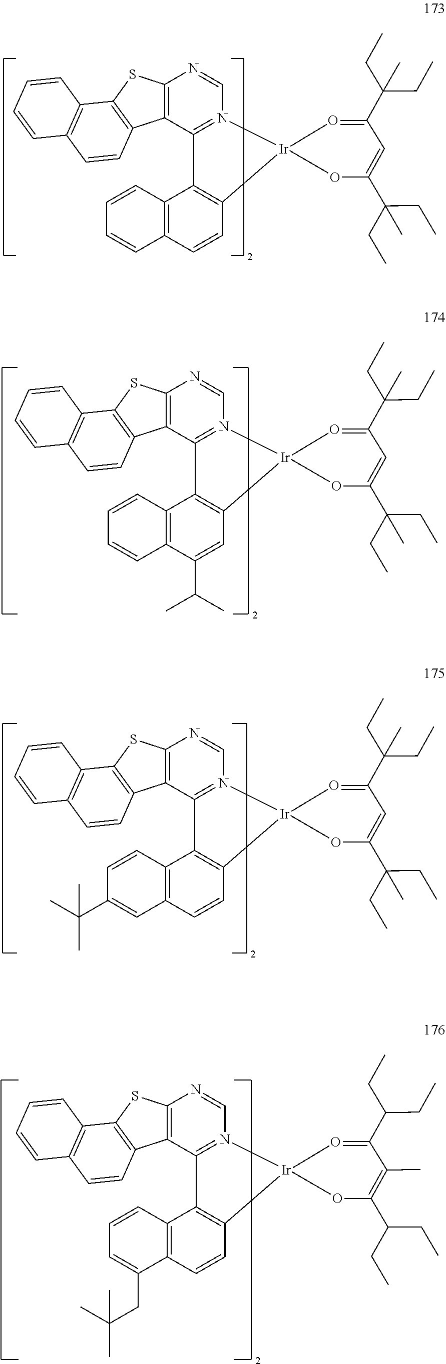

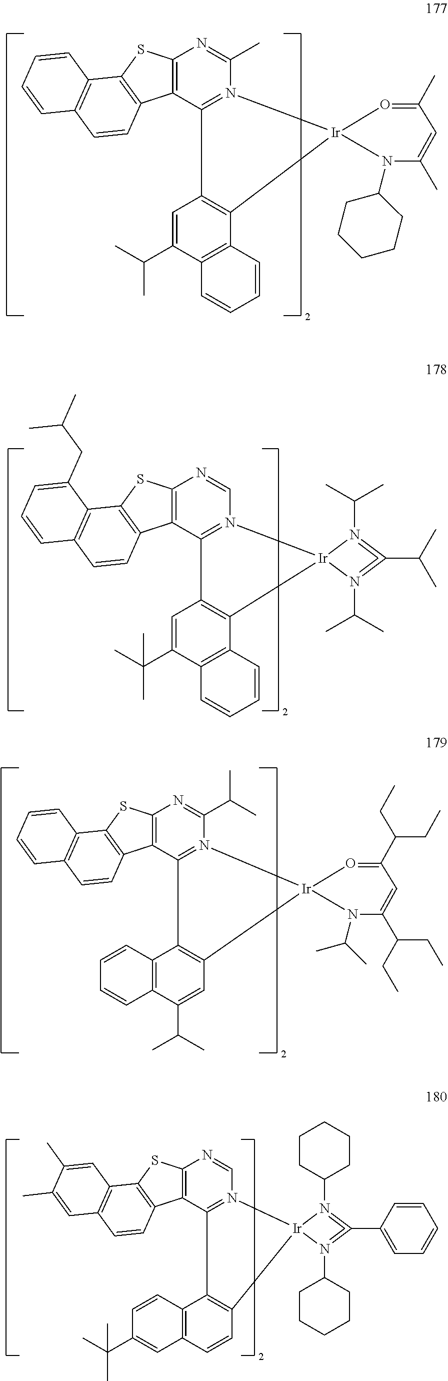

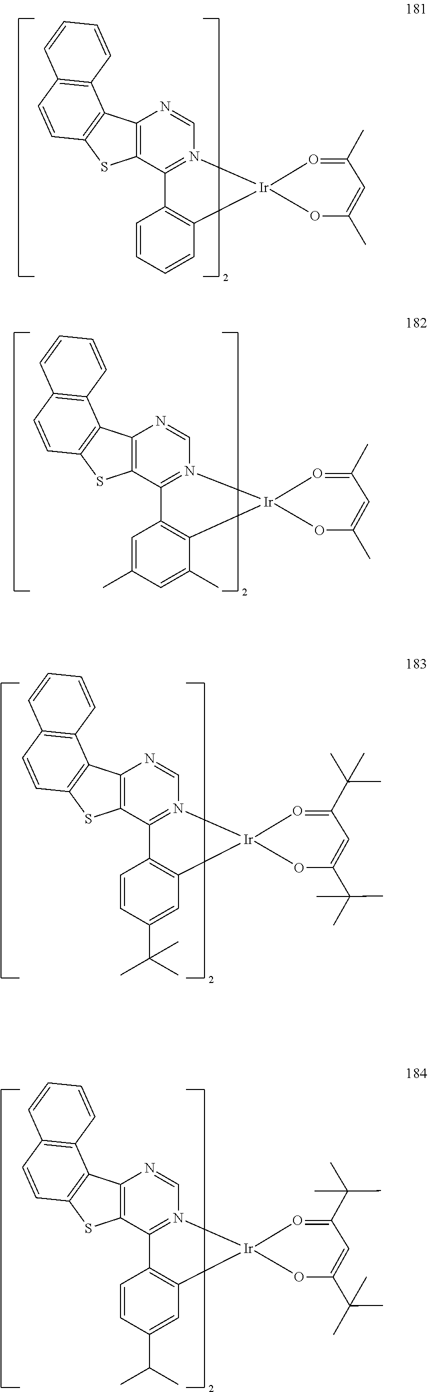

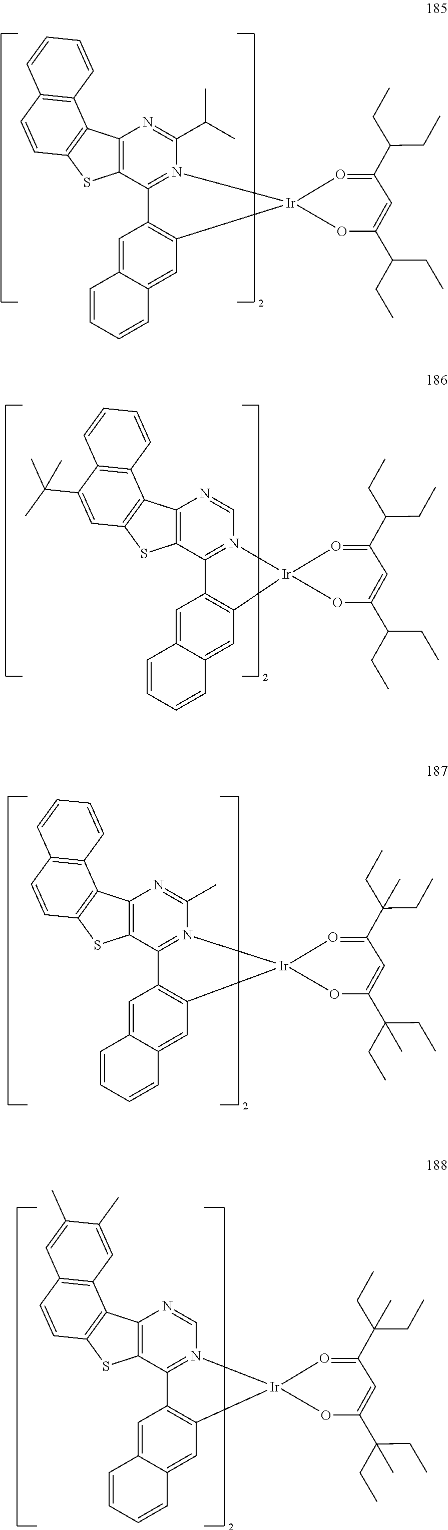

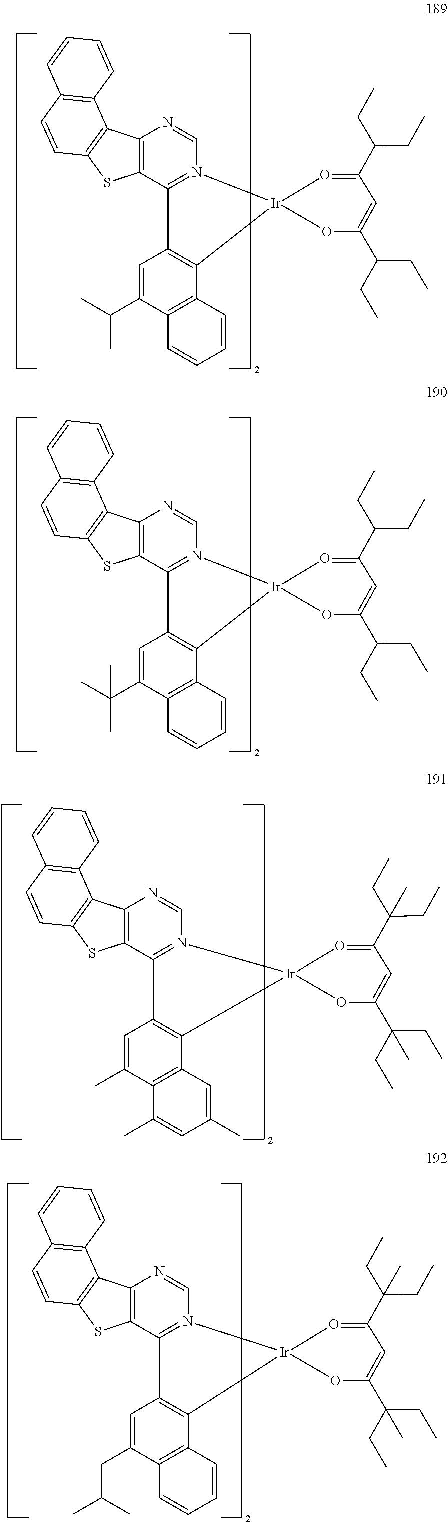

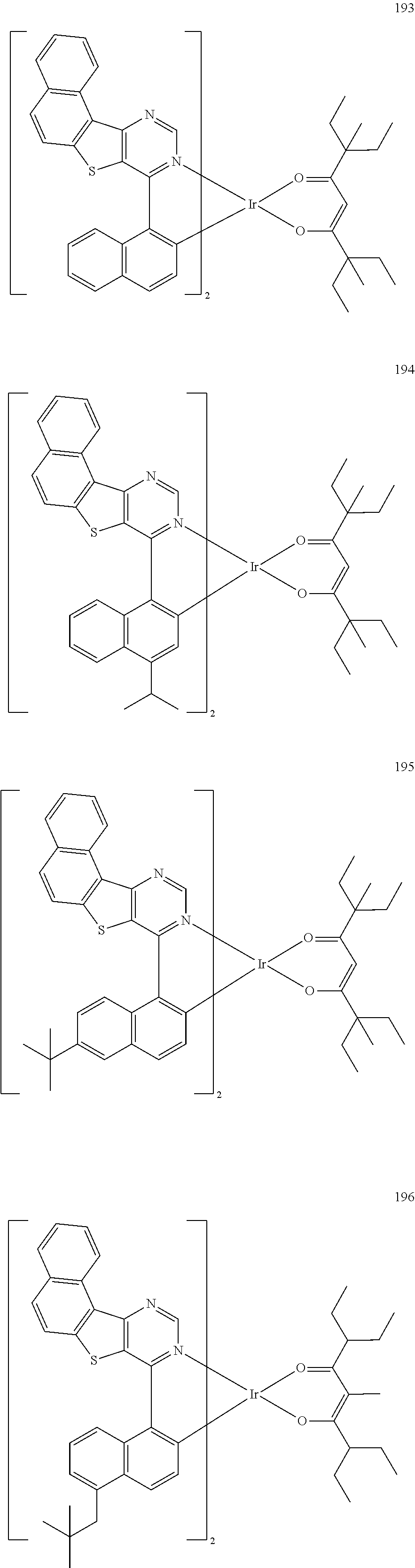

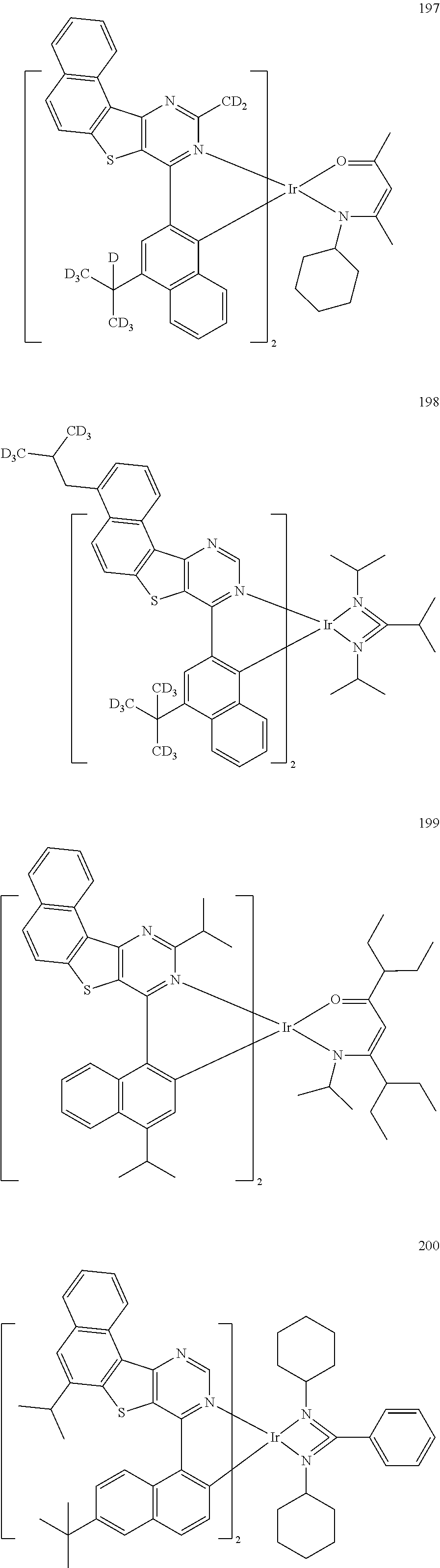

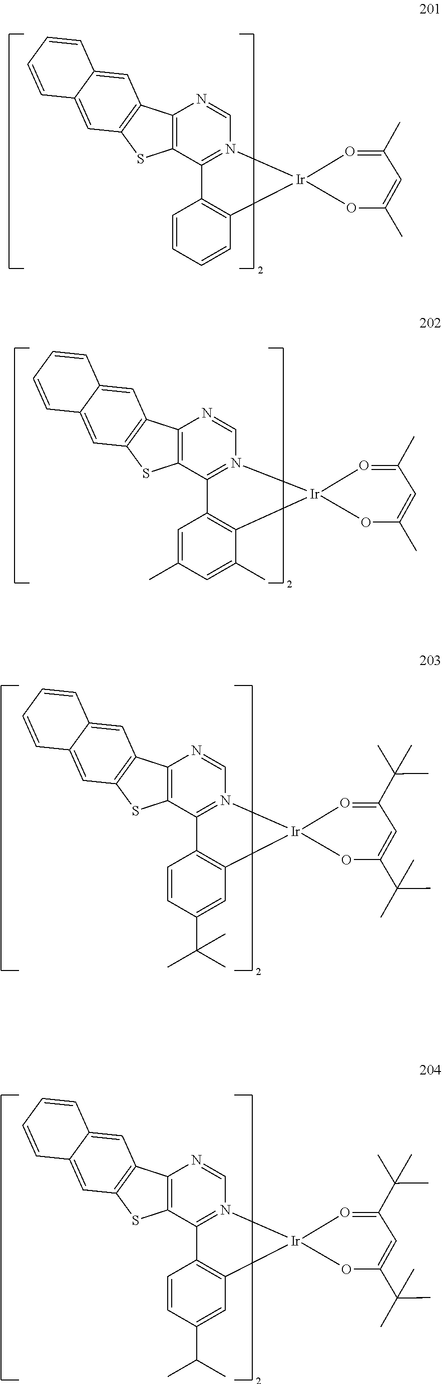

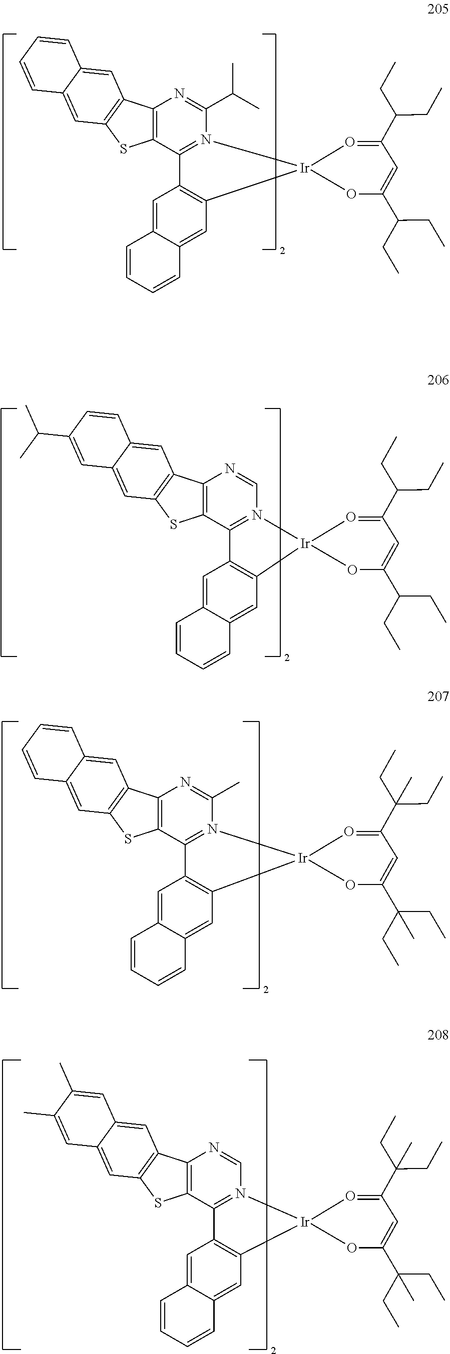

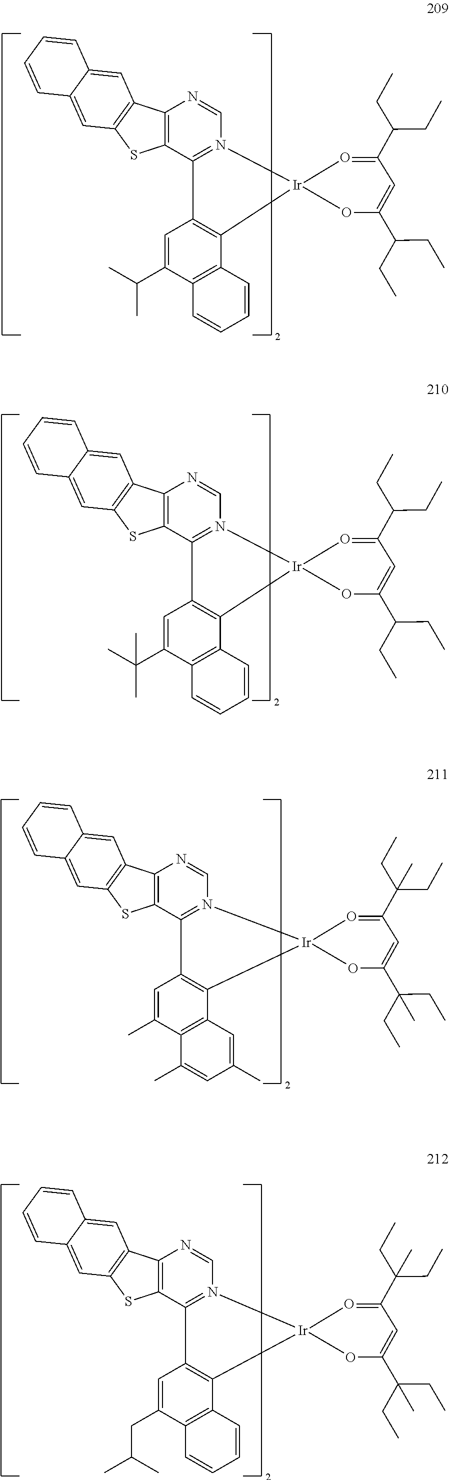

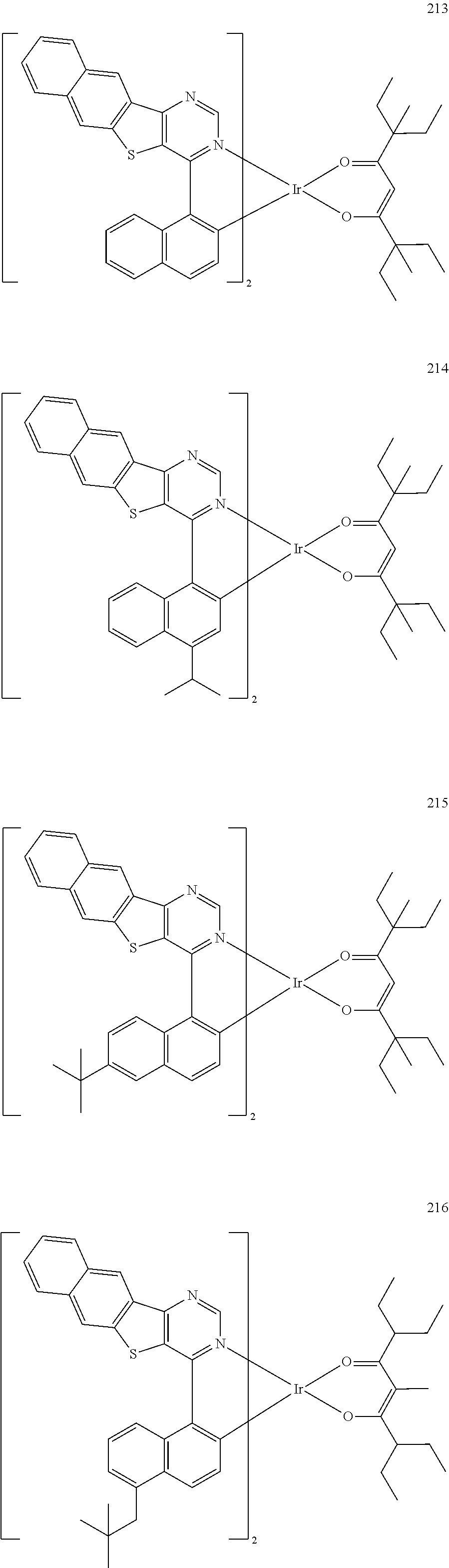

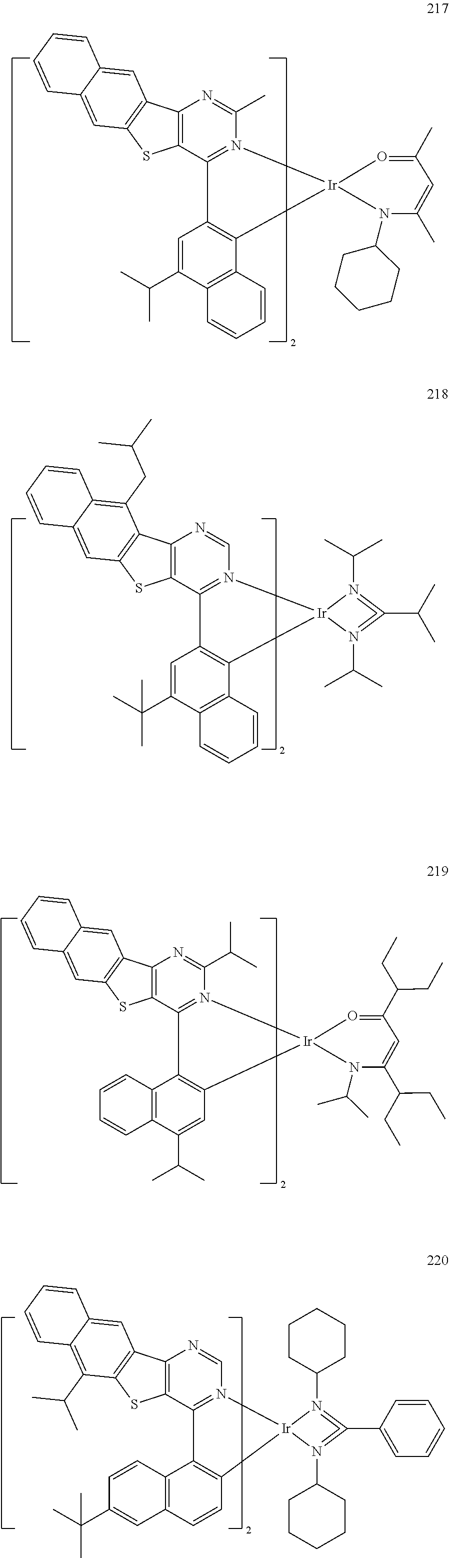

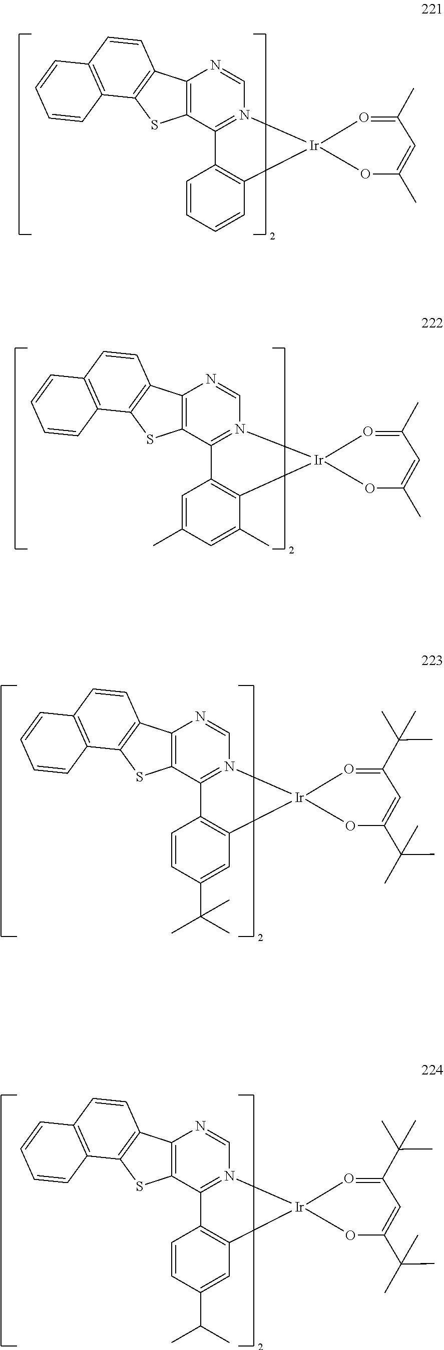

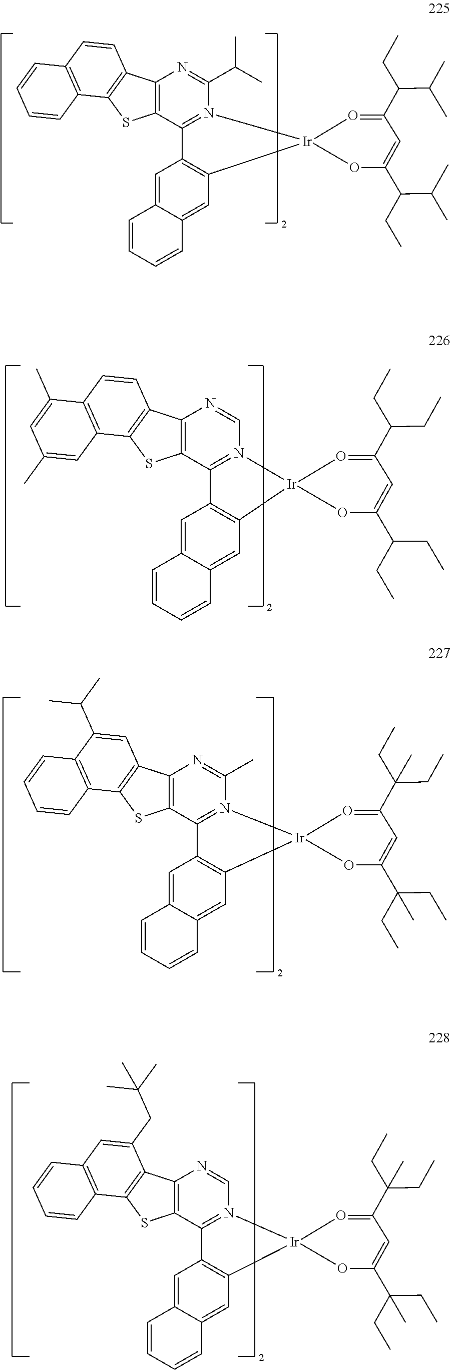

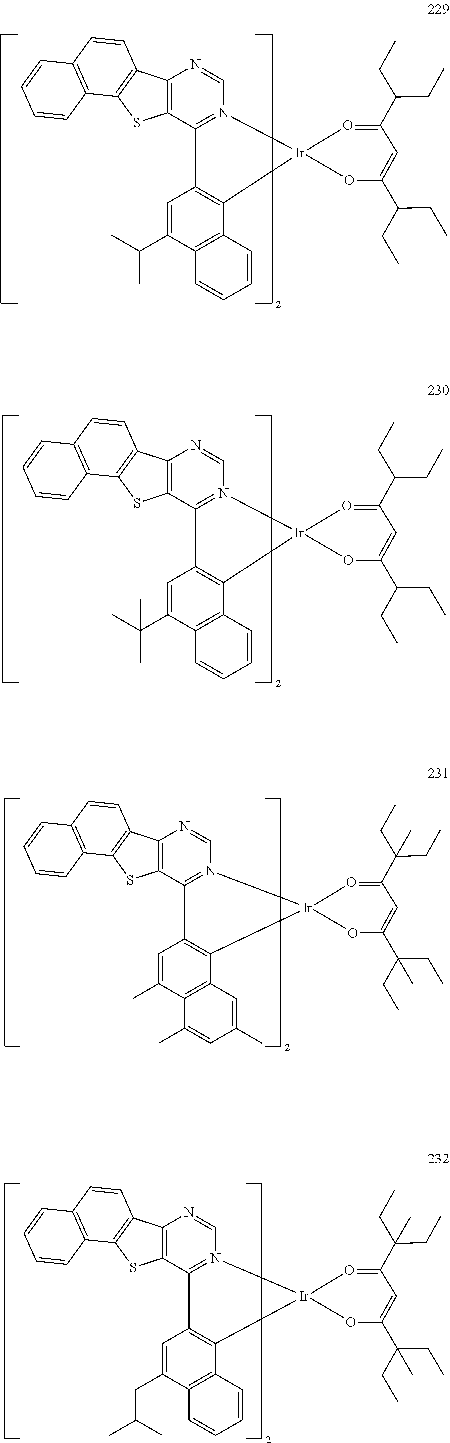

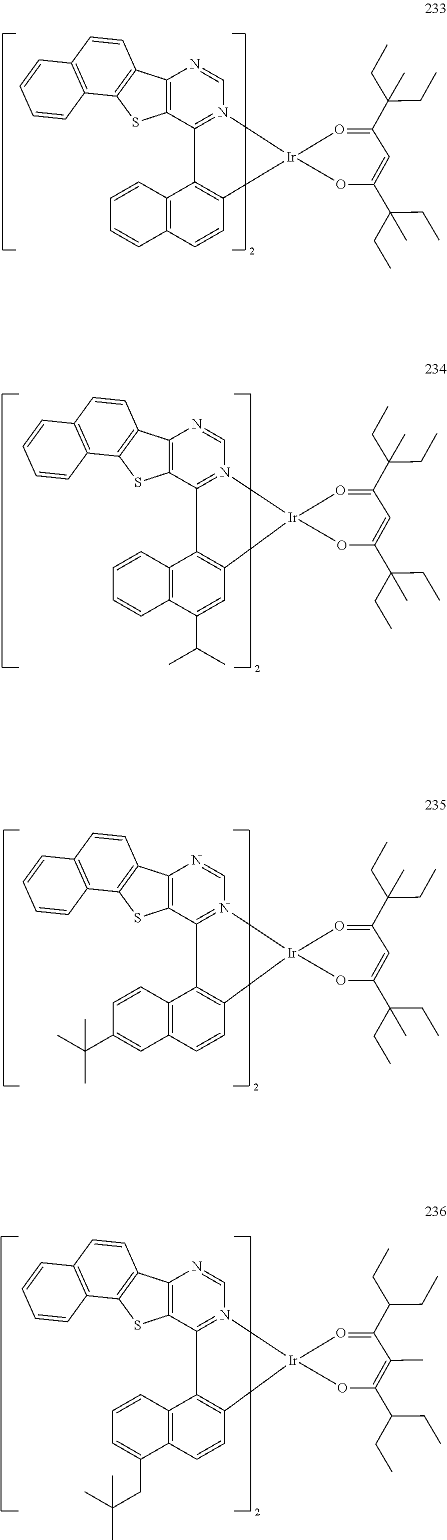

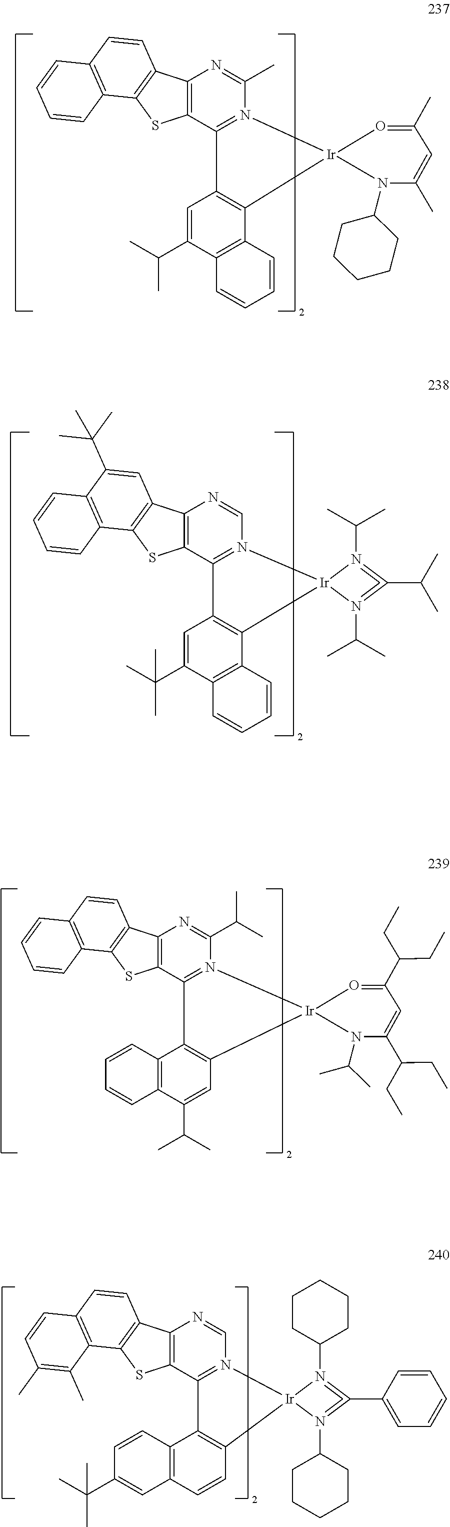

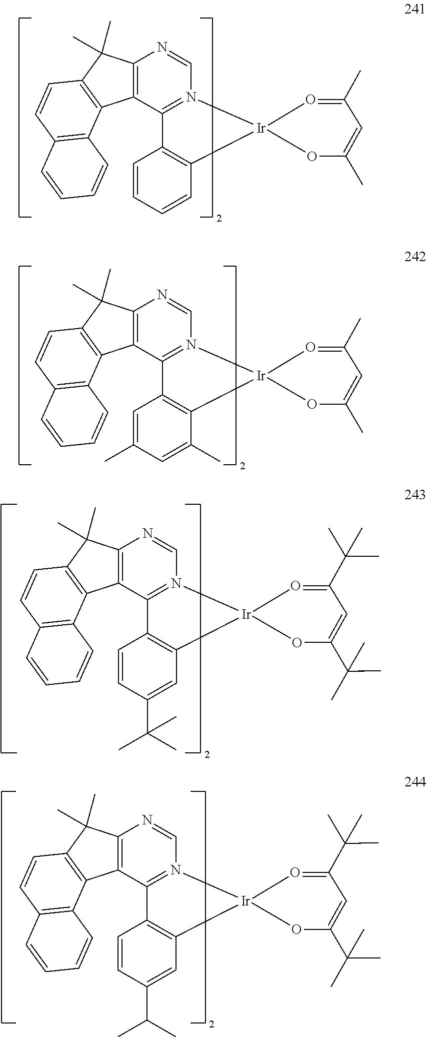

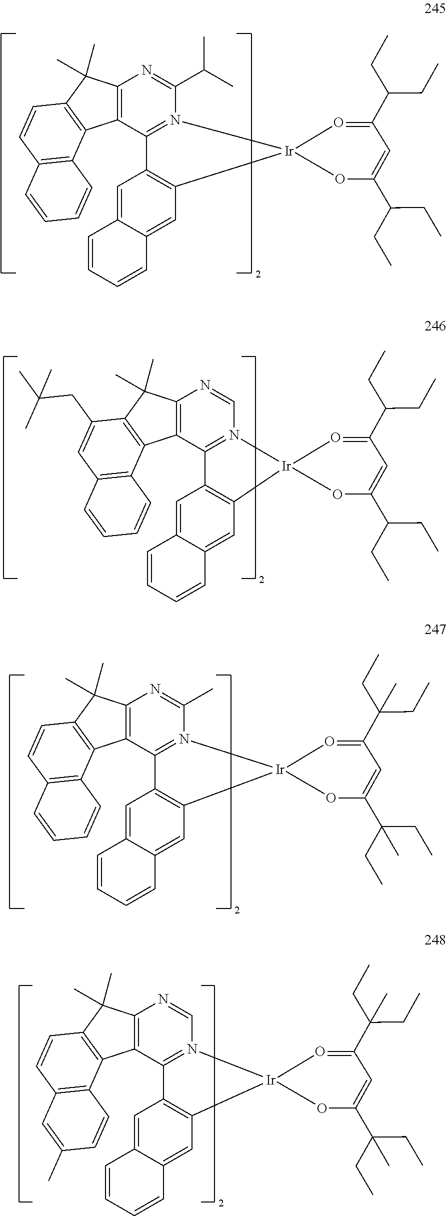

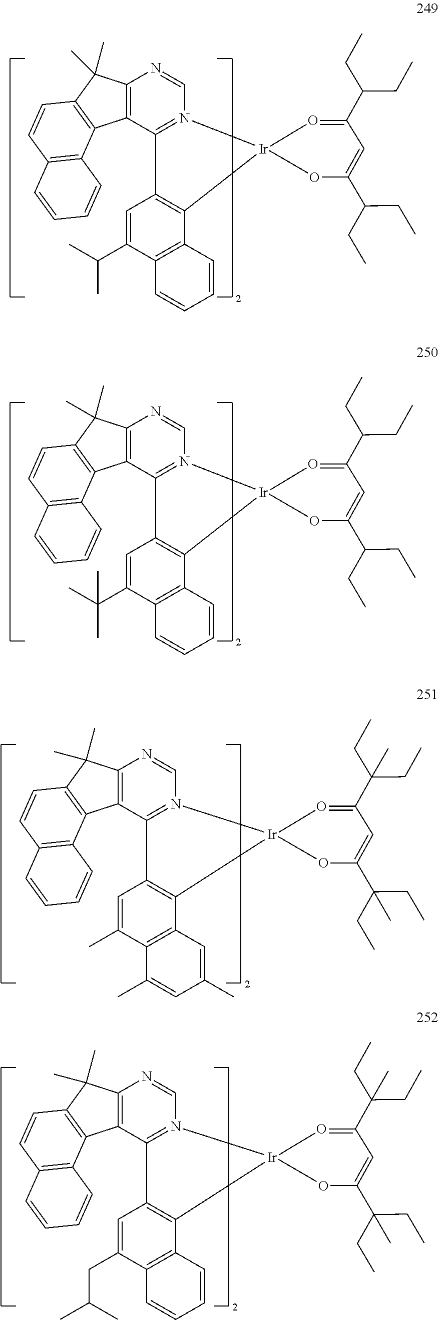

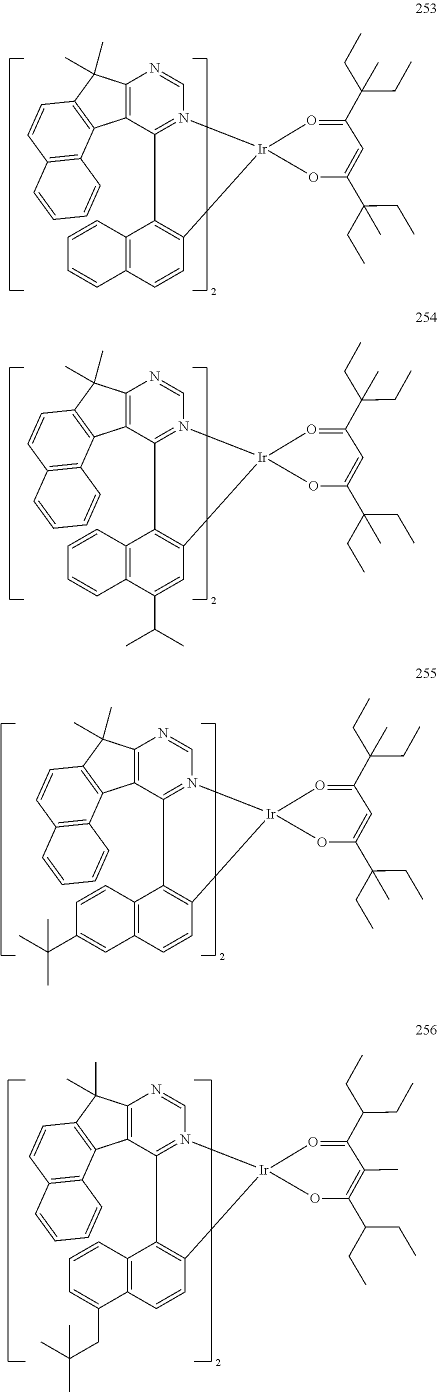

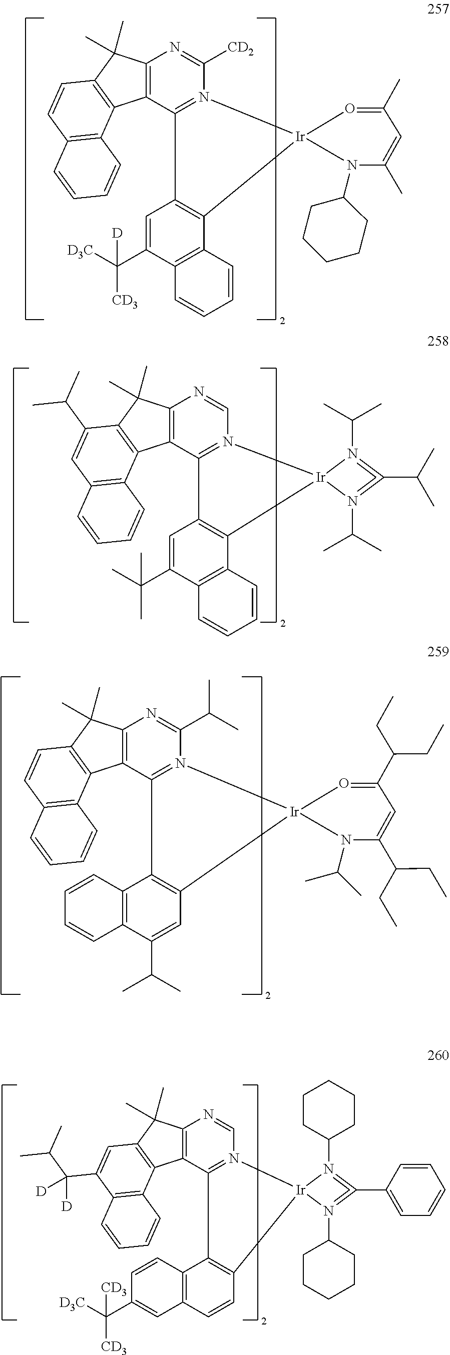

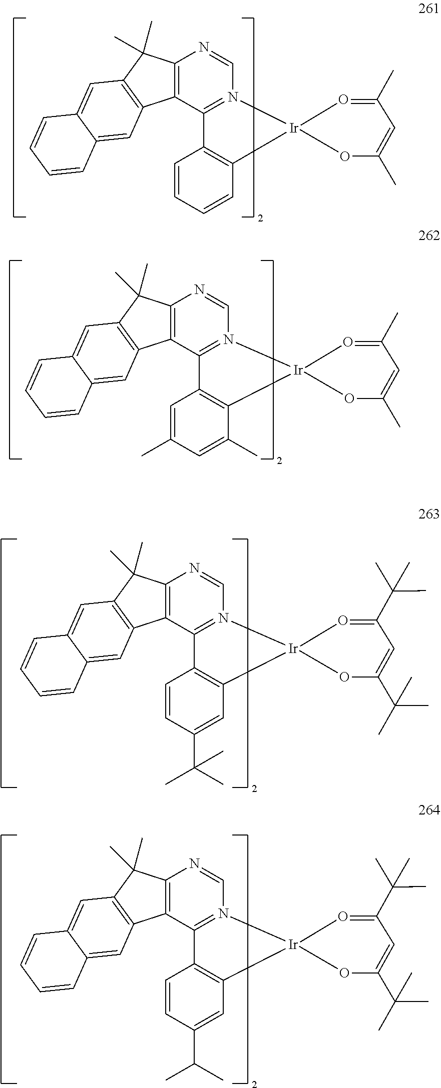

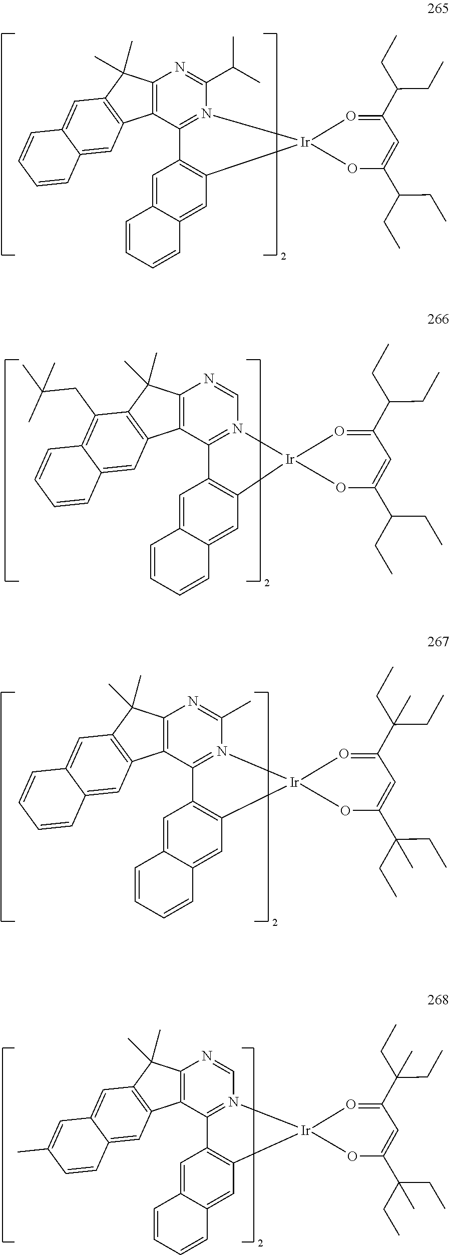

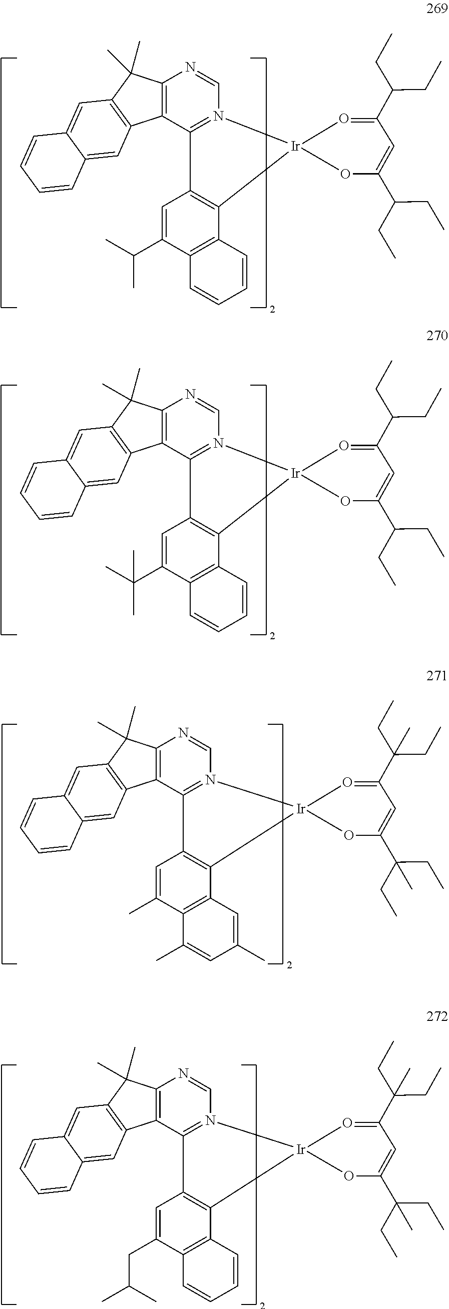

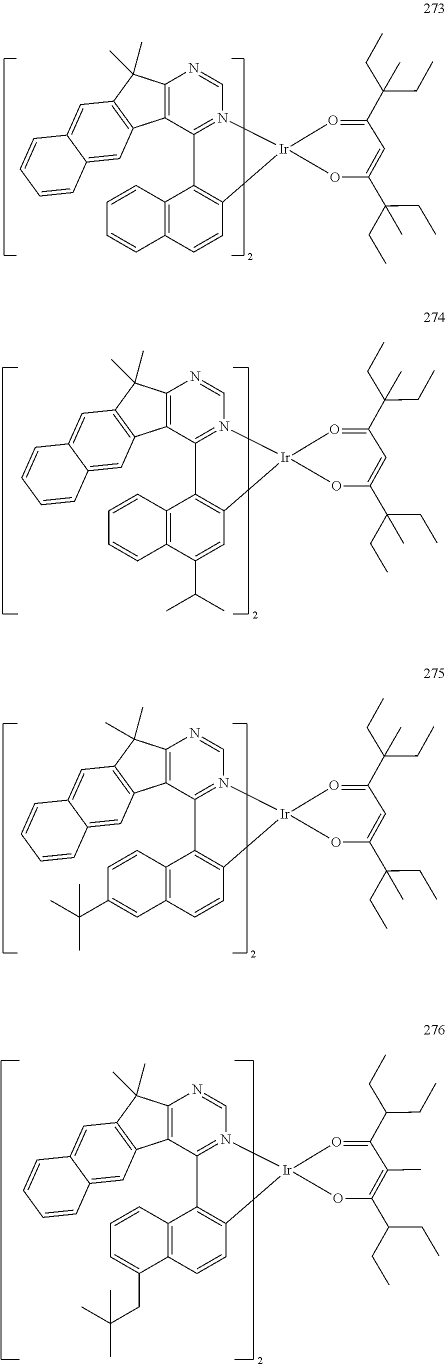

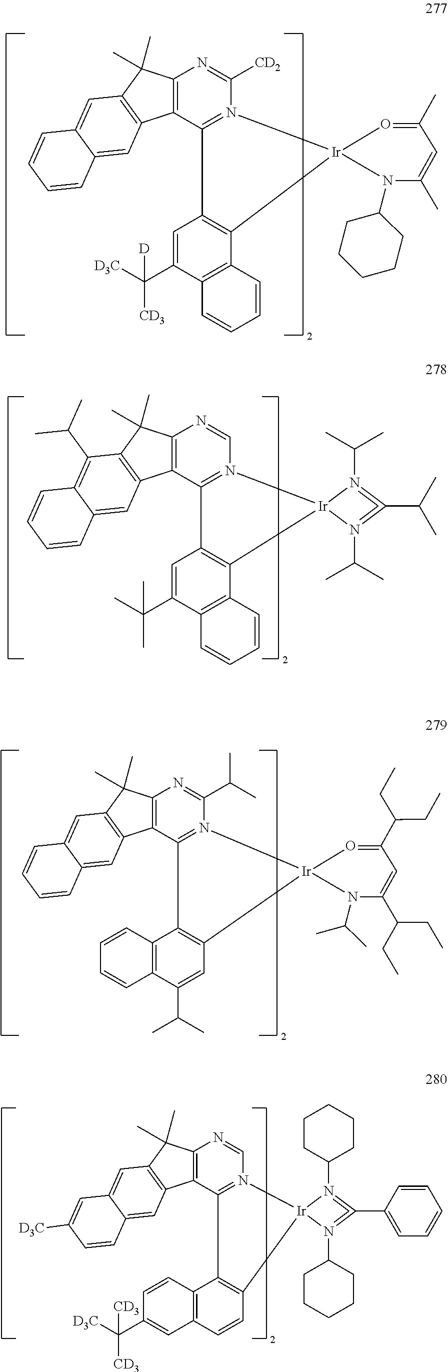

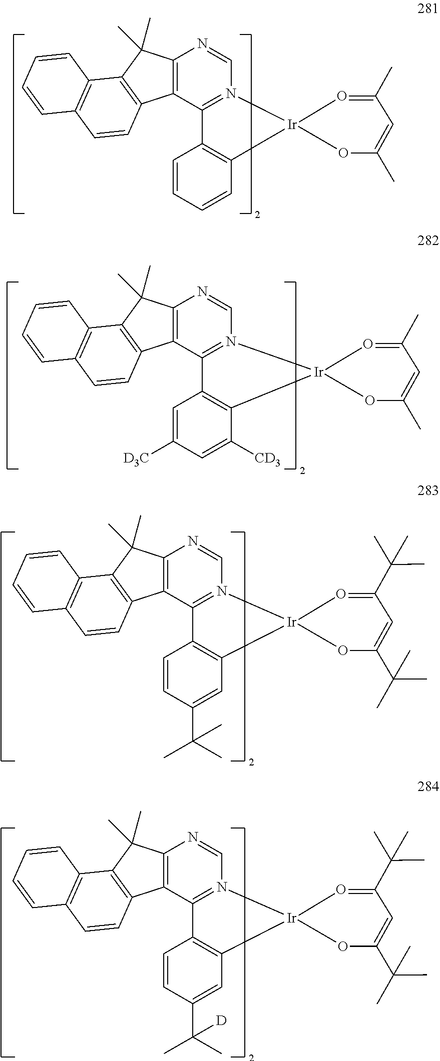

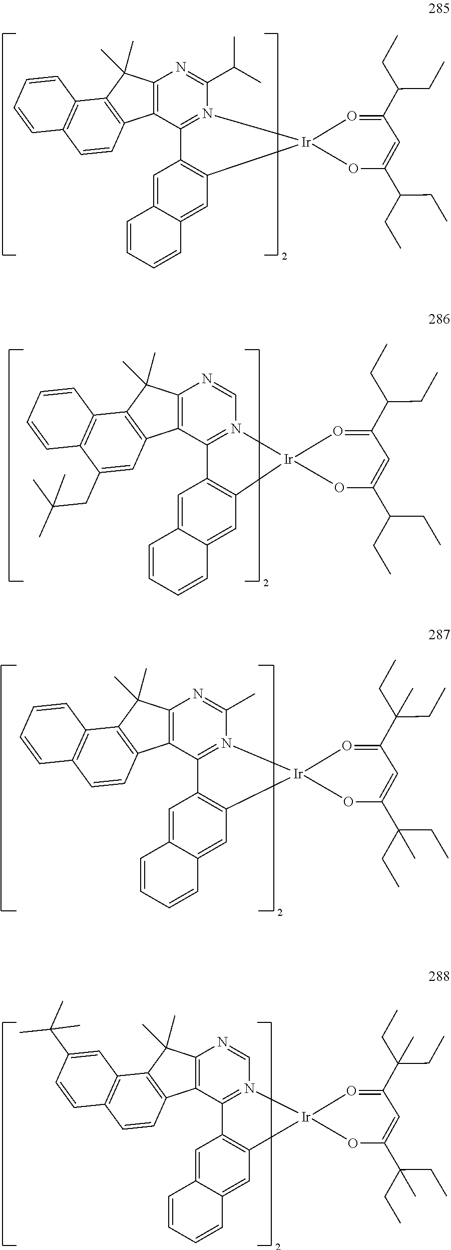

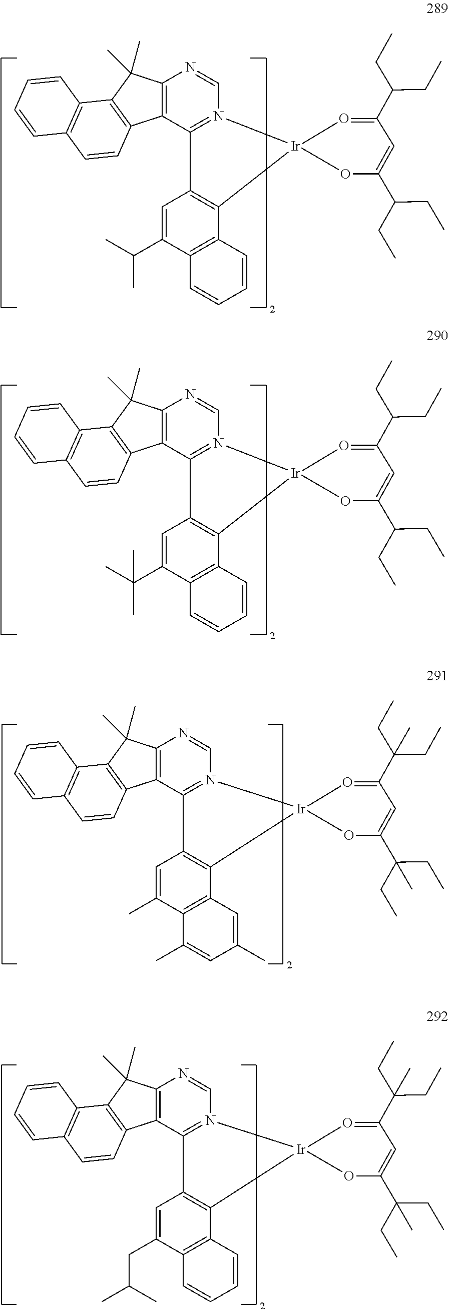

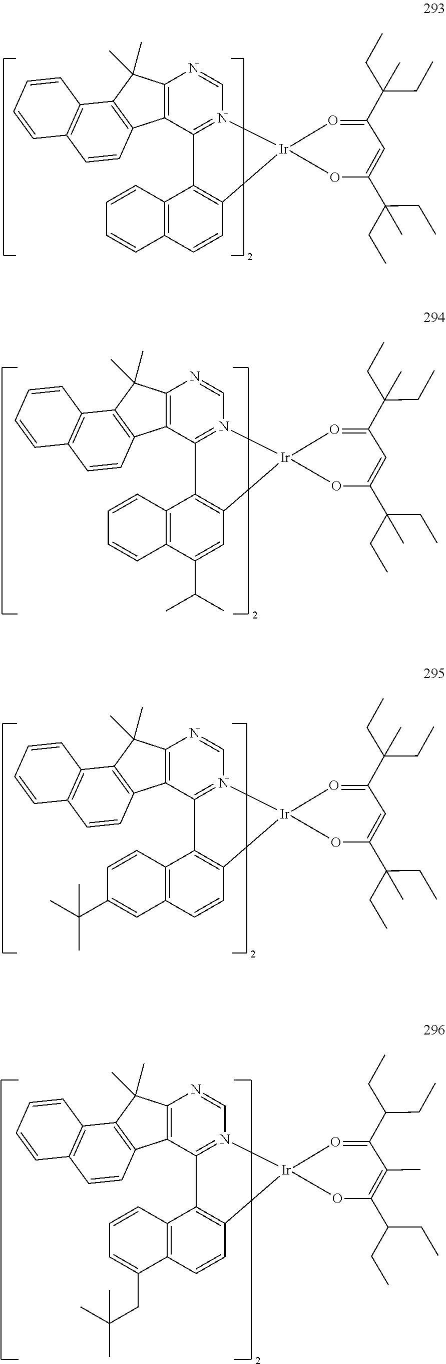

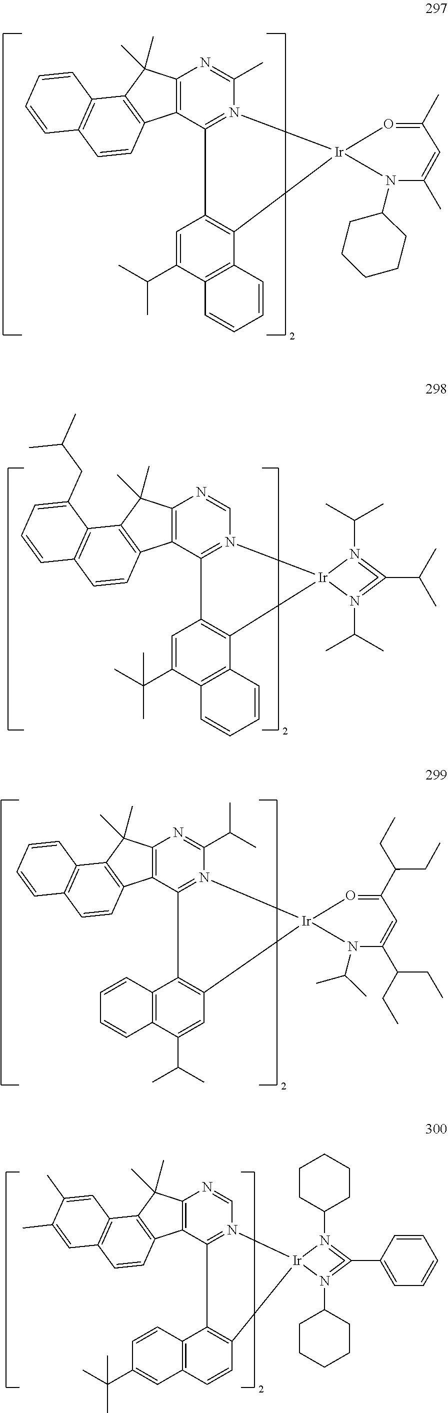

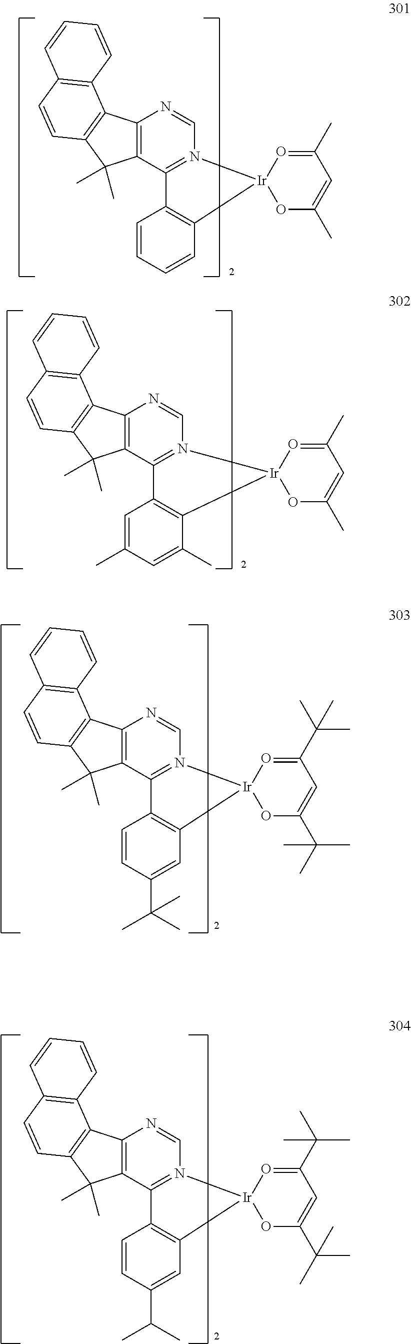

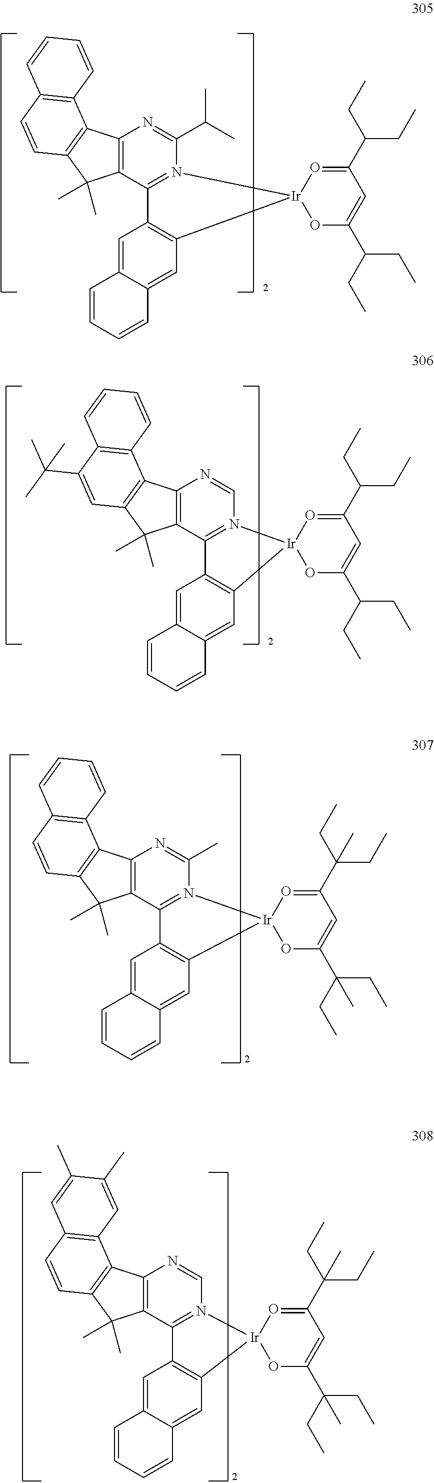

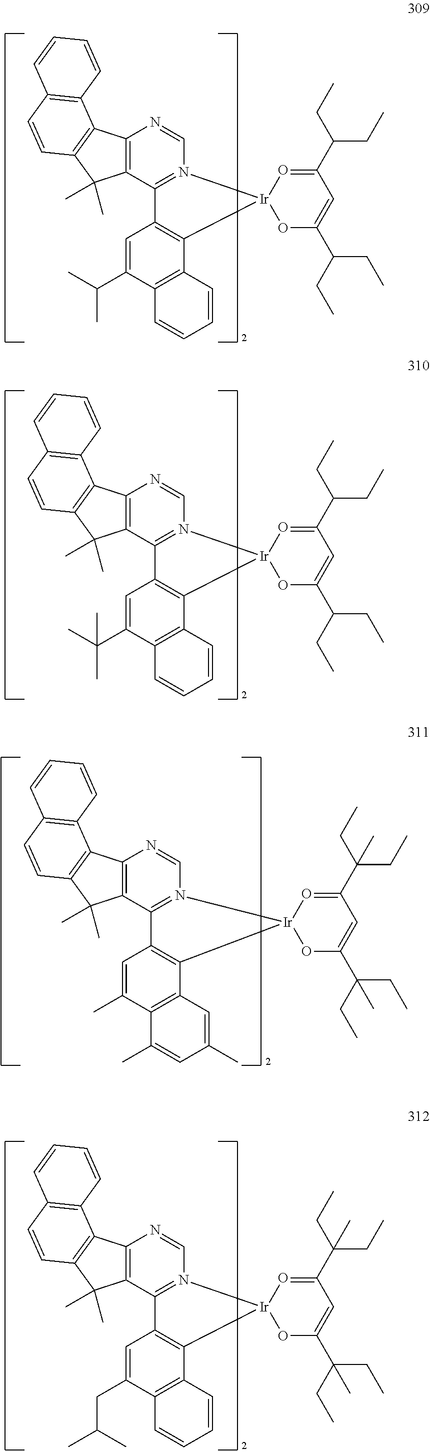

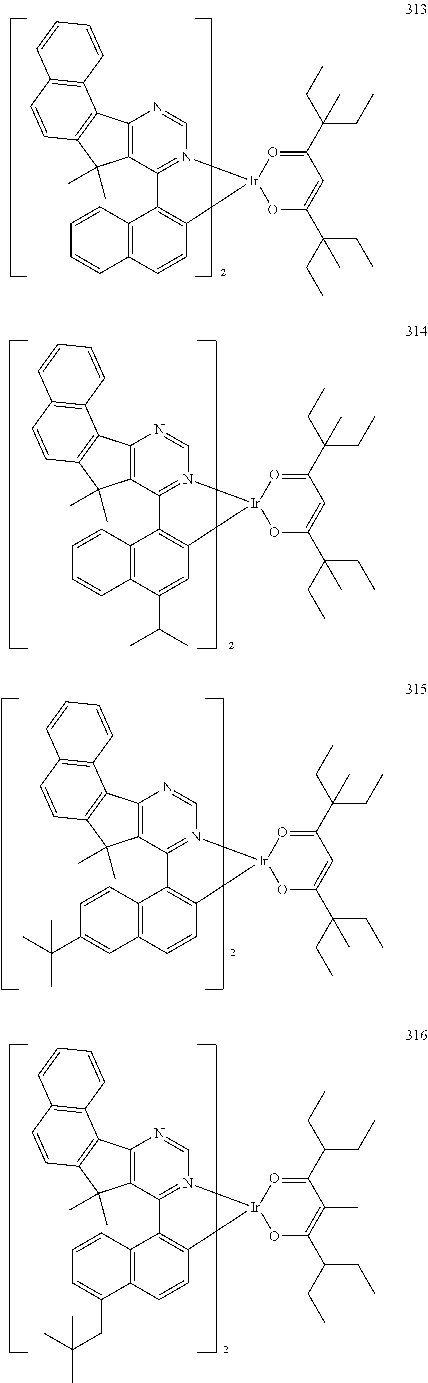

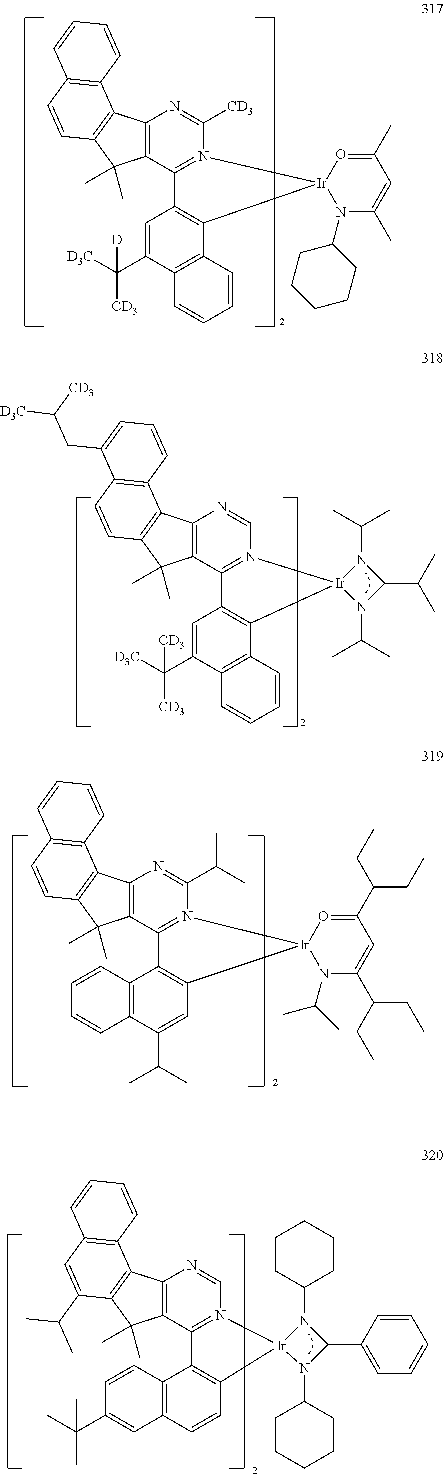

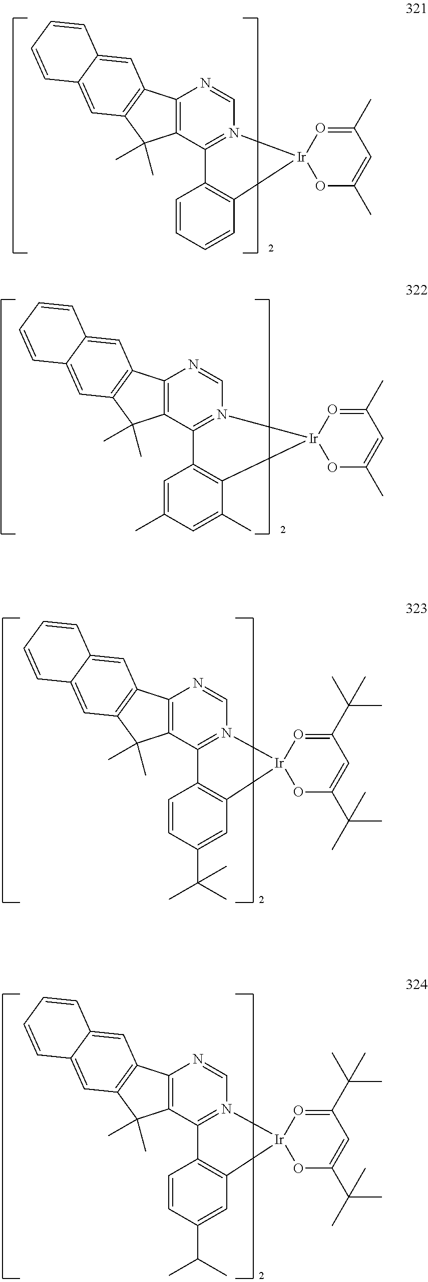

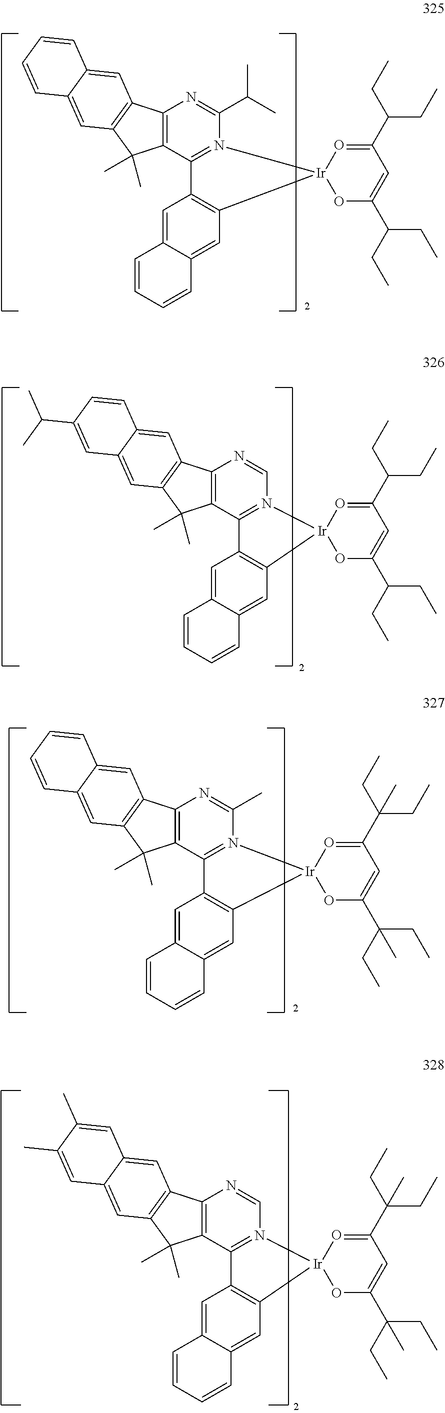

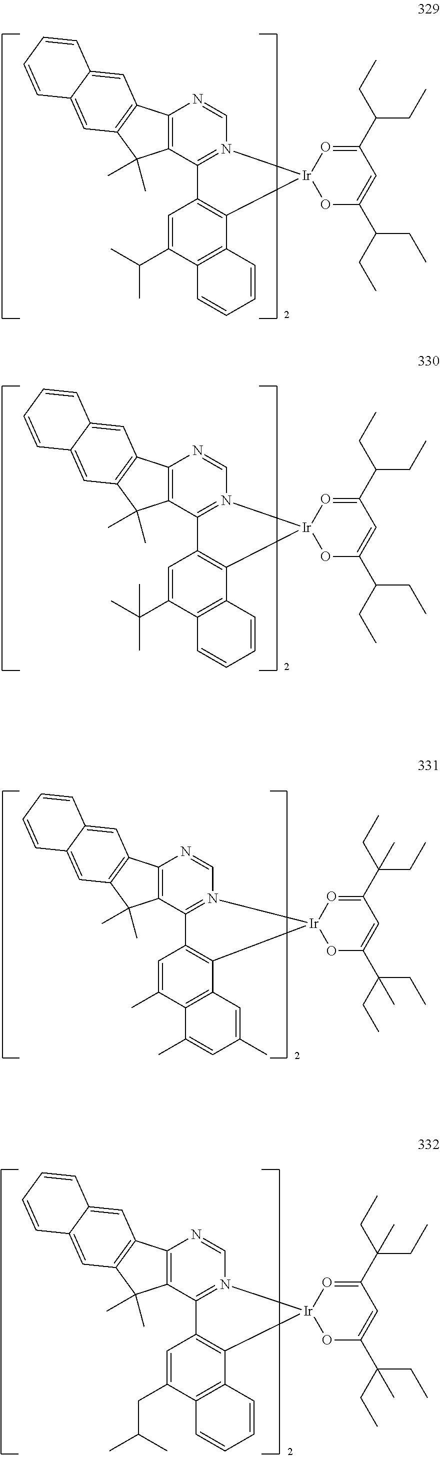

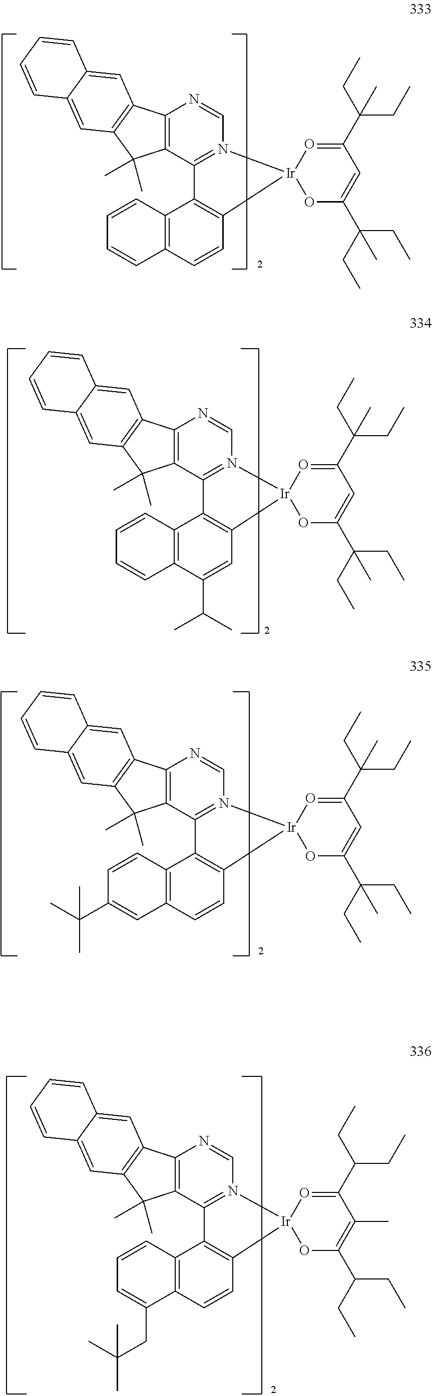

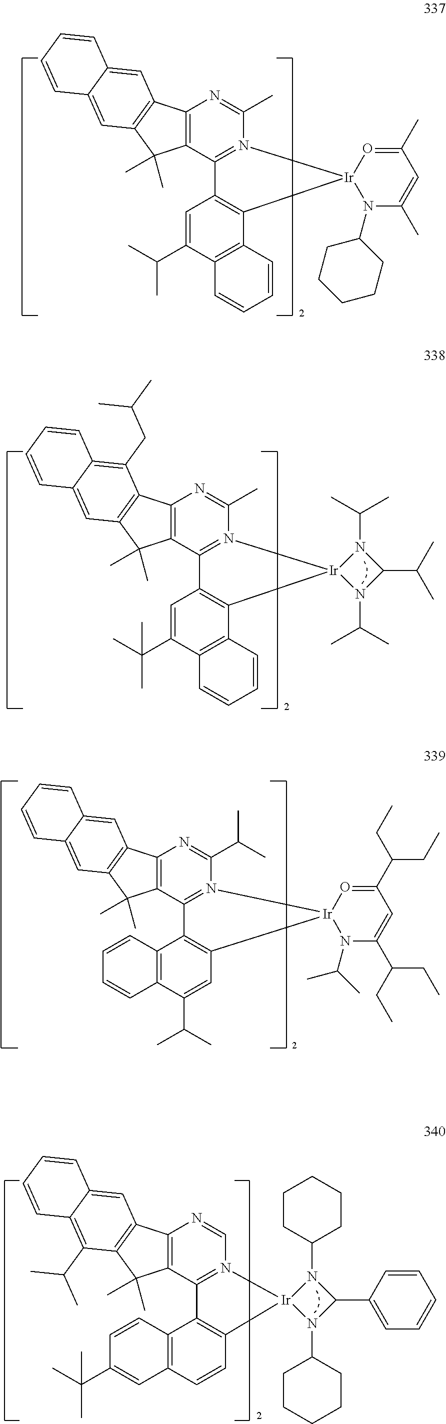

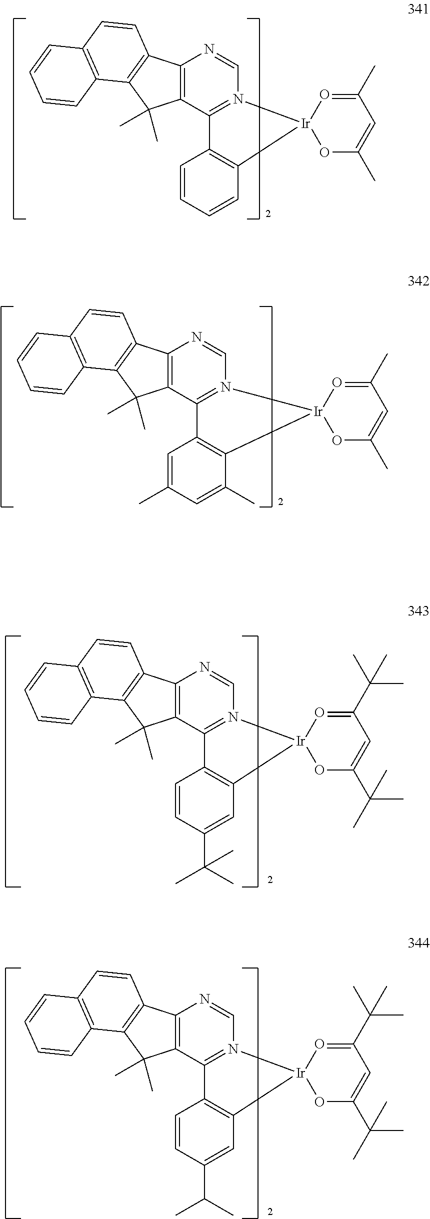

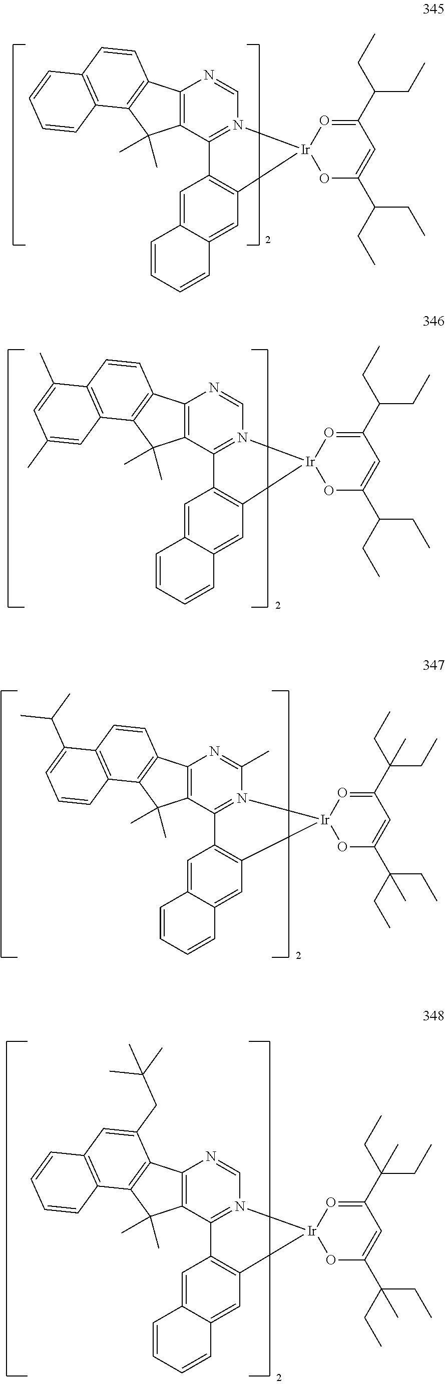

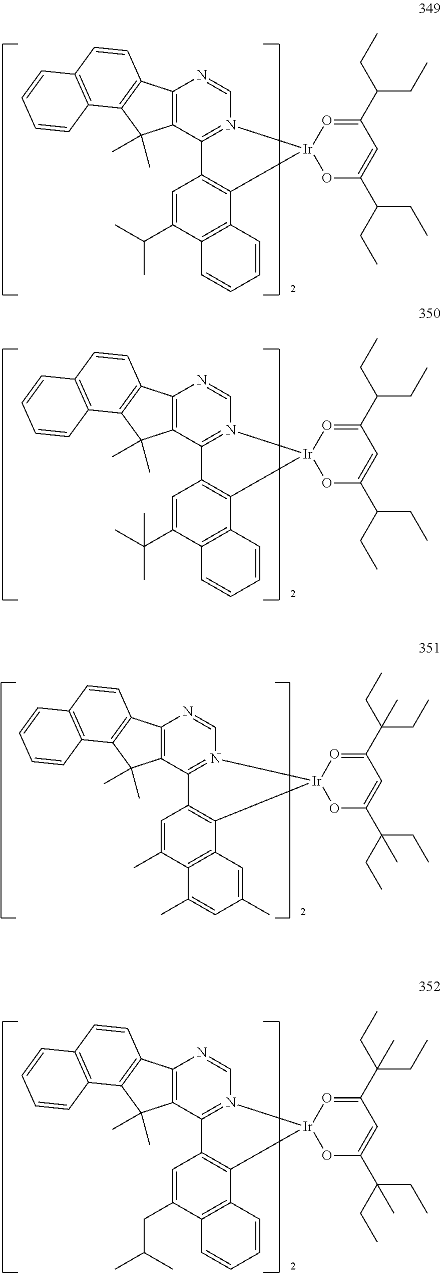

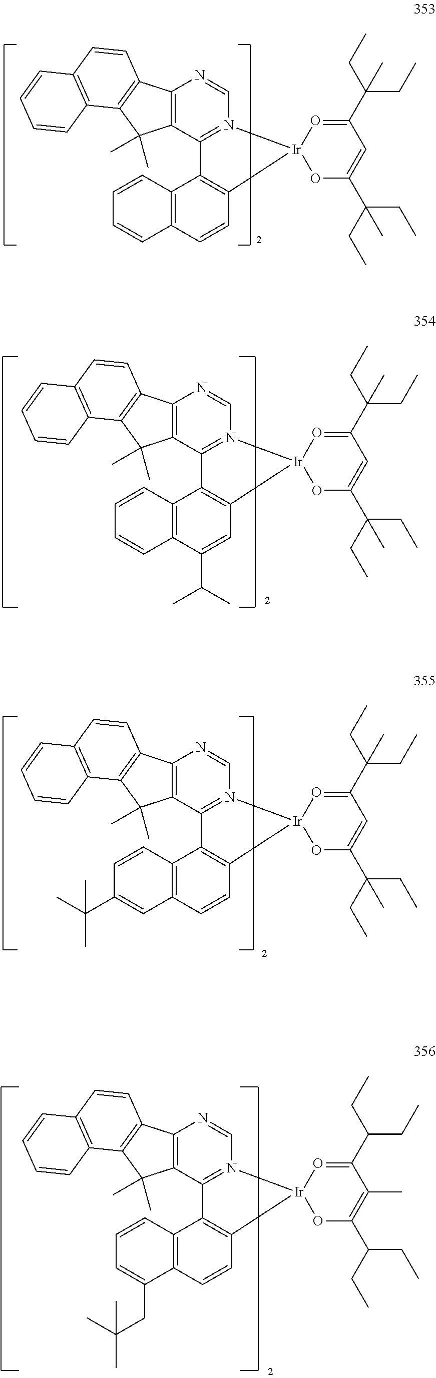

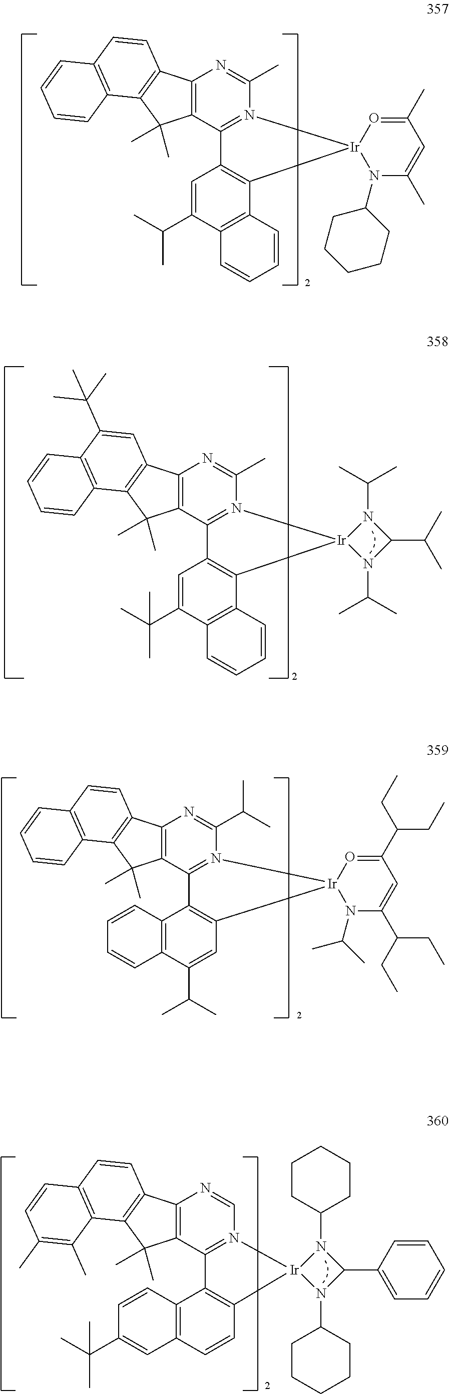

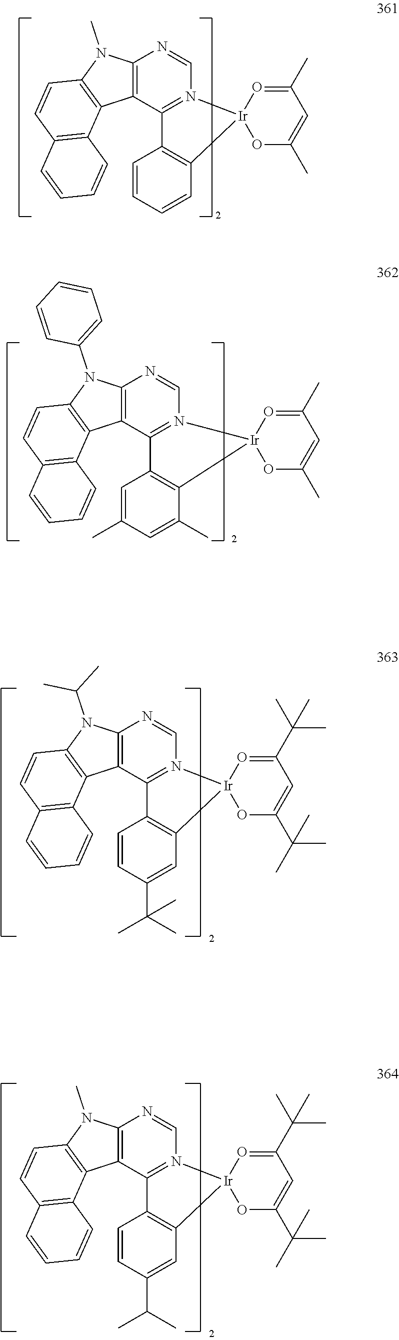

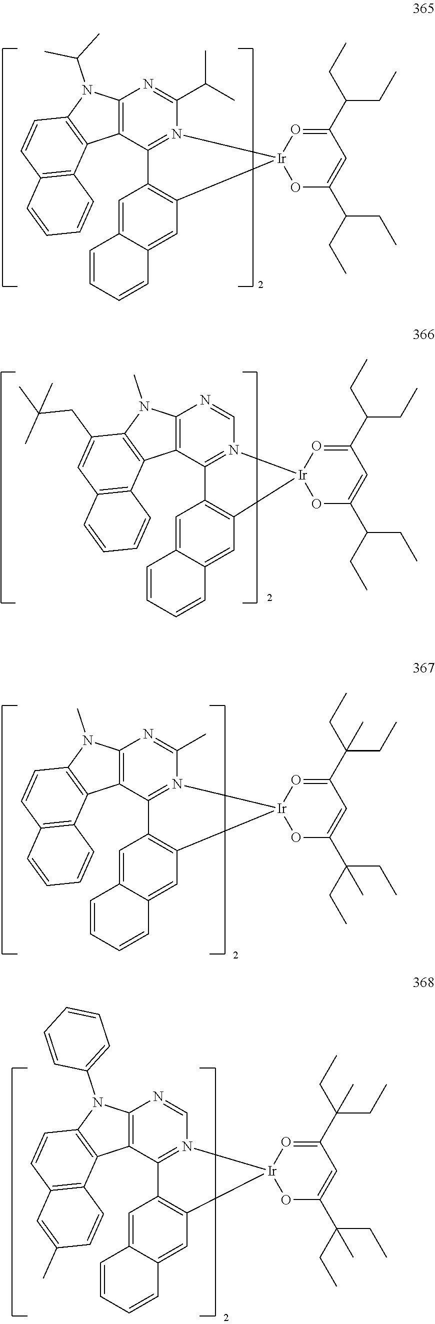

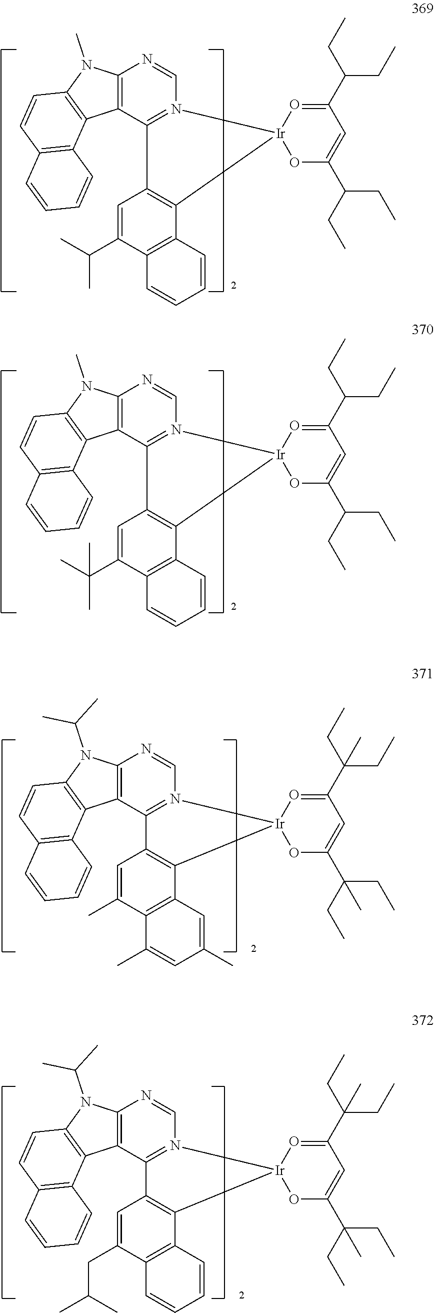

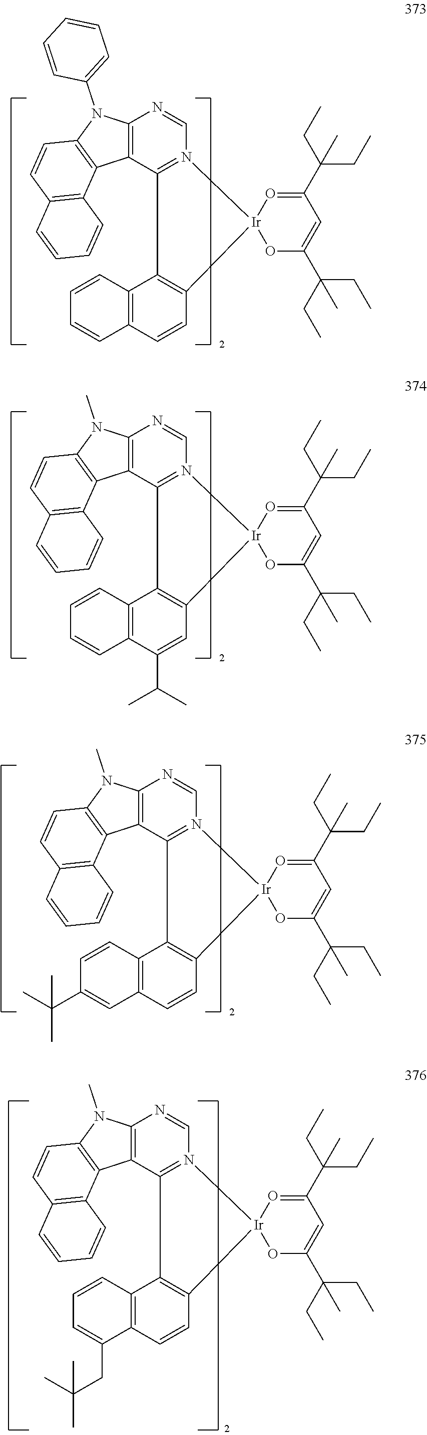

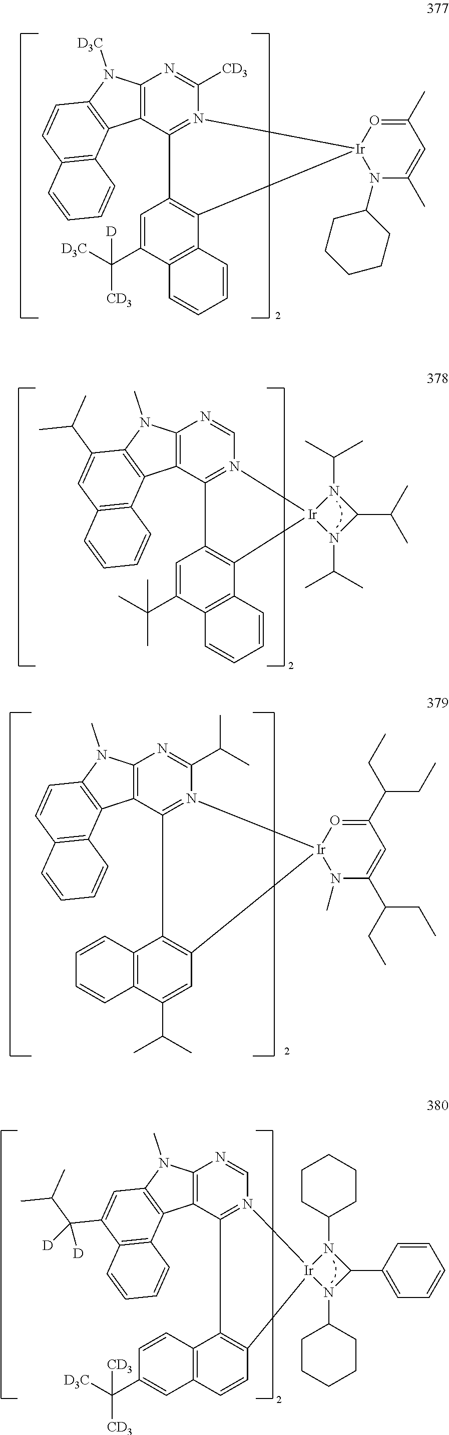

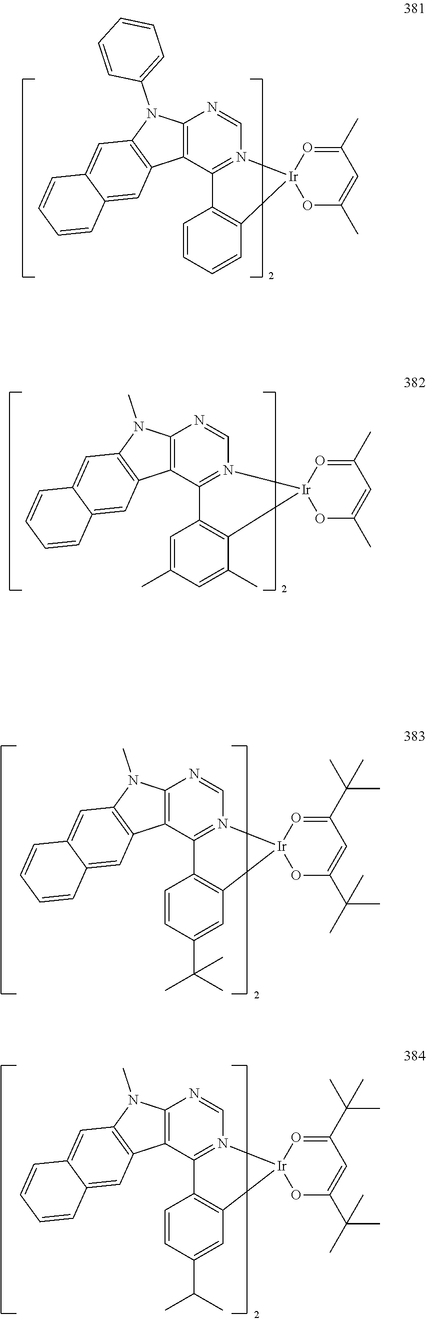

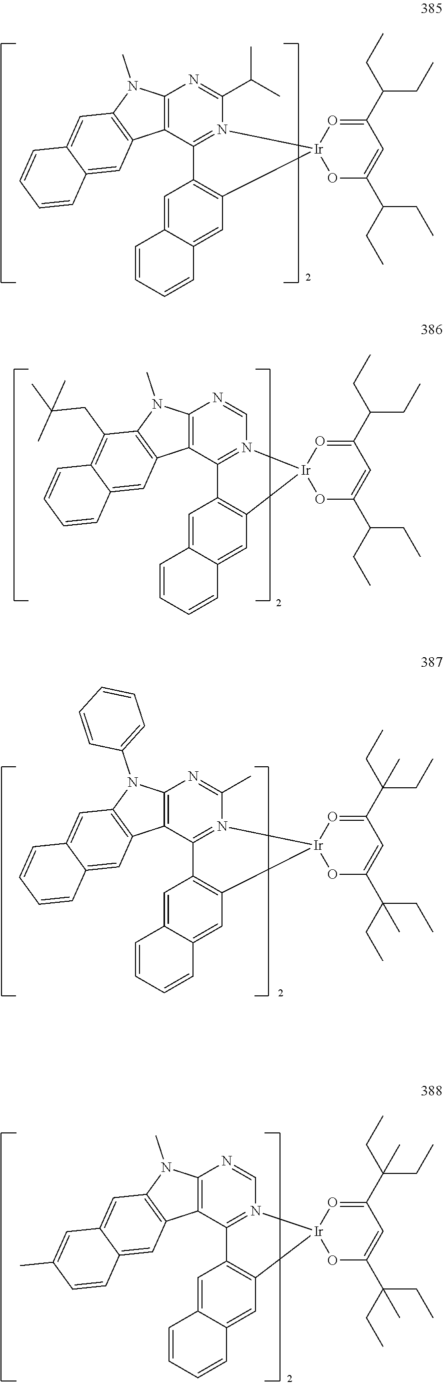

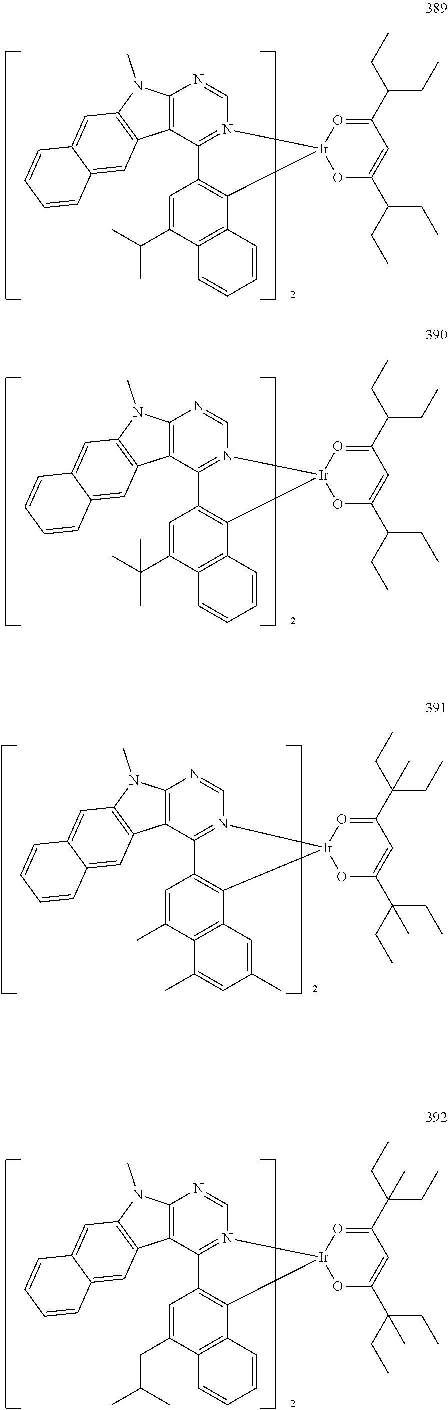

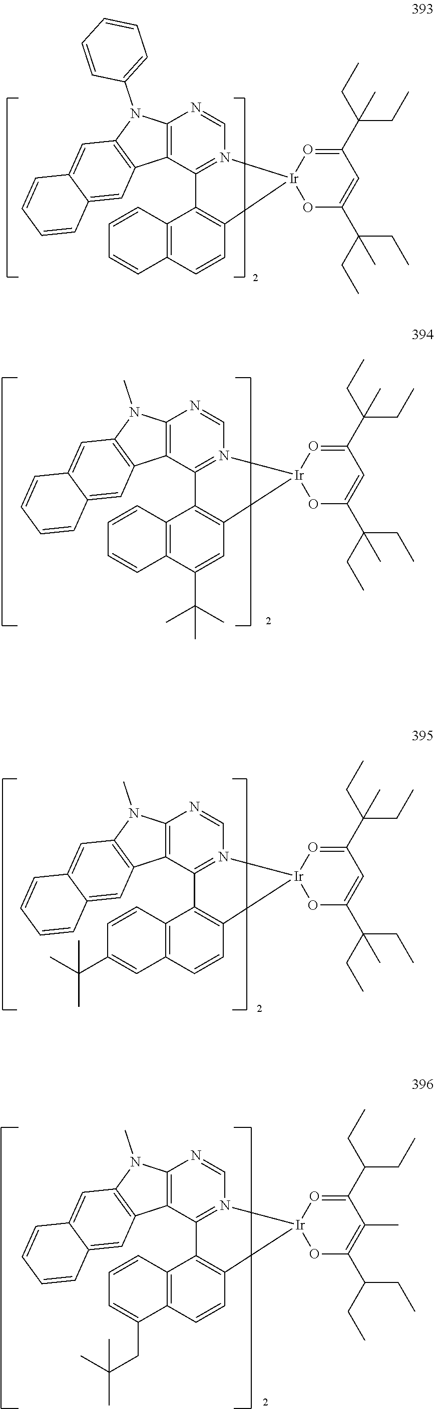

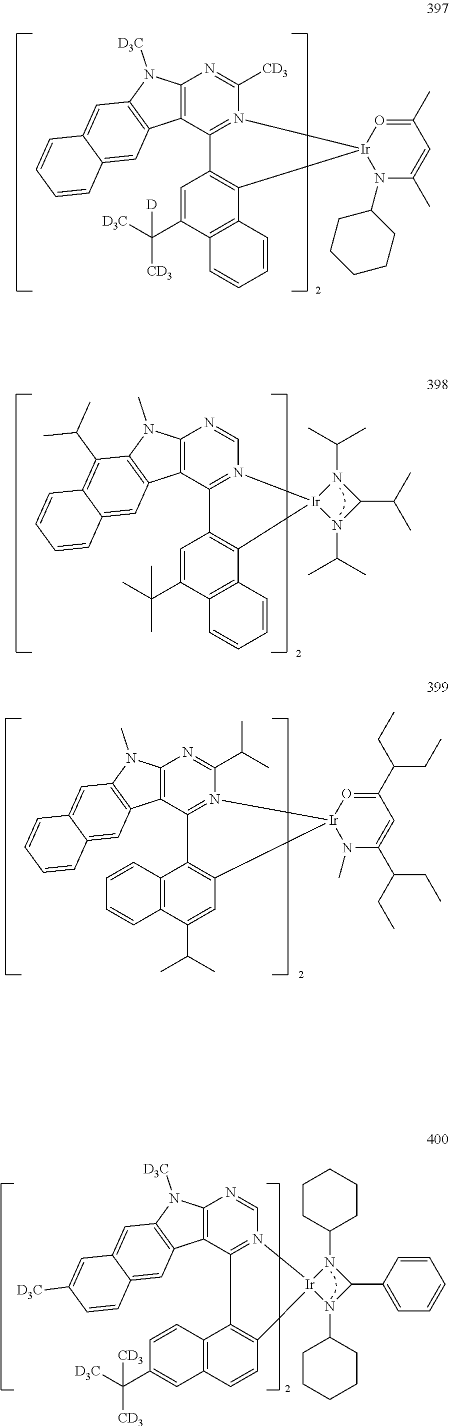

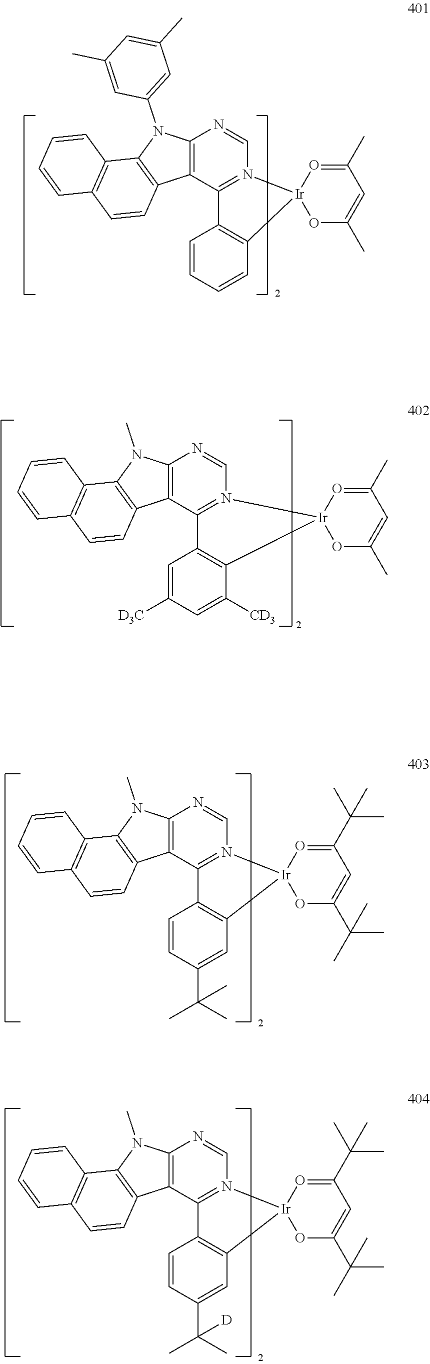

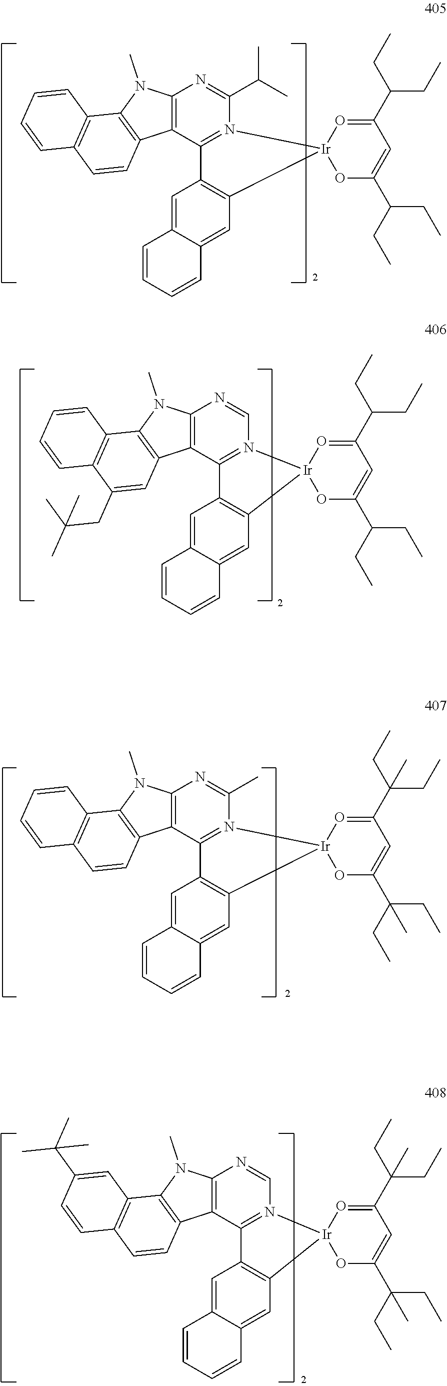

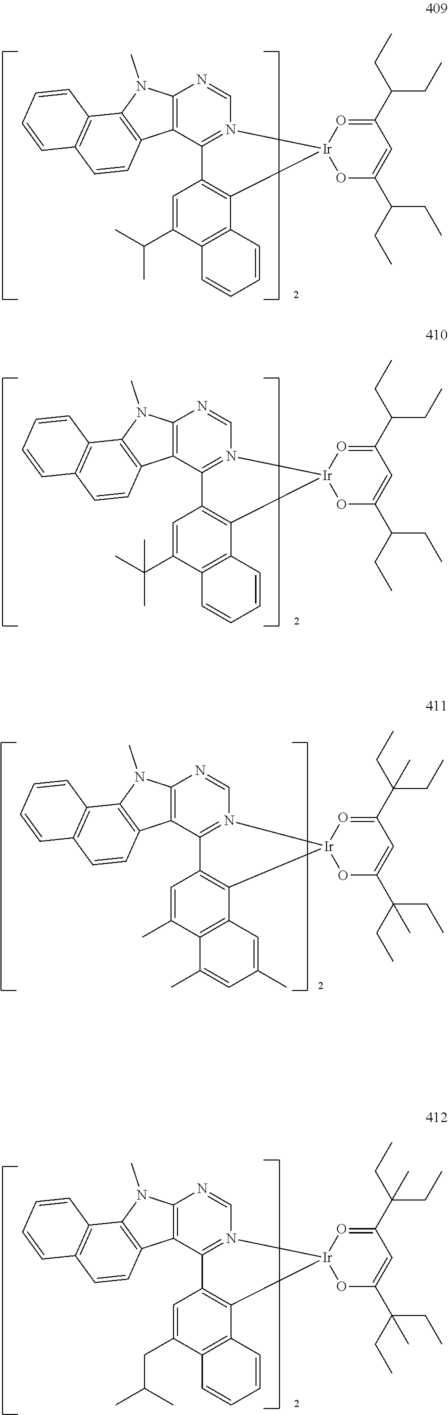

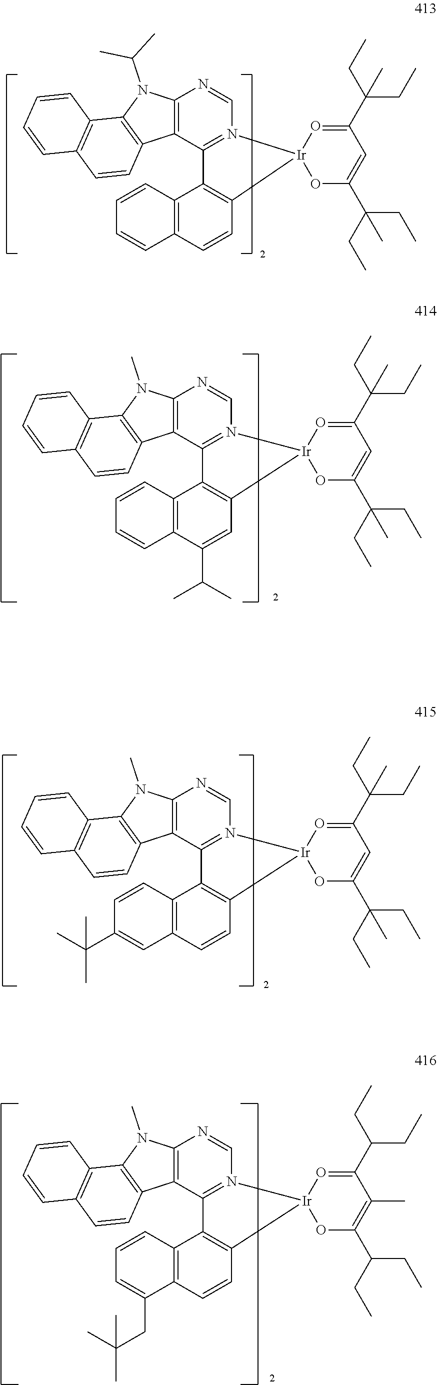

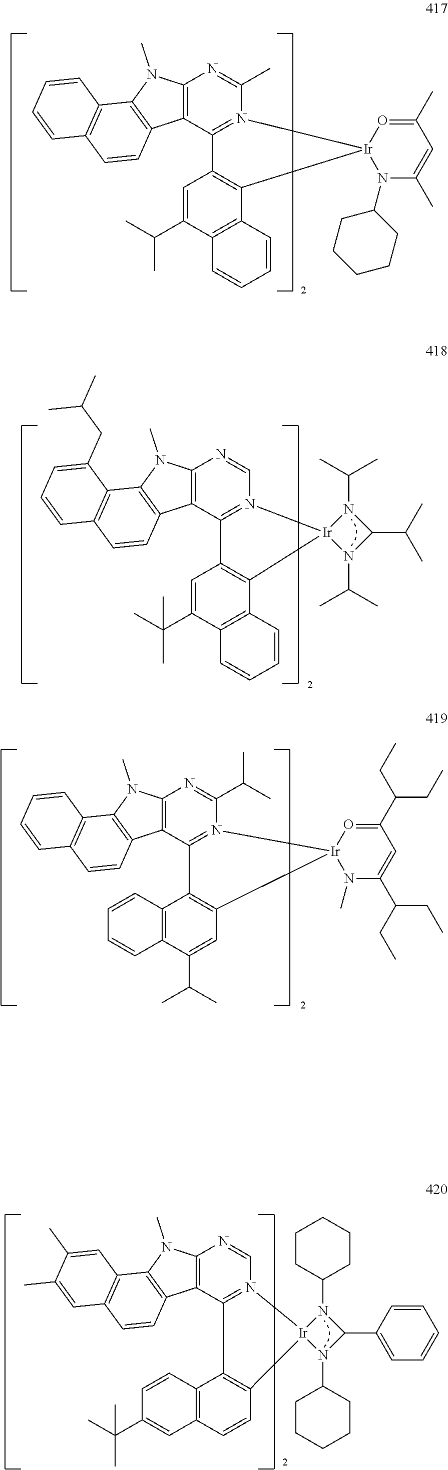

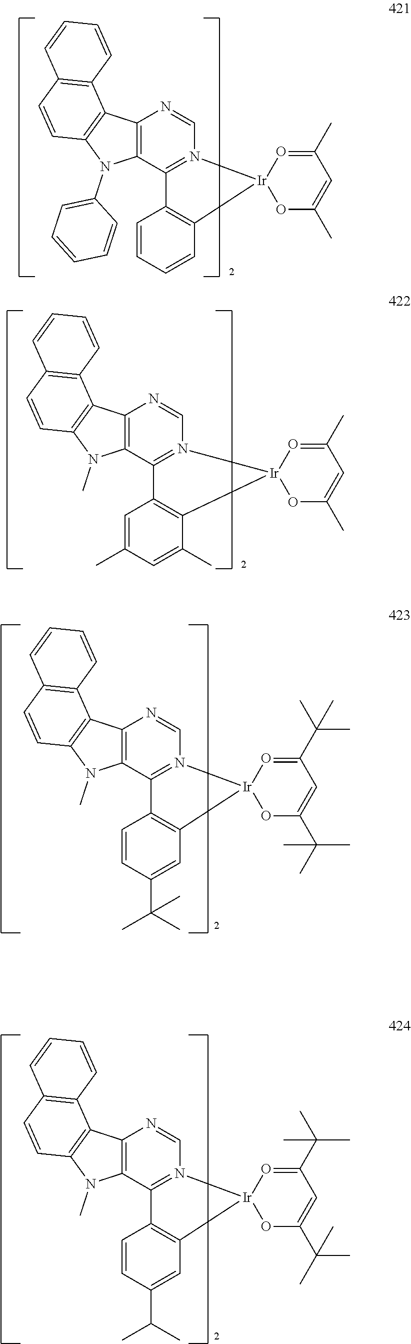

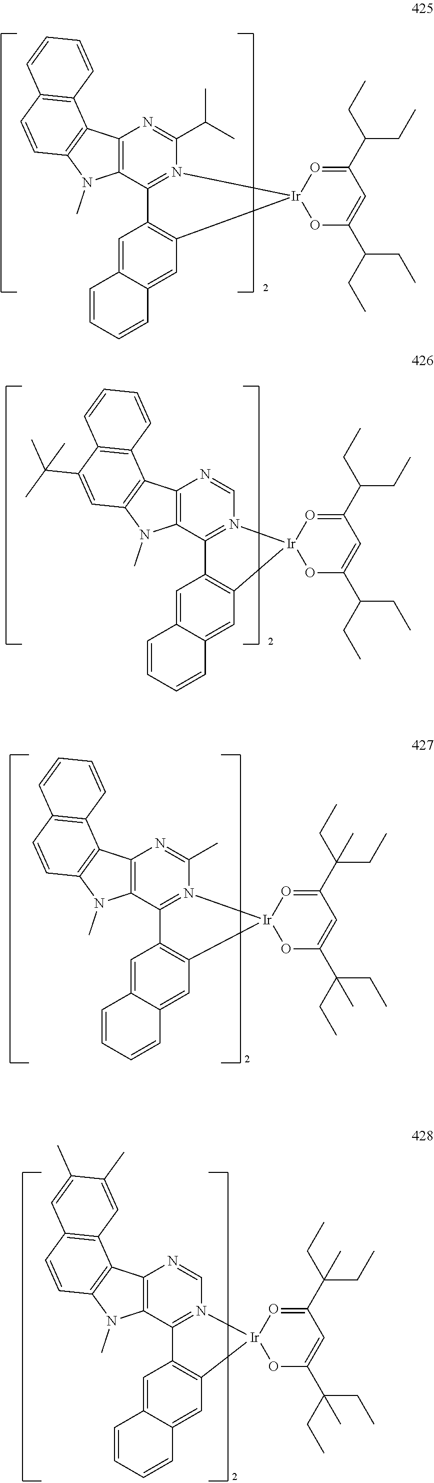

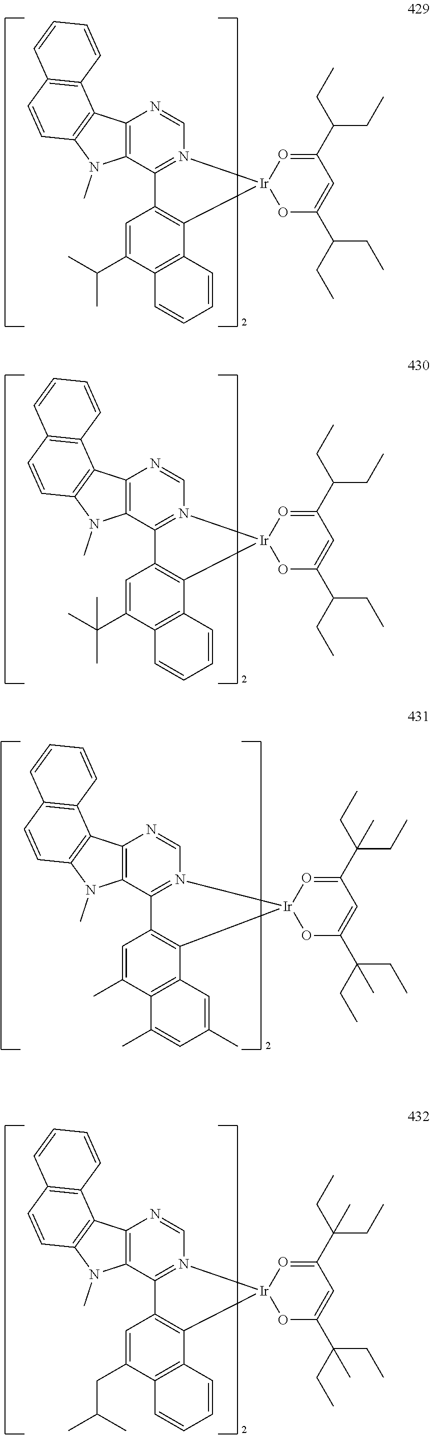

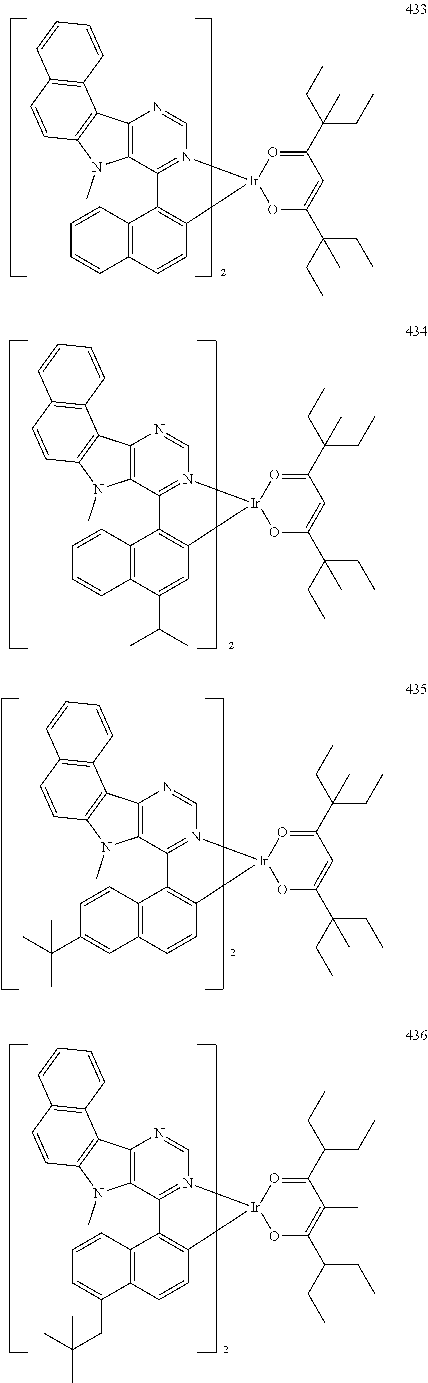

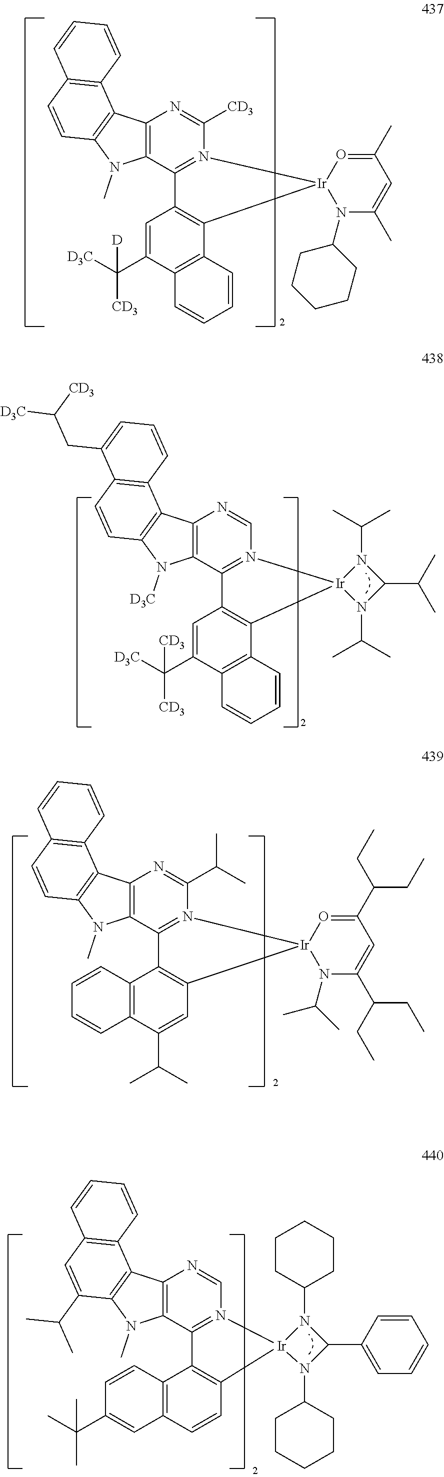

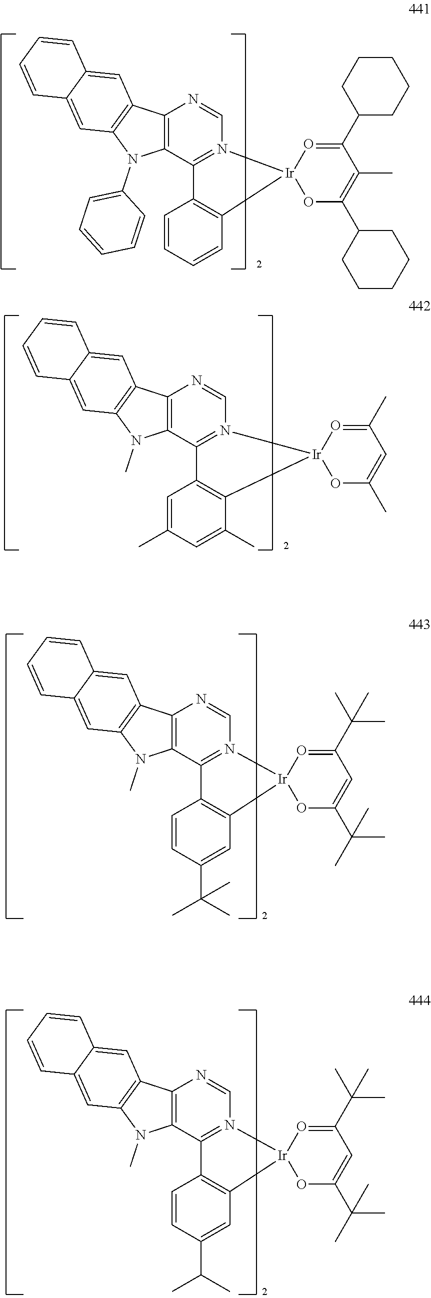

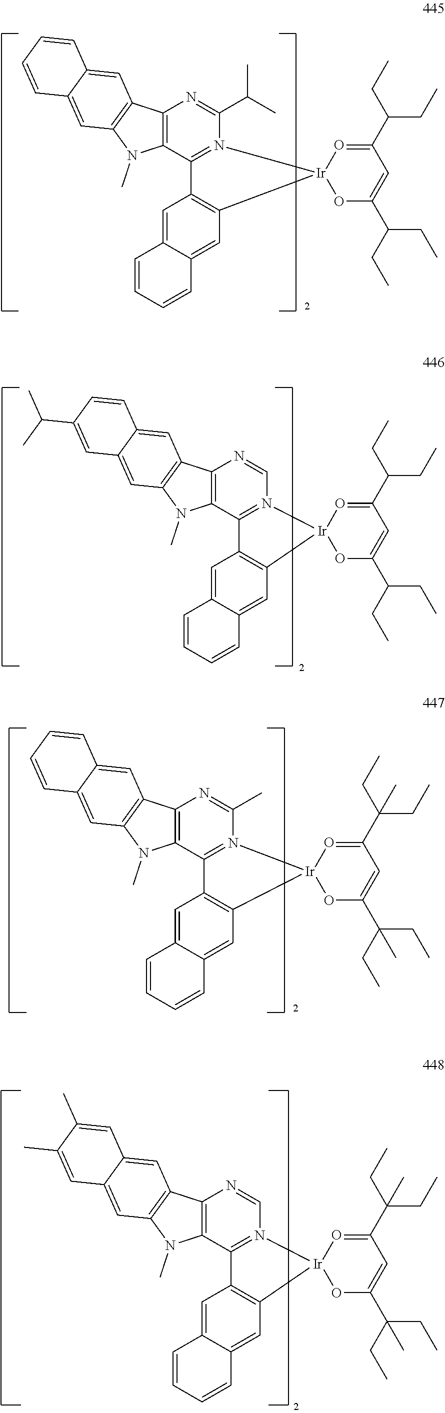

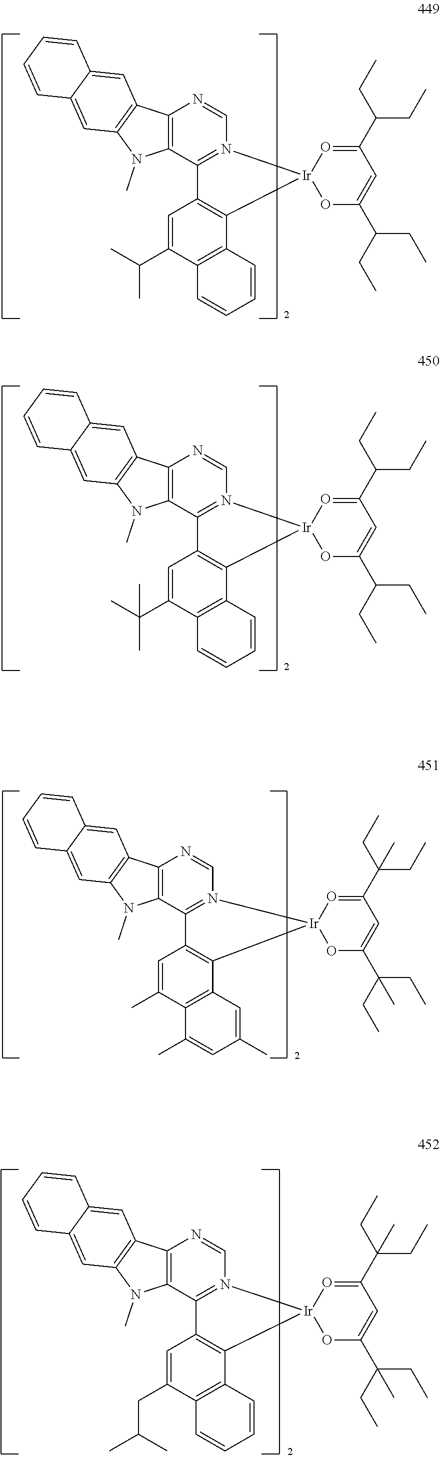

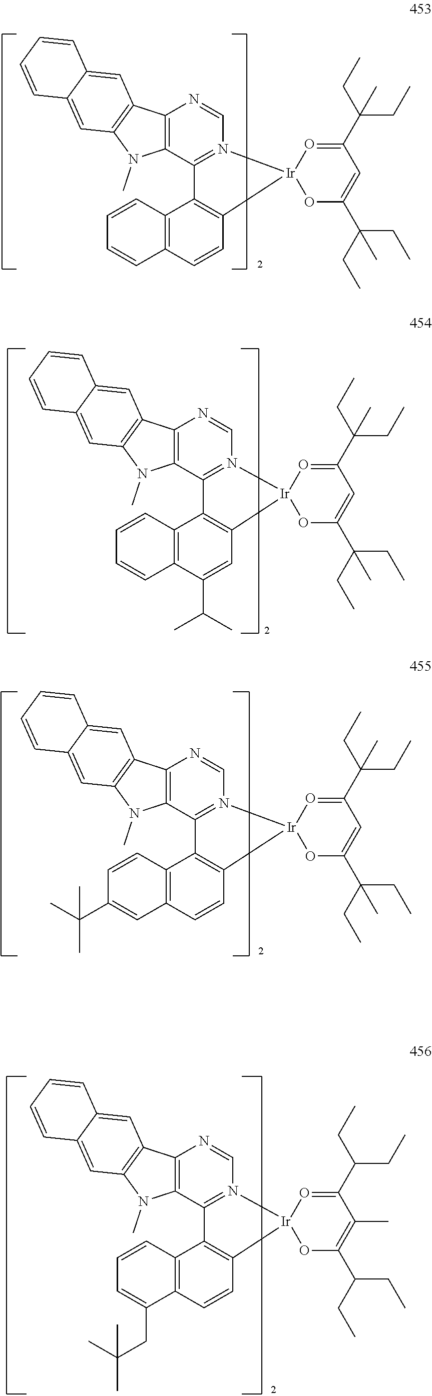

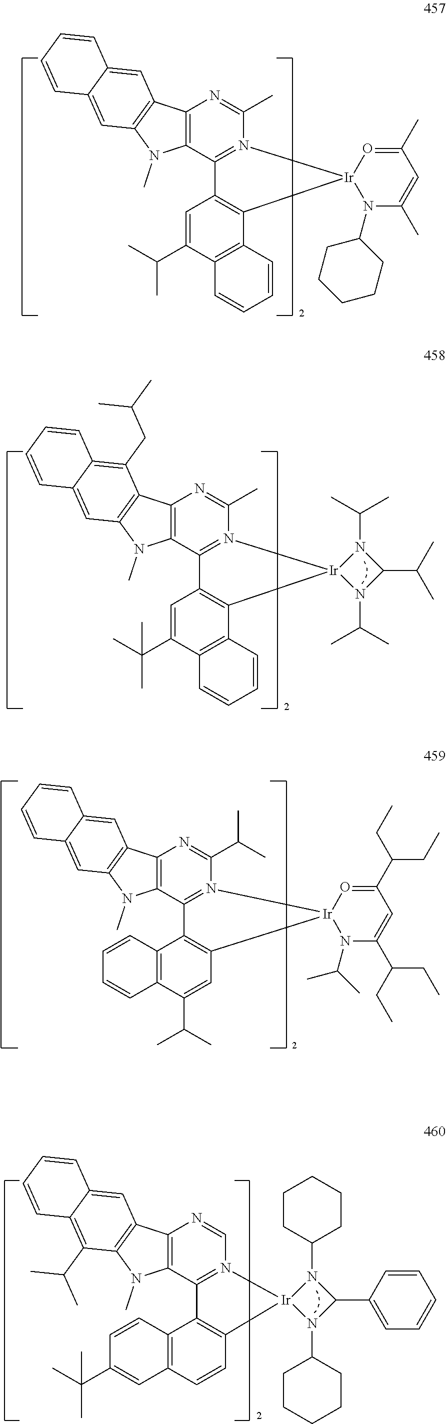

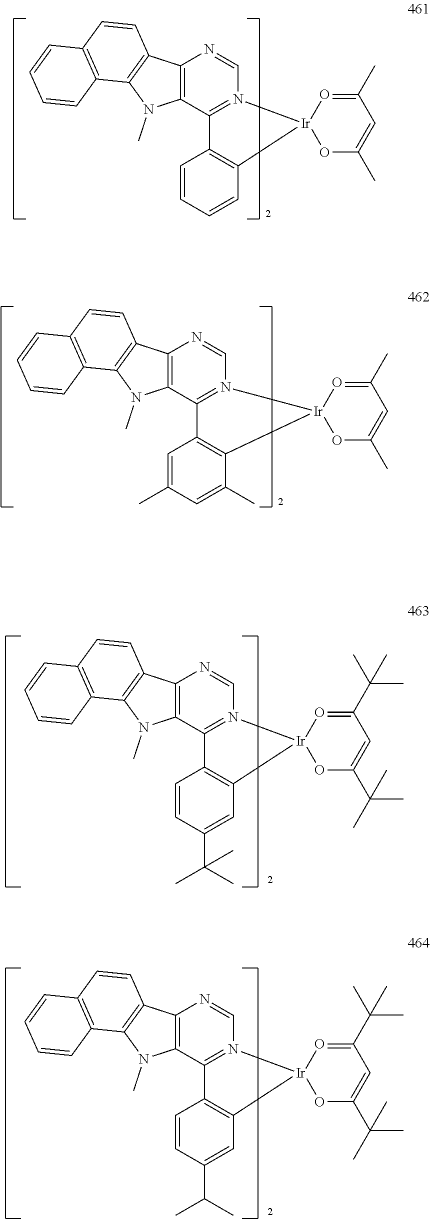

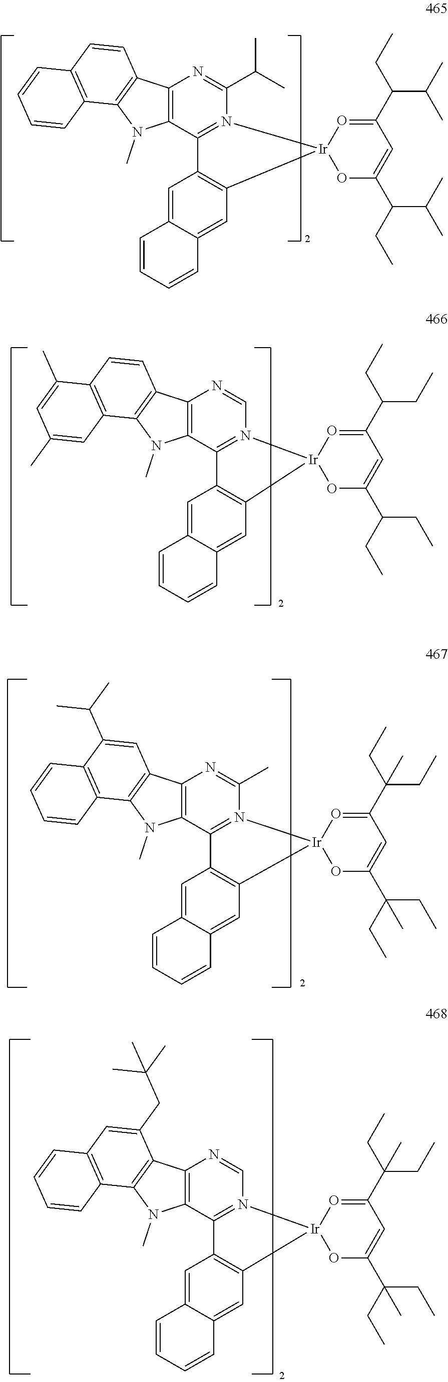

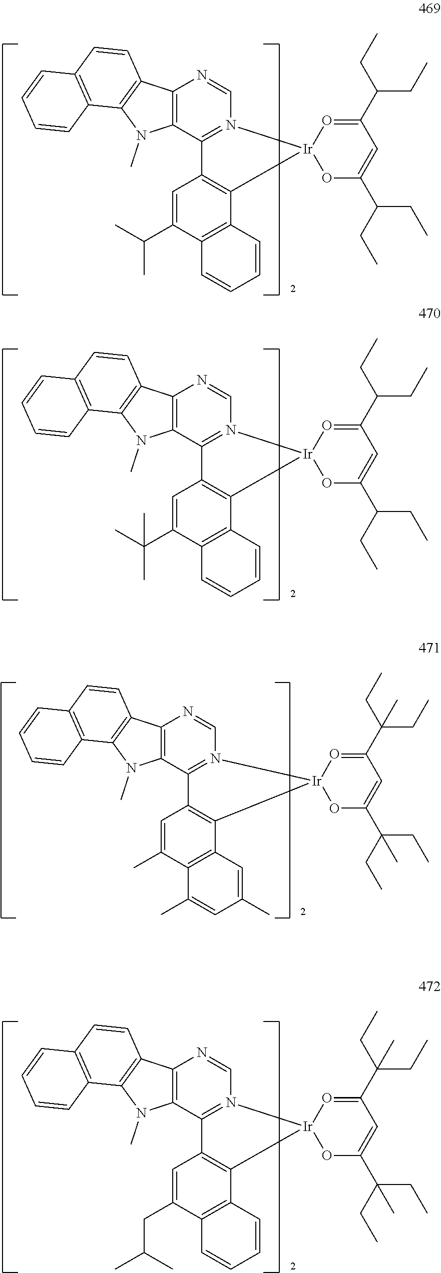

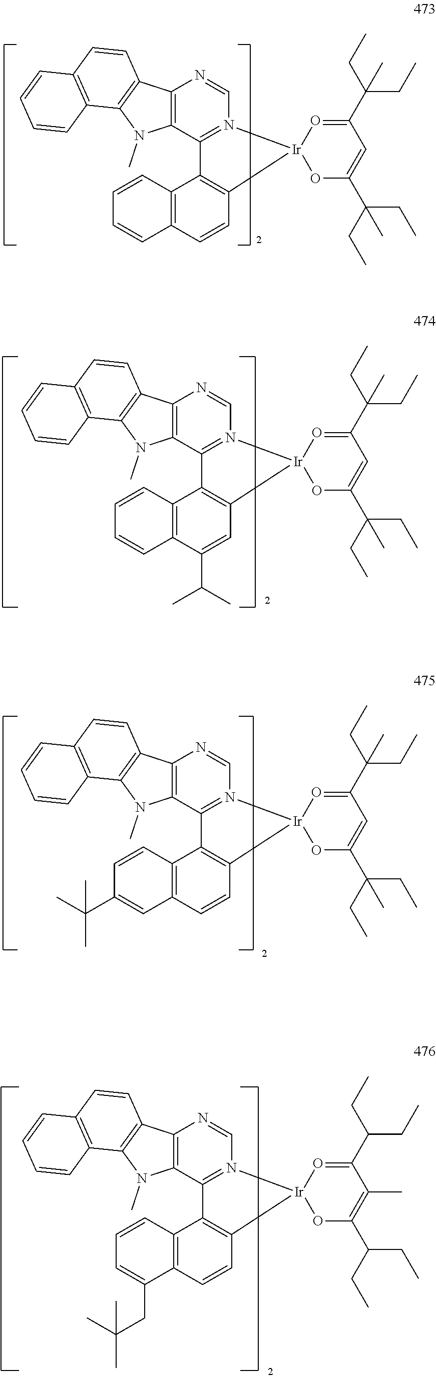

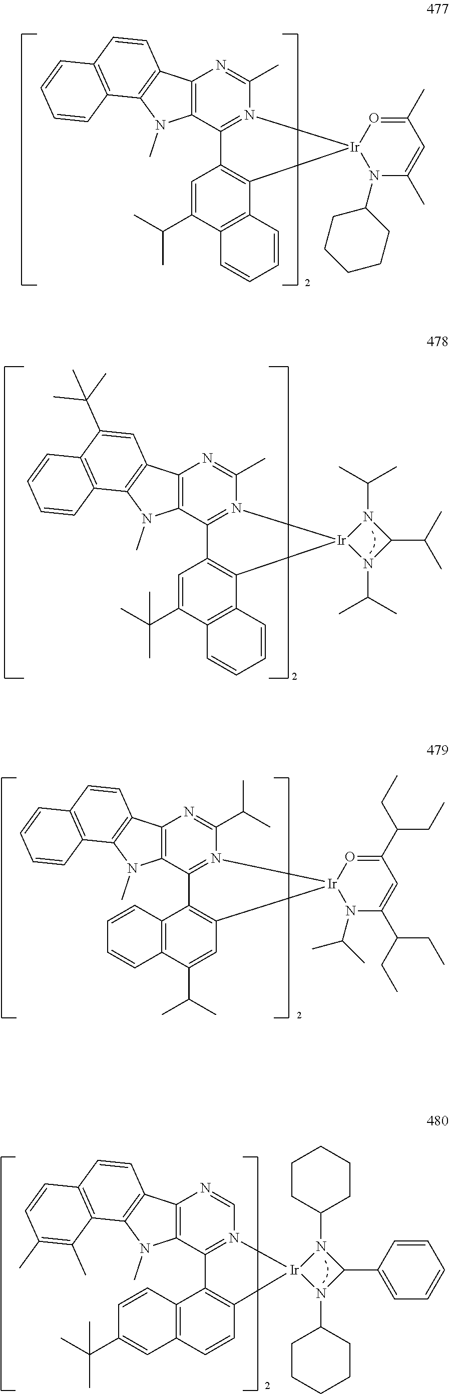

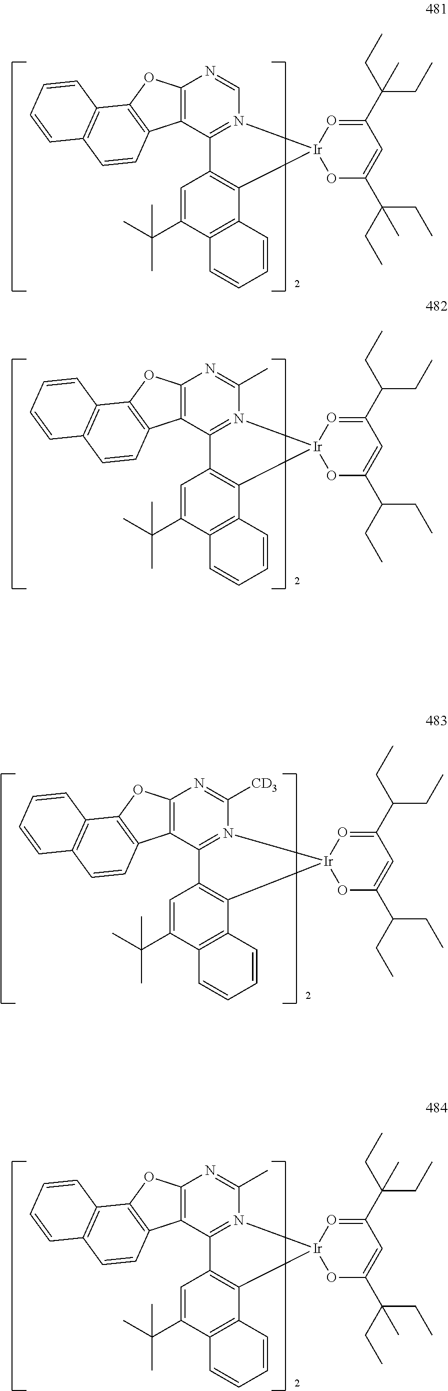

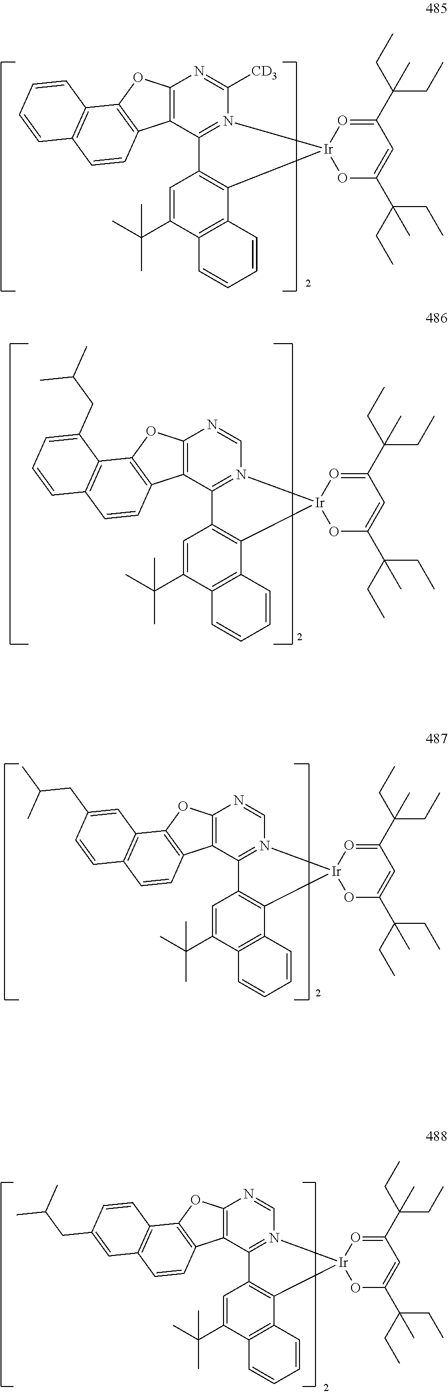

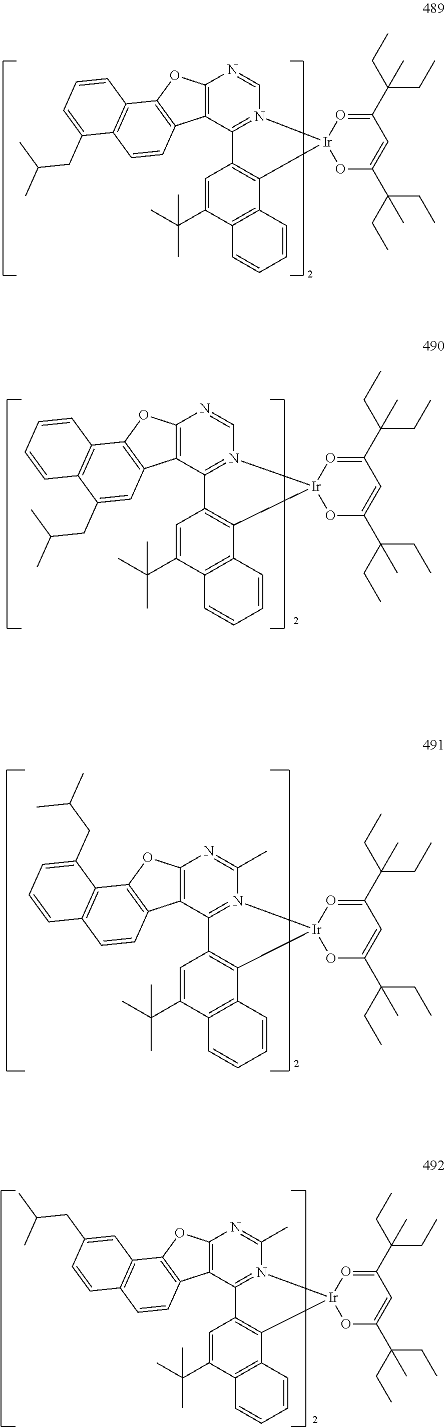

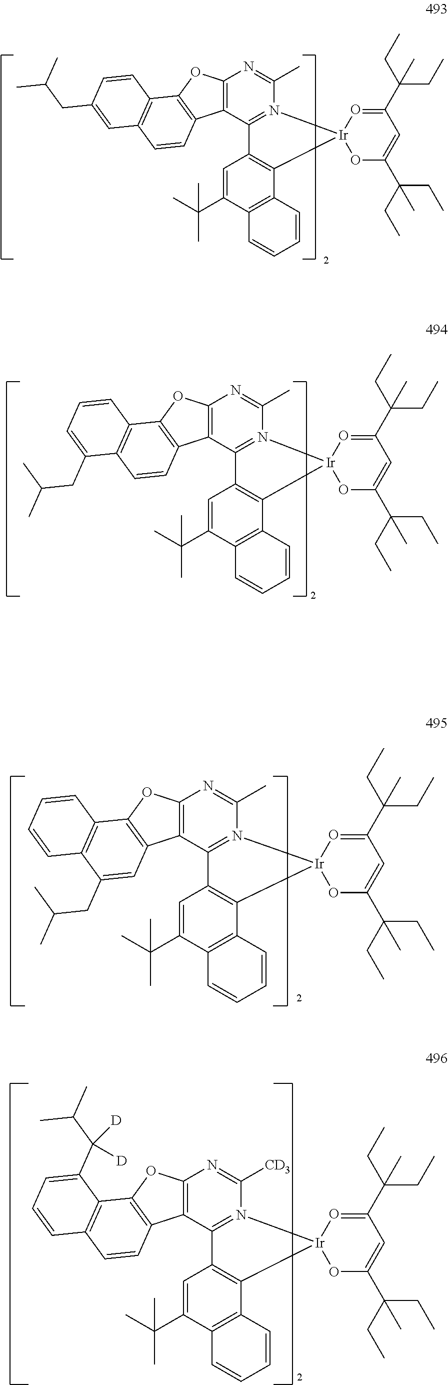

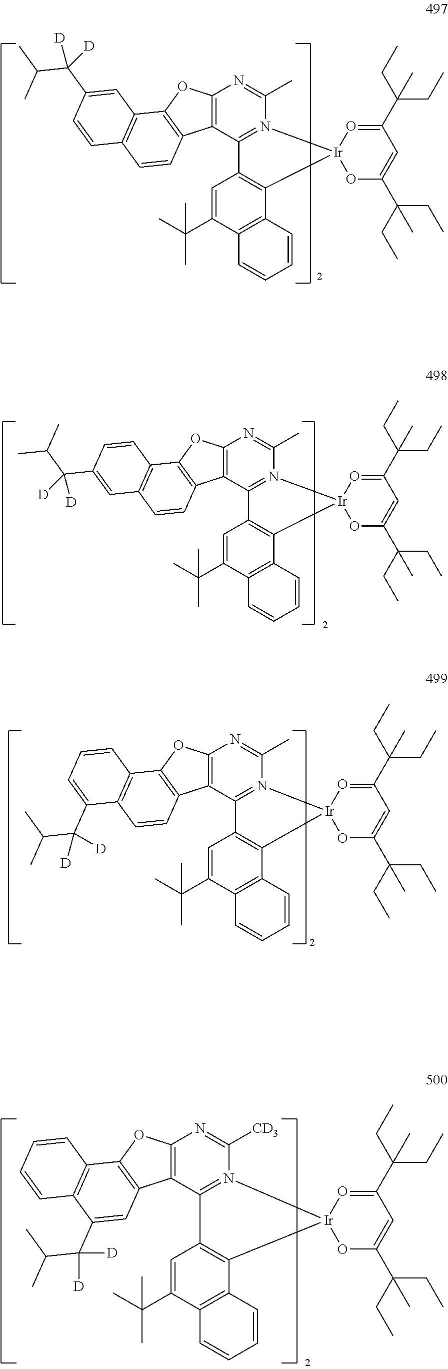

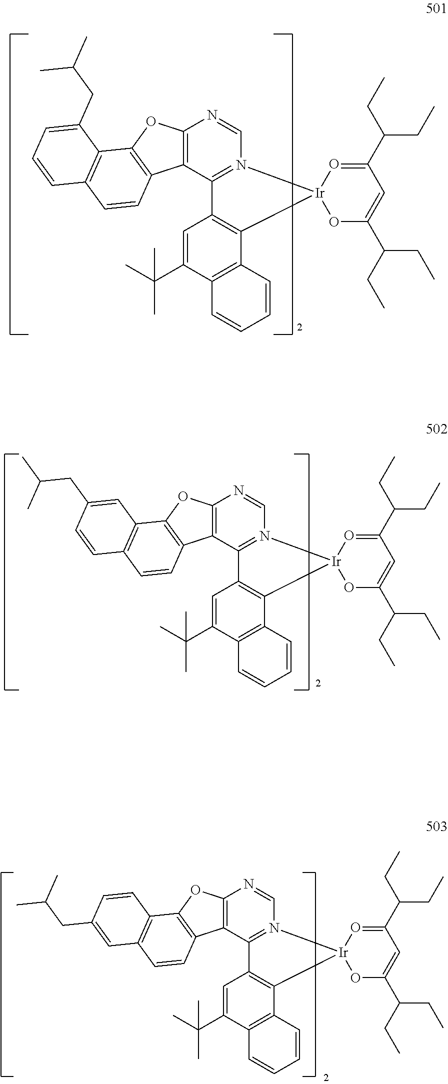

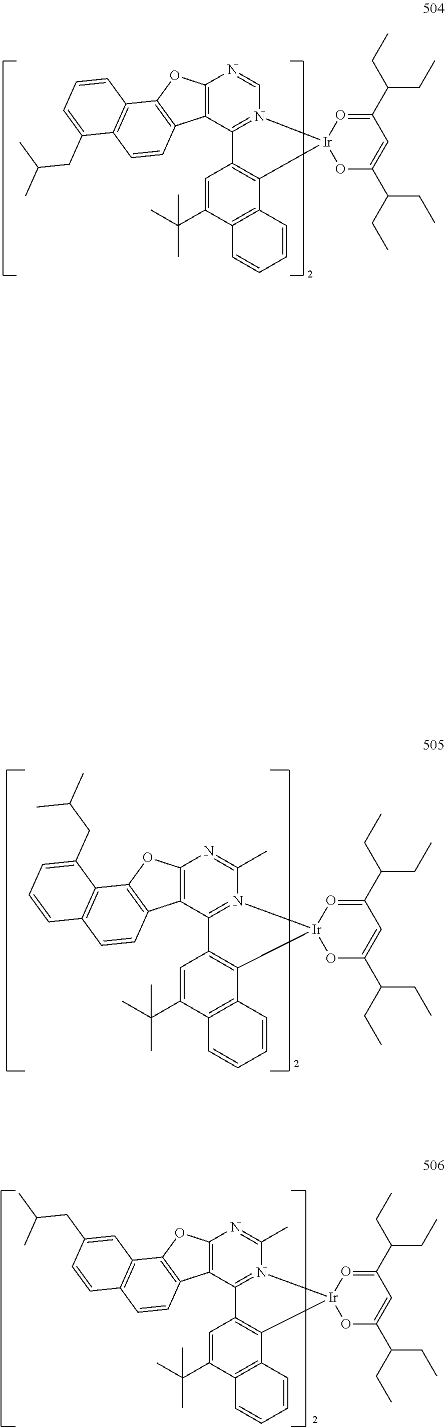

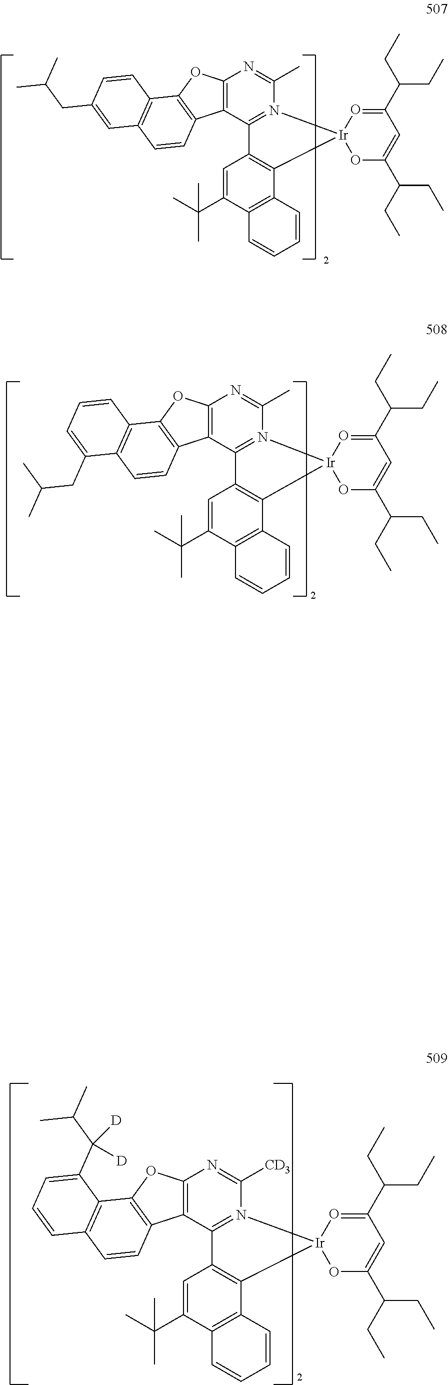

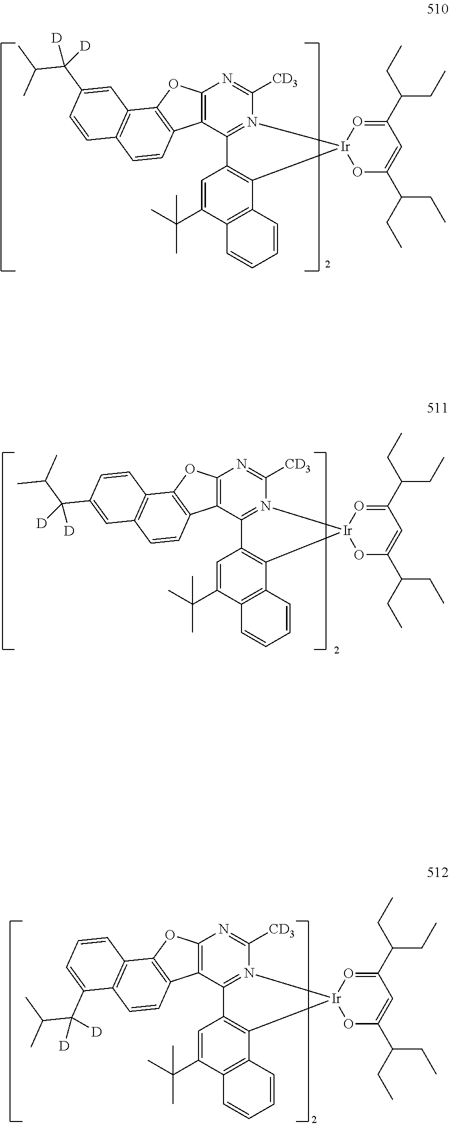

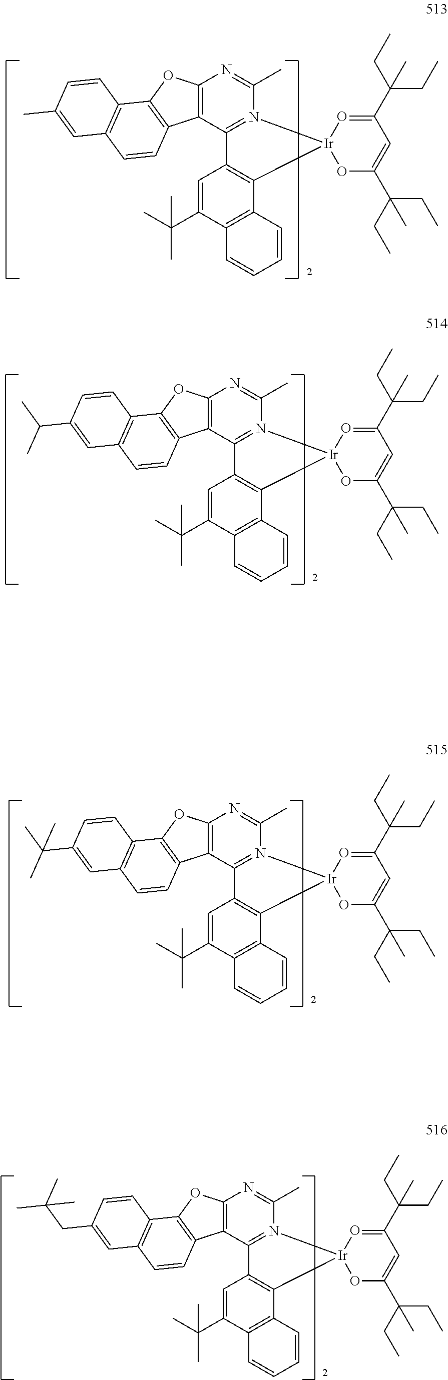

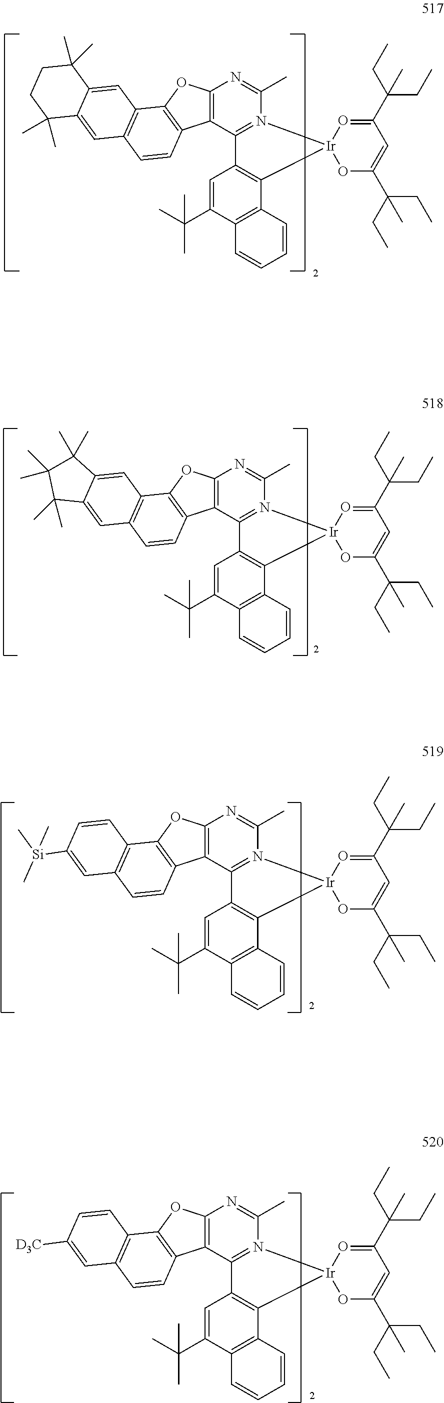

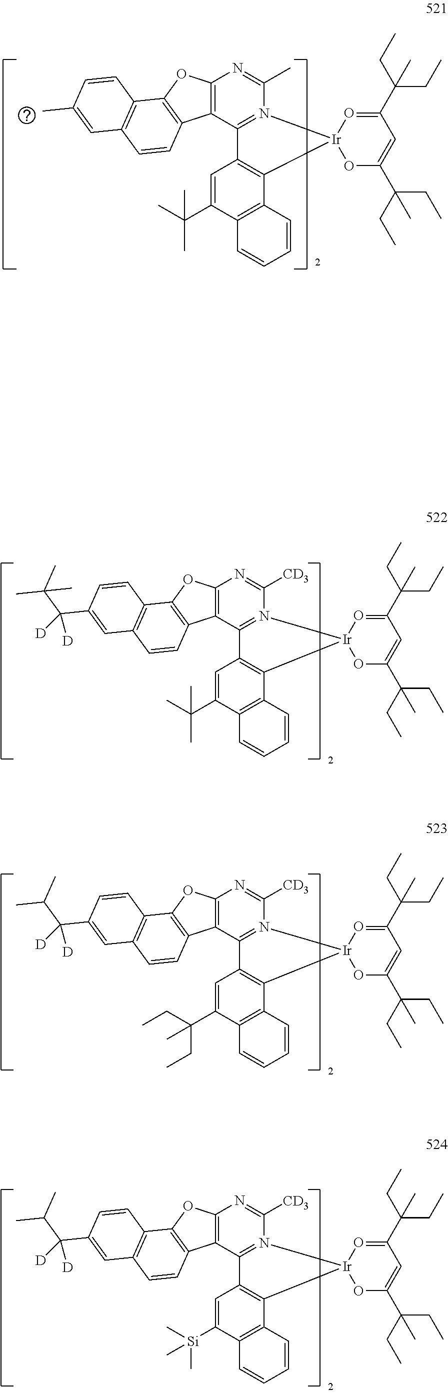

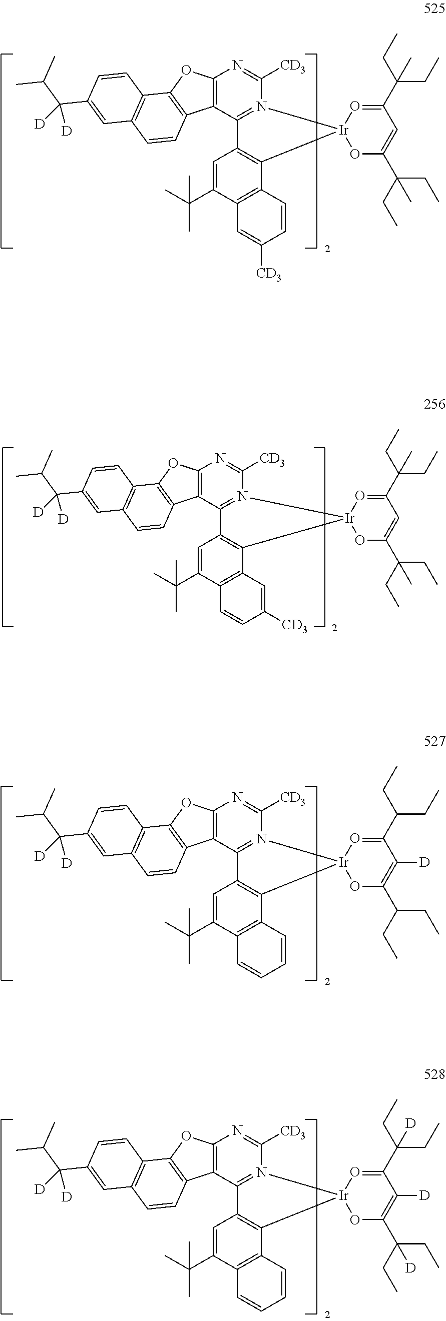

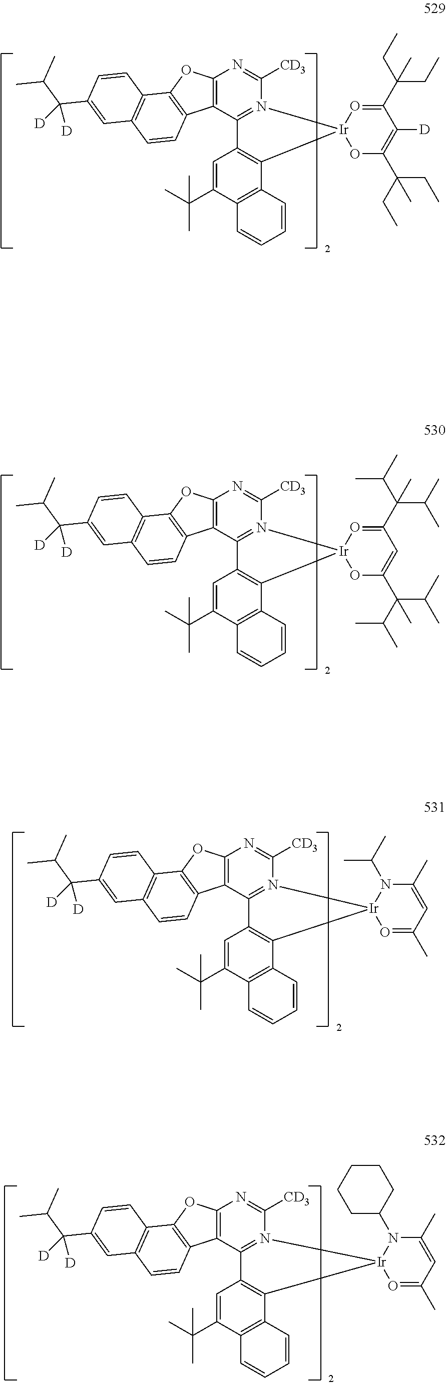

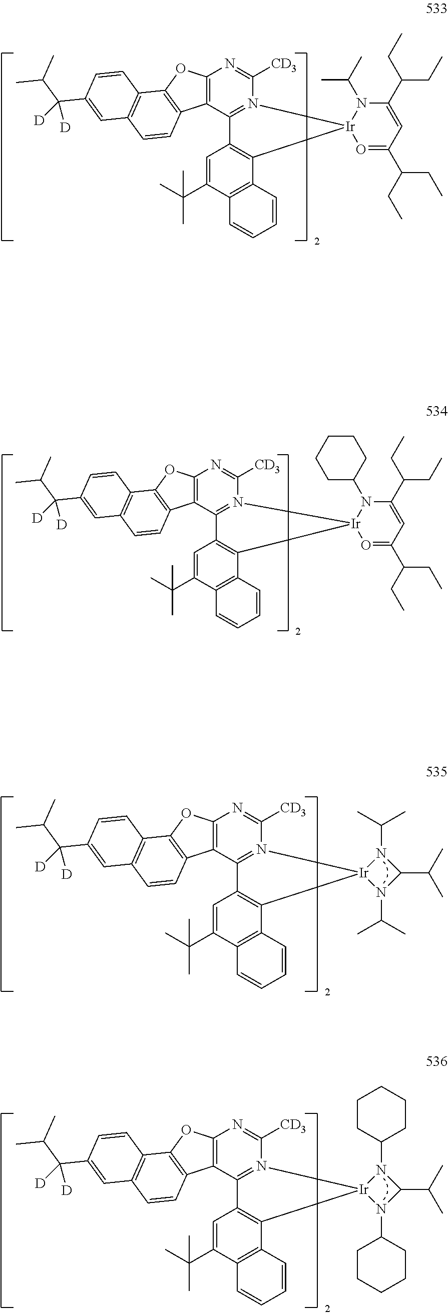

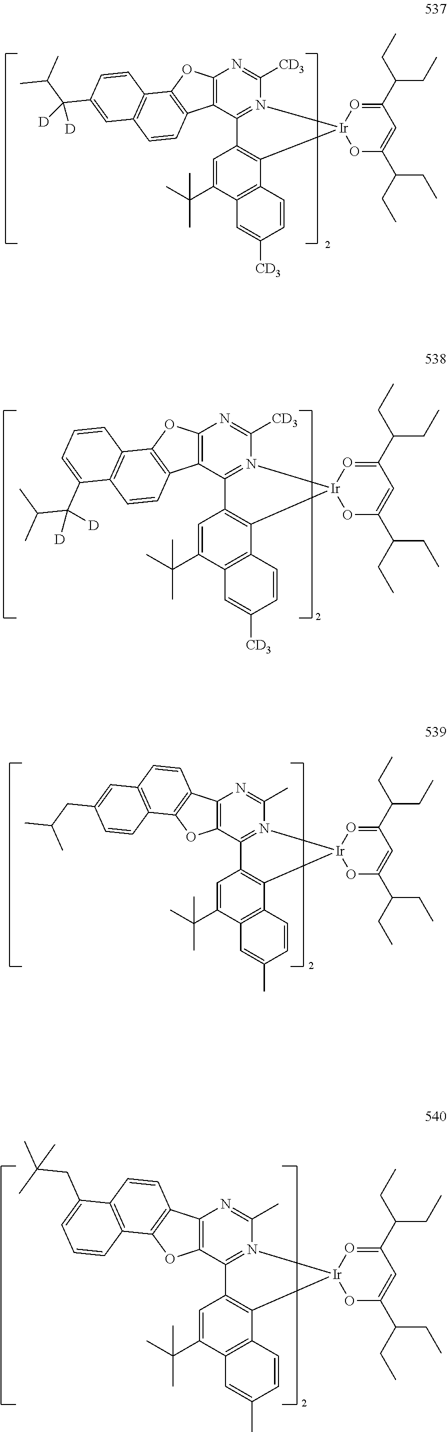

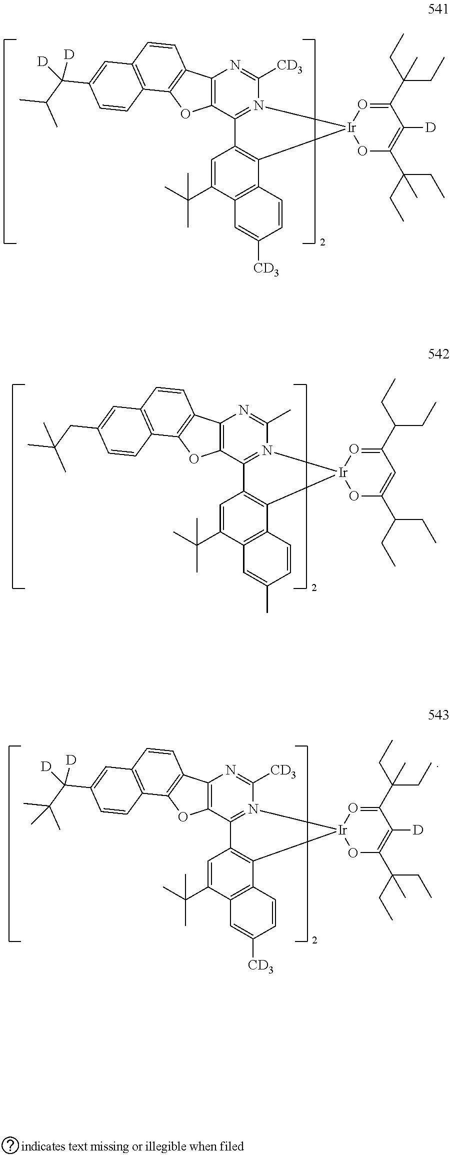

11. The organic light-emitting device of claim 8, wherein the light emitting layer is a red light emitting layer.

12. The organic light-emitting device of claim 8, wherein the light emitting layer further comprises a host material.

13. The organic light-emitting device of claim 8, wherein the organic layer further comprises at least one selected from a group consisting of a hole injection layer, a hole transport layer, an electron transport layer and an electron injection layer.

14. The organic light-emitting device of claim 13, wherein the organic layer further comprises a hole injection layer, wherein the hole injection layer comprises one or more of MTDATA, CuPc, TCTA, HATCN, TDAPB, PEDOT/PSS, or N1,N1′-([1,1′-biphenyl]-4,4′-diyl)bis(N1,N4,N4)-triphenylbenzene-1,4-diamine).

15. The organic light-emitting device of claim 13, wherein the organic layer further comprises a hole transport layer, wherein the hole transport layer comprises one or more of TPD, NPB, CBP, N-(biphenyl-4-yl)-9,9-dimethyl-N-(4-(9-phenyl-9H-carbazol-3-yl)phenyl)-9H-fluoren-2-amine, or N-(biphenyl-4-yl)-N-(4-(9-phenyl-9H-carbazol-3-yl)phenyl)biphenyl)-4-amine.

16. The organic light-emitting device of claim 13, wherein the organic layer further comprises an electron transport layer, wherein the electron transport layer comprises one or more of Alq3 (tris(8-hydroxyquinolino)aluminum), Liq (8-hydroxyquinolinolatolithium), PBD (2-(4-biphenylyl)-5-(4-tert-butylphenyl)-1,3,4oxadiazole), TAZ (3-(4-biphenyl)-phenyl-5-tert-butylphenyl-1,2,4-triazole), spiro-PBD, BAlq (bis(2-methyl-8-quinolinolate)-4-(phenylphenolato)aluminum), SAlq, TPBi (2,2′,2-(1,3,5-benzinetriyl)-tris(1-phenyl-1-H-benzimidazole), oxadiazole, triazole, phenanthroline, benzoxazole, benzthiazole, or 2-(4-(9,10-di(naphthalen-2-yl) anthracen-2-yl)phenyl)-1-phenyl-1H-benzo[d]imidazole.

17. The organic light-emitting device of claim 13, wherein the organic layer further comprises an electron injection layer, wherein the electron injection layer comprises one or more of Alq3 (tris(8-hydroxyquinolino)aluminum), PBD, TAZ, Spiro-PBD, BAlq, or SAlq.

18. An organic light-emitting device comprising:
a first electrode and a second electrode facing each other; and
a first light-emitting stack and a second light-emitting stack positioned between the first electrode and the second electrode,
wherein each of the first light-emitting stack and the second light-emitting stack comprises at least one light emitting layer,
wherein at least one of the light-emitting layers is a red phosphorescent light-emitting layer,
wherein the red phosphorescent light emitting layer comprises a dopant material,
wherein the dopant material comprises the organometallic compound according to claim 1.

19. An organic light-emitting device comprising:
a first electrode and a second electrode facing each other; and
a first light-emitting stack, a second light-emitting stack, and a third light-emitting stack positioned between the first electrode and the second electrode,
wherein each of the first light-emitting stack, the second light-emitting stack and the third light-emitting stack comprises at least one light emitting layer,
wherein at least one of the light-emitting layers is a red phosphorescent light-emitting layer,
wherein the red phosphorescent light emitting layer comprises a dopant material,
wherein the dopant material comprises the organometallic compound according to claim 1.

20. An organic light-emitting display device comprising:
a substrate;
a driving element positioned on the substrate; and
an organic light-emitting element disposed on the substrate and connected to the driving element,
wherein the organic light-emitting element comprises the organic light-emitting device according to claim 8.
